(19) United States
(12) Patent Application Publication
(10) Pub. No.: US 2023/0210002 A1
(43) Pub. Date: Jun. 29, 2023

(54) COMPOSITION, AND ORGANIC ELECTROLUMINESCENCE DEVICE

(71) Applicant: IDEMITSU KOSAN CO.,LTD., Tokyo (JP)

(72) Inventors: Shota TANAKA, Tokyo (JP); Keitaro YAMADA, Tokyo (JP); Yusuke TAKAHASHI, Tokyo (JP); Hiroaki TOYOSHIMA, Tokyo (JP)

(73) Assignee: IDEMITSU KOSAN CO.,LTD., Tokyo (JP)

(21) Appl. No.: 18/076,201

(22) Filed: Dec. 6, 2022

(30) Foreign Application Priority Data
Dec. 10, 2021 (JP) 2021-200873

(51) Int. Cl. H10K 85/60; H10K 50/15; H10K 50/17; H10K 50/11; H10K 85/40

(52) U.S. Cl. CPC H10K 85/6572; H10K 50/15; H10K 50/17; H10K 50/11; H10K 85/6574; H10K 85/631; H10K 85/636; H10K 85/633; H10K 85/6576; H10K 85/655; H10K 85/654; H10K 85/615; H10K 85/624; H10K 85/622; H10K 85/40; H10K 2102/302

(57) ABSTRACT

A composition including a compound represented by the following formula (12) and a compound represented by the following formula (21) (provided that the compound represented by the formula (12) is different from the compound represented by the formula (21)).

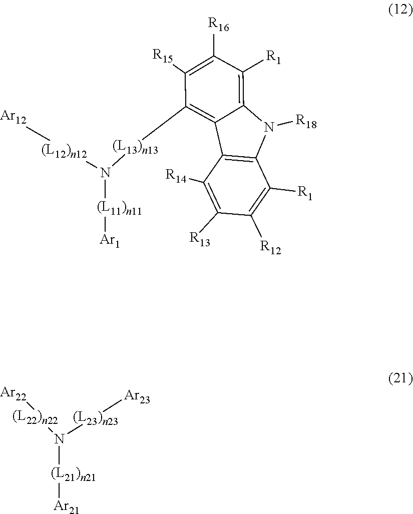

### TECHNICAL FIELD

Embodiments described in the present specification generally relate to a composition and an organic electroluminescence device.

### BACKGROUND ART

When voltage is applied to an organic electroluminescence device (hereinafter, also referred to as an organic EL device), holes and electrons are injected into an emitting layer from an anode and a cathode, respectively. Then, thus injected holes and electrons are recombined in the emitting layer, and excitons are formed therein.

Conventional organic EL devices have not yet had sufficient device performance. Although materials used for the organic EL device are gradually improved to enhance the device performance, further performance enhancement is required.

Patent Documents 1 and 2 disclose that a compound having the specific structure is used as a hole-transporting region in an organic EL device.

### RELATED ART DOCUMENTS

### Patent Documents

[Patent Document 1] WO 2016/064110 A1
[Patent Document 2] KR 10-2016-0054855

### SUMMARY OF THE INVENTION

It is an object of the present invention to provide a composition capable of achieving an organic EL device having high performance, and to provide an organic EL device having the performance.

As a result of intensive studies to achieve the above object, the present inventors have found that an organic EL device having high efficiency and long lifetime can be obtained by using two compounds having the specific structures in combination, and have completed the present invention.

According to the present invention, the following composition and the like are provided.

1. A composition comprising a first compound and a second compound, wherein the first compound is a compound represented by the following formula (12), and the second compound is a compound represented by the following formula (21) (provided that the compound represented by the formula (12) is different from the compound represented by the formula (21)):

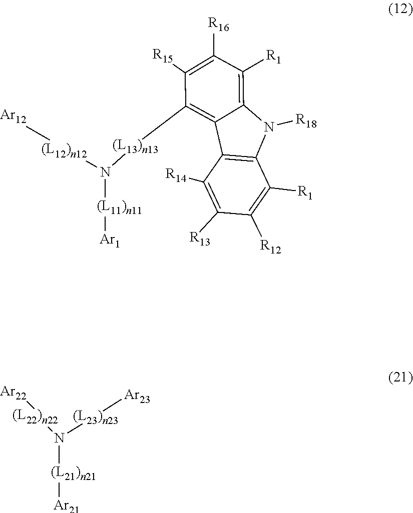

wherein in the formula (12),

Ar₁₁ and Ar₁₂ are independently

a substituted or unsubstituted aryl group having 6 to 50 ring carbon atoms,

a substituted or unsubstituted monovalent heterocyclic group having 5 to 50 ring atoms, or

—Si(R_{C1})(R_{C2})(R_{C3});

R_{C1} to R_{C3} are independently a substituted or unsubstituted aryl group having 6 to 50 ring carbon atoms,

when a plurality of each of R_{C1} to R_{C3} are present, the plurality of each of R_{C1} to R_{C3} may be the same as or different from each other;

n11 is an integer of 0 to 3; when n11 is 0, Ar₁₁ is directly bonded with the nitrogen atom of the amine via a single bond; when n11 is 2 or 3, a plurality of L₁₁'s is linked in series with each other and Ar₁₁ is bonded with L₁₁ which is farthest from the nitrogen atom of the amine; when two or more L₁₁'s are present, one or more sets of the adjacent two or more of the two or more L₁₁'s form a substituted or unsubstituted single ring by bonding with each other, form a substituted or unsubstituted fused ring by bonding with each other, or do not form the ring; when two or more L₁₁'s are present, the two or more L₁₁'s may be the same as or different from each other;

n12 is an integer of 0 to 3; when n12 is 0, Ar₁₂ is directly bonded with the nitrogen atom of the amine via a single bond; when n12 is 2 or 3, a plurality of L₁₂'s is linked in series with each other and Ar₁₂ is bonded with L₁₂ which is farthest from the nitrogen atom of the amine; when two or more L₁₂'s are present, one or more sets of the adjacent two or more of the two or more L₁₂'s form a substituted or unsubstituted single ring by bonding with each other, form a substituted or unsubstituted fused ring by bonding with each other, or do not form the ring; when two or more L₁₂'s are present, the two or more L₁₂'s may be the same as or different from each other;

n13 is an integer of 0 to 3; when n13 is 0, the carbon atom of the carbazole skeleton is directly bonded with the nitrogen atom of the amine via a single bond; when n13 is 2 or 3, a plurality of L₁₃'s is linked in series with each other and the carbazole skeleton is bonded with L₁₃ which is farthest from the nitrogen atom of the amine; when two or more L₁₃'s are present, one or more sets of the adjacent two or more of the two or more L₁₃'s form a substituted or unsubstituted single ring by bonding with each other, form a substituted or unsubstituted fused ring by bonding with each other, or do not form the ring; when two or more L₁₃'s are present, the two or more L₁₃'s may be the same as or different from each other;

L₁₁, L₁₂, and L₁₃ which do not form the ring are independently

a single bond,

a substituted or unsubstituted arylene group having 6 to 50 ring carbon atoms, or

a substituted or unsubstituted divalent heterocyclic group having 5 to 50 ring atoms;

one or more sets of the adjacent two or more of R₁₁ to R₁₇

form a substituted or unsubstituted single ring by bonding with each other,

form a substituted or unsubstituted fused ring by bonding with each other, or

do not bond with each other;

R₁₈, and R₁₁ to R₁₇ which do not form the substituted or unsubstituted single ring and which do not form the substituted or unsubstituted fused ring are independently

a hydrogen atom,

a cyano group,

a substituted or unsubstituted alkyl group having 1 to 50 carbon atoms,

a substituted or unsubstituted halogenated alkyl group having 1 to 50 carbon atoms,

a substituted or unsubstituted cycloalkyl group having 3 to 50 ring carbon atoms,

a group represented by —Si(R_{901A})(R_{902A})(R_{903A}),

a group represented by —O—(R_{904A}),

a substituted or unsubstituted aryl group having 6 to 50 ring carbon atoms, or

a substituted or unsubstituted monovalent heterocyclic group having 5 to 50 ring atoms;

R_{901A} to R_{904A} are independently

a hydrogen atom,

a substituted or unsubstituted alkyl group having 1 to 50 carbon atoms,

a substituted or unsubstituted cycloalkyl group having 3 to 50 ring carbon atoms,

a substituted or unsubstituted aryl group having 6 to 50 ring carbon atoms, or

a substituted or unsubstituted monovalent heterocyclic group having 5 to 50 ring atoms;

when a plurality of each of R_{901A} to R_{904A} are present, the plurality of each of R_{901A} to R_{904A} may be the same as or different from each other;

in the formula (21),

Ar₂₁, Ar₂₂, and Ar₂₃ are independently

a substituted or unsubstituted aryl group having 6 to 50 ring carbon atoms,

a substituted or unsubstituted monovalent heterocyclic group having 5 to 50 ring atoms, or

—Si(R_{C1})(R_{C2})(R_{C3});

R_{C1} to R_{C3} are the same as defined in the formula (12);

n21 is an integer of 0 to 3; when n21 is 0, Ar₂₁ is directly bonded with the nitrogen atom of the amine via a single bond; when n21 is 2 or 3, a plurality of L₂₁'s is linked in series with each other and Ar₂₁ is bonded with L₂₁ which is farthest from the nitrogen atom of the amine; when two or more L₂₁'s are present, one or more sets of the adjacent two or more of the two or more L₂₁'s form a substituted or unsubstituted single ring by bonding with each other, form a substituted or unsubstituted fused ring by bonding with each other, or do not form the ring; when two or more L₂₁'s are present, the two or more L₂₁'s may be the same as or different from each other;

n22 is an integer of 0 to 3; when n22 is 0, Ar₂₂ is directly bonded with the nitrogen atom of the amine via a single bond; when n22 is 2 or 3, a plurality of L₂₂'s is linked in series with each other and Ar₂₂ is bonded with L₂₂ which is farthest from the nitrogen atom of the amine; when two or more L₂₂'s are present, one or more sets of the adjacent two or more of the two or more L₂₂'s form a substituted or unsubstituted single ring by bonding with each other, form a substituted or unsubstituted fused ring by bonding with each other, or do not form the ring; when two or more L₂₂'s are present, the two or more L₂₂'s may be the same as or different from each other;

n23 is an integer of 0 to 3; when n23 is 0, Ar₂₃ is directly bonded with the nitrogen atom of the amine via a single bond; when n23 is 2 or 3, a plurality of L₂₃'s is linked in series with each other and Ar₂₃ is bonded with L₂₃ which is farthest from the nitrogen atom of the amine; when two or more L₂₃'s are present, one or more sets of the adjacent two or more of the two or more L₂₃'s form a substituted or unsubstituted single ring by bonding with each other, form a substituted or unsubstituted fused ring by bonding with each other, or do not form the ring; when two or more L₂₃'s are present, the two or more L₂₃'s may be the same as or different from each other; and

L₂₁, L₂₂, and L₂₃ which do not form the ring are independently

a single bond,

a substituted or unsubstituted arylene group having 6 to 50 ring carbon atoms, or

a substituted or unsubstituted divalent heterocyclic group having 5 to 50 ring atoms.

2. A composition comprising a first compound and a second compound, wherein the first compound is a compound represented by the following formula (11), and the second compound is a compound represented by the following formula (23) (provided that the compound represented by the formula (11) is different from the compound represented by the formula (23)):

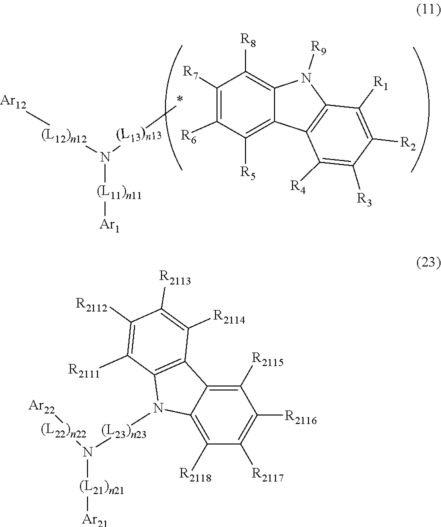

wherein in the formula (11),

Ar₁₁ and Ar₁₂ are independently

a substituted or unsubstituted aryl group having 6 to 50 ring carbon atoms,

a substituted or unsubstituted monovalent heterocyclic group having 5 to 50 ring atoms, or

—Si(R_{C1})(R_{C2})(R_{C3});

R_{C1} to R_{C3} are independently a substituted or unsubstituted aryl group having 6 to 50 ring carbon atoms,

when a plurality of each of R_{C1} to R_{C3} are present, the plurality of each of R_{C1} to R_{C3} may be the same as or different from each other;

any one of R₁ to R₈ represents a bond with L₁₃;

one or more sets of the adjacent two or more of R₁ to R₈ which do not represent a bond with L₁₃

form a substituted or unsubstituted single ring by bonding with each other,

form a substituted or unsubstituted fused ring by bonding with each other, or

do not bond with each other;

R₉, and R₁ to R₈ which do not represent a bond with L₁₃, which do not form the substituted or unsubstituted single ring and which do not form the substituted or unsubstituted fused ring are independently

a hydrogen atom,

a cyano group,

a substituted or unsubstituted alkyl group having 1 to 50 carbon atoms,

a substituted or unsubstituted halogenated alkyl group having 1 to 50 carbon atoms,

a substituted or unsubstituted cycloalkyl group having 3 to 50 ring carbon atoms,

a group represented by —Si(R_{901A})(R_{902A})(R_{903A}),

a group represented by —O—(R_{904A}),

a substituted or unsubstituted aryl group having 6 to 50 ring carbon atoms, or

a substituted or unsubstituted monovalent heterocyclic group having 5 to 50 ring atoms;

R_{901A} to R_{904A} are independently

a hydrogen atom,

a substituted or unsubstituted alkyl group having 1 to 50 carbon atoms,

a substituted or unsubstituted cycloalkyl group having 3 to 50 ring carbon atoms,

a substituted or unsubstituted aryl group having 6 to 50 ring carbon atoms, or

a substituted or unsubstituted monovalent heterocyclic group having 5 to 50 ring atoms;

when a plurality of each of R_{901A} to R_{904A} are present, the plurality of each of R_{901A} to R_{904A} may be the same as or different from each other;

n11 is an integer of 0 to 3; when n11 is 0, Ar₁₁ is directly bonded with the nitrogen atom of the amine via a single bond; when n11 is 2 or 3, a plurality of L₁₁'s is linked in series with each other and Ar₁₁ is bonded with L₁₁ which is farthest from the nitrogen atom of the amine; when two or more L₁₁'s are present, one or more sets of the adjacent two or more of the two or more L₁₁'s form a substituted or unsubstituted single ring by bonding with each other, form a substituted or unsubstituted fused ring by bonding with each other, or do not form the ring; when two or more L₁₁'s are present, the two or more L₁₁'s may be the same as or different from each other;

n12 is an integer of 0 to 3; when n12 is 0, Ar₁₂ is directly bonded with the nitrogen atom of the amine via a single bond; when n12 is 2 or 3, a plurality of L₁₂'s is linked in series with each other and Ar₁₂ is bonded with L₁₂ which is farthest from the nitrogen atom of the amine; when two or more L₁₂'s are present, one or more sets of the adjacent two or more of the two or more L₁₂'s form a substituted or unsubstituted single ring by bonding with each other, form a substituted or unsubstituted fused ring by bonding with each other, or do not form the ring; when two or more L₁₂'s are present, the two or more L₁₂'s may be the same as or different from each other;

n13 is an integer of 0 to 3; when n13 is 0, the carbon atom of the carbazole skeleton is directly bonded with the nitrogen atom of the amine via a single bond; when n13 is 2 or 3, a plurality of L₁₃'s is linked in series with each other and the carbazole skeleton is bonded with L₁₃ which is farthest from the nitrogen atom of the amine; when two or more L₁₃'s are present, one or more sets of the adjacent two or more of the two or more L₁₃'s form a substituted or unsubstituted single ring by bonding with each other, form a substituted or unsubstituted fused ring by bonding with each other, or do not form the ring; when two or more L₁₃'s are present, the two or more L₁₃'s may be the same as or different from each other;

L₁₁, L₁₂, and L₁₃ which do not form the ring are independently

a single bond,

a substituted or unsubstituted arylene group having 6 to 50 ring carbon atoms, or

a substituted or unsubstituted divalent heterocyclic group having 5 to 50 ring atoms;

in the formula (23),

Ar₂₁ and Ar₂₂ are independently

a substituted or unsubstituted aryl group having 6 to 50 ring carbon atoms,

a substituted or unsubstituted monovalent heterocyclic group having 5 to 50 ring atoms, or

—Si(R_{C1})(R_{C2})(R_{C3});

R_{C1} to R_{C3} are the same as defined in the formula (11);

L₂₁, L₂₂, and L₂₃ are independently

a single bond,

a substituted or unsubstituted arylene group having 6 to 50 ring carbon atoms, or

a substituted or unsubstituted divalent heterocyclic group having 5 to 50 ring atoms;

one or more sets of the adjacent two or more of R₂₁₁₁ to R₂₁₁₈ do not bond with each other;

R₂₁₁₁ to R₂₁₁₈ are independently a hydrogen atom, or a substituent R;

the substituent R is selected from the group consisting of

a substituted or unsubstituted alkyl group having 1 to 50 carbon atoms,

a substituted or unsubstituted alkenyl group having 2 to 50 carbon atoms,

a substituted or unsubstituted alkynyl group having 2 to 50 carbon atoms,

a substituted or unsubstituted cycloalkyl group having 3 to 50 ring carbon atoms,

—Si(R₉₀₁)(R₉₀₂)(R₉₀₃),

—O—(R₉₀₄),

—S—(R₉₀₅),

—N(R₉₀₅)(R₉₀₇)

(wherein R₉₀₁ to R₉₀₇ are independently

a hydrogen atom,

a substituted or unsubstituted alkyl group having 1 to 50 carbon atoms,

a substituted or unsubstituted cycloalkyl group having 3 to 50 ring carbon atoms,

a substituted or unsubstituted aryl group having 6 to 50 ring carbon atoms, or

a substituted or unsubstituted monovalent heterocyclic group having 5 to 50 ring atoms; when two or more of each of R₉₀₁ to R₉₀₇ are present, the two or more of each of R₉₀₁ to R₉₀₇ may be the same as or different from each other),

a halogen atom, a cyano group, a nitro group,

a substituted or unsubstituted aryl group having 6 to 50 ring carbon atoms, and

a substituted or unsubstituted monovalent heterocyclic group having 5 to 50 ring atoms; and

when two or more substituents R are present, the two or more substituents R may be the same as or different from each other.

3. An organic electroluminescence device comprising

a cathode,

an anode, and

one or two or more organic layers arranged between the cathode and the anode,

wherein at least one layer of the one or two or more organic layers

comprises a first compound and a second compound,

the first compound is a compound represented by the following formula (12),

the second compound is a compound represented by the following formula (21),

provided that the first compound is different from the second compound:

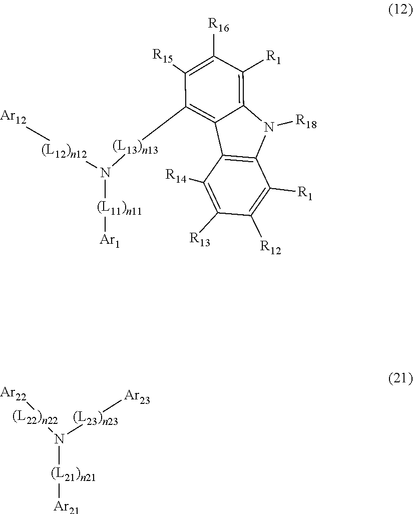

wherein in the formula (12),

Ar₁₁ and Ar₁₂ are independently

a substituted or unsubstituted aryl group having 6 to 50 ring carbon atoms,

a substituted or unsubstituted monovalent heterocyclic group having 5 to 50 ring atoms, or

—Si(R_{C1})(R_{C2})(R_{C3});

R_{C1} to R_{C3} are independently a substituted or unsubstituted aryl group having 6 to 50 ring carbon atoms,

when a plurality of each of R_{C1} to R_{C3} are present, the plurality of each of R_{C1} to R_{C3} may be the same as or different from each other;

n11 is an integer of 0 to 3; when n11 is 0, Ar₁₁ is directly bonded with the nitrogen atom of the amine via a single bond; when n11 is 2 or 3, a plurality of L₁₁'s is linked in series with each other and Ar₁₁ is bonded with L₁₁ which is farthest from the nitrogen atom of the amine; when two or more L₁₁'s are present, one or more sets of the adjacent two or more of the two or more L₁₁'s form a substituted or unsubstituted single ring by bonding with each other, form a substituted or unsubstituted fused ring by bonding with each other, or do not form the ring; when two or more L₁₁'s are present, the two or more L₁₁'s may be the same as or different from each other;

n12 is an integer of 0 to 3; when n12 is 0, Ar₁₂ is directly bonded with the nitrogen atom of the amine via a single bond; when n12 is 2 or 3, a plurality of L₁₂'s is linked in series with each other and Ar₁₂ is bonded with L₁₂ which is farthest from the nitrogen atom of the amine; when two or more L₁₂'s are present, one or more sets of the adjacent two or more of the two or more L₁₂'s form a substituted or unsubstituted single ring by bonding with each other, form a substituted or unsubstituted fused ring by bonding with each other, or do not form the ring; when two or more L₁₂'s are present, the two or more L₁₂'s may be the same as or different from each other;

n13 is an integer of 0 to 3; when n13 is 0, the carbon atom of the carbazole skeleton is directly bonded with the nitrogen atom of the amine via a single bond; when n13 is 2 or 3, a plurality of L₁₃'s is linked in series with each other and the carbazole skeleton is bonded with L₁₃ which is farthest from the nitrogen atom of the amine; when two or more L₁₃'s are present, one or more sets of the adjacent two or more of the two or more L₁₃'s form a substituted or unsubstituted single ring by bonding with each other, form a substituted or unsubstituted fused ring by bonding with each other, or do not form the ring; when two or more L₁₃'s are present, the two or more L₁₃'s may be the same as or different from each other;

L₁₁, L₁₂, and L₁₃ which do not form the ring are independently

a single bond,

a substituted or unsubstituted arylene group having 6 to 50 ring carbon atoms, or

a substituted or unsubstituted divalent heterocyclic group having 5 to 50 ring atoms;

one or more sets of the adjacent two or more of R₁₁ to R₁₇

form a substituted or unsubstituted single ring by bonding with each other,

form a substituted or unsubstituted fused ring by bonding with each other, or

do not bond with each other;

R₁₈, and R₁₁ to R₁₇ which do not form the substituted or unsubstituted single ring and which do not form the substituted or unsubstituted fused ring are independently

a hydrogen atom,

a cyano group,

a substituted or unsubstituted alkyl group having 1 to 50 carbon atoms,

a substituted or unsubstituted halogenated alkyl group having 1 to 50 carbon atoms,

a substituted or unsubstituted cycloalkyl group having 3 to 50 ring carbon atoms,

a group represented by —Si(R_{901A})(R_{902A})(R_{903A}),

a group represented by —O—(R_{904A}),

a substituted or unsubstituted aryl group having 6 to 50 ring carbon atoms, or

a substituted or unsubstituted monovalent heterocyclic group having 5 to 50 ring atoms;

R_{901A} to R_{904A} are independently

a hydrogen atom,

a substituted or unsubstituted alkyl group having 1 to 50 carbon atoms,

a substituted or unsubstituted cycloalkyl group having 3 to 50 ring carbon atoms,

a substituted or unsubstituted aryl group having 6 to 50 ring carbon atoms, or

a substituted or unsubstituted monovalent heterocyclic group having 5 to 50 ring atoms;

when a plurality of each of R_{901A} to R_{904A} are present, the plurality of each of R_{901A} to R_{904A} may be the same as or different from each other;

in the formula (21),

Ar₂₁, Ar₂₂, and Ar₂₃ are independently

a substituted or unsubstituted aryl group having 6 to 50 ring carbon atoms,

a substituted or unsubstituted monovalent heterocyclic group having 5 to 50 ring atoms, or

—Si(R_{C1})(R_{C2})(R_{C3});

R_{C1} to R_{C3} are the same as defined in the formula (12);

n21 is an integer of 0 to 3; when n21 is 0, Ar₂₁ is directly bonded with the nitrogen atom of the amine via a single bond; when n21 is 2 or 3, a plurality of L₂₁'s is linked in series with each other and Ar₂₁ is bonded with L₂₁ which is farthest from the nitrogen atom of the amine; when two or more L₂₁'s are present, one or more sets of the adjacent two or more of the two or more L₂₁'s form a substituted or unsubstituted single ring by bonding with each other, form a substituted or unsubstituted fused ring by bonding with each other, or do not form the ring; when two or more L₂₁'s are present, the two or more L₂₁'s may be the same as or different from each other;

n22 is an integer of 0 to 3; when n22 is 0, Ar₂₂ is directly bonded with the nitrogen atom of the amine via a single bond; when n22 is 2 or 3, a plurality of L₂₂'s is linked in series with each other and Ar₂₂ is bonded with L₂₂ which is farthest from the nitrogen atom of the amine; when two or more L₂₂'s are present, one or more sets of the adjacent two or more of the two or more L₂₂'s form a substituted or unsubstituted single ring by bonding with each other, form a substituted or unsubstituted fused ring by bonding with each other, or do not form the ring; when two or more L₂₂'s are present, the two or more L₂₂'s may be the same as or different from each other;

n23 is an integer of 0 to 3; when n23 is 0, Ar₂₃ is directly bonded with the nitrogen atom of the amine via a single bond; when n23 is 2 or 3, a plurality of L₂₃'s is linked in series with each other and Ar₂₃ is bonded with L₂₃ which is farthest from the nitrogen atom of the amine; when two or more L₂₃'s are present, one or more sets of the adjacent two or more of the two or more L₂₃'s form a substituted or unsubstituted single ring by bonding with each other, form a substituted or unsubstituted fused ring by bonding with each other, or do not form the ring; when two or more L₂₃'s are present, the two or more L₂₃'s may be the same as or different from each other; and

L₂₁, L₂₂, and L₂₃ which do not form the ring are independently

a single bond,

a substituted or unsubstituted arylene group having 6 to 50 ring carbon atoms, or

a substituted or unsubstituted divalent heterocyclic group having 5 to 50 ring atoms.

4. An organic electroluminescence device comprising

a cathode,

an anode, and

one or two or more organic layers arranged between the cathode and the anode,

wherein at least one layer of the one or two or more organic layers

comprises a first compound and a second compound,

the first compound is a compound represented by the following formula (11),

the second compound is a compound represented by the following formula (23),

provided that the first compound is different from the second compound:

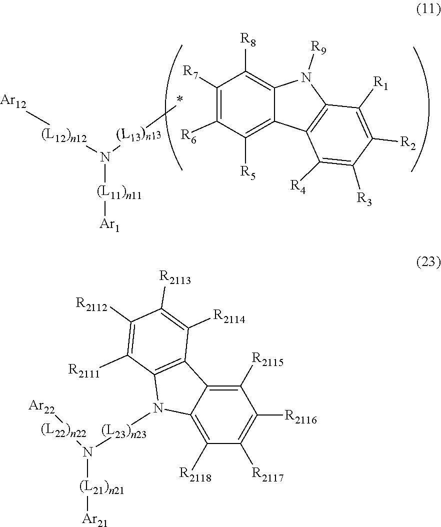

wherein in the formula (11),

Ar₁₁ and Ar₁₂ are independently

a substituted or unsubstituted aryl group having 6 to 50 ring carbon atoms,

a substituted or unsubstituted monovalent heterocyclic group having 5 to 50 ring atoms, or

—Si(R_{C1})(R_{C2})(R_{C3});

R_{C1} to R_{C3} are independently a substituted or unsubstituted aryl group having 6 to 50 ring carbon atoms,

when a plurality of each of R_{C1} to R_{C3} are present, the plurality of each of R_{C1} to R_{C3} may be the same as or different from each other;

any one of R₁ to R₈ represents a bond with L₁₃;

one or more sets of the adjacent two or more of R₁ to R₈ which do not represent a bond with L₁₃

form a substituted or unsubstituted single ring by bonding with each other,

form a substituted or unsubstituted fused ring by bonding with each other, or

do not bond with each other;

R₉, and R₁ to R₈ which do not represent a bond with L₁₃, which do not form the substituted or unsubstituted single ring and which do not form the substituted or unsubstituted fused ring are independently

a hydrogen atom,

a cyano group,

a substituted or unsubstituted alkyl group having 1 to 50 carbon atoms,

a substituted or unsubstituted halogenated alkyl group having 1 to 50 carbon atoms,

a substituted or unsubstituted cycloalkyl group having 3 to 50 ring carbon atoms,

a group represented by —Si(R_{901A})(R_{902A})(R_{903A}),

a group represented by —O—(R_{904A}),

a substituted or unsubstituted aryl group having 6 to 50 ring carbon atoms, or

a substituted or unsubstituted monovalent heterocyclic group having 5 to 50 ring atoms;

R_{901A} to R_{904A} are independently

a hydrogen atom,

a substituted or unsubstituted alkyl group having 1 to 50 carbon atoms,

a substituted or unsubstituted cycloalkyl group having 3 to 50 ring carbon atoms,

a substituted or unsubstituted aryl group having 6 to 50 ring carbon atoms, or

a substituted or unsubstituted monovalent heterocyclic group having 5 to 50 ring atoms;

when a plurality of each of R_{901A} to R_{904A} are present, the plurality of each of R_{901A} to R_{904A} may be the same as or different from each other;

n11 is an integer of 0 to 3; when n11 is 0, Ar₁₁ is directly bonded with the nitrogen atom of the amine via a single bond; when n11 is 2 or 3, a plurality of L₁₁'s is linked in series with each other and Ar₁₁ is bonded with L₁₁ which is farthest from the nitrogen atom of the amine; when two or more L₁₁'s are present, one or more sets of the adjacent two or more of the two or more L₁₁'s form a substituted or unsubstituted single ring by bonding with each other, form a substituted or unsubstituted fused ring by bonding with each other, or do not form the ring; when two or more L₁₁'s are present, the two or more L₁₁'s may be the same as or different from each other;

n12 is an integer of 0 to 3; when n12 is 0, Ar₁₂ is directly bonded with the nitrogen atom of the amine via a single bond; when n12 is 2 or 3, a plurality of L₁₂'s is linked in series with each other and Ar₁₂ is bonded with L₁₂ which is farthest from the nitrogen atom of the amine; when two or more L₁₂'s are present, one or more sets of the adjacent two or more of the two or more L₁₂'s form a substituted or unsubstituted single ring by bonding with each other, form a substituted or unsubstituted fused ring by bonding with each other, or do not form the ring; when two or more L₁₂'s are present, the two or more L₁₂'s may be the same as or different from each other;

n13 is an integer of 0 to 3; when n13 is 0, the carbon atom of the carbazole skeleton is directly bonded with the nitrogen atom of the amine via a single bond; when n13 is 2 or 3, a plurality of L₁₃'s is linked in series with each other and the carbazole skeleton is bonded with L₁₃ which is farthest from the nitrogen atom of the amine; when two or more L₁₃'s are present, one or more sets of the adjacent two or more of the two or more L₁₃'s form a substituted or unsubstituted single ring by bonding with each other, form a substituted or unsubstituted fused ring by bonding with each other, or do not form the ring; when two or more L₁₃'s are present, the two or more L₁₃'s may be the same as or different from each other;

L₁₁, L₁₂, and L₁₃ which do not form the ring are independently

a single bond,

a substituted or unsubstituted arylene group having 6 to 50 ring carbon atoms, or

a substituted or unsubstituted divalent heterocyclic group having 5 to 50 ring atoms;

in the formula (23),

Ar₂₁ and Ar₂₂ are independently

a substituted or unsubstituted aryl group having 6 to 50 ring carbon atoms,

a substituted or unsubstituted monovalent heterocyclic group having 5 to 50 ring atoms, or

—Si(R_{C1})(R_{C2})(R_{C3});

R_{C1} to R_{C3} are the same as defined in the formula (11);

L₂₁, L₂₂, and L₂₃ are independently

a single bond,

a substituted or unsubstituted arylene group having 6 to 50 ring carbon atoms, or

a substituted or unsubstituted divalent heterocyclic group having 5 to 50 ring atoms;

one or more sets of the adjacent two or more of R₂₁₁₁ to R₂₁₁₈ do not bond with each other;

R₂₁₁₁ to R₂₁₁₈ are independently a hydrogen atom, or a substituent R;

the substituent R is selected from the group consisting of

a substituted or unsubstituted alkyl group having 1 to 50 carbon atoms,

a substituted or unsubstituted alkenyl group having 2 to 50 carbon atoms,

a substituted or unsubstituted alkynyl group having 2 to 50 carbon atoms,

a substituted or unsubstituted cycloalkyl group having 3 to 50 ring carbon atoms,

—Si(R₉₀₁)(R₉₀₂)(R₉₀₃),

—O—(R₉₀₄),

—S—(R₉₀₅),

—N(R₉₀₅)(R₉₀₇)

(wherein R₉₀₁ to R₉₀₇ are independently

a hydrogen atom,

a substituted or unsubstituted alkyl group having 1 to 50 carbon atoms,

a substituted or unsubstituted cycloalkyl group having 3 to 50 ring carbon atoms,

a substituted or unsubstituted aryl group having 6 to 50 ring carbon atoms, or

a substituted or unsubstituted monovalent heterocyclic group having 5 to 50 ring atoms; when two or more of each of R₉₀₁ to R₉₀₇ are present, the two or more of each of R₉₀₁ to R₉₀₇ may be the same as or different from each other),

a halogen atom, a cyano group, a nitro group,

a substituted or unsubstituted aryl group having 6 to 50 ring carbon atoms, and

a substituted or unsubstituted monovalent heterocyclic group having 5 to 50 ring atoms; and

when two or more substituents R are present, the two or more substituents R may be the same as or different from each other.

5. An electronic apparatus, comprising the organic electroluminescence device according to 3 or 4.
6. A method for fabricating an organic electroluminescence device, comprising: forming a film on a substrate by depositing the first compound and the second compound in the same deposition source or different deposition sources to fabricate the organic electroluminescence device according to 3 or 4.

According to the present invention, there can be provided a composition capable of achieving an organic EL device having high performance, and an organic EL device having the performance.

### BRIEF DESCRIPTION OF THE DRAWINGS

The FIGURE is a diagram showing a schematic configuration of an organic EL device according to one embodiment of the present invention.

### MODE FOR CARRYING OUT THE INVENTION

### Definition

In this specification, a hydrogen atom includes its isotopes different in the number of neutrons, namely, a protium, a deuterium and a tritium.

In this specification, at a bondable position in a chemical formula where a symbol such as “R”, or “D” representing a deuterium atom is not indicated, a hydrogen atom, that is, a protium atom, a deuterium atom or a tritium atom is bonded.

In this specification, the number of ring carbon atoms represents the number of carbon atoms forming a subject ring itself among the carbon atoms of a compound having a structure in which atoms are bonded in a ring form (for example, a monocyclic compound, a fused ring compound, a cross-linked compound, a carbocyclic compound, or a heterocyclic compound). When the subject ring is substituted by a substituent, the carbon contained in the substituent is not included in the number of ring carbon atoms. The same shall apply to “the number of ring carbon atoms” described below, unless otherwise specified. For example, a benzene ring has 6 ring carbon atoms, a naphthalene ring includes 10 ring carbon atoms, a pyridine ring includes 5 ring carbon atoms, and a furan ring includes 4 ring carbon atoms. Further, for example, a 9,9-diphenylfluorenyl group includes 13 ring carbon atoms, and a 9,9′-spirobifluorenyl group includes 25 ring carbon atoms.

When a benzene ring is substituted by, for example, an alkyl group as a substituent, the number of carbon atoms of the alkyl group is not included in the number of ring carbon atoms of the benzene ring. Therefore, the number of ring carbon atoms of the benzene ring substituted by the alkyl group is 6. When a naphthalene ring is substituted by, for example, an alkyl group as a substituent, the number of carbon atoms of the alkyl group is not included in the number of ring carbon atoms of the naphthalene ring. Therefore, the number of ring carbon atoms of the naphthalene ring substituted by the alkyl group is 10.

In this specification, the number of ring atoms represents the number of atoms forming a subject ring itself among the atoms of a compound having a structure in which atoms are bonded in a ring form (for example, the structure includes a monocyclic ring, a fused ring and a ring assembly) (for example, a monocyclic compound, a fused ring compound, a cross-linked compound, a carbocyclic compound and a heterocyclic compound). The number of ring atoms does not include atoms which do not form the ring (for example, a hydrogen atom which terminates a bond of the atoms forming the ring), or atoms contained in a substituent when the ring is substituted by the substituent. The same shall apply to “the number of ring atoms” described below, unless otherwise specified. For example, the number of atoms of a pyridine ring is 6, the number of atoms of a quinazoline ring is 10, and the number of a furan ring is 5. For example, hydrogen atoms bonded to a pyridine ring and atoms constituting a substituent substituted on the pyridine ring are not included in the number of ring atoms of the pyridine ring. Therefore, the number of ring atoms of a pyridine ring with which a hydrogen atom or a substituent is bonded is 6. For example, hydrogen atoms and atoms constituting a substituent which are bonded with a quinazoline ring is not included in the number of ring atoms of the quinazoline ring. Therefore, the number of ring atoms of a quinazoline ring with which a hydrogen atom or a substituent is bonded is 10.

In this specification, “XX to YY carbon atoms” in the expression “a substituted or unsubstituted ZZ group including XX to YY carbon atoms” represents the number of carbon atoms in the case where the ZZ group is unsubstituted by a substituent, and does not include the number of carbon atoms of a substituent in the case where the ZZ group is substituted by the substituent. Here, “YY” is larger than “XX”, and “XX” means an integer of 1 or more and “YY” means an integer of 2 or more.

In this specification, “XX to YY atoms” in the expression “a substituted or unsubstituted ZZ group including XX to YY atoms” represents the number of atoms in the case where the ZZ group is unsubstituted by a substituent, and does not include the number of atoms of a substituent in the case where the ZZ group is substituted by the substituent. Here, “YY” is larger than “XX”, and “XX” means an integer of 1 or more and “YY” means an integer of 2 or more.

In this specification, the unsubstituted ZZ group represents the case where the “substituted or unsubstituted ZZ group” is a “ZZ group unsubstituted by a substituent”, and the substituted ZZ group represents the case where the “substituted or unsubstituted ZZ group” is a “ZZ group substituted by a substituent”.

In this specification, a term “unsubstituted” in the case of “a substituted or unsubstituted ZZ group” means that hydrogen atoms in the ZZ group are not substituted by a substituent. Hydrogen atoms in a term “unsubstituted ZZ group” are a protium atom, a deuterium atom, or a tritium atom.

In this specification, a term “substituted” in the case of “a substituted or unsubstituted ZZ group” means that one or more hydrogen atoms in the ZZ group are substituted by a substituent. Similarly, a term “substituted” in the case of “a BB group substituted by an AA group” means that one or more hydrogen atoms in the BB group are substituted by the AA group.

“Substituent as Described in this Specification”

Hereinafter, the substituent described in this specification will be explained.

The number of ring carbon atoms of the “unsubstituted aryl group” described in this specification is 6 to 50, preferably 6 to 30, and more preferably 6 to 18, unless otherwise specified.

The number of ring atoms of the “unsubstituted heterocyclic group” described in this specification is 5 to 50, preferably 5 to 30, and more preferably 5 to 18, unless otherwise specified.

The number of carbon atoms of the “unsubstituted alkyl group” described in this specification is 1 to 50, preferably 1 to 20, and more preferably 1 to 6, unless otherwise specified.

The number of carbon atoms of the “unsubstituted alkenyl group” described in this specification is 2 to 50, preferably 2 to 20, and more preferably 2 to 6, unless otherwise specified.

The number of carbon atoms of the “unsubstituted alkynyl group” described in this specification is 2 to 50, preferably 2 to 20, and more preferably 2 to 6, unless otherwise specified.

The number of ring carbon atoms of the “unsubstituted cycloalkyl group” described in this specification is 3 to 50, preferably 3 to 20, and more preferably 3 to 6, unless otherwise specified.

The number of ring carbon atoms of the “unsubstituted arylene group” described in this specification is 6 to 50, preferably 6 to 30, and more preferably 6 to 18, unless otherwise specified.

The number of ring atoms of the “unsubstituted divalent heterocyclic group” described in this specification is 5 to 50, preferably 5 to 30, and more preferably 5 to 18, unless otherwise specified.

The number of carbon atoms of the “unsubstituted alkylene group” described in this specification is 1 to 50, preferably 1 to 20, and more preferably 1 to 6, unless otherwise specified.

### “Substituted or Unsubstituted Aryl Group”

Specific examples of the “substituted or unsubstituted aryl group” described in this specification (specific example group G1) include the following unsubstituted aryl groups (specific example group G1A), substituted aryl groups (specific example group G1B), and the like. (Here, the unsubstituted aryl group refers to the case where the “substituted or unsubstituted aryl group” is an “aryl group unsubstituted by a substituent”, and the substituted aryl group refers to the case where the “substituted or unsubstituted aryl group” is an “aryl group substituted by a substituent”). In this specification, in the case where simply referred as an “aryl group”, it includes both a “unsubstituted aryl group” and a “substituted aryl group.”

The “substituted aryl group” means a group in which one or more hydrogen atoms of the “unsubstituted aryl group” are substituted by a substituent. Specific examples of the “substituted aryl group” include, for example, groups in which one or more hydrogen atoms of the “unsubstituted aryl group” of the following specific example group G1A are substituted by a substituent, the substituted aryl groups of the following specific example group G1B, and the like. It should be noted that the examples of the “unsubstituted aryl group” and the examples of the “substituted aryl group” enumerated in this specification are mere examples, and the “substituted aryl group” described in this specification also includes a group in which a hydrogen atom bonded with a carbon atom of the aryl group itself in the “substituted aryl group” of the following specific group G1B is further substituted by a substituent, and a group in which a hydrogen atom of a substituent in the “substituted aryl group” of the following specific group G1B is further substituted by a substituent.

### Unsubstituted Aryl Group (Specific Example Group G1A):

a phenyl group,

a p-biphenyl group,

a m-biphenyl group,

an o-biphenyl group,

a p-terphenyl-4-yl group,

a p-terphenyl-3-yl group,

a p-terphenyl-2-yl group,

a m-terphenyl-4-yl group,

a m-terphenyl-3-yl group,

a m-terphenyl-2-yl group,

an o-terphenyl-4-yl group,

an o-terphenyl-3-yl group,

an o-terphenyl-2-yl group,

a 1-naphthyl group,

a 2-naphthyl group,

an anthryl group,

a benzanthryl group,

a phenanthryl group,

a benzophenanthryl group,

a phenalenyl group,

a pyrenyl group,

a chrysenyl group,

a benzochrysenyl group,

a triphenylenyl group,

a benzotriphenylenyl group,

a tetracenyl group,

a pentacenyl group,

a fluorenyl group,

a 9,9′-spirobifluorenyl group,

a benzofluorenyl group,

a dibenzofluorenyl group,

a fluoranthenyl group,

a benzofluoranthenyl group,

a perylenyl group, and

a monovalent aryl group derived by removing one hydrogen atom from the ring structures represented by any of the following general formulas (TEMP-1) to (TEMP-15).

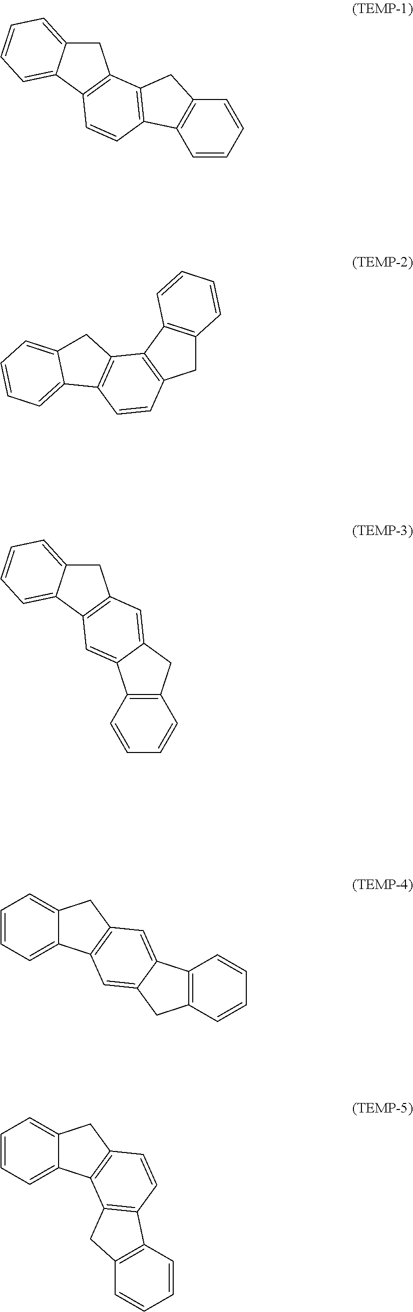

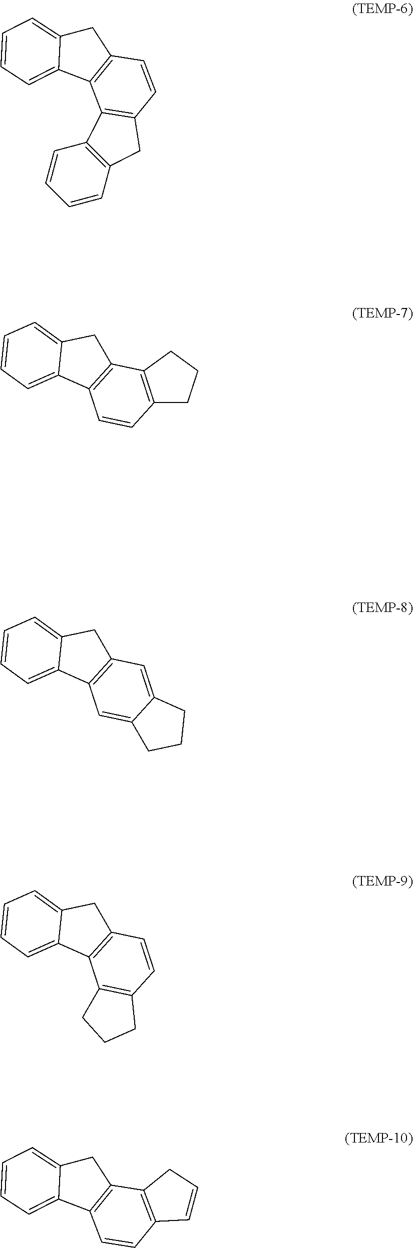

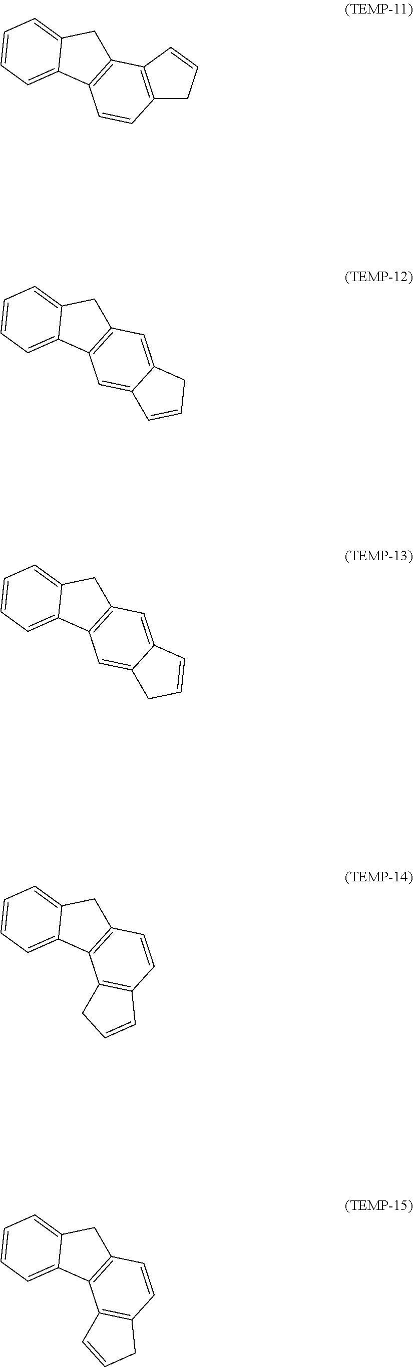

### Substituted Aryl Group (Specific Example Group G1B):

an o-tolyl group,

a m-tolyl group,

a p-tolyl group,

a p-xylyl group,

a m-xylyl group,

an o-xylyl group,

a p-isopropylphenyl group,

a m-isopropylphenyl group,

an o-isopropylphenyl group,

a p-t-butylphenyl group,

a m-t-butylphenyl group,

an o-t-butylphenyl group,

a 3,4,5-trimethylphenyl group,

a 9,9-dimethylfluorenyl group,

a 9,9-diphenylfluorenyl group,

a 9,9-bis(4-methylphenyl)fluorenyl group,

a 9,9-bis(4-isopropylphenyl)fluorenyl group,

a 9,9-bis(4-t-butylphenyl)fluorenyl group,

a cyanophenyl group,

a triphenylsilylphenyl group,

a trimethylsilylphenyl group,

a phenylnaphthyl group,

a naphthylphenyl group, and

a group in which one or more hydrogen atoms of a monovalent group derived from the ring structures represented by any of the general formulas (TEMP-1) to (TEMP-15) are substituted by a substituent.

### “Substituted or Unsubstituted Heterocyclic Group”

The “heterocyclic group” described in this specification is a ring group having at least one hetero atom in the ring atom. Specific examples of the hetero atom include a nitrogen atom, an oxygen atom, a sulfur atom, a silicon atom, a phosphorus atom, and a boron atom.

The “heterocyclic group” in this specification is a monocyclic group or a fused ring group.

The “heterocyclic group” in this specification is an aromatic heterocyclic group or a non-aromatic heterocyclic group.

Specific examples of the “substituted or unsubstituted heterocyclic group” (specific example group G2) described in this specification include the following unsubstituted heterocyclic group (specific example group G2A), the following substituted heterocyclic group (specific example group G2B), and the like. (Here, the unsubstituted heterocyclic group refers to the case where the “substituted or unsubstituted heterocyclic group” is a “heterocyclic group unsubstituted by a substituent”, and the substituted heterocyclic group refers to the case where the “substituted or unsubstituted heterocyclic group” is a “heterocyclic group substituted by a substituent”). In this specification, in the case where simply referred as a “heterocyclic group”, it includes both the “unsubstituted heterocyclic group” and the “substituted heterocyclic group.”

The “substituted heterocyclic group” means a group in which one or more hydrogen atom of the “unsubstituted heterocyclic group” are substituted by a substituent. Specific examples of the “substituted heterocyclic group” include a group in which a hydrogen atom of “unsubstituted heterocyclic group” of the following specific example group G2A is substituted by a substituent, the substituted heterocyclic groups of the following specific example group G2B, and the like. It should be noted that the examples of the “unsubstituted heterocyclic group” and the examples of the “substituted heterocyclic group” enumerated in this specification are mere examples, and the “substituted heterocyclic group” described in this specification includes groups in which hydrogen atom bonded with a ring atom of the heterocyclic group itself in the “substituted heterocyclic group” of the specific example group G2B is further substituted by a substituent, and a group in which hydrogen atom of a substituent in the “substituted heterocyclic group” of the specific example group G2B is further substituted by a substituent.

Specific example group G2A includes, for example, the following unsubstituted heterocyclic group containing a nitrogen atom (specific example group G2A1), the following unsubstituted heterocyclic group containing an oxygen atom (specific example group G2A2), the following unsubstituted heterocyclic group containing a sulfur atom (specific example group G2A3), and the monovalent heterocyclic group derived by removing one hydrogen atom from the ring structures represented by any of the following general formulas (TEMP-16) to (TEMP-33) (specific example group G2A4).

Specific example group G2B includes, for example, the following substituted heterocyclic group containing a nitrogen atom (specific example group G2B1), the following substituted heterocyclic group containing an oxygen atom (specific example group G2B2), the following substituted heterocyclic group containing a sulfur atom (specific example group G2B3), and the following group in which one or more hydrogen atoms of the monovalent heterocyclic group derived from the ring structures represented by any of the following general formulas (TEMP-16) to (TEMP-33) are substituted by a substituent (specific example group G2B4).

### Unsubstituted Heterocyclic Group Containing a Nitrogen Atom (Specific Example Group G2A1):

a pyrrolyl group,

an imidazolyl group,

a pyrazolyl group,

a triazolyl group,

a tetrazolyl group,

an oxazolyl group,

an isoxazolyl group,

an oxadiazolyl group,

a thiazolyl group,

an isothiazolyl group,

a thiadiazolyl group,

a pyridyl group,

a pyridazinyl group,

a pyrimidinyl group,

a pyrazinyl group,

a triazinyl group,

an indolyl group,

an isoindolyl group,

an indolizinyl group,

a quinolizinyl group,

a quinolyl group,

an isoquinolyl group,

a cinnolyl group,

a phthalazinyl group,

a quinazolinyl group,

a quinoxalinyl group,

a benzimidazolyl group,

an indazolyl group,

a phenanthrolinyl group,

a phenanthridinyl group,

an acridinyl group,

a phenazinyl group,

a carbazolyl group,

a benzocarbazolyl group,

a morpholino group,

a phenoxazinyl group,

a phenothiazinyl group,

an azacarbazolyl group, and

a diazacarbazolyl group.

### Unsubstituted Heterocyclic Group Containing an Oxygen Atom (Specific Example Group G2A2):

a furyl group,

an oxazolyl group,

an isoxazolyl group,

an oxadiazolyl group,

a xanthenyl group,

a benzofuranyl group,

an isobenzofuranyl group,

a dibenzofuranyl group,

a naphthobenzofuranyl group,

a benzoxazolyl group,

a benzisoxazolyl group,

a phenoxazinyl group,

a morpholino group,

a dinaphthofuranyl group,

an azadibenzofuranyl group,

a diazadibenzofuranyl group,

an azanaphthobenzofuranyl group, and

a diazanaphthobenzofuranyl group.

### Unsubstituted Heterocyclic Group Containing a Sulfur Atom (Specific Example Group G2A3):

a thienyl group,

a thiazolyl group,

an isothiazolyl group,

a thiadiazolyl group,

a benzothiophenyl group (benzothienyl group),

an isobenzothiophenyl group (isobenzothienyl group),

a dibenzothiophenyl group (dibenzothienyl group),

a naphthobenzothiophenyl group (naphthobenzothienyl group),

a benzothiazolyl group,

a benzisothiazolyl group,

a phenothiazinyl group,

a dinaphthothiophenyl group (dinaphthothienyl group),

an azadibenzothiophenyl group (azadibenzothienyl group),

a diazadibenzothiophenyl group (diazadibenzothienyl group),

an azanaphthobenzothiophenyl group (azanaphthobenzothienyl group), and

a diazanaphthobenzothiophenyl group (diazanaphthobenzothienyl group).

Monovalent Heterocyclic Group Derived by Removing One Hydrogen Atom from the Ring Structures Represented by any of the Following General Formulas (TEMP-16) to (TEMP-33) (Specific Example Group G2A4):

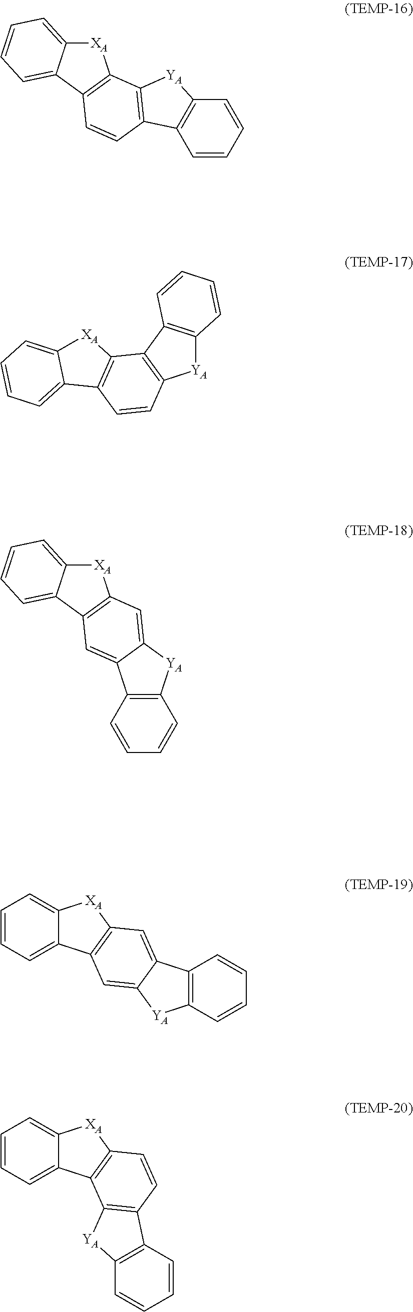

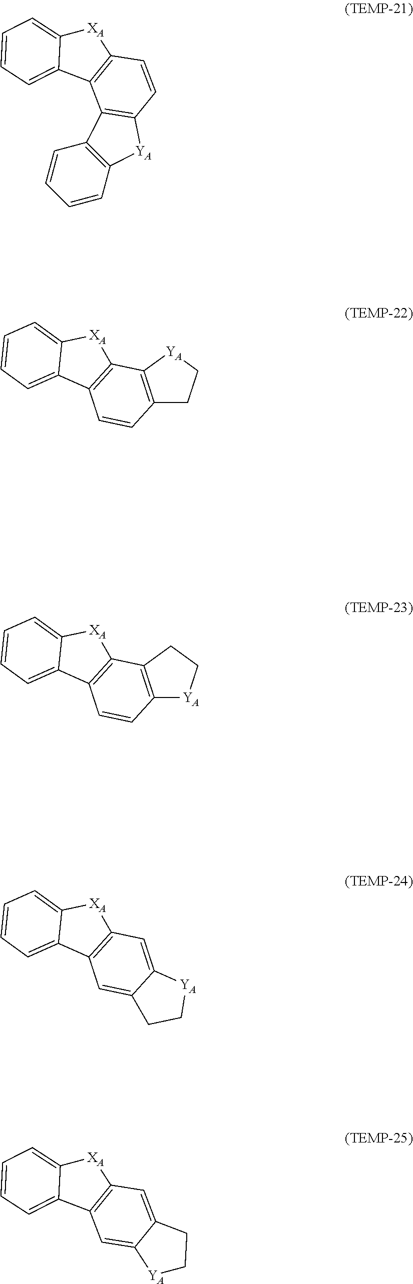

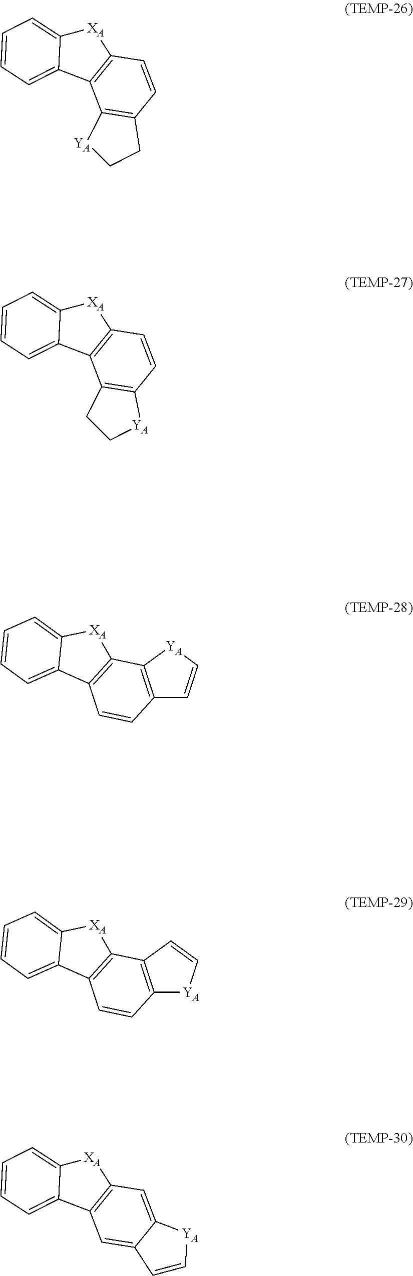

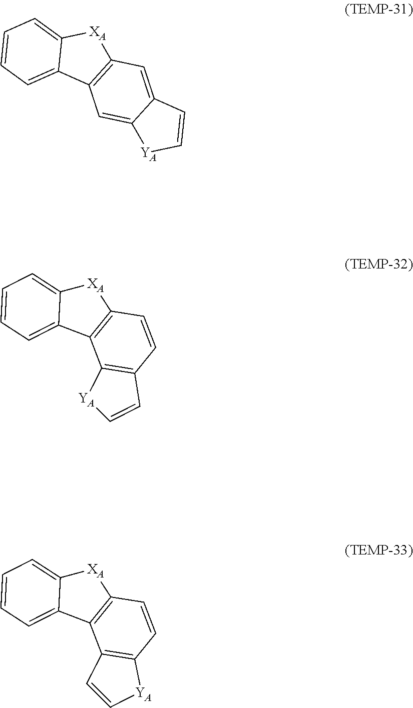

In the general formulas (TEMP-16) to (TEMP-33), X_{A} and Y_{A} are independently an oxygen atom, a sulfur atom, NH, or CH₂. Provided that at least one of X_{A} and Y_{A} is an oxygen atom, a sulfur atom, or NH.

In the general formulas (TEMP-16) to (TEMP-33), when at least one of X_{A} and Y_{A} is NH or CH₂, the monovalent heterocyclic group derived from the ring structures represented by any of the general formulas (TEMP-16) to (TEMP-33) includes a monovalent group derived by removing one hydrogen atom from these NH or CH₂.

### Substituted Heterocyclic Group Containing a Nitrogen Atom (Specific Example Group G2B1):

a (9-phenyl)carbazolyl group,

a (9-biphenylyl)carbazolyl group,

a (9-phenyl)phenylcarbazolyl group,

a (9-naphthyl)carbazolyl group,

a diphenylcarbazol-9-yl group,

a phenylcarbazol-9-yl group,

a methylbenzimidazolyl group,

an ethylbenzimidazolyl group,

a phenyltriazinyl group,

a biphenylyltriazinyl group,

a diphenyltriazinyl group,

a phenylquinazolinyl group, and

a biphenylylquinazolinyl group.

### Substituted Heterocyclic Group Containing an Oxygen Atom (Specific Example Group G2B2):

a phenyldibenzofuranyl group,

a methyldibenzofuranyl group,

a t-butyldibenzofuranyl group, and

a monovalent residue of spiro[9H-xanthene-9,9′-[9H]fluorene].

### Substituted Heterocyclic Group Containing a Sulfur Atom (Specific Example Group G2B3):

a phenyldibenzothiophenyl group,

a methyldibenzothiophenyl group,

a t-butyldibenzothiophenyl group, and

a monovalent residue of spiro[9H-thioxanthene-9,9′-[9H]fluorene].

Group in which One or More Hydrogen Atoms of the Monovalent Heterocyclic Group Derived from the Ring Structures Represented by any of the Following General Formulas (TEMP-16) to (TEMP-33) are Substituted by a Substituent (Specific Example Group G2B4):

The “one or more hydrogen atoms of the monovalent heterocyclic group” means one or more hydrogen atoms selected from hydrogen atoms bonded with ring carbon atoms of the monovalent heterocyclic group, a hydrogen atom bonded with a nitrogen atom when at least one of X_{A} and Y_{A} is NH, and hydrogen atoms of a methylene group when one of X_{A} and Y_{A} is CH₂.

### “Substituted or Unsubstituted Alkyl Group”

Specific examples of the “substituted or unsubstituted alkyl group” (specific example group G3) described in this specification include the following unsubstituted alkyl groups (specific example group G3A) and the following substituted alkyl groups (specific example group G3B). (Here, the unsubstituted alkyl group refers to the case where the “substituted or unsubstituted alkyl group” is an “alkyl group unsubstituted by a substituent”, and the substituted alkyl group refers to the case where the “substituted or unsubstituted alkyl group” is an “alkyl group substituted by a substituent”). In this specification, in the case where simply referred as an “alkyl group” includes both the “unsubstituted alkyl group” and the “substituted alkyl group.”

The “substituted alkyl group” means a group in which one or more hydrogen atoms in the “unsubstituted alkyl group” are substituted by a substituent. Specific examples of the “substituted alkyl group” include groups in which one or more hydrogen atoms in the following “unsubstituted alkyl group” (specific example group G3A) are substituted by a substituent, the following substituted alkyl group (specific example group G3B), and the like. In this specification, the alkyl group in the “unsubstituted alkyl group” means a linear alkyl group. Thus, the “unsubstituted alkyl group” includes a straight-chain “unsubstituted alkyl group” and a branched-chain “unsubstituted alkyl group”. It should be noted that the examples of the “unsubstituted alkyl group” and the examples of the “substituted alkyl group” enumerated in this specification are mere examples, and the “substituted alkyl group” described in this specification includes a group in which hydrogen atom of the alkyl group itself in the “substituted alkyl group” of the specific example group G3B is further substituted by a substituent, and a group in which hydrogen atom of a substituent in the “substituted alkyl group” of the specific example group G3B is further substituted by a substituent.

### Unsubstituted Alkyl Group (Specific Example Group G3A):

a methyl group,

an ethyl group,

a n-propyl group,

an isopropyl group,

a n-butyl group,

an isobutyl group,

a s-butyl group, and

a t-butyl group.

### Substituted Alkyl Group (Specific Example Group G3B):

a heptafluoropropyl group (including isomers),

a pentafluoroethyl group,

a 2,2,2-trifluoroethyl group, and

a trifluoromethyl group.

### “Substituted or Unsubstituted Alkenyl Group”

Specific examples of the “substituted or unsubstituted alkenyl group” described in this specification (specific example group G4) include the following unsubstituted alkenyl group (specific example group G4A), the following substituted alkenyl group (specific example group G4B), and the like. (Here, the unsubstituted alkenyl group refers to the case where the “substituted or unsubstituted alkenyl group” is a “alkenyl group unsubstituted by a substituent”, and the “substituted alkenyl group” refers to the case where the “substituted or unsubstituted alkenyl group” is a “alkenyl group substituted by a substituent.”). In this specification, in the case where simply referred as an “alkenyl group” includes both the “unsubstituted alkenyl group” and the “substituted alkenyl group.”

The “substituted alkenyl group” means a group in which one or more hydrogen atoms in the “unsubstituted alkenyl group” are substituted by a substituent. Specific examples of the “substituted alkenyl group” include a group in which the following “unsubstituted alkenyl group” (specific example group G4A) has a substituent, the following substituted alkenyl group (specific example group G4B), and the like. It should be noted that the examples of the “unsubstituted alkenyl group” and the examples of the “substituted alkenyl group” enumerated in this specification are mere examples, and the “substituted alkenyl group” described in this specification includes a group in which a hydrogen atom of the alkenyl group itself in the “substituted alkenyl group” of the specific example group G4B is further substituted by a substituent, and a group in which a hydrogen atom of a substituent in the “substituted alkenyl group” of the specific example group G4B is further substituted by a substituent.

### Unsubstituted Alkenyl Group (Specific Example Group G4A):

a vinyl group,

an allyl group,

a 1-butenyl group,

a 2-butenyl group, and

a 3-butenyl group.

### Substituted Alkenyl Group (Specific Example Group G4B):

a 1,3-butanedienyl group,

a 1-methylvinyl group,

a 1-methylallyl group,

a 1,1-dimethylallyl group,

a 2-methylally group, and

a 1,2-dimethylallyl group.

### “Substituted or Unsubstituted Alkynyl Group”

Specific examples of the “substituted or unsubstituted alkynyl group” described in this specification (specific example group G5) include the following unsubstituted alkynyl group (specific example group G5A) and the like. (Here, the unsubstituted alkynyl group refers to the case where the “substituted or unsubstituted alkynyl group” is an “alkynyl group unsubstituted by a substituent”). In this specification, in the case where simply referred as an “alkynyl group” includes both the “unsubstituted alkynyl group” and the “substituted alkynyl group.”

The “substituted alkynyl group” means a group in which one or more hydrogen atoms in the “unsubstituted alkynyl group” are substituted by a substituent. Specific examples of the “substituted alkynyl group” include a group in which one or more hydrogen atoms in the following “unsubstituted alkynyl group” (specific example group G5A) are substituted by a substituent, and the like.

### Unsubstituted Alkynyl Group (Specific Example Group G5A):

an ethynyl group.

### “Substituted or Unsubstituted Cycloalkyl Group”

Specific examples of the “substituted or unsubstituted cycloalkyl group” described in this specification (specific example group G6) include the following unsubstituted cycloalkyl group (specific example group G6A), the following substituted cycloalkyl group (specific example group G6B), and the like. (Here, the unsubstituted cycloalkyl group refers to the case where the “substituted or unsubstituted cycloalkyl group” is a “cycloalkyl group unsubstituted by a substituent”, and the substituted cycloalkyl group refers to the case where the “substituted or unsubstituted cycloalkyl group” is a “cycloalkyl group substituted by a substituent”). In this specification, in the case where simply referred as a “cycloalkyl group” includes both the “unsubstituted cycloalkyl group” and the “substituted cycloalkyl group.”

The “substituted cycloalkyl group” means a group in which one or more hydrogen atoms in the “unsubstituted cycloalkyl group” are substituted by a substituent. Specific examples of the “substituted cycloalkyl group” include a group in which one or more hydrogen atoms in the following “unsubstituted cycloalkyl group” (specific example group G6A) are substituted by a substituent, and examples of the following substituted cycloalkyl group (specific example group G6B), and the like. It should be noted that the examples of the “unsubstituted cycloalkyl group” and the examples of the “substituted cycloalkyl group” enumerated in this specification are mere examples, and the “substituted cycloalkyl group” in this specification includes a group in which one or more hydrogen atoms bonded with the carbon atom of the cycloalkyl group itself in the “substituted cycloalkyl group” of the specific example group G6B are substituted by a substituent, and a group in which a hydrogen atom of a substituent in the “substituted cycloalkyl group” of specific example group G6B is further substituted by a substituent.

### Unsubstituted Cycloalkyl Group (Specific Example Group G6A):

a cyclopropyl group,

a cyclobutyl group,

a cyclopentyl group,

a cyclohexyl group,

a 1-adamantyl group,

a 2-adamantyl group,

a 1-norbornyl group, and

a 2-norbornyl group.

### Substituted Cycloalkyl Group (Specific Example Group G6B):

a 4-methylcyclohexyl group.

“Group Represented by —Si(R₉₀₁)(R₉₀₂)(R₉₀₃)”

Specific examples of the group represented by —Si(R₉₀₁)(R₉₀₂)(R₉₀₃) described in this specification (specific example group G7) include:

—Si(G1)(G1)(G1),

—Si(G1)(G2)(G2),

—Si(G1)(G1)(G2),

—Si(G2)(G2)(G2),

—Si(G3)(G3)(G3), and

—Si(G6)(G6)(G6).

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

Plural G1's in —Si(G1)(G1)(G1) are the same or different.

Plural G2's in —Si(G1)(G2)(G2) are the same or different.

Plural G1's in —Si(G1)(G1)(G2) are the same or different.

Plural G2's in —Si(G2)(G2)(G2) are be the same or different.

Plural G3's in —Si(G3)(G3)(G3) are the same or different.

Plural G6's in —Si(G6)(G6)(G6) are be the same or different.

### “Group Represented by —O—(R₉₀₄)”

Specific examples of the group represented by —O—(R₉₀₄) in this specification (specific example group G8) include:

—O(G1),

—O(G2),

—O(G3), and

—O(G6).

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

“Group represented by —S—(R₉₀₅)”

Specific examples of the group represented by —S—(R₉₀₅) in this specification (specific example group G9) include:

—S(G1),

—S(G2),

—S(G3), and

—S(G6).

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

“Group represented by —N(R₉₀₆)(R₉₀₇)”

Specific examples of the group represented by —N(R₉₀₆)(R₉₀₇) in this specification (specific example group G10) include:

—N(G1)(G1),

—N(G2)(G2),

—N(G1)(G2),

—N(G3)(G3), and

—N(G6)(G6).

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

Plural G1's in —N(G1)(G1) are the same or different.

Plural G2's in —N(G2)(G2) are the same or different.

Plural G3's in —N(G3)(G3) are the same or different.

Plural G6's in —N(G6)(G6) are the same or different.

### “Halogen Atom”

Specific examples of the “halogen atom” described in this specification (specific example group G11) include a fluorine atom, a chlorine atom, a bromine atom, an iodine atom, and the like.

### “Substituted or Unsubstituted Fluoroalkyl Group”

The “substituted or unsubstituted fluoroalkyl group” described in this specification is a group in which at least one hydrogen atom bonded with a carbon atom constituting the alkyl group in the “substituted or unsubstituted alkyl group” is substituted by a fluorine atom, and includes a group in which all hydrogen atoms bonded with a carbon atom constituting the alkyl group in the “substituted or unsubstituted alkyl group” are substituted by a fluorine atom (a perfluoro group). The number of carbon atoms of the “unsubstituted fluoroalkyl group” is 1 to 50, preferably 1 to 30, more preferably 1 to 18, unless otherwise specified in this specification. The “substituted fluoroalkyl group” means a group in which one or more hydrogen atoms of the “fluoroalkyl group” are substituted by a substituent. The “substituted fluoroalkyl group” described in this specification also includes a group in which one or more hydrogen atoms bonded with a carbon atom of the alkyl chains in the “substituted fluoroalkyl group” are further substituted by a substituent, and a group in which one or more hydrogen atom of a substituent in the “substituted fluoroalkyl group” are further substituted by a substituent. Specific examples of the “unsubstituted fluoroalkyl group” include a group in which one or more hydrogen atoms in the “alkyl group” (specific group G3) are substituted by a fluorine atom, and the like.

### “Substituted or Unsubstituted Haloalkyl Group”

The “substituted or unsubstituted haloalkyl group” described in this specification is a group in which at least one hydrogen atom bonded with a carbon atom constituting the alkyl group in the “substituted or unsubstituted alkyl group” is substituted by a halogen atom, and also includes a group in which all hydrogen atoms bonded with a carbon atom constituting the alkyl group in the “substituted or unsubstituted alkyl group” are substituted by a halogen atom. The number of carbon atoms of the “unsubstituted haloalkyl group” is 1 to 50, preferably 1 to 30, more preferably 1 to 18, unless otherwise specified in this specification. The “substituted haloalkyl group” means a group in which one or more hydrogen atoms of the “haloalkyl group” are substituted by a substituent. The “substituted haloalkyl group” described in this specification also includes a group in which one or more hydrogen atoms bonded with a carbon atom of the alkyl chain in the “substituted haloalkyl group” are further substituted by a substituent, and a group in which one or more hydrogen atoms of a substituent in the “substituted haloalkyl group” are further substituted by a substituent. Specific examples of the “unsubstituted haloalkyl group” include a group in which one or more hydrogen atoms in the “alkyl group” (specific example group G3) are substituted by a halogen atom, and the like. A haloalkyl group is sometimes referred to as an alkyl halide group.

### “Substituted or Unsubstituted Alkoxy Group”

Specific examples of the “substituted or unsubstituted alkoxy group” described in this specification include a group represented by —O(G3), wherein G3 is the “substituted or unsubstituted alkyl group” described in the specific example group G3. The number of carbon atoms of the “unsubstituted alkoxy group” is 1 to 50, preferably 1 to 30, more preferably 1 to 18, unless otherwise specified in this specification.

### “Substituted or Unsubstituted Alkylthio Group”

Specific examples of the “substituted or unsubstituted alkylthio group” described in this specification include a group represented by —S(G3), wherein G3 is the “substituted or unsubstituted alkyl group” described in the specific example group G3. The number of carbon atoms of the “unsubstituted alkylthio group” is 1 to 50, preferably 1 to 30, more preferably 1 to 18, unless otherwise specified in this specification.

### “Substituted or Unsubstituted Aryloxy Group”

Specific examples of the “substituted or unsubstituted aryloxy group” described in this specification include a group represented by —O(G1), wherein G1 is the “substituted or unsubstituted aryl group” described in the specific example group G1. The number of ring carbon atoms of the “unsubstituted aryloxy group” is 6 to 50, preferably 6 to 30, more preferably 6 to 18, unless otherwise specified in this specification.

### “Substituted or Unsubstituted Arylthio Group”

Specific examples of the “substituted or unsubstituted arylthio group” described in this specification include a group represented by —S(G1), wherein G1 is a “substituted or unsubstituted aryl group” described in the specific example group G1. The number of ring carbon atoms of the “unsubstituted arylthio group” is 6 to 50, preferably 6 to 30, more preferably 6 to 18, unless otherwise specified in this specification.

### “Substituted or Unsubstituted Trialkylsilyl Group”

Specific examples of the “trialkylsilyl group” described in this specification include a group represented by —Si(G3)(G3)(G3), where G3 is the “substituted or unsubstituted alkyl group” described in the specific example group G3. Plural G3's in —Si(G3)(G3)(G3) are the same or different. The number of carbon atoms in each alkyl group of the “trialkylsilyl group” is 1 to 50, preferably 1 to 20, more preferably 1 to 6, unless otherwise specified in this specification.

### “Substituted or Unsubstituted Aralkyl Group”

Specific examples of the “substituted or unsubstituted aralkyl group” described in this specification is a group represented by -(G3)-(G1), wherein G3 is the “substituted or unsubstituted alkyl group” described in the specific example group G3, and G1 is the “substituted or unsubstituted aryl group” described in the specific example group G1. Therefore, the “aralkyl group” is a group in which a hydrogen atom of the “alkyl group” is substituted by an “aryl group” as a substituent, and is one form of the “substituted alkyl group.” The “unsubstituted aralkyl group” is the “unsubstituted alkyl group” substituted by the “unsubstituted aryl group”, and the number of carbon atoms of the “unsubstituted aralkyl group” is 7 to 50, preferably 7 to 30, more preferably 7 to 18, unless otherwise specified in this specification.

Specific examples of the “substituted or unsubstituted aralkyl group” include a benzyl group, a 1-phenylethyl group, a 2-phenylethyl group, a 1-phenylisopropyl group, a 2-phenylisopropyl group, a phenyl-t-butyl group, an α-naphthylmethyl group, a 1-α-naphthylethyl group, a 2-α-naphthylethyl group, a 1-α-naphthylisopropyl group, a 2-α-naphthylisopropyl group, a β-naphthylmethyl group, a 1-β-naphthylethyl group, a 2-β-naphthylethyl group, a 1-β-naphthylisopropyl group, a 2-β-naphthylisopropyl group, and the like.

Unless otherwise specified in this specification, examples of the substituted or unsubstituted aryl group described in this specification preferably include a phenyl group, a p-biphenyl group, a m-biphenyl group, an o-biphenyl group, a p-terphenyl-4-yl group, a p-terphenyl-3-yl group, a p-terphenyl-2-yl group, a m-terphenyl-4-yl group, a m-terphenyl-3-yl group, a m-terphenyl-2-yl group, an o-terphenyl-4-yl group, an o-terphenyl-3-yl group, an o-terphenyl-2-yl group, a 1-naphthyl group, a 2-naphthyl group, an anthryl group, a phenanthryl group, a pyrenyl group, a chrysenyl group, a triphenylenyl group, a fluorenyl group, a 9,9′-spirobifluorenyl group, 9,9-dimethylfluorenyl group, 9,9-diphenylfluorenyl group, and the like.

Unless otherwise specified in this specification, examples of the substituted or unsubstituted heterocyclic groups described in this specification preferably include a pyridyl group, a pyrimidinyl group, a triazinyl group, a quinolyl group, an isoquinolyl group, a quinazolinyl group, a benzimidazolyl group, a phenanthrolinyl group, a carbazolyl group (a 1-carbazolyl group, a 2-carbazolyl group, a 3-carbazolyl group, a 4-carbazolyl group, or a 9-carbazolyl group), a benzocarbazolyl group, an azacarbazolyl group, a diazacarbazolyl group, a dibenzofuranyl group, a naphthobenzofuranyl group, an azadibenzofuranyl group, a diazadibenzofuranyl group, a dibenzothiophenyl group, a naphthobenzothiophenyl group, an azadibenzothiophenyl group, a diazadibenzothiophenyl group, a (9-phenyl)carbazolyl group (a (9-phenyl)carbazol-1-yl group, a (9-phenyl)carbazol-2-yl group, a (9-phenyl)carbazol-3-yl group, or a (9-phenyl)carbazol-4-yl group), a (9-biphenylyl)carbazolyl group, a (9-phenyl)phenylcarbazolyl group, a diphenylcarbazol-9-yl group, a phenylcarbazol-9-yl group, a phenyltriazinyl group, a biphenylyltriazinyl group, a diphenyltriazinyl group, a phenyldibenzofuranyl group, a phenyldibenzothiophenyl group, and the like.

In this specification, the carbazolyl group is specifically any of the following groups, unless otherwise specified in this specification.

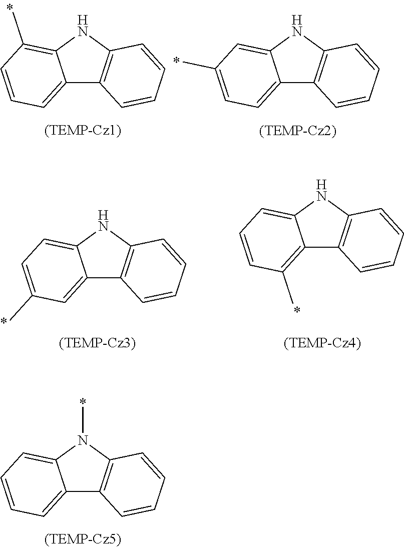

In this specification, the (9-phenyl)carbazolyl group is specifically any of the following groups, unless otherwise specified in this specification.

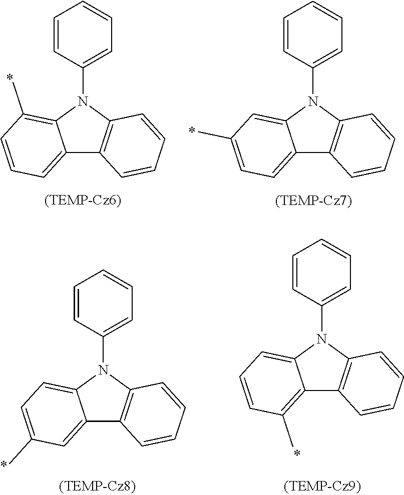

In the general formulas (TEMP-Cz1) to (TEMP-Cz9), * represents a bonding site.

In this specification, the dibenzofuranyl group and the dibenzothiophenyl group are specifically any of the following groups, unless otherwise specified in this specification.

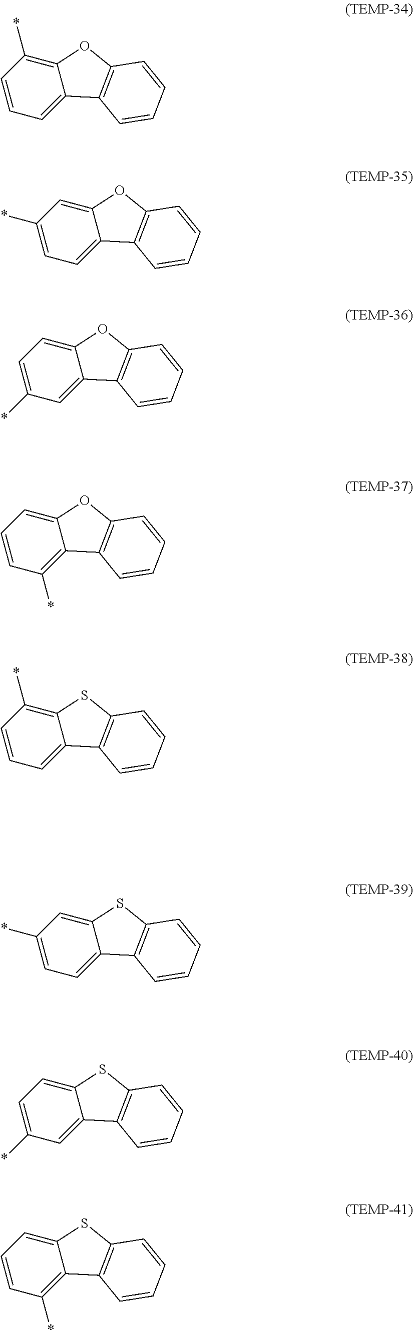

In the general formulas (TEMP-34) to (TEMP-41), * represents a bonding site.

The substituted or unsubstituted alkyl group described in this specification is preferably a methyl group, an ethyl group, a propyl group, an isopropyl group, a n-butyl group, an isobutyl group, a t-butyl group, or the like, unless otherwise specified in this specification.

### “Substituted or Unsubstituted Arylene Group”

The “substituted or unsubstituted arylene group” described in this specification is a divalent group derived by removing one hydrogen atom on the aryl ring of the “substituted or unsubstituted aryl group”, unless otherwise specified. Specific examples of the “substituted or unsubstituted arylene group” (specific example group G12) include a divalent group derived by removing one hydrogen atom on the aryl ring of the “substituted or unsubstituted aryl group” described in the specific example group G1, and the like.

### “Substituted or Unsubstituted Divalent Heterocyclic Group”

The “substituted or unsubstituted divalent heterocyclic group” described in this specification is a divalent group derived by removing one hydrogen atom on the heterocycle of the “substituted or unsubstituted heterocyclic group”, unless otherwise specified. Specific examples of the “substituted or unsubstituted divalent heterocyclic group” (specific example group G13) include a divalent group derived by removing one hydrogen atom on the heterocycle of the “substituted or unsubstituted heterocyclic group” described in the specific example group G2, and the like.

### “Substituted or Unsubstituted Alkylene Group”

The “substituted or unsubstituted alkylene group” described in this specification is a divalent group derived by removing one hydrogen atom on the alkyl chain of the “substituted or unsubstituted alkyl group”, unless otherwise specified. Specific examples of the “substituted or unsubstituted alkylene group” (specific example group G14) include a divalent group derived by removing one hydrogen atom on the alkyl chain of the “substituted or unsubstituted alkyl group” described in the specific example group G3, and the like.

The substituted or unsubstituted arylene group described in this specification is preferably any group of the following general formulas (TEMP-42) to (TEMP-68), unless otherwise specified in this specification.

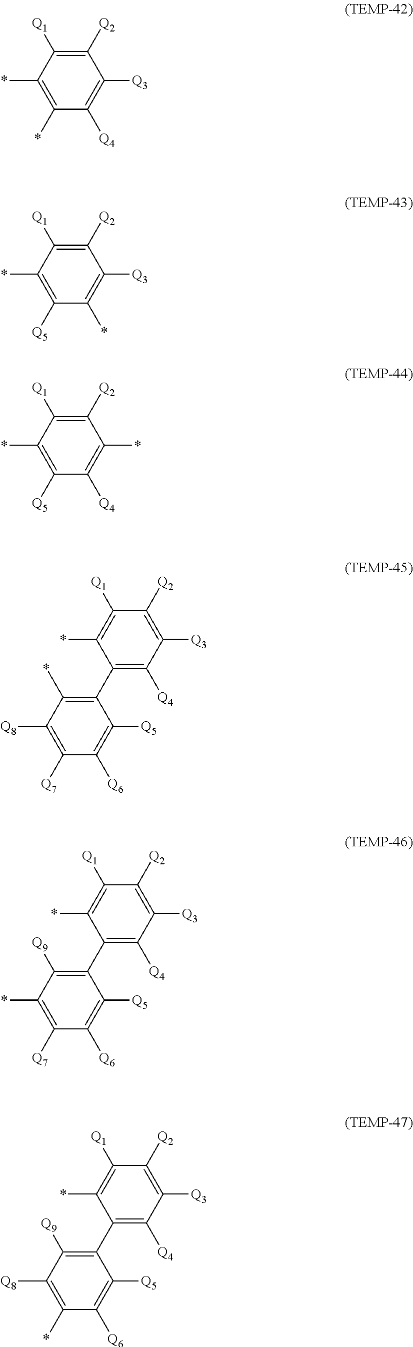

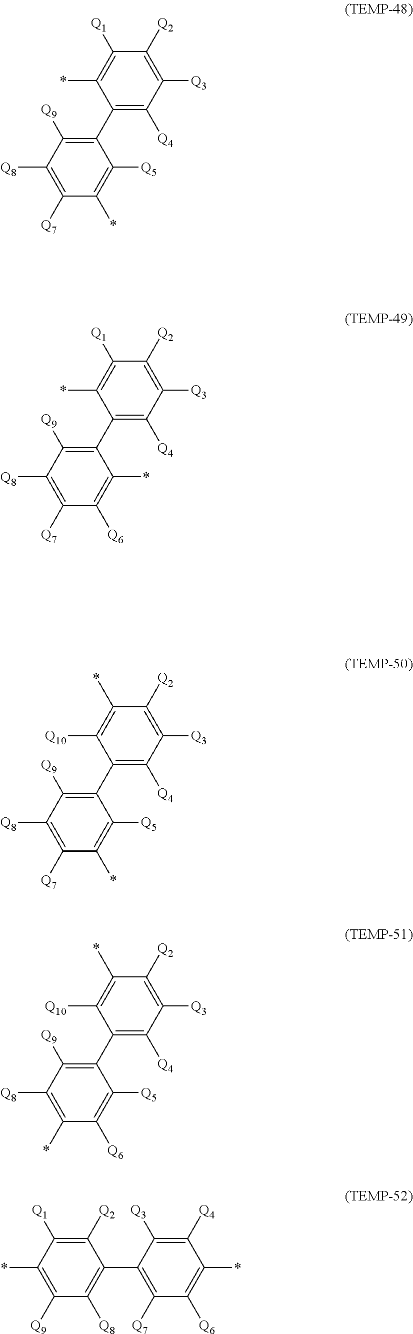

In the general formulas (TEMP-42) to (TEMP-52), Q₁ to Q₁₀ are independently a hydrogen atom or a substituent.

In the general formulas (TEMP-42) to (TEMP-52), * represents a bonding site.

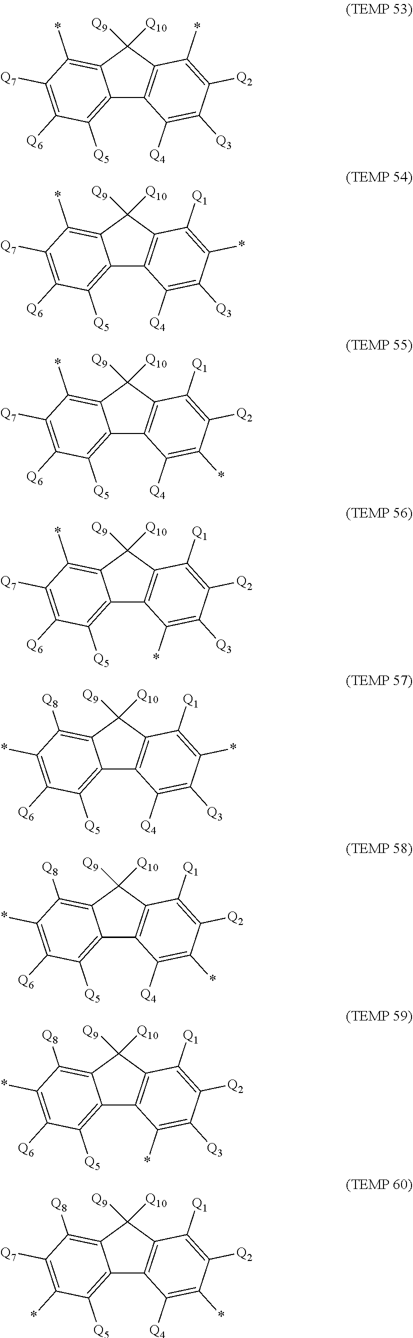

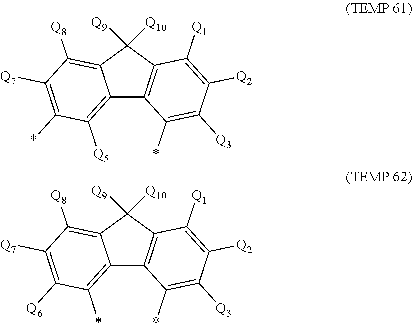

In the general formulas (TEMP-53) to (TEMP-62), Q₁ to Q₁₀ are independently a hydrogen atom or a substituent.

Q₉ and Q₁₀ may be bonded with each other via a single bond to form a ring.

In the general formulas (TEMP-53) to (TEMP-62), * represents a bonding site.

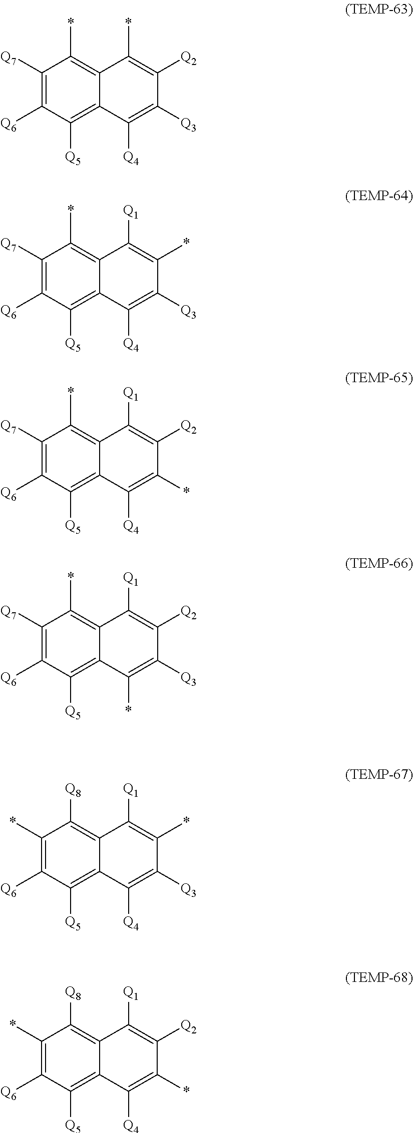

In the general formulas (TEMP-63) to (TEMP-68), Q₁ to Q₈ are independently a hydrogen atom or a substituent.

In the general formulas (TEMP-63) to (TEMP-68), * represents a bonding site.

The substituted or unsubstituted divalent heterocyclic group described in this specification is preferably any group of the following general formulas (TEMP-69) to (TEMP-102), unless otherwise specified in this specification.

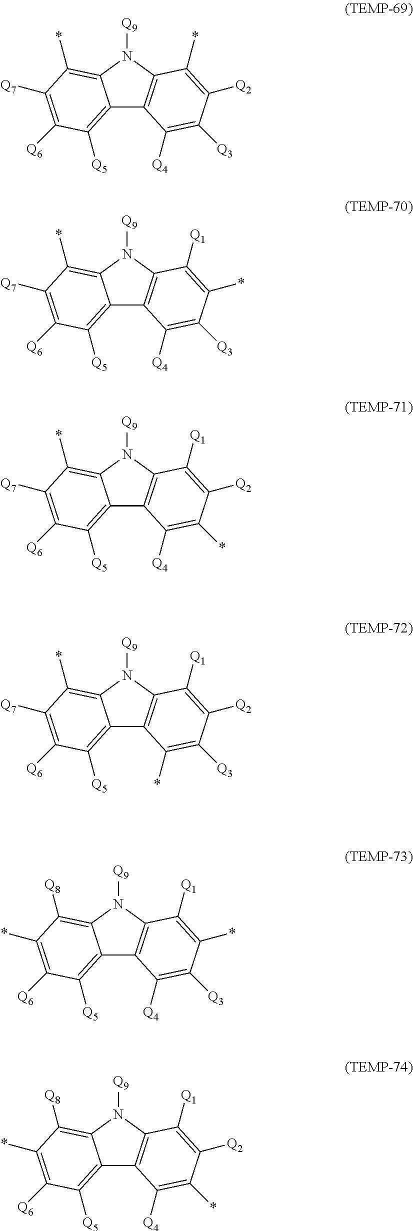

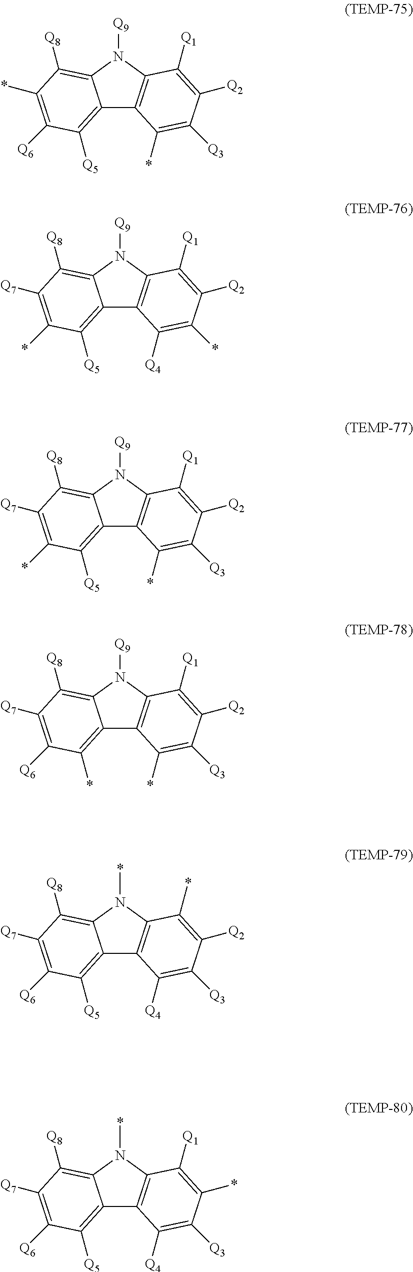

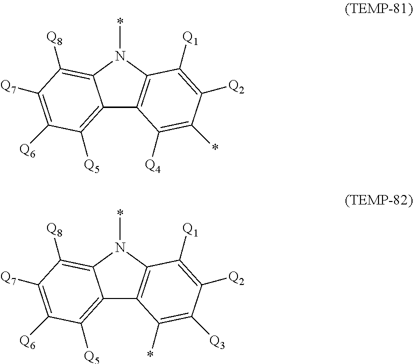

In the general formulas (TEMP-69) to (TEMP-82), Q₁ to Q₉ are independently a hydrogen atom or a substituent.

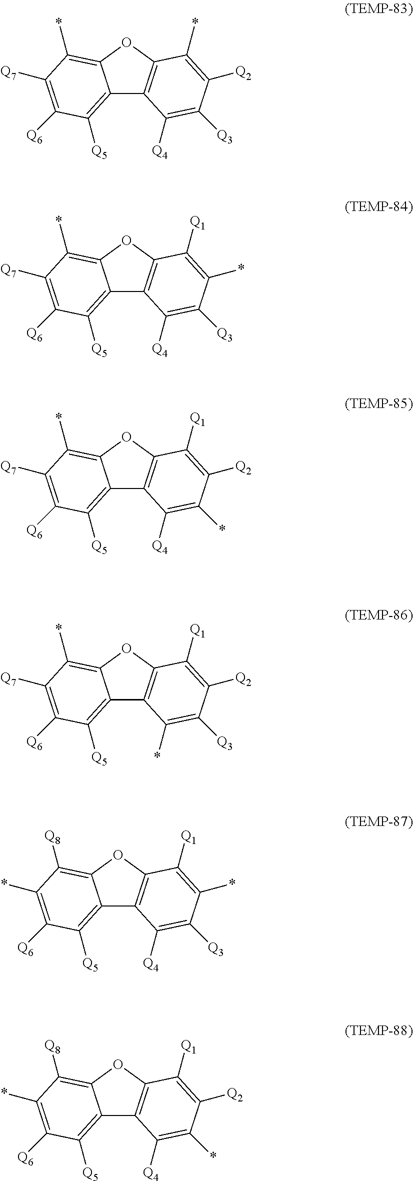

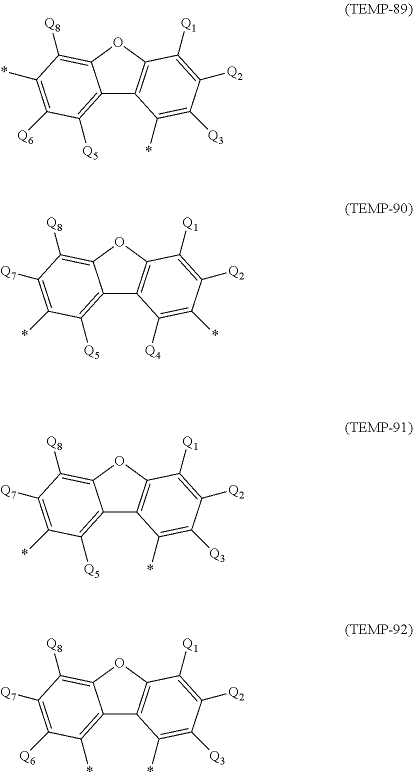

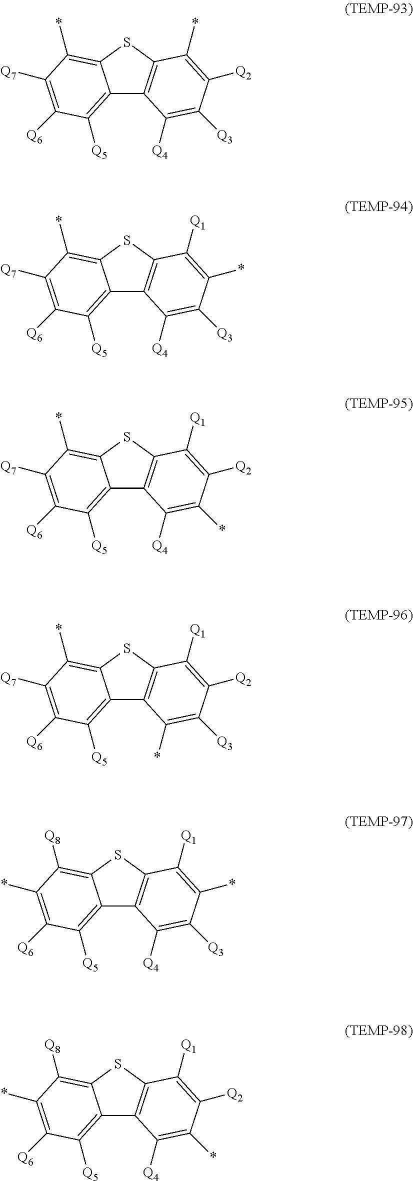

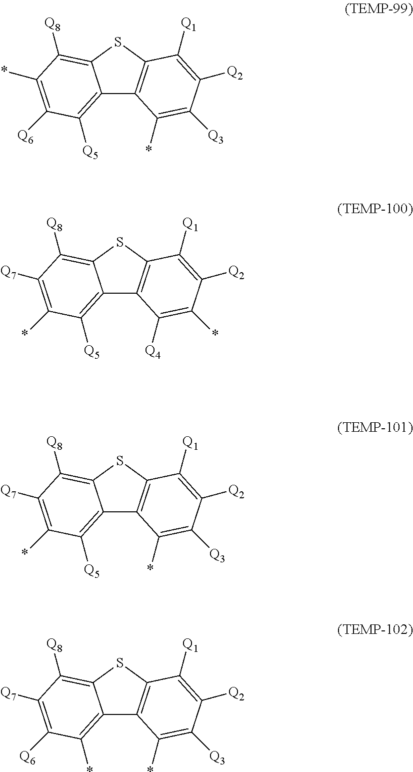

In the general formulas (TEMP-83) to (TEMP-102), Q₁ to Q₈ are independently a hydrogen atom or a substituent.

The above is the explanation of the “Substituent described in this specification.”

“The Case where Bonded with Each Other to Form a Ring”

In this specification, the case where “one or more sets of adjacent two or more form a substituted or unsubstituted monocycle by bonding with each other, form a substituted or unsubstituted fused ring by bonding with each other, or do not bond with each other” means the case where “one or more sets of adjacent two or more form a substituted or unsubstituted monocycle by bonding with each other”; the case where “one or more sets of adjacent two or more form a substituted or unsubstituted fused ring by bonding with each other”; and the case where “one or more sets of adjacent two or more do not bond with each other.”

The case where “one or more sets of adjacent two or more form a substituted or unsubstituted monocycle by bonding with each other” and the case where “one or more sets of adjacent two or more form a substituted or unsubstituted fused ring by bonding with each other” in this specification (these cases may be collectively referred to as “the case where forming a ring by bonding with each other”) will be described below. The case of an anthracene compound represented by the following general formula (TEMP-103) in which the mother skeleton is an anthracene ring will be described as an example.

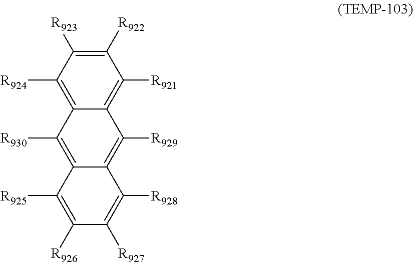

For example, in the case where “one or more sets of adjacent two or more among R₉₂₁ to R₉₃₀ form a ring by bonding with each other”, the one set of adjacent two includes a pair of R₉₂₁ and R₉₂₂, a pair of R₉₂₂ and R₉₂₃, a pair of R₉₂₃ and R₉₂₄, a pair of R₉₂₄ and R₉₃₀, a pair of R₉₃₀ and R₉₂₅, a pair of R₉₂₅ and R₉₂₆, a pair of R₉₂₆ and R₉₂₇, a pair of R₉₂₇ and R₉₂₈, a pair of R₉₂₈ and R₉₂₉, and a pair of R₉₂₉ and R₉₂₁.

The “one or more sets” means that two or more sets of the adjacent two or more sets may form a ring at the same time. For example, R₉₂₁ and R₉₂₂ form a ring Q_{A} by bonding with each other, and at the same, time R₉₂₅ and R₉₂₆ form a ring Q_{B} by bonding with each other, the anthracene compound represented by the general formula (TEMP-103) is represented by the following general formula (TEMP-104).

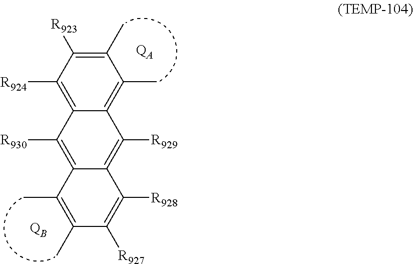

The case where the “set of adjacent two or more” form a ring includes not only the case where the set (pair) of adjacent “two” is bonded with as in the above-mentioned examples, but also the case where the set of adjacent “three or more” are bonded with each other. For example, it means the case where R₉₂₁ and R₉₂₂ form a ring Q_{A} by bonding with each other, and R₉₂₂ and R₉₂₃ form a ring Q_{C} by bonding with each other, and adjacent three (R₉₂₁, R₉₂₂ and R₉₂₃) form rings by bonding with each other and together fused to the anthracene mother skeleton. In this case, the anthracene compound represented by the general formula (TEMP-103) is represented by the following general formula (TEMP-105). In the following general formula (TEMP-105), the ring Q_{A} and the ring Q_{C} share R₉₂₂.

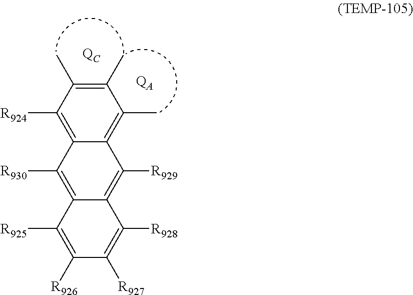

The “monocycle” or “fused ring” formed may be a saturated ring or an unsaturated ring, as a structure of the formed ring alone. Even when the “one pair of adjacent two” forms a “monocycle” or a “fused ring”, the “monocycle” or the “fused ring” may form a saturated ring or an unsaturated ring. For example, the ring Q_{A} and the ring Q_{B} formed in the general formula (TEMP-104) are independently a “monocycle” or a “fused ring.” The ring Q_{A} and the ring Q_{C} formed in the general formula (TEMP-105) are “fused ring.” The ring Q_{A} and ring Q_{C} of the general formula (TEMP-105) are fused ring by fusing the ring Q_{A} and the ring Q_{C} together. When the ring Q_{A} of the general formula (TMEP-104) is a benzene ring, the ring Q_{A} is a monocycle. When the ring Q_{A} of the general formula (TMEP-104) is a naphthalene ring, the ring Q_{A} is a fused ring.

The “unsaturated ring” includes, in addition to an aromatic hydrocarbon ring and an aromatic heterocycle, an aliphatic hydrocarbon ring with an unsaturated bond, i.e., double and/or triple bonds in the ring structure (e.g., cyclohexene, cyclohexadiene, etc.), and a non-aromatic heterocycle with an unsaturated bond (e.g., dihydropyran, imidazoline, pyrazoline, quinolizine, indoline, isoindoline, etc.). The “saturated ring” includes an aliphatic hydrocarbon ring without an unsaturated bond and a non-aromatic heterocycle without ab unsaturated bond.

Specific examples of the aromatic hydrocarbon ring include a structure in which the group listed as a specific example in the specific example group G1 is terminated by a hydrogen atom.

Specific examples of the aromatic heterocycle include a structure in which the aromatic heterocyclic group listed as a specific example in the example group G2 is terminated by a hydrogen atom.

Specific examples of the aliphatic hydrocarbon ring include a structure in which the group listed as a specific example in the specific example group G6 is terminated by a hydrogen atom.

The term “to form a ring” means forming a ring only with plural atoms of the mother skeleton, or with plural atoms of the mother skeleton and one or more arbitrary atoms in addition. For example, the ring Q_{A} shown in the general formula (TEMP-104), which is formed by bonding R₉₂₁ and R₉₂₂ with each other, is a ring formed from the carbon atom of the anthracene skeleton with which R₉₂₁ is bonded, the carbon atom of the anthracene skeleton with which R₉₂₂ is bonded, and one or more arbitrary atoms. For example, in the case where the ring Q_{A} is formed with R₉₂₁ and R₉₂₂, when a monocyclic unsaturated ring is formed with the carbon atom of the anthracene skeleton with which R₉₂₁ is bonded, the carbon atom of the anthracene skeleton with which R₉₂₂ is bonded, and four carbon atoms, the ring formed with R₉₂₁ and R₉₂₂ is a benzene ring.

Here, the “arbitrary atom” is preferably at least one atom selected from the group consisting of a carbon atom, a nitrogen atom, an oxygen atom, and a sulfur atom, unless otherwise specified in this specification. In the arbitrary atom (for example, a carbon atom or a nitrogen atom), a bond which does not form a ring may be terminated with a hydrogen atom or the like, or may be substituted with “arbitrary substituent” described below. When an arbitrary atom other than a carbon atom is contained, the ring formed is a heterocycle.

The number of “one or more arbitrary atom(s)” constituting a monocycle or a fused ring is preferably 2 or more and 15 or less, more preferably 3 or more and 12 or less, and still more preferably 3 or more and 5 or less, unless otherwise specified in this specification.

The “monocycle” is preferable among the “monocycle” and the “fused ring”, unless otherwise specified in this specification.

The “unsaturated ring” is preferable among the “saturated ring” and the “unsaturated ring”, unless otherwise specified in this specification.

Unless otherwise specified in this specification, the “monocycle” is preferably a benzene ring.

Unless otherwise specified in this specification, the “unsaturated ring” is preferably a benzene ring.

Unless otherwise specified in this specification, when “one or more sets of adjacent two or more” are “bonded with each other to form a substituted or unsubstituted monocycle” or “bonded with each other to form a substituted or unsubstituted fused ring”, this specification, one or more sets of adjacent two or more are preferably bonded with each other to form a substituted or unsubstituted “unsaturated ring” from plural atoms of the mother skeleton and one or more and 15 or less atoms which is at least one kind selected from a carbon atom, a nitrogen atom, an oxygen atom, and a sulfur atom.

The substituent in the case where the above-mentioned “monocycle” or “fused ring” has a substituent is, for example, an “arbitrary substituent” described below. Specific examples of the substituent which the above-mentioned “monocycle” or “fused ring” has include the substituent described above in the “Substituent described in this specification” section.

The substituent in the case where the above-mentioned “saturated ring” or “unsaturated ring” has a substituent is, for example, an “arbitrary substituent” described below. Specific examples of the substituent which the above-mentioned “monocycle” or “fused ring” has include the substituent described above in the “Substituent described in this specification” section.

The foregoing describes the case where “one or more sets of adjacent two or more form a substituted or unsubstituted monocycle by bonding with each other” and the case where “one or more sets of adjacent two or more form a substituted or unsubstituted fused ring by bonding with each other” (the case where “forming a ring by bonding with each other”).

### Substituent in the Case of “Substituted or Unsubstituted”

In one embodiment in this specification, the substituent (in this specification, sometimes referred to as an “arbitrary substituent”) in the case of “substituted or unsubstituted” is, for example, a group selected from the group consisting of:

an unsubstituted alkyl group including 1 to 50 carbon atoms,

an unsubstituted alkenyl group including 2 to 50 carbon atoms,

an unsubstituted alkynyl group including 2 to 50 carbon atoms,

an unsubstituted cycloalkyl group including 3 to 50 ring carbon atoms,

—Si(R₉₀₁)(R₉₀₂)(R₉₀₃),

—O—(R₉₀₄),

—S—(R₉₀₅),

—N(R₉₀₅)(R₉₀₇),

a halogen atom, a cyano group, a nitro group,

an unsubstituted aryl group including 6 to 50 ring carbon atoms, and

an unsubstituted heterocyclic group including 5 to 50 ring atoms,

wherein, R₉₀₁ to R₉₀₇ are independently

a hydrogen atom,

a substituted or unsubstituted alkyl group including 1 to 50 carbon atoms,

a substituted or unsubstituted cycloalkyl group including 3 to 50 ring carbon atoms,

a substituted or unsubstituted aryl group including 6 to 50 ring carbon atoms, or

a substituted or unsubstituted heterocyclic group including 5 to 50 ring atoms.

When two or more R₉₀₁'s are present, the two or more R₉₀₁'s may be the same or different.

When two or more R₉₀₂'s are present, the two or more R₉₀₂'s may be the same or different.

When two or more R₉₀₃'s are present, the two or more R₉₀₃'s may be the same or different.

When two or more R₉₀₄'s are present, the two or more R₉₀₄'s may be the same or different.

When two or more R₉₀₅'s are present, the two or more R₉₀₅'s may be the same or different.

When two or more R₉₀₆'s are present, the two or more R₉₀₆'s may be the same or different.

When two or more R₉₀₇'s are present, the two or more R₉₀₇'s may be the same or different.

In one embodiment, the substituent in the case of “substituted or unsubstituted” is a group selected from the group consisting of:

an alkyl group including 1 to 50 carbon atoms,

an aryl group including 6 to 50 ring carbon atoms, and

a heterocyclic group including 5 to 50 ring atoms.

In one embodiment, the substituent in the case of “substituted or unsubstituted” is a group selected from the group consisting of:

an alkyl group including 1 to 18 carbon atoms,

an aryl group including 6 to 18 ring carbon atoms, and

a heterocyclic group including 5 to 18 ring atoms.

Specific examples of each of the arbitrary substituents include specific examples of substituent described in the section “Substituent described in this specification” above.

Unless otherwise specified in this specification, adjacent arbitrary substituents may form a “saturated ring” or an “unsaturated ring”, preferably form a substituted or unsubstituted saturated 5-membered ring, a substituted or unsubstituted saturated 6-membered ring, a substituted or unsubstituted unsaturated 5-membered ring, or a substituted or unsubstituted unsaturated 6-membered ring, more preferably form a benzene ring.

Unless otherwise specified in this specification, the arbitrary substituent may further have a substituent. The substituent which the arbitrary substituent further has is the same as that of the above-mentioned arbitrary substituent.

In this specification, the numerical range represented by “AA to BB” means the range including the numerical value AA described on the front side of “AA to BB” as the lower limit and the numerical value BB described on the rear side of “AA to BB” as the upper limit.

### [First Composition]

A first composition according to an aspect of the present invention includes a first compound and a second compound, wherein the first compound is a compound represented by the formula (12) (hereinafter, also referred to as a “first compound in the first composition”), and the second compound is a compound represented by the formula (21) (hereinafter, also referred to as a “second compound in the first composition”).

When the first composition includes two compounds having the specific structures, the first composition is used in an organic EL device to be capable of enhancing the device performance thereof. Specifically, an organic EL device having high efficiency and long lifetime can be achieved.

Each member of the first composition will be described below.

### (First Compound in First Composition)

A first compound in the first composition is a compound represented by the following formula (12):

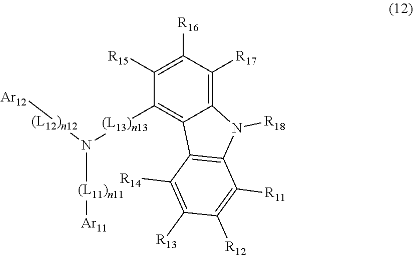

wherein in the formula (12),

Ar₁₁ and Ar₁₂ are independently

a substituted or unsubstituted aryl group having 6 to 50 ring carbon atoms,

a substituted or unsubstituted monovalent heterocyclic group having 5 to 50 ring atoms, or

—Si(R_{C1})(R_{C2})(R_{C3});

R_{C1} to R_{C3} are independently a substituted or unsubstituted aryl group having 6 to 50 ring carbon atoms,

when a plurality of each of R_{C1} to R_{C3} are present, the plurality of each of R_{C1} to R_{C3} may be the same as or different from each other;

n11 is an integer of 0 to 3; when n11 is 0, Ar₁₁ is directly bonded with the nitrogen atom of the amine via a single bond; when n11 is 2 or 3, a plurality of L₁₁'s is linked in series with each other and Ar₁₁ is bonded with L₁₁ which is farthest from the nitrogen atom of the amine; when two or more L₁₁'s are present, one or more sets of the adjacent two or more of the two or more L₁₁'s form a substituted or unsubstituted single ring by bonding with each other, form a substituted or unsubstituted fused ring by bonding with each other, or do not form the ring; when two or more L₁₁'s are present, the two or more L₁₁'s may be the same as or different from each other;

n12 is an integer of 0 to 3; when n12 is 0, Ar₁₂ is directly bonded with the nitrogen atom of the amine via a single bond; when n12 is 2 or 3, a plurality of L₁₂'s is linked in series with each other and Ar₁₂ is bonded with L₁₂ which is farthest from the nitrogen atom of the amine; when two or more L₁₂'s are present, one or more sets of the adjacent two or more of the two or more L₁₂'s form a substituted or unsubstituted single ring by bonding with each other, form a substituted or unsubstituted fused ring by bonding with each other, or do not form the ring; when two or more L₁₂'s are present, the two or more L₁₂'s may be the same as or different from each other;

n13 is an integer of 0 to 3; when n13 is 0, the carbon atom of the carbazole skeleton is directly bonded with the nitrogen atom of the amine via a single bond; when n13 is 2 or 3, a plurality of L₁₃'s is linked in series with each other and the carbazole skeleton is bonded with L₁₃ which is farthest from the nitrogen atom of the amine; when two or more L₁₃'s are present, one or more sets of the adjacent two or more of the two or more L₁₃'s form a substituted or unsubstituted single ring by bonding with each other, form a substituted or unsubstituted fused ring by bonding with each other, or do not form the ring; when two or more L₁₃'s are present, the two or more L₁₃'s may be the same as or different from each other;

L₁₁, L₁₂, and L₁₃ which do not form the ring are independently

a single bond,

a substituted or unsubstituted arylene group having 6 to 50 ring carbon atoms, or

a substituted or unsubstituted divalent heterocyclic group having 5 to 50 ring atoms;

one or more sets of the adjacent two or more of R₁₁ to R₁₇

form a substituted or unsubstituted single ring by bonding with each other,

form a substituted or unsubstituted fused ring by bonding with each other, or

do not bond with each other;

R₁₈, and R₁ to R₁₇ which do not form the substituted or unsubstituted single ring and which do not form the substituted or unsubstituted fused ring are independently

a hydrogen atom,

a cyano group,

a substituted or unsubstituted alkyl group having 1 to 50 carbon atoms,

a substituted or unsubstituted halogenated alkyl group having 1 to 50 carbon atoms,

a substituted or unsubstituted cycloalkyl group having 3 to 50 ring carbon atoms,

a group represented by —Si(R_{901A})(R_{902A})(R_{903A}),

a group represented by —O—(R_{904A}),

a substituted or unsubstituted aryl group having 6 to 50 ring carbon atoms, or

a substituted or unsubstituted monovalent heterocyclic group having 5 to 50 ring atoms;

R_{901A} to R_{904A} are independently

a hydrogen atom,

a substituted or unsubstituted alkyl group having 1 to 50 carbon atoms,

a substituted or unsubstituted cycloalkyl group having 3 to 50 ring carbon atoms,

a substituted or unsubstituted aryl group having 6 to 50 ring carbon atoms, or

a substituted or unsubstituted monovalent heterocyclic group having 5 to 50 ring atoms;

when a plurality of each of R_{901A} to R_{904A} are present, the plurality of each of R_{901A} to R_{904A} may be the same as or different from each other.

In one embodiment, L₁₃ is a substituted or unsubstituted arylene group having 6 to 50 ring carbon atoms, or a substituted or unsubstituted divalent heterocyclic group having 5 to 50 ring atoms.

In one embodiment, L₁₃ is a substituted or unsubstituted arylene group having 6 to 18 ring carbon atoms, or a substituted or unsubstituted divalent heterocyclic group having 5 to 18 ring atoms.

In one embodiment, L₁₃ is a substituted or unsubstituted phenylene group, or a substituted or unsubstituted naphthylene group.

In one embodiment, n13 is 1 or 2.

In one embodiment, n13 is 1.

In one embodiment, L₁₁ is a single bond, a substituted or unsubstituted arylene group having 6 to 18 ring carbon atoms, or a substituted or unsubstituted divalent heterocyclic group having 5 to 18 ring atoms.

In one embodiment, L₁₁ is a single bond, or a substituted or unsubstituted arylene group having 6 to 18 ring carbon atoms.

In one embodiment, L₁₁ is a single bond, a substituted or unsubstituted phenylene group, or a substituted or unsubstituted naphthylene group.

In one embodiment, n11 is 1 or 2.

In one embodiment, L₁₂ is a single bond, a substituted or unsubstituted arylene group having 6 to 18 ring carbon atoms, or a substituted or unsubstituted divalent heterocyclic group having 5 to 18 ring atoms.

In one embodiment, L₁₁ is a single bond, or a substituted or unsubstituted arylene group having 6 to 18 ring carbon atoms.

In one embodiment, L₁₁ is a single bond, a substituted or unsubstituted phenylene group, or a substituted or unsubstituted naphthylene group.

In one embodiment, n12 is 1 or 2.

In one embodiment, Ar₁₁ and Ar₁₂ are independently a substituted or unsubstituted aryl group having 6 to 50 ring carbon atoms, or a substituted or unsubstituted monovalent heterocyclic group having 5 to 50 ring atoms.

In one embodiment, Ar₁₁ and Ar₁₂ are independently a substituted or unsubstituted aryl group having 6 to 18 ring carbon atoms, or a substituted or unsubstituted monovalent heterocyclic group having 5 to 18 ring atoms.

In one embodiment, Ar₁ and Ar₁₂ are independently a substituted or unsubstituted phenyl group, a substituted or unsubstituted biphenyl group (p-biphenyl group, m-biphenyl group or o-biphenyl group), or a substituted or unsubstituted naphthyl group (1-naphthyl group or 2-naphthyl group).

In one embodiment, one or more sets of the adjacent two or more of R₁ to R₁₇ do not bond with each other.

In one embodiment, R₁ to R₁₇ are independently

a hydrogen atom,

a substituted or unsubstituted alkyl group having 1 to 50 carbon atoms,

a substituted or unsubstituted aryl group having 6 to 50 ring carbon atoms, or

a substituted or unsubstituted monovalent heterocyclic group having 5 to 50 ring atoms.

In one embodiment, R₁ to R₁₇ are independently

a hydrogen atom,

a substituted or unsubstituted alkyl group having 1 to 50 carbon atoms, or

a substituted or unsubstituted aryl group having 6 to 50 ring carbon atoms.

In one embodiment, R₁₁ to R₁₇ are independently

a hydrogen atom,

a substituted or unsubstituted alkyl group having 1 to 18 carbon atoms, or

a substituted or unsubstituted aryl group having 6 to 18 ring carbon atoms.

In one embodiment, R₁₁ to R₁₇ are independently a hydrogen atom.

In one embodiment, R₁₈ is

a hydrogen atom,

a substituted or unsubstituted alkyl group having 1 to 50 carbon atoms, or

a substituted or unsubstituted aryl group having 6 to 50 ring carbon atoms.

In one embodiment, R₁₈ is

a hydrogen atom,

a substituted or unsubstituted alkyl group having 1 to 18 carbon atoms, or

a substituted or unsubstituted aryl group having 6 to 18 ring carbon atoms.

In one embodiment, R₁₈ is a substituted or unsubstituted phenyl group, a substituted or unsubstituted biphenyl group (p-biphenyl group, m-biphenyl group or o-biphenyl group), or a substituted or unsubstituted naphthyl group (1-naphthyl group or 2-naphthyl group).

In one embodiment, the compound represented by the formula (12) is a compound represented by the following formula (12-1) or (12-2):

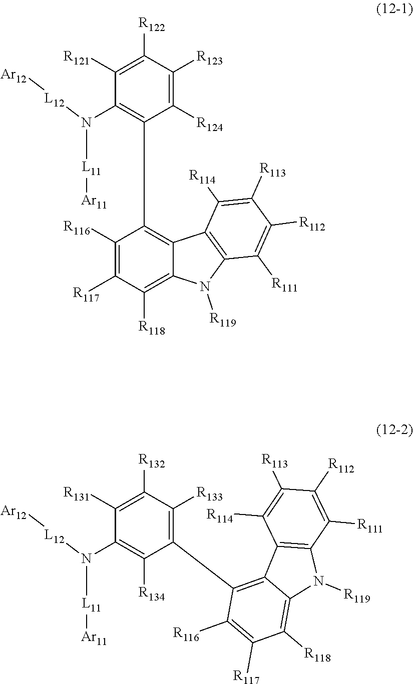

wherein in the formula (12-1),

Ar₁₁, Ar₁₂, L₁₁, and L₁₂ are the same as defined in the formula (12);

one or more sets of the adjacent two or more of R₁₁₁ to R₁₁₄ and R₁₁ to R₁₁₈

form a substituted or unsubstituted single ring by bonding with each other,

form a substituted or unsubstituted fused ring by bonding with each other, or

do not bond with each other;

R₁₁₉, and R₁₁₁ to R₁₁₄ and R₁₁₆ to R₁₁₈ which do not form the substituted or unsubstituted single ring and which do not form the substituted or unsubstituted fused ring are independently

a hydrogen atom,

a cyano group,

a substituted or unsubstituted alkyl group having 1 to 50 carbon atoms,

a substituted or unsubstituted halogenated alkyl group having 1 to 50 carbon atoms,

a substituted or unsubstituted cycloalkyl group having 3 to 50 ring carbon atoms,

a group represented by —Si(R_{901A})(R_{902A})(R_{903A}),

a group represented by —O—(R_{904A}),

a substituted or unsubstituted aryl group having 6 to 50 ring carbon atoms, or

a substituted or unsubstituted monovalent heterocyclic group having 5 to 50 ring atoms;

R_{901A} to R_{904A} are the same as defined in the formula (12);

R₁₂₁ to R₁₂₄ are independently a hydrogen atom, or a substituent R;

in the formula (12-2),

Ar₁₁, Ar₁₂, L₁₁, and L₁₂ are the same as defined in the formula (12);

one or more sets of the adjacent two or more of R₁₁₁ to R₁₁₄ and R₁₁₅ to R₁₁₈

form a substituted or unsubstituted single ring by bonding with each other,

form a substituted or unsubstituted fused ring by bonding with each other, or

do not bond with each other;

R₁₁₉, and R₁₁₁ to R₁₁₄ and R₁₁₆ to R₁₁₈ which do not form the substituted or unsubstituted single ring and which do not form the substituted or unsubstituted fused ring are independently

a hydrogen atom,

a cyano group,

a substituted or unsubstituted alkyl group having 1 to 50 carbon atoms,

a substituted or unsubstituted halogenated alkyl group having 1 to 50 carbon atoms,

a substituted or unsubstituted cycloalkyl group having 3 to 50 ring carbon atoms,

a group represented by —Si(R_{901A})(R_{902A})(R_{903A}),

a group represented by —O—(R_{904A}),

a substituted or unsubstituted aryl group having 6 to 50 ring carbon atoms, or

a substituted or unsubstituted monovalent heterocyclic group having 5 to 50 ring atoms;

R_{901A} to R_{904A} are the same as defined in the formula (12);

R₁₃₁ to R₁₃₄ are independently a hydrogen atom, or a substituent R;

the substituent R is selected from the group consisting of

a substituted or unsubstituted alkyl group having 1 to 50 carbon atoms,

a substituted or unsubstituted alkenyl group having 2 to 50 carbon atoms,

a substituted or unsubstituted alkynyl group having 2 to 50 carbon atoms,

a substituted or unsubstituted cycloalkyl group having 3 to 50 ring carbon atoms,

—Si(R₉₀₁)(R₉₀₂)(R₉₀₃),

—O—(R₉₀₄),

—S—(R₉₀₅),

—N(R₉₀₅)(R₉₀₇)

(wherein R₉₀₁ to R₉₀₇ are independently

a hydrogen atom,

a substituted or unsubstituted alkyl group having 1 to 50 carbon atoms,

a substituted or unsubstituted cycloalkyl group having 3 to 50 ring carbon atoms,

a substituted or unsubstituted aryl group having 6 to 50 ring carbon atoms, or

a substituted or unsubstituted monovalent heterocyclic group having 5 to 50 ring atoms; when two or more of each of R₉₀₁ to R₉₀₇ are present, the two or more of each of R₉₀₁ to R₉₀₇ may be the same as or different from each other),

a halogen atom, a cyano group, a nitro group,

a substituted or unsubstituted aryl group having 6 to 50 ring carbon atoms, and

a substituted or unsubstituted monovalent heterocyclic group having 5 to 50 ring atoms; and

when two or more substituents R are present, the two or more substituents R may be the same as or different from each other.

In one embodiment, R₁₂₁ to R₁₂₄ is a hydrogen atom.

In one embodiment, R₁₃₁ to R₁₃₄ is a hydrogen atom.

In one embodiment, one or more sets of the adjacent two or more of R₁₁₁ to R₁₁₄ and R₁₁₆ to R₁₁₈ do not bond with each other.

In one embodiment, R₁₁₁ to R₁₁₄ and R₁₁₆ to R₁₁₈ are independently

a hydrogen atom,

a substituted or unsubstituted alkyl group having 1 to 50 carbon atoms,

a substituted or unsubstituted aryl group having 6 to 50 ring carbon atoms, or

a substituted or unsubstituted monovalent heterocyclic group having 5 to 50 ring atoms.

In one embodiment, R₁₁₁ to R₁₁₄ and R₁₁ to R₁₁₃ are independently

a hydrogen atom,

a substituted or unsubstituted alkyl group having 1 to 50 carbon atoms, or

a substituted or unsubstituted aryl group having 6 to 50 ring carbon atoms.

In one embodiment, R₁₁₁ to R₁₁₄ and R₁₁₆ to R₁₁₈ are independently

a hydrogen atom,

a substituted or unsubstituted alkyl group having 1 to 18 carbon atoms, or

a substituted or unsubstituted aryl group having 6 to 18 ring carbon atoms.

In one embodiment, R₁₁₁ to R₁₁₄ and R₁₁₆ to R₁₁₈ are independently a hydrogen atom.

In one embodiment, R₁₁₉ is

a hydrogen atom,

a substituted or unsubstituted alkyl group having 1 to 50 carbon atoms, or

a substituted or unsubstituted aryl group having 6 to 50 ring carbon atoms.

In one embodiment, R₁₁₉ is

a hydrogen atom,

a substituted or unsubstituted alkyl group having 1 to 18 carbon atoms, or

a substituted or unsubstituted aryl group having 6 to 18 ring carbon atoms.

In one embodiment, R₁₁₉ is a substituted or unsubstituted phenyl group, a substituted or unsubstituted biphenyl group (p-biphenyl group, m-biphenyl group or o-biphenyl group), or a substituted or unsubstituted naphthyl group (1-naphthyl group or 2-naphthyl group).

### (Second Compound in First Composition)

A second compound in the first composition is a compound represented by the following formula (21):

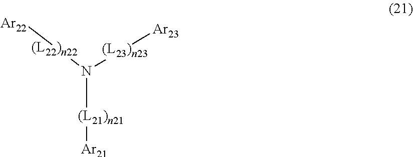

wherein in the formula (21),

Ar₂₁, Ar₂₂, and Ar₂₃ are independently

a substituted or unsubstituted aryl group having 6 to 50 ring carbon atoms,

a substituted or unsubstituted monovalent heterocyclic group having 5 to 50 ring atoms, or

—Si(R_{C1})(R_{C2})(R_{C3});

R_{C1} to R_{C3} are the same as defined in the formula (12);

n21 is an integer of 0 to 3; when n21 is 0, Ar₂₁ is directly bonded with the nitrogen atom of the amine via a single bond; when n21 is 2 or 3, a plurality of L₂₁'s is linked in series with each other and Ar₂₁ is bonded with L₂₁ which is farthest from the nitrogen atom of the amine; when two or more L₂₁'s are present, one or more sets of the adjacent two or more of the two or more L₂₁'s form a substituted or unsubstituted single ring by bonding with each other, form a substituted or unsubstituted fused ring by bonding with each other, or do not form the ring; when two or more L₂₁'s are present, the two or more L₂₁'s may be the same as or different from each other;

n22 is an integer of 0 to 3; when n22 is 0, Ar₂₂ is directly bonded with the nitrogen atom of the amine via a single bond; when n22 is 2 or 3, a plurality of L₂₂'s is linked in series with each other and Ar₂₂ is bonded with L₂₂ which is farthest from the nitrogen atom of the amine; when two or more L₂₂'s are present, one or more sets of the adjacent two or more of the two or more L₂₂'s form a substituted or unsubstituted single ring by bonding with each other, form a substituted or unsubstituted fused ring by bonding with each other, or do not form the ring; when two or more L₂₂'s are present, the two or more L₂₂'s may be the same as or different from each other;

n23 is an integer of 0 to 3; when n23 is 0, Ar₂₃ is directly bonded with the nitrogen atom of the amine via a single bond; when n23 is 2 or 3, a plurality of L₂₃'s is linked in series with each other and Ar₂₃ is bonded with L₂₃ which is farthest from the nitrogen atom of the amine; when two or more L₂₃'s are present, one or more sets of the adjacent two or more of the two or more L₂₃'s form a substituted or unsubstituted single ring by bonding with each other, form a substituted or unsubstituted fused ring by bonding with each other, or do not form the ring; when two or more L₂₃'s are present, the two or more L₂₃'s may be the same as or different from each other; and

L₂₁, L₂₂, and L₂₃ which do not form the ring are independently

a single bond,

a substituted or unsubstituted arylene group having 6 to 50 ring carbon atoms, or

a substituted or unsubstituted divalent heterocyclic group having 5 to 50 ring atoms.

The second compound is different from the first compound. The expression “the second compound is different from the first compound” includes the case where chemical structures (skeletons) are different from each other, and the case where chemical structures (skeletons) are the same and they include the different isotopes. The isotope means a atom having the same atomic number and having the different number of neutorns. For example, a benzene (C₆H₆) and a deuterated benzene (C₆D₆) are different componds each other.

When chemical structures (skeletons) are the same and they include the different isotopes, and when compounds have the different numbers of or the different configurations of isotopes, the compounds are different from each other. For example, even when compunds are deuterated benzenes, C₆H₅D₁ and C₆D₆ are different componds each other. Further, for example, even when compounds are represented by C₆H₄D₂, a compound having deuterium atoms at 1st-position and 2nd-position of benzene ring and a compound having deuterium atoms at 1st-position and 3rd-position of benzene ring are different from each other, since they have different configurations of isotoopes.

In one embodiment, Ar₂₁ is

a substituted or unsubstituted aryl group having 6 to 50 ring carbon atoms, or

a substituted or unsubstituted monovalent heterocyclic group having 5 to 50 ring atoms.

In one embodiment, Ar₂₂ is

a substituted or unsubstituted aryl group having 6 to 18 ring carbon atoms, or

a substituted or unsubstituted monovalent heterocyclic group having 5 to 18 ring atoms.

In one embodiment, Ar₂₂ is

a substituted or unsubstituted aryl group having 6 to 50 ring carbon atoms, or

a substituted or unsubstituted monovalent heterocyclic group having 5 to 50 ring atoms.

In one embodiment, Ar₂₂ is

a substituted or unsubstituted aryl group having 6 to 18 ring carbon atoms, or

a substituted or unsubstituted monovalent heterocyclic group having 5 to 18 ring atoms.

In one embodiment, Ar₂₃ is

a substituted or unsubstituted aryl group having 6 to 50 ring carbon atoms, or

a substituted or unsubstituted monovalent heterocyclic group having 5 to 50 ring atoms.

In one embodiment, Ar₂₃ is

a substituted or unsubstituted aryl group having 6 to 18 ring carbon atoms, or

a substituted or unsubstituted monovalent heterocyclic group having 5 to 18 ring atoms.

In one embodiment, Ar₂₁ is a substituted or unsubstituted aryl group having 6 to 50 ring carbon atoms,

Ar₂₂ is a substituted or unsubstituted aryl group having 6 to 50 ring carbon atoms, and

Ar₂₃ is a substituted or unsubstituted monovalent heterocyclic group having 5 to 50 ring atoms.

In one embodiment, L₂₁ is a single bond, or a substituted or unsubstituted arylene group having 6 to 50 ring carbon atoms.

In one embodiment, L₂₁ is a single bond, or a substituted or unsubstituted arylene group having 6 to 18 ring carbon atoms.

In one embodiment, L₂₁ is a single bond, a substituted or unsubstituted phenylene group, or a substituted or unsubstituted naphthylene group.

In one embodiment, L₂₂ is a single bond, or a substituted or unsubstituted arylene group having 6 to 50 ring carbon atoms.

In one embodiment, L₂₂ is a single bond, or a substituted or unsubstituted arylene group having 6 to 18 ring carbon atoms.

In one embodiment, L₂₂ is a single bond, a substituted or unsubstituted phenylene group, or a substituted or unsubstituted naphthylene group.

In one embodiment, L₂₃ is a single bond, or a substituted or unsubstituted arylene group having 6 to 50 ring carbon atoms.

In one embodiment, L₂₃ is a single bond, or a substituted or unsubstituted arylene group having 6 to 18 ring carbon atoms.

In one embodiment, L₂₃ is a single bond, a substituted or unsubstituted phenylene group, or a substituted or unsubstituted naphthylene group.

In one embodiment, n21 is 1 or 2.

In one embodiment, n22 is 1 or 2.

In one embodiment, n23 is 1 or 2.

In one embodiment, n23 is 2.

In one embodiment, the compound represented by the formula (21) is a compound represented by the following formula (22):

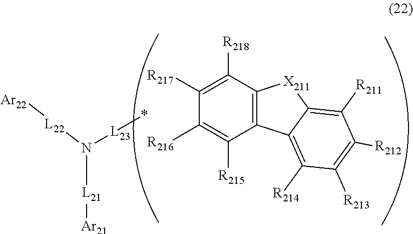

wherein in the formula (22),

Ar₂₁, Ar₂₂ and L₂₁ to L₂₃ are the same as defined in the formula (21);

X₂₁₁ is C(Rₐ)(R_{b}), N(R₂₁₉), O, or S;

any one of R₂₁₉ in the case where X₂₁₁ is N(R₂₁₉) and R₂₁₁ to R₂₁₈ represents a bond with L₂₃; when L₂₃ is a single bond, any of carbon atoms in the skeleton among the structure in the above parentheses and N in the case where X₂₁₁ is N(R₂₁₉) is directly bonded with the nitrogen atom of the amine via a single bond;

one or more sets of the adjacent two or more of R₂₁₁ to R₂₁₈ which do not represent a bond with L₂₃ do not bond with each other;

R₂₁₁ to R₂₁₉ which do not represent a bond with L₂₃ are independently a hydrogen atom, or a substituent R;

Rₐ and R_{b}

form a substituted or unsubstituted single ring by bonding with each other,

form a substituted or unsubstituted fused ring by bonding with each other, or

do not bond with each other;

Rₐ and R_{b} which do not form the substituted or unsubstituted single ring and which do not form the substituted or unsubstituted fused ring are independently

a substituted or unsubstituted alkyl group having 1 to 10 carbon atoms, or

a substituted or unsubstituted aryl group having 6 to 18 ring carbon atoms;

the substituent R is selected from the group consisting of

a substituted or unsubstituted alkyl group having 1 to 50 carbon atoms,

a substituted or unsubstituted alkenyl group having 2 to 50 carbon atoms,

a substituted or unsubstituted alkynyl group having 2 to 50 carbon atoms,

a substituted or unsubstituted cycloalkyl group having 3 to 50 ring carbon atoms,

—Si(R₉₀₁)(R₉₀₂)(R₉₀₃),

—O—(R₉₀₄),

—S—(R₉₀₅),

—N(R₉₀₆)(R₉₀₇)

(wherein R₉₀₁ to R₉₀₇ are independently

a hydrogen atom,

a substituted or unsubstituted alkyl group having 1 to 50 carbon atoms,

a substituted or unsubstituted cycloalkyl group having 3 to 50 ring carbon atoms,

a substituted or unsubstituted aryl group having 6 to 50 ring carbon atoms, or

a substituted or unsubstituted monovalent heterocyclic group having 5 to 50 ring atoms; when two or more of each of R₉₀₁ to R₉₀₇ are present, the two or more of each of R₉₀₁ to R₉₀₇ may be the same as or different from each other),

a halogen atom, a cyano group, a nitro group,

a substituted or unsubstituted aryl group having 6 to 50 ring carbon atoms, and

a substituted or unsubstituted monovalent heterocyclic group having 5 to 50 ring atoms; and

when two or more substituents R are present, the two or more substituents R may be the same as or different from each other.

The expression “when L₂₃ is a single bond, any of carbon atoms in the skeleton among the structure in the above parentheses and N in the case where X₂₁₁ is N(R₂₁₉) is directly bonded with the nitrogen atom of the amine via a single bond” will be described.

When R₂₁₆ represents a bond with L₂₃ and L₂₃ is a single bond, the compound represented by the formula (22) is as follows.

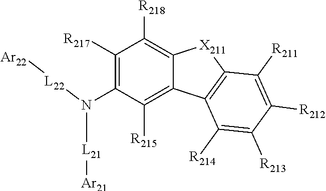

When R₂₁₉ represents a bond with L₂₃ in the case where X₂₁₁ is N(R₂₁₉), and when L₂₃ is a single bond, the compound represented by the formula (22) is as follows.

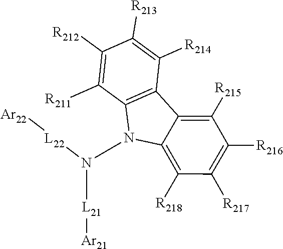

In one embodiment, X₂₁₁ is N(R₂₁₉), O, or S.

In one embodiment, X₂₁₁ is N(R₂₁₉).

In one embodiment, X₂₁₁ is O or S.

In one embodiment, R₂₁₁ to R₂₁₉ which do not represent a bond with L₂₃ are a hydrogen atom.

In one embodiment, the compound represented by the formula (22) is a compound represented by the following formula (22-1) or (22-2):

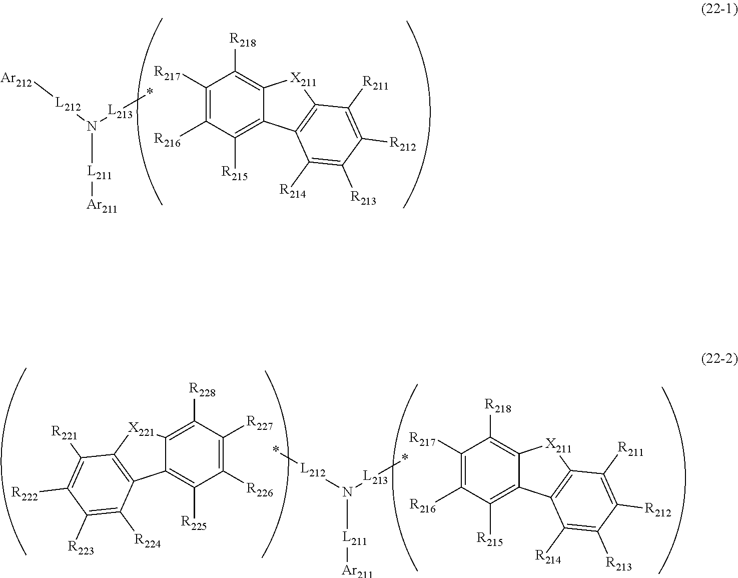

wherein in the formula (22-1),

X₂₁₁ and R₂₁₁ to R₂₁₈ are the same as defined in the formula (22);

Ar₂₁₁ and Ar₂₁₂ are independently

a substituted or unsubstituted aryl group having 6 to 50 ring carbon atoms, or

—Si(R_{C1})(R_{C2})(R_{C3});

R_{C1} to R_{C3} are the same as defined in the formula (12);

L₂₁₁, L₂₁₂, and L₂₁₃ are independently

a single bond,

a substituted or unsubstituted arylene group having 6 to 50 ring carbon atoms, or

a substituted or unsubstituted divalent heterocyclic group having 5 to 50 ring atoms;

in the formula (22-2),

X₂₁₁ and R₂₁₁ to R₂₁₈ are the same as defined in the formula (22);

Ar₂₁₁ is

a substituted or unsubstituted aryl group having 6 to 50 ring carbon atoms, or

—Si(R_{C1})(R_{C2})(R_{C3});

R_{C1} to R_{C3} are the same as defined in the formula (12);

L₂₁₁, L₂₁₂, and L₂₁₃ are independently

a single bond,

a substituted or unsubstituted arylene group having 6 to 50 ring carbon atoms, or

a substituted or unsubstituted divalent heterocyclic group having 5 to 50 ring atoms;

X₂₂₁ is C(Rₐ)(R_{b}), N(R₂₂₉), O, or S;

any one of R₂₂₉ in the case where X₂₂₁ is N(R₂₂₉) and R₂₂₁ to R₂₂₈ represents a bond with L₂₁₂; when L₂₁₂ is a single bond, any of carbon atoms in the skeleton among the structure in the above parentheses and N in the case where X₂₂₁ is N(R₂₂₉) is directly bonded with the nitrogen atom of the amine via a single bond;

one or more sets of the adjacent two or more of R₂₂₁ to R₂₂₈ which do not represent a bond with L₂₁₂ do not bond with each other;

R₂₂₁ to R₂₂₉ which do not represent a bond with L₂₁₃ are independently a hydrogen atom, or a substituent R;

Rₐ and R_{b}

form a substituted or unsubstituted single ring by bonding with each other,

form a substituted or unsubstituted fused ring by bonding with each other, or

do not bond with each other;

Rₐ and R_{b} which do not form the substituted or unsubstituted single ring and which do not form the substituted or unsubstituted fused ring are independently

a substituted or unsubstituted alkyl group having 1 to 10 carbon atoms, or

a substituted or unsubstituted aryl group having 6 to 18 ring carbon atoms; and

the substituent R are the same as defined in the formula (22).

In one embodiment, the compound represented by the formula (22) is a compound represented by the following formula (23):

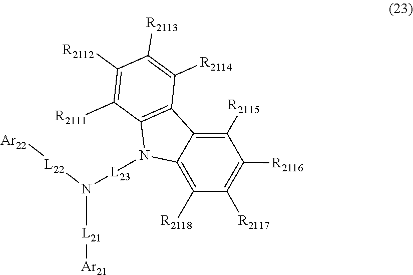

wherein in the formula (23), Ar₂₁, Ar₂₂ and L₂₁ to L₂₃ are the same as defined in the formula (21);

one or more sets of the adjacent two or more of R₂₁₁₁ to R₂₁₁₈ do not bond with each other;

R₂₁₁₁ to R₂₁₁₈ are independently a hydrogen atom, or a substituent R; and

the substituent R are the same as defined in the formula (22).

In one embodiment, R₂₁₁₁ to R₂₁₁₈ are a hydrogen atom.

In one embodiment, the compound represented by the formula (22) is a compound represented by the following formula (24-1) or (24-2):

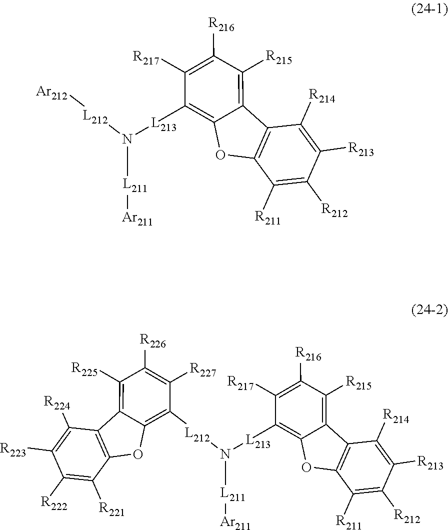

wherein in the formulas (24-1) and (24-2), Ar₂₁₁, Ar₂₁₂, L₂₁₁ to L₂₁₃, R₂₁₁ to R₂₁₇, and R₂₂₁ to R₂₂₇ are the same as defined in the formulas (22-1) and (22-2).

In one embodiment, Ar₂₁ and Ar₂₂ are independently a substituted or unsubstituted aryl group having 6 to 50 ring carbon atoms, or —Si(R_{C1})(R_{C2})(R_{C3}).

In one embodiment, the ionization potential of the first compound in the first composition is 5.7 eV or less, and is, for example, 5.65 eV or less, or 5.6 eV or less.

In one embodiment, the ionization potential of the second compound in the first composition is 5.6 eV or more, and is, for example, 5.65 eV or more, or 5.7 eV or more.

The ionization potential (Ip) is measured by the method described in the Examples.

In one embodiment, the ionization potential of the second compound in the first composition is larger than the ionization potential of the first compound in the first composition by 0.1 eV or more.

In one embodiment, the hole mobility of the first compound in the first composition is larger than 1.0×10⁻⁵ cm²/(V·s), and is, for example, larger than 5.0×10⁻⁵ cm²/(V·s), or larger than 1×10⁻⁴ cm²/(V·s).

In one embodiment, the hole mobility of the second compound in the first composition is smaller than 1.0×10⁻⁵ cm²/(V·s), and is, for example, smaller than 0.5×10−5 cm²/(V·s), or smaller than 1.0×10⁻⁶ cm²/(V·s).

When the second compound having larger ionization potential value and smaller hole mobility is combined with the first compound relatively having smaller ionization potential value and larger hole mobility, effects improving the hole-injecting property to the emitting layer and improving the device lifetime while maintaining the efficiency are further expected.

The hole mobility (μh) is measured by the method described in the Examples.

### (Composition)

The amount ratio of the first compound and the second compound in the first composition is not particularly limited, and the amount ratio of materials can be appropriately determined depending on effects desired for the composition.

In one embodiment, the amount of the first compound is 30 to 70% by mass based on the total amount of the first compound and the second compound in the first composition, and it may be 40 to 60% by mass.

The first composition may or may not include a component other than the first compound and the second compound. In one embodiment, the composition substantially consists of the first compound and the second compound.

The expression “substantially consists of the first compound and the second compound” refers that the first composition includes no other component or includes extreamly small amount of other component as long as the effects of the present invention are not impaired. For example, the expression includes the case where unavoidable impurities are immixed therein.

In one embodiment, 80% by mass or more, 90% by mass or more, 95% by mass or more, 99% by mass or more, 99.5% by mass or more, 99.9% by mass or more, 99.99% by mass or more, or 100% by mass of the first composition is the first compound and the second compound.

In one embodiment, 80 mol % or more, 90 mol % or more, 95 mol % or more, 99 mol % or more, 99.5 mol % or more, 99.9 mol % or more, 99.99 mol % or more, or 100 mol % of the first composition is the first compound and the second compound.

In one embodiment, the first composition consists of the first compound and the second compound.

### (Shape, Production Method, and the Like)

The form of the first composition is not particularly limited, and for example, solid, powder, solution, and a film (layer) can be given. As the film (layer), for example, an organic layer configuring the organic EL device (for example, a hole-injecting layer, a hole-transporting layer and an electron-blocking layer) can be used. When the composition according to an aspect of the present invention is solid-like or powder-like, it may be formed in the shape of pellet.

When the composition is powder-like (mixed powder), it may be the mixed powder containing the first compound and the second compound in one particle, or it may be the mixed powder in which a particle composed of the first compound and a particle composed of the second compound are mixed.

A method for producing mixed powder, for example, may include pulverizing and mixing the first compound and the second compound by using a mortar and the like, or may include putting the first compound and the second compound in a container and the like, heating and melting them under a chemically inert environment, subsequently, cooling them to the ambient temperature, and pulverizing the obtained mixture by using a mixer and the like to obtain powder. The latter method can lead mixing the first compound and the second compound at the molecular level to allow more uniform deposition. It can also prevent problems such as mix unevenness which can be caused during transport of the mixed powder.

The mixed powder may be compressed and formed to be pellet-like.

In one embodiment, the first composition can be used for a deposition method (including a vacuum deposition method), that is, it can be used for any technical field including depositing an organic compound to form a film.

The expression “can be used for a deposition method (including a vacuum deposition method)” can also be rephrased as the words “for a deposition method (or for a vacuum deposition method)”.

### [Second Composition]

A second composition according to an aspect of the present invention includes a first compound and a second compound, wherein the first compound is a compound represented by the formula (11) (hereinafter, also referred to as a “first compound in the second composition”), and the second compound is a compound represented by the formula (23) (hereinafter, also referred to as a “second compound in the second composition”).

When the second composition includes two compounds having the specific structures, the second composition is used in an organic EL device to be capable of enhancing the device performance thereof. Specifically, an organic EL device having high efficiency and long lifetime can be achieved.

Each member of the second composition will be described below.

### (First Compound in Second Composition)

A first compound in the second composition is a compound represented by the following formula (11):

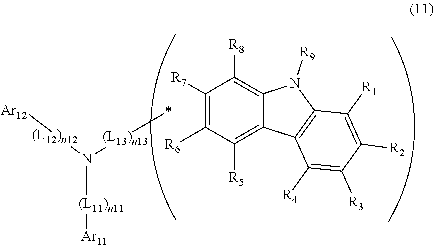

wherein in the formula (11),

Ar₁₁ and Ar₁₂ are independently

a substituted or unsubstituted aryl group having 6 to 50 ring carbon atoms,

a substituted or unsubstituted monovalent heterocyclic group having 5 to 50 ring atoms, or

—Si(R_{C1})(R_{C2})(R_{C3});

R_{C1} to R_{C3} are independently a substituted or unsubstituted aryl group having 6 to 50 ring carbon atoms,

when a plurality of each of R_{C1} to R_{C3} are present, the plurality of each of R_{C1} to R_{C3} may be the same as or different from each other;

any one of R₁ to R₈ represents a bond with L₁₃;

one or more sets of the adjacent two or more of R₁ to R₈ which do not represent a bond with L₁₃

form a substituted or unsubstituted single ring by bonding with each other,

form a substituted or unsubstituted fused ring by bonding with each other, or

do not bond with each other;

R₉, and R₁ to R₈ which do not represent a bond with L₁₃, which do not form the substituted or unsubstituted single ring and which do not form the substituted or unsubstituted fused ring are independently

a hydrogen atom,

a cyano group,

a substituted or unsubstituted alkyl group having 1 to 50 carbon atoms,

a substituted or unsubstituted halogenated alkyl group having 1 to 50 carbon atoms,

a substituted or unsubstituted cycloalkyl group having 3 to 50 ring carbon atoms,

a group represented by —Si(R_{901A})(R_{902A})(R_{903A}),

a group represented by —O—(R_{904A}),

a substituted or unsubstituted aryl group having 6 to 50 ring carbon atoms, or

a substituted or unsubstituted monovalent heterocyclic group having 5 to 50 ring atoms;

R_{901A} to R_{904A} are independently

a hydrogen atom,

a substituted or unsubstituted alkyl group having 1 to 50 carbon atoms,

a substituted or unsubstituted cycloalkyl group having 3 to 50 ring carbon atoms,

a substituted or unsubstituted aryl group having 6 to 50 ring carbon atoms, or

a substituted or unsubstituted monovalent heterocyclic group having 5 to 50 ring atoms;

when a plurality of each of R_{901A} to R_{904A} are present, the plurality of each of R_{901A} to R_{904A} may be the same as or different from each other;

n11 is an integer of 0 to 3; when n11 is 0, Ar₁₁ is directly bonded with the nitrogen atom of the amine via a single bond; when n11 is 2 or 3, a plurality of L₁₁'s is linked in series with each other and Ar₁₁ is bonded with L₁₁ which is farthest from the nitrogen atom of the amine; when two or more L₁₁'s are present, one or more sets of the adjacent two or more of the two or more L₁₁'s form a substituted or unsubstituted single ring by bonding with each other, form a substituted or unsubstituted fused ring by bonding with each other, or do not form the ring; when two or more L₁₁'s are present, the two or more L₁₁'s may be the same as or different from each other;

n12 is an integer of 0 to 3; when n12 is 0, Ar₁₂ is directly bonded with the nitrogen atom of the amine via a single bond; when n12 is 2 or 3, a plurality of L₁₂'s is linked in series with each other and Ar₁₂ is bonded with L₁₂ which is farthest from the nitrogen atom of the amine; when two or more L₁₂'s are present, one or more sets of the adjacent two or more of the two or more L₁₂'s form a substituted or unsubstituted single ring by bonding with each other, form a substituted or unsubstituted fused ring by bonding with each other, or do not form the ring; when two or more L₁₂'s are present, the two or more L₁₂'s may be the same as or different from each other;

n13 is an integer of 0 to 3; when n13 is 0, the carbon atom of the carbazole skeleton is directly bonded with the nitrogen atom of the amine via a single bond; when n13 is 2 or 3, a plurality of L₁₃'s is linked in series with each other and the carbazole skeleton is bonded with L₁₃ which is farthest from the nitrogen atom of the amine; when two or more L₁₃'s are present, one or more sets of the adjacent two or more of the two or more L₁₃'s form a substituted or unsubstituted single ring by bonding with each other, form a substituted or unsubstituted fused ring by bonding with each other, or do not form the ring; when two or more L₁₃'s are present, the two or more L₁₃'s may be the same as or different from each other;

L₁₁, L₁₂, and L₁₃ which do not form the ring are independently

a single bond,

a substituted or unsubstituted arylene group having 6 to 50 ring carbon atoms, or

a substituted or unsubstituted divalent heterocyclic group having 5 to 50 ring atoms.

The first compound in the second composition is the same as the first compound in the first composition, except that a bonding position of the carbazole skeleton represented by the structure in the parentheses of the formula (11) is not limited to 4th-position (the case where R₄ or R₅ represents a bond with L₁₃), and those described above in the first compound of the first composition can be used for it.

In one embodiment, one or more sets of the adjacent two or more of R₁ to R₈ do not bond with each other.

In one embodiment, R₁ to R₈ are independently

a hydrogen atom,

a substituted or unsubstituted alkyl group having 1 to 50 carbon atoms,

a substituted or unsubstituted aryl group having 6 to 50 ring carbon atoms, or

a substituted or unsubstituted monovalent heterocyclic group having 5 to 50 ring atoms.

In one embodiment, R₁ to R₈ are independently

a hydrogen atom,

a substituted or unsubstituted alkyl group having 1 to 50 carbon atoms, or

a substituted or unsubstituted aryl group having 6 to 50 ring carbon atoms.

In one embodiment, R₁ to R₈ are independently

a hydrogen atom,

a substituted or unsubstituted alkyl group having 1 to 18 carbon atoms, or

a substituted or unsubstituted aryl group having 6 to 18 ring carbon atoms.

In one embodiment, R₁ to R₈ are independently a hydrogen atom.

In one embodiment, R₉ is

a hydrogen atom,

a substituted or unsubstituted alkyl group having 1 to 50 carbon atoms, or

a substituted or unsubstituted aryl group having 6 to 50 ring carbon atoms.

In one embodiment, R₉ is

a hydrogen atom,

a substituted or unsubstituted alkyl group having 1 to 18 carbon atoms, or

a substituted or unsubstituted aryl group having 6 to 18 ring carbon atoms.

In one embodiment, R₉ is a substituted or unsubstituted phenyl group, a substituted or unsubstituted biphenyl group (p-biphenyl group, m-biphenyl group or o-biphenyl group), or a substituted or unsubstituted naphthyl group (1-naphthyl group or 2-naphthyl group).

In one embodiment, the compound represented by the formula (11) is a compound represented by the following formula (11-1):

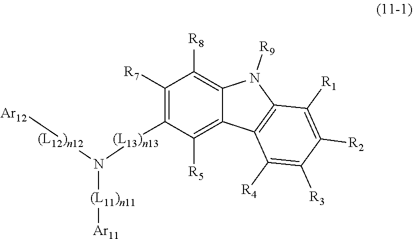

wherein in the formula (11-1), Ar₁₁, Ar₁₂, n11, n12, n13, L₁₁, L₁₂, L₁₃, R₁ to R₅, and R₇ to R₉ are the same as defined in the formula (11).

In one embodiment, the first compound in the second composition is the compound represented by the formula (12). The compound represented by the formula (12) is the same as the compound of the formula (12) described above in the first compound of the first composition, and those described above can be used for it.

In one embodiment, the first compound in the second composition is the compound represented by the formula (12-1) or (12-2). The formulas (12-1) and (12-2) are the same as the compounds of the formulas (12-1) and (12-2) described above in the first compound of the first composition, and those described above can be used for it.

### (Second Compound in Second Composition)

A second compound in the second composition is the compound represented by the formula (23). The compound represented by the formula (23) is the same as the compound of the formula (23) described above in the second compound of the first composition, and those described above can be used for it.

In one embodiment, the second compound in the second composition is the compound represented by the formula (24-1) or (24-2). The compounds represented by the formulas (24-1) and (24-2) are the same as the compounds of the formulas (24-1) and (24-2) described above in the second compound of the first composition, and those described above can be used for it.

Others described above in the first composition can be used for those of the second composition. That is, the ionization potential, the hole mobility, the formulation, the shape, the production method, and the like described in the first composition can be used for those of the second composition.

### (First Compound in First Composition and Second Composition)

The first compound in the first composition and the second composition can be synthesized by using known alternative reactions or raw materials adapted to the target compound.

Specific examples of the first compound in the first composition and the second composition will be described below, but these are merely examples, and it is not limited to the following specific examples.

As specific examples of the first compound in the first composition, a cmopound satisfying the formula (12) can be given among the following compounds. As specific examples of the first compound in the second composition, all of the following compounds can be given.

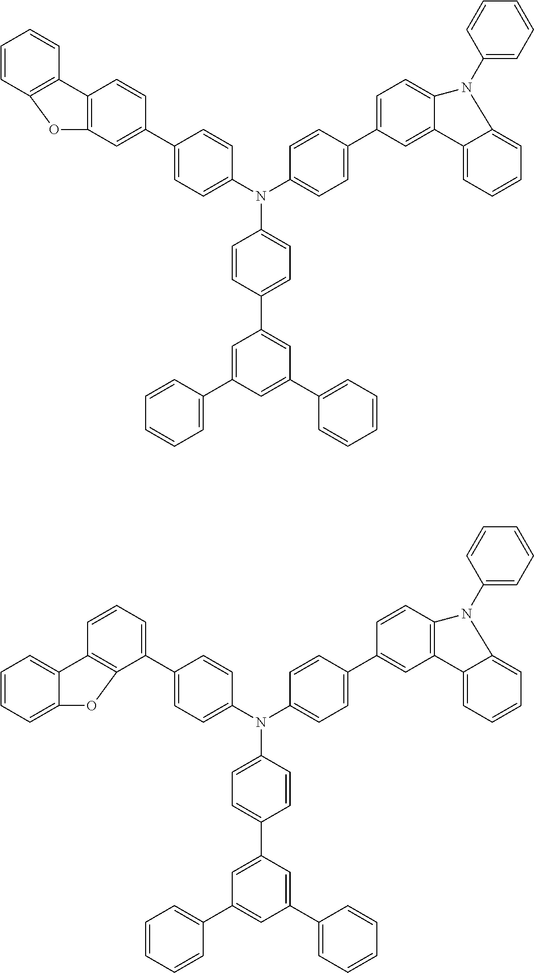 [SMILES: c1ccc(-c2cc(-c3ccccc3)cc(-c3ccc(N(c4ccc(-c5ccc6c(c5)oc5ccccc56)cc4)c4ccc(-c5ccc6c(c5)c5ccccc5n6-c5ccccc5)cc4)cc3)c2)cc1 ; c1ccc(-c2cc(-c3ccccc3)cc(-c3ccc(N(c4ccc(-c5ccc6c(c5)c5ccccc5n6-c5ccccc5)cc4)c4ccc(-c5cccc6c5oc5ccccc56)cc4)cc3)c2)cc1]

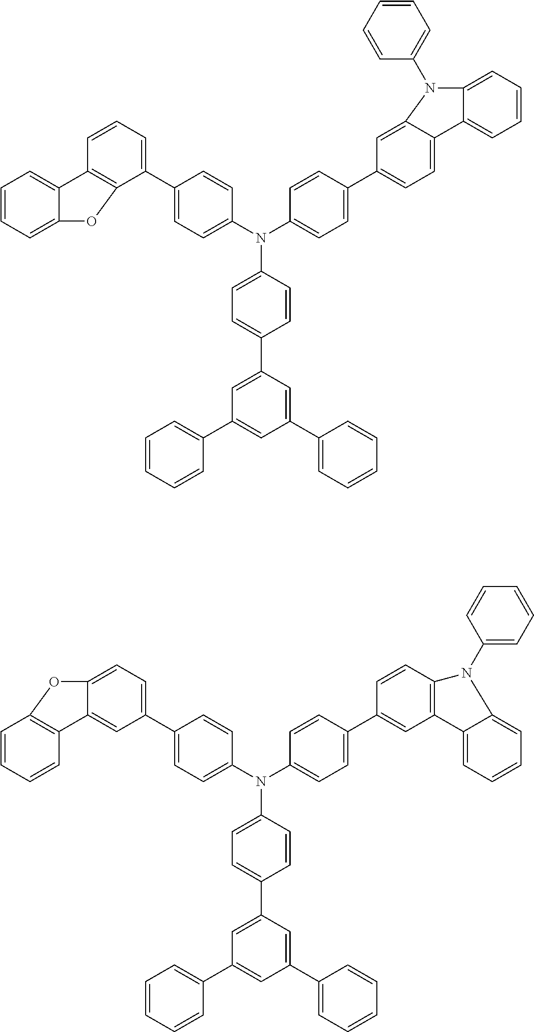 [SMILES: c1ccc(-c2cc(-c3ccccc3)cc(-c3ccc(N(c4ccc(-c5ccc6c7ccccc7n(-c7ccccc7)c6c5)cc4)c4ccc(-c5cccc6c5oc5ccccc56)cc4)cc3)c2)cc1 ; c1ccc(-c2cc(-c3ccccc3)cc(-c3ccc(N(c4ccc(-c5ccc6oc7ccccc7c6c5)cc4)c4ccc(-c5ccc6c(c5)c5ccccc5n6-c5ccccc5)cc4)cc3)c2)cc1]

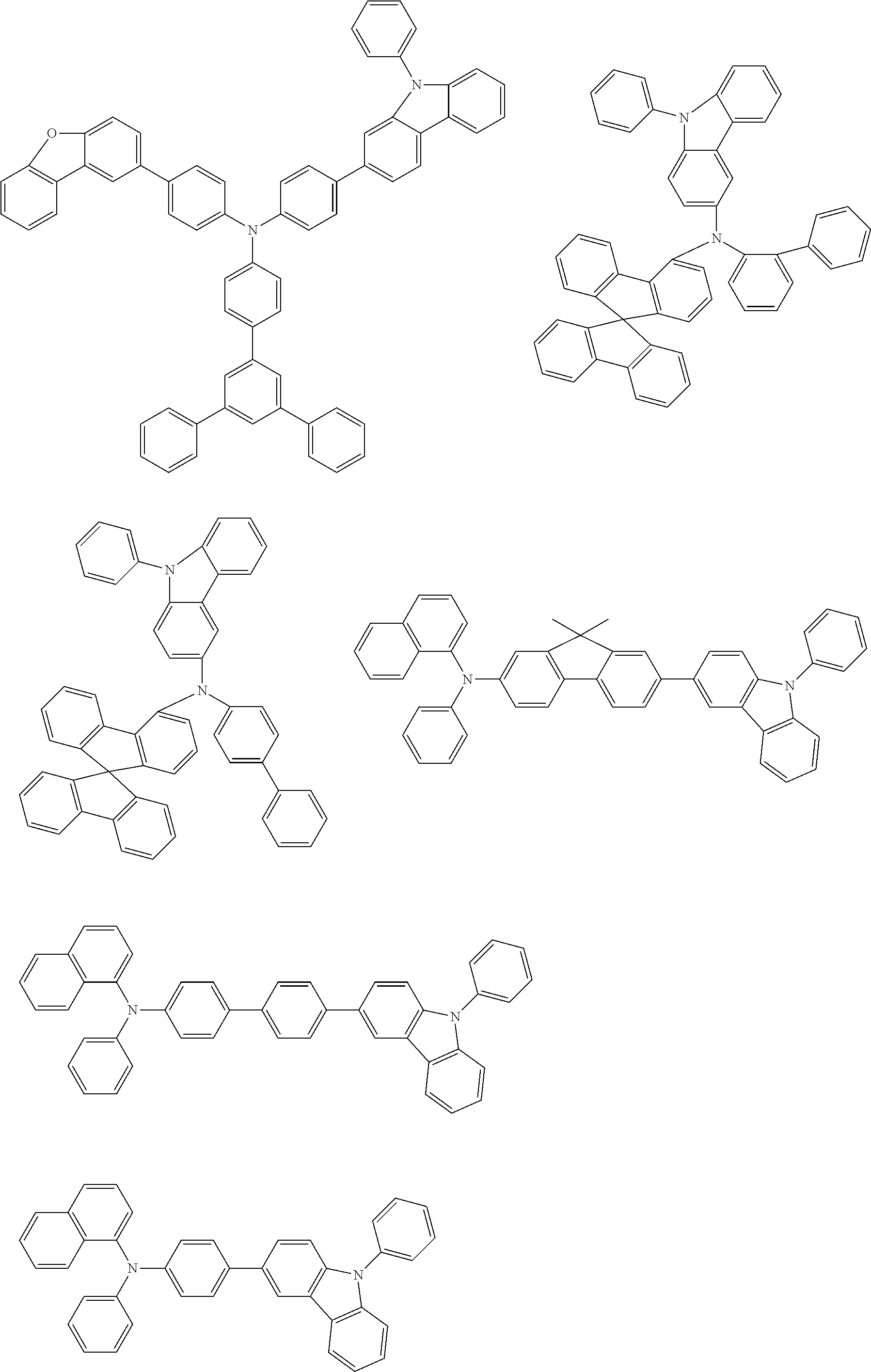

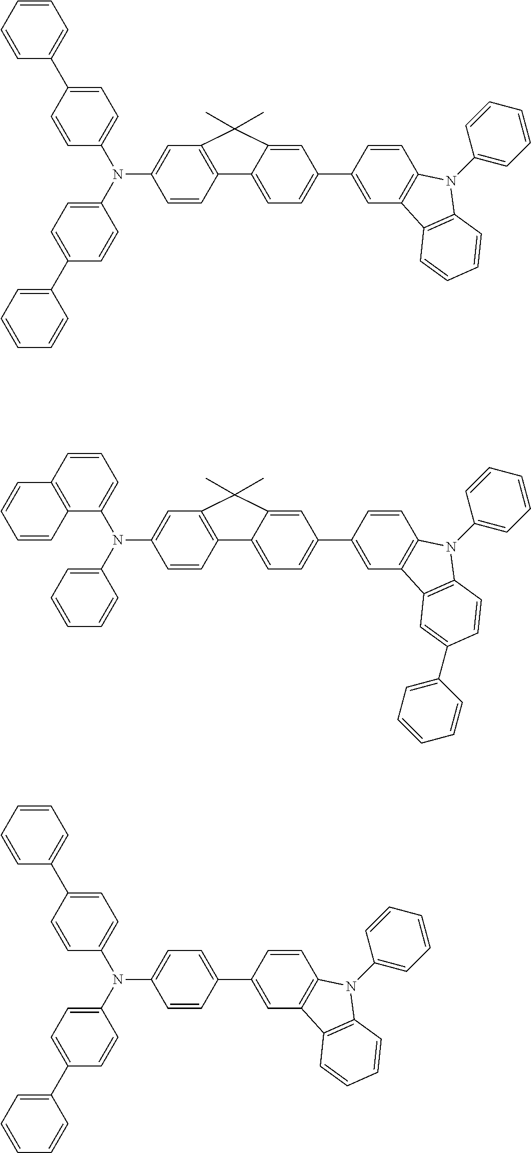 [SMILES: CC1(C)c2cc(-c3ccc4c(c3)c3ccccc3n4-c3ccccc3)ccc2-c2ccc(N(c3ccc(-c4ccccc4)cc3)c3ccc(-c4ccccc4)cc3)cc21 ; CC1(C)c2cc(-c3ccc4c(c3)c3cc(-c5ccccc5)ccc3n4-c3ccccc3)ccc2-c2ccc(N(c3ccccc3)c3cccc4ccccc34)cc21 ; c1ccc(-c2ccc(N(c3ccc(-c4ccccc4)cc3)c3ccc(-c4ccc5c(c4)c4ccccc4n5-c4ccccc4)cc3)cc2)cc1]

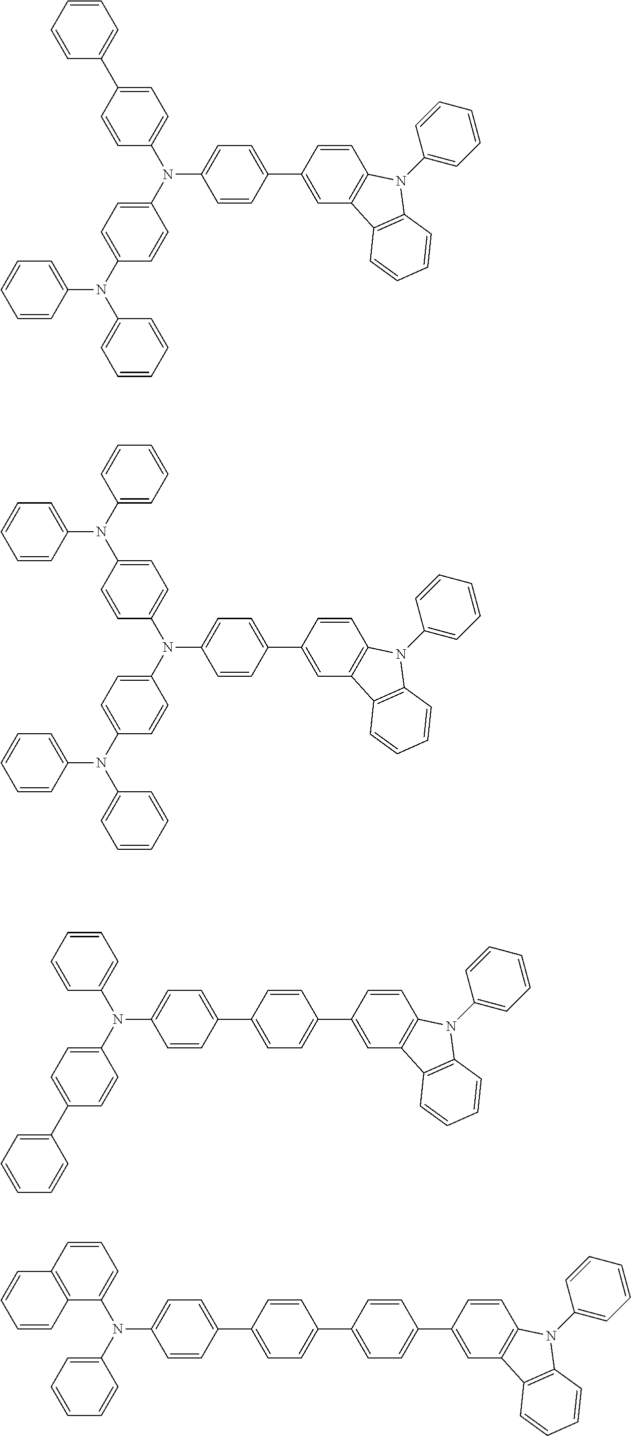 [SMILES: c1ccc(-c2ccc(N(c3ccc(-c4ccc5c(c4)c4ccccc4n5-c4ccccc4)cc3)c3ccc(N(c4ccccc4)c4ccccc4)cc3)cc2)cc1 ; c1ccc(N(c2ccccc2)c2ccc(N(c3ccc(-c4ccc5c(c4)c4ccccc4n5-c4ccccc4)cc3)c3ccc(N(c4ccccc4)c4ccccc4)cc3)cc2)cc1 ; c1ccc(-c2ccc(N(c3ccccc3)c3ccc(-c4ccc(-c5ccc6c(c5)c5ccccc5n6-c5ccccc5)cc4)cc3)cc2)cc1 ; c1ccc(N(c2ccc(-c3ccc(-c4ccc(-c5ccc6c(c5)c5ccccc5n6-c5ccccc5)cc4)cc3)cc2)c2cccc3ccccc23)cc1]

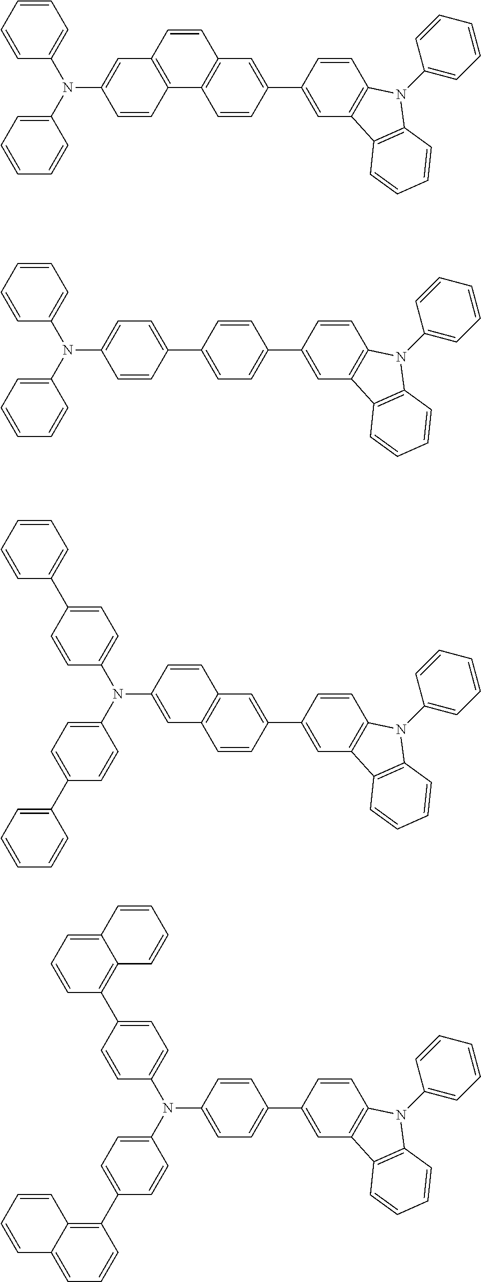 [SMILES: c1ccc(N(c2ccccc2)c2ccc3c(ccc4cc(-c5ccc6c(c5)c5ccccc5n6-c5ccccc5)ccc43)c2)cc1 ; c1ccc(N(c2ccccc2)c2ccc(-c3ccc(-c4ccc5c(c4)c4ccccc4n5-c4ccccc4)cc3)cc2)cc1 ; c1ccc(-c2ccc(N(c3ccc(-c4ccccc4)cc3)c3ccc4cc(-c5ccc6c(c5)c5ccccc5n6-c5ccccc5)ccc4c3)cc2)cc1 ; c1ccc(-n2c3ccccc3c3cc(-c4ccc(N(c5ccc(-c6cccc7ccccc67)cc5)c5ccc(-c6cccc7ccccc67)cc5)cc4)ccc32)cc1]

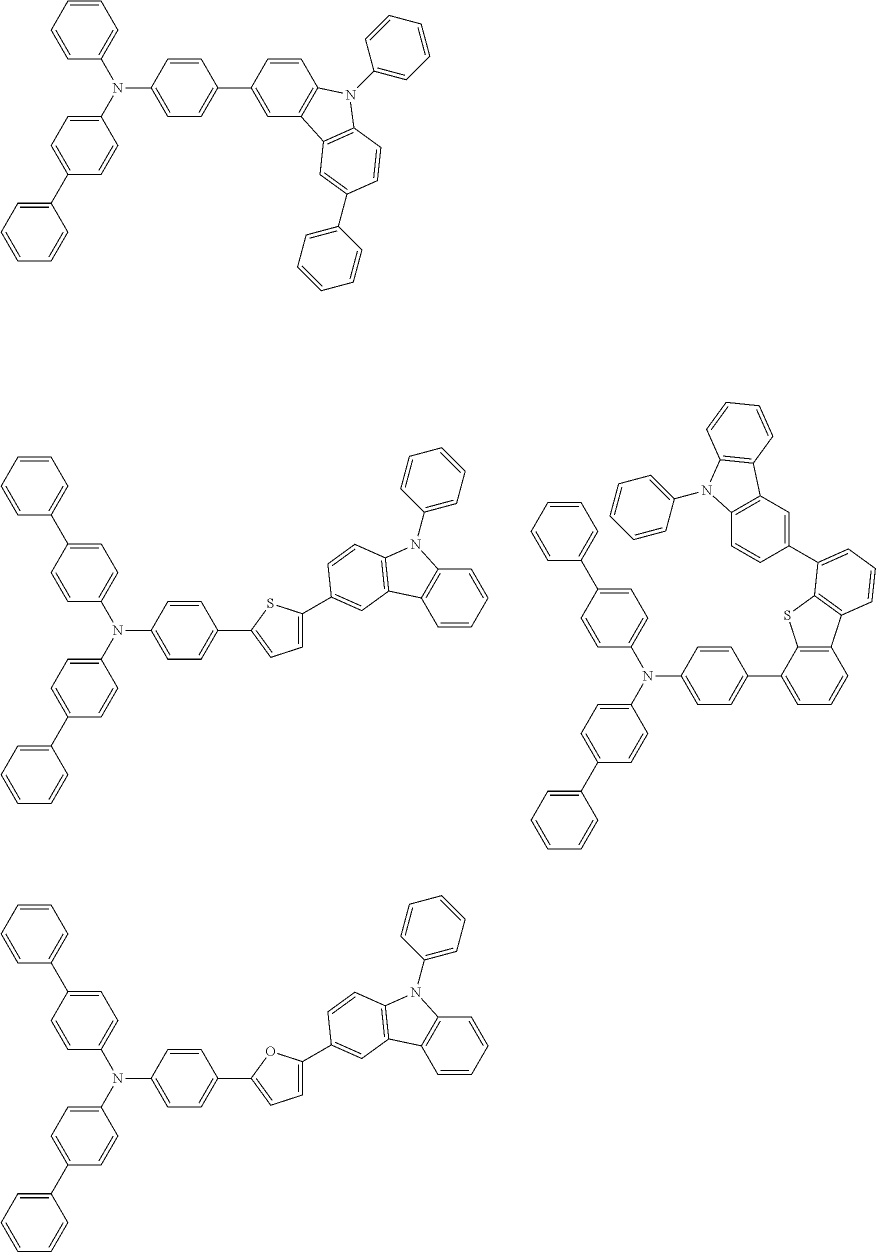 [SMILES: c1ccc(-c2ccc(N(c3ccccc3)c3ccc(-c4ccc5c(c4)c4cc(-c6ccccc6)ccc4n5-c4ccccc4)cc3)cc2)cc1 ; c1ccc(-c2ccc(N(c3ccc(-c4ccccc4)cc3)c3ccc(-c4ccc(-c5ccc6c(c5)c5ccccc5n6-c5ccccc5)s4)cc3)cc2)cc1 ; c1ccc(-c2ccc(N(c3ccc(-c4ccccc4)cc3)c3ccc(-c4cccc5c4sc4c(-c6ccc7c(c6)c6ccccc6n7-c6ccccc6)cccc45)cc3)cc2)cc1 ; c1ccc(-c2ccc(N(c3ccc(-c4ccccc4)cc3)c3ccc(-c4ccc(-c5ccc6c(c5)c5ccccc5n6-c5ccccc5)o4)cc3)cc2)cc1]

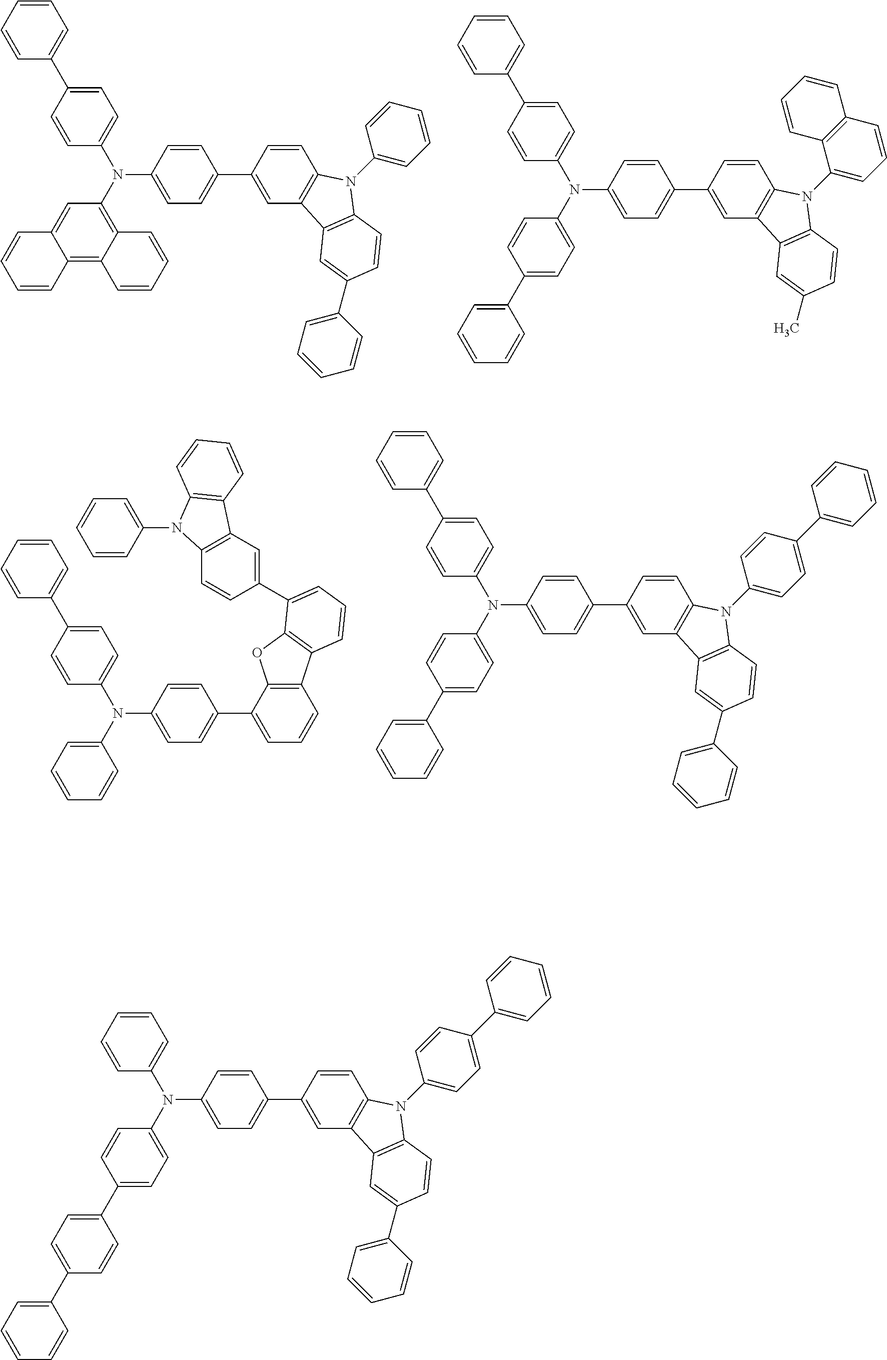

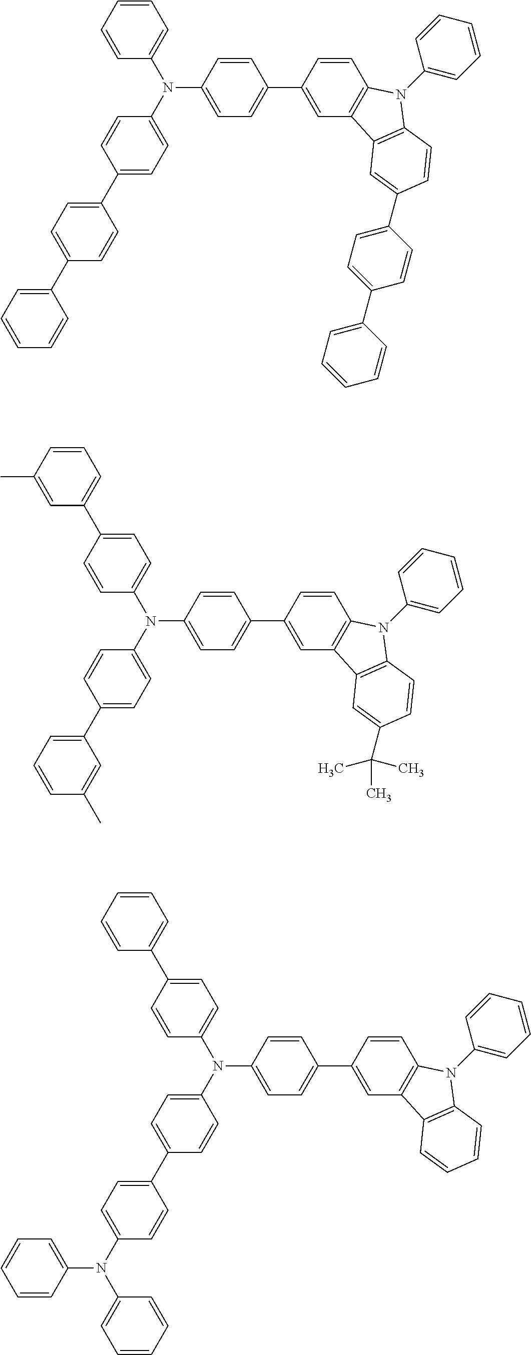 [SMILES: c1ccc(-c2ccc(-c3ccc(N(c4ccccc4)c4ccc(-c5ccc6c(c5)c5cc(-c7ccc(-c8ccccc8)cc7)ccc5n6-c5ccccc5)cc4)cc3)cc2)cc1 ; Cc1cccc(-c2ccc(N(c3ccc(-c4cccc(C)c4)cc3)c3ccc(-c4ccc5c(c4)c4cc(C(C)(C)C)ccc4n5-c4ccccc4)cc3)cc2)c1 ; c1ccc(-c2ccc(N(c3ccc(-c4ccc(N(c5ccccc5)c5ccccc5)cc4)cc3)c3ccc(-c4ccc5c(c4)c4ccccc4n5-c4ccccc4)cc3)cc2)cc1]

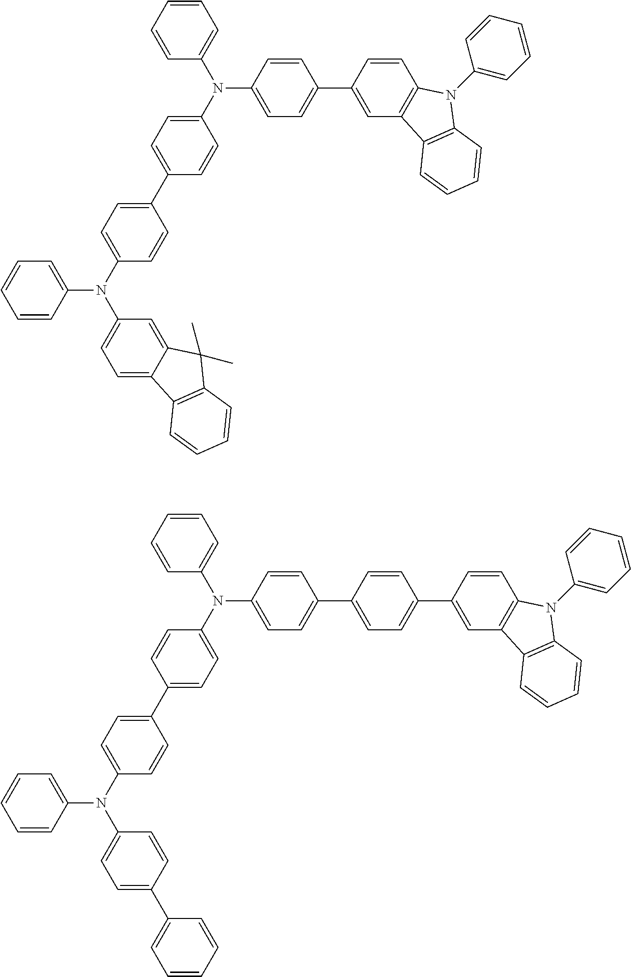 [SMILES: CC1(C)c2ccccc2-c2ccc(N(c3ccccc3)c3ccc(-c4ccc(N(c5ccccc5)c5ccc(-c6ccc7c(c6)c6ccccc6n7-c6ccccc6)cc5)cc4)cc3)cc21 ; c1ccc(-c2ccc(N(c3ccccc3)c3ccc(-c4ccc(N(c5ccccc5)c5ccc(-c6ccc(-c7ccc8c(c7)c7ccccc7n8-c7ccccc7)cc6)cc5)cc4)cc3)cc2)cc1]

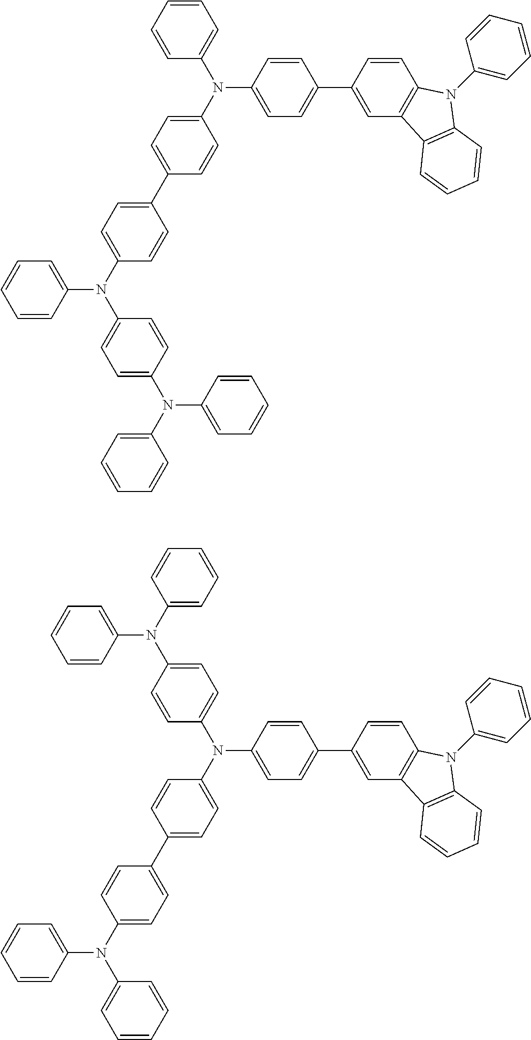 [SMILES: c1ccc(N(c2ccc(-c3ccc(N(c4ccccc4)c4ccc(N(c5ccccc5)c5ccccc5)cc4)cc3)cc2)c2ccc(-c3ccc4c(c3)c3ccccc3n4-c3ccccc3)cc2)cc1 ; c1ccc(N(c2ccccc2)c2ccc(-c3ccc(N(c4ccc(-c5ccc6c(c5)c5ccccc5n6-c5ccccc5)cc4)c4ccc(N(c5ccccc5)c5ccccc5)cc4)cc3)cc2)cc1]

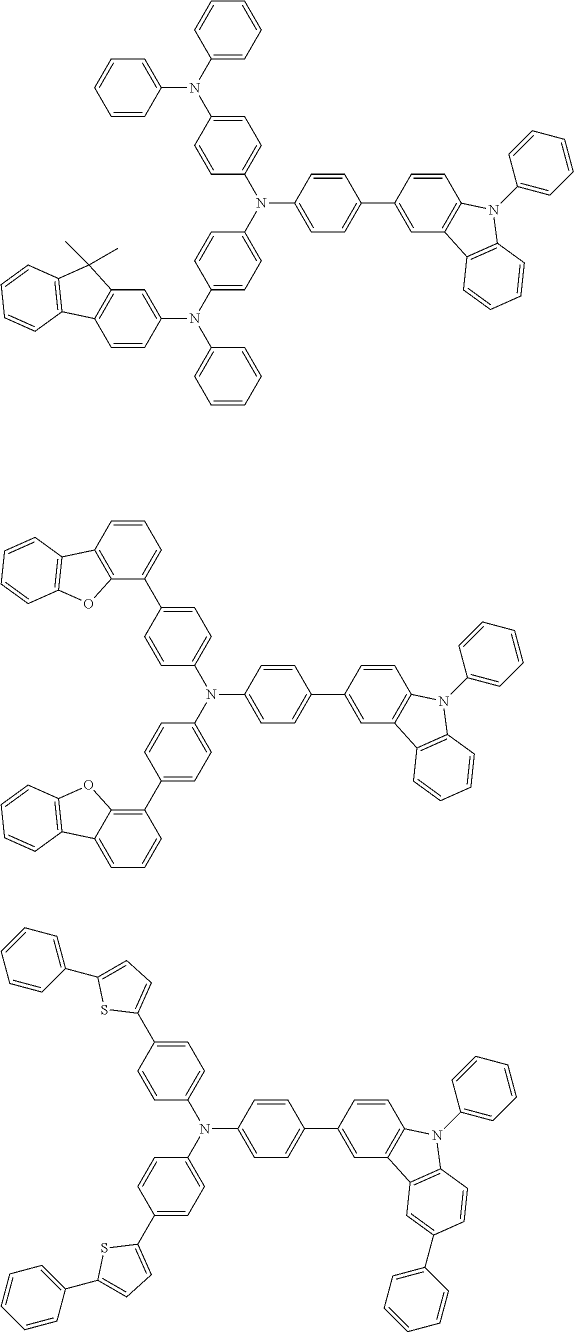 [SMILES: CC1(C)c2ccccc2-c2ccc(N(c3ccccc3)c3ccc(N(c4ccc(-c5ccc6c(c5)c5ccccc5n6-c5ccccc5)cc4)c4ccc(N(c5ccccc5)c5ccccc5)cc4)cc3)cc21 ; c1ccc(-n2c3ccccc3c3cc(-c4ccc(N(c5ccc(-c6cccc7c6oc6ccccc67)cc5)c5ccc(-c6cccc7c6oc6ccccc67)cc5)cc4)ccc32)cc1 ; c1ccc(-c2ccc3c(c2)c2cc(-c4ccc(N(c5ccc(-c6ccc(-c7ccccc7)s6)cc5)c5ccc(-c6ccc(-c7ccccc7)s6)cc5)cc4)ccc2n3-c2ccccc2)cc1]

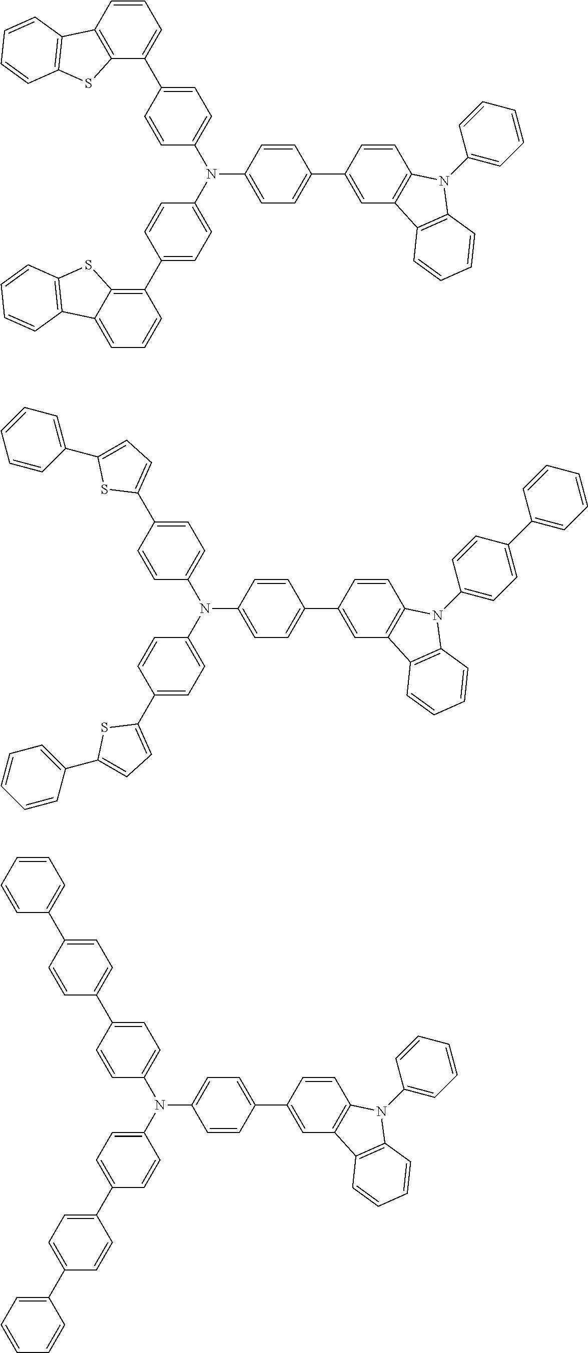 [SMILES: c1ccc(-n2c3ccccc3c3cc(-c4ccc(N(c5ccc(-c6cccc7c6sc6ccccc67)cc5)c5ccc(-c6cccc7c6sc6ccccc67)cc5)cc4)ccc32)cc1 ; c1ccc(-c2ccc(-n3c4ccccc4c4cc(-c5ccc(N(c6ccc(-c7ccc(-c8ccccc8)s7)cc6)c6ccc(-c7ccc(-c8ccccc8)s7)cc6)cc5)ccc43)cc2)cc1 ; c1ccc(-c2ccc(-c3ccc(N(c4ccc(-c5ccc(-c6ccccc6)cc5)cc4)c4ccc(-c5ccc6c(c5)c5ccccc5n6-c5ccccc5)cc4)cc3)cc2)cc1]

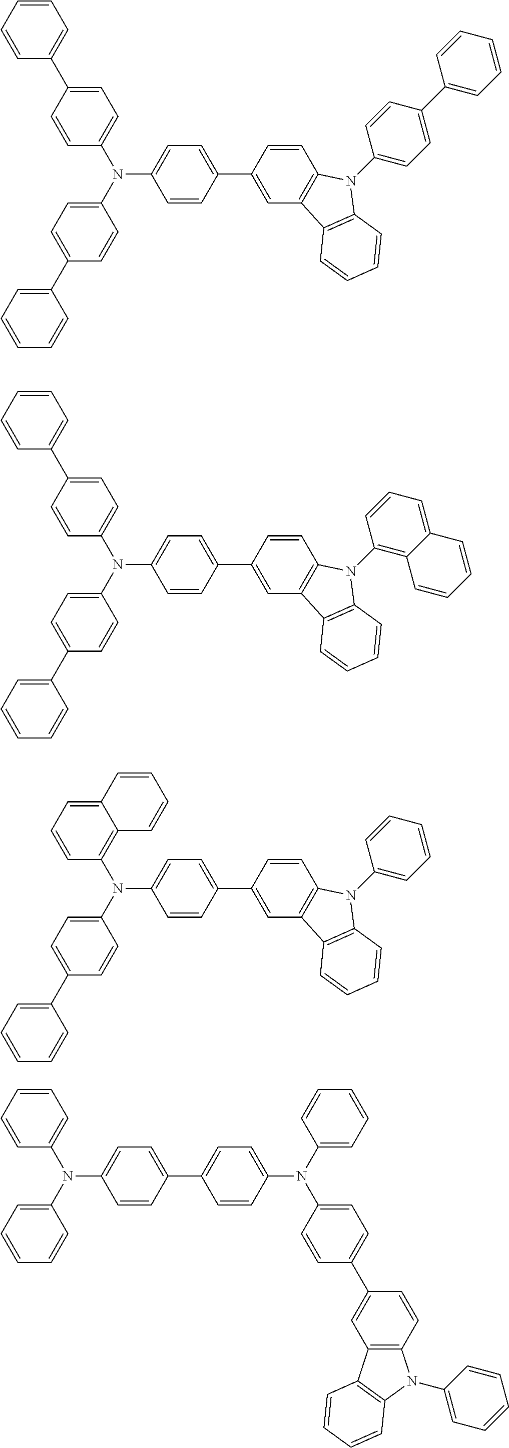

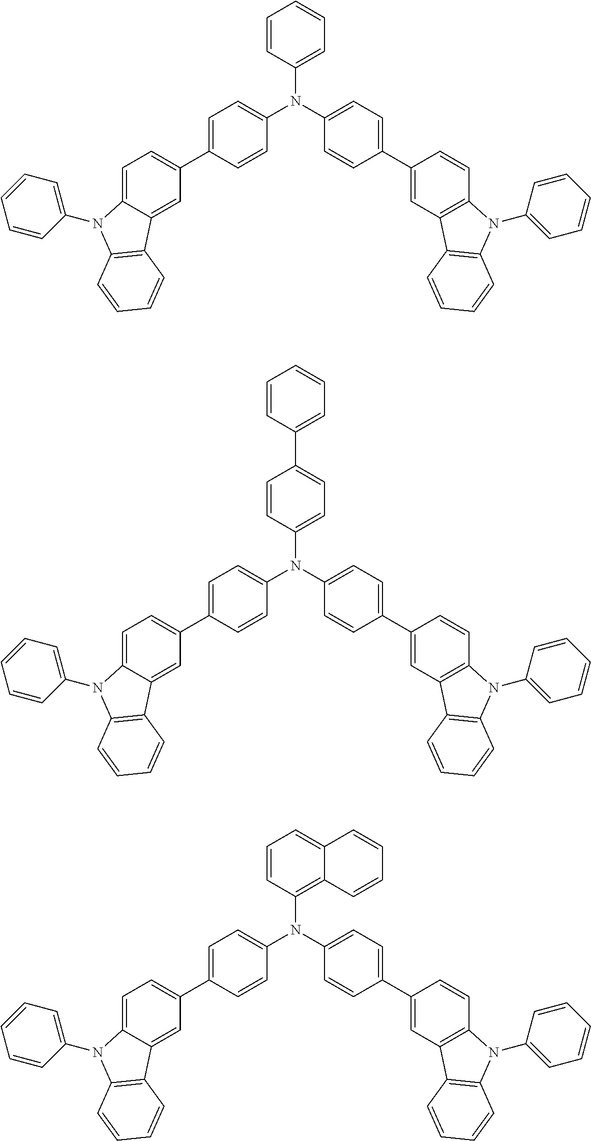 [SMILES: c1ccc(N(c2ccc(-c3ccc4c(c3)c3ccccc3n4-c3ccccc3)cc2)c2ccc(-c3ccc4c(c3)c3ccccc3n4-c3ccccc3)cc2)cc1 ; c1ccc(-c2ccc(N(c3ccc(-c4ccc5c(c4)c4ccccc4n5-c4ccccc4)cc3)c3ccc(-c4ccc5c(c4)c4ccccc4n5-c4ccccc4)cc3)cc2)cc1 ; c1ccc(-n2c3ccccc3c3cc(-c4ccc(N(c5ccc(-c6ccc7c(c6)c6ccccc6n7-c6ccccc6)cc5)c5cccc6ccccc56)cc4)ccc32)cc1]

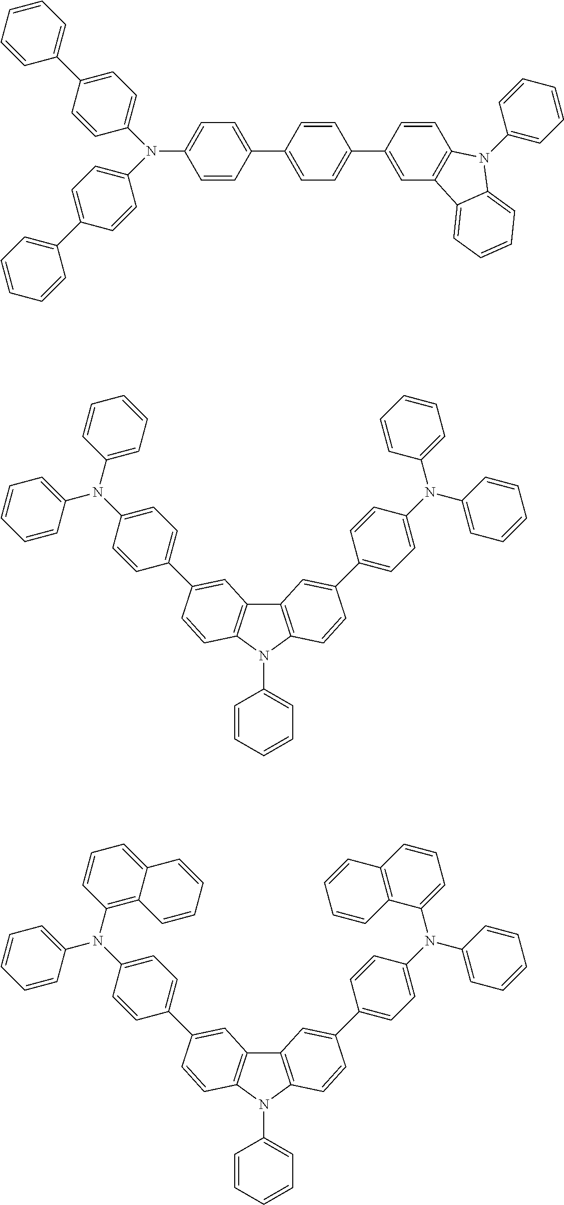 [SMILES: c1ccc(-c2ccc(N(c3ccc(-c4ccccc4)cc3)c3ccc(-c4ccc(-c5ccc6c(c5)c5ccccc5n6-c5ccccc5)cc4)cc3)cc2)cc1 ; c1ccc(N(c2ccccc2)c2ccc(-c3ccc4c(c3)c3cc(-c5ccc(N(c6ccccc6)c6ccccc6)cc5)ccc3n4-c3ccccc3)cc2)cc1 ; c1ccc(N(c2ccc(-c3ccc4c(c3)c3cc(-c5ccc(N(c6ccccc6)c6cccc7ccccc67)cc5)ccc3n4-c3ccccc3)cc2)c2cccc3ccccc23)cc1]

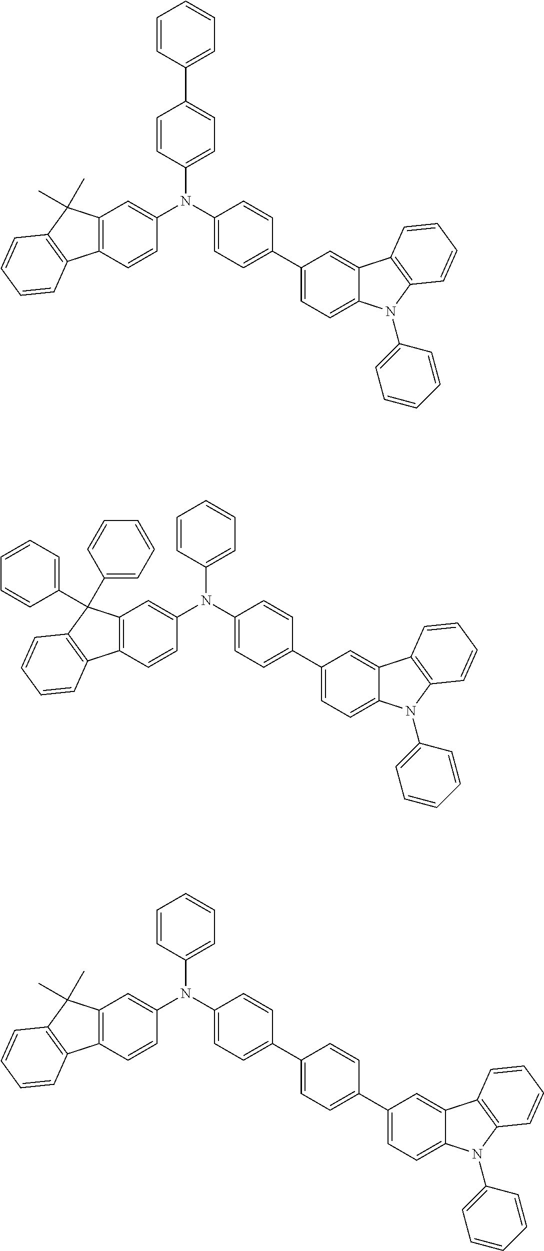 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; CC1(C)c2ccccc2-c2ccc(N(c3ccccc3)c3ccc(-c4ccc(-c5ccc6c(c5)c5ccccc5n6-c5ccccc5)cc4)cc3)cc21]

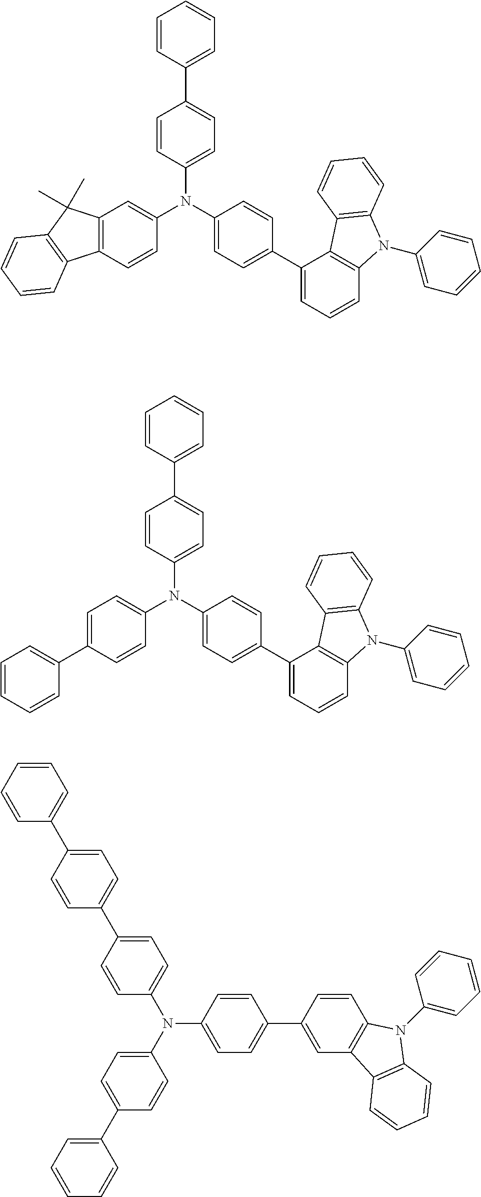 [SMILES: CC1(C)c2ccccc2-c2ccc(N(c3ccc(-c4ccccc4)cc3)c3ccc(-c4cccc5c4c4ccccc4n5-c4ccccc4)cc3)cc21 ; c1ccc(-c2ccc(N(c3ccc(-c4ccccc4)cc3)c3ccc(-c4cccc5c4c4ccccc4n5-c4ccccc4)cc3)cc2)cc1 ; c1ccc(-c2ccc(-c3ccc(N(c4ccc(-c5ccccc5)cc4)c4ccc(-c5ccc6c(c5)c5ccccc5n6-c5ccccc5)cc4)cc3)cc2)cc1]

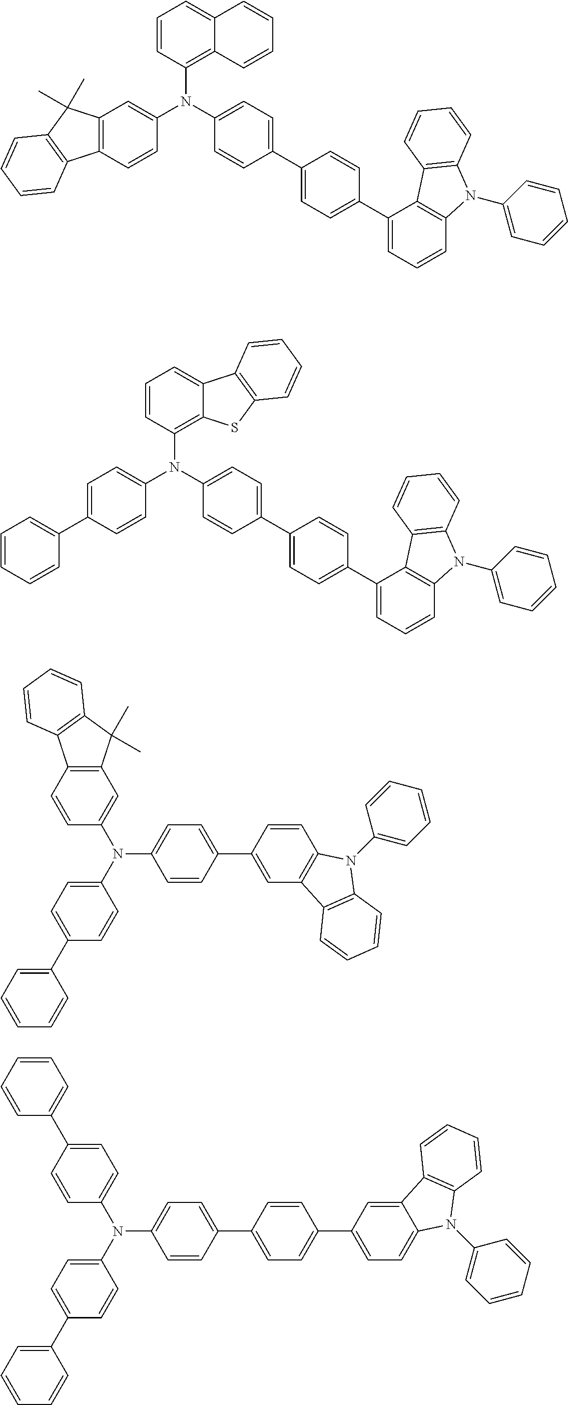

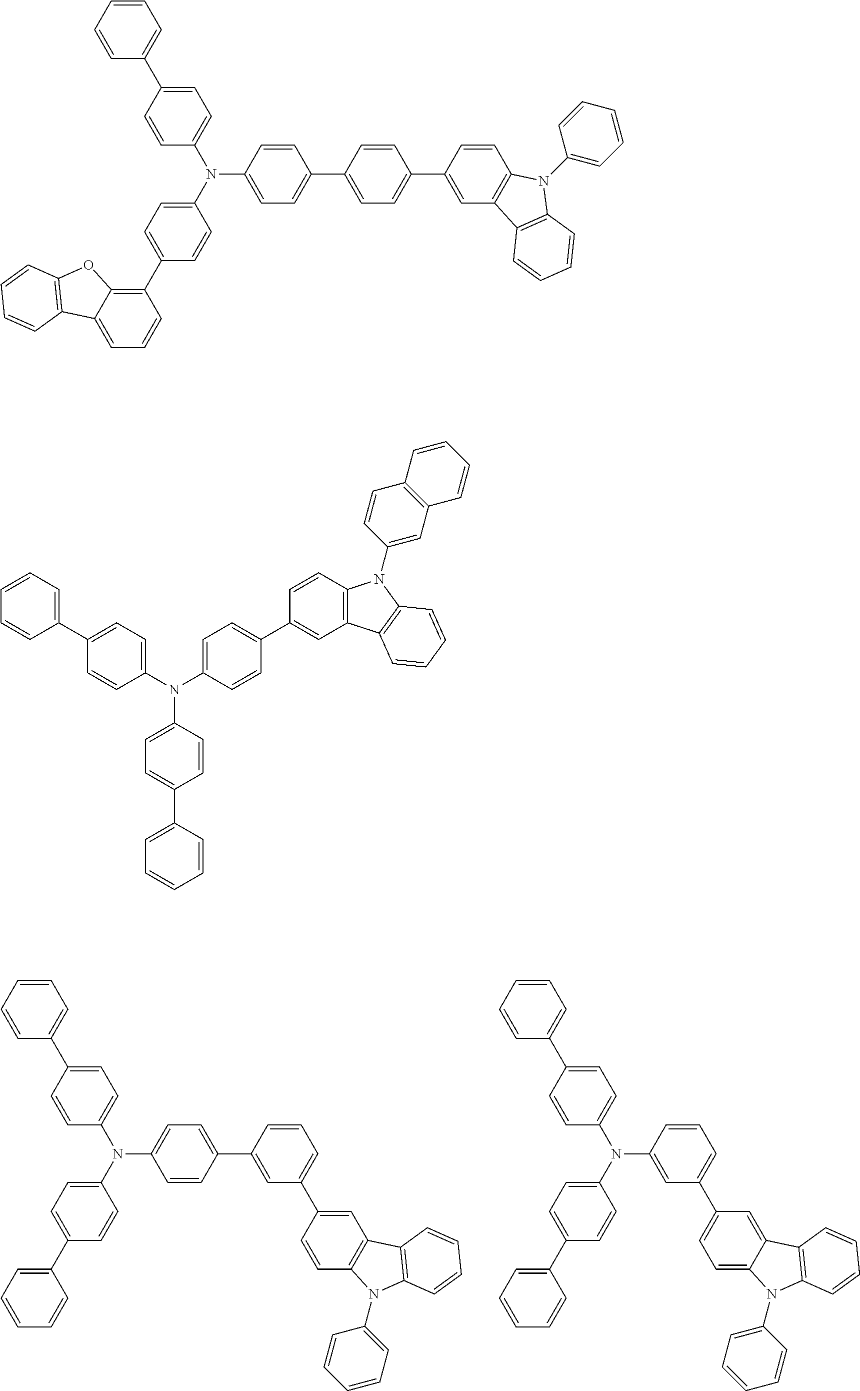

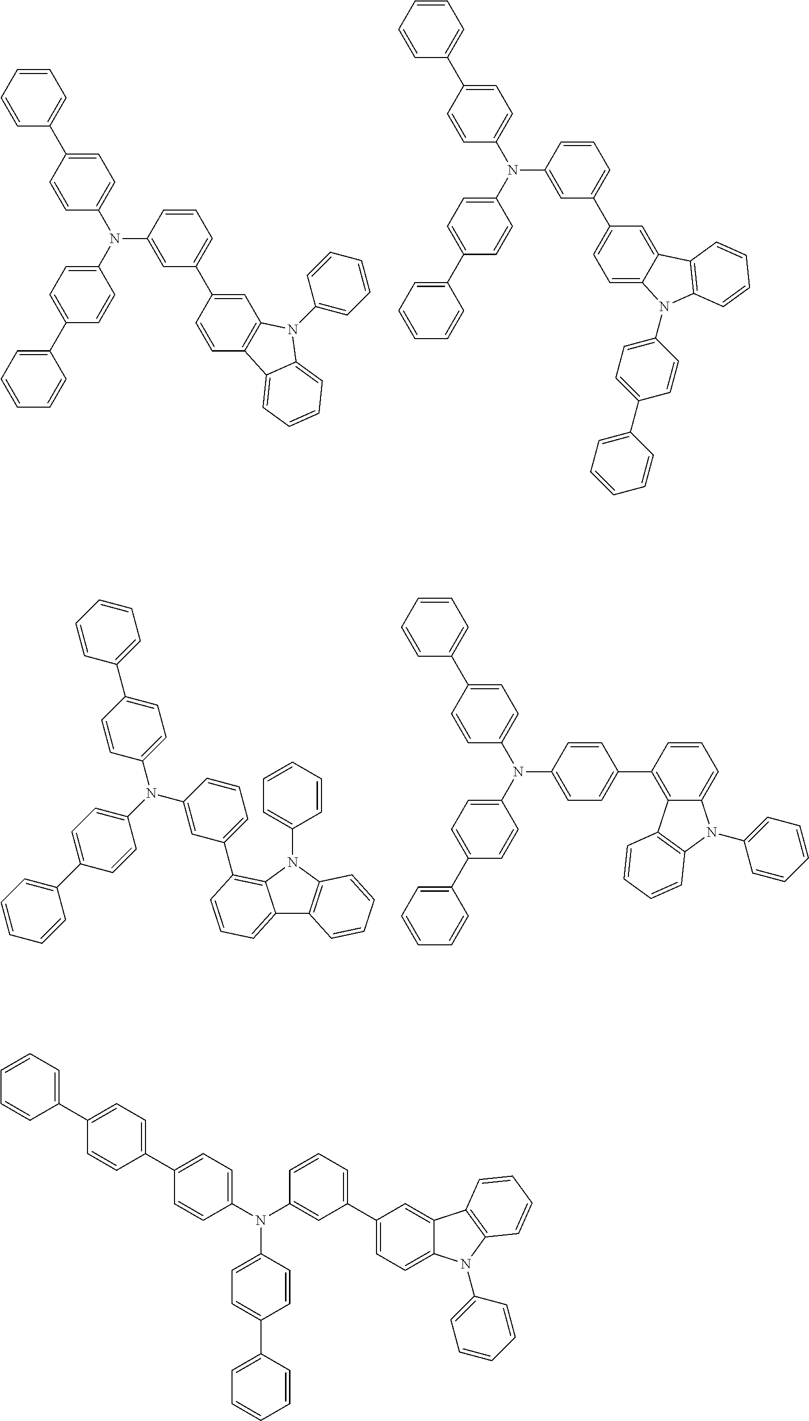

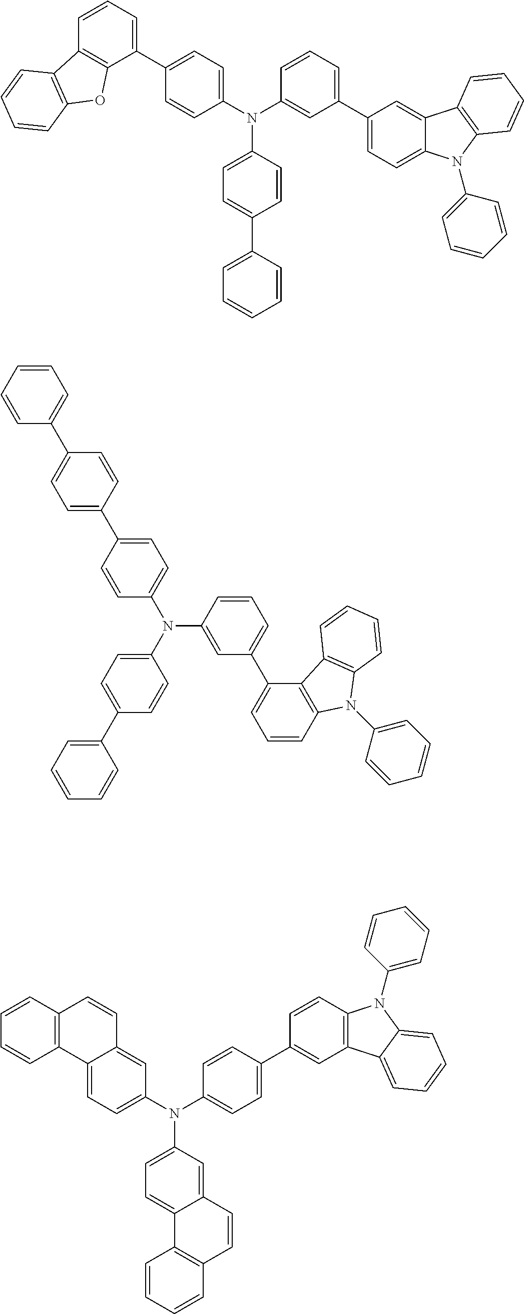 [SMILES: c1ccc(-c2ccc(N(c3ccc(-c4cccc5c4oc4ccccc45)cc3)c3cccc(-c4ccc5c(c4)c4ccccc4n5-c4ccccc4)c3)cc2)cc1 ; c1ccc(-c2ccc(-c3ccc(N(c4ccc(-c5ccccc5)cc4)c4cccc(-c5cccc6c5c5ccccc5n6-c5ccccc5)c4)cc3)cc2)cc1 ; c1ccc(-n2c3ccccc3c3cc(-c4ccc(N(c5ccc6c(ccc7ccccc76)c5)c5ccc6c(ccc7ccccc76)c5)cc4)ccc32)cc1]

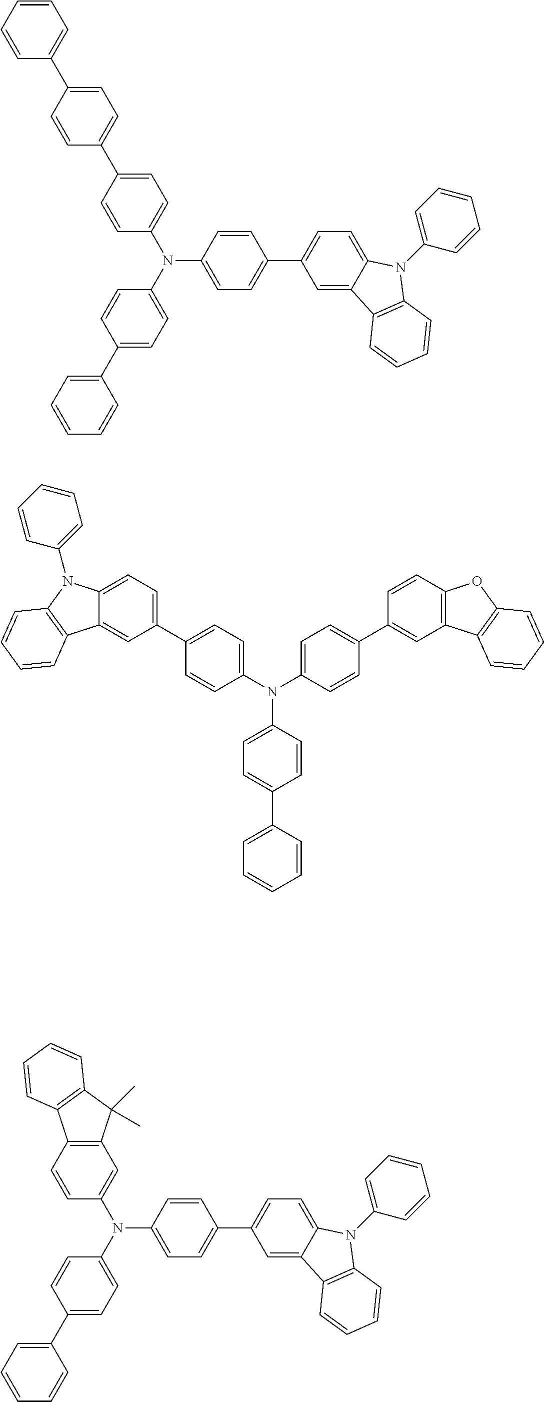 [SMILES: c1ccc(-c2ccc(-c3ccc(N(c4ccc(-c5ccccc5)cc4)c4ccc(-c5ccc6c(c5)c5ccccc5n6-c5ccccc5)cc4)cc3)cc2)cc1 ; c1ccc(-c2ccc(N(c3ccc(-c4ccc5oc6ccccc6c5c4)cc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

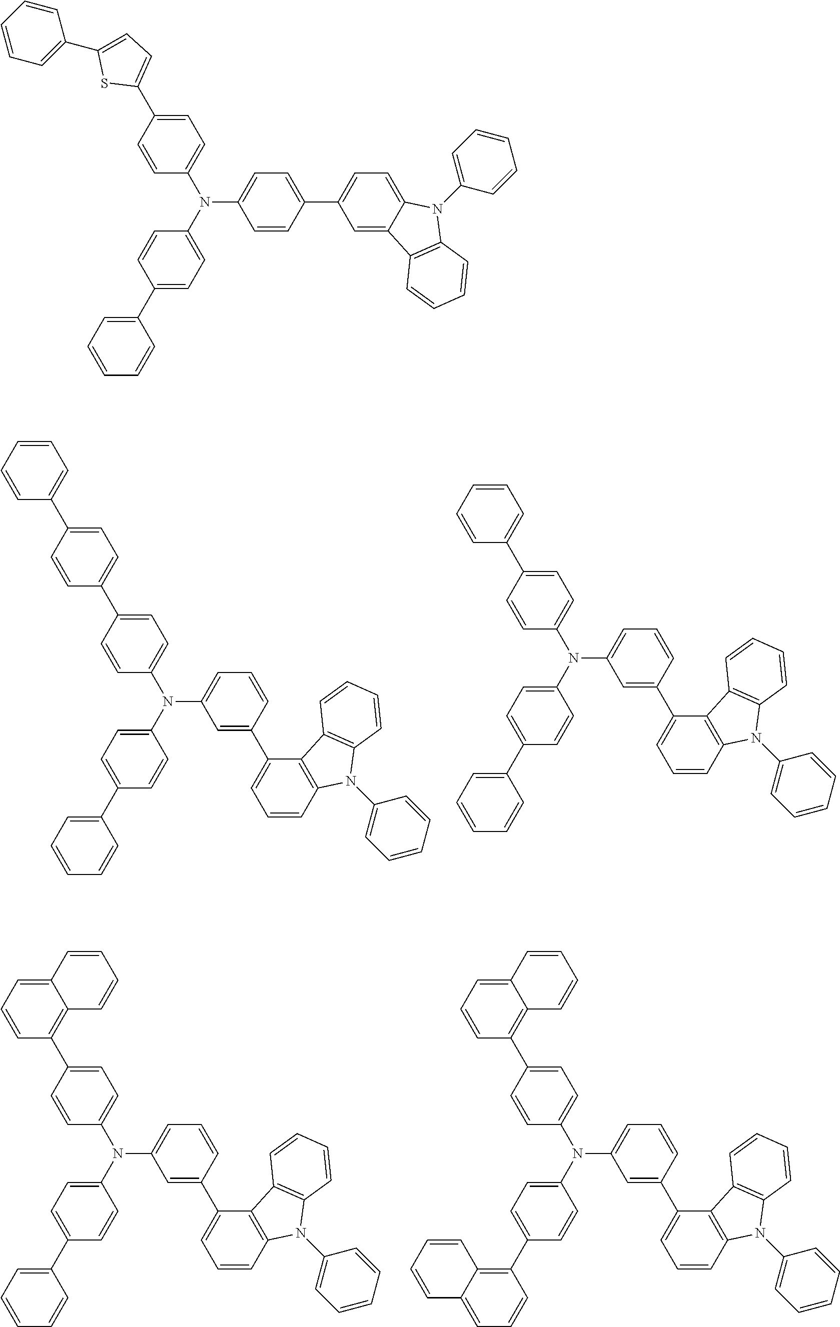

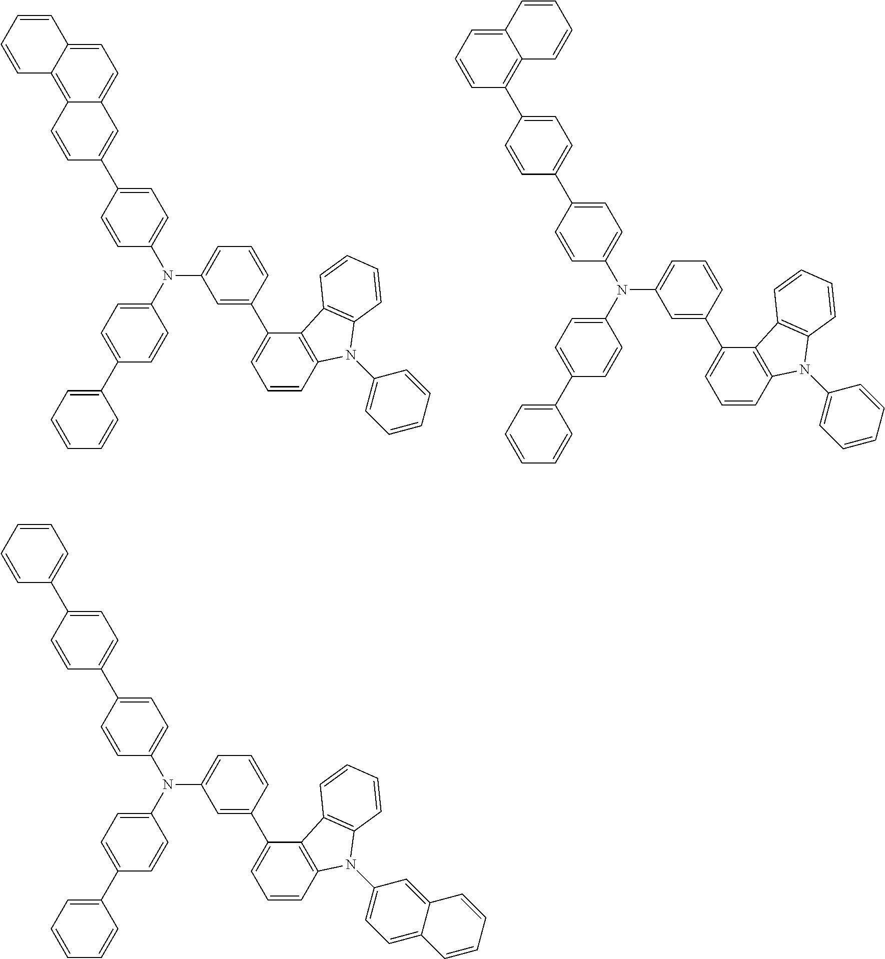 [SMILES: c1ccc(-c2ccc(N(c3ccc(-c4ccc5c(ccc6ccccc65)c4)cc3)c3cccc(-c4cccc5c4c4ccccc4n5-c4ccccc4)c3)cc2)cc1 ; c1ccc(-c2ccc(N(c3ccc(-c4ccc(-c5cccc6ccccc56)cc4)cc3)c3cccc(-c4cccc5c4c4ccccc4n5-c4ccccc4)c3)cc2)cc1 ; c1ccc(-c2ccc(-c3ccc(N(c4ccc(-c5ccccc5)cc4)c4cccc(-c5cccc6c5c5ccccc5n6-c5ccc6ccccc6c5)c4)cc3)cc2)cc1]

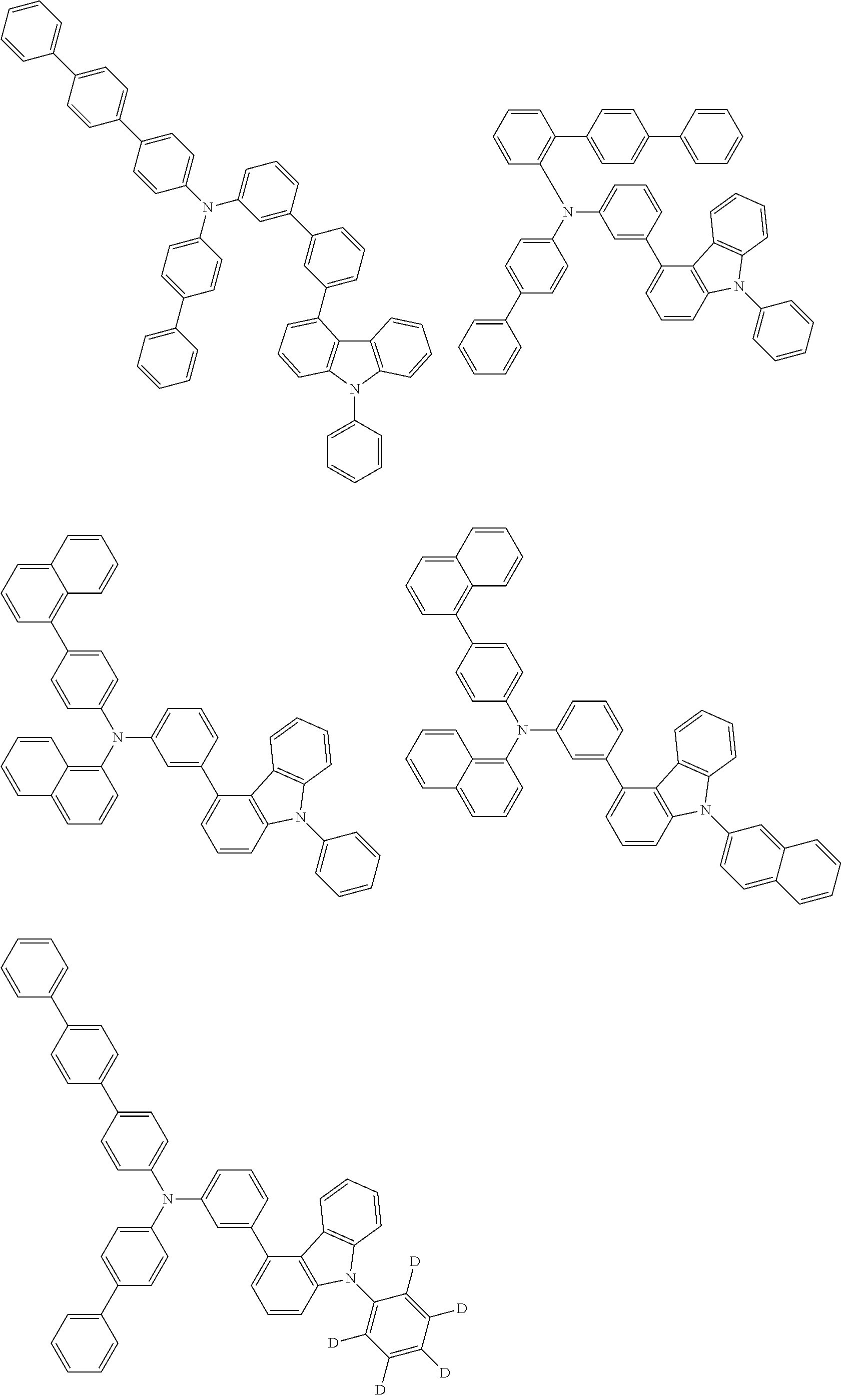

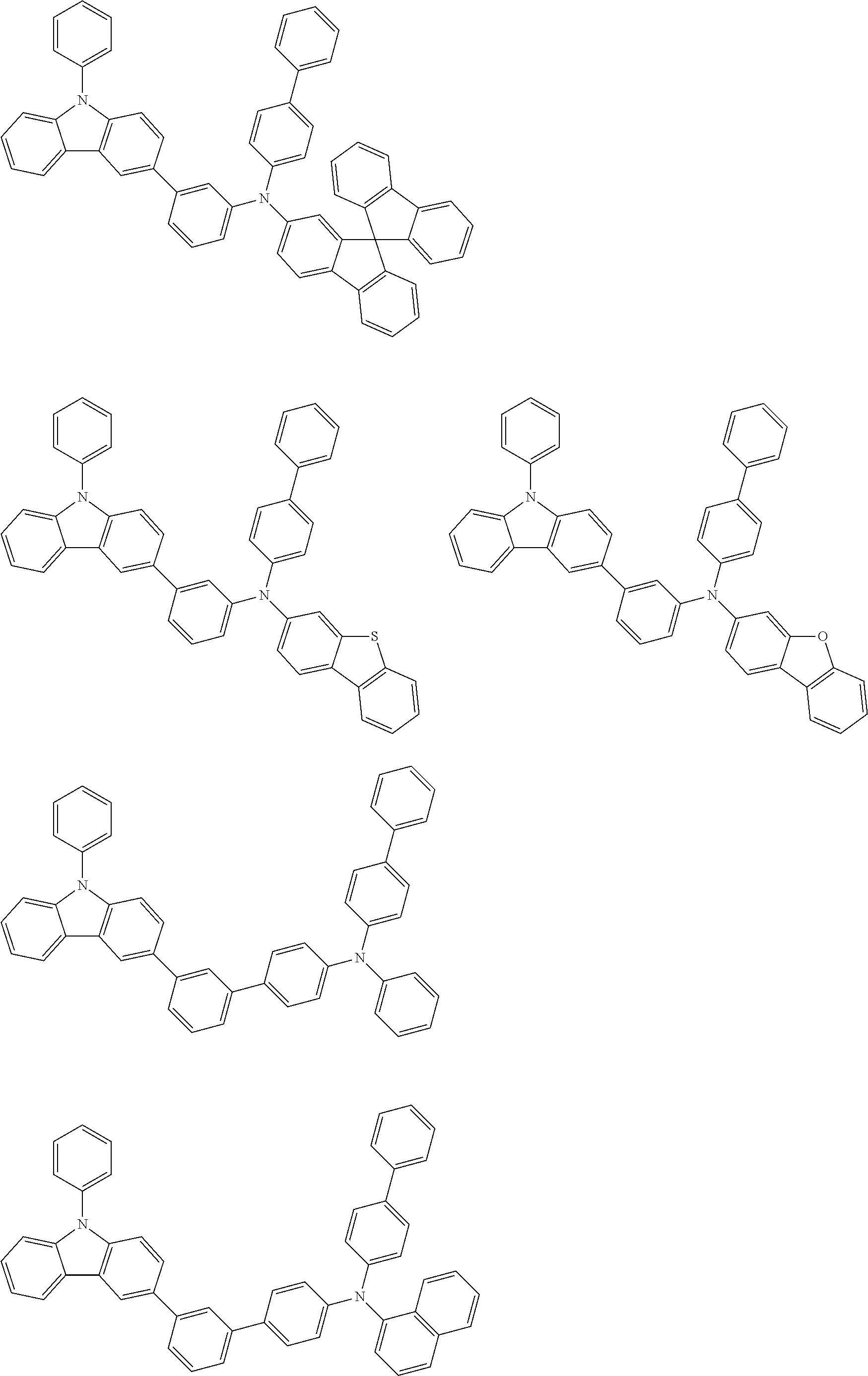

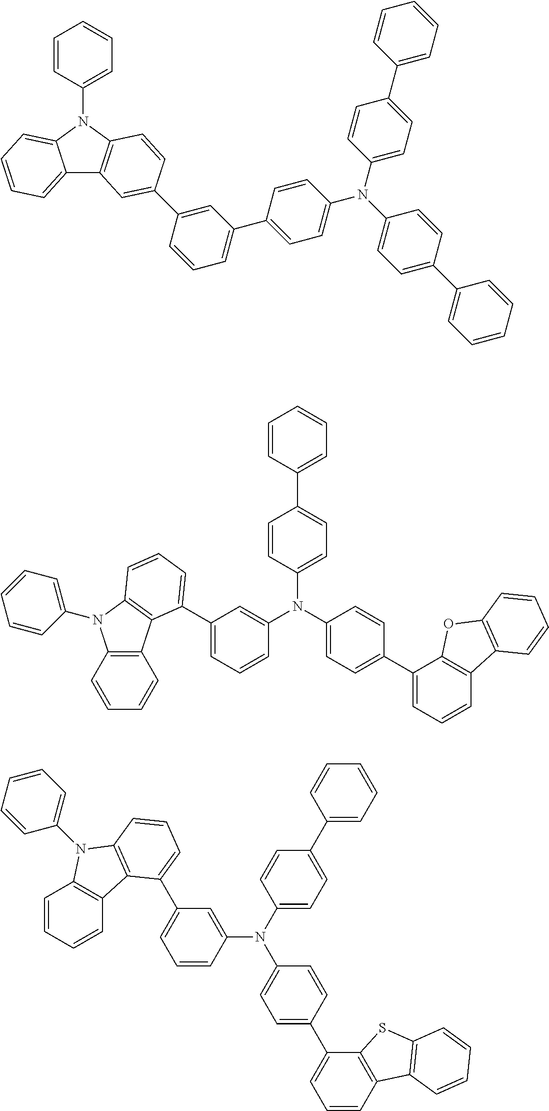 [SMILES: c1ccc(-c2ccc(N(c3ccc(-c4ccccc4)cc3)c3ccc(-c4cccc(-c5ccc6c(c5)c5ccccc5n6-c5ccccc5)c4)cc3)cc2)cc1 ; c1ccc(-c2ccc(N(c3ccc(-c4cccc5c4oc4ccccc45)cc3)c3cccc(-c4cccc5c4c4ccccc4n5-c4ccccc4)c3)cc2)cc1 ; c1ccc(-c2ccc(N(c3ccc(-c4cccc5c4sc4ccccc45)cc3)c3cccc(-c4cccc5c4c4ccccc4n5-c4ccccc4)c3)cc2)cc1]

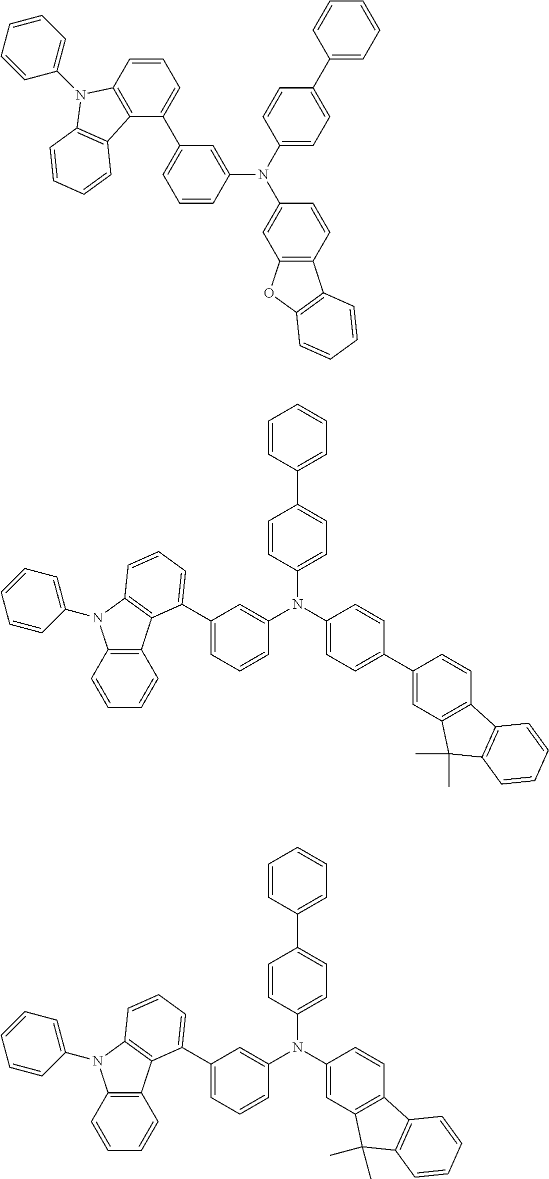 [SMILES: c1ccc(-c2ccc(N(c3cccc(-c4cccc5c4c4ccccc4n5-c4ccccc4)c3)c3ccc4c(c3)oc3ccccc34)cc2)cc1 ; CC1(C)c2ccccc2-c2ccc(-c3ccc(N(c4ccc(-c5ccccc5)cc4)c4cccc(-c5cccc6c5c5ccccc5n6-c5ccccc5)c4)cc3)cc21 ; CC1(C)c2ccccc2-c2ccc(N(c3ccc(-c4ccccc4)cc3)c3cccc(-c4cccc5c4c4ccccc4n5-c4ccccc4)c3)cc21]

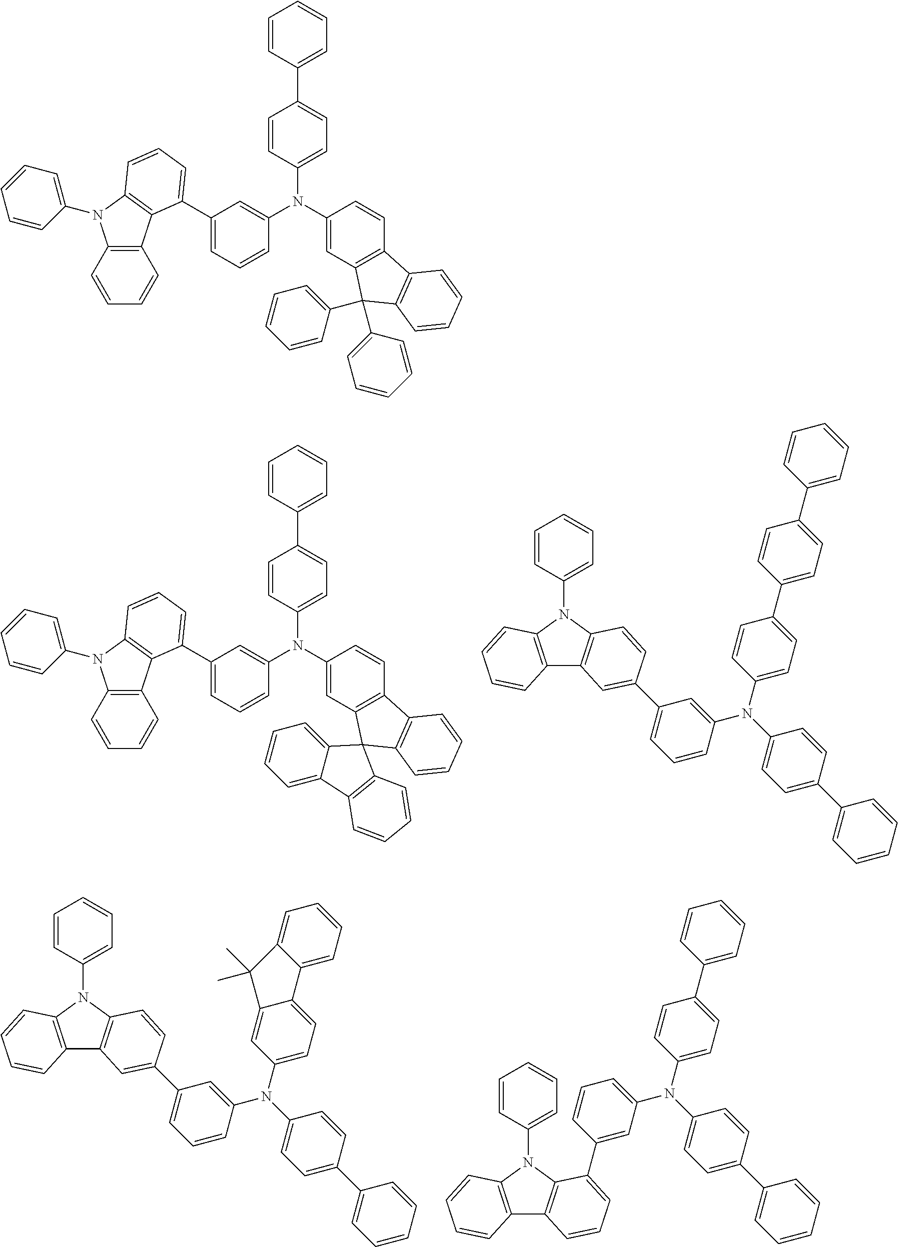

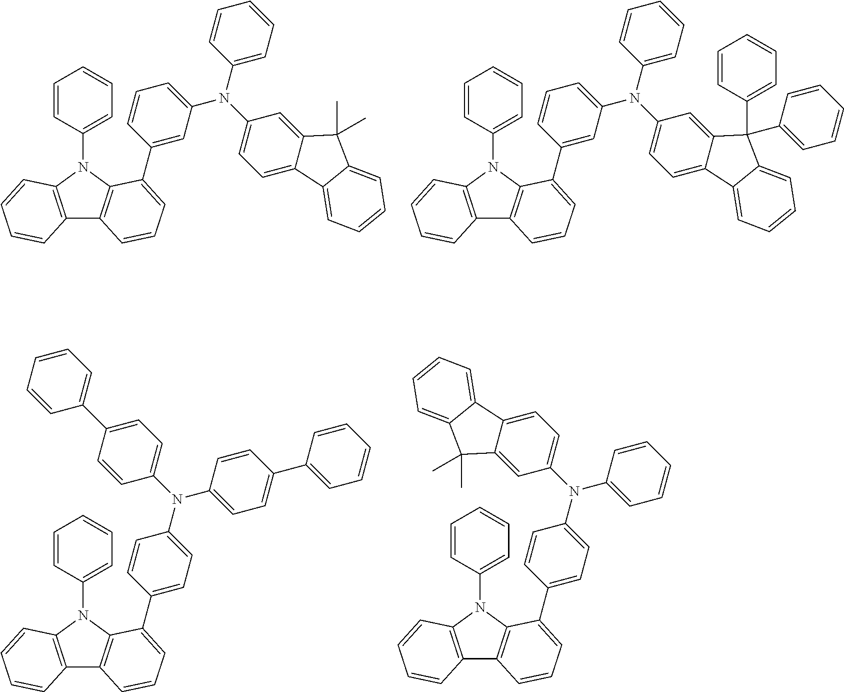

In one embodiment, specific examples of the first compound in the first composition include the following compounds.

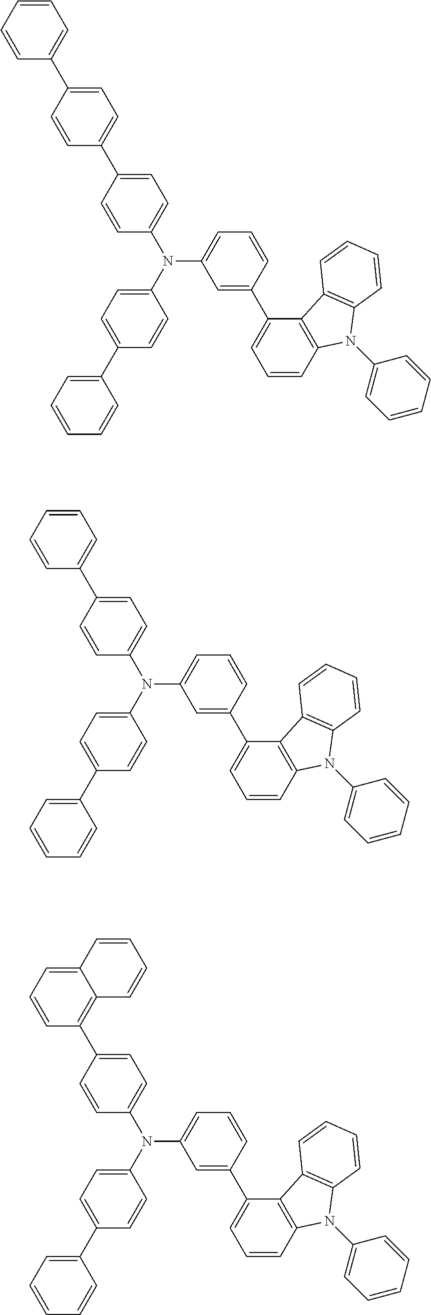 [SMILES: c1ccc(-c2ccc(-c3ccc(N(c4ccc(-c5ccccc5)cc4)c4cccc(-c5cccc6c5c5ccccc5n6-c5ccccc5)c4)cc3)cc2)cc1 ; c1ccc(-c2ccc(N(c3ccc(-c4ccccc4)cc3)c3cccc(-c4cccc5c4c4ccccc4n5-c4ccccc4)c3)cc2)cc1 ; c1ccc(-c2ccc(N(c3ccc(-c4cccc5ccccc45)cc3)c3cccc(-c4cccc5c4c4ccccc4n5-c4ccccc4)c3)cc2)cc1]

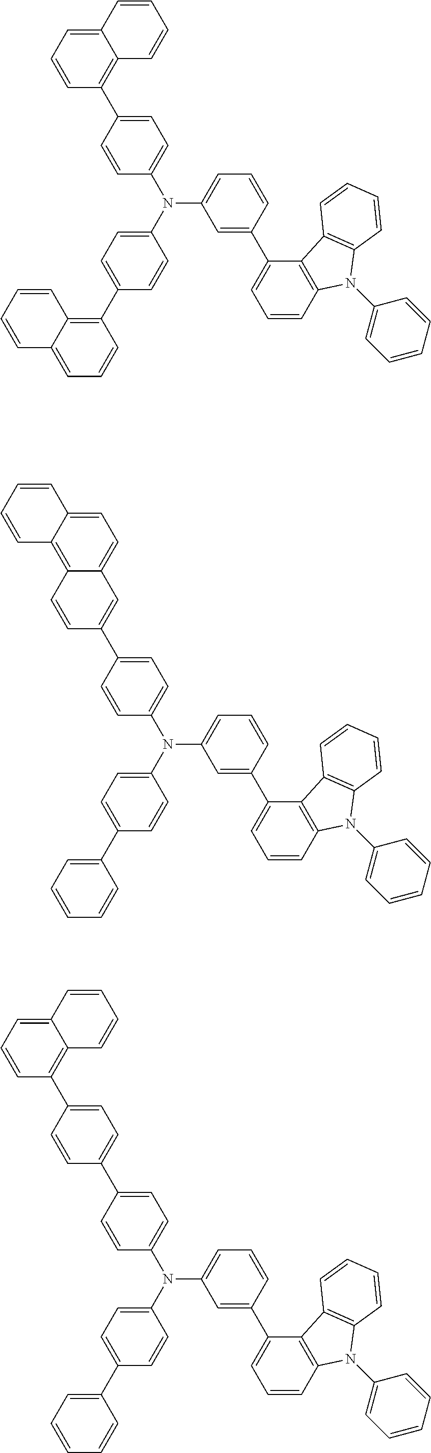 [SMILES: c1ccc(-n2c3ccccc3c3c(-c4cccc(N(c5ccc(-c6cccc7ccccc67)cc5)c5ccc(-c6cccc7ccccc67)cc5)c4)cccc32)cc1 ; c1ccc(-c2ccc(N(c3ccc(-c4ccc5c(ccc6ccccc65)c4)cc3)c3cccc(-c4cccc5c4c4ccccc4n5-c4ccccc4)c3)cc2)cc1 ; c1ccc(-c2ccc(N(c3ccc(-c4ccc(-c5cccc6ccccc56)cc4)cc3)c3cccc(-c4cccc5c4c4ccccc4n5-c4ccccc4)c3)cc2)cc1]

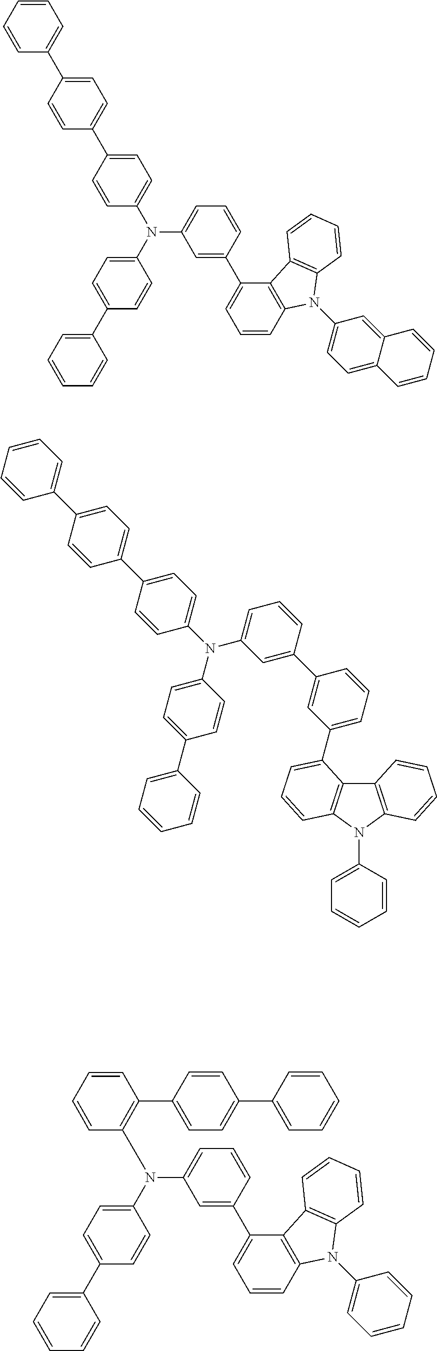 [SMILES: c1ccc(-c2ccc(-c3ccc(N(c4ccc(-c5ccccc5)cc4)c4cccc(-c5cccc6c5c5ccccc5n6-c5ccc6ccccc6c5)c4)cc3)cc2)cc1 ; c1ccc(-c2ccc(-c3ccc(N(c4ccc(-c5ccccc5)cc4)c4cccc(-c5cccc(-c6cccc7c6c6ccccc6n7-c6ccccc6)c5)c4)cc3)cc2)cc1 ; c1ccc(-c2ccc(-c3ccccc3N(c3ccc(-c4ccccc4)cc3)c3cccc(-c4cccc5c4c4ccccc4n5-c4ccccc4)c3)cc2)cc1]

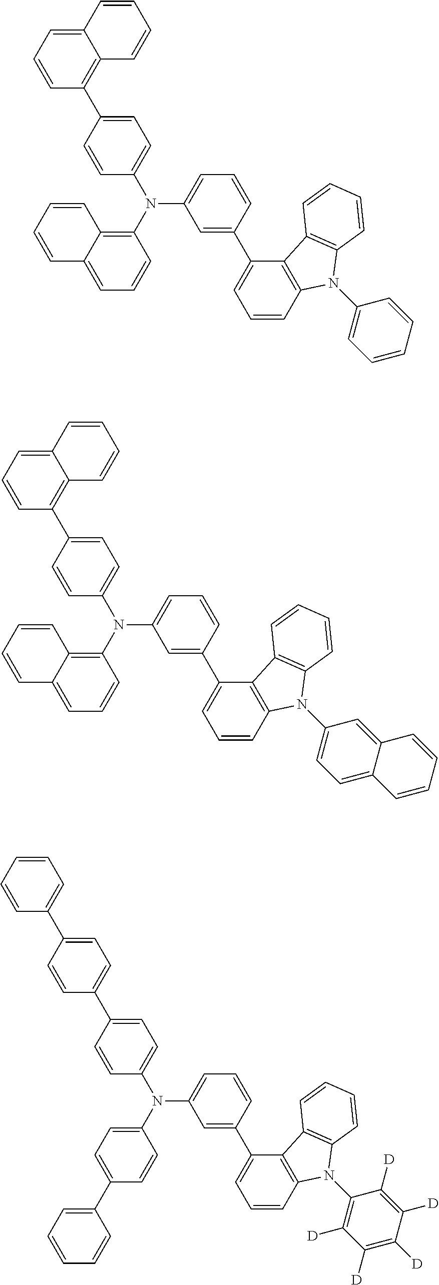 [SMILES: c1ccc(-n2c3ccccc3c3c(-c4cccc(N(c5ccc(-c6cccc7ccccc67)cc5)c5cccc6ccccc56)c4)cccc32)cc1 ; c1cc(-c2cccc3c2c2ccccc2n3-c2ccc3ccccc3c2)cc(N(c2ccc(-c3cccc4ccccc34)cc2)c2cccc3ccccc23)c1 ; [2H]c1c([2H])c([2H])c(-n2c3ccccc3c3c(-c4cccc(N(c5ccc(-c6ccccc6)cc5)c5ccc(-c6ccc(-c7ccccc7)cc6)cc5)c4)cccc32)c([2H])c1[2H]]

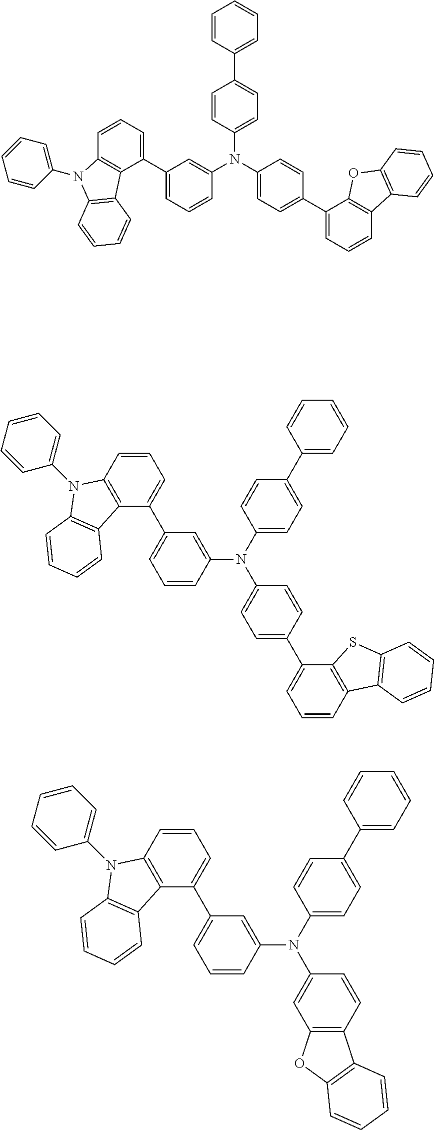 [SMILES: c1ccc(-c2ccc(N(c3ccc(-c4cccc5c4oc4ccccc45)cc3)c3cccc(-c4cccc5c4c4ccccc4n5-c4ccccc4)c3)cc2)cc1 ; c1ccc(-c2ccc(N(c3ccc(-c4cccc5c4sc4ccccc45)cc3)c3cccc(-c4cccc5c4c4ccccc4n5-c4ccccc4)c3)cc2)cc1 ; c1ccc(-c2ccc(N(c3cccc(-c4cccc5c4c4ccccc4n5-c4ccccc4)c3)c3ccc4c(c3)oc3ccccc34)cc2)cc1]

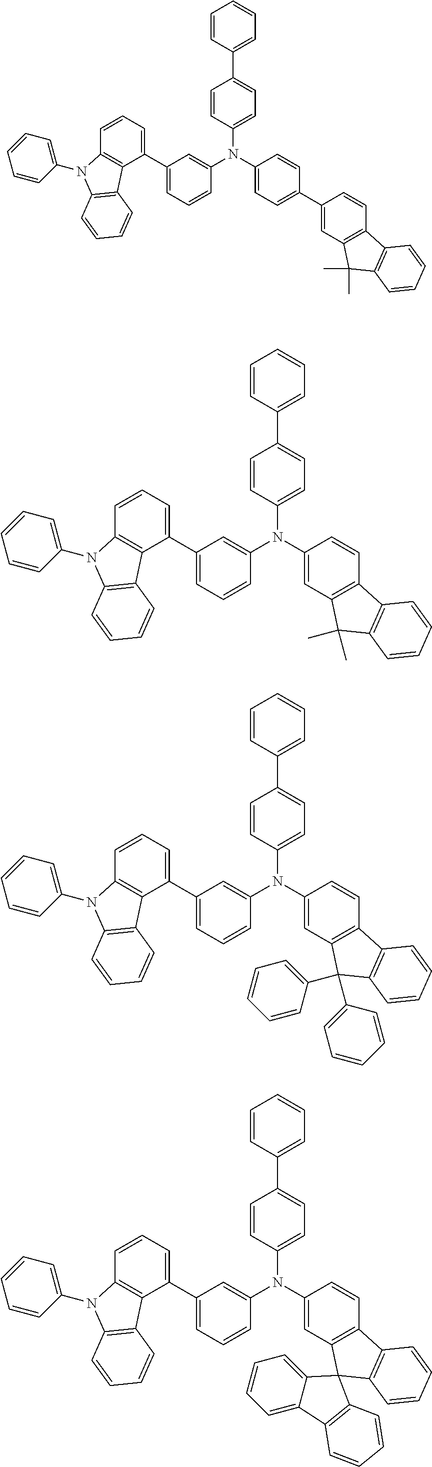 [SMILES: CC1(C)c2ccccc2-c2ccc(-c3ccc(N(c4ccc(-c5ccccc5)cc4)c4cccc(-c5cccc6c5c5ccccc5n6-c5ccccc5)c4)cc3)cc21 ; CC1(C)c2ccccc2-c2ccc(N(c3ccc(-c4ccccc4)cc3)c3cccc(-c4cccc5c4c4ccccc4n5-c4ccccc4)c3)cc21 ; c1ccc(-c2ccc(N(c3cccc(-c4cccc5c4c4ccccc4n5-c4ccccc4)c3)c3ccc4c(c3)C(c3ccccc3)(c3ccccc3)c3ccccc3-4)cc2)cc1 ; c1ccc(-c2ccc(N(c3cccc(-c4cccc5c4c4ccccc4n5-c4ccccc4)c3)c3ccc4c(c3)C3(c5ccccc5-c5ccccc53)c3ccccc3-4)cc2)cc1]

In one embodiment, specific examples of the first compound in the second composition include the following compounds.

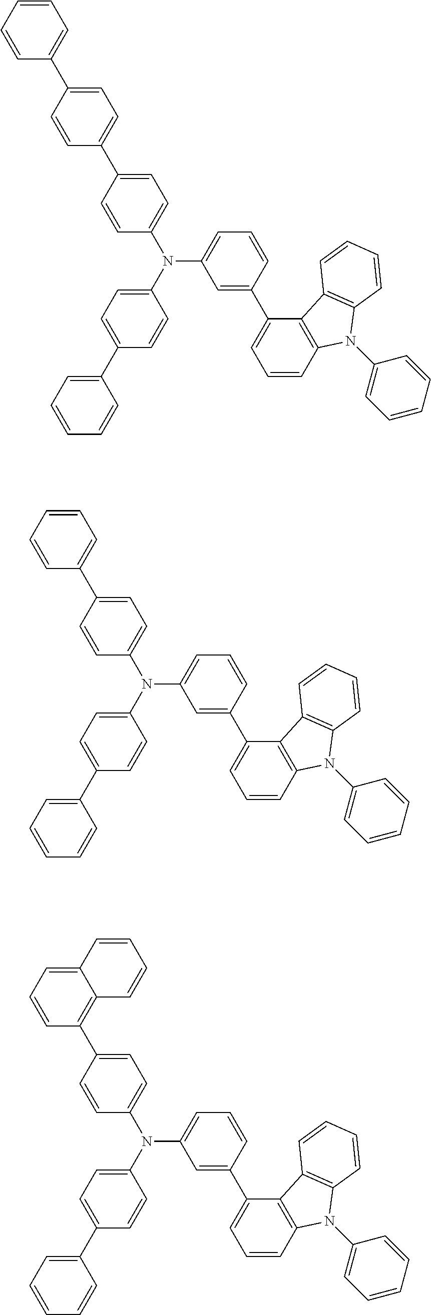 [SMILES: c1ccc(-c2ccc(-c3ccc(N(c4ccc(-c5ccccc5)cc4)c4cccc(-c5cccc6c5c5ccccc5n6-c5ccccc5)c4)cc3)cc2)cc1 ; c1ccc(-c2ccc(N(c3ccc(-c4ccccc4)cc3)c3cccc(-c4cccc5c4c4ccccc4n5-c4ccccc4)c3)cc2)cc1 ; c1ccc(-c2ccc(N(c3ccc(-c4cccc5ccccc45)cc3)c3cccc(-c4cccc5c4c4ccccc4n5-c4ccccc4)c3)cc2)cc1]

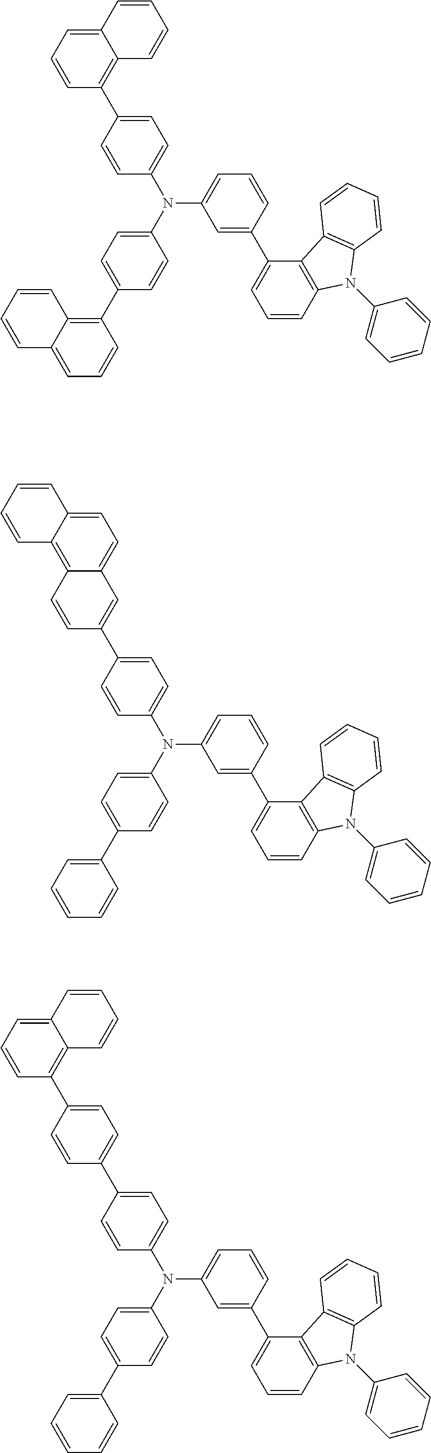 [SMILES: c1ccc(-n2c3ccccc3c3c(-c4cccc(N(c5ccc(-c6cccc7ccccc67)cc5)c5ccc(-c6cccc7ccccc67)cc5)c4)cccc32)cc1 ; c1ccc(-c2ccc(N(c3ccc(-c4ccc5c(ccc6ccccc65)c4)cc3)c3cccc(-c4cccc5c4c4ccccc4n5-c4ccccc4)c3)cc2)cc1 ; c1ccc(-c2ccc(N(c3ccc(-c4ccc(-c5cccc6ccccc56)cc4)cc3)c3cccc(-c4cccc5c4c4ccccc4n5-c4ccccc4)c3)cc2)cc1]

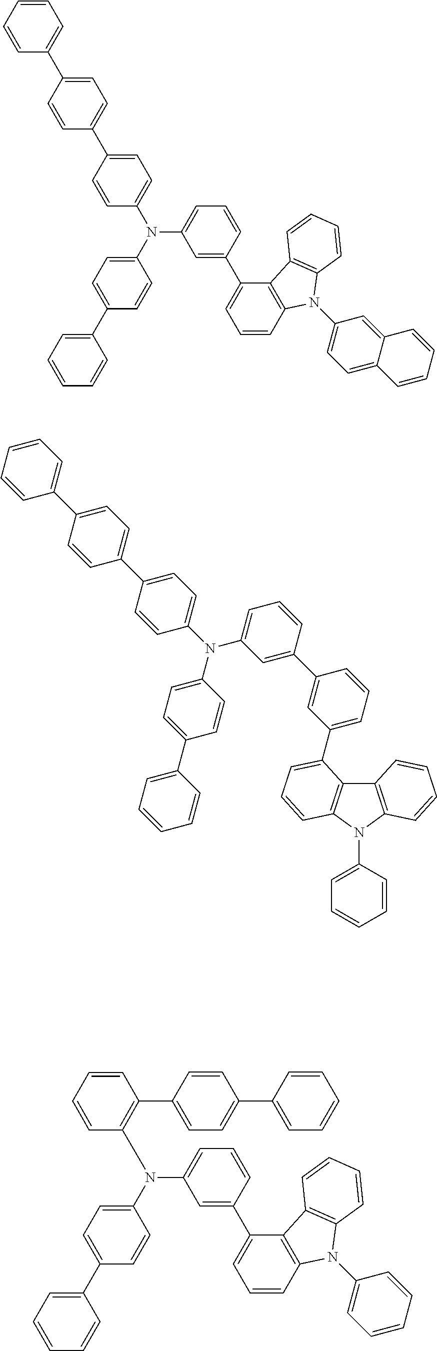 [SMILES: c1ccc(-c2ccc(-c3ccc(N(c4ccc(-c5ccccc5)cc4)c4cccc(-c5cccc6c5c5ccccc5n6-c5ccc6ccccc6c5)c4)cc3)cc2)cc1 ; c1ccc(-c2ccc(-c3ccc(N(c4ccc(-c5ccccc5)cc4)c4cccc(-c5cccc(-c6cccc7c6c6ccccc6n7-c6ccccc6)c5)c4)cc3)cc2)cc1 ; c1ccc(-c2ccc(-c3ccccc3N(c3ccc(-c4ccccc4)cc3)c3cccc(-c4cccc5c4c4ccccc4n5-c4ccccc4)c3)cc2)cc1]

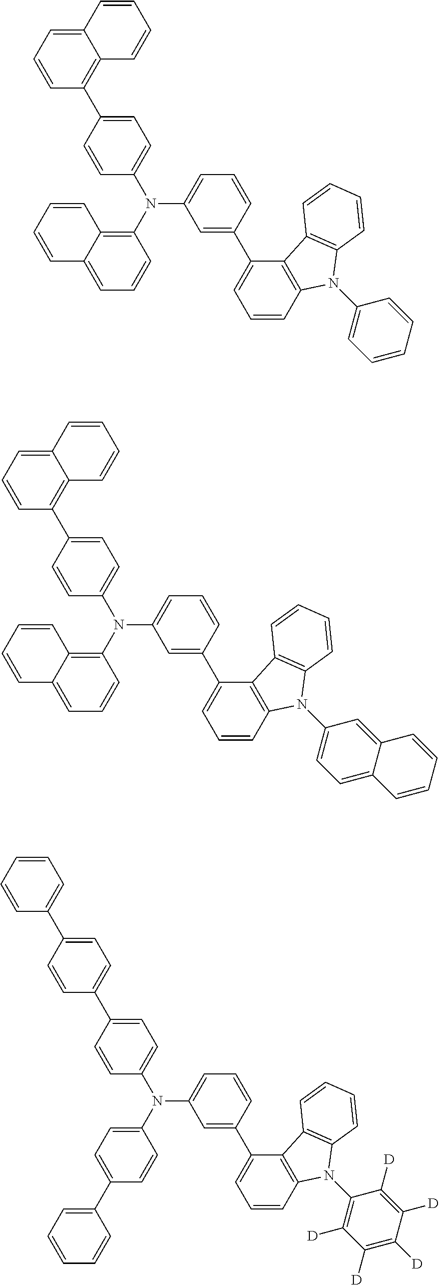 [SMILES: c1ccc(-n2c3ccccc3c3c(-c4cccc(N(c5ccc(-c6cccc7ccccc67)cc5)c5cccc6ccccc56)c4)cccc32)cc1 ; c1cc(-c2cccc3c2c2ccccc2n3-c2ccc3ccccc3c2)cc(N(c2ccc(-c3cccc4ccccc34)cc2)c2cccc3ccccc23)c1 ; [2H]c1c([2H])c([2H])c(-n2c3ccccc3c3c(-c4cccc(N(c5ccc(-c6ccccc6)cc5)c5ccc(-c6ccc(-c7ccccc7)cc6)cc5)c4)cccc32)c([2H])c1[2H]]

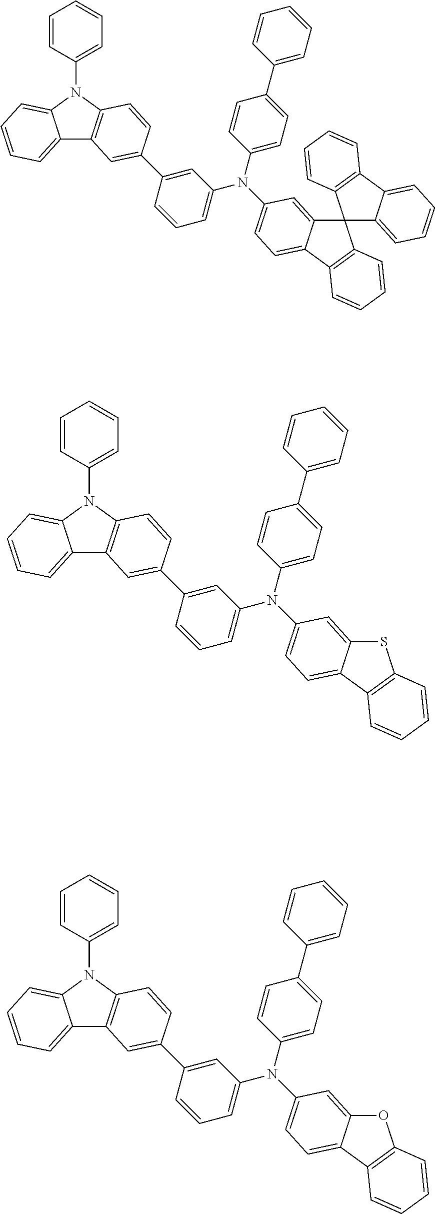 [SMILES: c1ccc(-c2ccc(N(c3cccc(-c4ccc5c(c4)c4ccccc4n5-c4ccccc4)c3)c3ccc4c(c3)C3(c5ccccc5-c5ccccc53)c3ccccc3-4)cc2)cc1 ; c1ccc(-c2ccc(N(c3cccc(-c4ccc5c(c4)c4ccccc4n5-c4ccccc4)c3)c3ccc4c(c3)sc3ccccc34)cc2)cc1 ; c1ccc(-c2ccc(N(c3cccc(-c4ccc5c(c4)c4ccccc4n5-c4ccccc4)c3)c3ccc4c(c3)oc3ccccc34)cc2)cc1]

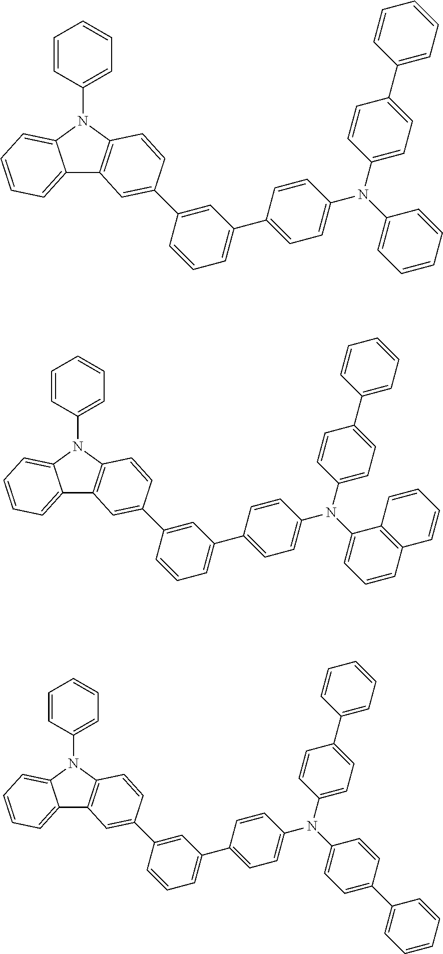 [SMILES: c1ccc(-c2ccc(N(c3ccccc3)c3ccc(-c4cccc(-c5ccc6c(c5)c5ccccc5n6-c5ccccc5)c4)cc3)cc2)cc1 ; c1ccc(-c2ccc(N(c3ccc(-c4cccc(-c5ccc6c(c5)c5ccccc5n6-c5ccccc5)c4)cc3)c3cccc4ccccc34)cc2)cc1 ; c1ccc(-c2ccc(N(c3ccc(-c4ccccc4)cc3)c3ccc(-c4cccc(-c5ccc6c(c5)c5ccccc5n6-c5ccccc5)c4)cc3)cc2)cc1]

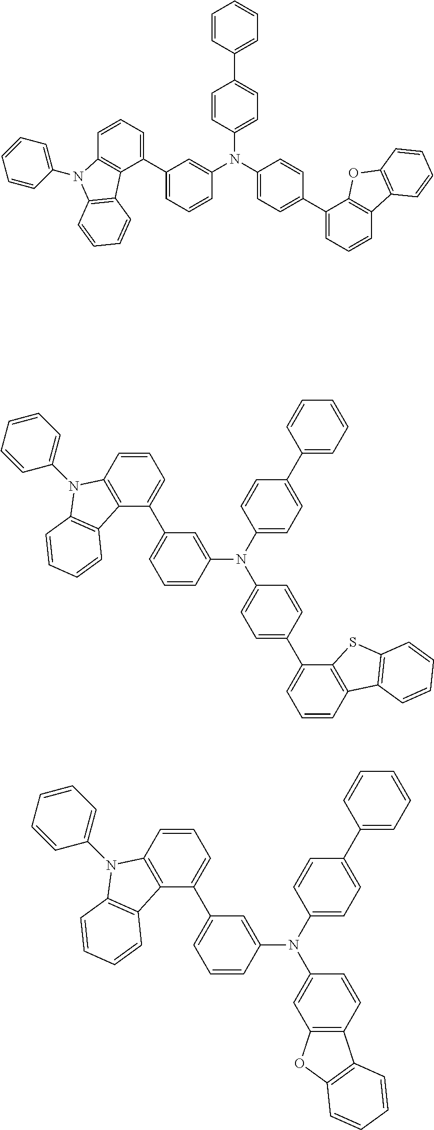 [SMILES: c1ccc(-c2ccc(N(c3ccc(-c4cccc5c4oc4ccccc45)cc3)c3cccc(-c4cccc5c4c4ccccc4n5-c4ccccc4)c3)cc2)cc1 ; c1ccc(-c2ccc(N(c3ccc(-c4cccc5c4sc4ccccc45)cc3)c3cccc(-c4cccc5c4c4ccccc4n5-c4ccccc4)c3)cc2)cc1 ; c1ccc(-c2ccc(N(c3cccc(-c4cccc5c4c4ccccc4n5-c4ccccc4)c3)c3ccc4c(c3)oc3ccccc34)cc2)cc1]

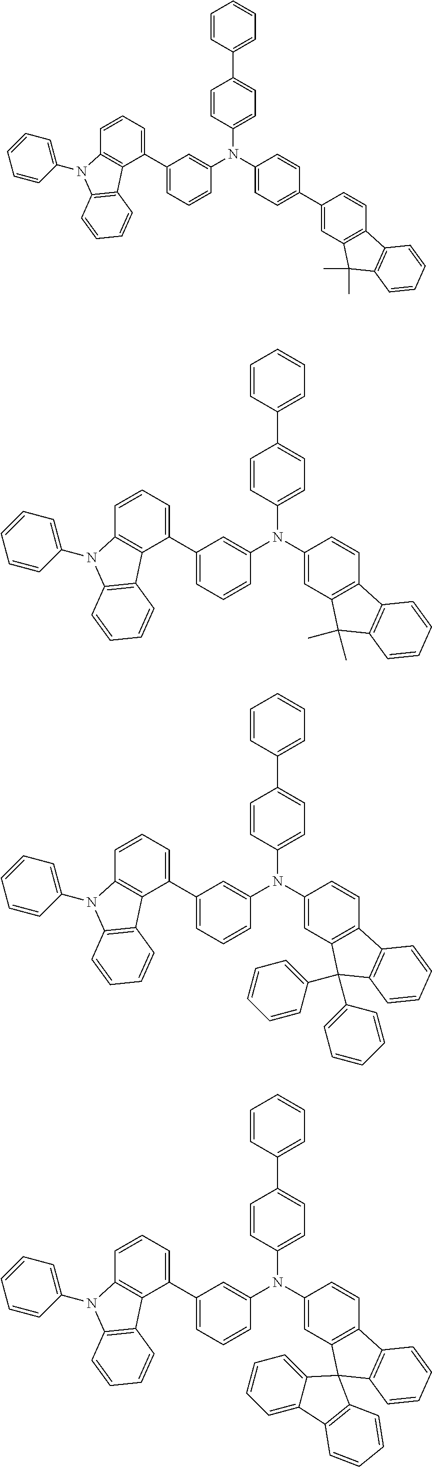 [SMILES: CC1(C)c2ccccc2-c2ccc(-c3ccc(N(c4ccc(-c5ccccc5)cc4)c4cccc(-c5cccc6c5c5ccccc5n6-c5ccccc5)c4)cc3)cc21 ; CC1(C)c2ccccc2-c2ccc(N(c3ccc(-c4ccccc4)cc3)c3cccc(-c4cccc5c4c4ccccc4n5-c4ccccc4)c3)cc21 ; c1ccc(-c2ccc(N(c3cccc(-c4cccc5c4c4ccccc4n5-c4ccccc4)c3)c3ccc4c(c3)C(c3ccccc3)(c3ccccc3)c3ccccc3-4)cc2)cc1 ; c1ccc(-c2ccc(N(c3cccc(-c4cccc5c4c4ccccc4n5-c4ccccc4)c3)c3ccc4c(c3)C3(c5ccccc5-c5ccccc53)c3ccccc3-4)cc2)cc1]

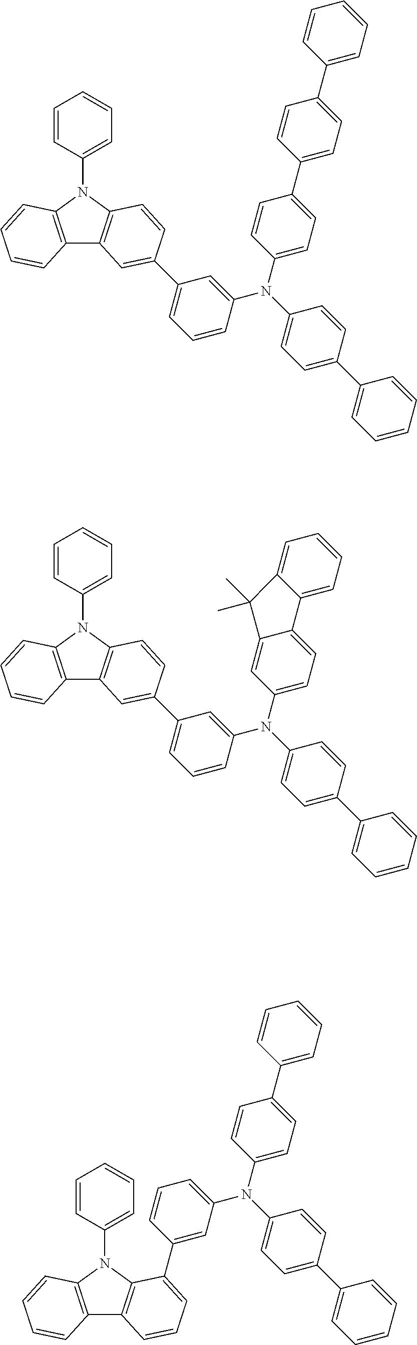 [SMILES: c1ccc(-c2ccc(-c3ccc(N(c4ccc(-c5ccccc5)cc4)c4cccc(-c5ccc6c(c5)c5ccccc5n6-c5ccccc5)c4)cc3)cc2)cc1 ; CC1(C)c2ccccc2-c2ccc(N(c3ccc(-c4ccccc4)cc3)c3cccc(-c4ccc5c(c4)c4ccccc4n5-c4ccccc4)c3)cc21 ; c1ccc(-c2ccc(N(c3ccc(-c4ccccc4)cc3)c3cccc(-c4cccc5c6ccccc6n(-c6ccccc6)c45)c3)cc2)cc1]

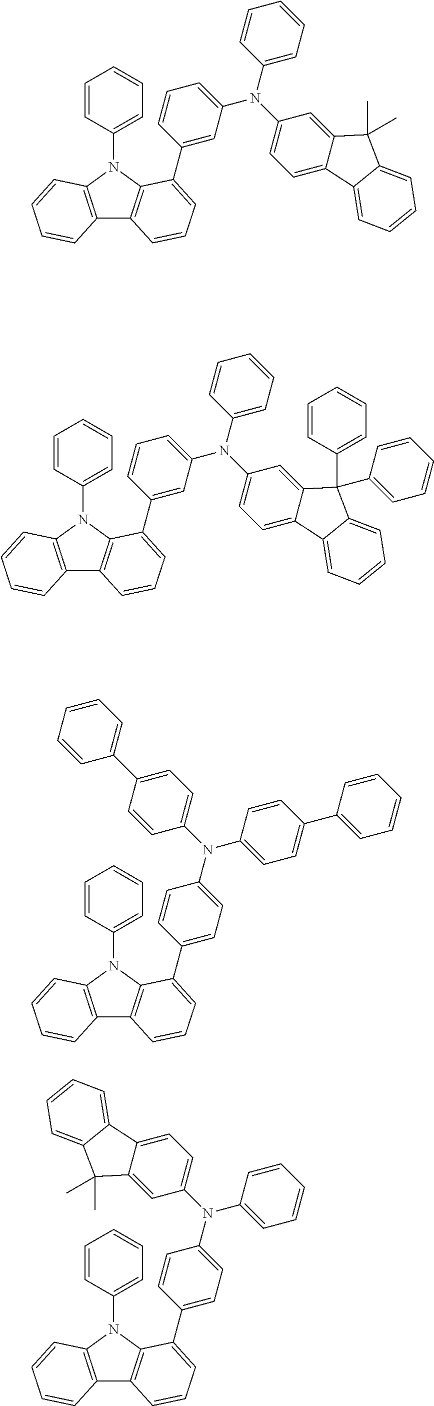

### (Second Compound in First Composition and Second Composition)

The second compound in the first composition and the second composition can be synthesized by using known alternative reactions or raw materials adapted to the target compound.

Specific examples of the second compound in the first composition and the second composition will be described below, but these are merely examples, and the second compound is not limited to the following specific examples.

As specific examples of the second compound in the first composition, all of the following compounds can be given. As specific examples of the second compound in the second composition, a cmopound satisfying the formula (23) can be given among the following compounds.

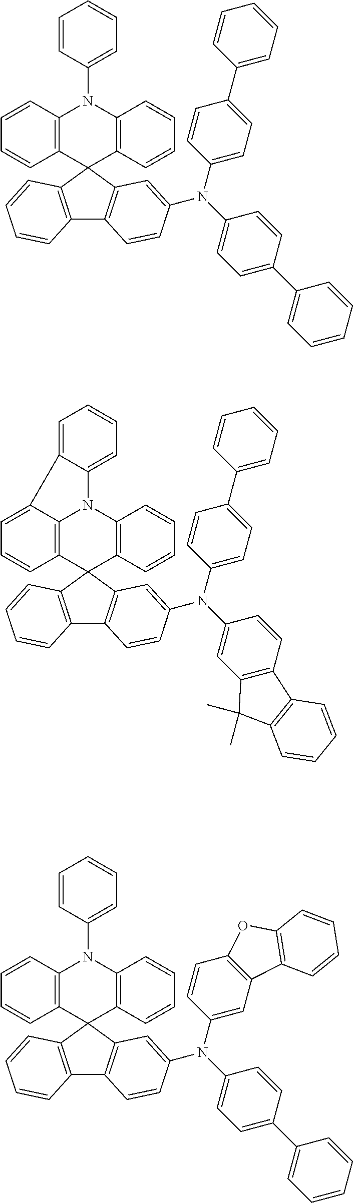 [SMILES: c1ccc(-c2ccc(N(c3ccc(-c4ccccc4)cc3)c3ccc4c(c3)C3(c5ccccc5-4)c4ccccc4N(c4ccccc4)c4ccccc43)cc2)cc1 ; CC1(C)c2ccccc2-c2ccc(N(c3ccc(-c4ccccc4)cc3)c3ccc4c(c3)C3(c5ccccc5-4)c4ccccc4-n4c5ccccc5c5cccc3c54)cc21 ; c1ccc(-c2ccc(N(c3ccc4c(c3)C3(c5ccccc5-4)c4ccccc4N(c4ccccc4)c4ccccc43)c3ccc4oc5ccccc5c4c3)cc2)cc1]

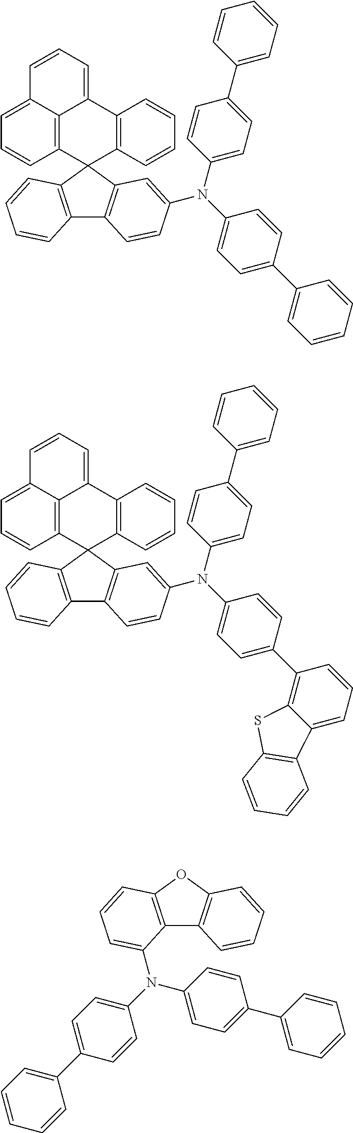 [SMILES: c1ccc(-c2ccc(N(c3ccc(-c4ccccc4)cc3)c3ccc4c(c3)C3(c5ccccc5-4)c4ccccc4-c4cccc5cccc3c45)cc2)cc1 ; c1ccc(-c2ccc(N(c3ccc(-c4cccc5c4sc4ccccc45)cc3)c3ccc4c(c3)C3(c5ccccc5-4)c4ccccc4-c4cccc5cccc3c45)cc2)cc1 ; c1ccc(-c2ccc(N(c3ccc(-c4ccccc4)cc3)c3cccc4oc5ccccc5c34)cc2)cc1]

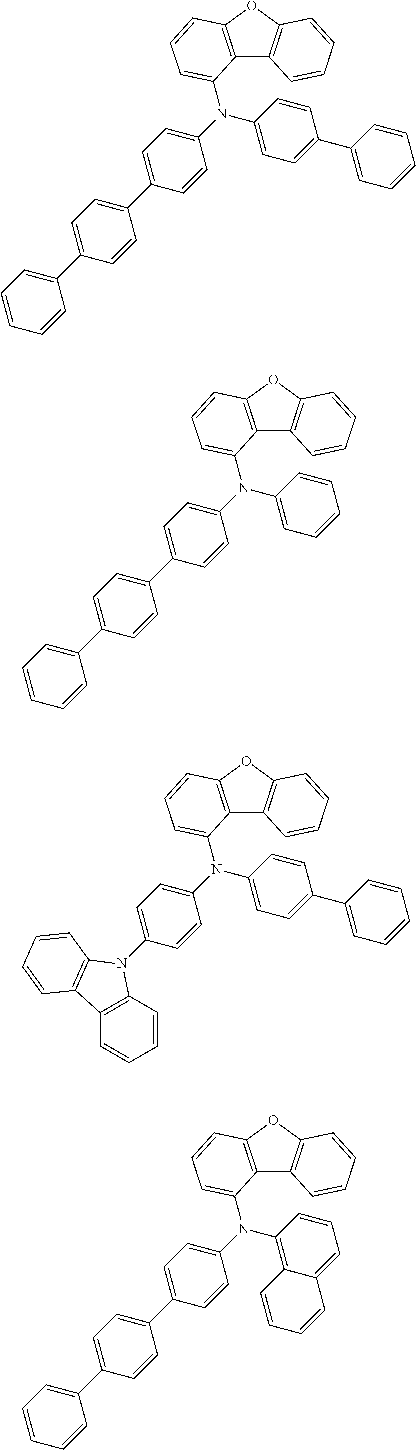 [SMILES: c1ccc(-c2ccc(-c3ccc(N(c4ccc(-c5ccccc5)cc4)c4cccc5oc6ccccc6c45)cc3)cc2)cc1 ; c1ccc(-c2ccc(-c3ccc(N(c4ccccc4)c4cccc5oc6ccccc6c45)cc3)cc2)cc1 ; c1ccc(-c2ccc(N(c3ccc(-n4c5ccccc5c5ccccc54)cc3)c3cccc4oc5ccccc5c34)cc2)cc1 ; c1ccc(-c2ccc(-c3ccc(N(c4cccc5ccccc45)c4cccc5oc6ccccc6c45)cc3)cc2)cc1]

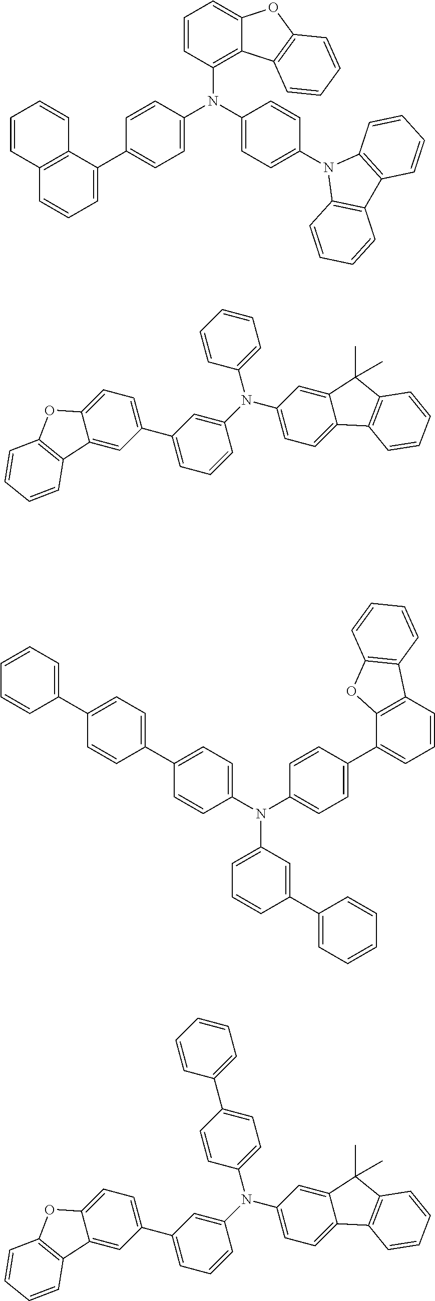 [SMILES: c1ccc2c(-c3ccc(N(c4ccc(-n5c6ccccc6c6ccccc65)cc4)c4cccc5oc6ccccc6c45)cc3)cccc2c1 ; CC1(C)c2ccccc2-c2ccc(N(c3ccccc3)c3cccc(-c4ccc5oc6ccccc6c5c4)c3)cc21 ; c1ccc(-c2ccc(-c3ccc(N(c4ccc(-c5cccc6c5oc5ccccc56)cc4)c4cccc(-c5ccccc5)c4)cc3)cc2)cc1 ; CC1(C)c2ccccc2-c2ccc(N(c3ccc(-c4ccccc4)cc3)c3cccc(-c4ccc5oc6ccccc6c5c4)c3)cc21]

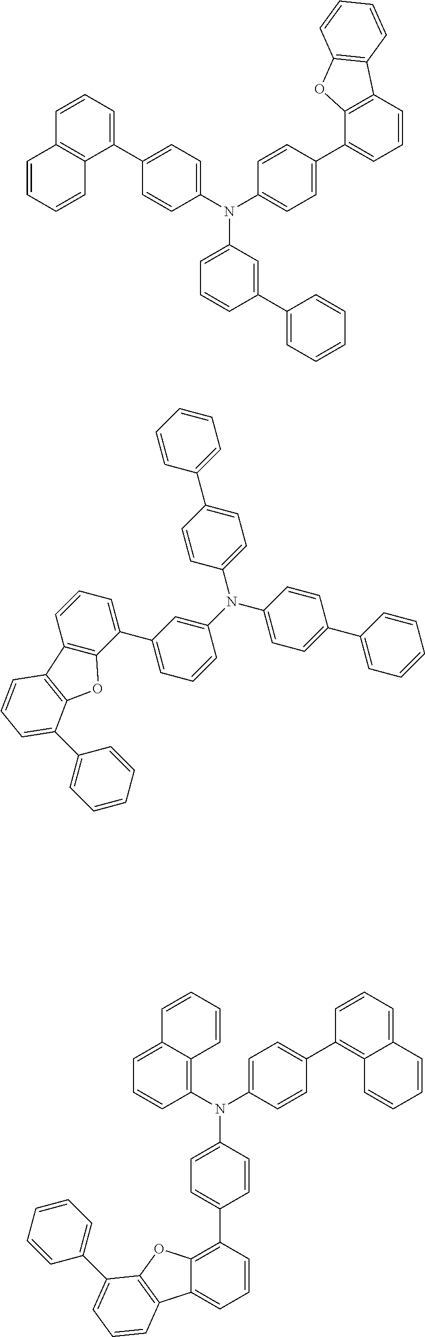 [SMILES: c1ccc(-c2cccc(N(c3ccc(-c4cccc5ccccc45)cc3)c3ccc(-c4cccc5c4oc4ccccc45)cc3)c2)cc1 ; c1ccc(-c2ccc(N(c3ccc(-c4ccccc4)cc3)c3cccc(-c4cccc5c4oc4c(-c6ccccc6)cccc45)c3)cc2)cc1 ; c1ccc(-c2cccc3c2oc2c(-c4ccc(N(c5ccc(-c6cccc7ccccc67)cc5)c5cccc6ccccc56)cc4)cccc23)cc1]

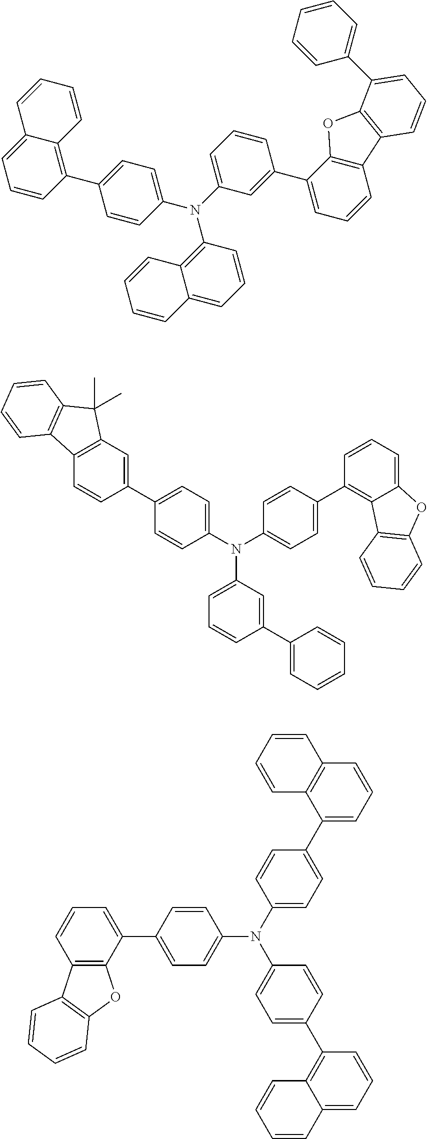

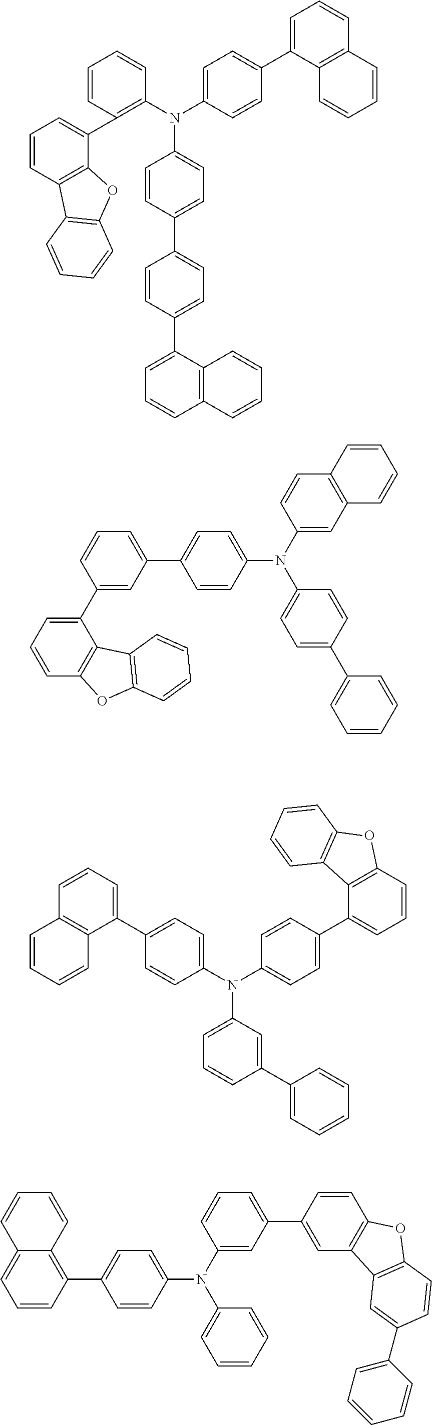 [SMILES: c1ccc(N(c2ccc(-c3ccc(-c4cccc5ccccc45)cc3)cc2)c2ccc(-c3cccc4ccccc34)cc2)c(-c2cccc3c2oc2ccccc23)c1 ; c1ccc(-c2ccc(N(c3ccc(-c4cccc(-c5cccc6oc7ccccc7c56)c4)cc3)c3ccc4ccccc4c3)cc2)cc1 ; c1ccc(-c2cccc(N(c3ccc(-c4cccc5ccccc45)cc3)c3ccc(-c4cccc5oc6ccccc6c45)cc3)c2)cc1 ; c1ccc(-c2ccc3oc4ccc(-c5cccc(N(c6ccccc6)c6ccc(-c7cccc8ccccc78)cc6)c5)cc4c3c2)cc1]

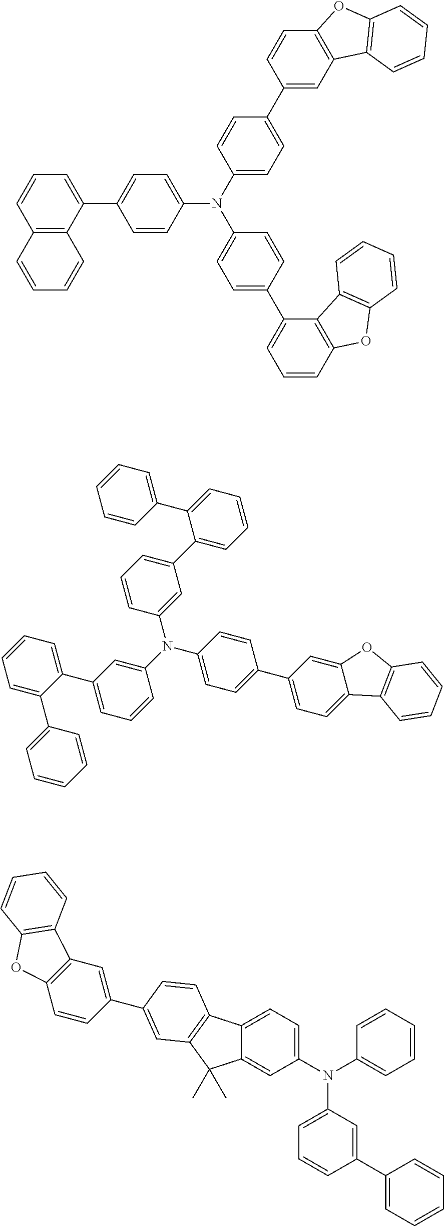 [SMILES: c1ccc2c(-c3ccc(N(c4ccc(-c5ccc6oc7ccccc7c6c5)cc4)c4ccc(-c5cccc6oc7ccccc7c56)cc4)cc3)cccc2c1 ; c1ccc(-c2ccccc2-c2cccc(N(c3ccc(-c4ccc5c(c4)oc4ccccc45)cc3)c3cccc(-c4ccccc4-c4ccccc4)c3)c2)cc1 ; CC1(C)c2cc(-c3ccc4oc5ccccc5c4c3)ccc2-c2ccc(N(c3ccccc3)c3cccc(-c4ccccc4)c3)cc21]

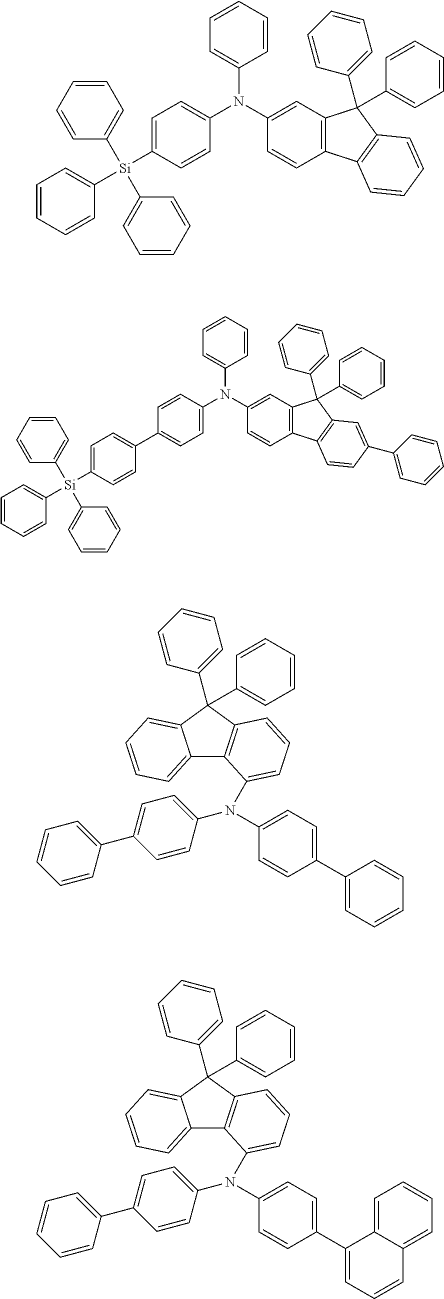 [SMILES: c1ccc(N(c2ccc([Si](c3ccccc3)(c3ccccc3)c3ccccc3)cc2)c2ccc3c(c2)C(c2ccccc2)(c2ccccc2)c2ccccc2-3)cc1 ; c1ccc(-c2ccc3c(c2)C(c2ccccc2)(c2ccccc2)c2cc(N(c4ccccc4)c4ccc(-c5ccc([Si](c6ccccc6)(c6ccccc6)c6ccccc6)cc5)cc4)ccc2-3)cc1 ; c1ccc(-c2ccc(N(c3ccc(-c4ccccc4)cc3)c3cccc4c3-c3ccccc3C4(c3ccccc3)c3ccccc3)cc2)cc1 ; c1ccc(-c2ccc(N(c3ccc(-c4cccc5ccccc45)cc3)c3cccc4c3-c3ccccc3C4(c3ccccc3)c3ccccc3)cc2)cc1]

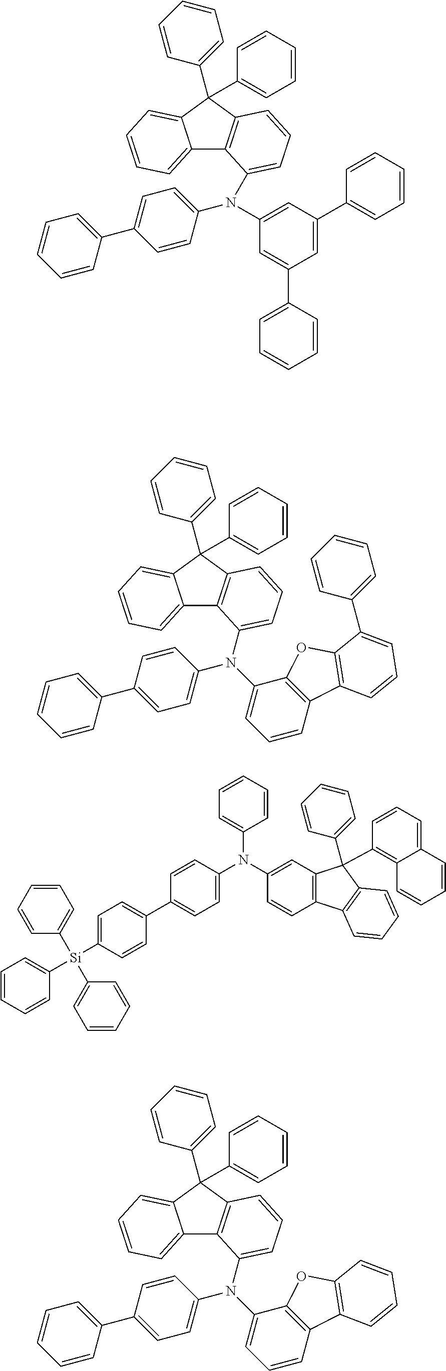

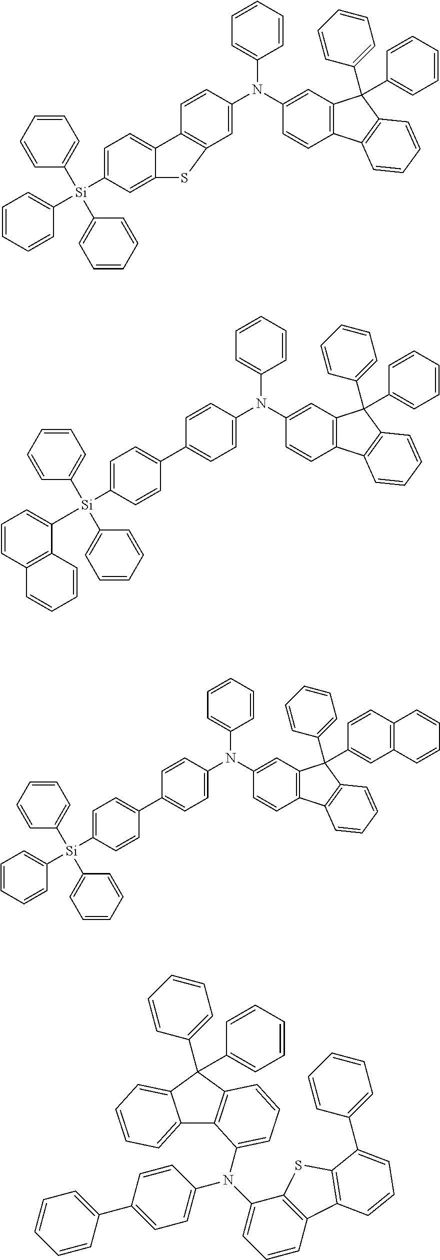 [SMILES: c1ccc(N(c2ccc3c(c2)C(c2ccccc2)(c2ccccc2)c2ccccc2-3)c2ccc3c(c2)sc2cc([Si](c4ccccc4)(c4ccccc4)c4ccccc4)ccc23)cc1 ; c1ccc(N(c2ccc(-c3ccc([Si](c4ccccc4)(c4ccccc4)c4cccc5ccccc45)cc3)cc2)c2ccc3c(c2)C(c2ccccc2)(c2ccccc2)c2ccccc2-3)cc1 ; c1ccc(N(c2ccc(-c3ccc([Si](c4ccccc4)(c4ccccc4)c4ccccc4)cc3)cc2)c2ccc3c(c2)C(c2ccccc2)(c2ccc4ccccc4c2)c2ccccc2-3)cc1 ; c1ccc(-c2ccc(N(c3cccc4c3-c3ccccc3C4(c3ccccc3)c3ccccc3)c3cccc4c3sc3c(-c5ccccc5)cccc34)cc2)cc1]

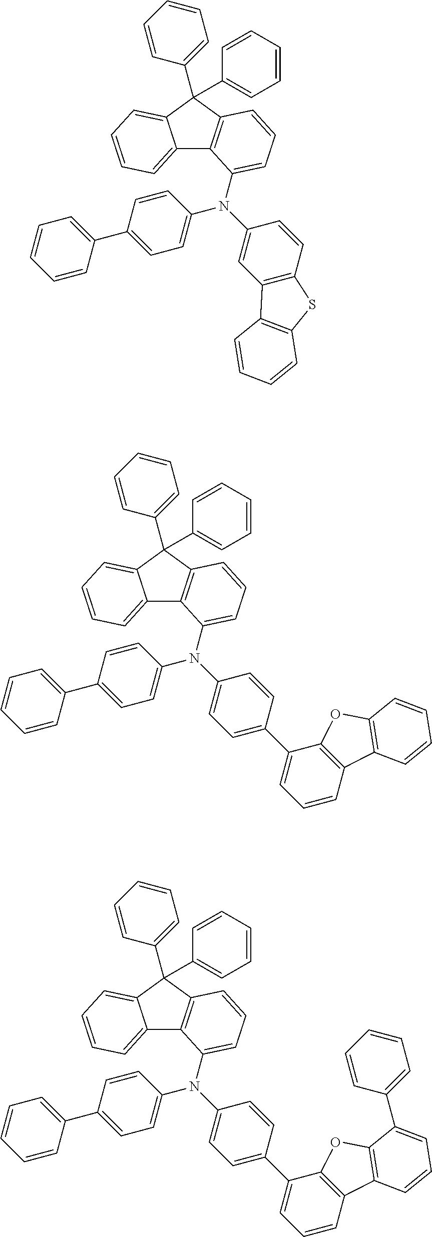 [SMILES: c1ccc(-c2ccc(N(c3ccc4sc5ccccc5c4c3)c3cccc4c3-c3ccccc3C4(c3ccccc3)c3ccccc3)cc2)cc1 ; c1ccc(-c2ccc(N(c3ccc(-c4cccc5c4oc4ccccc45)cc3)c3cccc4c3-c3ccccc3C4(c3ccccc3)c3ccccc3)cc2)cc1 ; c1ccc(-c2ccc(N(c3ccc(-c4cccc5c4oc4c(-c6ccccc6)cccc45)cc3)c3cccc4c3-c3ccccc3C4(c3ccccc3)c3ccccc3)cc2)cc1]

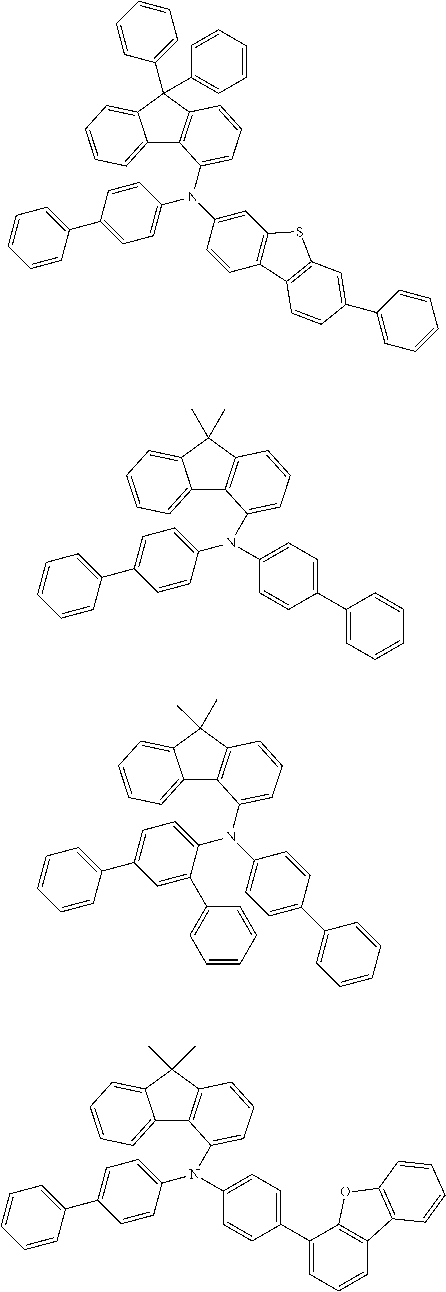 [SMILES: c1ccc(-c2ccc(N(c3ccc4c(c3)sc3cc(-c5ccccc5)ccc34)c3cccc4c3-c3ccccc3C4(c3ccccc3)c3ccccc3)cc2)cc1 ; CC1(C)c2ccccc2-c2c(N(c3ccc(-c4ccccc4)cc3)c3ccc(-c4ccccc4)cc3)cccc21 ; CC1(C)c2ccccc2-c2c(N(c3ccc(-c4ccccc4)cc3)c3ccc(-c4ccccc4)cc3-c3ccccc3)cccc21 ; CC1(C)c2ccccc2-c2c(N(c3ccc(-c4ccccc4)cc3)c3ccc(-c4cccc5c4oc4ccccc45)cc3)cccc21]

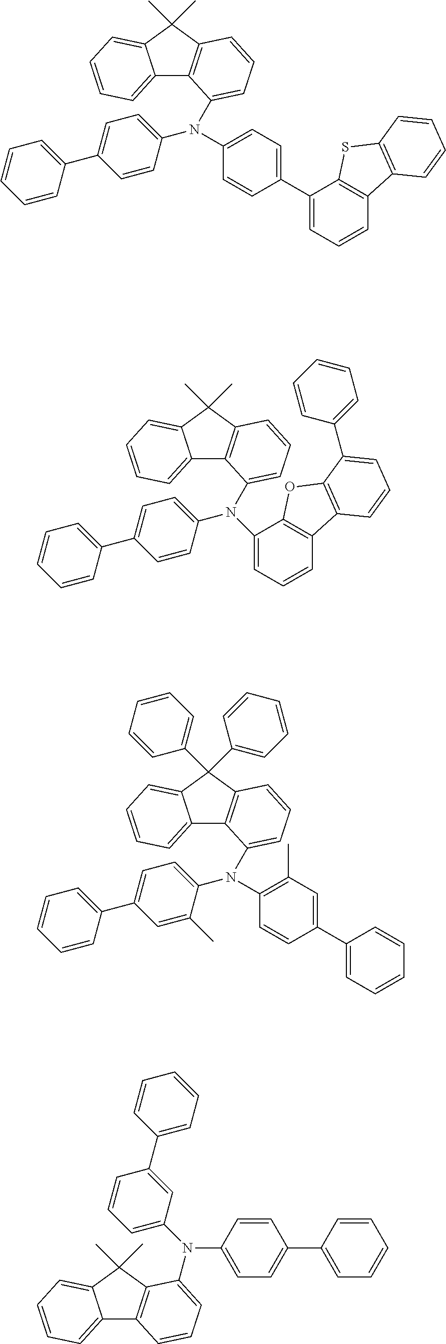 [SMILES: CC1(C)c2ccccc2-c2c(N(c3ccc(-c4ccccc4)cc3)c3ccc(-c4cccc5c4sc4ccccc45)cc3)cccc21 ; CC1(C)c2ccccc2-c2c(N(c3ccc(-c4ccccc4)cc3)c3cccc4c3oc3c(-c5ccccc5)cccc34)cccc21 ; Cc1cc(-c2ccccc2)ccc1N(c1ccc(-c2ccccc2)cc1C)c1cccc2c1-c1ccccc1C2(c1ccccc1)c1ccccc1 ; CC1(C)c2ccccc2-c2cccc(N(c3ccc(-c4ccccc4)cc3)c3cccc(-c4ccccc4)c3)c21]

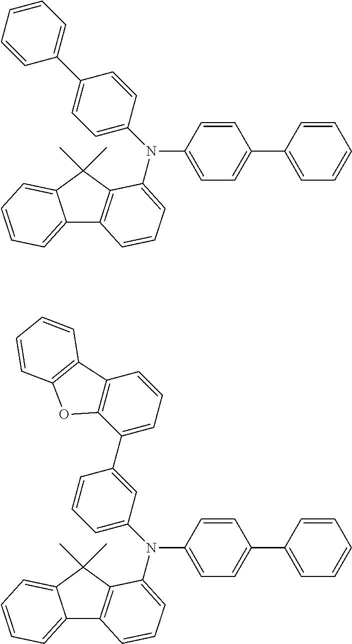 [SMILES: CC1(C)c2ccccc2-c2cccc(N(c3ccc(-c4ccccc4)cc3)c3ccc(-c4ccccc4)cc3)c21 ; CC1(C)c2ccccc2-c2cccc(N(c3ccc(-c4ccccc4)cc3)c3cccc(-c4cccc5c4oc4ccccc45)c3)c21]

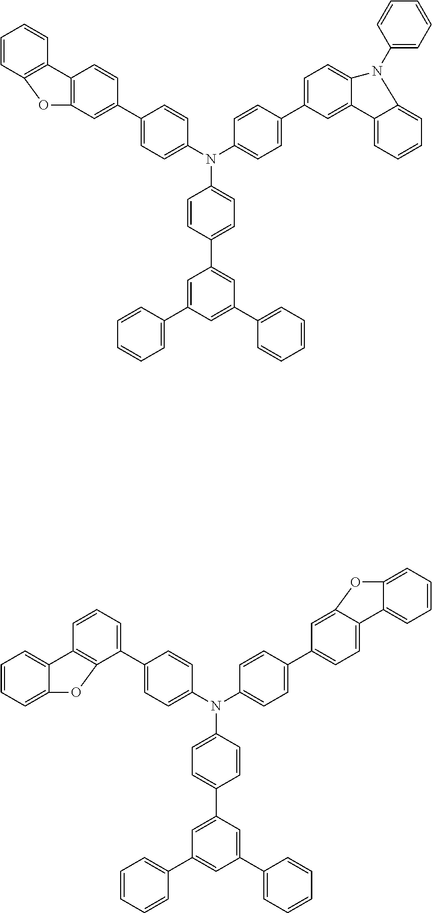 [SMILES: c1ccc(-c2cc(-c3ccccc3)cc(-c3ccc(N(c4ccc(-c5ccc6c(c5)oc5ccccc56)cc4)c4ccc(-c5ccc6c(c5)c5ccccc5n6-c5ccccc5)cc4)cc3)c2)cc1 ; c1ccc(-c2cc(-c3ccccc3)cc(-c3ccc(N(c4ccc(-c5ccc6c(c5)oc5ccccc56)cc4)c4ccc(-c5cccc6c5oc5ccccc56)cc4)cc3)c2)cc1]

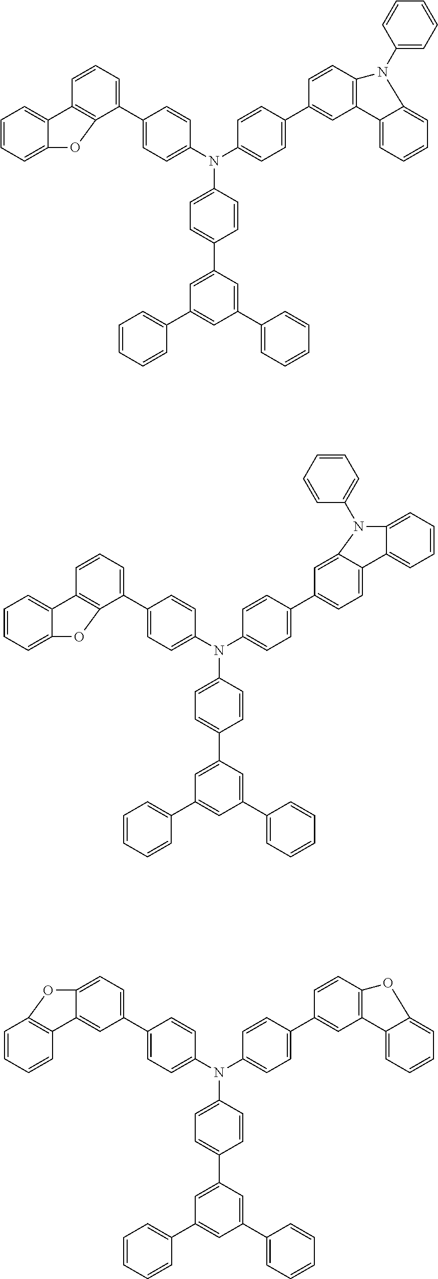 [SMILES: c1ccc(-c2cc(-c3ccccc3)cc(-c3ccc(N(c4ccc(-c5ccc6c(c5)c5ccccc5n6-c5ccccc5)cc4)c4ccc(-c5cccc6c5oc5ccccc56)cc4)cc3)c2)cc1 ; c1ccc(-c2cc(-c3ccccc3)cc(-c3ccc(N(c4ccc(-c5ccc6c7ccccc7n(-c7ccccc7)c6c5)cc4)c4ccc(-c5cccc6c5oc5ccccc56)cc4)cc3)c2)cc1 ; c1ccc(-c2cc(-c3ccccc3)cc(-c3ccc(N(c4ccc(-c5ccc6oc7ccccc7c6c5)cc4)c4ccc(-c5ccc6oc7ccccc7c6c5)cc4)cc3)c2)cc1]

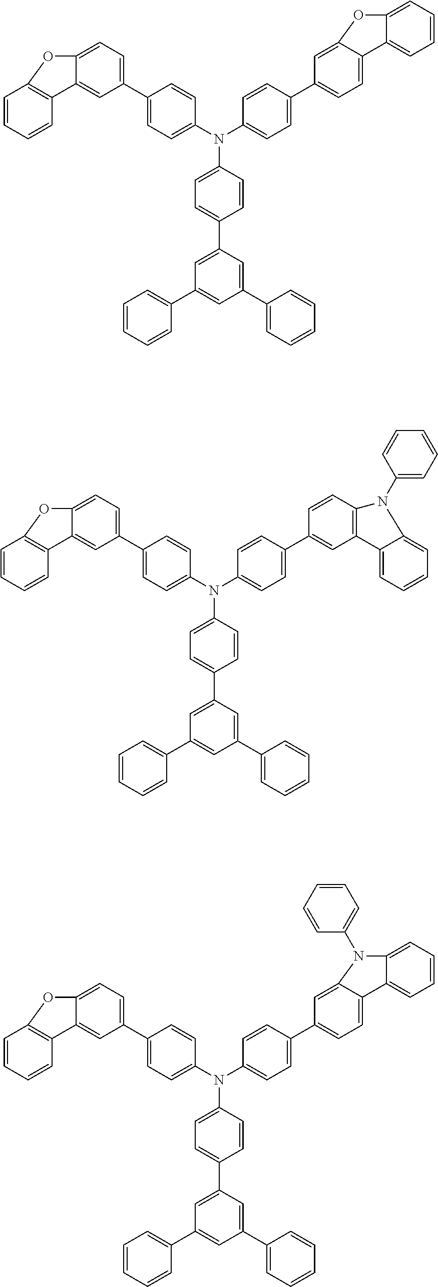 [SMILES: c1ccc(-c2cc(-c3ccccc3)cc(-c3ccc(N(c4ccc(-c5ccc6c(c5)oc5ccccc56)cc4)c4ccc(-c5ccc6oc7ccccc7c6c5)cc4)cc3)c2)cc1 ; c1ccc(-c2cc(-c3ccccc3)cc(-c3ccc(N(c4ccc(-c5ccc6oc7ccccc7c6c5)cc4)c4ccc(-c5ccc6c(c5)c5ccccc5n6-c5ccccc5)cc4)cc3)c2)cc1 ; c1ccc(-c2cc(-c3ccccc3)cc(-c3ccc(N(c4ccc(-c5ccc6oc7ccccc7c6c5)cc4)c4ccc(-c5ccc6c7ccccc7n(-c7ccccc7)c6c5)cc4)cc3)c2)cc1]

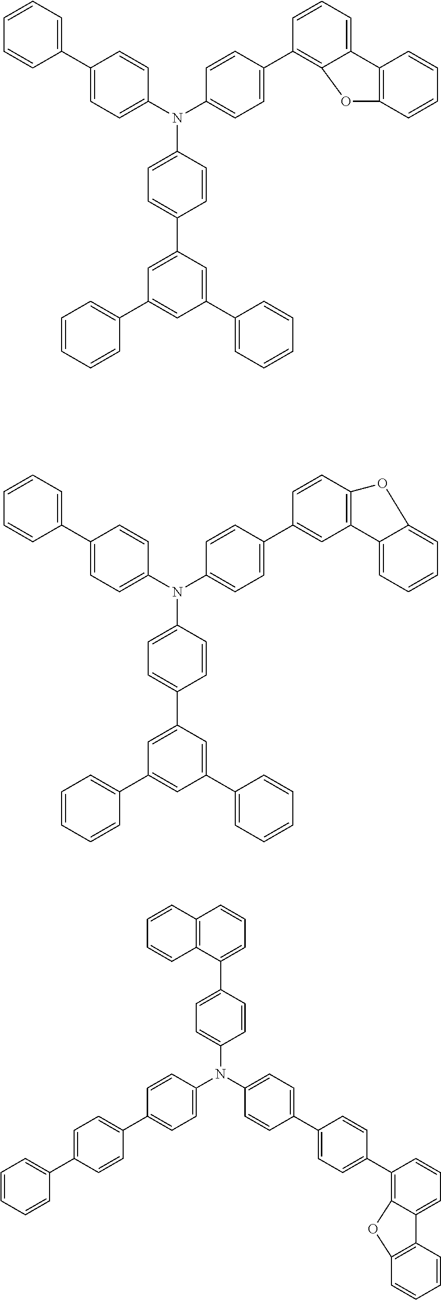 [SMILES: c1ccc(-c2ccc(N(c3ccc(-c4cc(-c5ccccc5)cc(-c5ccccc5)c4)cc3)c3ccc(-c4cccc5c4oc4ccccc45)cc3)cc2)cc1 ; c1ccc(-c2ccc(N(c3ccc(-c4cc(-c5ccccc5)cc(-c5ccccc5)c4)cc3)c3ccc(-c4ccc5oc6ccccc6c5c4)cc3)cc2)cc1 ; c1ccc(-c2ccc(-c3ccc(N(c4ccc(-c5ccc(-c6cccc7c6oc6ccccc67)cc5)cc4)c4ccc(-c5cccc6ccccc56)cc4)cc3)cc2)cc1]

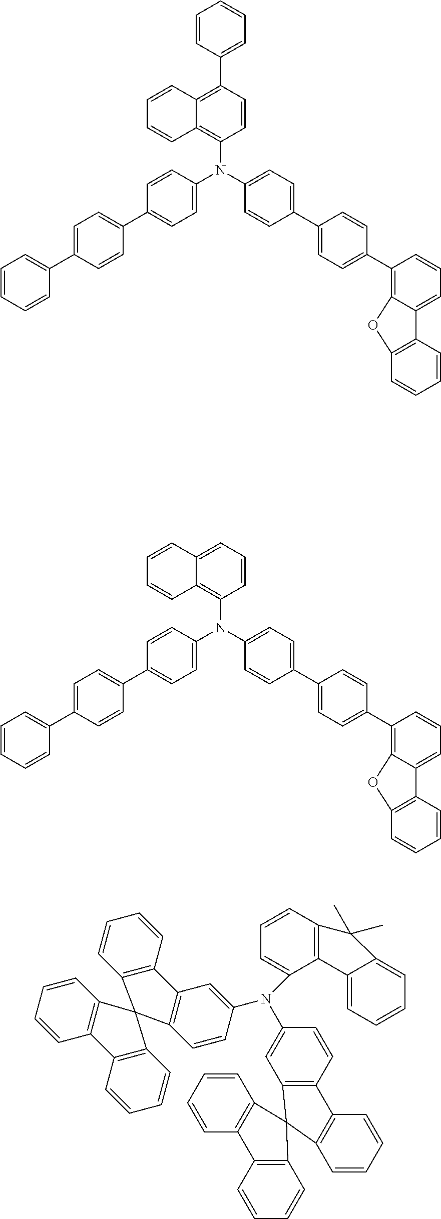 [SMILES: c1ccc(-c2ccc(-c3ccc(N(c4ccc(-c5ccc(-c6cccc7c6oc6ccccc67)cc5)cc4)c4ccc(-c5ccccc5)c5ccccc45)cc3)cc2)cc1 ; c1ccc(-c2ccc(-c3ccc(N(c4ccc(-c5ccc(-c6cccc7c6oc6ccccc67)cc5)cc4)c4cccc5ccccc45)cc3)cc2)cc1 ; CC1(C)c2ccccc2-c2c(N(c3ccc4c(c3)-c3ccccc3C43c4ccccc4-c4ccccc43)c3ccc4c(c3)C3(c5ccccc5-c5ccccc53)c3ccccc3-4)cccc21]

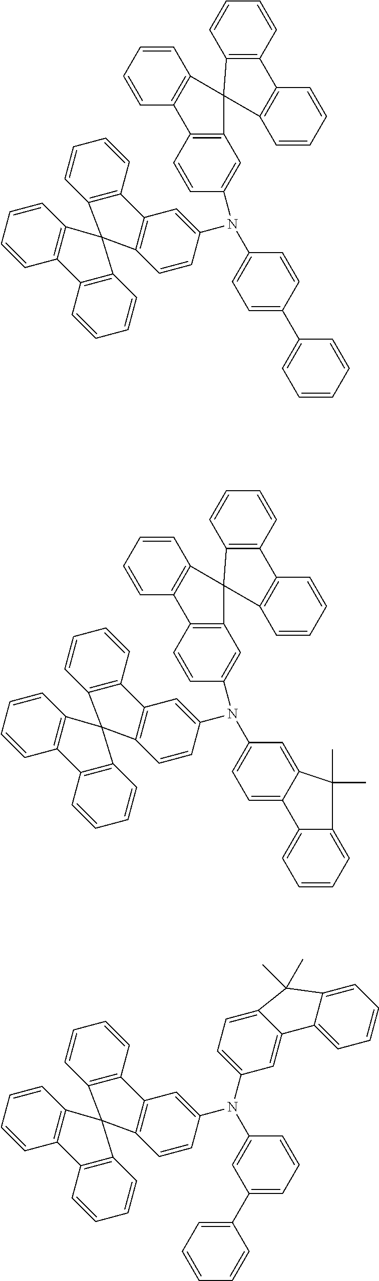 [SMILES: c1ccc(-c2ccc(N(c3ccc4c(c3)-c3ccccc3C43c4ccccc4-c4ccccc43)c3ccc4c(c3)C3(c5ccccc5-c5ccccc53)c3ccccc3-4)cc2)cc1 ; CC1(C)c2ccccc2-c2ccc(N(c3ccc4c(c3)-c3ccccc3C43c4ccccc4-c4ccccc43)c3ccc4c(c3)C3(c5ccccc5-c5ccccc53)c3ccccc3-4)cc21 ; CC1(C)c2ccccc2-c2cc(N(c3cccc(-c4ccccc4)c3)c3ccc4c(c3)-c3ccccc3C43c4ccccc4-c4ccccc43)ccc21]

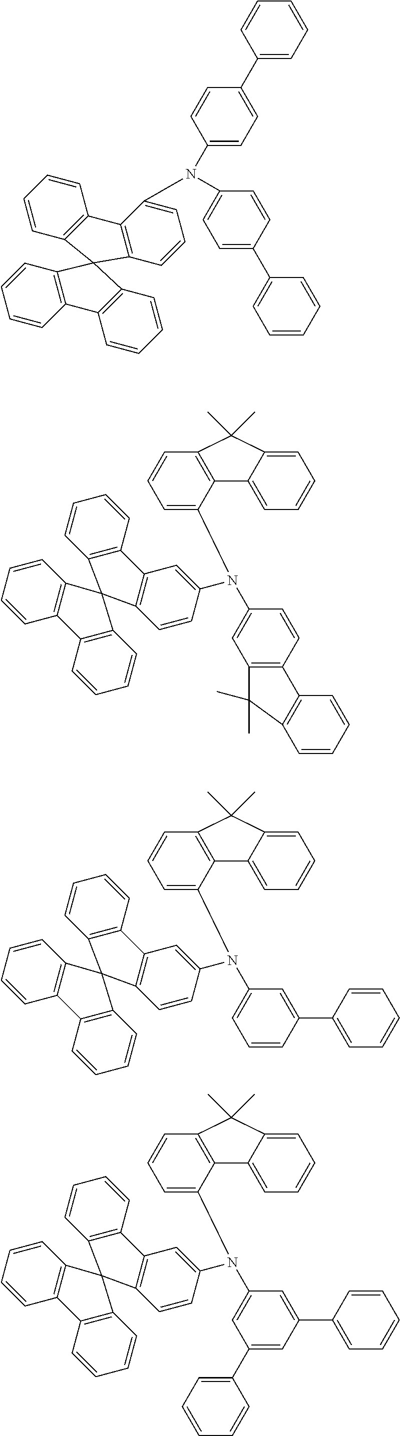 [SMILES: c1ccc(-c2ccc(N(c3ccc(-c4ccccc4)cc3)c3cccc4c3-c3ccccc3C43c4ccccc4-c4ccccc43)cc2)cc1 ; CC1(C)c2ccccc2-c2ccc(N(c3ccc4c(c3)-c3ccccc3C43c4ccccc4-c4ccccc43)c3cccc4c3-c3ccccc3C4(C)C)cc21 ; CC1(C)c2ccccc2-c2c(N(c3cccc(-c4ccccc4)c3)c3ccc4c(c3)-c3ccccc3C43c4ccccc4-c4ccccc43)cccc21 ; CC1(C)c2ccccc2-c2c(N(c3cc(-c4ccccc4)cc(-c4ccccc4)c3)c3ccc4c(c3)-c3ccccc3C43c4ccccc4-c4ccccc43)cccc21]

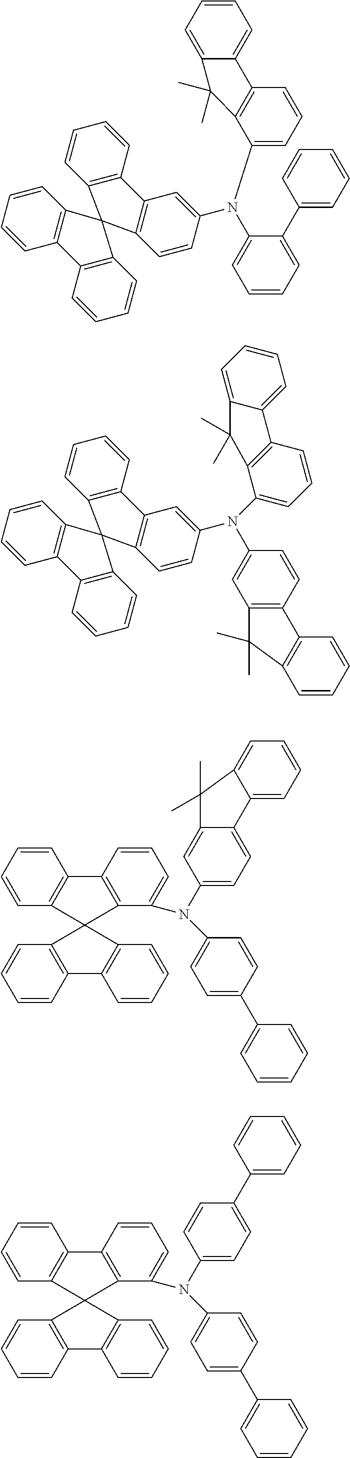

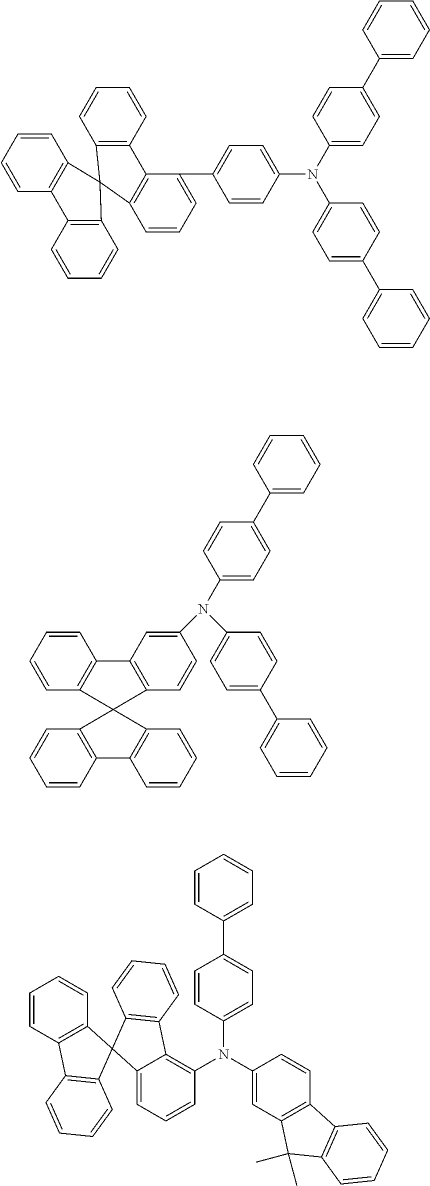 [SMILES: c1ccc(-c2ccc(N(c3ccc(-c4ccccc4)cc3)c3ccc(-c4cccc5c4-c4ccccc4C54c5ccccc5-c5ccccc54)cc3)cc2)cc1 ; c1ccc(-c2ccc(N(c3ccc(-c4ccccc4)cc3)c3ccc4c(c3)-c3ccccc3C43c4ccccc4-c4ccccc43)cc2)cc1 ; CC1(C)c2ccccc2-c2ccc(N(c3ccc(-c4ccccc4)cc3)c3cccc4c3-c3ccccc3C43c4ccccc4-c4ccccc43)cc21]

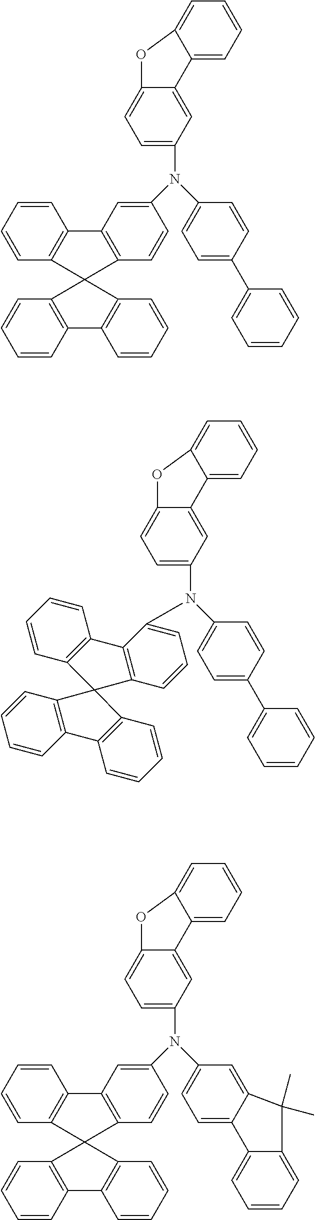

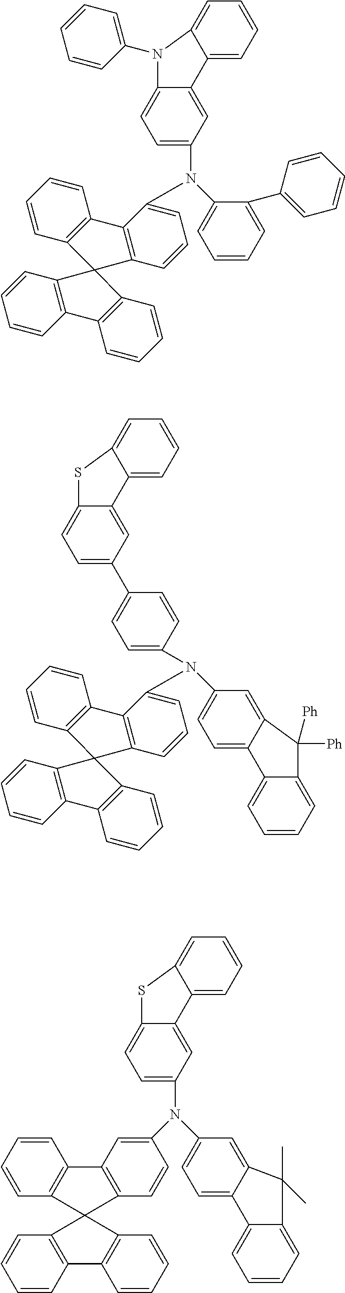

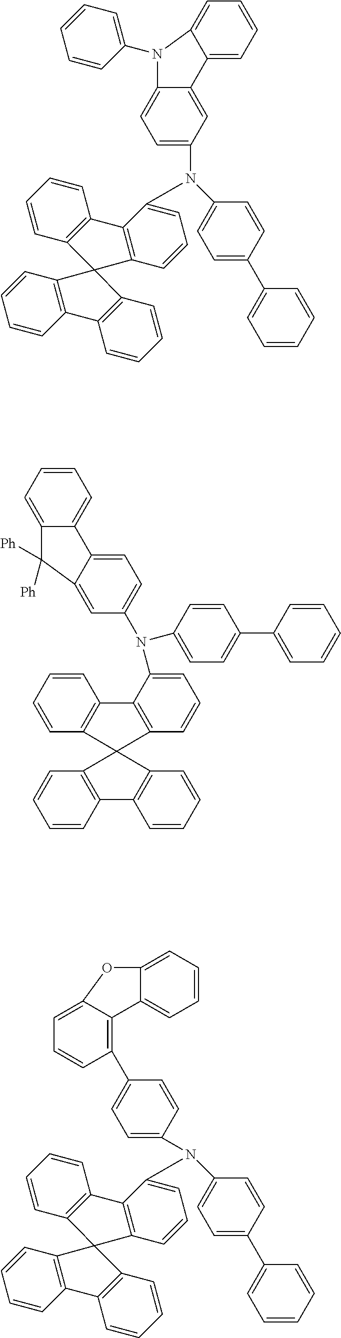

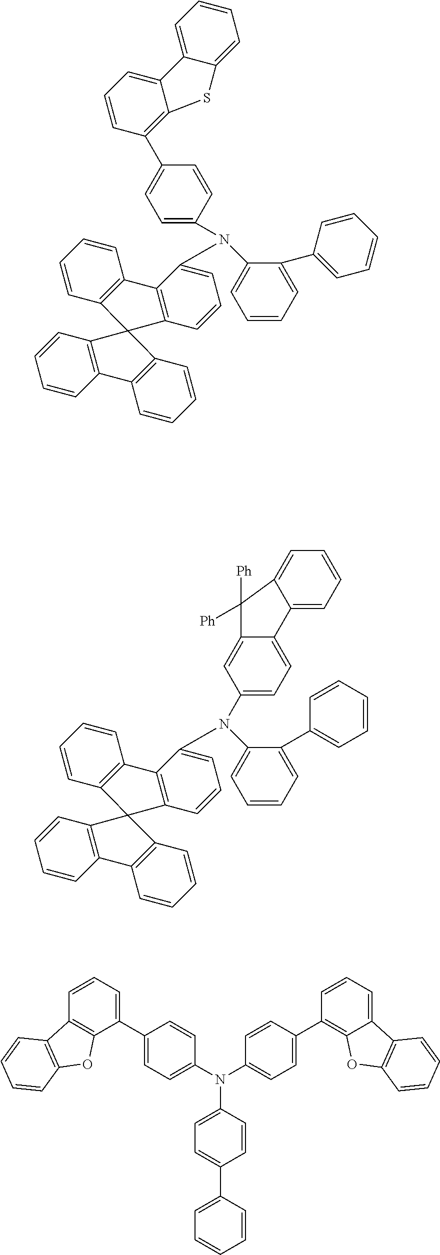

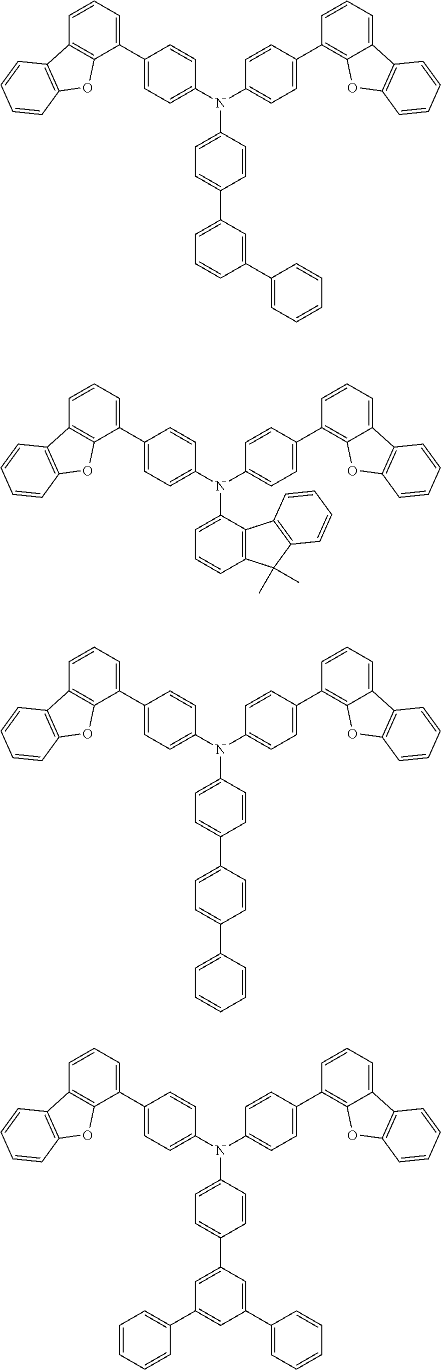 [SMILES: c1ccc(-c2cccc(-c3ccc(N(c4ccc(-c5cccc6c5oc5ccccc56)cc4)c4ccc(-c5cccc6c5oc5ccccc56)cc4)cc3)c2)cc1 ; CC1(C)c2ccccc2-c2c(N(c3ccc(-c4cccc5c4oc4ccccc45)cc3)c3ccc(-c4cccc5c4oc4ccccc45)cc3)cccc21 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; c1ccc(-c2cc(-c3ccccc3)cc(-c3ccc(N(c4ccc(-c5cccc6c5oc5ccccc56)cc4)c4ccc(-c5cccc6c5oc5ccccc56)cc4)cc3)c2)cc1]

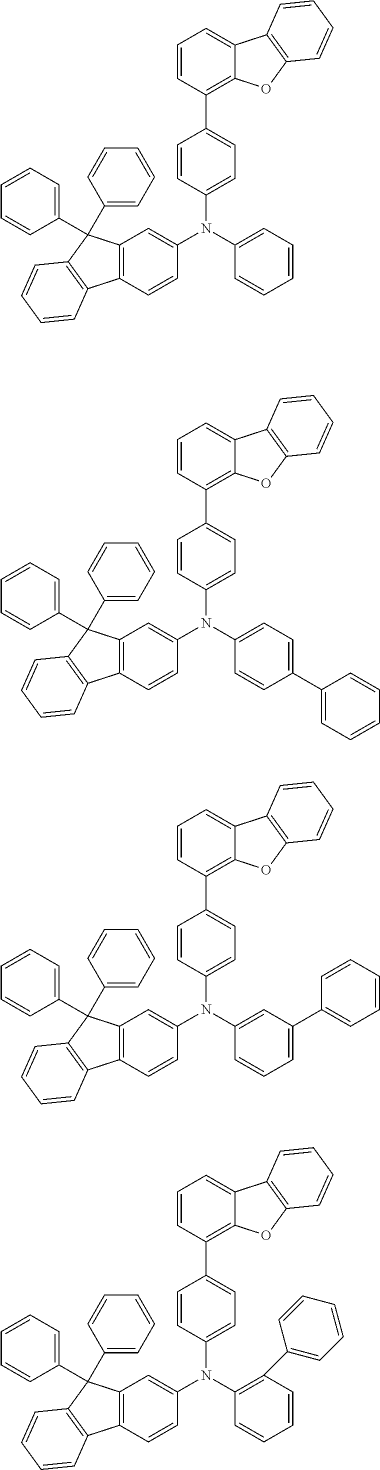 [SMILES: c1ccc(N(c2ccc(-c3cccc4c3oc3ccccc34)cc2)c2ccc3c(c2)C(c2ccccc2)(c2ccccc2)c2ccccc2-3)cc1 ; c1ccc(-c2ccc(N(c3ccc(-c4cccc5c4oc4ccccc45)cc3)c3ccc4c(c3)C(c3ccccc3)(c3ccccc3)c3ccccc3-4)cc2)cc1 ; c1ccc(-c2cccc(N(c3ccc(-c4cccc5c4oc4ccccc45)cc3)c3ccc4c(c3)C(c3ccccc3)(c3ccccc3)c3ccccc3-4)c2)cc1 ; c1ccc(-c2ccccc2N(c2ccc(-c3cccc4c3oc3ccccc34)cc2)c2ccc3c(c2)C(c2ccccc2)(c2ccccc2)c2ccccc2-3)cc1]

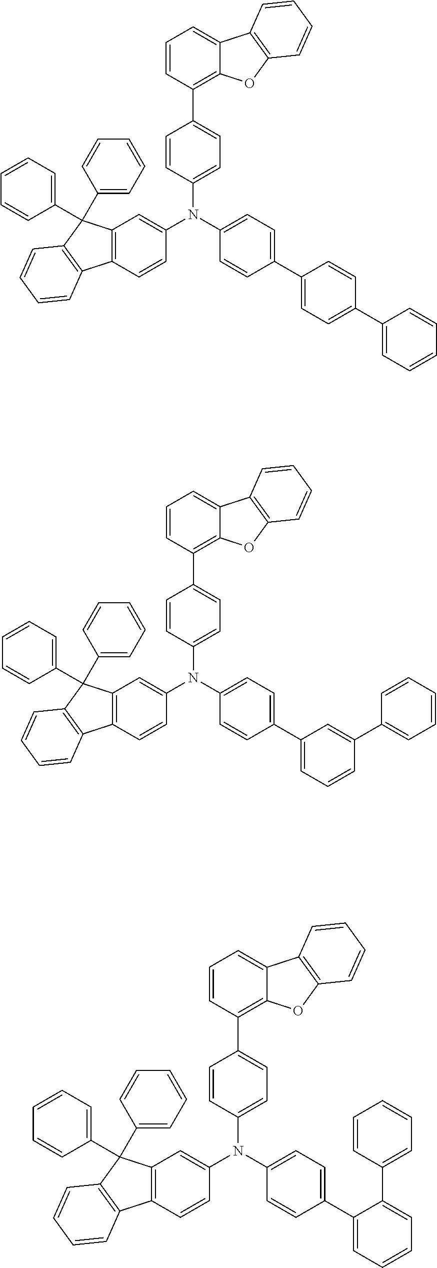 [SMILES: c1ccc(-c2ccc(-c3ccc(N(c4ccc(-c5cccc6c5oc5ccccc56)cc4)c4ccc5c(c4)C(c4ccccc4)(c4ccccc4)c4ccccc4-5)cc3)cc2)cc1 ; c1ccc(-c2cccc(-c3ccc(N(c4ccc(-c5cccc6c5oc5ccccc56)cc4)c4ccc5c(c4)C(c4ccccc4)(c4ccccc4)c4ccccc4-5)cc3)c2)cc1 ; c1ccc(-c2ccccc2-c2ccc(N(c3ccc(-c4cccc5c4oc4ccccc45)cc3)c3ccc4c(c3)C(c3ccccc3)(c3ccccc3)c3ccccc3-4)cc2)cc1]

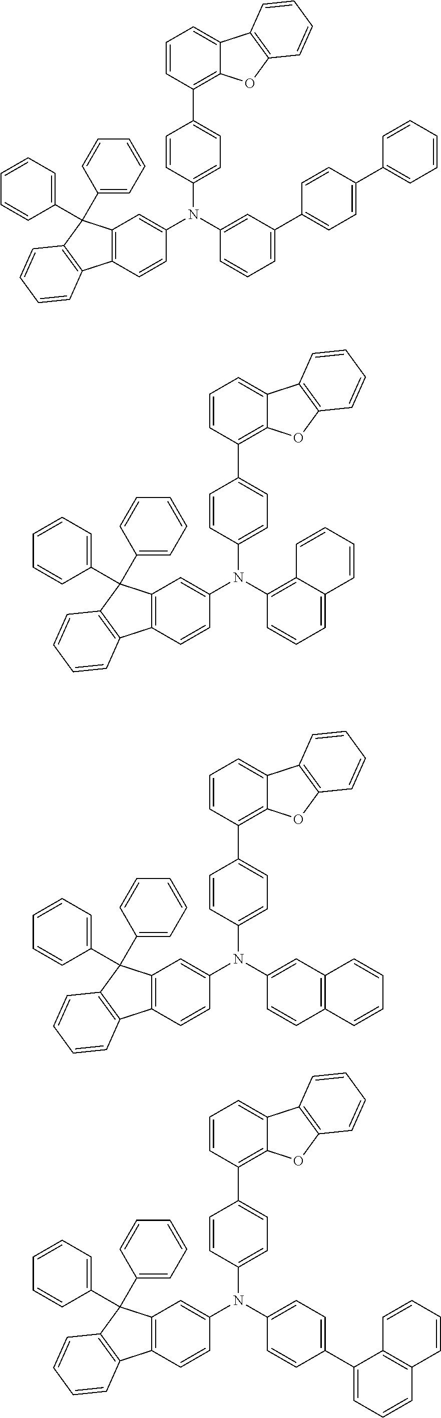 [SMILES: c1ccc(-c2ccc(-c3cccc(N(c4ccc(-c5cccc6c5oc5ccccc56)cc4)c4ccc5c(c4)C(c4ccccc4)(c4ccccc4)c4ccccc4-5)c3)cc2)cc1 ; c1ccc(C2(c3ccccc3)c3ccccc3-c3ccc(N(c4ccc(-c5cccc6c5oc5ccccc56)cc4)c4cccc5ccccc45)cc32)cc1 ; c1ccc(C2(c3ccccc3)c3ccccc3-c3ccc(N(c4ccc(-c5cccc6c5oc5ccccc56)cc4)c4ccc5ccccc5c4)cc32)cc1 ; c1ccc(C2(c3ccccc3)c3ccccc3-c3ccc(N(c4ccc(-c5cccc6ccccc56)cc4)c4ccc(-c5cccc6c5oc5ccccc56)cc4)cc32)cc1]

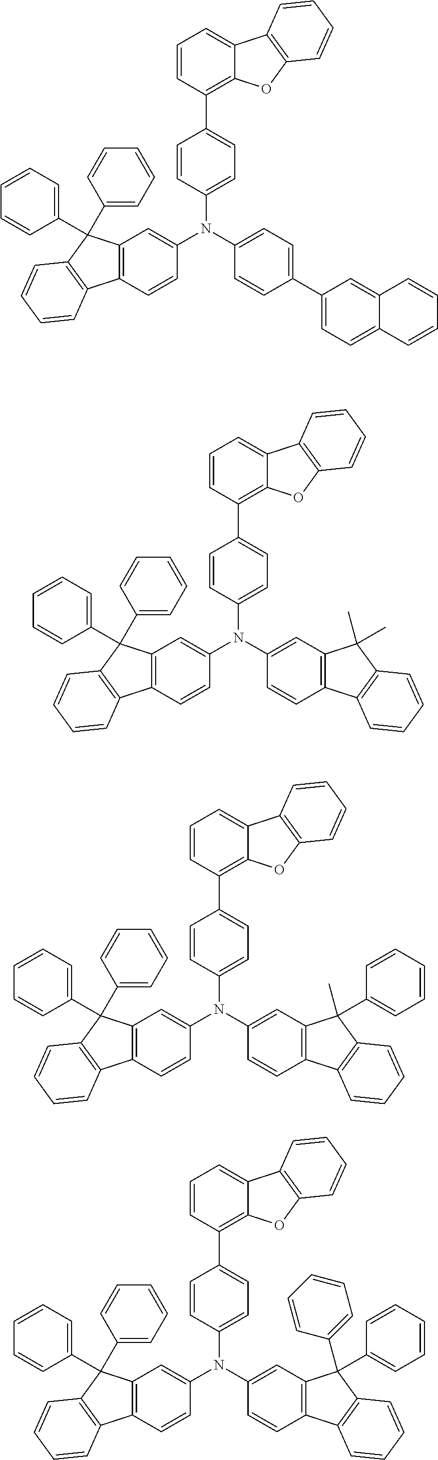

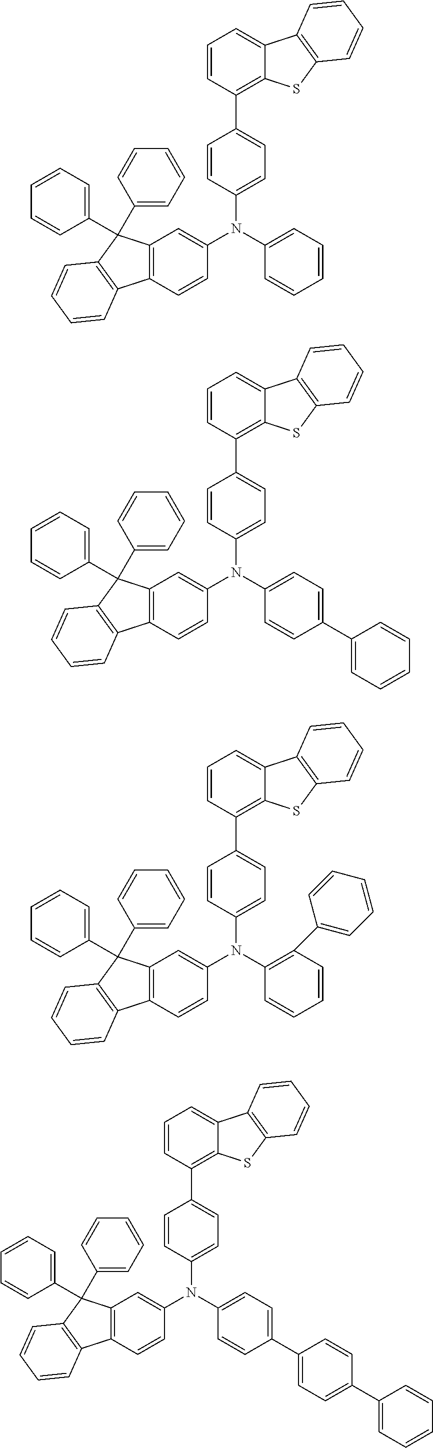 [SMILES: c1ccc(N(c2ccc(-c3cccc4c3sc3ccccc34)cc2)c2ccc3c(c2)C(c2ccccc2)(c2ccccc2)c2ccccc2-3)cc1 ; c1ccc(-c2ccc(N(c3ccc(-c4cccc5c4sc4ccccc45)cc3)c3ccc4c(c3)C(c3ccccc3)(c3ccccc3)c3ccccc3-4)cc2)cc1 ; c1ccc(-c2ccccc2N(c2ccc(-c3cccc4c3sc3ccccc34)cc2)c2ccc3c(c2)C(c2ccccc2)(c2ccccc2)c2ccccc2-3)cc1 ; c1ccc(-c2ccc(-c3ccc(N(c4ccc(-c5cccc6c5sc5ccccc56)cc4)c4ccc5c(c4)C(c4ccccc4)(c4ccccc4)c4ccccc4-5)cc3)cc2)cc1]

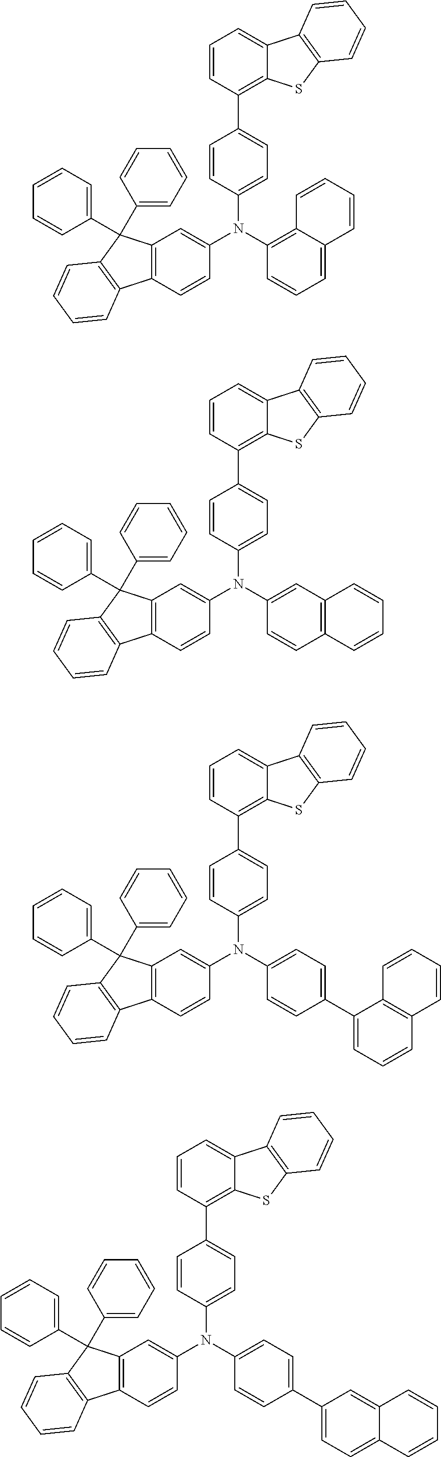 [SMILES: c1ccc(C2(c3ccccc3)c3ccccc3-c3ccc(N(c4ccc(-c5cccc6c5sc5ccccc56)cc4)c4cccc5ccccc45)cc32)cc1 ; c1ccc(C2(c3ccccc3)c3ccccc3-c3ccc(N(c4ccc(-c5cccc6c5sc5ccccc56)cc4)c4ccc5ccccc5c4)cc32)cc1 ; c1ccc(C2(c3ccccc3)c3ccccc3-c3ccc(N(c4ccc(-c5cccc6ccccc56)cc4)c4ccc(-c5cccc6c5sc5ccccc56)cc4)cc32)cc1 ; c1ccc(C2(c3ccccc3)c3ccccc3-c3ccc(N(c4ccc(-c5ccc6ccccc6c5)cc4)c4ccc(-c5cccc6c5sc5ccccc56)cc4)cc32)cc1]

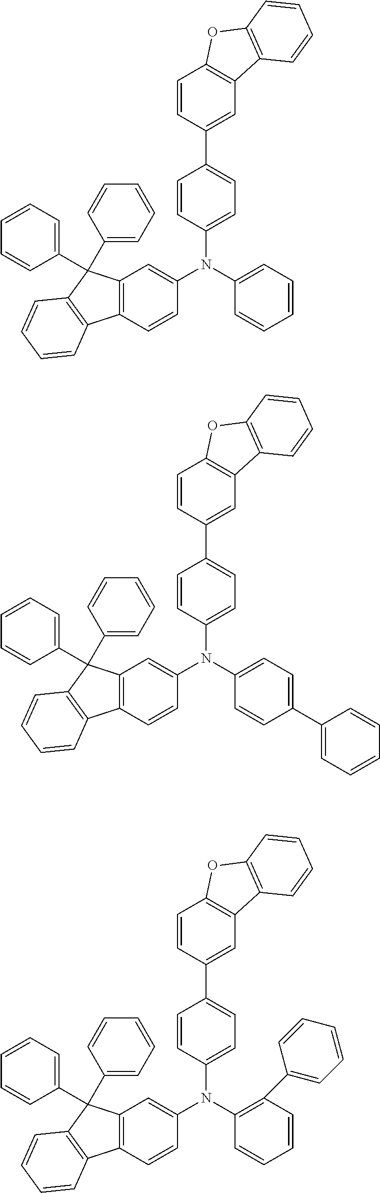 [SMILES: c1ccc(N(c2ccc(-c3ccc4oc5ccccc5c4c3)cc2)c2ccc3c(c2)C(c2ccccc2)(c2ccccc2)c2ccccc2-3)cc1 ; c1ccc(-c2ccc(N(c3ccc(-c4ccc5oc6ccccc6c5c4)cc3)c3ccc4c(c3)C(c3ccccc3)(c3ccccc3)c3ccccc3-4)cc2)cc1 ; c1ccc(-c2ccccc2N(c2ccc(-c3ccc4oc5ccccc5c4c3)cc2)c2ccc3c(c2)C(c2ccccc2)(c2ccccc2)c2ccccc2-3)cc1]

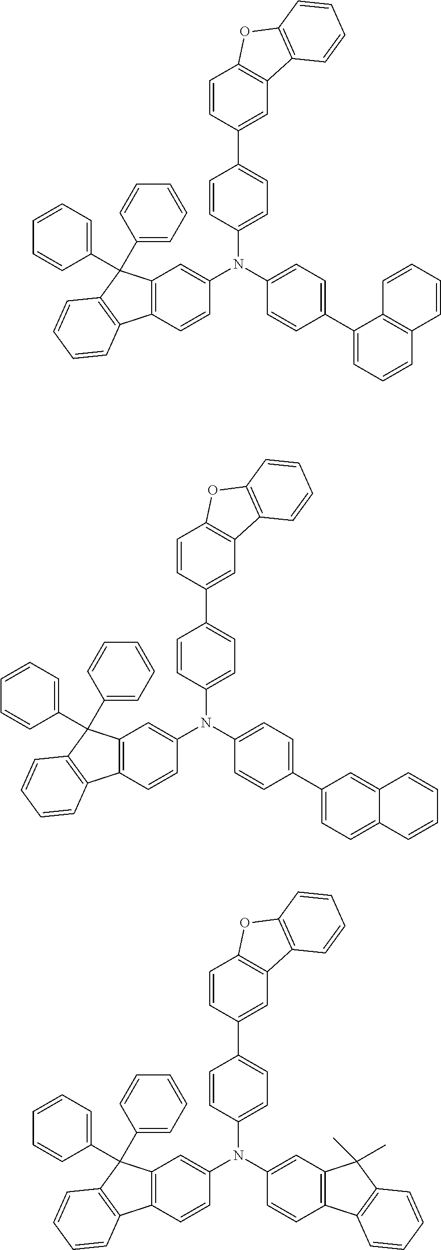 [SMILES: c1ccc(C2(c3ccccc3)c3ccccc3-c3ccc(N(c4ccc(-c5ccc6oc7ccccc7c6c5)cc4)c4ccc(-c5cccc6ccccc56)cc4)cc32)cc1 ; c1ccc(C2(c3ccccc3)c3ccccc3-c3ccc(N(c4ccc(-c5ccc6ccccc6c5)cc4)c4ccc(-c5ccc6oc7ccccc7c6c5)cc4)cc32)cc1 ; CC1(C)c2ccccc2-c2ccc(N(c3ccc(-c4ccc5oc6ccccc6c5c4)cc3)c3ccc4c(c3)C(c3ccccc3)(c3ccccc3)c3ccccc3-4)cc21]

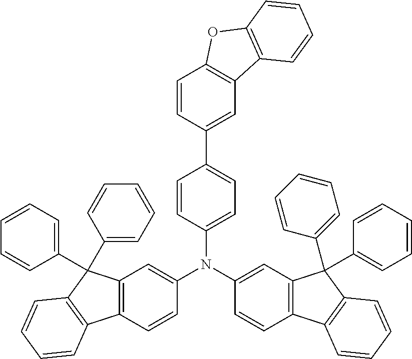 [SMILES: c1ccc(C2(c3ccccc3)c3ccccc3-c3ccc(N(c4ccc(-c5ccc6oc7ccccc7c6c5)cc4)c4ccc5c(c4)C(c4ccccc4)(c4ccccc4)c4ccccc4-5)cc32)cc1]

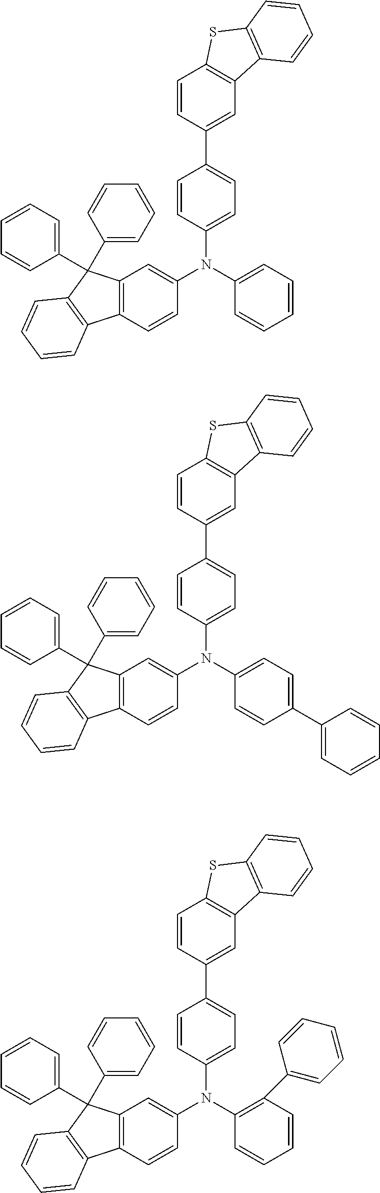 [SMILES: c1ccc(N(c2ccc(-c3ccc4sc5ccccc5c4c3)cc2)c2ccc3c(c2)C(c2ccccc2)(c2ccccc2)c2ccccc2-3)cc1 ; c1ccc(-c2ccc(N(c3ccc(-c4ccc5sc6ccccc6c5c4)cc3)c3ccc4c(c3)C(c3ccccc3)(c3ccccc3)c3ccccc3-4)cc2)cc1 ; c1ccc(-c2ccccc2N(c2ccc(-c3ccc4sc5ccccc5c4c3)cc2)c2ccc3c(c2)C(c2ccccc2)(c2ccccc2)c2ccccc2-3)cc1]

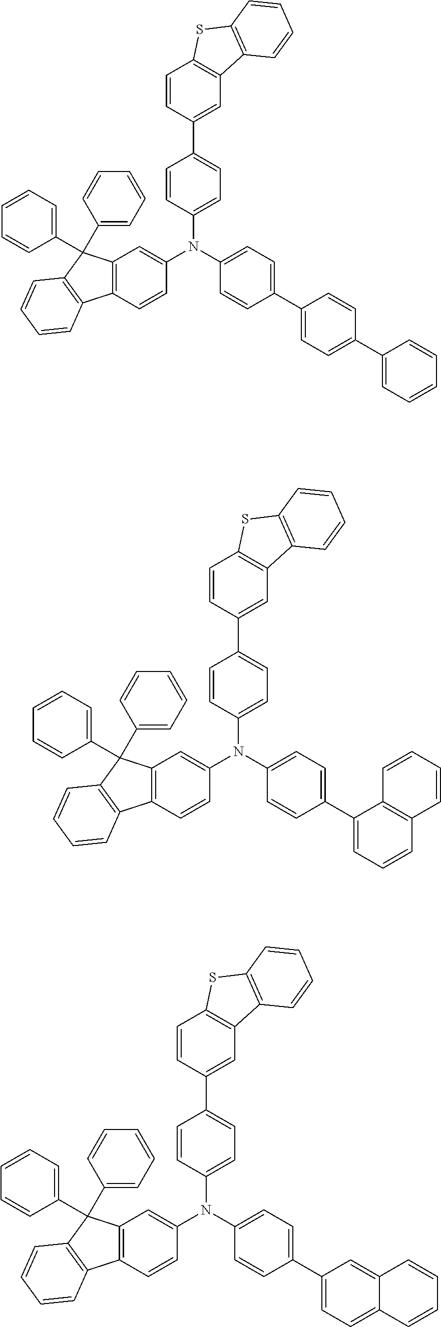 [SMILES: c1ccc(-c2ccc(-c3ccc(N(c4ccc(-c5ccc6sc7ccccc7c6c5)cc4)c4ccc5c(c4)C(c4ccccc4)(c4ccccc4)c4ccccc4-5)cc3)cc2)cc1 ; c1ccc(C2(c3ccccc3)c3ccccc3-c3ccc(N(c4ccc(-c5ccc6sc7ccccc7c6c5)cc4)c4ccc(-c5cccc6ccccc56)cc4)cc32)cc1 ; c1ccc(C2(c3ccccc3)c3ccccc3-c3ccc(N(c4ccc(-c5ccc6ccccc6c5)cc4)c4ccc(-c5ccc6sc7ccccc7c6c5)cc4)cc32)cc1]

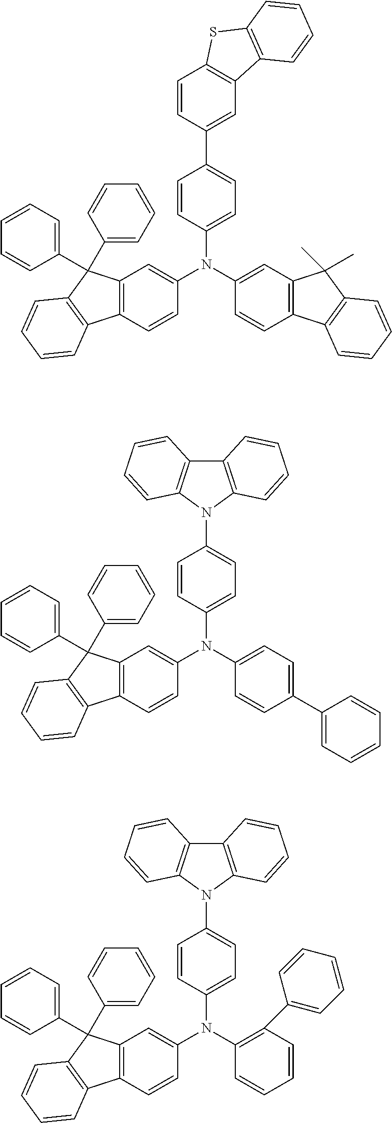 [SMILES: CC1(C)c2ccccc2-c2ccc(N(c3ccc(-c4ccc5sc6ccccc6c5c4)cc3)c3ccc4c(c3)C(c3ccccc3)(c3ccccc3)c3ccccc3-4)cc21 ; c1ccc(-c2ccc(N(c3ccc(-n4c5ccccc5c5ccccc54)cc3)c3ccc4c(c3)C(c3ccccc3)(c3ccccc3)c3ccccc3-4)cc2)cc1 ; c1ccc(-c2ccccc2N(c2ccc(-n3c4ccccc4c4ccccc43)cc2)c2ccc3c(c2)C(c2ccccc2)(c2ccccc2)c2ccccc2-3)cc1]

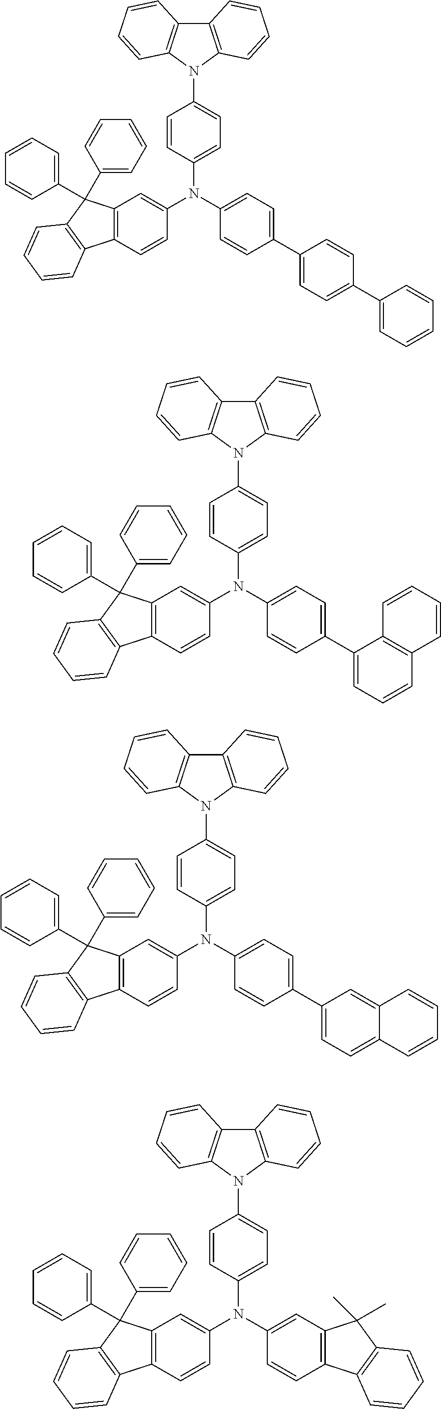 [SMILES: c1ccc(-c2ccc(-c3ccc(N(c4ccc(-n5c6ccccc6c6ccccc65)cc4)c4ccc5c(c4)C(c4ccccc4)(c4ccccc4)c4ccccc4-5)cc3)cc2)cc1 ; c1ccc(C2(c3ccccc3)c3ccccc3-c3ccc(N(c4ccc(-c5cccc6ccccc56)cc4)c4ccc(-n5c6ccccc6c6ccccc65)cc4)cc32)cc1 ; c1ccc(C2(c3ccccc3)c3ccccc3-c3ccc(N(c4ccc(-c5ccc6ccccc6c5)cc4)c4ccc(-n5c6ccccc6c6ccccc65)cc4)cc32)cc1 ; CC1(C)c2ccccc2-c2ccc(N(c3ccc(-n4c5ccccc5c5ccccc54)cc3)c3ccc4c(c3)C(c3ccccc3)(c3ccccc3)c3ccccc3-4)cc21]

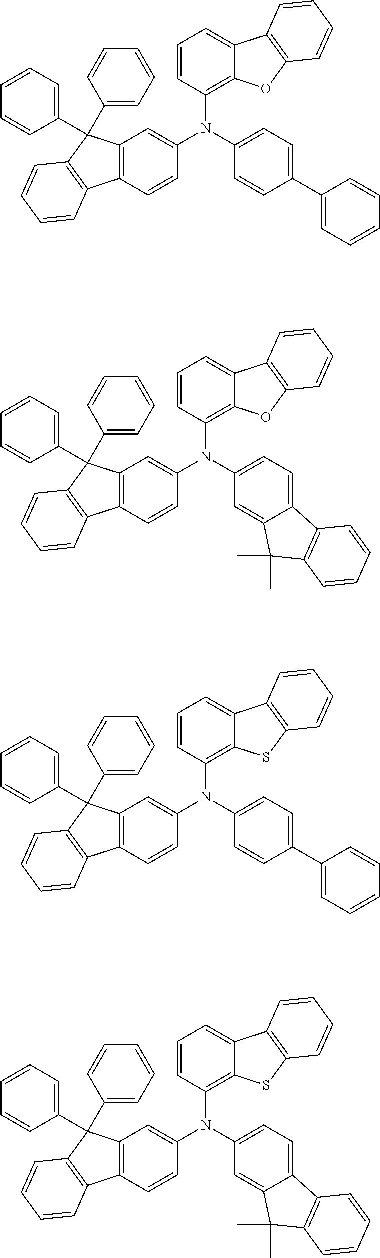 [SMILES: c1ccc(-c2ccc(N(c3ccc4c(c3)C(c3ccccc3)(c3ccccc3)c3ccccc3-4)c3cccc4c3oc3ccccc34)cc2)cc1 ; CC1(C)c2ccccc2-c2ccc(N(c3ccc4c(c3)C(c3ccccc3)(c3ccccc3)c3ccccc3-4)c3cccc4c3oc3ccccc34)cc21 ; c1ccc(-c2ccc(N(c3ccc4c(c3)C(c3ccccc3)(c3ccccc3)c3ccccc3-4)c3cccc4c3sc3ccccc34)cc2)cc1 ; CC1(C)c2ccccc2-c2ccc(N(c3ccc4c(c3)C(c3ccccc3)(c3ccccc3)c3ccccc3-4)c3cccc4c3sc3ccccc34)cc21]

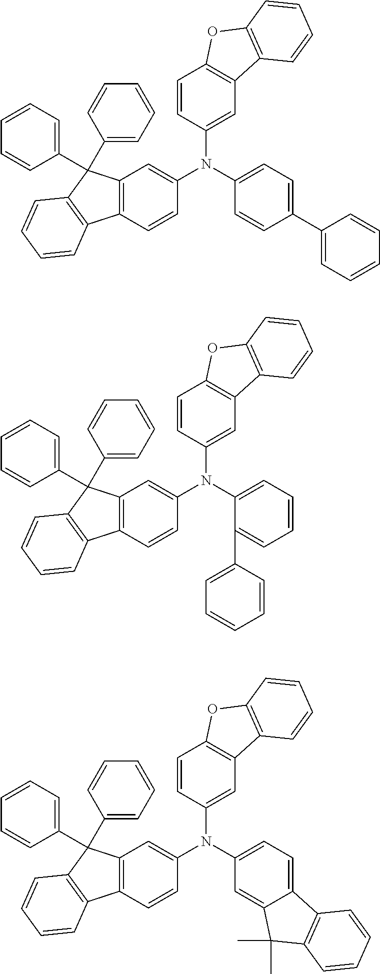 [SMILES: c1ccc(-c2ccc(N(c3ccc4c(c3)C(c3ccccc3)(c3ccccc3)c3ccccc3-4)c3ccc4oc5ccccc5c4c3)cc2)cc1 ; c1ccc(-c2ccccc2N(c2ccc3c(c2)C(c2ccccc2)(c2ccccc2)c2ccccc2-3)c2ccc3oc4ccccc4c3c2)cc1 ; CC1(C)c2ccccc2-c2ccc(N(c3ccc4c(c3)C(c3ccccc3)(c3ccccc3)c3ccccc3-4)c3ccc4oc5ccccc5c4c3)cc21]

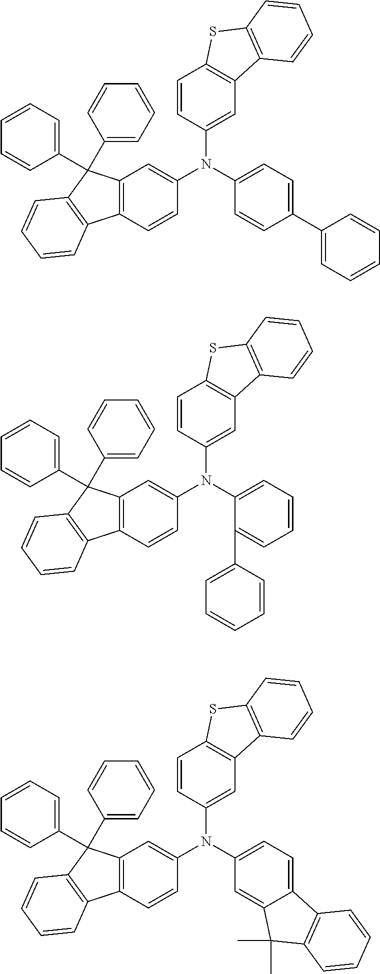 [SMILES: c1ccc(-c2ccc(N(c3ccc4c(c3)C(c3ccccc3)(c3ccccc3)c3ccccc3-4)c3ccc4sc5ccccc5c4c3)cc2)cc1 ; c1ccc(-c2ccccc2N(c2ccc3c(c2)C(c2ccccc2)(c2ccccc2)c2ccccc2-3)c2ccc3sc4ccccc4c3c2)cc1 ; CC1(C)c2ccccc2-c2ccc(N(c3ccc4c(c3)C(c3ccccc3)(c3ccccc3)c3ccccc3-4)c3ccc4sc5ccccc5c4c3)cc21]

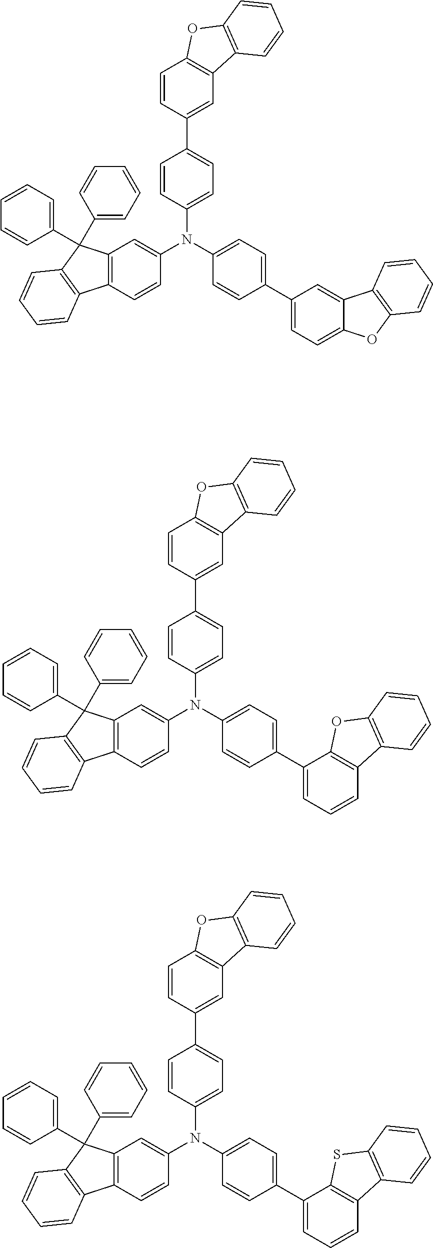 [SMILES: c1ccc(C2(c3ccccc3)c3ccccc3-c3ccc(N(c4ccc(-c5ccc6oc7ccccc7c6c5)cc4)c4ccc(-c5ccc6oc7ccccc7c6c5)cc4)cc32)cc1 ; c1ccc(C2(c3ccccc3)c3ccccc3-c3ccc(N(c4ccc(-c5ccc6oc7ccccc7c6c5)cc4)c4ccc(-c5cccc6c5oc5ccccc56)cc4)cc32)cc1 ; c1ccc(C2(c3ccccc3)c3ccccc3-c3ccc(N(c4ccc(-c5ccc6oc7ccccc7c6c5)cc4)c4ccc(-c5cccc6c5sc5ccccc56)cc4)cc32)cc1]

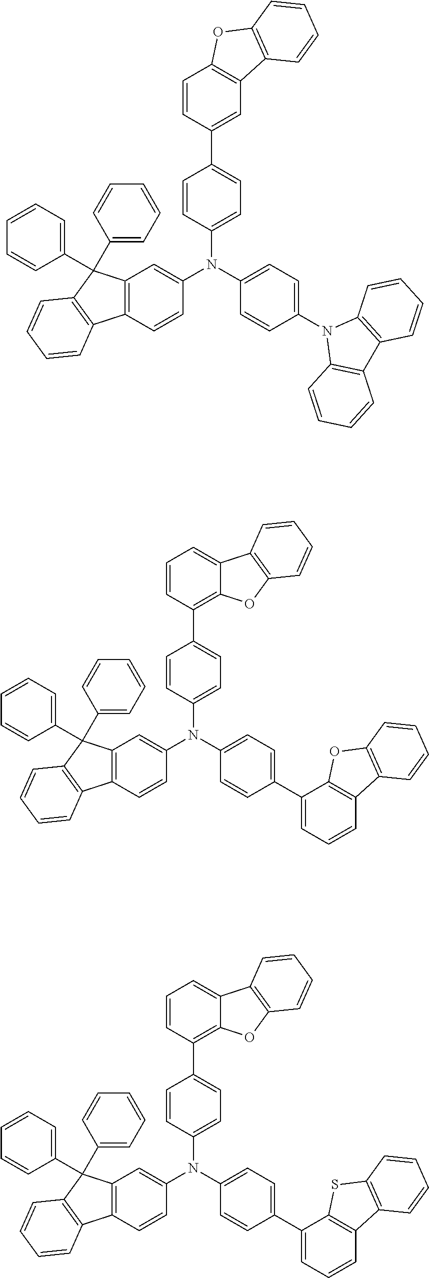 [SMILES: c1ccc(C2(c3ccccc3)c3ccccc3-c3ccc(N(c4ccc(-c5ccc6oc7ccccc7c6c5)cc4)c4ccc(-n5c6ccccc6c6ccccc65)cc4)cc32)cc1 ; c1ccc(C2(c3ccccc3)c3ccccc3-c3ccc(N(c4ccc(-c5cccc6c5oc5ccccc56)cc4)c4ccc(-c5cccc6c5oc5ccccc56)cc4)cc32)cc1 ; c1ccc(C2(c3ccccc3)c3ccccc3-c3ccc(N(c4ccc(-c5cccc6c5oc5ccccc56)cc4)c4ccc(-c5cccc6c5sc5ccccc56)cc4)cc32)cc1]

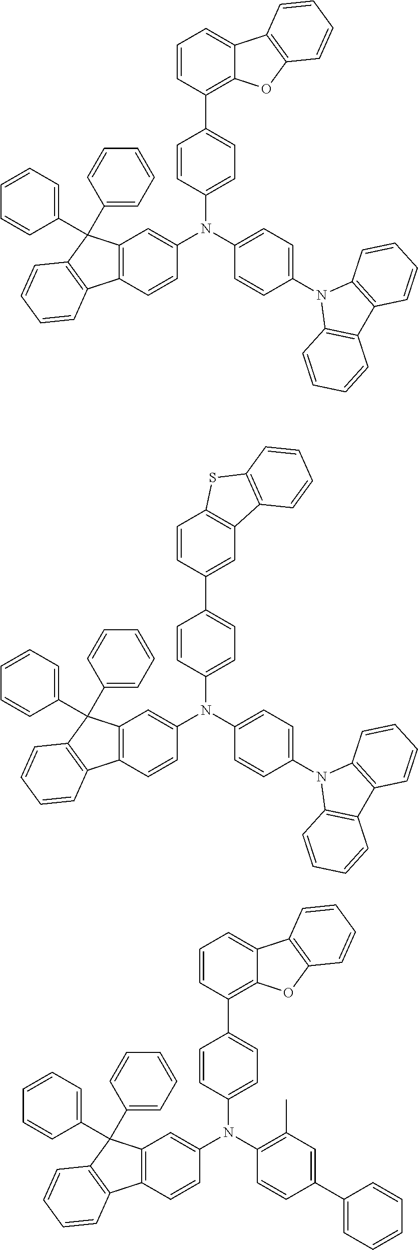

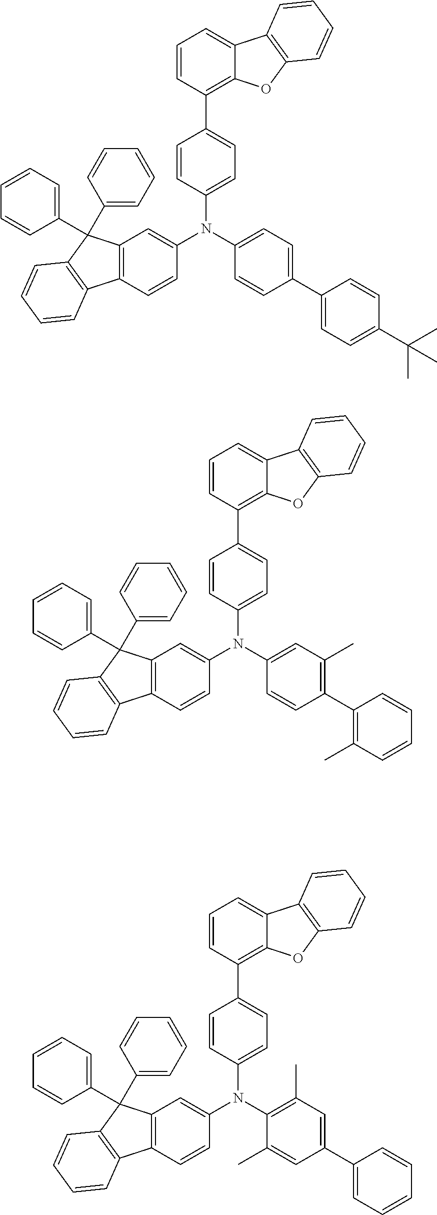 [SMILES: CC(C)(C)c1ccc(-c2ccc(N(c3ccc(-c4cccc5c4oc4ccccc45)cc3)c3ccc4c(c3)C(c3ccccc3)(c3ccccc3)c3ccccc3-4)cc2)cc1 ; Cc1ccccc1-c1ccc(N(c2ccc(-c3cccc4c3oc3ccccc34)cc2)c2ccc3c(c2)C(c2ccccc2)(c2ccccc2)c2ccccc2-3)cc1C ; Cc1cc(-c2ccccc2)cc(C)c1N(c1ccc(-c2cccc3c2oc2ccccc23)cc1)c1ccc2c(c1)C(c1ccccc1)(c1ccccc1)c1ccccc1-2]

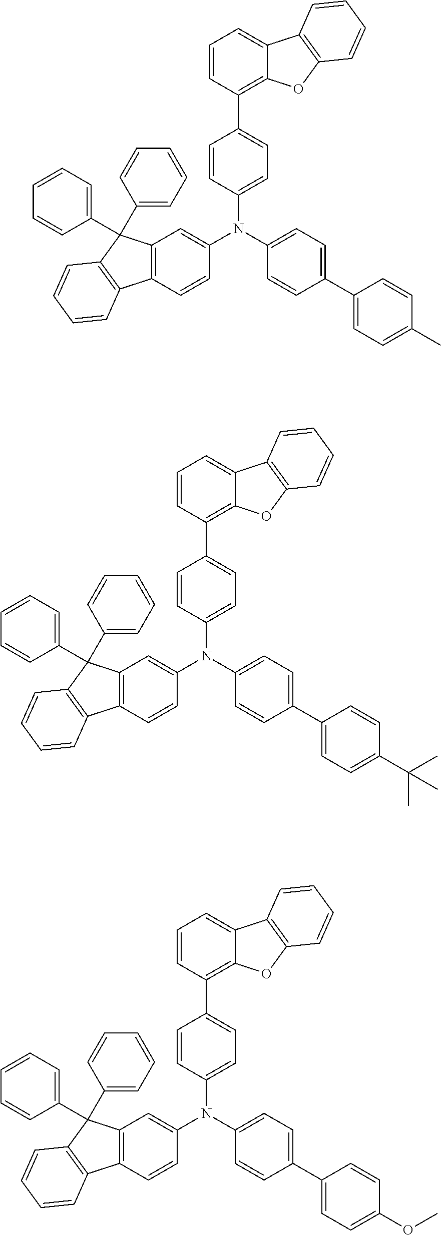 [SMILES: Cc1ccc(-c2ccc(N(c3ccc(-c4cccc5c4oc4ccccc45)cc3)c3ccc4c(c3)C(c3ccccc3)(c3ccccc3)c3ccccc3-4)cc2)cc1 ; CC(C)(C)c1ccc(-c2ccc(N(c3ccc(-c4cccc5c4oc4ccccc45)cc3)c3ccc4c(c3)C(c3ccccc3)(c3ccccc3)c3ccccc3-4)cc2)cc1 ; COc1ccc(-c2ccc(N(c3ccc(-c4cccc5c4oc4ccccc45)cc3)c3ccc4c(c3)C(c3ccccc3)(c3ccccc3)c3ccccc3-4)cc2)cc1]

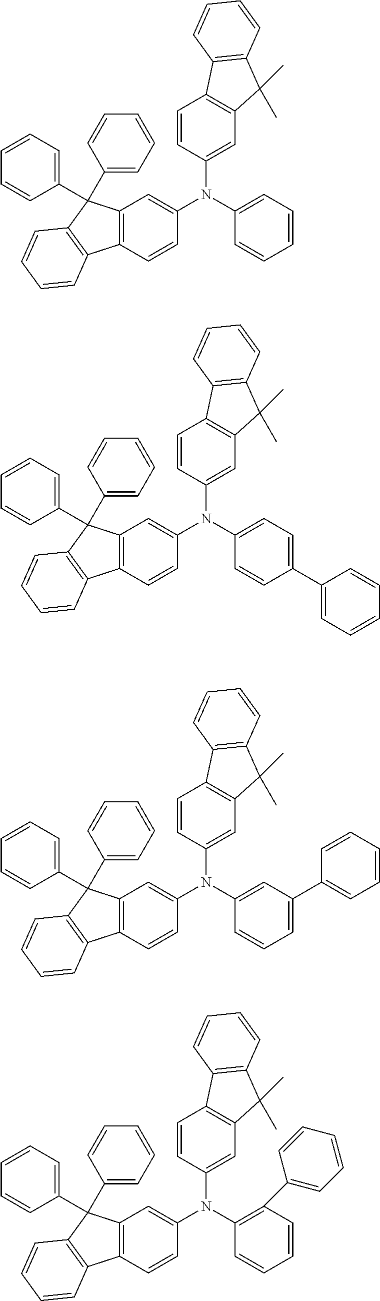 [SMILES: CC1(C)c2ccccc2-c2ccc(N(c3ccccc3)c3ccc4c(c3)C(c3ccccc3)(c3ccccc3)c3ccccc3-4)cc21 ; CC1(C)c2ccccc2-c2ccc(N(c3ccc(-c4ccccc4)cc3)c3ccc4c(c3)C(c3ccccc3)(c3ccccc3)c3ccccc3-4)cc21 ; CC1(C)c2ccccc2-c2ccc(N(c3cccc(-c4ccccc4)c3)c3ccc4c(c3)C(c3ccccc3)(c3ccccc3)c3ccccc3-4)cc21 ; CC1(C)c2ccccc2-c2ccc(N(c3ccc4c(c3)C(c3ccccc3)(c3ccccc3)c3ccccc3-4)c3ccccc3-c3ccccc3)cc21]

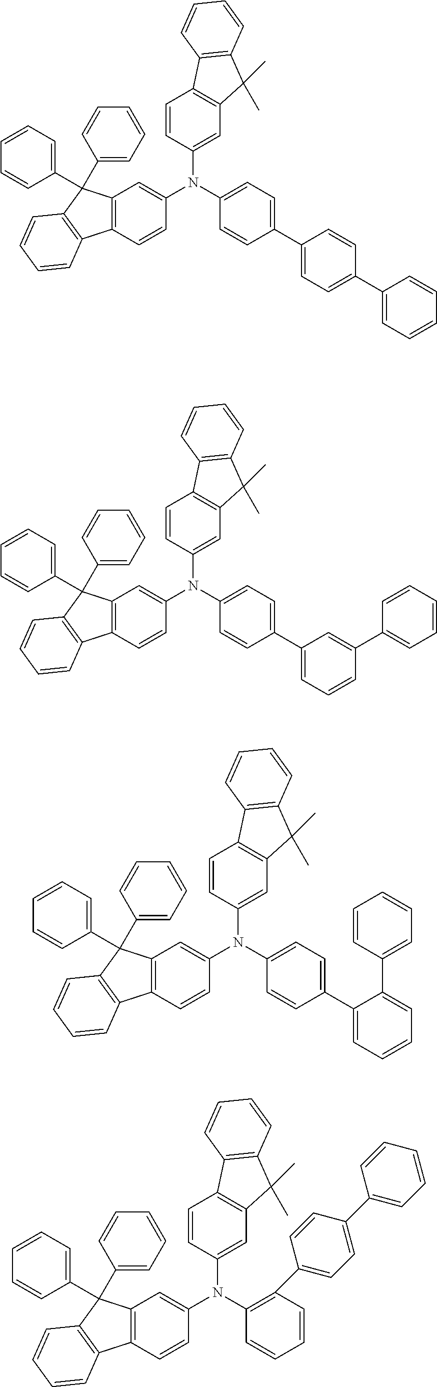 [SMILES: CC1(C)c2ccccc2-c2ccc(N(c3ccc(-c4ccc(-c5ccccc5)cc4)cc3)c3ccc4c(c3)C(c3ccccc3)(c3ccccc3)c3ccccc3-4)cc21 ; CC1(C)c2ccccc2-c2ccc(N(c3ccc(-c4cccc(-c5ccccc5)c4)cc3)c3ccc4c(c3)C(c3ccccc3)(c3ccccc3)c3ccccc3-4)cc21 ; CC1(C)c2ccccc2-c2ccc(N(c3ccc(-c4ccccc4-c4ccccc4)cc3)c3ccc4c(c3)C(c3ccccc3)(c3ccccc3)c3ccccc3-4)cc21 ; CC1(C)c2ccccc2-c2ccc(N(c3ccc4c(c3)C(c3ccccc3)(c3ccccc3)c3ccccc3-4)c3ccccc3-c3ccc(-c4ccccc4)cc3)cc21]

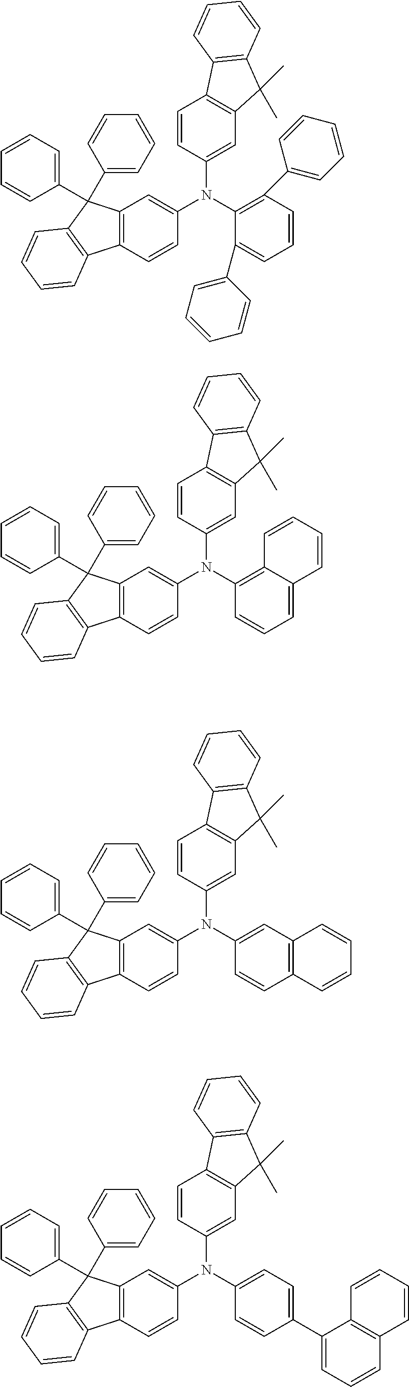

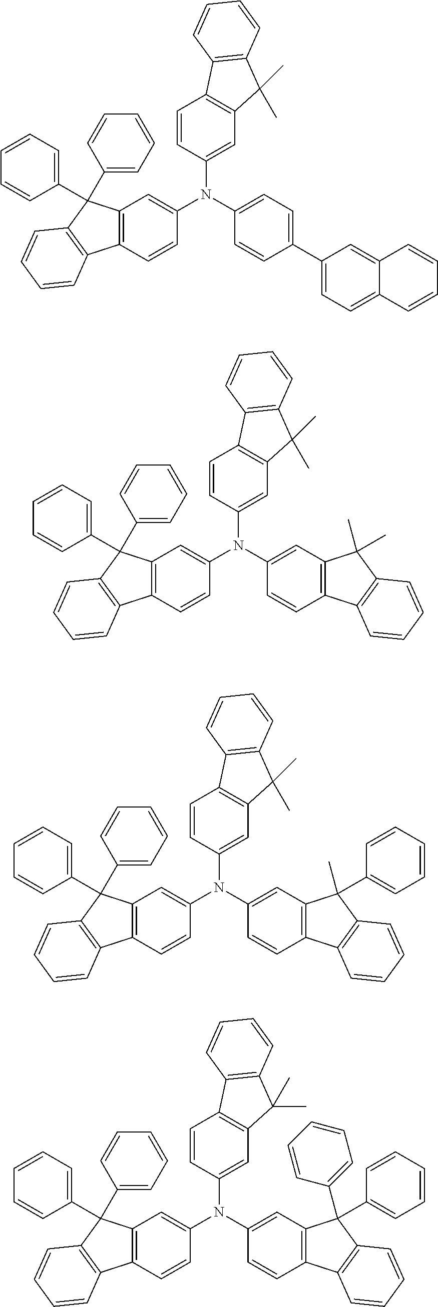 [SMILES: CC1(C)c2ccccc2-c2ccc(N(c3ccc(-c4ccc5ccccc5c4)cc3)c3ccc4c(c3)C(c3ccccc3)(c3ccccc3)c3ccccc3-4)cc21 ; CC1(C)c2ccccc2-c2ccc(N(c3ccc4c(c3)C(C)(C)c3ccccc3-4)c3ccc4c(c3)C(c3ccccc3)(c3ccccc3)c3ccccc3-4)cc21 ; CC1(C)c2ccccc2-c2ccc(N(c3ccc4c(c3)C(C)(c3ccccc3)c3ccccc3-4)c3ccc4c(c3)C(c3ccccc3)(c3ccccc3)c3ccccc3-4)cc21 ; CC1(C)c2ccccc2-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc21]

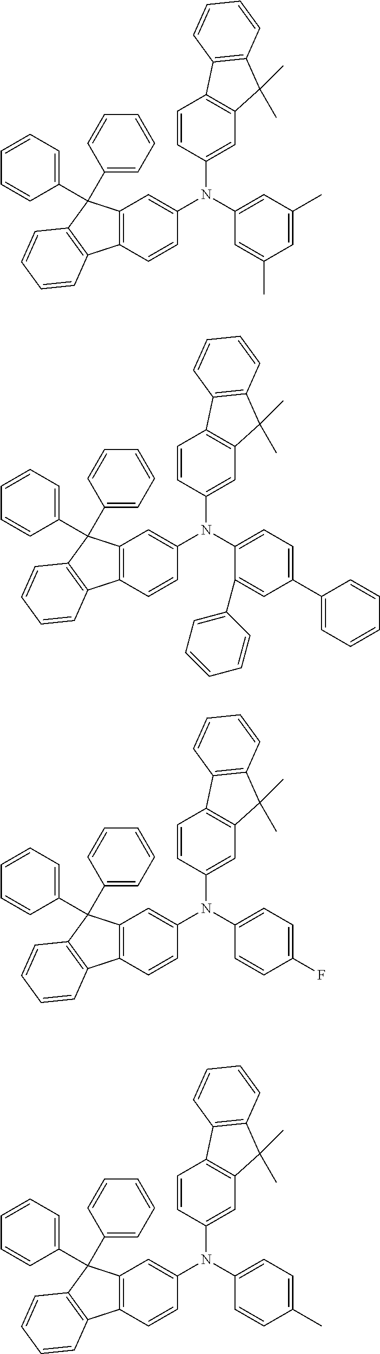

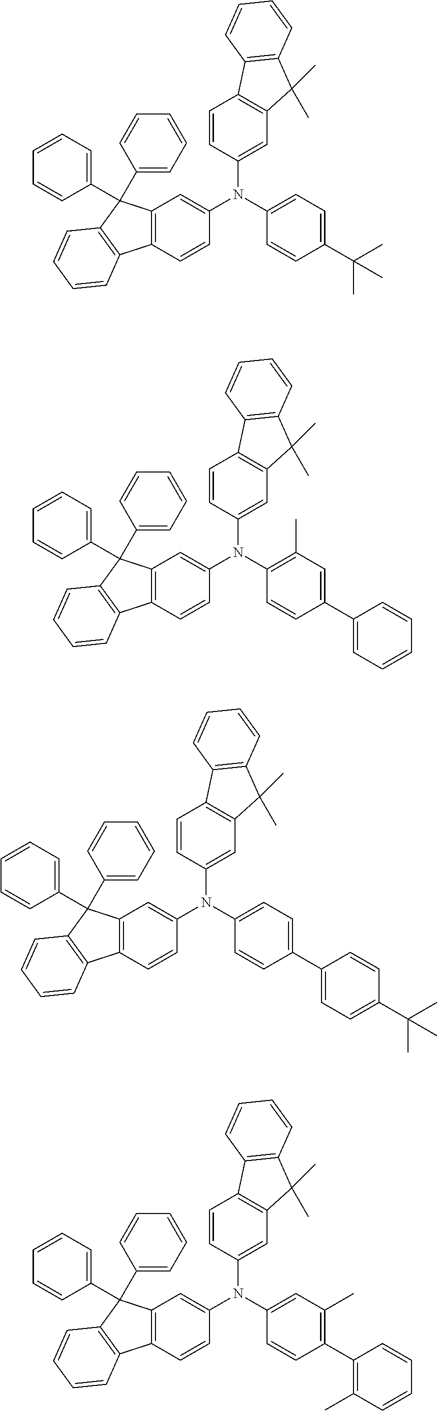 [SMILES: CC(C)(C)c1ccc(N(c2ccc3c(c2)C(C)(C)c2ccccc2-3)c2ccc3c(c2)C(c2ccccc2)(c2ccccc2)c2ccccc2-3)cc1 ; Cc1cc(-c2ccccc2)ccc1N(c1ccc2c(c1)C(C)(C)c1ccccc1-2)c1ccc2c(c1)C(c1ccccc1)(c1ccccc1)c1ccccc1-2 ; CC(C)(C)c1ccc(-c2ccc(N(c3ccc4c(c3)C(C)(C)c3ccccc3-4)c3ccc4c(c3)C(c3ccccc3)(c3ccccc3)c3ccccc3-4)cc2)cc1 ; Cc1ccccc1-c1ccc(N(c2ccc3c(c2)C(C)(C)c2ccccc2-3)c2ccc3c(c2)C(c2ccccc2)(c2ccccc2)c2ccccc2-3)cc1C]

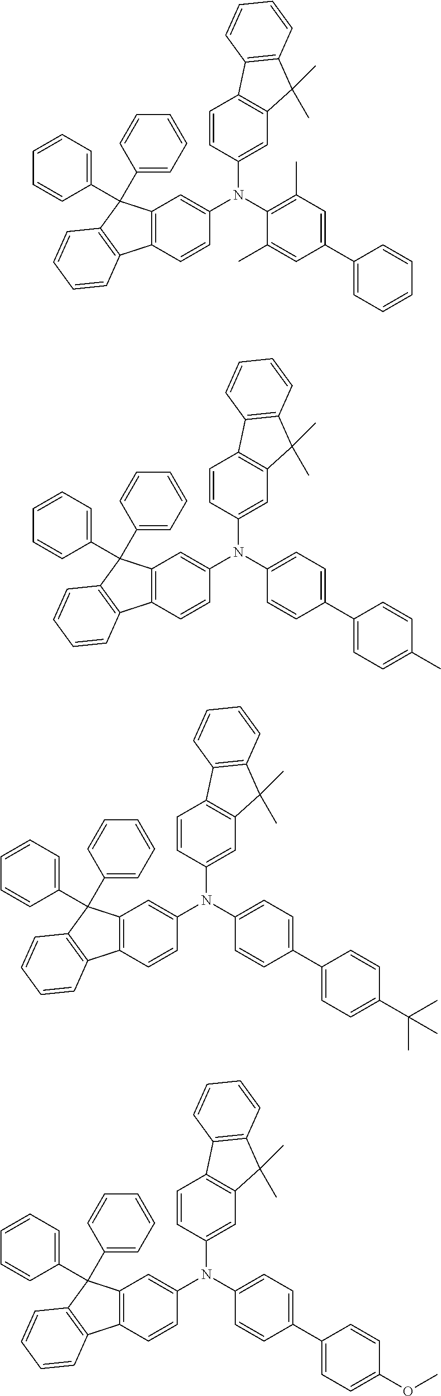 [SMILES: Cc1cc(-c2ccccc2)cc(C)c1N(c1ccc2c(c1)C(C)(C)c1ccccc1-2)c1ccc2c(c1)C(c1ccccc1)(c1ccccc1)c1ccccc1-2 ; Cc1ccc(-c2ccc(N(c3ccc4c(c3)C(C)(C)c3ccccc3-4)c3ccc4c(c3)C(c3ccccc3)(c3ccccc3)c3ccccc3-4)cc2)cc1 ; CC(C)(C)c1ccc(-c2ccc(N(c3ccc4c(c3)C(C)(C)c3ccccc3-4)c3ccc4c(c3)C(c3ccccc3)(c3ccccc3)c3ccccc3-4)cc2)cc1 ; COc1ccc(-c2ccc(N(c3ccc4c(c3)C(C)(C)c3ccccc3-4)c3ccc4c(c3)C(c3ccccc3)(c3ccccc3)c3ccccc3-4)cc2)cc1]

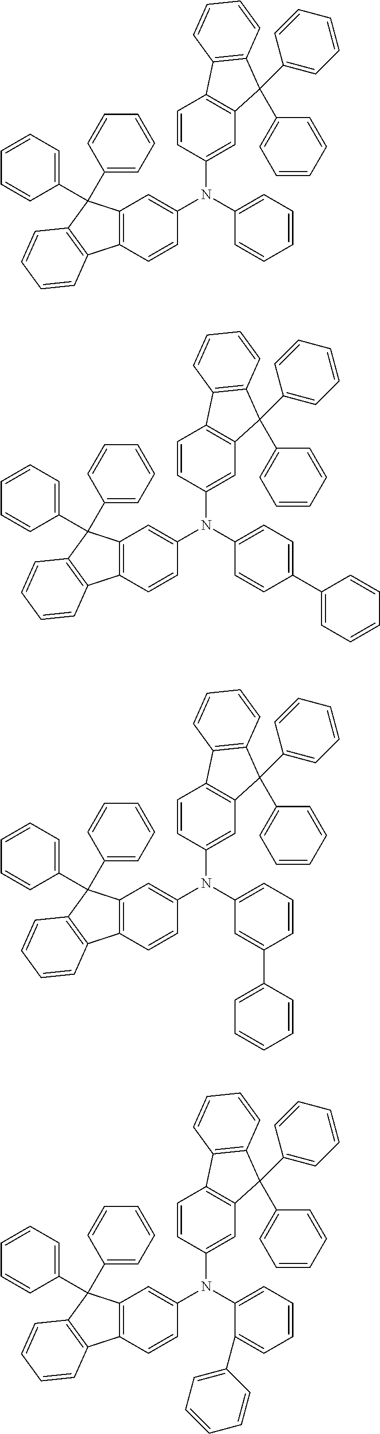 [SMILES: c1ccc(N(c2ccc3c(c2)C(c2ccccc2)(c2ccccc2)c2ccccc2-3)c2ccc3c(c2)C(c2ccccc2)(c2ccccc2)c2ccccc2-3)cc1 ; c1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc2)cc1 ; c1ccc(-c2cccc(N(c3ccc4c(c3)C(c3ccccc3)(c3ccccc3)c3ccccc3-4)c3ccc4c(c3)C(c3ccccc3)(c3ccccc3)c3ccccc3-4)c2)cc1 ; c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1]

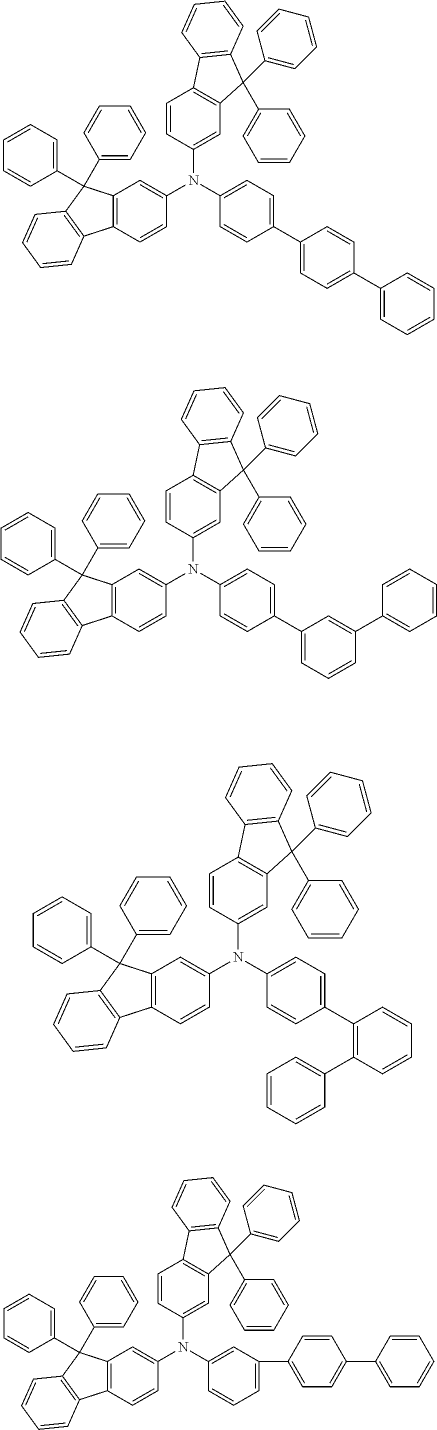 [SMILES: c1ccc(-c2ccc(-c3ccc(N(c4ccc5c(c4)C(c4ccccc4)(c4ccccc4)c4ccccc4-5)c4ccc5c(c4)C(c4ccccc4)(c4ccccc4)c4ccccc4-5)cc3)cc2)cc1 ; c1ccc(-c2cccc(-c3ccc(N(c4ccc5c(c4)C(c4ccccc4)(c4ccccc4)c4ccccc4-5)c4ccc5c(c4)C(c4ccccc4)(c4ccccc4)c4ccccc4-5)cc3)c2)cc1 ; c1ccc(-c2ccccc2-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc2)cc1 ; c1ccc(-c2ccc(-c3cccc(N(c4ccc5c(c4)C(c4ccccc4)(c4ccccc4)c4ccccc4-5)c4ccc5c(c4)C(c4ccccc4)(c4ccccc4)c4ccccc4-5)c3)cc2)cc1]

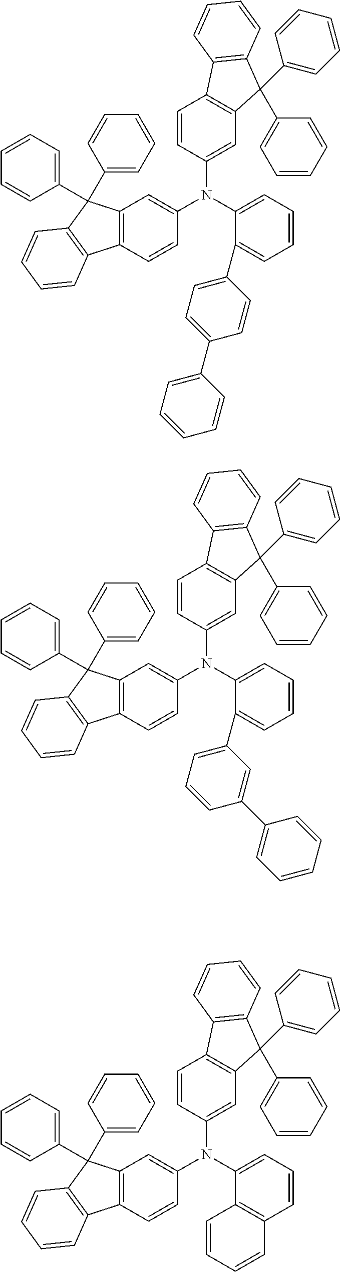

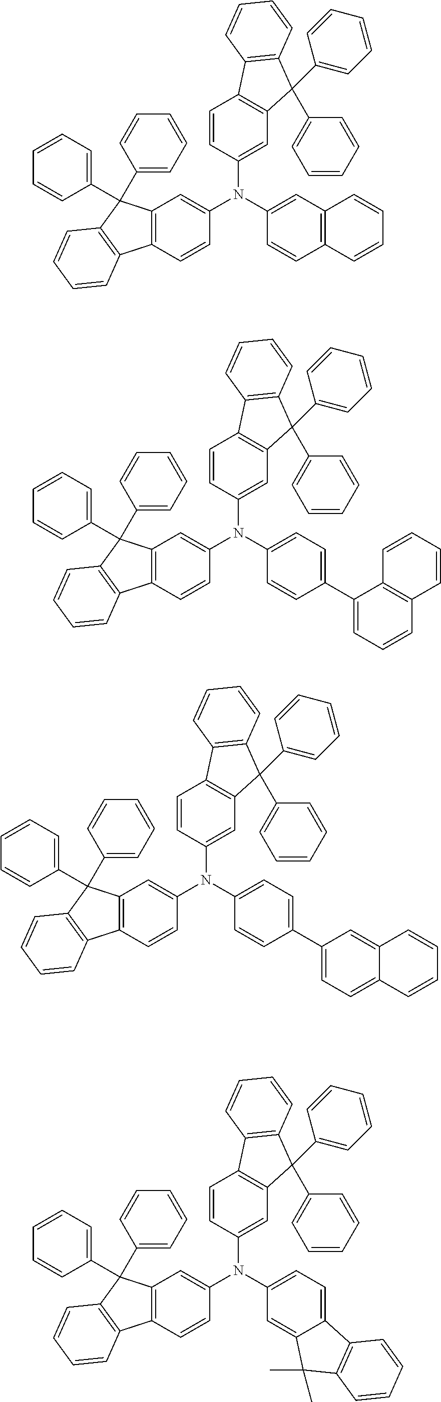 [SMILES: c1ccc(C2(c3ccccc3)c3ccccc3-c3ccc(N(c4ccc5c(c4)C(c4ccccc4)(c4ccccc4)c4ccccc4-5)c4ccc5ccccc5c4)cc32)cc1 ; c1ccc(C2(c3ccccc3)c3ccccc3-c3ccc(N(c4ccc(-c5cccc6ccccc56)cc4)c4ccc5c(c4)C(c4ccccc4)(c4ccccc4)c4ccccc4-5)cc32)cc1 ; c1ccc(C2(c3ccccc3)c3ccccc3-c3ccc(N(c4ccc(-c5ccc6ccccc6c5)cc4)c4ccc5c(c4)C(c4ccccc4)(c4ccccc4)c4ccccc4-5)cc32)cc1 ; CC1(C)c2ccccc2-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc21]

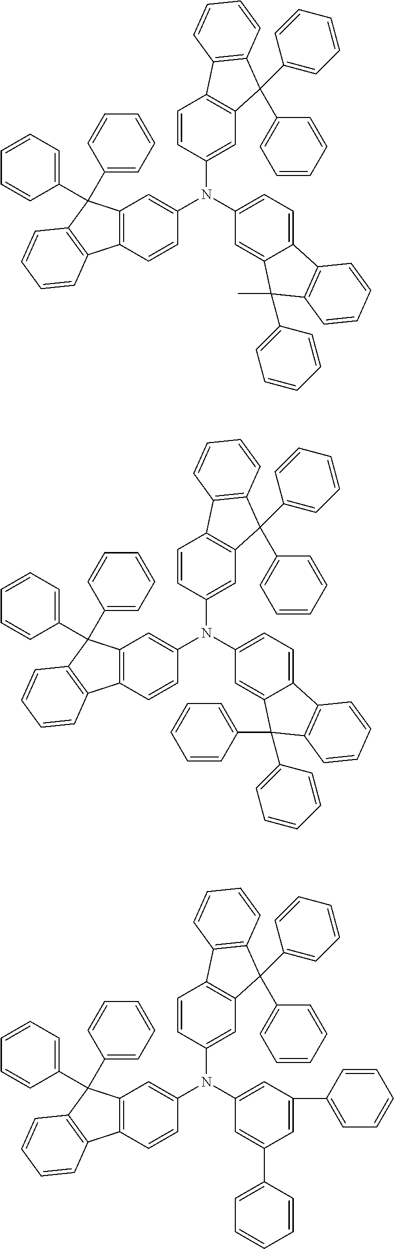 [SMILES: CC1(c2ccccc2)c2ccccc2-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc21 ; c1ccc(C2(c3ccccc3)c3ccccc3-c3ccc(N(c4ccc5c(c4)C(c4ccccc4)(c4ccccc4)c4ccccc4-5)c4ccc5c(c4)C(c4ccccc4)(c4ccccc4)c4ccccc4-5)cc32)cc1 ; c1ccc(-c2cc(-c3ccccc3)cc(N(c3ccc4c(c3)C(c3ccccc3)(c3ccccc3)c3ccccc3-4)c3ccc4c(c3)C(c3ccccc3)(c3ccccc3)c3ccccc3-4)c2)cc1]

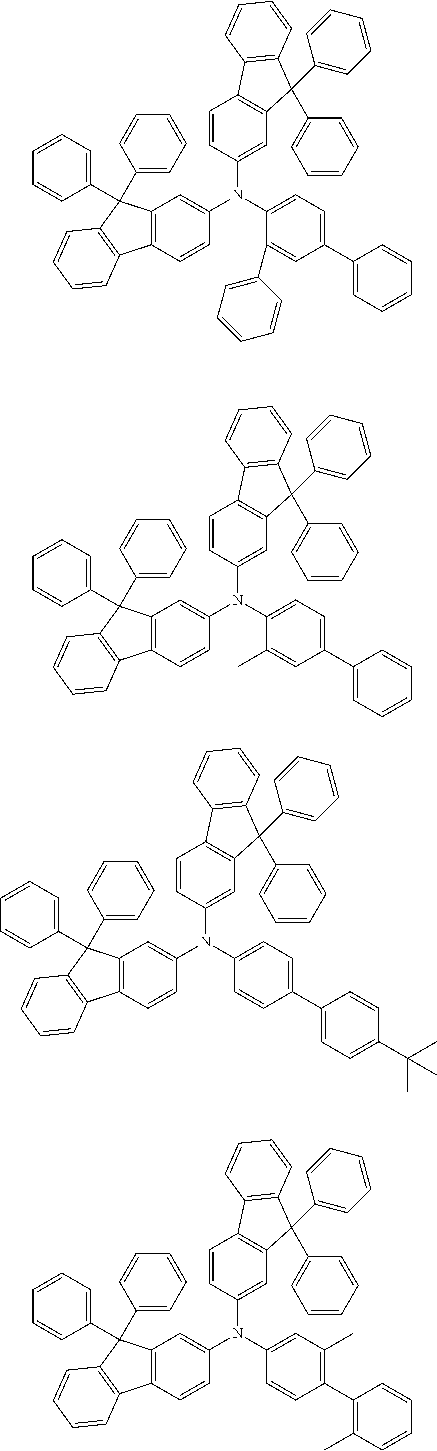 [SMILES: c1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)c(-c3ccccc3)c2)cc1 ; Cc1cc(-c2ccccc2)ccc1N(c1ccc2c(c1)C(c1ccccc1)(c1ccccc1)c1ccccc1-2)c1ccc2c(c1)C(c1ccccc1)(c1ccccc1)c1ccccc1-2 ; CC(C)(C)c1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc2)cc1 ; Cc1ccccc1-c1ccc(N(c2ccc3c(c2)C(c2ccccc2)(c2ccccc2)c2ccccc2-3)c2ccc3c(c2)C(c2ccccc2)(c2ccccc2)c2ccccc2-3)cc1C]

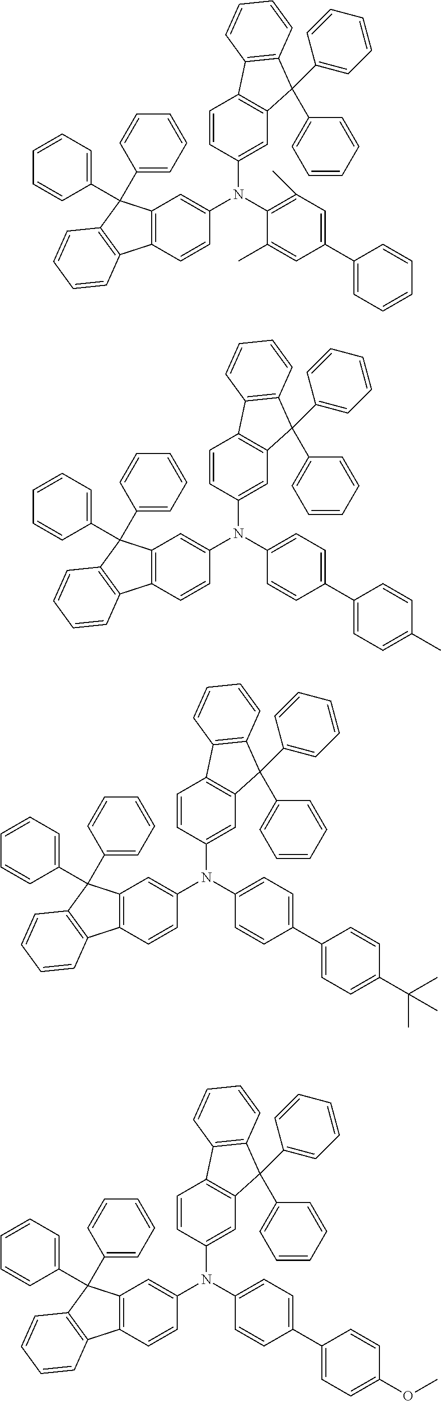 [SMILES: Cc1cc(-c2ccccc2)cc(C)c1N(c1ccc2c(c1)C(c1ccccc1)(c1ccccc1)c1ccccc1-2)c1ccc2c(c1)C(c1ccccc1)(c1ccccc1)c1ccccc1-2 ; Cc1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc2)cc1 ; CC(C)(C)c1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc2)cc1 ; COc1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc2)cc1]

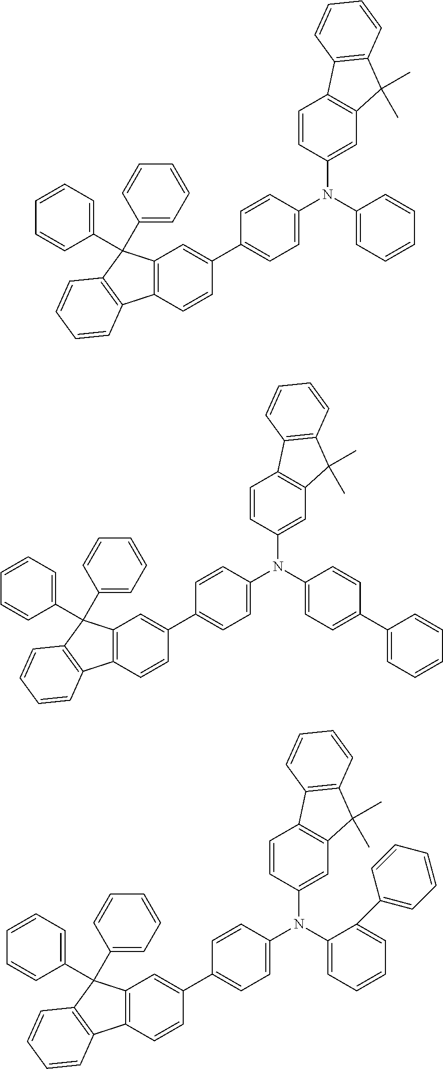 [SMILES: CC1(C)c2ccccc2-c2ccc(N(c3ccccc3)c3ccc(-c4ccc5c(c4)C(c4ccccc4)(c4ccccc4)c4ccccc4-5)cc3)cc21 ; CC1(C)c2ccccc2-c2ccc(N(c3ccc(-c4ccccc4)cc3)c3ccc(-c4ccc5c(c4)C(c4ccccc4)(c4ccccc4)c4ccccc4-5)cc3)cc21 ; CC1(C)c2ccccc2-c2ccc(N(c3ccc(-c4ccc5c(c4)C(c4ccccc4)(c4ccccc4)c4ccccc4-5)cc3)c3ccccc3-c3ccccc3)cc21]

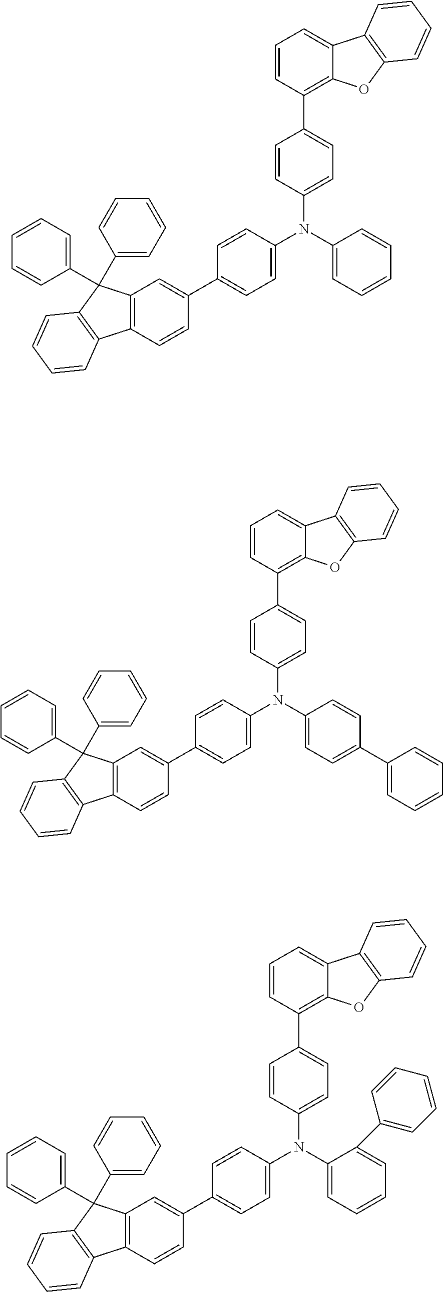 [SMILES: c1ccc(N(c2ccc(-c3ccc4c(c3)C(c3ccccc3)(c3ccccc3)c3ccccc3-4)cc2)c2ccc(-c3cccc4c3oc3ccccc34)cc2)cc1 ; c1ccc(-c2ccc(N(c3ccc(-c4ccc5c(c4)C(c4ccccc4)(c4ccccc4)c4ccccc4-5)cc3)c3ccc(-c4cccc5c4oc4ccccc45)cc3)cc2)cc1 ; c1ccc(-c2ccccc2N(c2ccc(-c3ccc4c(c3)C(c3ccccc3)(c3ccccc3)c3ccccc3-4)cc2)c2ccc(-c3cccc4c3oc3ccccc34)cc2)cc1]

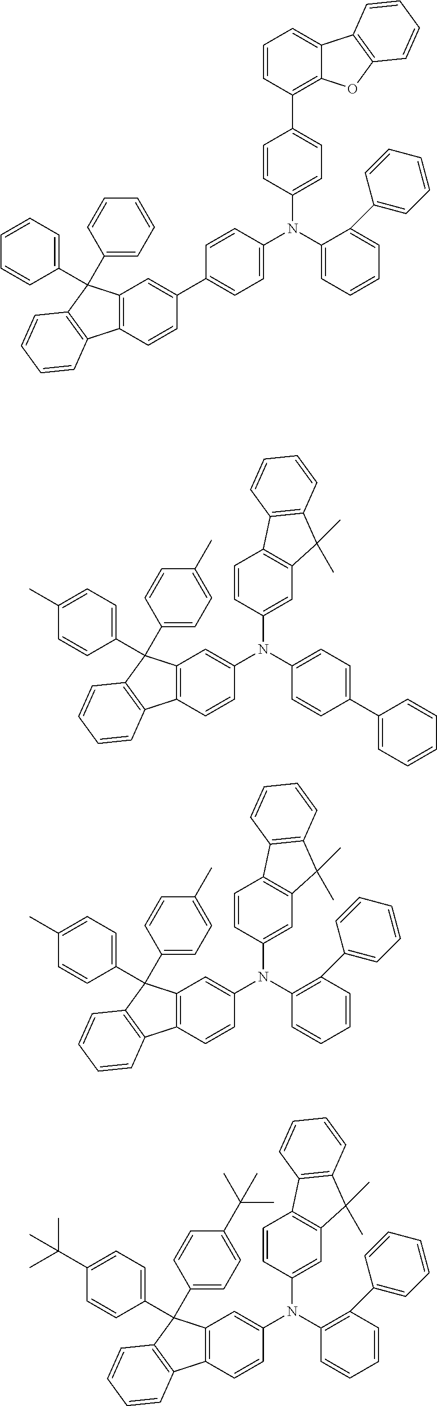 [SMILES: c1ccc(-c2ccccc2N(c2ccc(-c3ccc4c(c3)C(c3ccccc3)(c3ccccc3)c3ccccc3-4)cc2)c2ccc(-c3cccc4c3oc3ccccc34)cc2)cc1 ; Cc1ccc(C2(c3ccc(C)cc3)c3ccccc3-c3ccc(N(c4ccc(-c5ccccc5)cc4)c4ccc5c(c4)C(C)(C)c4ccccc4-5)cc32)cc1 ; Cc1ccc(C2(c3ccc(C)cc3)c3ccccc3-c3ccc(N(c4ccc5c(c4)C(C)(C)c4ccccc4-5)c4ccccc4-c4ccccc4)cc32)cc1 ; CC(C)(C)c1ccc(C2(c3ccc(C(C)(C)C)cc3)c3ccccc3-c3ccc(N(c4ccc5c(c4)C(C)(C)c4ccccc4-5)c4ccccc4-c4ccccc4)cc32)cc1]

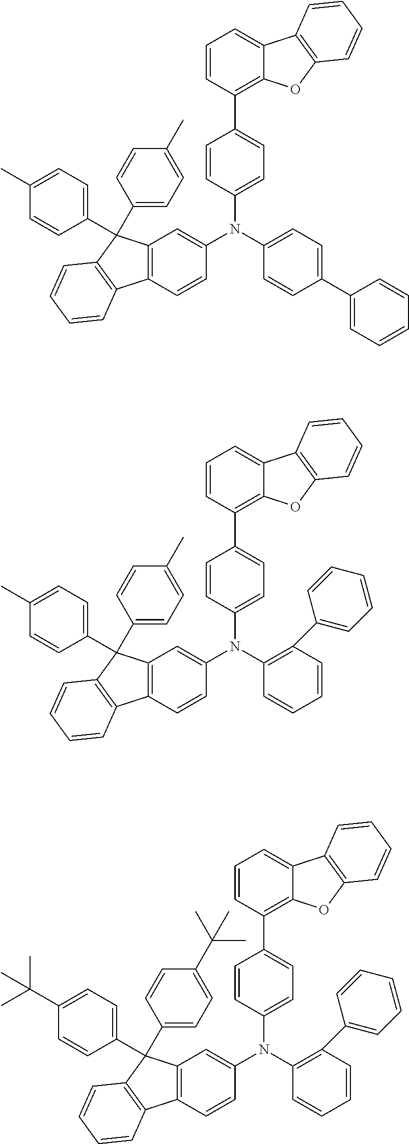 [SMILES: Cc1ccc(C2(c3ccc(C)cc3)c3ccccc3-c3ccc(N(c4ccc(-c5ccccc5)cc4)c4ccc(-c5cccc6c5oc5ccccc56)cc4)cc32)cc1 ; Cc1ccc(C2(c3ccc(C)cc3)c3ccccc3-c3ccc(N(c4ccc(-c5cccc6c5oc5ccccc56)cc4)c4ccccc4-c4ccccc4)cc32)cc1 ; CC(C)(C)c1ccc(C2(c3ccc(C(C)(C)C)cc3)c3ccccc3-c3ccc(N(c4ccc(-c5cccc6c5oc5ccccc56)cc4)c4ccccc4-c4ccccc4)cc32)cc1]

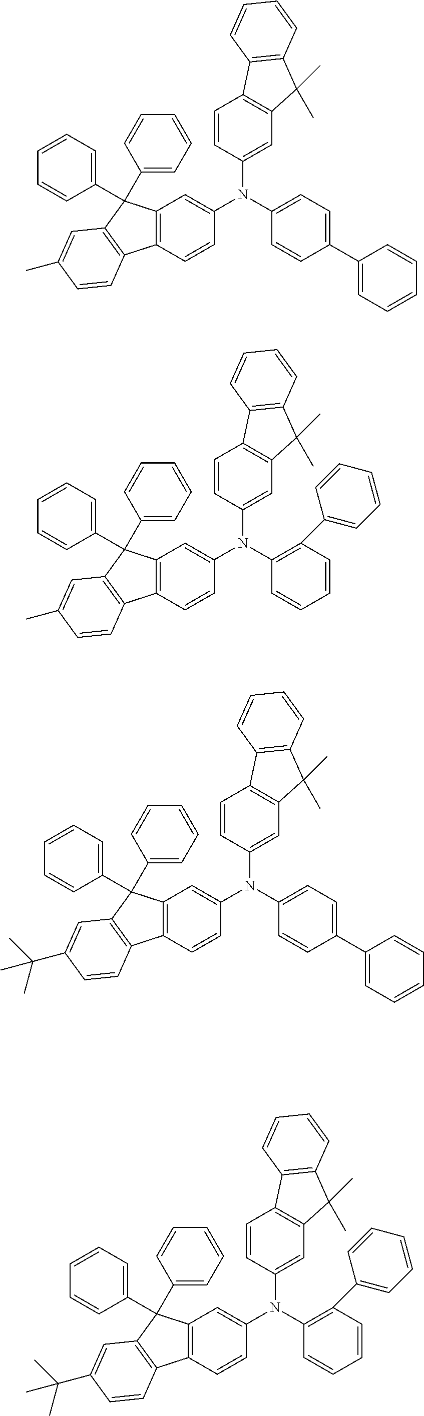 [SMILES: Cc1ccc2c(c1)C(c1ccccc1)(c1ccccc1)c1cc(N(c3ccc(-c4ccccc4)cc3)c3ccc4c(c3)C(C)(C)c3ccccc3-4)ccc1-2 ; Cc1ccc2c(c1)C(c1ccccc1)(c1ccccc1)c1cc(N(c3ccc4c(c3)C(C)(C)c3ccccc3-4)c3ccccc3-c3ccccc3)ccc1-2 ; CC(C)(C)c1ccc2c(c1)C(c1ccccc1)(c1ccccc1)c1cc(N(c3ccc(-c4ccccc4)cc3)c3ccc4c(c3)C(C)(C)c3ccccc3-4)ccc1-2 ; CC(C)(C)c1ccc2c(c1)C(c1ccccc1)(c1ccccc1)c1cc(N(c3ccc4c(c3)C(C)(C)c3ccccc3-4)c3ccccc3-c3ccccc3)ccc1-2]

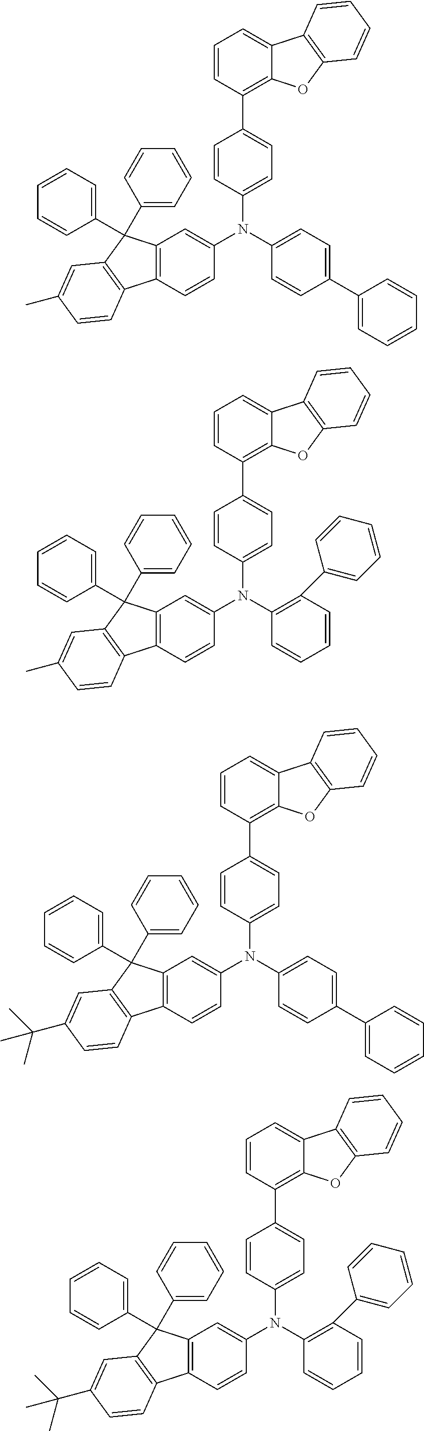

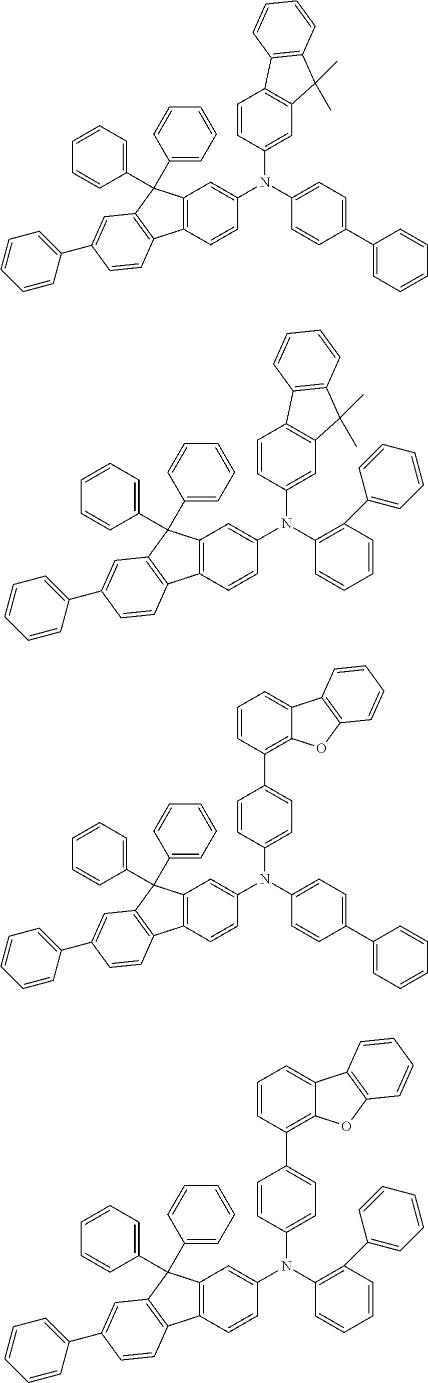 [SMILES: CC1(C)c2ccccc2-c2ccc(N(c3ccc(-c4ccccc4)cc3)c3ccc4c(c3)C(c3ccccc3)(c3ccccc3)c3cc(-c5ccccc5)ccc3-4)cc21 ; CC1(C)c2ccccc2-c2ccc(N(c3ccc4c(c3)C(c3ccccc3)(c3ccccc3)c3cc(-c5ccccc5)ccc3-4)c3ccccc3-c3ccccc3)cc21 ; c1ccc(-c2ccc(N(c3ccc(-c4cccc5c4oc4ccccc45)cc3)c3ccc4c(c3)C(c3ccccc3)(c3ccccc3)c3cc(-c5ccccc5)ccc3-4)cc2)cc1 ; c1ccc(-c2ccc3c(c2)C(c2ccccc2)(c2ccccc2)c2cc(N(c4ccc(-c5cccc6c5oc5ccccc56)cc4)c4ccccc4-c4ccccc4)ccc2-3)cc1]

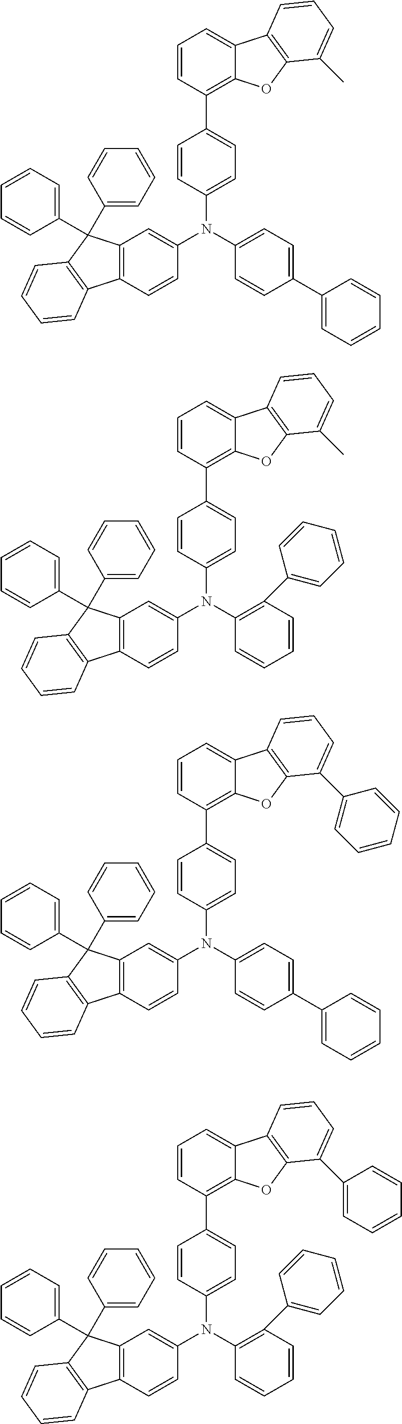

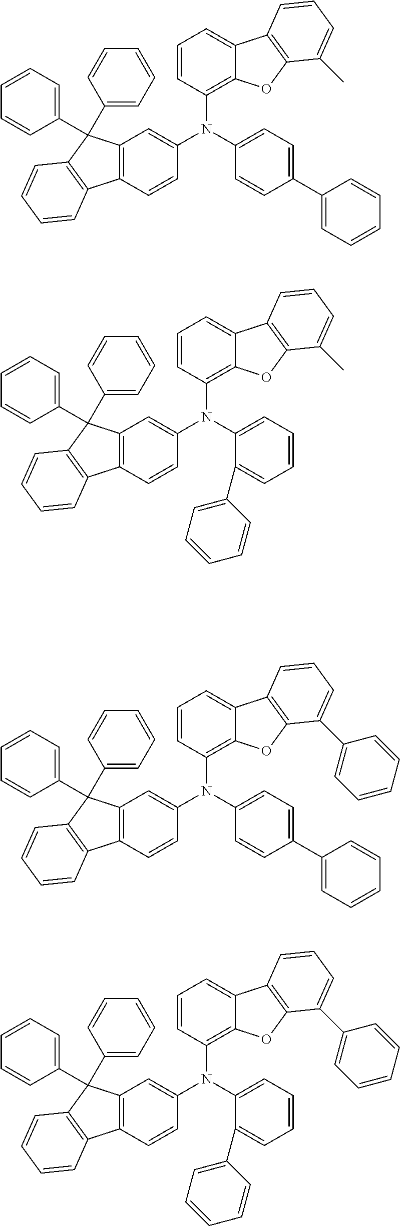 [SMILES: Cc1cccc2c1oc1c(N(c3ccc(-c4ccccc4)cc3)c3ccc4c(c3)C(c3ccccc3)(c3ccccc3)c3ccccc3-4)cccc12 ; Cc1cccc2c1oc1c(N(c3ccc4c(c3)C(c3ccccc3)(c3ccccc3)c3ccccc3-4)c3ccccc3-c3ccccc3)cccc12 ; c1ccc(-c2ccc(N(c3ccc4c(c3)C(c3ccccc3)(c3ccccc3)c3ccccc3-4)c3cccc4c3oc3c(-c5ccccc5)cccc34)cc2)cc1 ; c1ccc(-c2ccccc2N(c2ccc3c(c2)C(c2ccccc2)(c2ccccc2)c2ccccc2-3)c2cccc3c2oc2c(-c4ccccc4)cccc23)cc1]

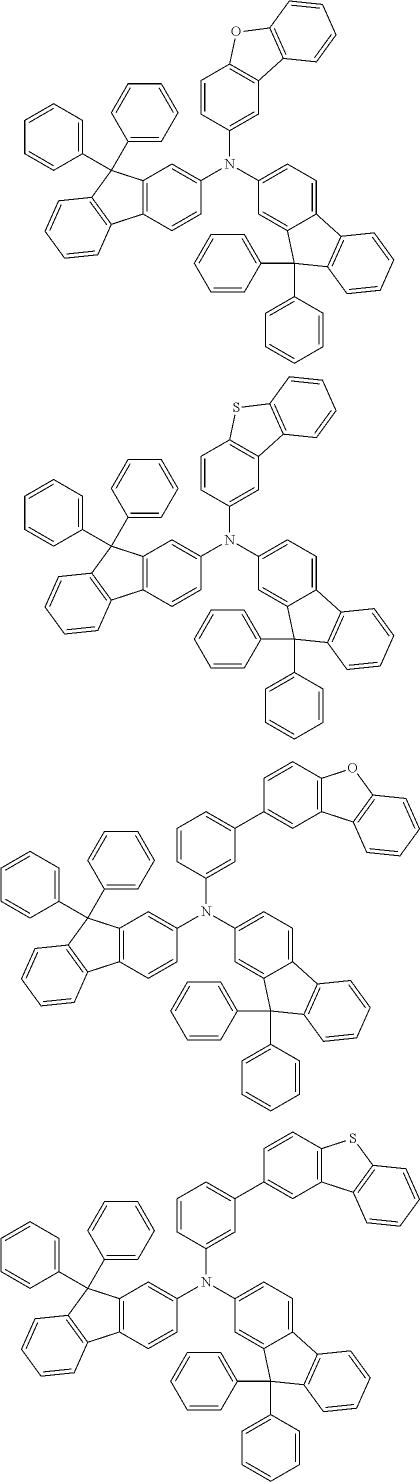

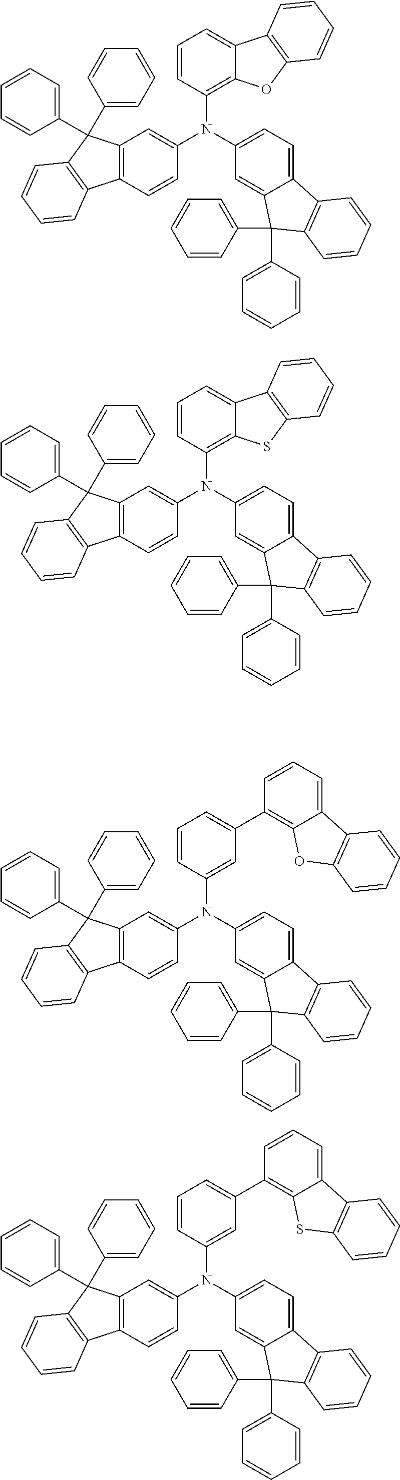

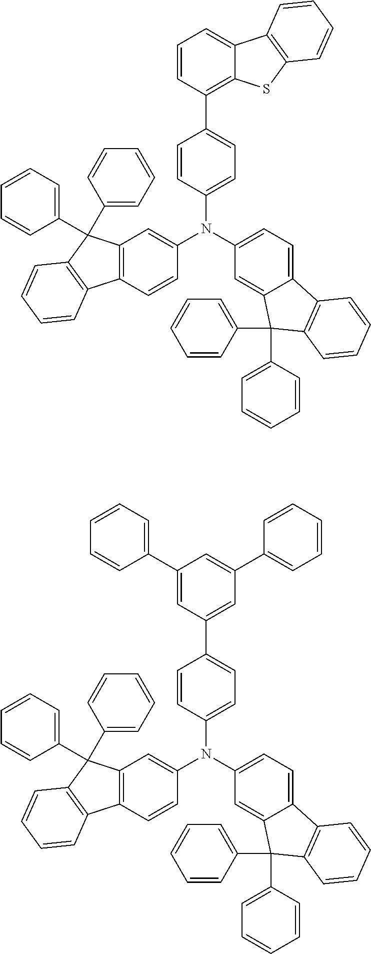 [SMILES: c1ccc(C2(c3ccccc3)c3ccccc3-c3ccc(N(c4ccc(-c5cccc6c5sc5ccccc56)cc4)c4ccc5c(c4)C(c4ccccc4)(c4ccccc4)c4ccccc4-5)cc32)cc1 ; c1ccc(-c2cc(-c3ccccc3)cc(-c3ccc(N(c4ccc5c(c4)C(c4ccccc4)(c4ccccc4)c4ccccc4-5)c4ccc5c(c4)C(c4ccccc4)(c4ccccc4)c4ccccc4-5)cc3)c2)cc1]

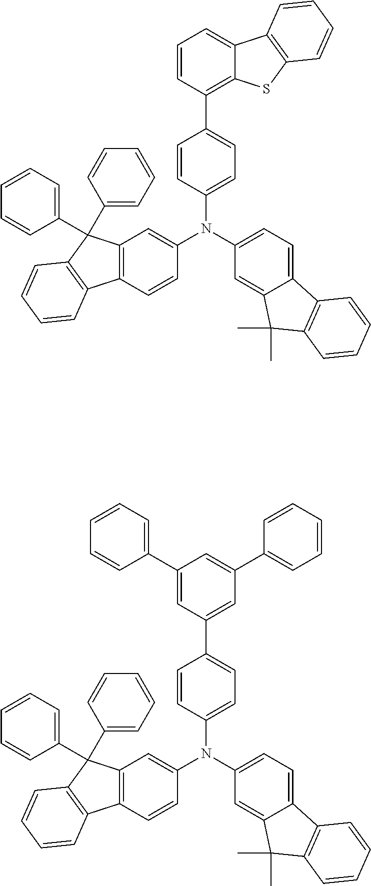 [SMILES: CC1(C)c2ccccc2-c2ccc(N(c3ccc(-c4cccc5c4sc4ccccc45)cc3)c3ccc4c(c3)C(c3ccccc3)(c3ccccc3)c3ccccc3-4)cc21 ; CC1(C)c2ccccc2-c2ccc(N(c3ccc(-c4cc(-c5ccccc5)cc(-c5ccccc5)c4)cc3)c3ccc4c(c3)C(c3ccccc3)(c3ccccc3)c3ccccc3-4)cc21]

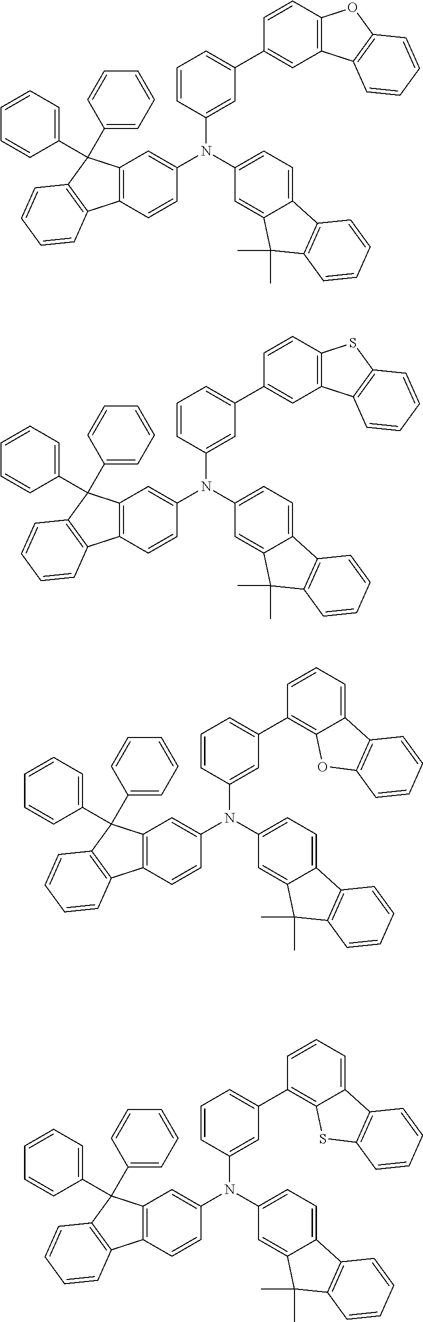 [SMILES: CC1(C)c2ccccc2-c2ccc(N(c3cccc(-c4ccc5oc6ccccc6c5c4)c3)c3ccc4c(c3)C(c3ccccc3)(c3ccccc3)c3ccccc3-4)cc21 ; CC1(C)c2ccccc2-c2ccc(N(c3cccc(-c4ccc5sc6ccccc6c5c4)c3)c3ccc4c(c3)C(c3ccccc3)(c3ccccc3)c3ccccc3-4)cc21 ; CC1(C)c2ccccc2-c2ccc(N(c3cccc(-c4cccc5c4oc4ccccc45)c3)c3ccc4c(c3)C(c3ccccc3)(c3ccccc3)c3ccccc3-4)cc21 ; CC1(C)c2ccccc2-c2ccc(N(c3cccc(-c4cccc5c4sc4ccccc45)c3)c3ccc4c(c3)C(c3ccccc3)(c3ccccc3)c3ccccc3-4)cc21]

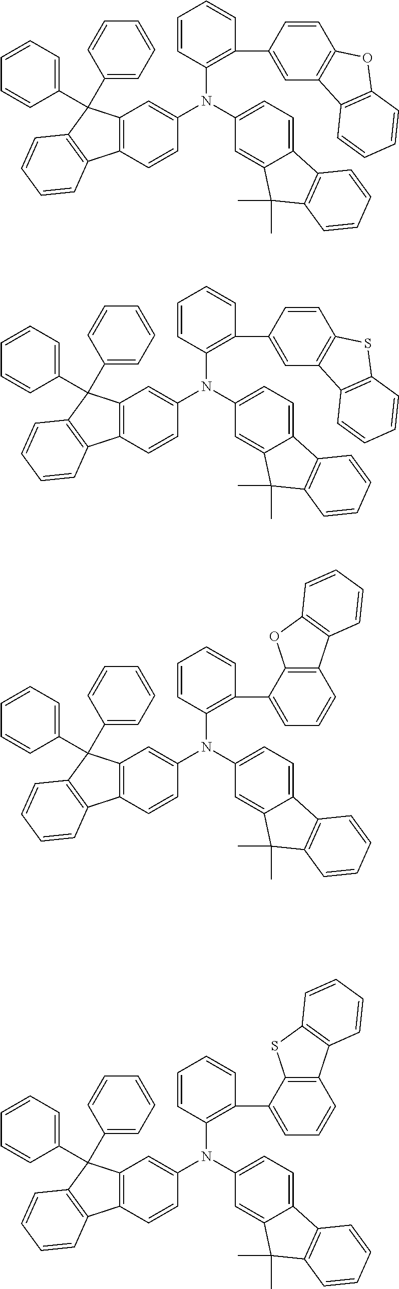 [SMILES: CC1(C)c2ccccc2-c2ccc(N(c3ccc4c(c3)C(c3ccccc3)(c3ccccc3)c3ccccc3-4)c3ccccc3-c3ccc4oc5ccccc5c4c3)cc21 ; CC1(C)c2ccccc2-c2ccc(N(c3ccc4c(c3)C(c3ccccc3)(c3ccccc3)c3ccccc3-4)c3ccccc3-c3ccc4sc5ccccc5c4c3)cc21 ; CC1(C)c2ccccc2-c2ccc(N(c3ccc4c(c3)C(c3ccccc3)(c3ccccc3)c3ccccc3-4)c3ccccc3-c3cccc4c3oc3ccccc34)cc21 ; CC1(C)c2ccccc2-c2ccc(N(c3ccc4c(c3)C(c3ccccc3)(c3ccccc3)c3ccccc3-4)c3ccccc3-c3cccc4c3sc3ccccc34)cc21]

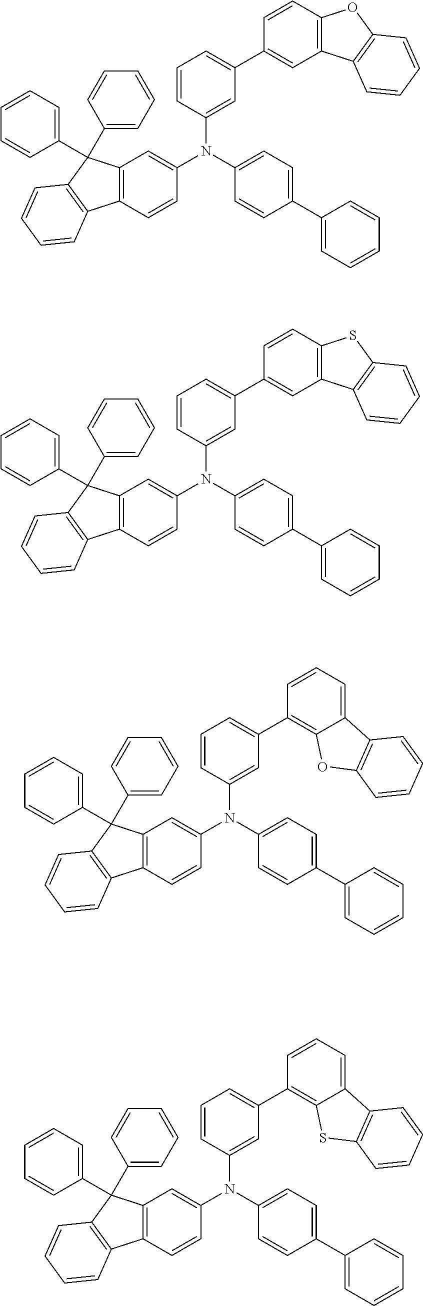 [SMILES: c1ccc(-c2ccc(N(c3cccc(-c4ccc5oc6ccccc6c5c4)c3)c3ccc4c(c3)C(c3ccccc3)(c3ccccc3)c3ccccc3-4)cc2)cc1 ; c1ccc(-c2ccc(N(c3cccc(-c4ccc5sc6ccccc6c5c4)c3)c3ccc4c(c3)C(c3ccccc3)(c3ccccc3)c3ccccc3-4)cc2)cc1 ; c1ccc(-c2ccc(N(c3cccc(-c4cccc5c4oc4ccccc45)c3)c3ccc4c(c3)C(c3ccccc3)(c3ccccc3)c3ccccc3-4)cc2)cc1 ; c1ccc(-c2ccc(N(c3cccc(-c4cccc5c4sc4ccccc45)c3)c3ccc4c(c3)C(c3ccccc3)(c3ccccc3)c3ccccc3-4)cc2)cc1]

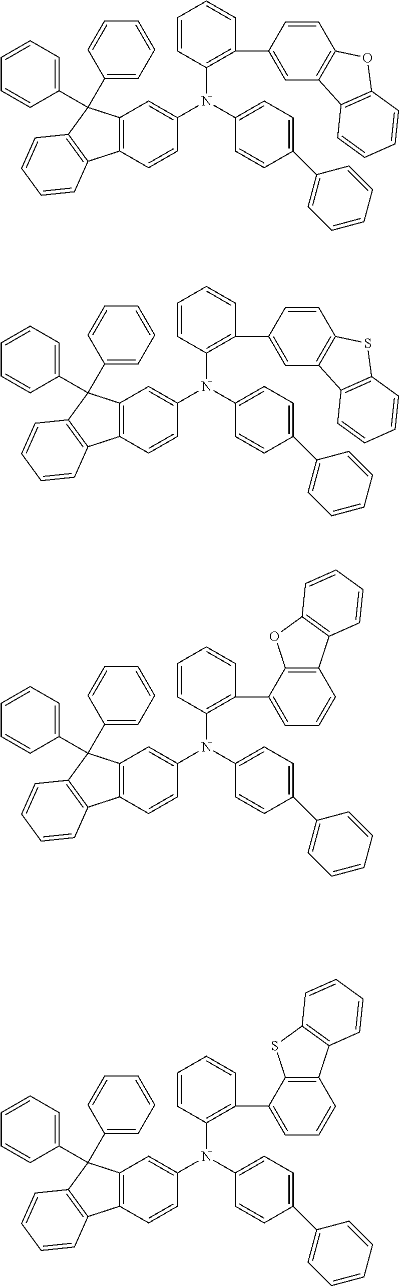 [SMILES: c1ccc(-c2ccc(N(c3ccc4c(c3)C(c3ccccc3)(c3ccccc3)c3ccccc3-4)c3ccccc3-c3ccc4oc5ccccc5c4c3)cc2)cc1 ; c1ccc(-c2ccc(N(c3ccc4c(c3)C(c3ccccc3)(c3ccccc3)c3ccccc3-4)c3ccccc3-c3ccc4sc5ccccc5c4c3)cc2)cc1 ; c1ccc(-c2ccc(N(c3ccc4c(c3)C(c3ccccc3)(c3ccccc3)c3ccccc3-4)c3ccccc3-c3cccc4c3oc3ccccc34)cc2)cc1 ; c1ccc(-c2ccc(N(c3ccc4c(c3)C(c3ccccc3)(c3ccccc3)c3ccccc3-4)c3ccccc3-c3cccc4c3sc3ccccc34)cc2)cc1]

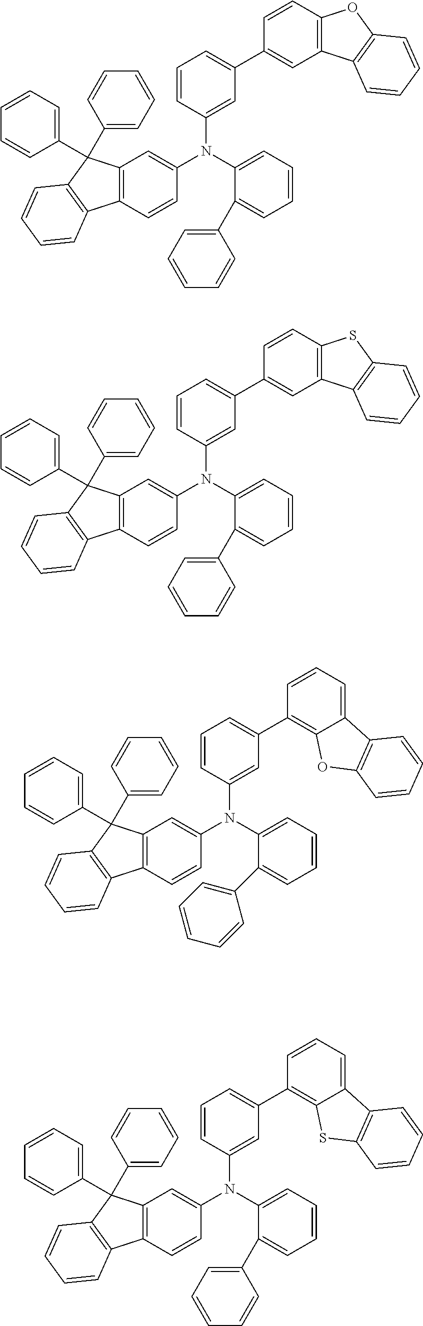 [SMILES: c1ccc(-c2ccccc2N(c2cccc(-c3ccc4oc5ccccc5c4c3)c2)c2ccc3c(c2)C(c2ccccc2)(c2ccccc2)c2ccccc2-3)cc1 ; c1ccc(-c2ccccc2N(c2cccc(-c3ccc4sc5ccccc5c4c3)c2)c2ccc3c(c2)C(c2ccccc2)(c2ccccc2)c2ccccc2-3)cc1 ; c1ccc(-c2ccccc2N(c2cccc(-c3cccc4c3oc3ccccc34)c2)c2ccc3c(c2)C(c2ccccc2)(c2ccccc2)c2ccccc2-3)cc1 ; c1ccc(-c2ccccc2N(c2cccc(-c3cccc4c3sc3ccccc34)c2)c2ccc3c(c2)C(c2ccccc2)(c2ccccc2)c2ccccc2-3)cc1]

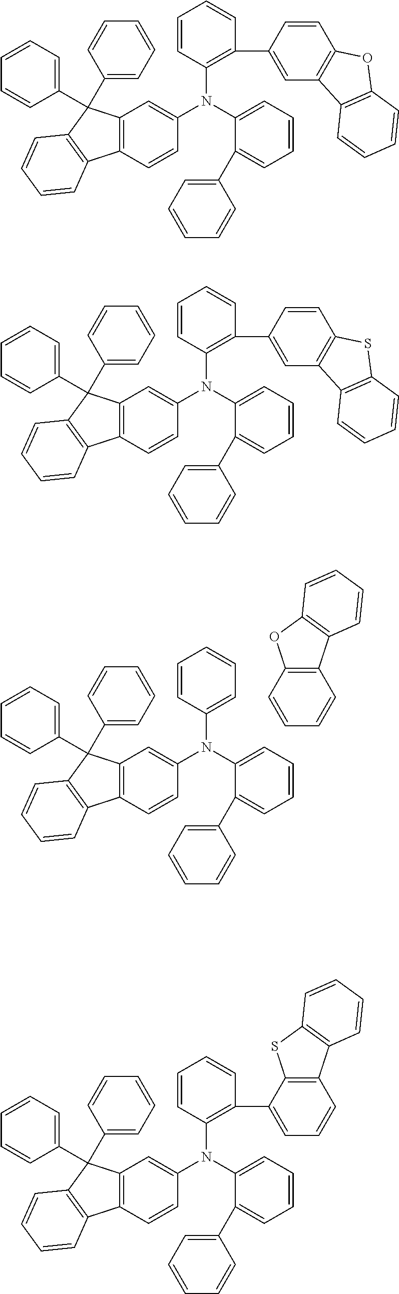

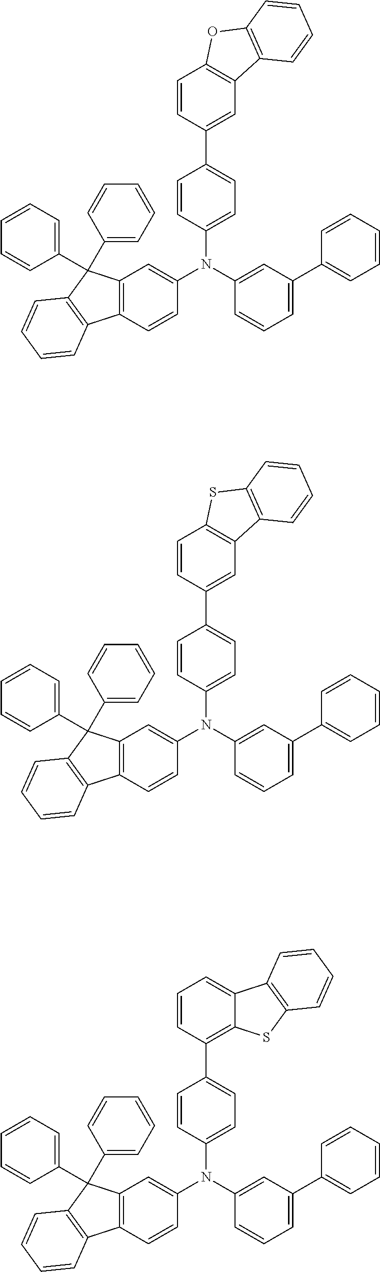 [SMILES: c1ccc(-c2cccc(N(c3ccc(-c4ccc5oc6ccccc6c5c4)cc3)c3ccc4c(c3)C(c3ccccc3)(c3ccccc3)c3ccccc3-4)c2)cc1 ; c1ccc(-c2cccc(N(c3ccc(-c4ccc5sc6ccccc6c5c4)cc3)c3ccc4c(c3)C(c3ccccc3)(c3ccccc3)c3ccccc3-4)c2)cc1 ; c1ccc(-c2cccc(N(c3ccc(-c4cccc5c4sc4ccccc45)cc3)c3ccc4c(c3)C(c3ccccc3)(c3ccccc3)c3ccccc3-4)c2)cc1]

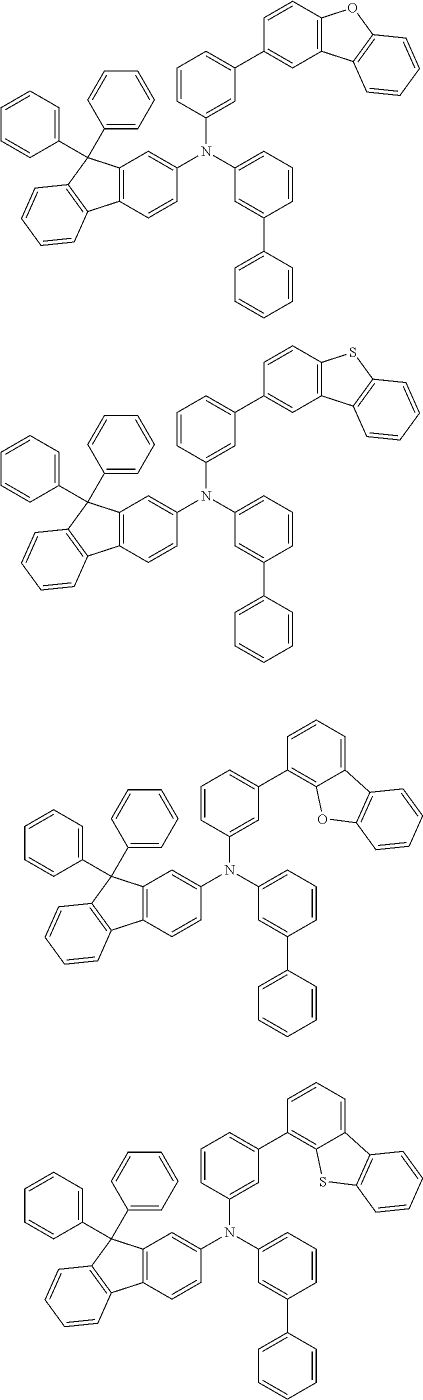

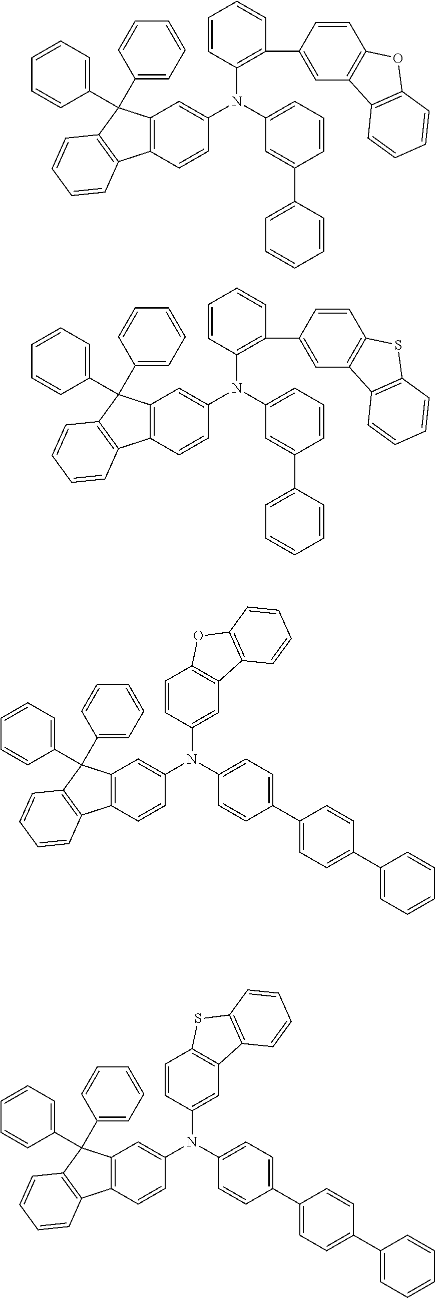 [SMILES: c1ccc(-c2cccc(N(c3ccc4c(c3)C(c3ccccc3)(c3ccccc3)c3ccccc3-4)c3ccccc3-c3ccc4oc5ccccc5c4c3)c2)cc1 ; c1ccc(-c2cccc(N(c3ccc4c(c3)C(c3ccccc3)(c3ccccc3)c3ccccc3-4)c3ccccc3-c3ccc4sc5ccccc5c4c3)c2)cc1 ; c1ccc(-c2ccc(-c3ccc(N(c4ccc5c(c4)C(c4ccccc4)(c4ccccc4)c4ccccc4-5)c4ccc5oc6ccccc6c5c4)cc3)cc2)cc1 ; c1ccc(-c2ccc(-c3ccc(N(c4ccc5c(c4)C(c4ccccc4)(c4ccccc4)c4ccccc4-5)c4ccc5sc6ccccc6c5c4)cc3)cc2)cc1]

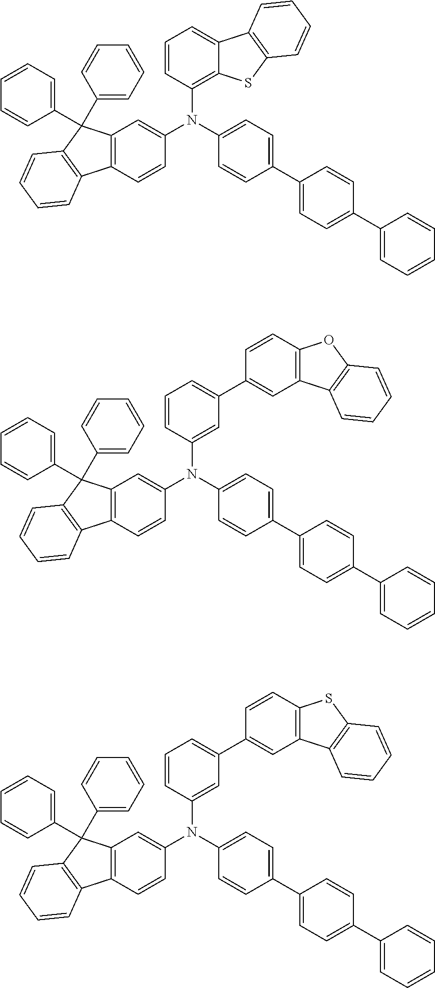 [SMILES: c1ccc(-c2ccc(-c3ccc(N(c4ccc5c(c4)C(c4ccccc4)(c4ccccc4)c4ccccc4-5)c4cccc5c4sc4ccccc45)cc3)cc2)cc1 ; c1ccc(-c2ccc(-c3ccc(N(c4cccc(-c5ccc6oc7ccccc7c6c5)c4)c4ccc5c(c4)C(c4ccccc4)(c4ccccc4)c4ccccc4-5)cc3)cc2)cc1 ; c1ccc(-c2ccc(-c3ccc(N(c4cccc(-c5ccc6sc7ccccc7c6c5)c4)c4ccc5c(c4)C(c4ccccc4)(c4ccccc4)c4ccccc4-5)cc3)cc2)cc1]

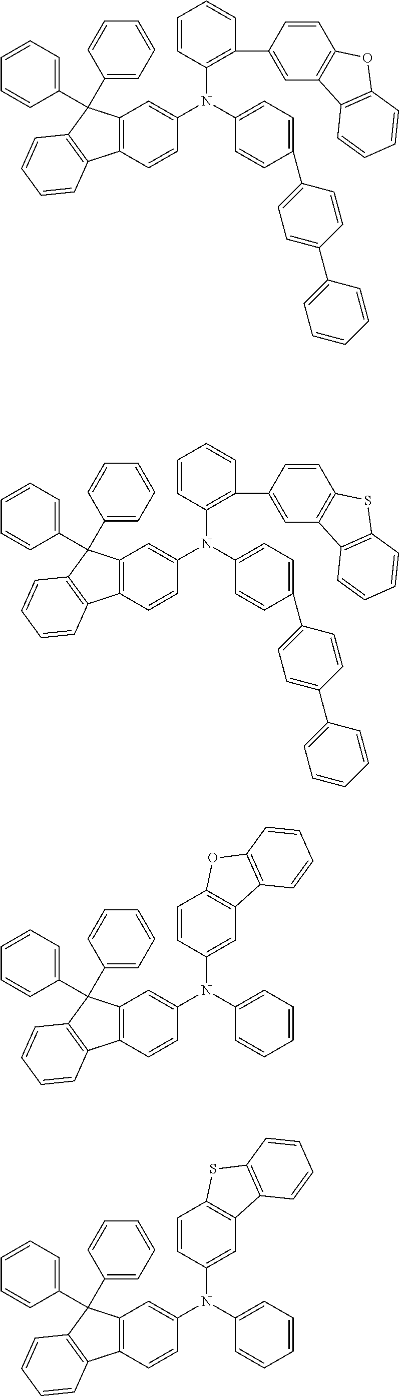 [SMILES: c1ccc(-c2ccc(-c3ccc(N(c4ccc5c(c4)C(c4ccccc4)(c4ccccc4)c4ccccc4-5)c4ccccc4-c4ccc5oc6ccccc6c5c4)cc3)cc2)cc1 ; c1ccc(-c2ccc(-c3ccc(N(c4ccc5c(c4)C(c4ccccc4)(c4ccccc4)c4ccccc4-5)c4ccccc4-c4ccc5sc6ccccc6c5c4)cc3)cc2)cc1 ; c1ccc(N(c2ccc3c(c2)C(c2ccccc2)(c2ccccc2)c2ccccc2-3)c2ccc3oc4ccccc4c3c2)cc1 ; c1ccc(N(c2ccc3c(c2)C(c2ccccc2)(c2ccccc2)c2ccccc2-3)c2ccc3sc4ccccc4c3c2)cc1]

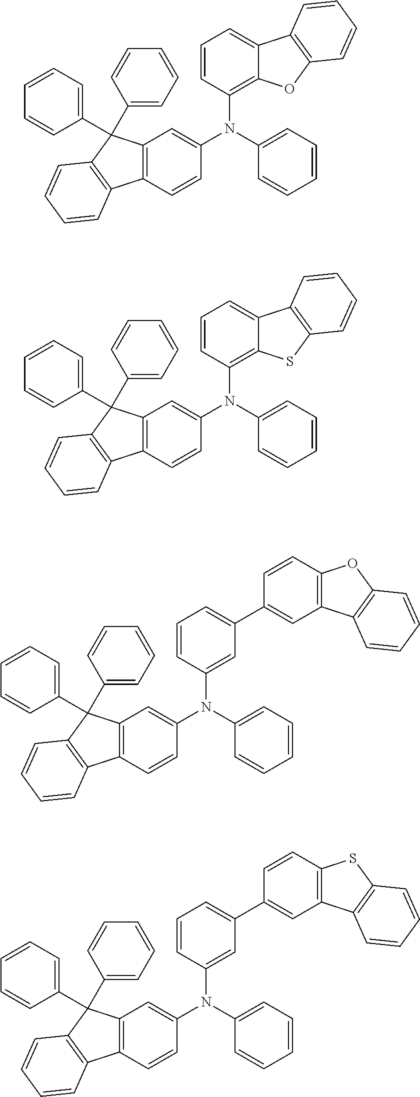 [SMILES: c1ccc(N(c2ccc3c(c2)C(c2ccccc2)(c2ccccc2)c2ccccc2-3)c2cccc3c2oc2ccccc23)cc1 ; c1ccc(N(c2ccc3c(c2)C(c2ccccc2)(c2ccccc2)c2ccccc2-3)c2cccc3c2sc2ccccc23)cc1 ; c1ccc(N(c2cccc(-c3ccc4oc5ccccc5c4c3)c2)c2ccc3c(c2)C(c2ccccc2)(c2ccccc2)c2ccccc2-3)cc1 ; c1ccc(N(c2cccc(-c3ccc4sc5ccccc5c4c3)c2)c2ccc3c(c2)C(c2ccccc2)(c2ccccc2)c2ccccc2-3)cc1]

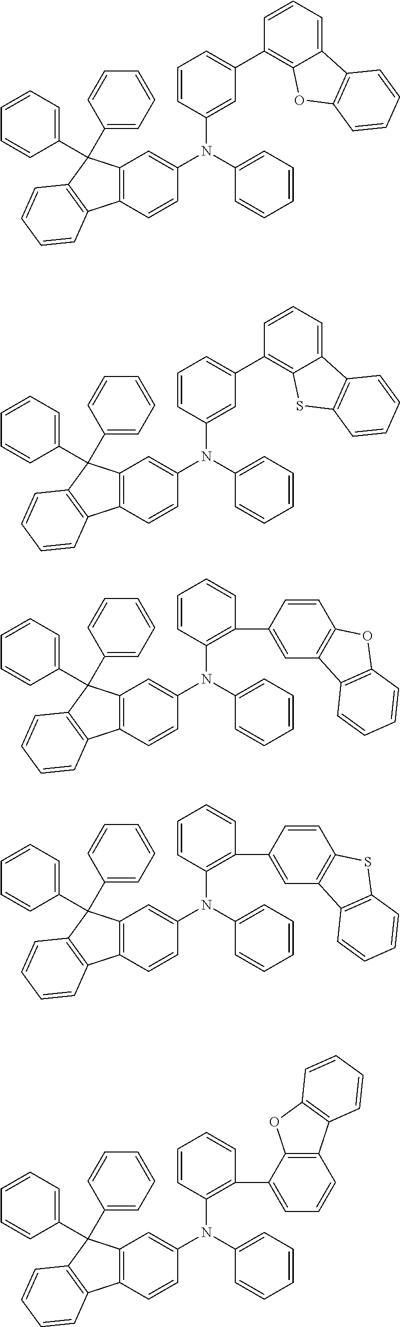 [SMILES: c1ccc(N(c2cccc(-c3cccc4c3oc3ccccc34)c2)c2ccc3c(c2)C(c2ccccc2)(c2ccccc2)c2ccccc2-3)cc1 ; c1ccc(N(c2cccc(-c3cccc4c3sc3ccccc34)c2)c2ccc3c(c2)C(c2ccccc2)(c2ccccc2)c2ccccc2-3)cc1 ; c1ccc(N(c2ccc3c(c2)C(c2ccccc2)(c2ccccc2)c2ccccc2-3)c2ccccc2-c2ccc3oc4ccccc4c3c2)cc1 ; c1ccc(N(c2ccc3c(c2)C(c2ccccc2)(c2ccccc2)c2ccccc2-3)c2ccccc2-c2ccc3sc4ccccc4c3c2)cc1 ; c1ccc(N(c2ccc3c(c2)C(c2ccccc2)(c2ccccc2)c2ccccc2-3)c2ccccc2-c2cccc3c2oc2ccccc23)cc1]

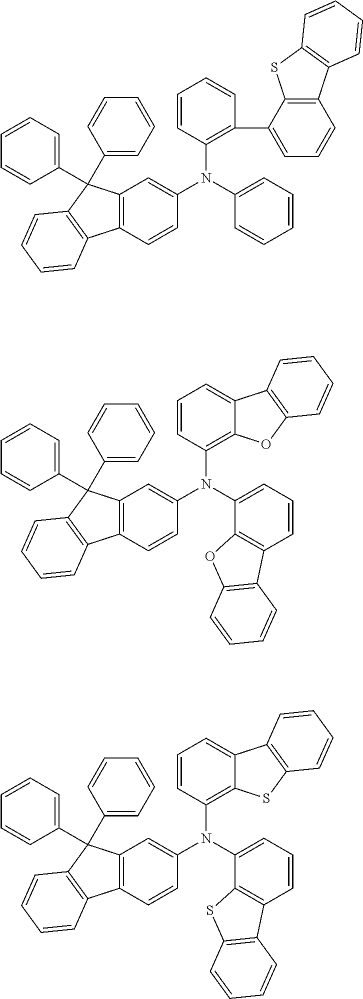 [SMILES: c1ccc(N(c2ccc3c(c2)C(c2ccccc2)(c2ccccc2)c2ccccc2-3)c2ccccc2-c2cccc3c2sc2ccccc23)cc1 ; c1ccc(C2(c3ccccc3)c3ccccc3-c3ccc(N(c4cccc5c4oc4ccccc45)c4cccc5c4oc4ccccc45)cc32)cc1 ; c1ccc(C2(c3ccccc3)c3ccccc3-c3ccc(N(c4cccc5c4sc4ccccc45)c4cccc5c4sc4ccccc45)cc32)cc1]

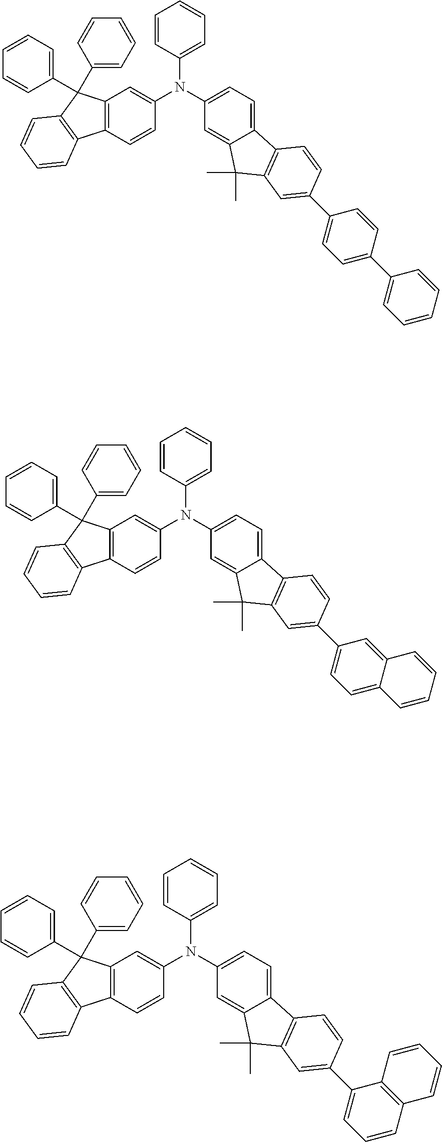 [SMILES: CC1(C)c2cc(-c3ccc(-c4ccccc4)cc3)ccc2-c2ccc(N(c3ccccc3)c3ccc4c(c3)C(c3ccccc3)(c3ccccc3)c3ccccc3-4)cc21 ; CC1(C)c2cc(-c3ccc4ccccc4c3)ccc2-c2ccc(N(c3ccccc3)c3ccc4c(c3)C(c3ccccc3)(c3ccccc3)c3ccccc3-4)cc21 ; CC1(C)c2cc(-c3cccc4ccccc34)ccc2-c2ccc(N(c3ccccc3)c3ccc4c(c3)C(c3ccccc3)(c3ccccc3)c3ccccc3-4)cc21]

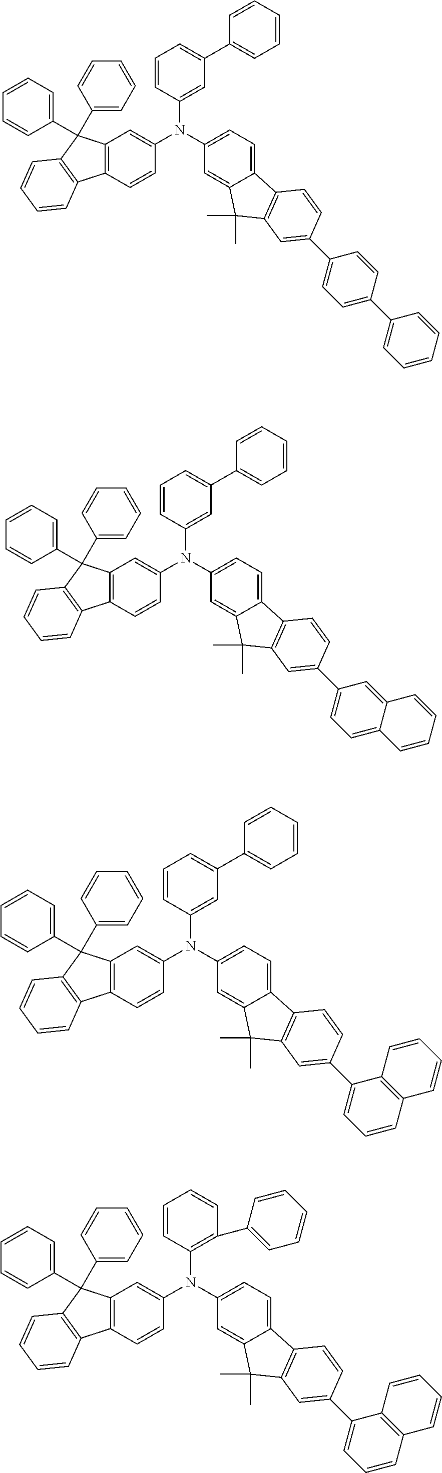 [SMILES: CC1(C)c2cc(-c3ccc(-c4ccccc4)cc3)ccc2-c2ccc(N(c3cccc(-c4ccccc4)c3)c3ccc4c(c3)C(c3ccccc3)(c3ccccc3)c3ccccc3-4)cc21 ; CC1(C)c2cc(-c3ccc4ccccc4c3)ccc2-c2ccc(N(c3cccc(-c4ccccc4)c3)c3ccc4c(c3)C(c3ccccc3)(c3ccccc3)c3ccccc3-4)cc21 ; CC1(C)c2cc(-c3cccc4ccccc34)ccc2-c2ccc(N(c3cccc(-c4ccccc4)c3)c3ccc4c(c3)C(c3ccccc3)(c3ccccc3)c3ccccc3-4)cc21 ; CC1(C)c2cc(-c3cccc4ccccc34)ccc2-c2ccc(N(c3ccc4c(c3)C(c3ccccc3)(c3ccccc3)c3ccccc3-4)c3ccccc3-c3ccccc3)cc21]

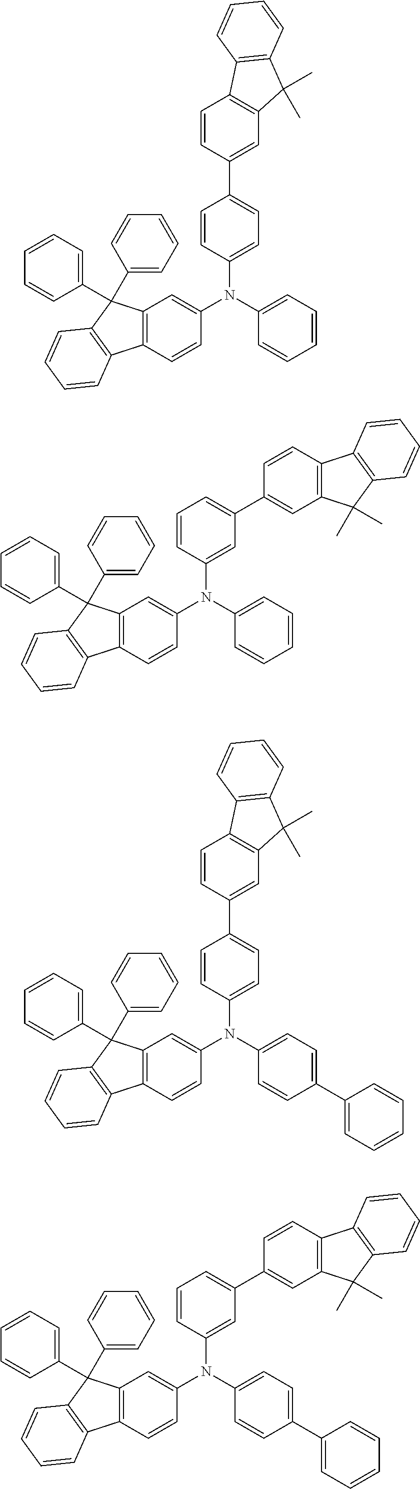 [SMILES: CC1(C)c2ccccc2-c2ccc(-c3ccc(N(c4ccccc4)c4ccc5c(c4)C(c4ccccc4)(c4ccccc4)c4ccccc4-5)cc3)cc21 ; CC1(C)c2ccccc2-c2ccc(-c3cccc(N(c4ccccc4)c4ccc5c(c4)C(c4ccccc4)(c4ccccc4)c4ccccc4-5)c3)cc21 ; CC1(C)c2ccccc2-c2ccc(-c3ccc(N(c4ccc(-c5ccccc5)cc4)c4ccc5c(c4)C(c4ccccc4)(c4ccccc4)c4ccccc4-5)cc3)cc21 ; CC1(C)c2ccccc2-c2ccc(-c3cccc(N(c4ccc(-c5ccccc5)cc4)c4ccc5c(c4)C(c4ccccc4)(c4ccccc4)c4ccccc4-5)c3)cc21]

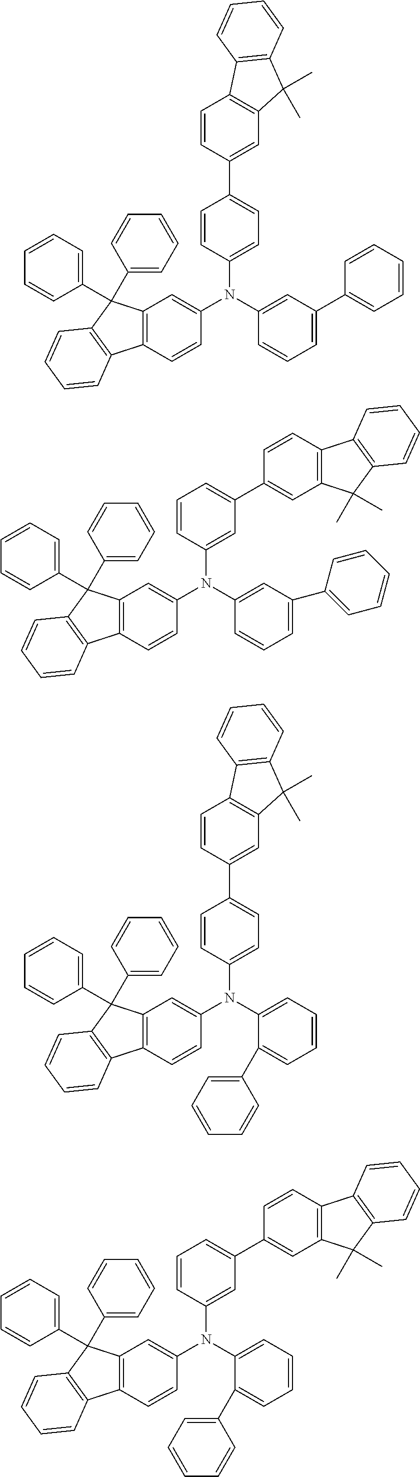 [SMILES: CC1(C)c2ccccc2-c2ccc(-c3ccc(N(c4cccc(-c5ccccc5)c4)c4ccc5c(c4)C(c4ccccc4)(c4ccccc4)c4ccccc4-5)cc3)cc21 ; CC1(C)c2ccccc2-c2ccc(-c3cccc(N(c4cccc(-c5ccccc5)c4)c4ccc5c(c4)C(c4ccccc4)(c4ccccc4)c4ccccc4-5)c3)cc21 ; CC1(C)c2ccccc2-c2ccc(-c3ccc(N(c4ccc5c(c4)C(c4ccccc4)(c4ccccc4)c4ccccc4-5)c4ccccc4-c4ccccc4)cc3)cc21 ; CC1(C)c2ccccc2-c2ccc(-c3cccc(N(c4ccc5c(c4)C(c4ccccc4)(c4ccccc4)c4ccccc4-5)c4ccccc4-c4ccccc4)c3)cc21]

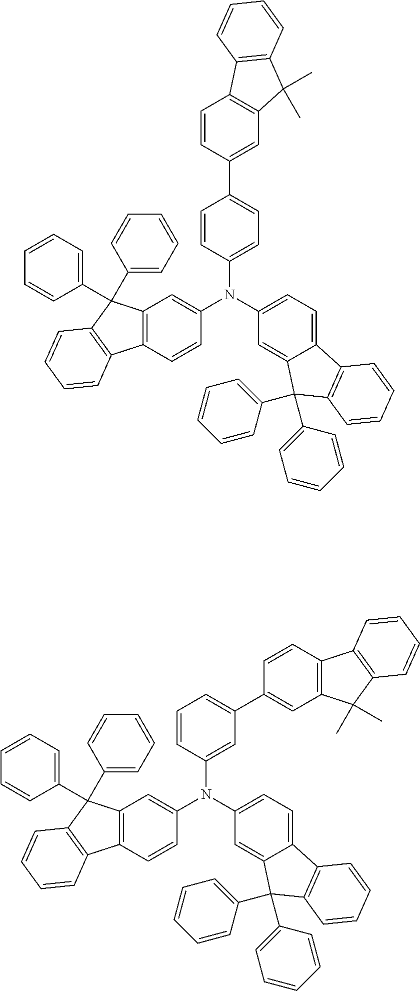 [SMILES: CC1(C)c2ccccc2-c2ccc(-c3ccc(N(c4ccc5c(c4)C(c4ccccc4)(c4ccccc4)c4ccccc4-5)c4ccc5c(c4)C(c4ccccc4)(c4ccccc4)c4ccccc4-5)cc3)cc21 ; CC1(C)c2ccccc2-c2ccc(-c3cccc(N(c4ccc5c(c4)C(c4ccccc4)(c4ccccc4)c4ccccc4-5)c4ccc5c(c4)C(c4ccccc4)(c4ccccc4)c4ccccc4-5)c3)cc21]

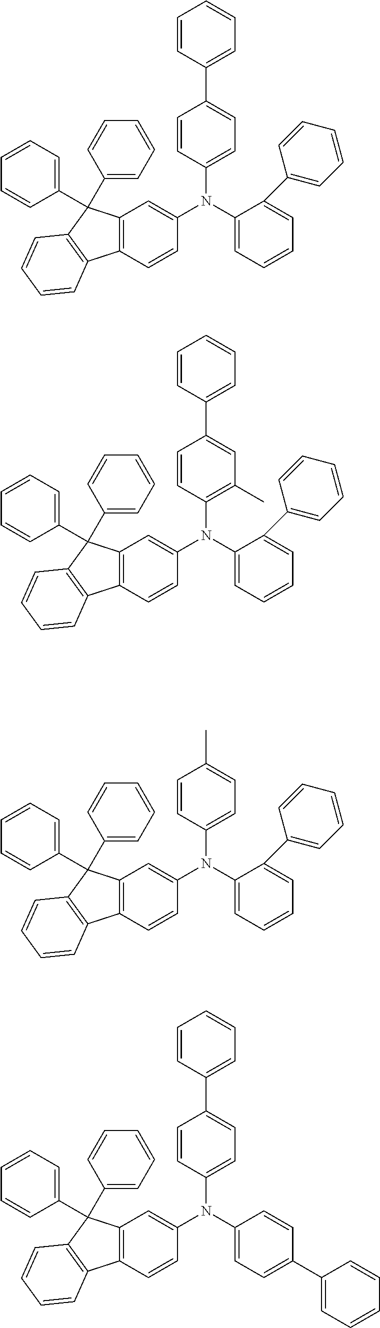 [SMILES: c1ccc(-c2ccc(N(c3ccc4c(c3)C(c3ccccc3)(c3ccccc3)c3ccccc3-4)c3ccccc3-c3ccccc3)cc2)cc1 ; Cc1cc(-c2ccccc2)ccc1N(c1ccc2c(c1)C(c1ccccc1)(c1ccccc1)c1ccccc1-2)c1ccccc1-c1ccccc1 ; Cc1ccc(N(c2ccc3c(c2)C(c2ccccc2)(c2ccccc2)c2ccccc2-3)c2ccccc2-c2ccccc2)cc1 ; c1ccc(-c2ccc(N(c3ccc(-c4ccccc4)cc3)c3ccc4c(c3)C(c3ccccc3)(c3ccccc3)c3ccccc3-4)cc2)cc1]

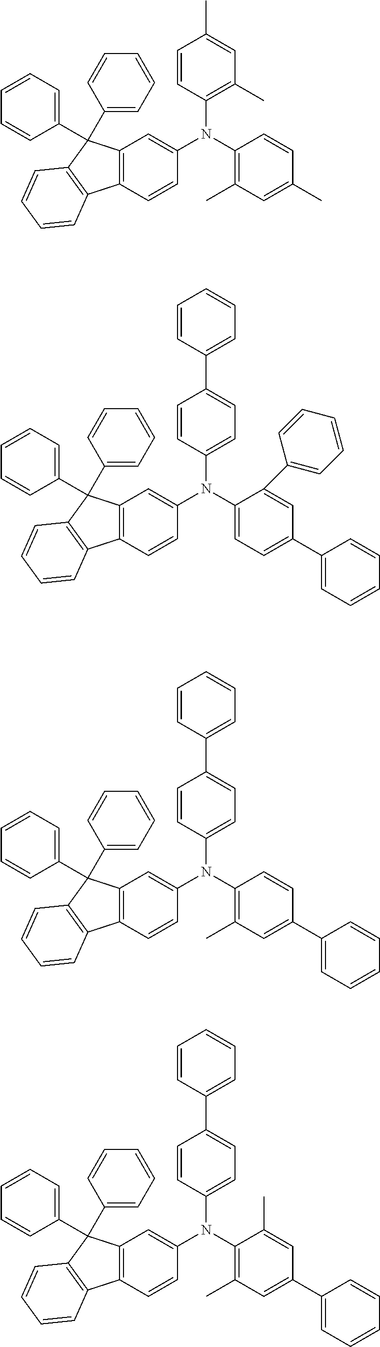 [SMILES: Cc1ccc(N(c2ccc3c(c2)C(c2ccccc2)(c2ccccc2)c2ccccc2-3)c2ccc(C)cc2C)c(C)c1 ; c1ccc(-c2ccc(N(c3ccc4c(c3)C(c3ccccc3)(c3ccccc3)c3ccccc3-4)c3ccc(-c4ccccc4)cc3-c3ccccc3)cc2)cc1 ; Cc1cc(-c2ccccc2)ccc1N(c1ccc(-c2ccccc2)cc1)c1ccc2c(c1)C(c1ccccc1)(c1ccccc1)c1ccccc1-2 ; Cc1cc(-c2ccccc2)cc(C)c1N(c1ccc(-c2ccccc2)cc1)c1ccc2c(c1)C(c1ccccc1)(c1ccccc1)c1ccccc1-2]

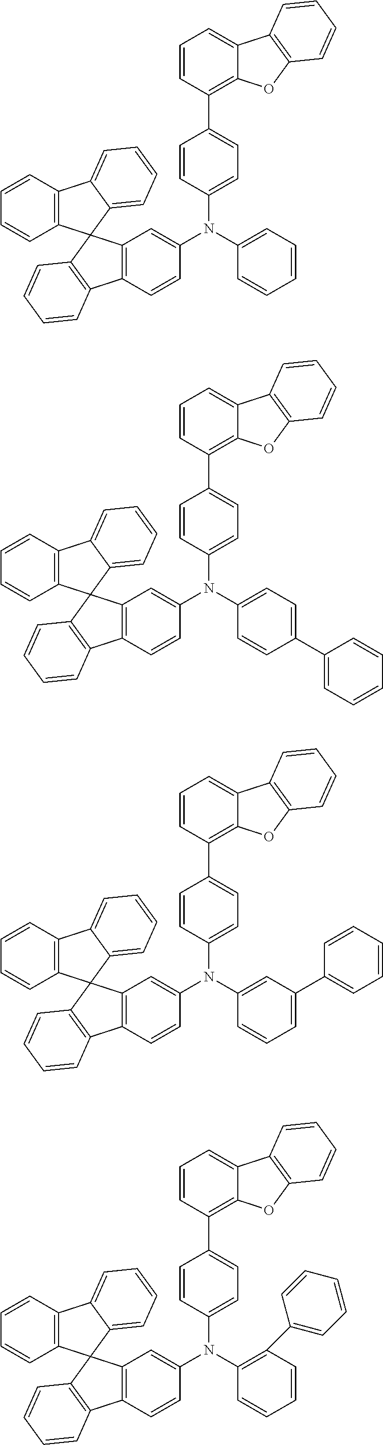 [SMILES: c1ccc(N(c2ccc(-c3cccc4c3oc3ccccc34)cc2)c2ccc3c(c2)C2(c4ccccc4-c4ccccc42)c2ccccc2-3)cc1 ; c1ccc(-c2ccc(N(c3ccc(-c4cccc5c4oc4ccccc45)cc3)c3ccc4c(c3)C3(c5ccccc5-c5ccccc53)c3ccccc3-4)cc2)cc1 ; c1ccc(-c2cccc(N(c3ccc(-c4cccc5c4oc4ccccc45)cc3)c3ccc4c(c3)C3(c5ccccc5-c5ccccc53)c3ccccc3-4)c2)cc1 ; c1ccc(-c2ccccc2N(c2ccc(-c3cccc4c3oc3ccccc34)cc2)c2ccc3c(c2)C2(c4ccccc4-c4ccccc42)c2ccccc2-3)cc1]

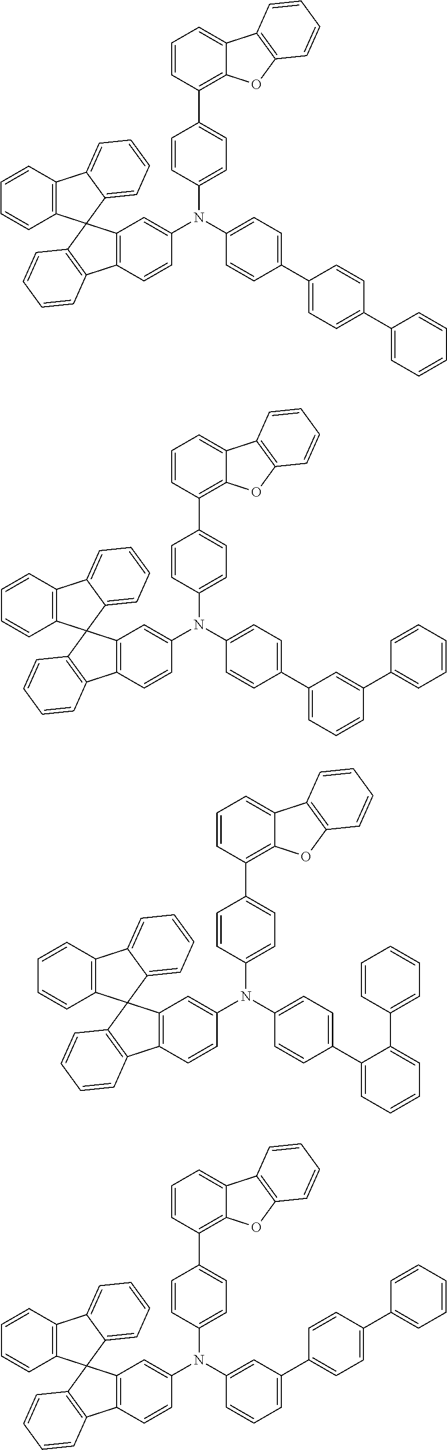

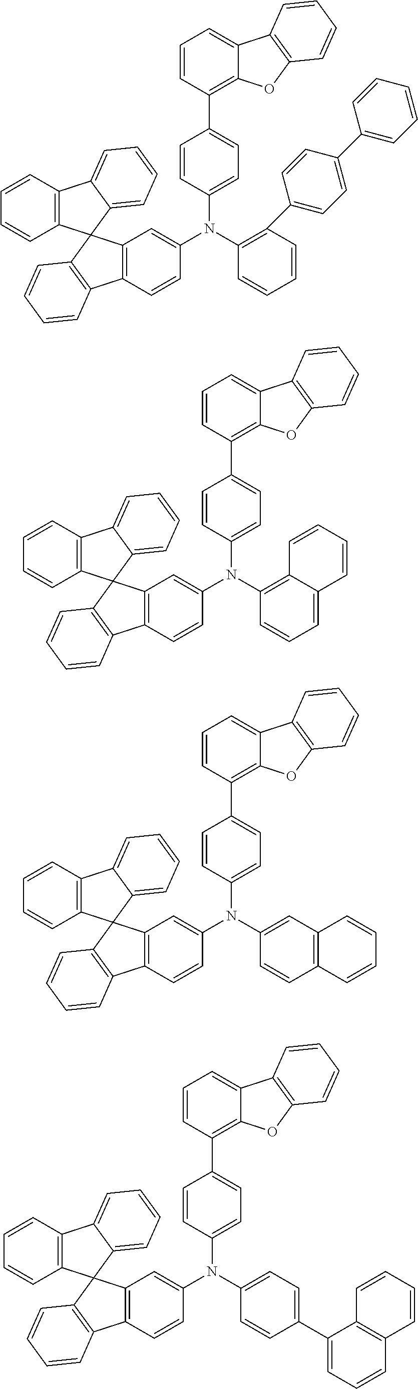 [SMILES: c1ccc(-c2ccc(-c3ccccc3N(c3ccc(-c4cccc5c4oc4ccccc45)cc3)c3ccc4c(c3)C3(c5ccccc5-c5ccccc53)c3ccccc3-4)cc2)cc1 ; c1ccc2c(c1)-c1ccccc1C21c2ccccc2-c2ccc(N(c3ccc(-c4cccc5c4oc4ccccc45)cc3)c3cccc4ccccc34)cc21 ; c1ccc2c(c1)-c1ccccc1C21c2ccccc2-c2ccc(N(c3ccc(-c4cccc5c4oc4ccccc45)cc3)c3ccc4ccccc4c3)cc21 ; c1ccc2c(c1)-c1ccccc1C21c2ccccc2-c2ccc(N(c3ccc(-c4cccc5ccccc45)cc3)c3ccc(-c4cccc5c4oc4ccccc45)cc3)cc21]

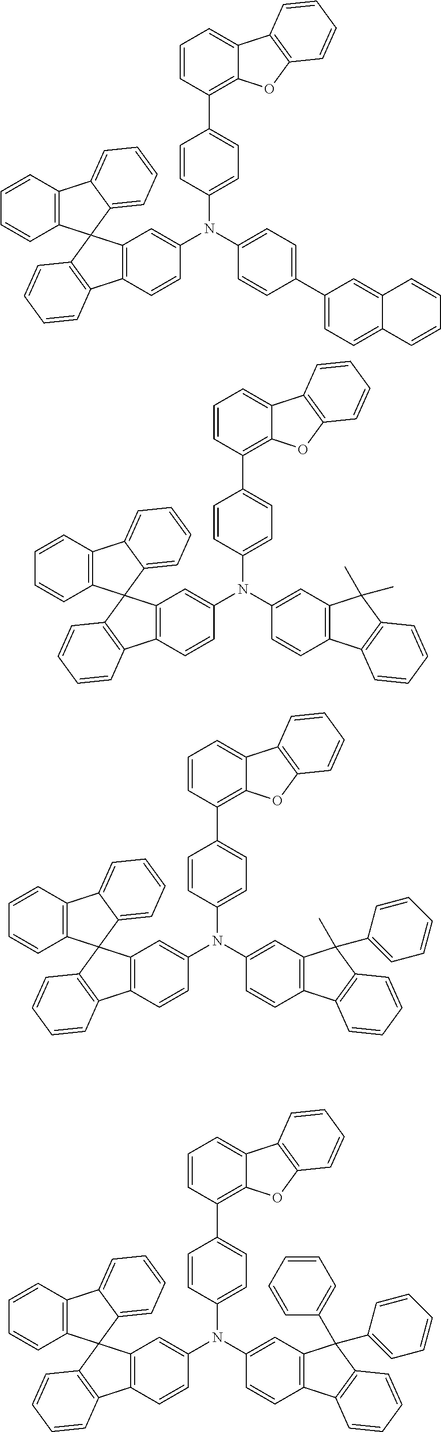

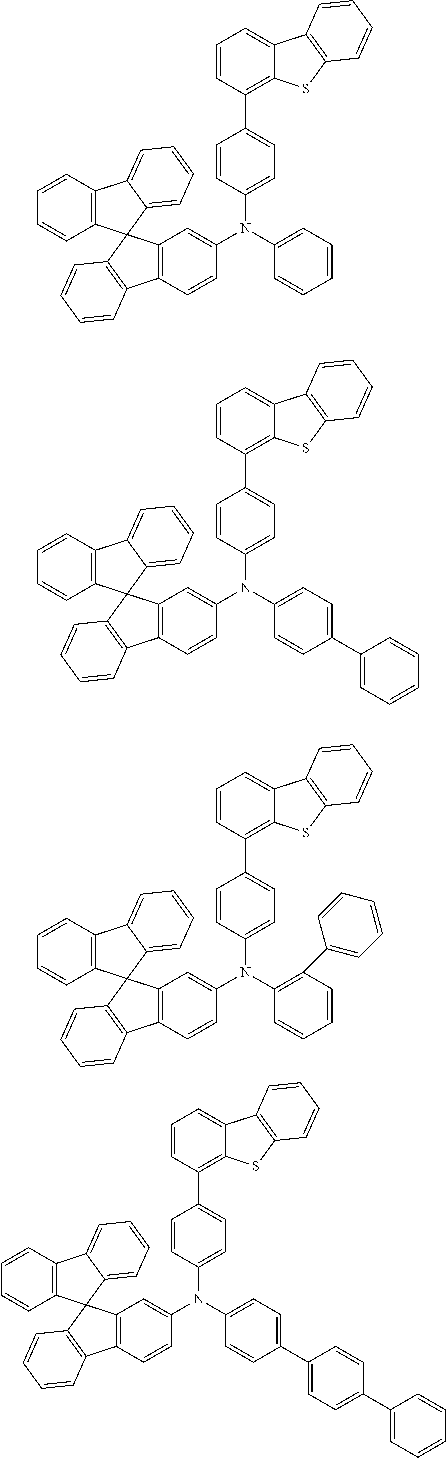

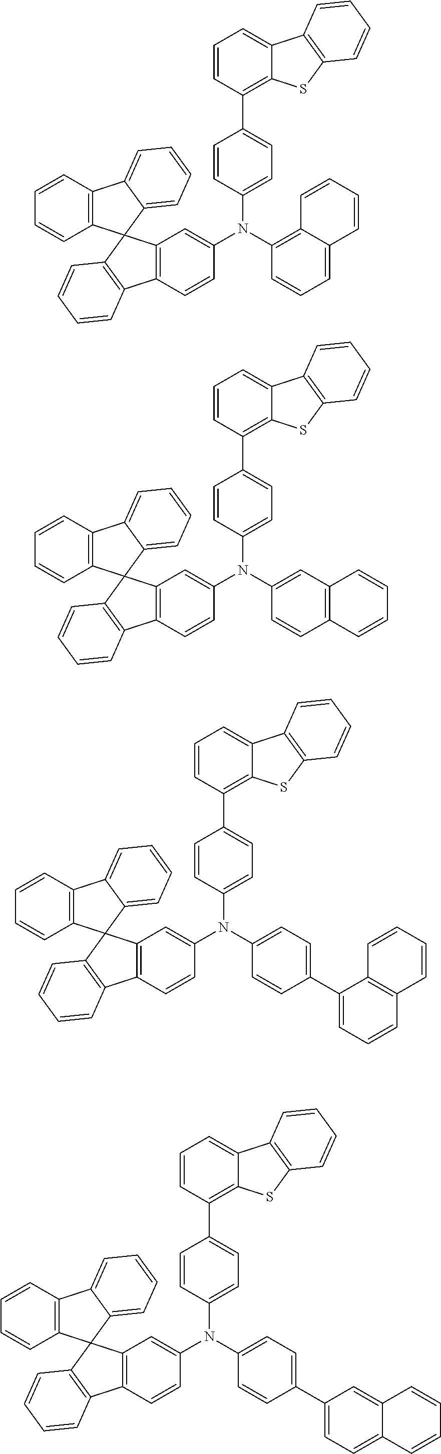 [SMILES: c1ccc2c(c1)-c1ccccc1C21c2ccccc2-c2ccc(N(c3ccc(-c4cccc5c4sc4ccccc45)cc3)c3cccc4ccccc34)cc21 ; c1ccc2c(c1)-c1ccccc1C21c2ccccc2-c2ccc(N(c3ccc(-c4cccc5c4sc4ccccc45)cc3)c3ccc4ccccc4c3)cc21 ; c1ccc2c(c1)-c1ccccc1C21c2ccccc2-c2ccc(N(c3ccc(-c4cccc5ccccc45)cc3)c3ccc(-c4cccc5c4sc4ccccc45)cc3)cc21 ; c1ccc2c(c1)-c1ccccc1C21c2ccccc2-c2ccc(N(c3ccc(-c4ccc5ccccc5c4)cc3)c3ccc(-c4cccc5c4sc4ccccc45)cc3)cc21]

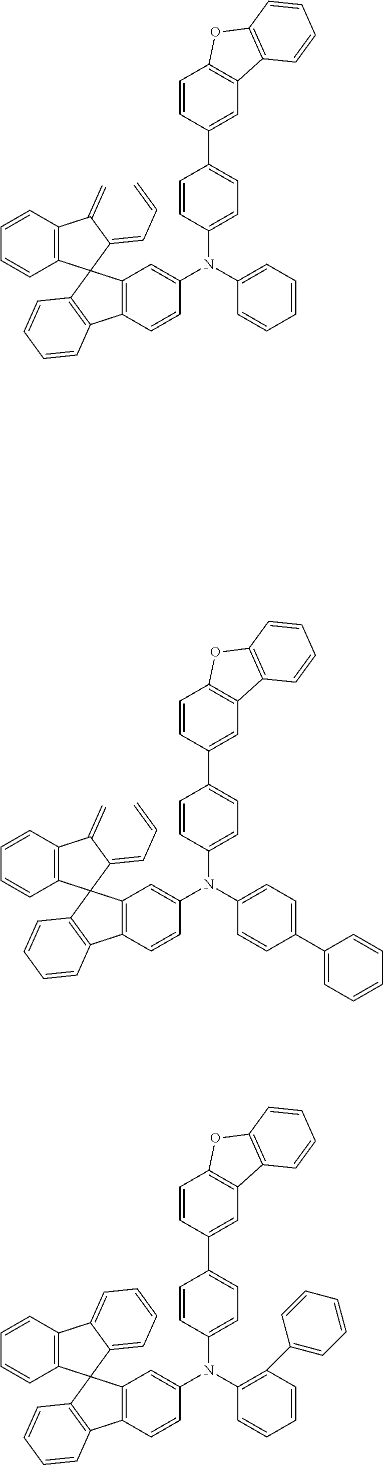 [SMILES: C=C/C=C1\C(=C)c2ccccc2C12c1ccccc1-c1ccc(N(c3ccccc3)c3ccc(-c4ccc5oc6ccccc6c5c4)cc3)cc12 ; C=C/C=C1\C(=C)c2ccccc2C12c1ccccc1-c1ccc(N(c3ccc(-c4ccccc4)cc3)c3ccc(-c4ccc5oc6ccccc6c5c4)cc3)cc12 ; c1ccc(-c2ccccc2N(c2ccc(-c3ccc4oc5ccccc5c4c3)cc2)c2ccc3c(c2)C2(c4ccccc4-c4ccccc42)c2ccccc2-3)cc1]

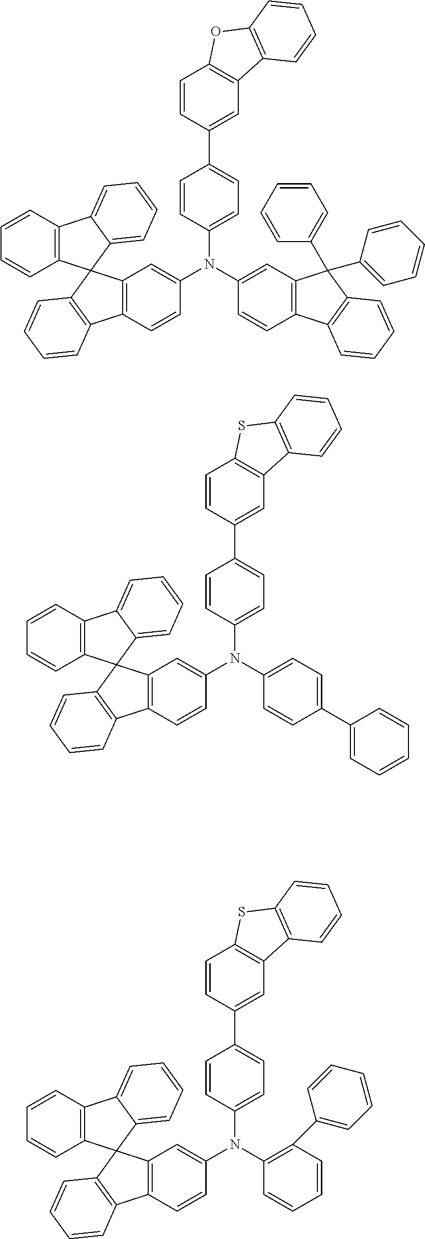

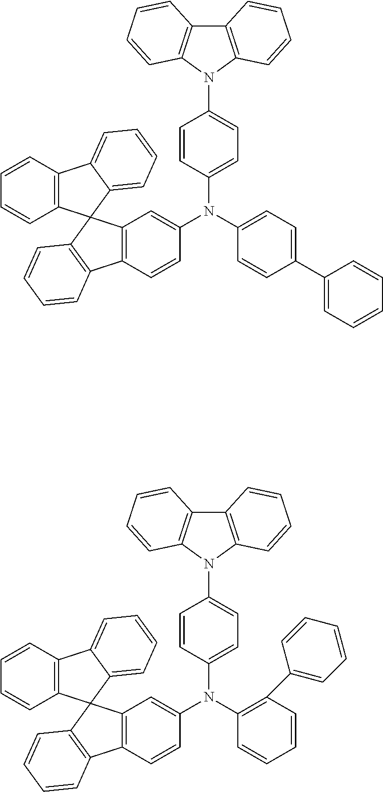 [SMILES: c1ccc(-c2ccc(N(c3ccc(-n4c5ccccc5c5ccccc54)cc3)c3ccc4c(c3)C3(c5ccccc5-c5ccccc53)c3ccccc3-4)cc2)cc1 ; c1ccc(-c2ccccc2N(c2ccc(-n3c4ccccc4c4ccccc43)cc2)c2ccc3c(c2)C2(c4ccccc4-c4ccccc42)c2ccccc2-3)cc1]

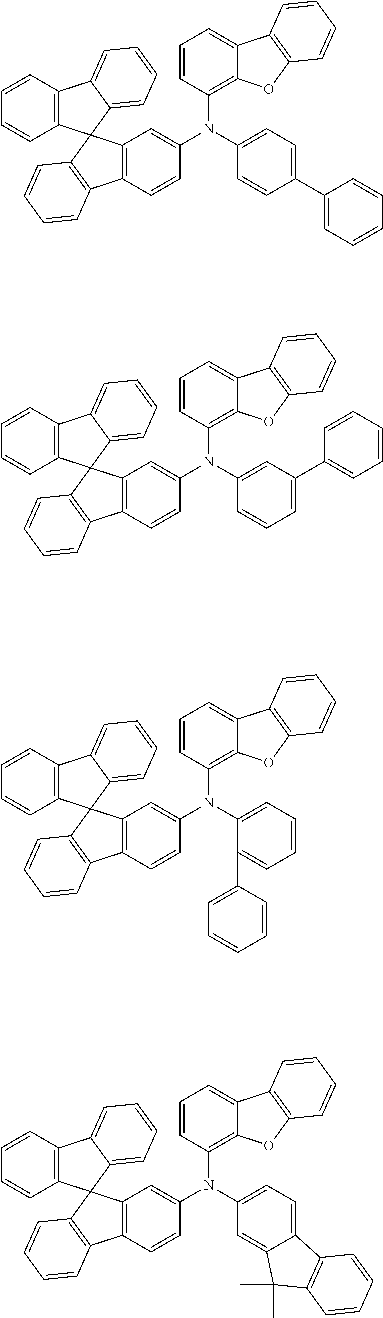 [SMILES: c1ccc(-c2ccc(N(c3ccc4c(c3)C3(c5ccccc5-c5ccccc53)c3ccccc3-4)c3cccc4c3oc3ccccc34)cc2)cc1 ; c1ccc(-c2cccc(N(c3ccc4c(c3)C3(c5ccccc5-c5ccccc53)c3ccccc3-4)c3cccc4c3oc3ccccc34)c2)cc1 ; c1ccc(-c2ccccc2N(c2ccc3c(c2)C2(c4ccccc4-c4ccccc42)c2ccccc2-3)c2cccc3c2oc2ccccc23)cc1 ; CC1(C)c2ccccc2-c2ccc(N(c3ccc4c(c3)C3(c5ccccc5-c5ccccc53)c3ccccc3-4)c3cccc4c3oc3ccccc34)cc21]

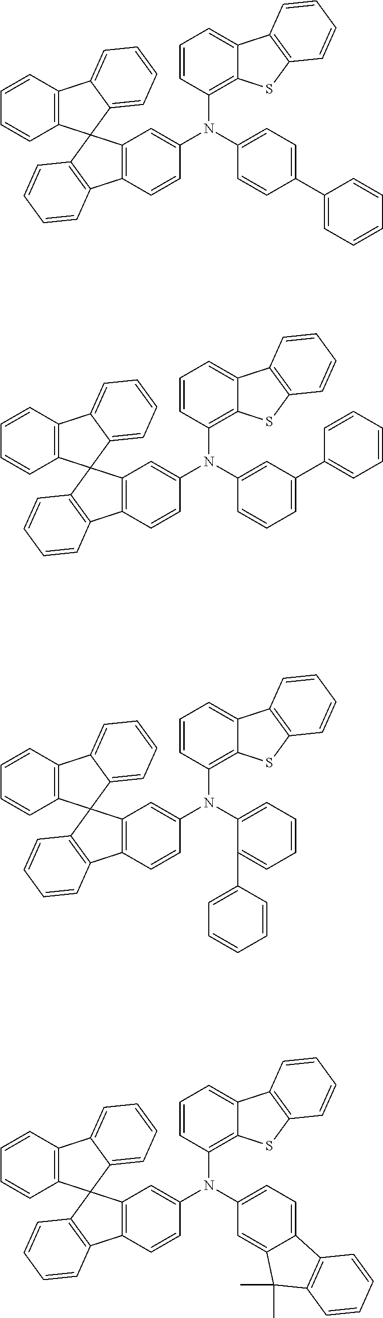 [SMILES: c1ccc(-c2ccc(N(c3ccc4c(c3)C3(c5ccccc5-c5ccccc53)c3ccccc3-4)c3cccc4c3sc3ccccc34)cc2)cc1 ; c1ccc(-c2cccc(N(c3ccc4c(c3)C3(c5ccccc5-c5ccccc53)c3ccccc3-4)c3cccc4c3sc3ccccc34)c2)cc1 ; c1ccc(-c2ccccc2N(c2ccc3c(c2)C2(c4ccccc4-c4ccccc42)c2ccccc2-3)c2cccc3c2sc2ccccc23)cc1 ; CC1(C)c2ccccc2-c2ccc(N(c3ccc4c(c3)C3(c5ccccc5-c5ccccc53)c3ccccc3-4)c3cccc4c3sc3ccccc34)cc21]

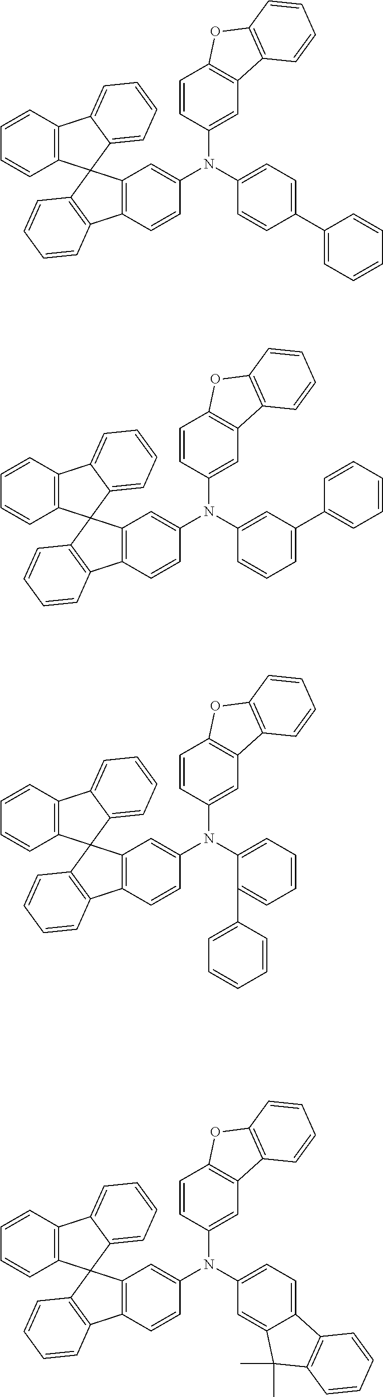 [SMILES: c1ccc(-c2ccc(N(c3ccc4c(c3)C3(c5ccccc5-c5ccccc53)c3ccccc3-4)c3ccc4oc5ccccc5c4c3)cc2)cc1 ; c1ccc(-c2cccc(N(c3ccc4c(c3)C3(c5ccccc5-c5ccccc53)c3ccccc3-4)c3ccc4oc5ccccc5c4c3)c2)cc1 ; c1ccc(-c2ccccc2N(c2ccc3c(c2)C2(c4ccccc4-c4ccccc42)c2ccccc2-3)c2ccc3oc4ccccc4c3c2)cc1 ; CC1(C)c2ccccc2-c2ccc(N(c3ccc4c(c3)C3(c5ccccc5-c5ccccc53)c3ccccc3-4)c3ccc4oc5ccccc5c4c3)cc21]

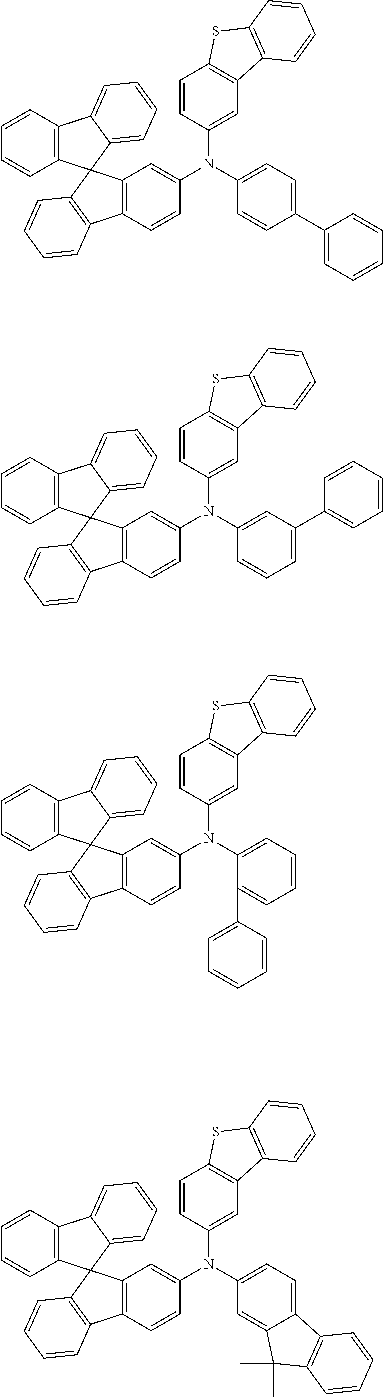 [SMILES: c1ccc(-c2ccc(N(c3ccc4c(c3)C3(c5ccccc5-c5ccccc53)c3ccccc3-4)c3ccc4sc5ccccc5c4c3)cc2)cc1 ; c1ccc(-c2cccc(N(c3ccc4c(c3)C3(c5ccccc5-c5ccccc53)c3ccccc3-4)c3ccc4sc5ccccc5c4c3)c2)cc1 ; c1ccc(-c2ccccc2N(c2ccc3c(c2)C2(c4ccccc4-c4ccccc42)c2ccccc2-3)c2ccc3sc4ccccc4c3c2)cc1 ; CC1(C)c2ccccc2-c2ccc(N(c3ccc4c(c3)C3(c5ccccc5-c5ccccc53)c3ccccc3-4)c3ccc4sc5ccccc5c4c3)cc21]

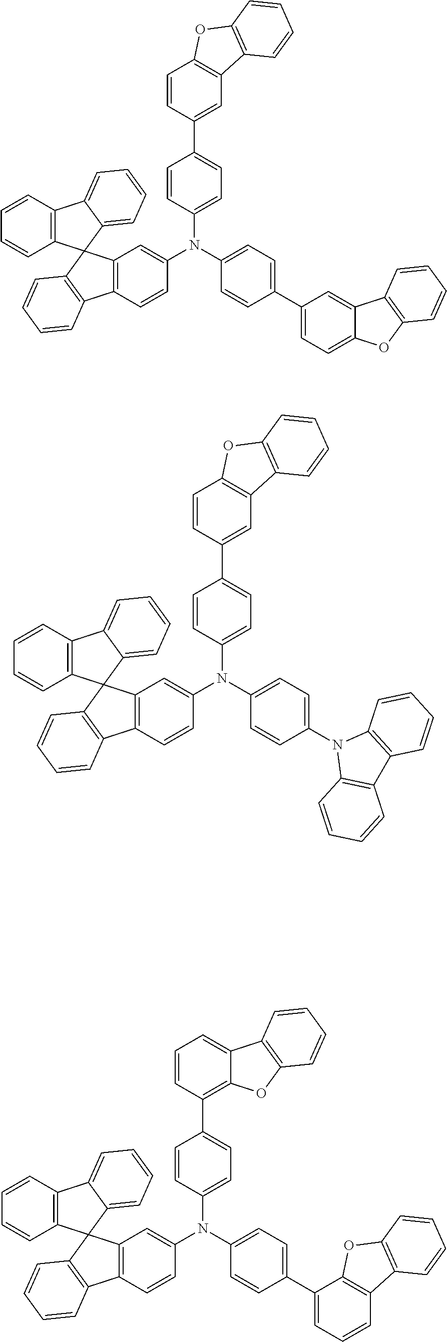 [SMILES: c1ccc2c(c1)-c1ccccc1C21c2ccccc2-c2ccc(N(c3ccc(-c4ccc5oc6ccccc6c5c4)cc3)c3ccc(-c4ccc5oc6ccccc6c5c4)cc3)cc21 ; c1ccc2c(c1)-c1ccccc1C21c2ccccc2-c2ccc(N(c3ccc(-c4ccc5oc6ccccc6c5c4)cc3)c3ccc(-n4c5ccccc5c5ccccc54)cc3)cc21 ; c1ccc2c(c1)-c1ccccc1C21c2ccccc2-c2ccc(N(c3ccc(-c4cccc5c4oc4ccccc45)cc3)c3ccc(-c4cccc5c4oc4ccccc45)cc3)cc21]

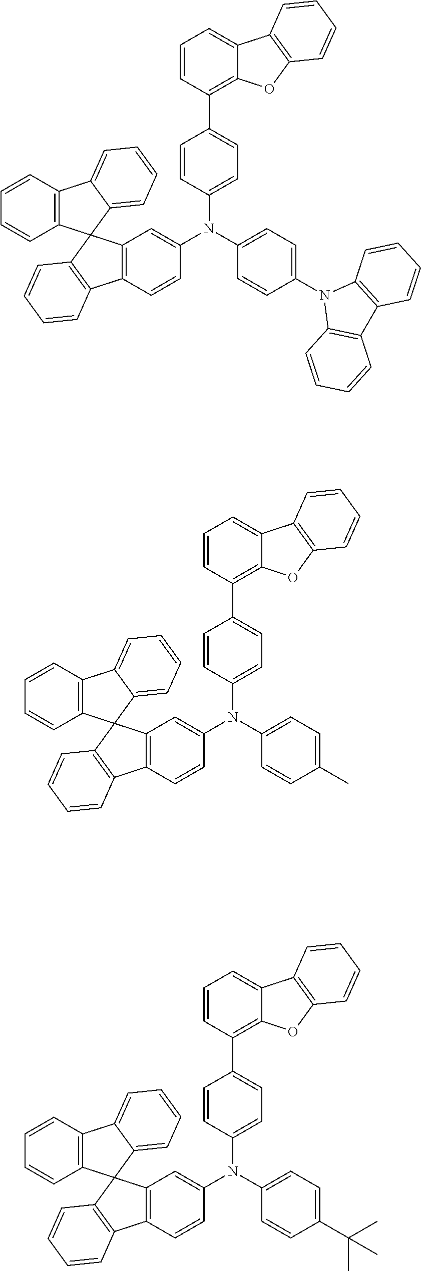 [SMILES: c1ccc2c(c1)-c1ccccc1C21c2ccccc2-c2ccc(N(c3ccc(-c4cccc5c4oc4ccccc45)cc3)c3ccc(-n4c5ccccc5c5ccccc54)cc3)cc21 ; Cc1ccc(N(c2ccc(-c3cccc4c3oc3ccccc34)cc2)c2ccc3c(c2)C2(c4ccccc4-c4ccccc42)c2ccccc2-3)cc1 ; CC(C)(C)c1ccc(N(c2ccc(-c3cccc4c3oc3ccccc34)cc2)c2ccc3c(c2)C2(c4ccccc4-c4ccccc42)c2ccccc2-3)cc1]

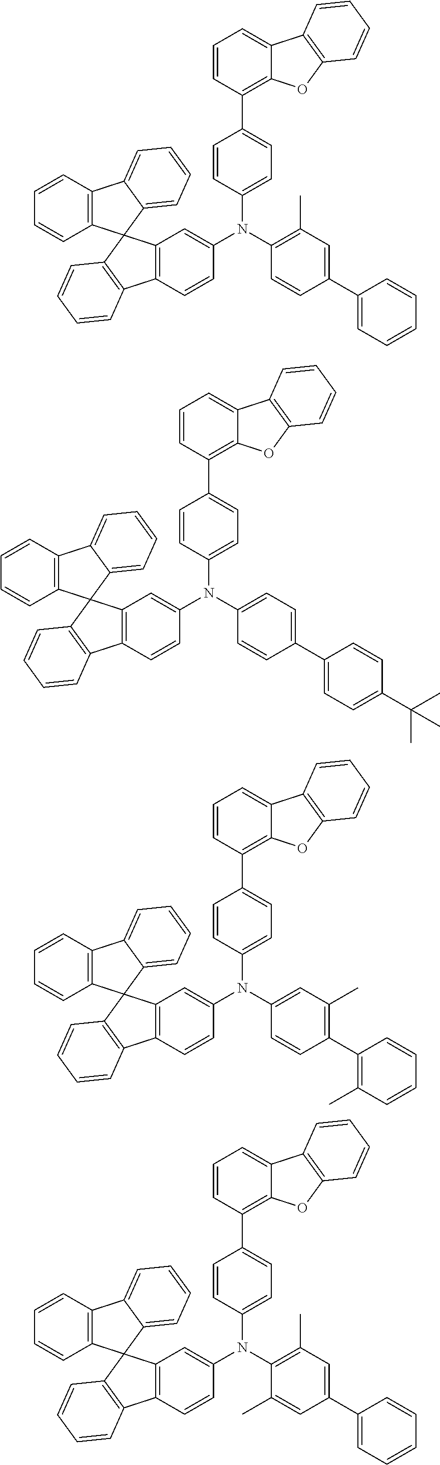

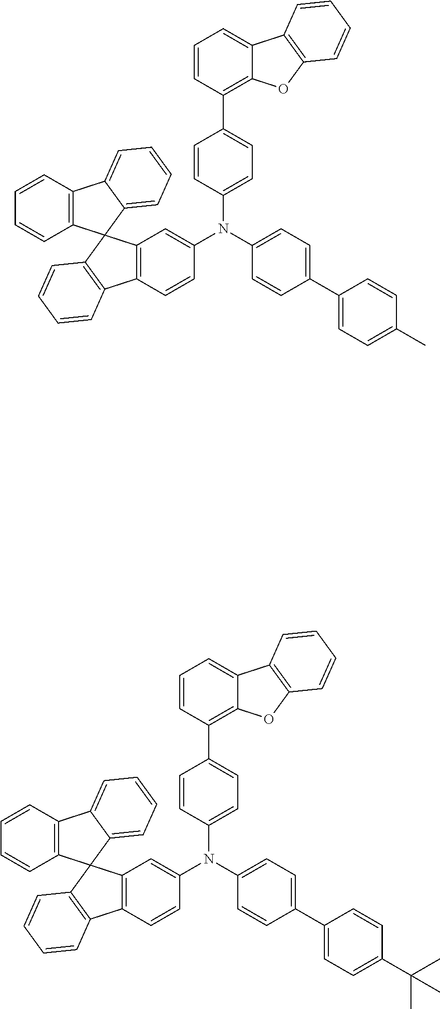 [SMILES: Cc1ccc(-c2ccc(N(c3ccc(-c4cccc5c4oc4ccccc45)cc3)c3ccc4c(c3)C3(c5ccccc5-c5ccccc53)c3ccccc3-4)cc2)cc1 ; CC(C)(C)c1ccc(-c2ccc(N(c3ccc(-c4cccc5c4oc4ccccc45)cc3)c3ccc4c(c3)C3(c5ccccc5-c5ccccc53)c3ccccc3-4)cc2)cc1]

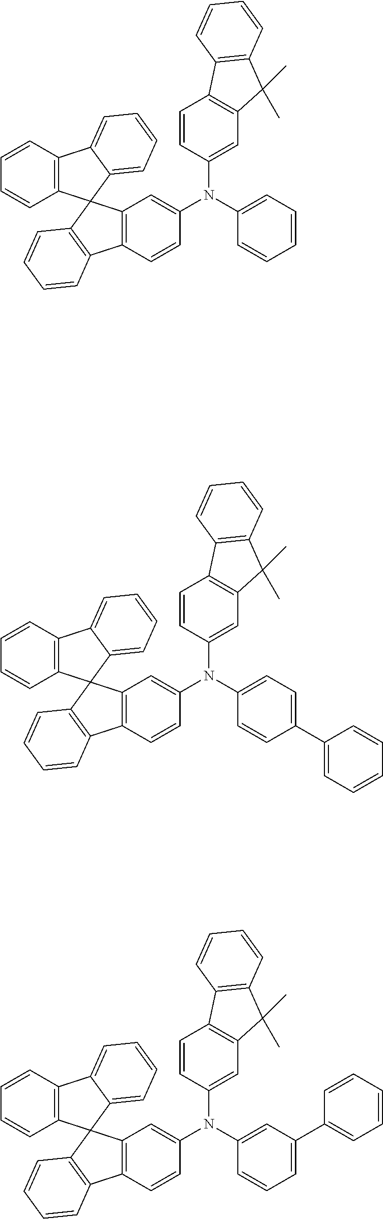 [SMILES: CC1(C)c2ccccc2-c2ccc(N(c3ccccc3)c3ccc4c(c3)C3(c5ccccc5-c5ccccc53)c3ccccc3-4)cc21 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; CC1(C)c2ccccc2-c2ccc(N(c3cccc(-c4ccccc4)c3)c3ccc4c(c3)C3(c5ccccc5-c5ccccc53)c3ccccc3-4)cc21]

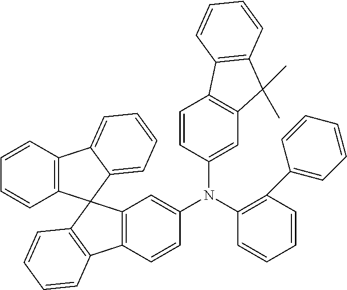 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

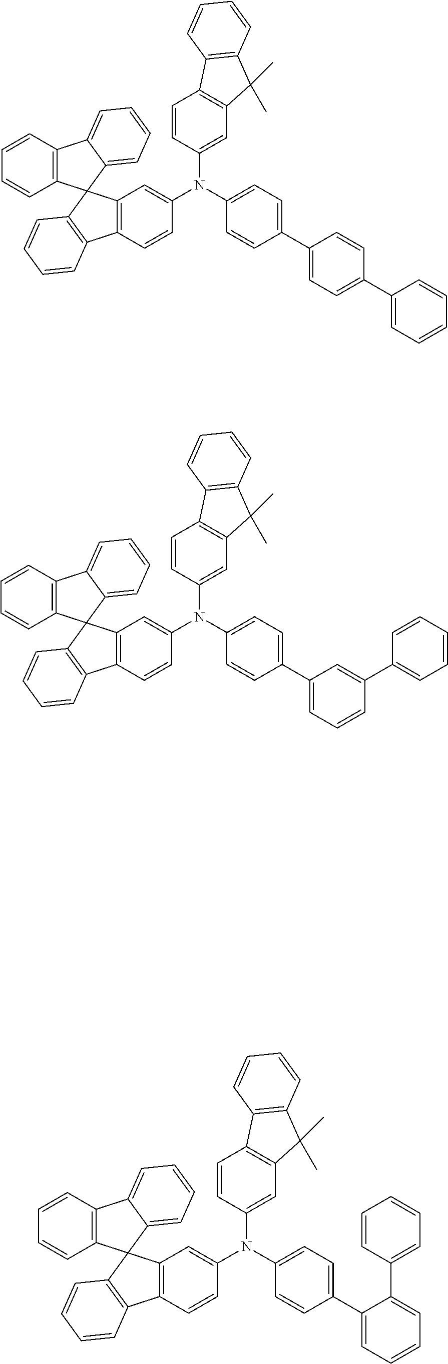 [SMILES: CC1(C)c2ccccc2-c2ccc(N(c3ccc(-c4ccc(-c5ccccc5)cc4)cc3)c3ccc4c(c3)C3(c5ccccc5-c5ccccc53)c3ccccc3-4)cc21 ; CC1(C)c2ccccc2-c2ccc(N(c3ccc(-c4cccc(-c5ccccc5)c4)cc3)c3ccc4c(c3)C3(c5ccccc5-c5ccccc53)c3ccccc3-4)cc21 ; CC1(C)c2ccccc2-c2ccc(N(c3ccc(-c4ccccc4-c4ccccc4)cc3)c3ccc4c(c3)C3(c5ccccc5-c5ccccc53)c3ccccc3-4)cc21]

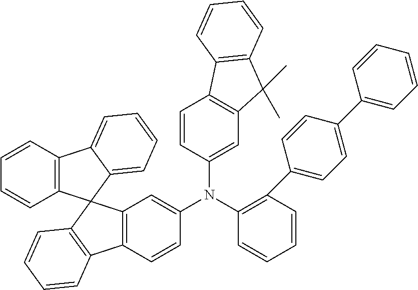 [SMILES: CC1(C)c2ccccc2-c2ccc(N(c3ccc4c(c3)C3(c5ccccc5-c5ccccc53)c3ccccc3-4)c3ccccc3-c3ccc(-c4ccccc4)cc3)cc21]

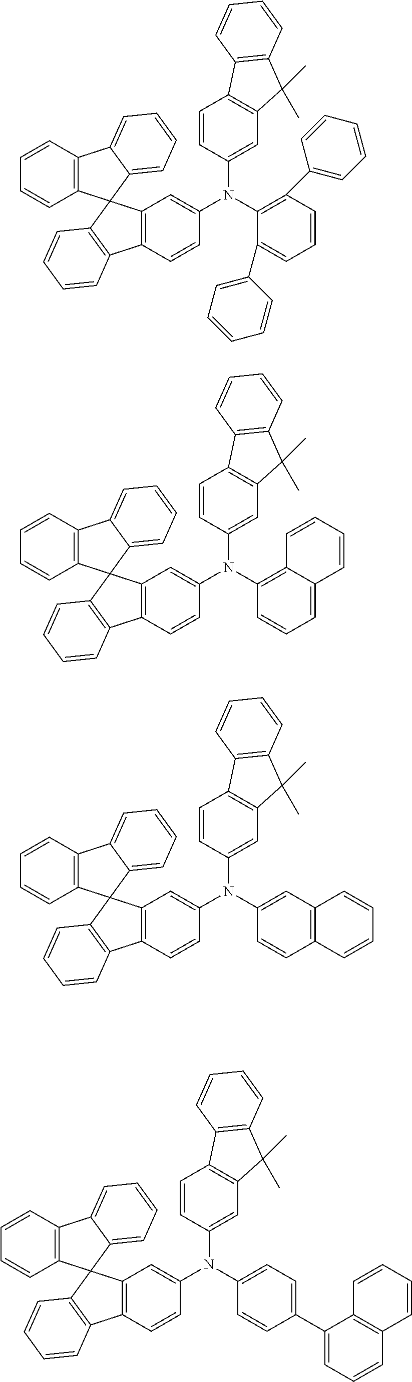

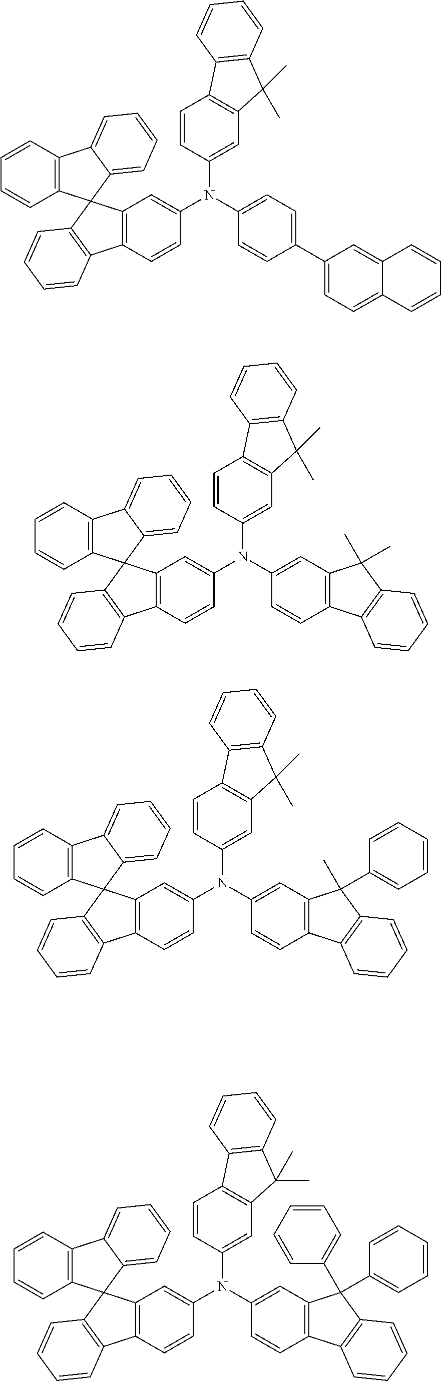 [SMILES: CC1(C)c2ccccc2-c2ccc(N(c3ccc(-c4ccc5ccccc5c4)cc3)c3ccc4c(c3)C3(c5ccccc5-c5ccccc53)c3ccccc3-4)cc21 ; CC1(C)c2ccccc2-c2ccc(N(c3ccc4c(c3)C(C)(C)c3ccccc3-4)c3ccc4c(c3)C3(c5ccccc5-c5ccccc53)c3ccccc3-4)cc21 ; CC1(C)c2ccccc2-c2ccc(N(c3ccc4c(c3)C(C)(c3ccccc3)c3ccccc3-4)c3ccc4c(c3)C3(c5ccccc5-c5ccccc53)c3ccccc3-4)cc21 ; CC1(C)c2ccccc2-c2ccc(N(c3ccc4c(c3)C(c3ccccc3)(c3ccccc3)c3ccccc3-4)c3ccc4c(c3)C3(c5ccccc5-c5ccccc53)c3ccccc3-4)cc21]

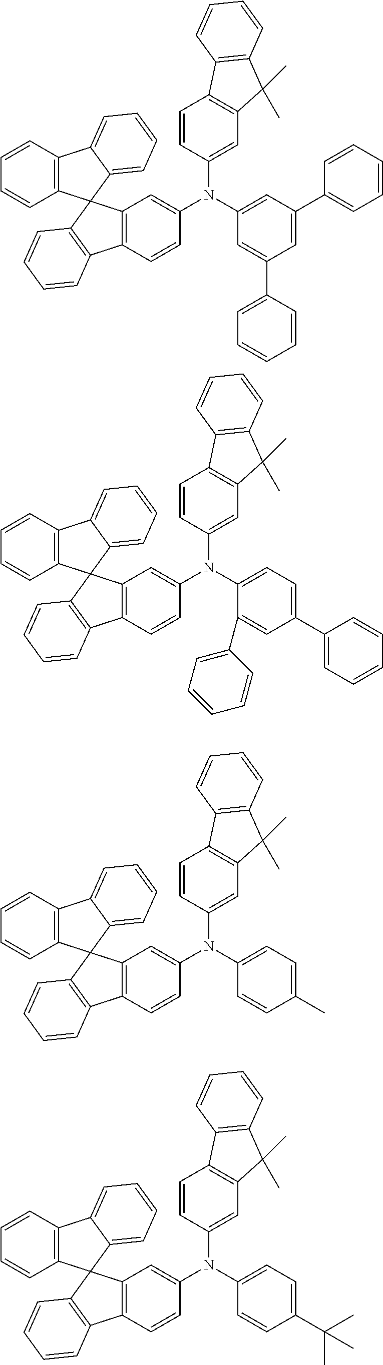

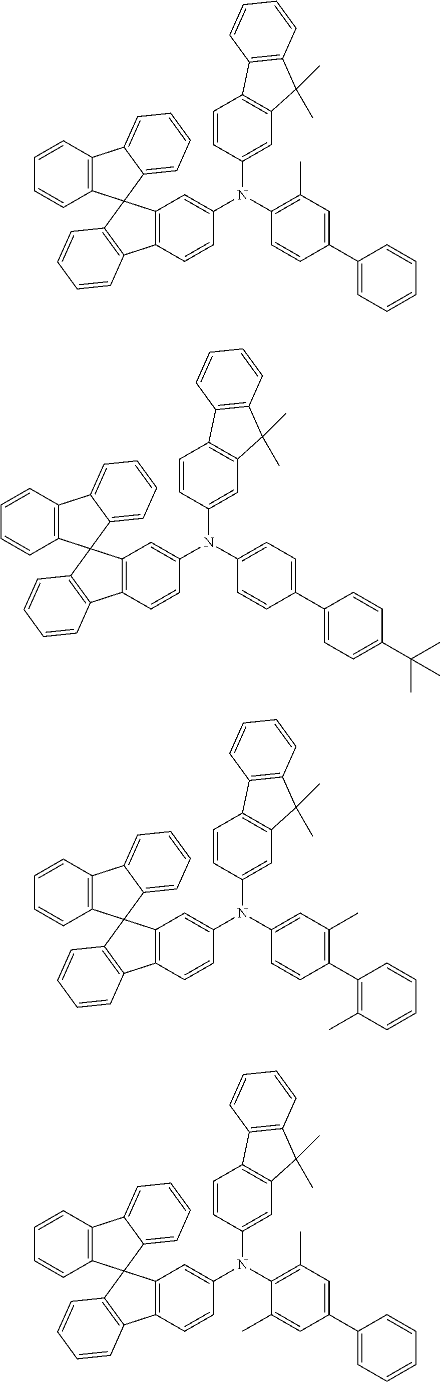 [SMILES: Cc1cc(-c2ccccc2)ccc1N(c1ccc2c(c1)C(C)(C)c1ccccc1-2)c1ccc2c(c1)C1(c3ccccc3-c3ccccc31)c1ccccc1-2 ; CC(C)(C)c1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; Cc1ccccc1-c1ccc(N(c2ccc3c(c2)C(C)(C)c2ccccc2-3)c2ccc3c(c2)C2(c4ccccc4-c4ccccc42)c2ccccc2-3)cc1C ; Cc1cc(-c2ccccc2)cc(C)c1N(c1ccc2c(c1)C(C)(C)c1ccccc1-2)c1ccc2c(c1)C1(c3ccccc3-c3ccccc31)c1ccccc1-2]

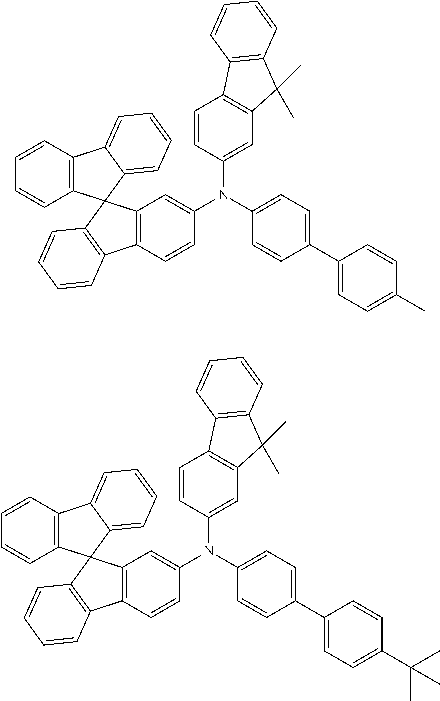 [SMILES: Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; CC(C)(C)c1ccc(-c2ccc(N(c3ccc4c(c3)C(C)(C)c3ccccc3-4)c3ccc4c(c3)C3(c5ccccc5-c5ccccc53)c3ccccc3-4)cc2)cc1]

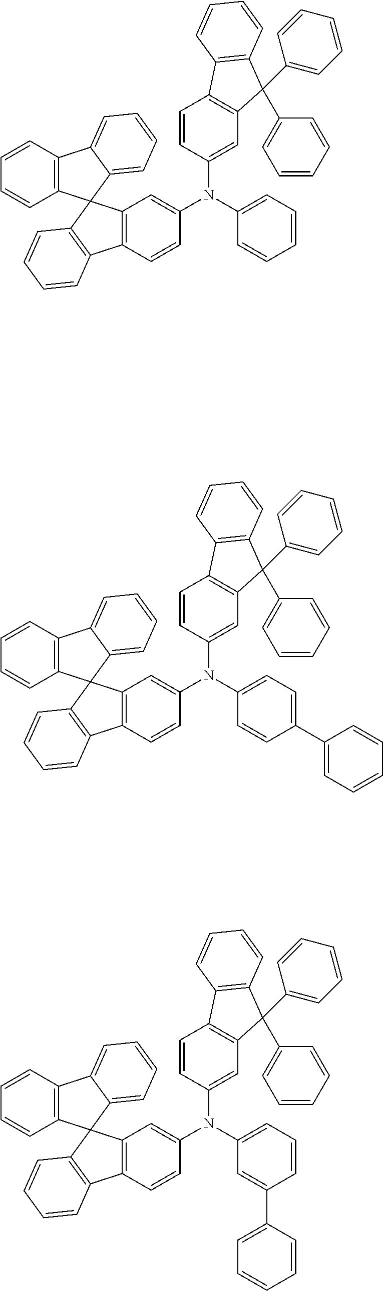 [SMILES: c1ccc(N(c2ccc3c(c2)C(c2ccccc2)(c2ccccc2)c2ccccc2-3)c2ccc3c(c2)C2(c4ccccc4-c4ccccc42)c2ccccc2-3)cc1 ; c1ccc(-c2ccc(N(c3ccc4c(c3)C(c3ccccc3)(c3ccccc3)c3ccccc3-4)c3ccc4c(c3)C3(c5ccccc5-c5ccccc53)c3ccccc3-4)cc2)cc1 ; c1ccc(-c2cccc(N(c3ccc4c(c3)C(c3ccccc3)(c3ccccc3)c3ccccc3-4)c3ccc4c(c3)C3(c5ccccc5-c5ccccc53)c3ccccc3-4)c2)cc1]

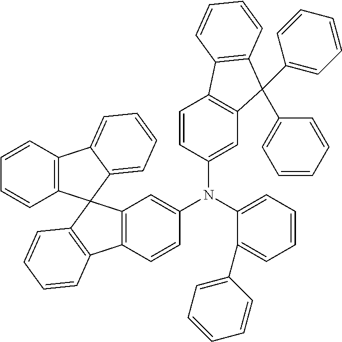 [SMILES: c1ccc(-c2ccccc2N(c2ccc3c(c2)C(c2ccccc2)(c2ccccc2)c2ccccc2-3)c2ccc3c(c2)C2(c4ccccc4-c4ccccc42)c2ccccc2-3)cc1]

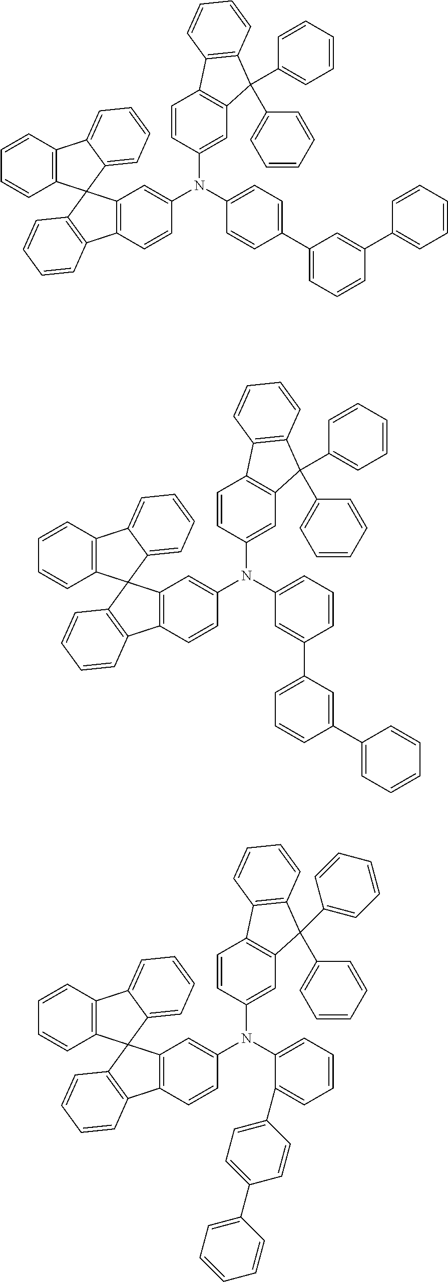 [SMILES: c1ccc(-c2cccc(-c3ccc(N(c4ccc5c(c4)C(c4ccccc4)(c4ccccc4)c4ccccc4-5)c4ccc5c(c4)C4(c6ccccc6-c6ccccc64)c4ccccc4-5)cc3)c2)cc1 ; c1ccc(-c2cccc(-c3cccc(N(c4ccc5c(c4)C(c4ccccc4)(c4ccccc4)c4ccccc4-5)c4ccc5c(c4)C4(c6ccccc6-c6ccccc64)c4ccccc4-5)c3)c2)cc1 ; c1ccc(-c2ccc(-c3ccccc3N(c3ccc4c(c3)C(c3ccccc3)(c3ccccc3)c3ccccc3-4)c3ccc4c(c3)C3(c5ccccc5-c5ccccc53)c3ccccc3-4)cc2)cc1]

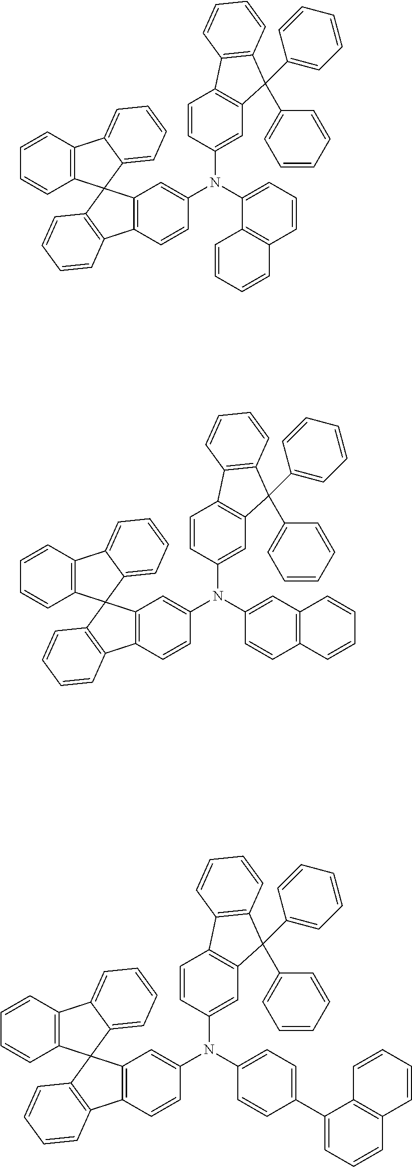 [SMILES: c1ccc(C2(c3ccccc3)c3ccccc3-c3ccc(N(c4ccc5c(c4)C4(c6ccccc6-c6ccccc64)c4ccccc4-5)c4cccc5ccccc45)cc32)cc1 ; c1ccc(C2(c3ccccc3)c3ccccc3-c3ccc(N(c4ccc5c(c4)C4(c6ccccc6-c6ccccc64)c4ccccc4-5)c4ccc5ccccc5c4)cc32)cc1 ; c1ccc(C2(c3ccccc3)c3ccccc3-c3ccc(N(c4ccc(-c5cccc6ccccc56)cc4)c4ccc5c(c4)C4(c6ccccc6-c6ccccc64)c4ccccc4-5)cc32)cc1]

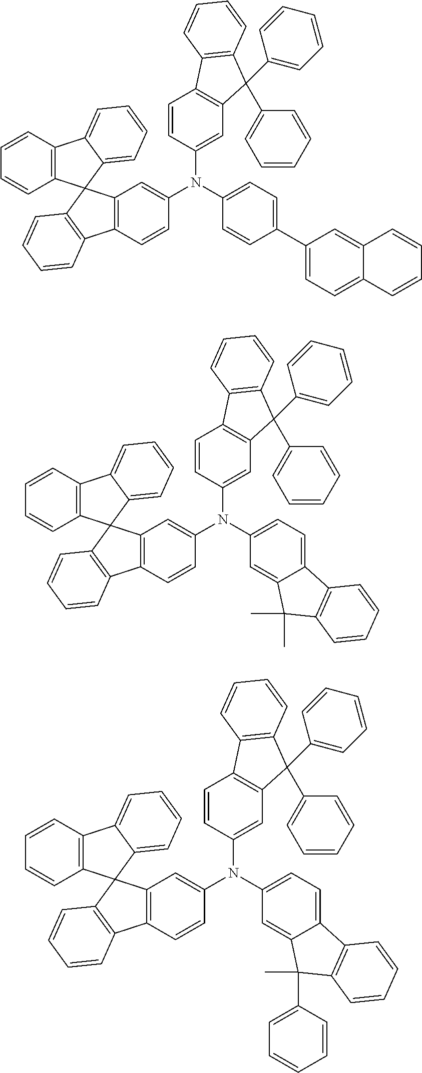

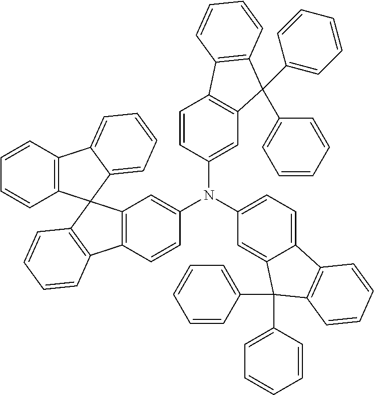 [SMILES: c1ccc(C2(c3ccccc3)c3ccccc3-c3ccc(N(c4ccc5c(c4)C(c4ccccc4)(c4ccccc4)c4ccccc4-5)c4ccc5c(c4)C4(c6ccccc6-c6ccccc64)c4ccccc4-5)cc32)cc1]

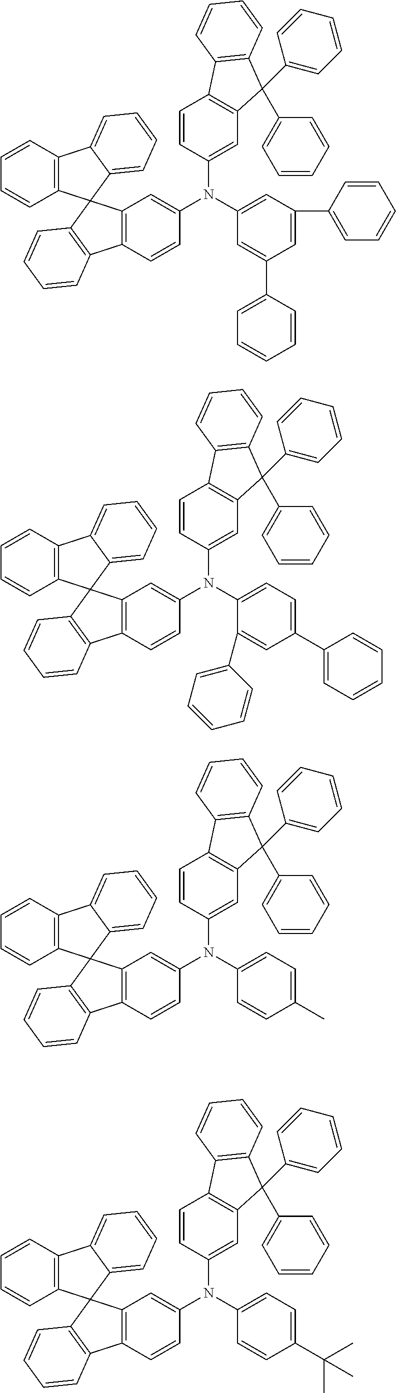

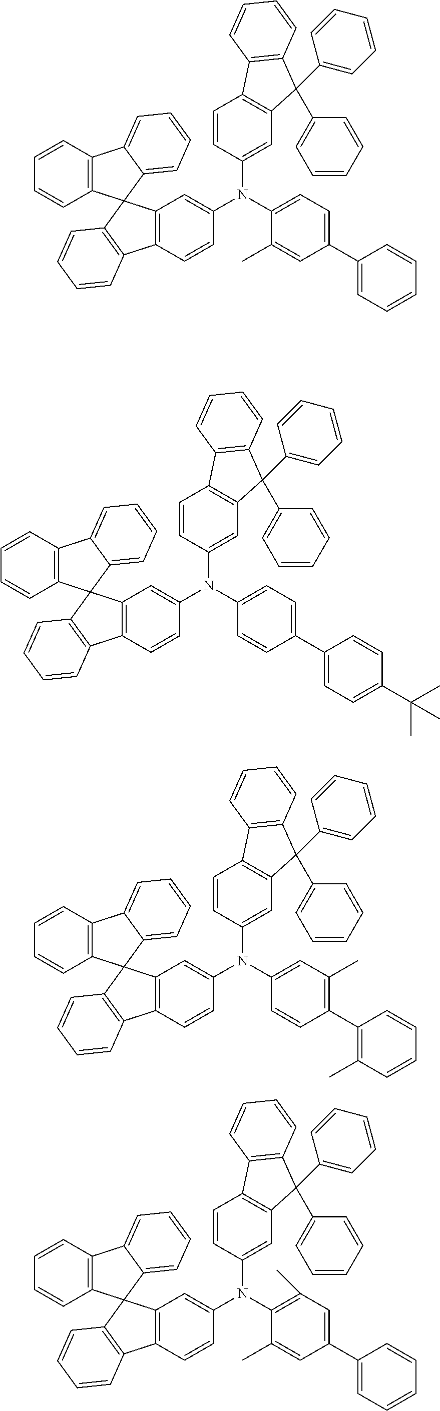

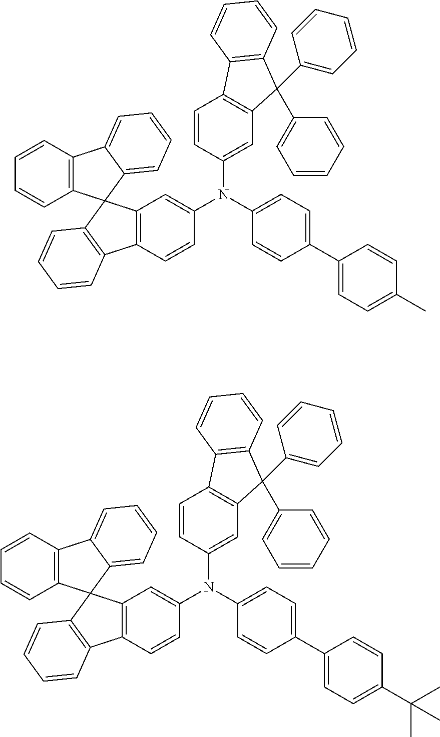 [SMILES: Cc1ccc(-c2ccc(N(c3ccc4c(c3)C(c3ccccc3)(c3ccccc3)c3ccccc3-4)c3ccc4c(c3)C3(c5ccccc5-c5ccccc53)c3ccccc3-4)cc2)cc1 ; CC(C)(C)c1ccc(-c2ccc(N(c3ccc4c(c3)C(c3ccccc3)(c3ccccc3)c3ccccc3-4)c3ccc4c(c3)C3(c5ccccc5-c5ccccc53)c3ccccc3-4)cc2)cc1]

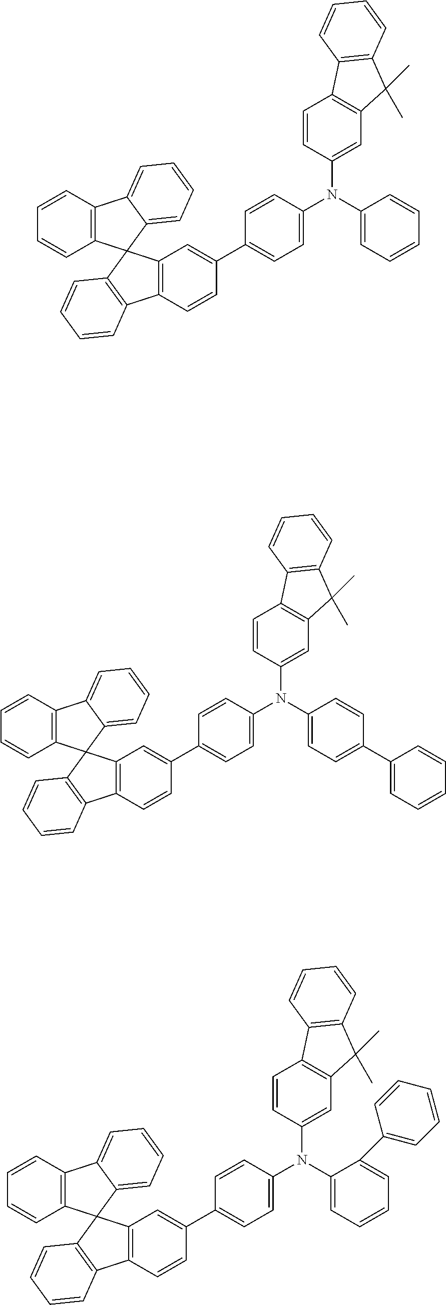 [SMILES: CC1(C)c2ccccc2-c2ccc(N(c3ccccc3)c3ccc(-c4ccc5c(c4)C4(c6ccccc6-c6ccccc64)c4ccccc4-5)cc3)cc21 ; CC1(C)c2ccccc2-c2ccc(N(c3ccc(-c4ccccc4)cc3)c3ccc(-c4ccc5c(c4)C4(c6ccccc6-c6ccccc64)c4ccccc4-5)cc3)cc21 ; CC1(C)c2ccccc2-c2ccc(N(c3ccc(-c4ccc5c(c4)C4(c6ccccc6-c6ccccc64)c4ccccc4-5)cc3)c3ccccc3-c3ccccc3)cc21]

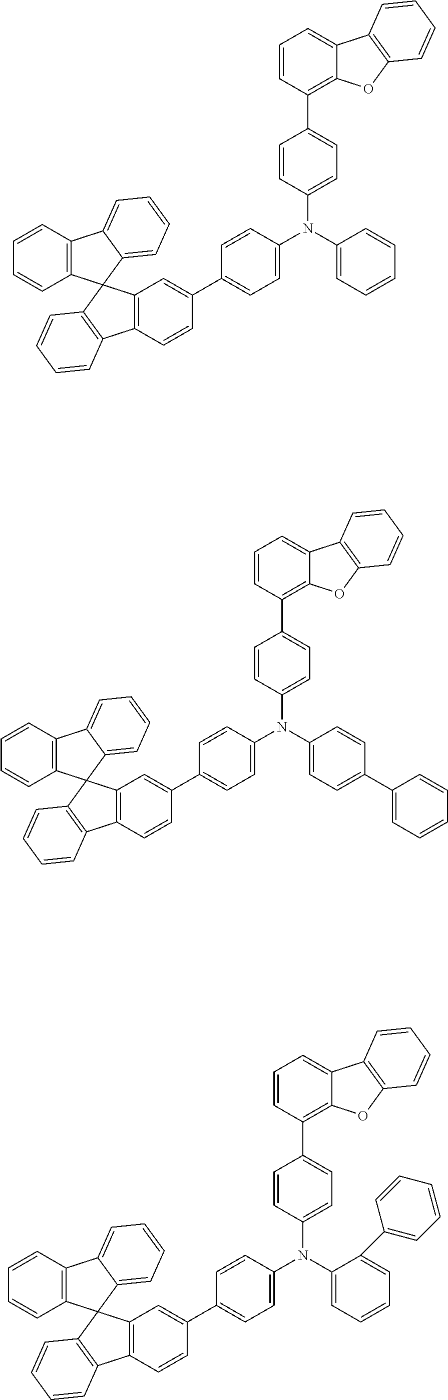 [SMILES: c1ccc(N(c2ccc(-c3ccc4c(c3)C3(c5ccccc5-c5ccccc53)c3ccccc3-4)cc2)c2ccc(-c3cccc4c3oc3ccccc34)cc2)cc1 ; c1ccc(-c2ccc(N(c3ccc(-c4ccc5c(c4)C4(c6ccccc6-c6ccccc64)c4ccccc4-5)cc3)c3ccc(-c4cccc5c4oc4ccccc45)cc3)cc2)cc1 ; c1ccc(-c2ccccc2N(c2ccc(-c3ccc4c(c3)C3(c5ccccc5-c5ccccc53)c3ccccc3-4)cc2)c2ccc(-c3cccc4c3oc3ccccc34)cc2)cc1]

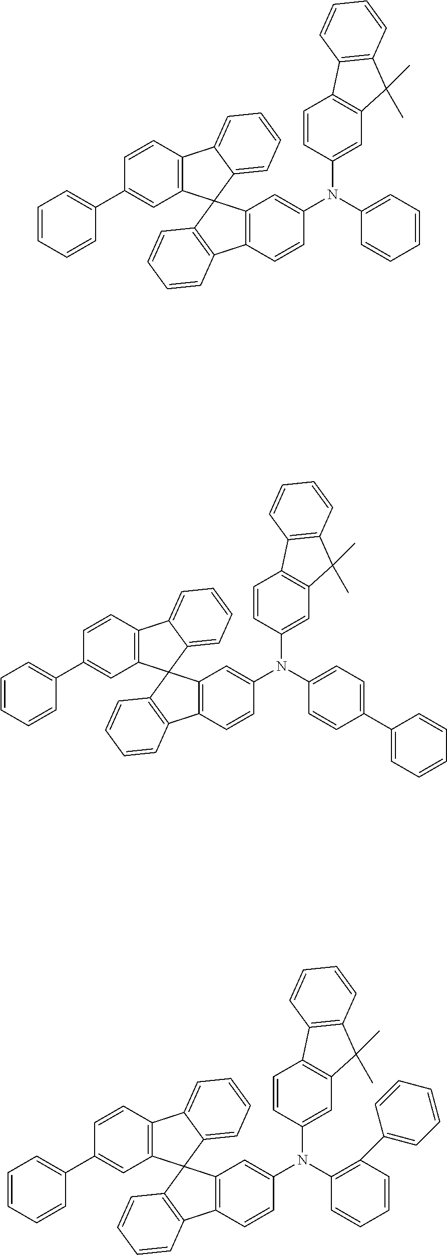 [SMILES: CC1(C)c2ccccc2-c2ccc(N(c3ccccc3)c3ccc4c(c3)C3(c5ccccc5-c5ccc(-c6ccccc6)cc53)c3ccccc3-4)cc21 ; CC1(C)c2ccccc2-c2ccc(N(c3ccc(-c4ccccc4)cc3)c3ccc4c(c3)C3(c5ccccc5-c5ccc(-c6ccccc6)cc53)c3ccccc3-4)cc21 ; CC1(C)c2ccccc2-c2ccc(N(c3ccc4c(c3)C3(c5ccccc5-c5ccc(-c6ccccc6)cc53)c3ccccc3-4)c3ccccc3-c3ccccc3)cc21]

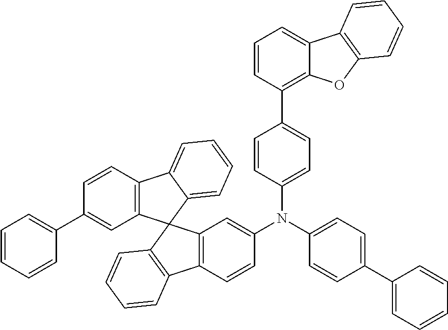 [SMILES: c1ccc(-c2ccc(N(c3ccc(-c4cccc5c4oc4ccccc45)cc3)c3ccc4c(c3)C3(c5ccccc5-c5ccc(-c6ccccc6)cc53)c3ccccc3-4)cc2)cc1]

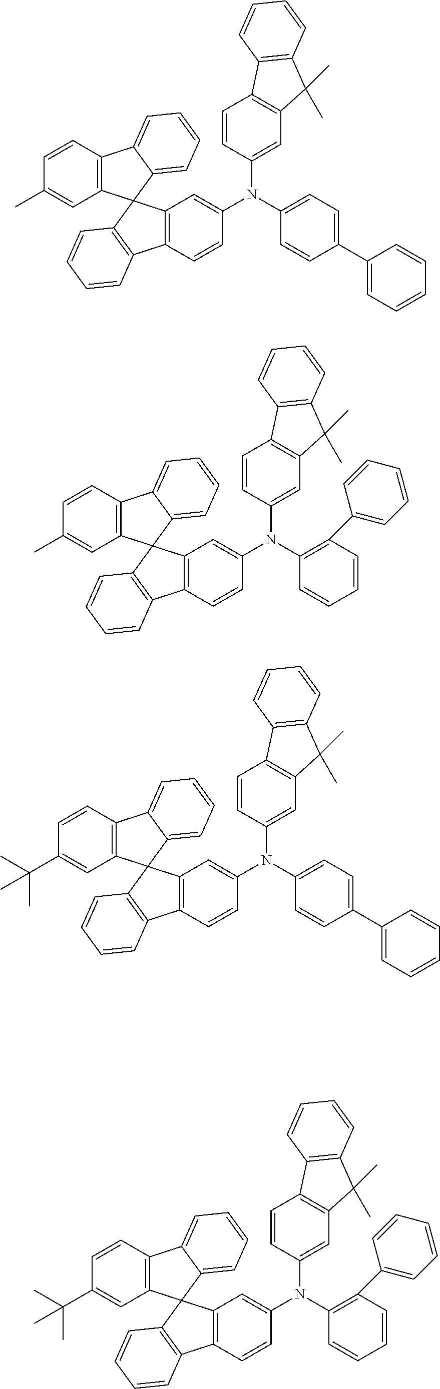 [SMILES: Cc1ccc2c(c1)C1(c3ccccc3-2)c2ccccc2-c2ccc(N(c3ccc(-c4ccccc4)cc3)c3ccc4c(c3)C(C)(C)c3ccccc3-4)cc21 ; Cc1ccc2c(c1)C1(c3ccccc3-2)c2ccccc2-c2ccc(N(c3ccc4c(c3)C(C)(C)c3ccccc3-4)c3ccccc3-c3ccccc3)cc21 ; CC(C)(C)c1ccc2c(c1)C1(c3ccccc3-c3ccc(N(c4ccc(-c5ccccc5)cc4)c4ccc5c(c4)C(C)(C)c4ccccc4-5)cc31)c1ccccc1-2 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1ccccc1-2]

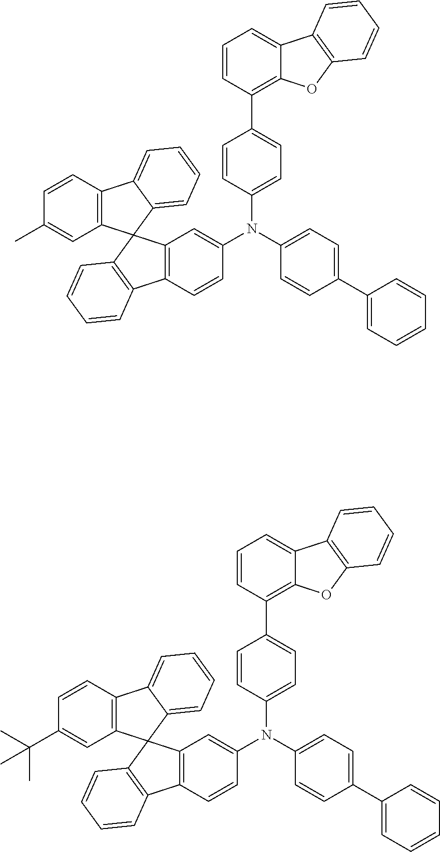 [SMILES: Cc1ccc2c(c1)C1(c3ccccc3-2)c2ccccc2-c2ccc(N(c3ccc(-c4ccccc4)cc3)c3ccc(-c4cccc5c4oc4ccccc45)cc3)cc21 ; CC(C)(C)c1ccc2c(c1)C1(c3ccccc3-c3ccc(N(c4ccc(-c5ccccc5)cc4)c4ccc(-c5cccc6c5oc5ccccc56)cc4)cc31)c1ccccc1-2]

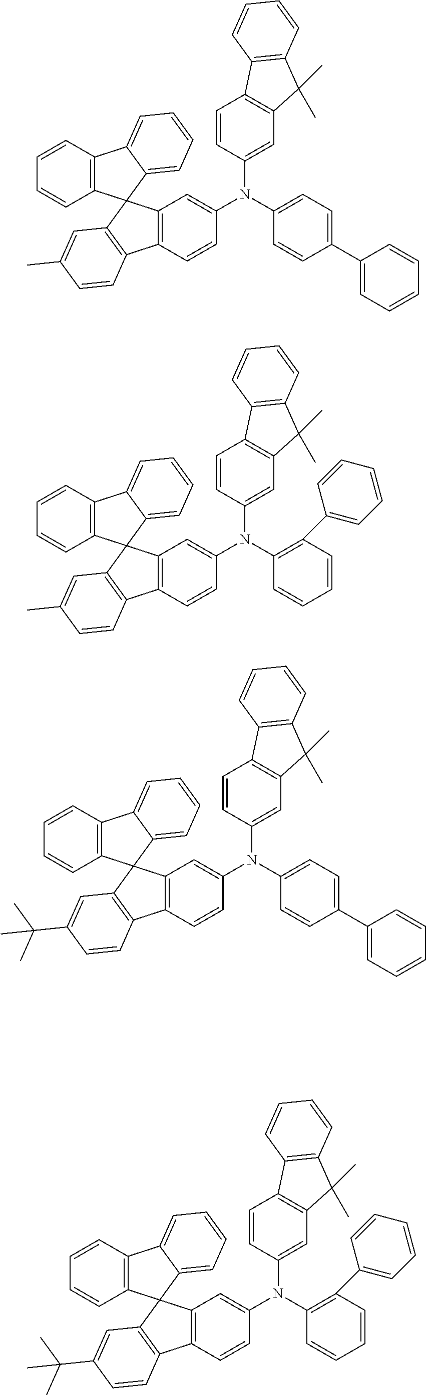 [SMILES: Cc1ccc2c(c1)C1(c3ccccc3-c3ccccc31)c1cc(N(c3ccc(-c4ccccc4)cc3)c3ccc4c(c3)C(C)(C)c3ccccc3-4)ccc1-2 ; Cc1ccc2c(c1)C1(c3ccccc3-c3ccccc31)c1cc(N(c3ccc4c(c3)C(C)(C)c3ccccc3-4)c3ccccc3-c3ccccc3)ccc1-2 ; CC(C)(C)c1ccc2c(c1)C1(c3ccccc3-c3ccccc31)c1cc(N(c3ccc(-c4ccccc4)cc3)c3ccc4c(c3)C(C)(C)c3ccccc3-4)ccc1-2 ; CC(C)(C)c1ccc2c(c1)C1(c3ccccc3-c3ccccc31)c1cc(N(c3ccc4c(c3)C(C)(C)c3ccccc3-4)c3ccccc3-c3ccccc3)ccc1-2]

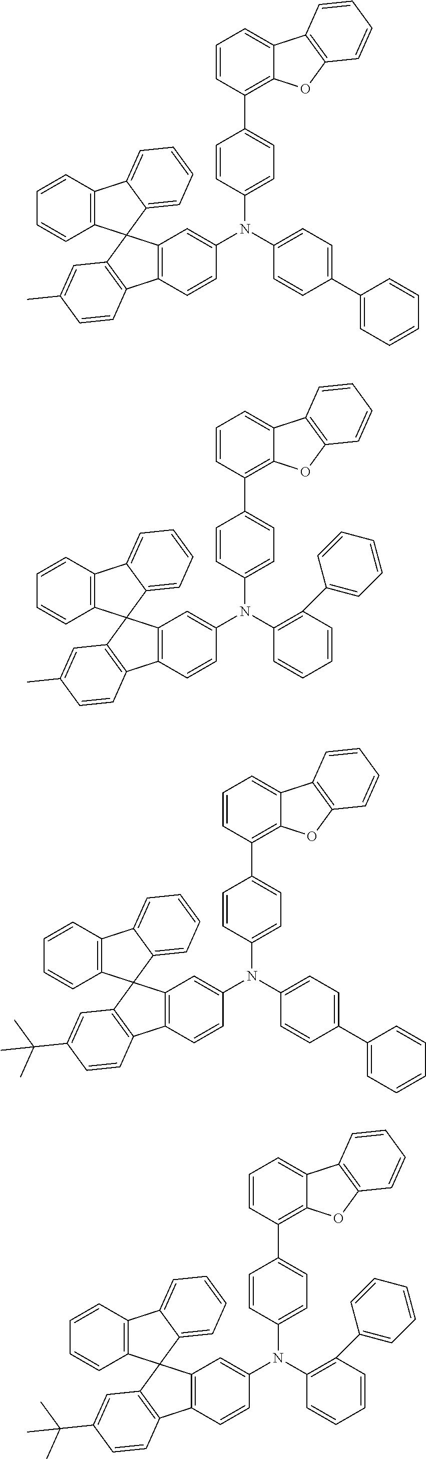

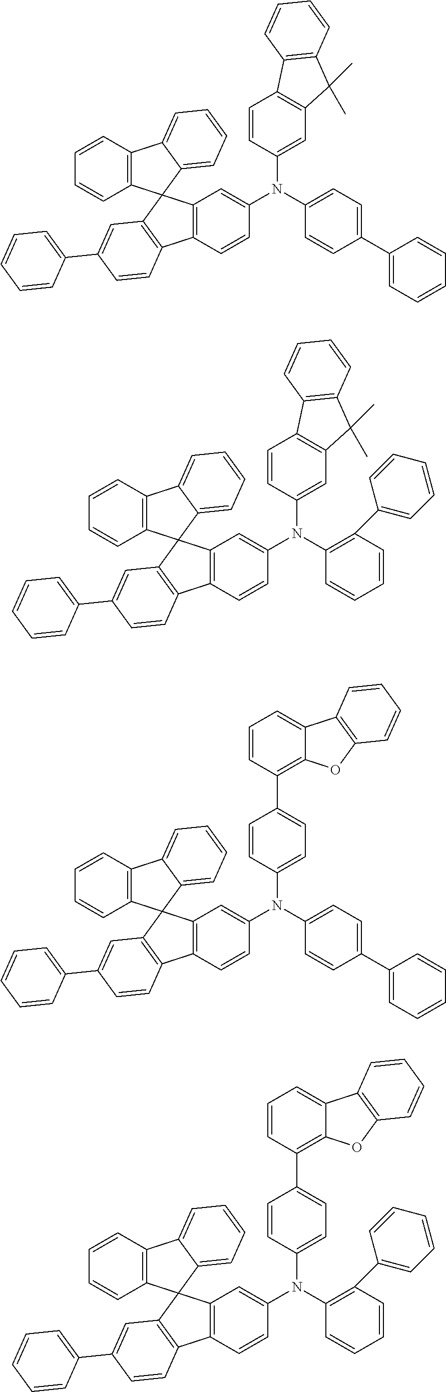

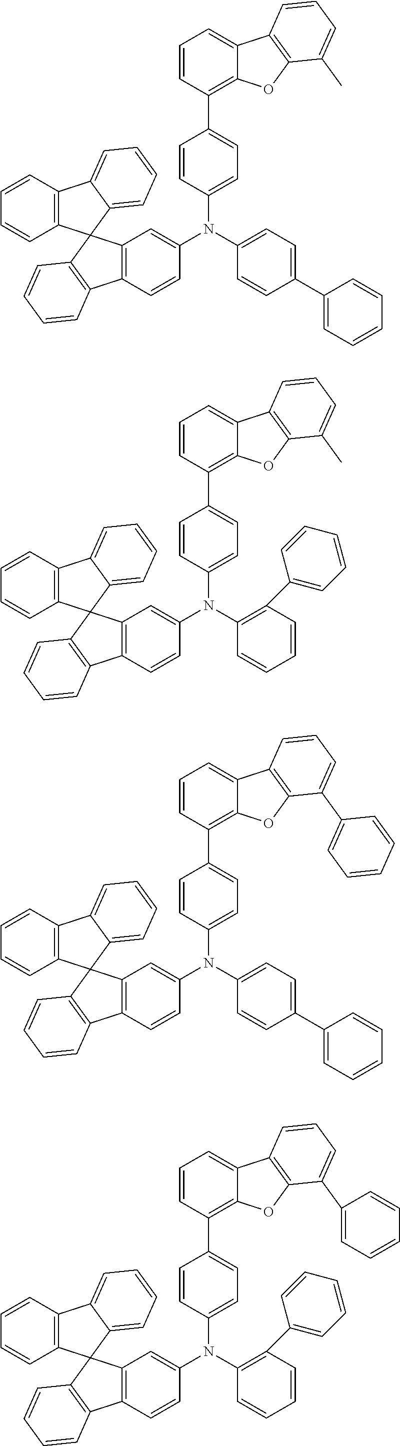 [SMILES: Cc1cccc2c1oc1c(-c3ccc(N(c4ccc(-c5ccccc5)cc4)c4ccc5c(c4)C4(c6ccccc6-c6ccccc64)c4ccccc4-5)cc3)cccc12 ; Cc1cccc2c1oc1c(-c3ccc(N(c4ccc5c(c4)C4(c6ccccc6-c6ccccc64)c4ccccc4-5)c4ccccc4-c4ccccc4)cc3)cccc12 ; c1ccc(-c2ccc(N(c3ccc(-c4cccc5c4oc4c(-c6ccccc6)cccc45)cc3)c3ccc4c(c3)C3(c5ccccc5-c5ccccc53)c3ccccc3-4)cc2)cc1 ; c1ccc(-c2ccccc2N(c2ccc(-c3cccc4c3oc3c(-c5ccccc5)cccc34)cc2)c2ccc3c(c2)C2(c4ccccc4-c4ccccc42)c2ccccc2-3)cc1]

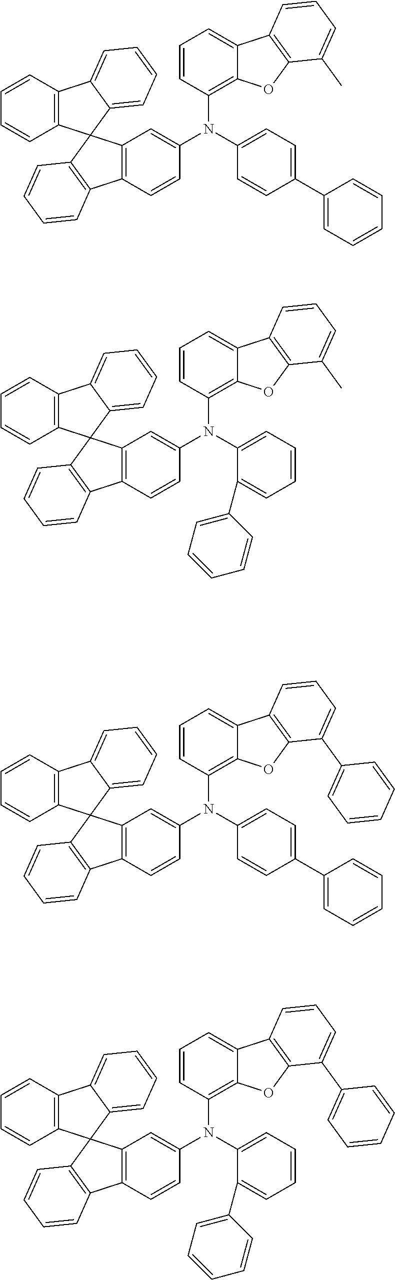 [SMILES: Cc1cccc2c1oc1c(N(c3ccc(-c4ccccc4)cc3)c3ccc4c(c3)C3(c5ccccc5-c5ccccc53)c3ccccc3-4)cccc12 ; Cc1cccc2c1oc1c(N(c3ccc4c(c3)C3(c5ccccc5-c5ccccc53)c3ccccc3-4)c3ccccc3-c3ccccc3)cccc12 ; c1ccc(-c2ccc(N(c3ccc4c(c3)C3(c5ccccc5-c5ccccc53)c3ccccc3-4)c3cccc4c3oc3c(-c5ccccc5)cccc34)cc2)cc1 ; c1ccc(-c2ccccc2N(c2ccc3c(c2)C2(c4ccccc4-c4ccccc42)c2ccccc2-3)c2cccc3c2oc2c(-c4ccccc4)cccc23)cc1]

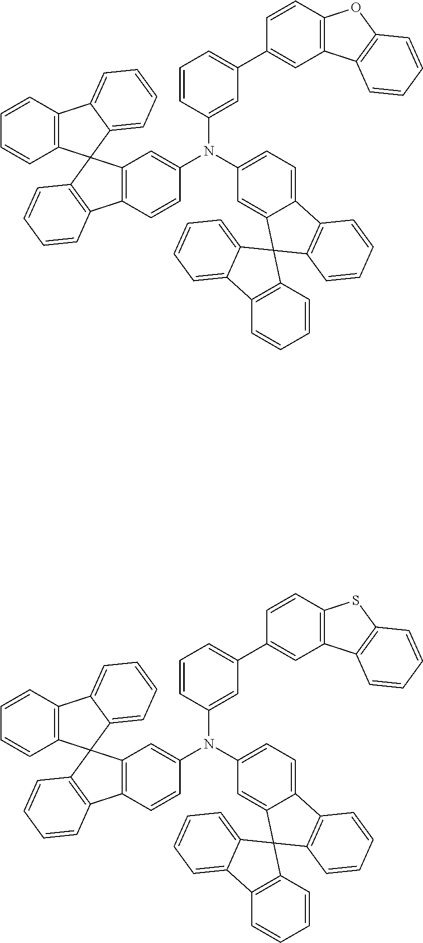 [SMILES: c1cc(-c2ccc3oc4ccccc4c3c2)cc(N(c2ccc3c(c2)C2(c4ccccc4-c4ccccc42)c2ccccc2-3)c2ccc3c(c2)C2(c4ccccc4-c4ccccc42)c2ccccc2-3)c1 ; c1cc(-c2ccc3sc4ccccc4c3c2)cc(N(c2ccc3c(c2)C2(c4ccccc4-c4ccccc42)c2ccccc2-3)c2ccc3c(c2)C2(c4ccccc4-c4ccccc42)c2ccccc2-3)c1]

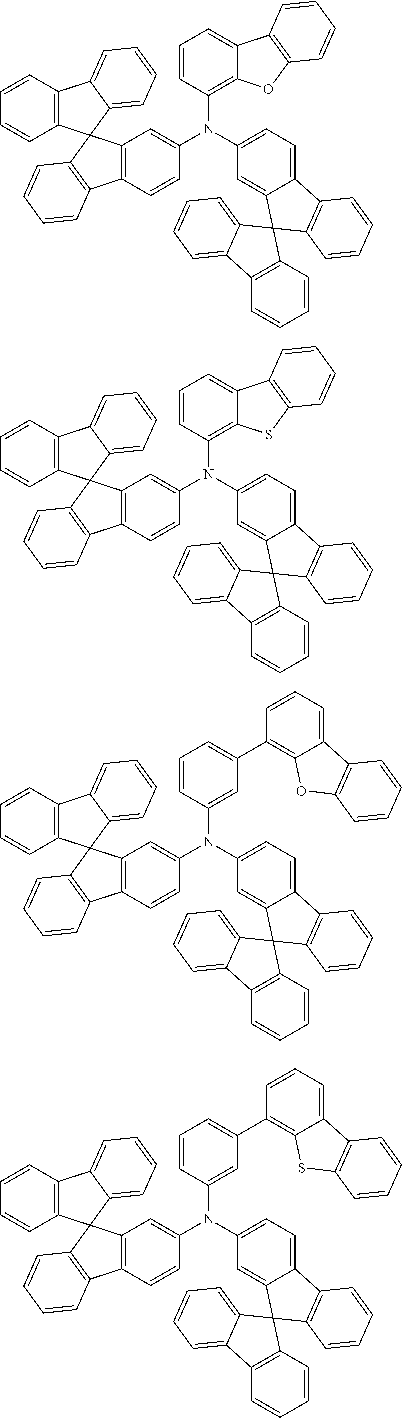

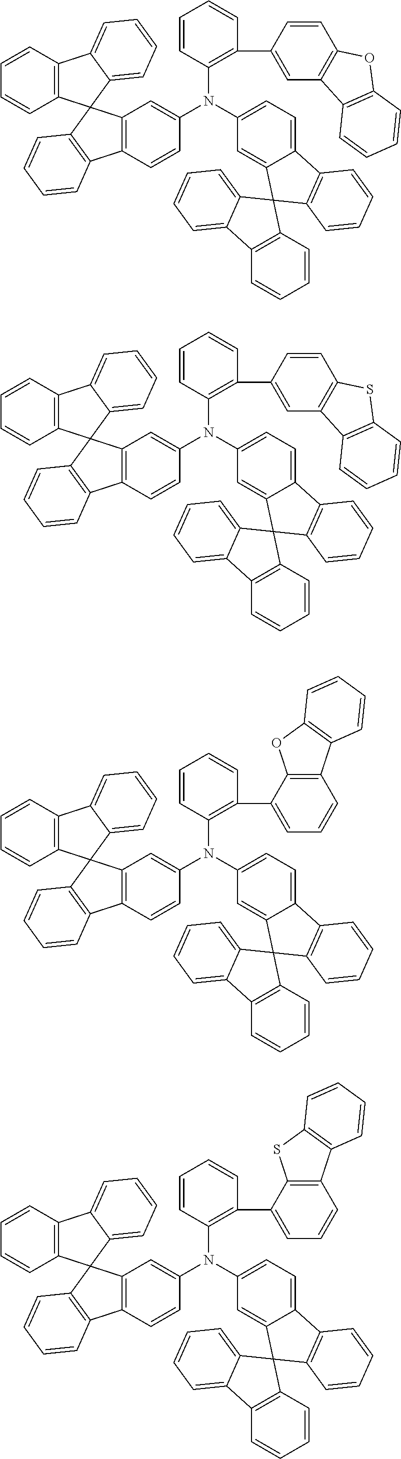 [SMILES: c1ccc(N(c2ccc3c(c2)C2(c4ccccc4-c4ccccc42)c2ccccc2-3)c2ccc3c(c2)C2(c4ccccc4-c4ccccc42)c2ccccc2-3)c(-c2ccc3oc4ccccc4c3c2)c1 ; c1ccc(N(c2ccc3c(c2)C2(c4ccccc4-c4ccccc42)c2ccccc2-3)c2ccc3c(c2)C2(c4ccccc4-c4ccccc42)c2ccccc2-3)c(-c2ccc3sc4ccccc4c3c2)c1 ; c1ccc(N(c2ccc3c(c2)C2(c4ccccc4-c4ccccc42)c2ccccc2-3)c2ccc3c(c2)C2(c4ccccc4-c4ccccc42)c2ccccc2-3)c(-c2cccc3c2oc2ccccc23)c1 ; c1ccc(N(c2ccc3c(c2)C2(c4ccccc4-c4ccccc42)c2ccccc2-3)c2ccc3c(c2)C2(c4ccccc4-c4ccccc42)c2ccccc2-3)c(-c2cccc3c2sc2ccccc23)c1]

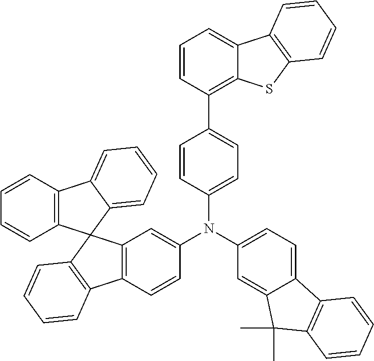 [SMILES: CC1(C)c2ccccc2-c2ccc(N(c3ccc(-c4cccc5c4sc4ccccc45)cc3)c3ccc4c(c3)C3(c5ccccc5-c5ccccc53)c3ccccc3-4)cc21]

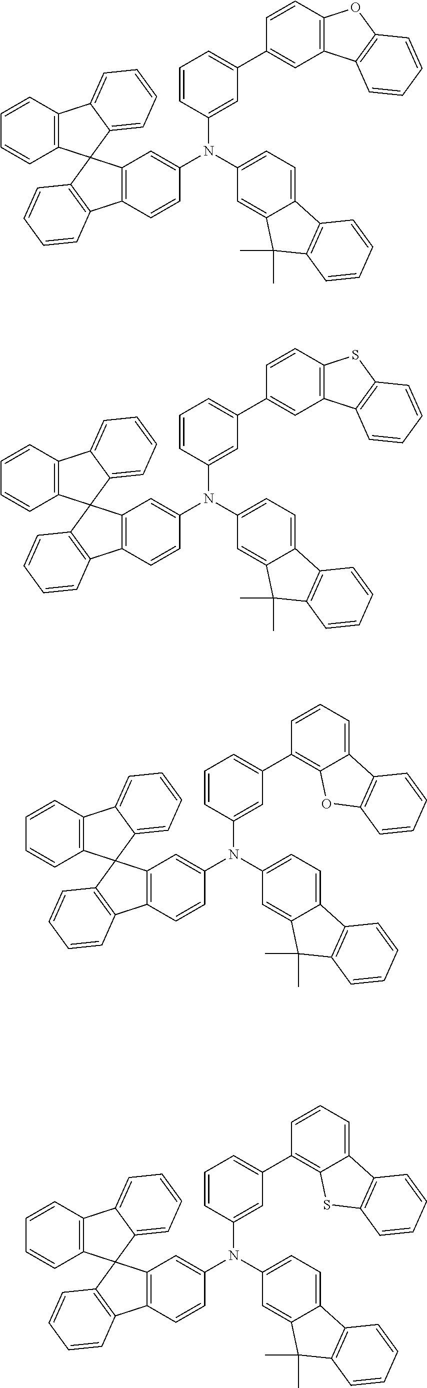 [SMILES: CC1(C)c2ccccc2-c2ccc(N(c3cccc(-c4ccc5oc6ccccc6c5c4)c3)c3ccc4c(c3)C3(c5ccccc5-c5ccccc53)c3ccccc3-4)cc21 ; CC1(C)c2ccccc2-c2ccc(N(c3cccc(-c4ccc5sc6ccccc6c5c4)c3)c3ccc4c(c3)C3(c5ccccc5-c5ccccc53)c3ccccc3-4)cc21 ; CC1(C)c2ccccc2-c2ccc(N(c3cccc(-c4cccc5c4oc4ccccc45)c3)c3ccc4c(c3)C3(c5ccccc5-c5ccccc53)c3ccccc3-4)cc21 ; CC1(C)c2ccccc2-c2ccc(N(c3cccc(-c4cccc5c4sc4ccccc45)c3)c3ccc4c(c3)C3(c5ccccc5-c5ccccc53)c3ccccc3-4)cc21]

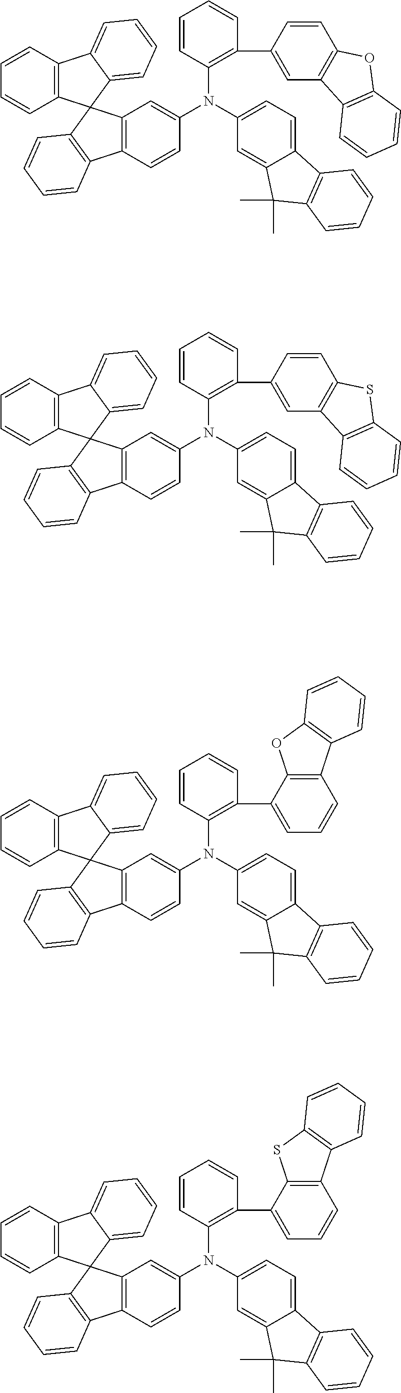 [SMILES: CC1(C)c2ccccc2-c2ccc(N(c3ccc4c(c3)C3(c5ccccc5-c5ccccc53)c3ccccc3-4)c3ccccc3-c3ccc4oc5ccccc5c4c3)cc21 ; CC1(C)c2ccccc2-c2ccc(N(c3ccc4c(c3)C3(c5ccccc5-c5ccccc53)c3ccccc3-4)c3ccccc3-c3ccc4sc5ccccc5c4c3)cc21 ; CC1(C)c2ccccc2-c2ccc(N(c3ccc4c(c3)C3(c5ccccc5-c5ccccc53)c3ccccc3-4)c3ccccc3-c3cccc4c3oc3ccccc34)cc21 ; CC1(C)c2ccccc2-c2ccc(N(c3ccc4c(c3)C3(c5ccccc5-c5ccccc53)c3ccccc3-4)c3ccccc3-c3cccc4c3sc3ccccc34)cc21]

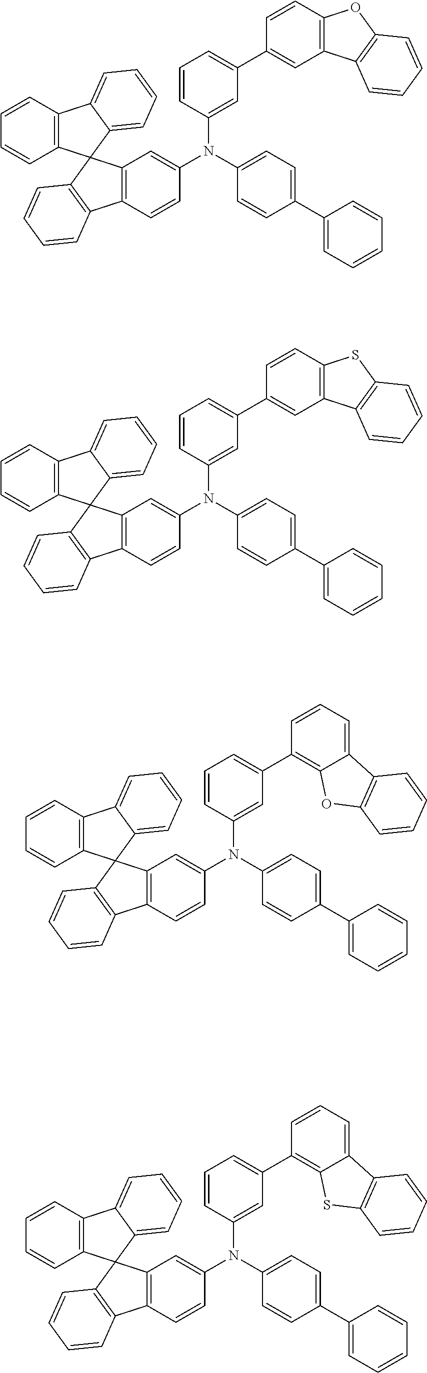 [SMILES: c1ccc(-c2ccc(N(c3cccc(-c4ccc5oc6ccccc6c5c4)c3)c3ccc4c(c3)C3(c5ccccc5-c5ccccc53)c3ccccc3-4)cc2)cc1 ; c1ccc(-c2ccc(N(c3cccc(-c4ccc5sc6ccccc6c5c4)c3)c3ccc4c(c3)C3(c5ccccc5-c5ccccc53)c3ccccc3-4)cc2)cc1 ; c1ccc(-c2ccc(N(c3cccc(-c4cccc5c4oc4ccccc45)c3)c3ccc4c(c3)C3(c5ccccc5-c5ccccc53)c3ccccc3-4)cc2)cc1 ; c1ccc(-c2ccc(N(c3cccc(-c4cccc5c4sc4ccccc45)c3)c3ccc4c(c3)C3(c5ccccc5-c5ccccc53)c3ccccc3-4)cc2)cc1]

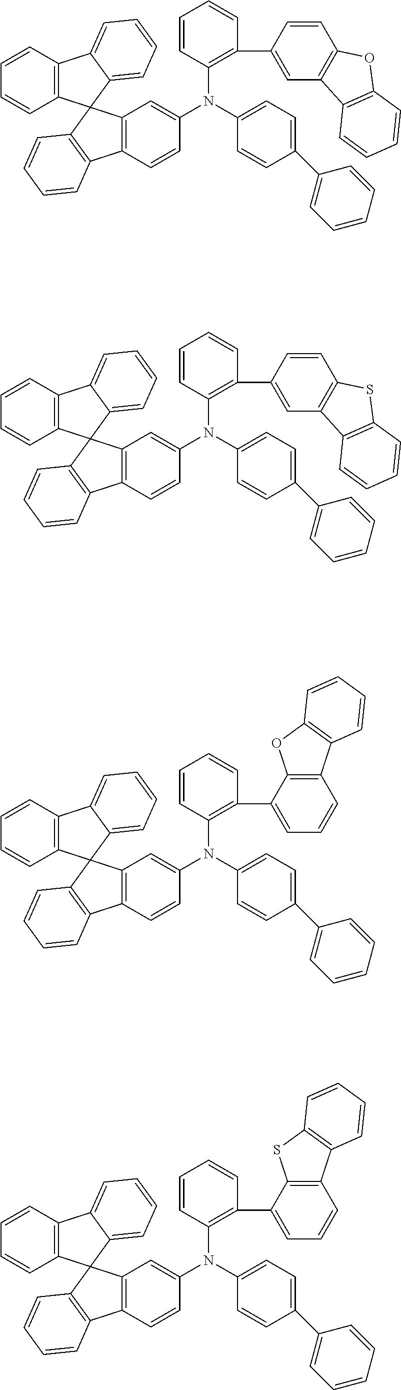 [SMILES: c1ccc(-c2ccc(N(c3ccc4c(c3)C3(c5ccccc5-c5ccccc53)c3ccccc3-4)c3ccccc3-c3ccc4oc5ccccc5c4c3)cc2)cc1 ; c1ccc(-c2ccc(N(c3ccc4c(c3)C3(c5ccccc5-c5ccccc53)c3ccccc3-4)c3ccccc3-c3ccc4sc5ccccc5c4c3)cc2)cc1 ; c1ccc(-c2ccc(N(c3ccc4c(c3)C3(c5ccccc5-c5ccccc53)c3ccccc3-4)c3ccccc3-c3cccc4c3oc3ccccc34)cc2)cc1 ; c1ccc(-c2ccc(N(c3ccc4c(c3)C3(c5ccccc5-c5ccccc53)c3ccccc3-4)c3ccccc3-c3cccc4c3sc3ccccc34)cc2)cc1]

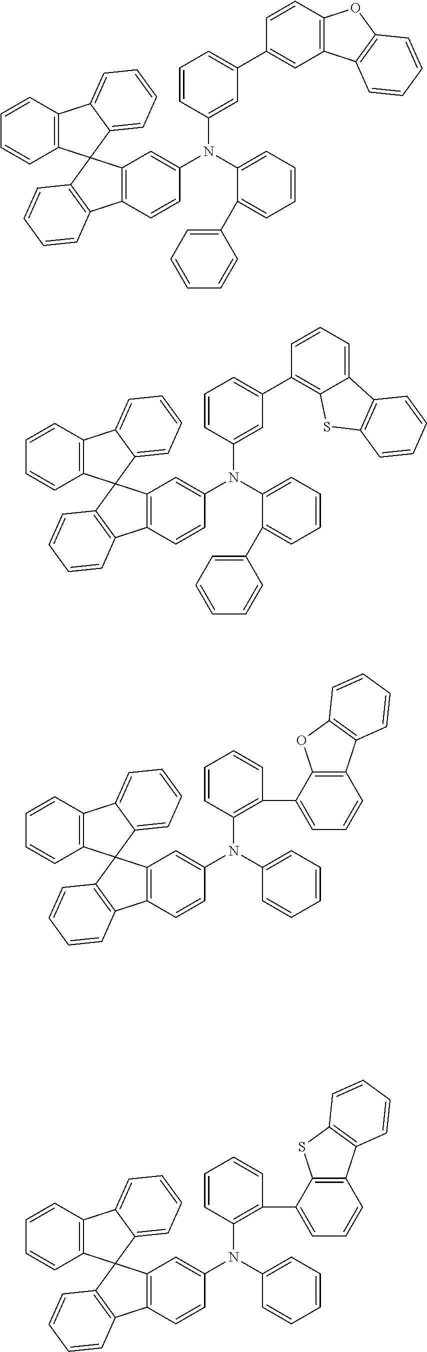 [SMILES: c1ccc(-c2ccccc2N(c2cccc(-c3ccc4oc5ccccc5c4c3)c2)c2ccc3c(c2)C2(c4ccccc4-c4ccccc42)c2ccccc2-3)cc1 ; c1ccc(-c2ccccc2N(c2cccc(-c3cccc4c3sc3ccccc34)c2)c2ccc3c(c2)C2(c4ccccc4-c4ccccc42)c2ccccc2-3)cc1 ; c1ccc(N(c2ccc3c(c2)C2(c4ccccc4-c4ccccc42)c2ccccc2-3)c2ccccc2-c2cccc3c2oc2ccccc23)cc1 ; c1ccc(N(c2ccc3c(c2)C2(c4ccccc4-c4ccccc42)c2ccccc2-3)c2ccccc2-c2cccc3c2sc2ccccc23)cc1]

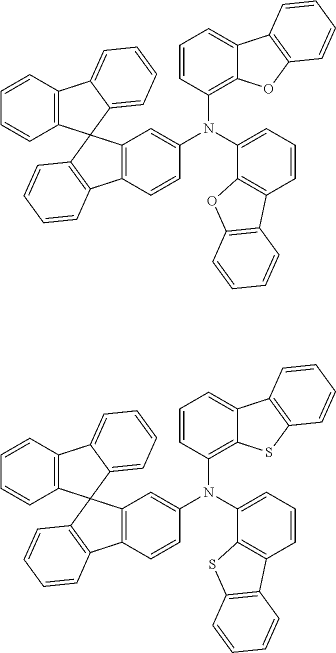 [SMILES: c1ccc2c(c1)-c1ccccc1C21c2ccccc2-c2ccc(N(c3cccc4c3oc3ccccc34)c3cccc4c3oc3ccccc34)cc21 ; c1ccc2c(c1)-c1ccccc1C21c2ccccc2-c2ccc(N(c3cccc4c3sc3ccccc34)c3cccc4c3sc3ccccc34)cc21]

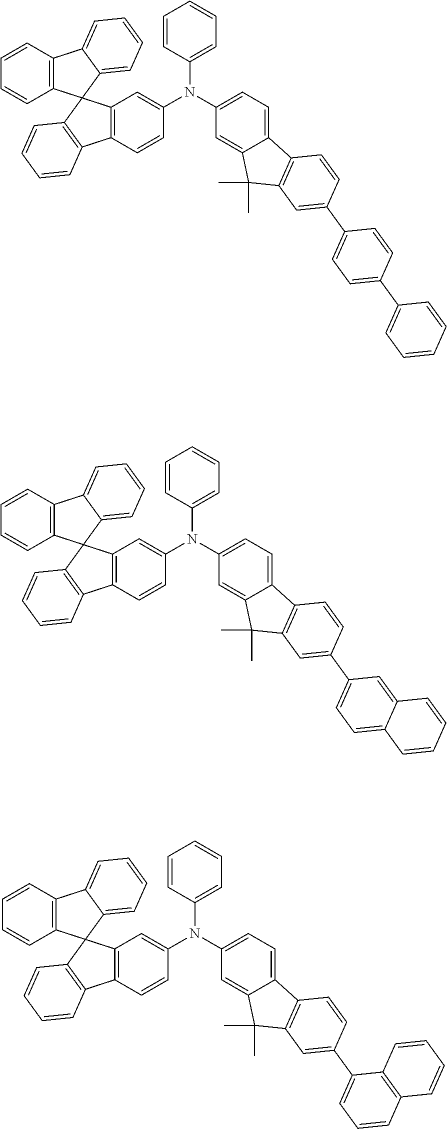 [SMILES: CC1(C)c2cc(-c3ccc(-c4ccccc4)cc3)ccc2-c2ccc(N(c3ccccc3)c3ccc4c(c3)C3(c5ccccc5-c5ccccc53)c3ccccc3-4)cc21 ; CC1(C)c2cc(-c3ccc4ccccc4c3)ccc2-c2ccc(N(c3ccccc3)c3ccc4c(c3)C3(c5ccccc5-c5ccccc53)c3ccccc3-4)cc21 ; CC1(C)c2cc(-c3cccc4ccccc34)ccc2-c2ccc(N(c3ccccc3)c3ccc4c(c3)C3(c5ccccc5-c5ccccc53)c3ccccc3-4)cc21]

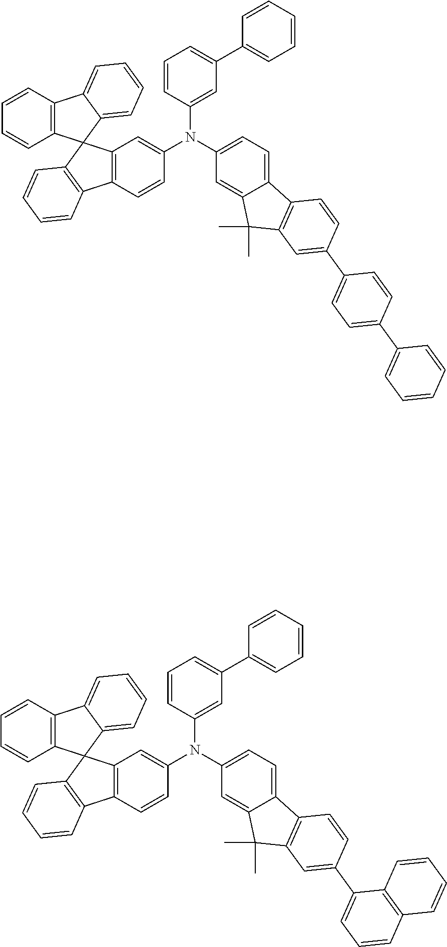 [SMILES: CC1(C)c2cc(-c3ccc(-c4ccccc4)cc3)ccc2-c2ccc(N(c3cccc(-c4ccccc4)c3)c3ccc4c(c3)C3(c5ccccc5-c5ccccc53)c3ccccc3-4)cc21 ; CC1(C)c2cc(-c3cccc4ccccc34)ccc2-c2ccc(N(c3cccc(-c4ccccc4)c3)c3ccc4c(c3)C3(c5ccccc5-c5ccccc53)c3ccccc3-4)cc21]

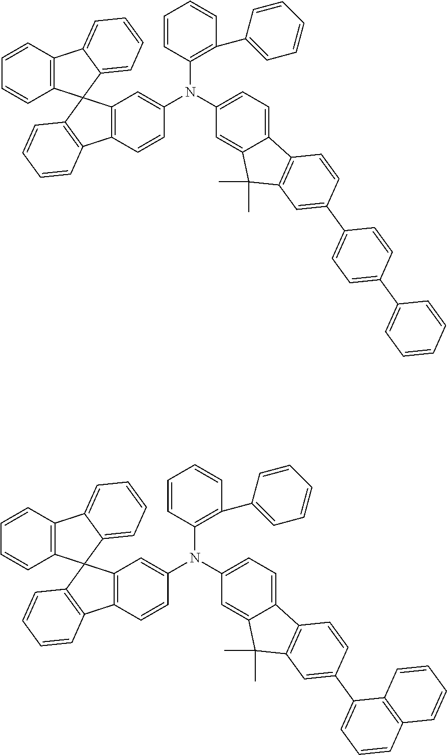 [SMILES: CC1(C)c2cc(-c3ccc(-c4ccccc4)cc3)ccc2-c2ccc(N(c3ccc4c(c3)C3(c5ccccc5-c5ccccc53)c3ccccc3-4)c3ccccc3-c3ccccc3)cc21 ; CC1(C)c2cc(-c3cccc4ccccc34)ccc2-c2ccc(N(c3ccc4c(c3)C3(c5ccccc5-c5ccccc53)c3ccccc3-4)c3ccccc3-c3ccccc3)cc21]

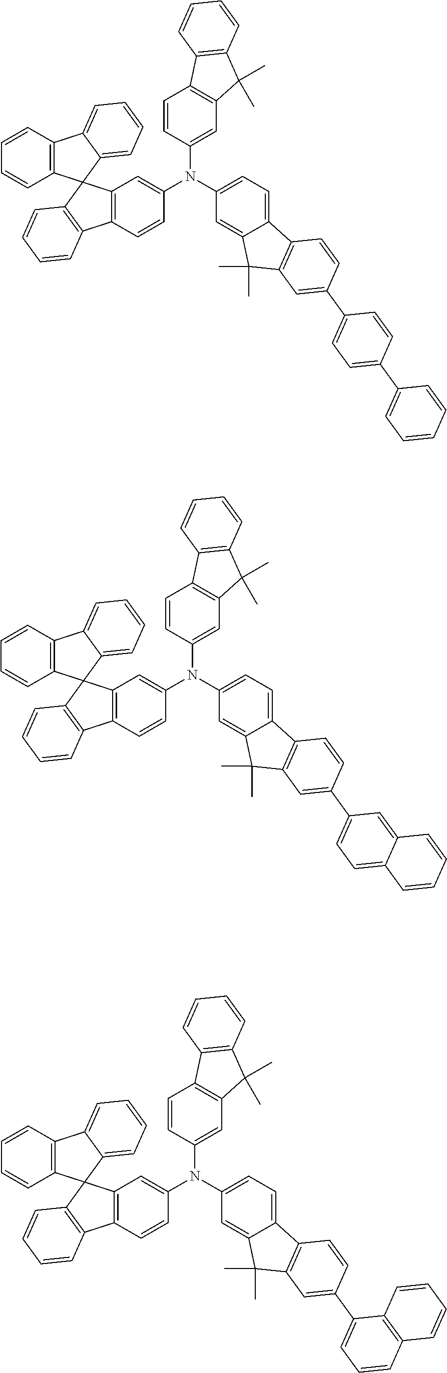 [SMILES: CC1(C)c2ccccc2-c2ccc(N(c3ccc4c(c3)C(C)(C)c3cc(-c5ccc(-c6ccccc6)cc5)ccc3-4)c3ccc4c(c3)C3(c5ccccc5-c5ccccc53)c3ccccc3-4)cc21 ; CC1(C)c2ccccc2-c2ccc(N(c3ccc4c(c3)C(C)(C)c3cc(-c5ccc6ccccc6c5)ccc3-4)c3ccc4c(c3)C3(c5ccccc5-c5ccccc53)c3ccccc3-4)cc21 ; CC1(C)c2ccccc2-c2ccc(N(c3ccc4c(c3)C(C)(C)c3cc(-c5cccc6ccccc56)ccc3-4)c3ccc4c(c3)C3(c5ccccc5-c5ccccc53)c3ccccc3-4)cc21]

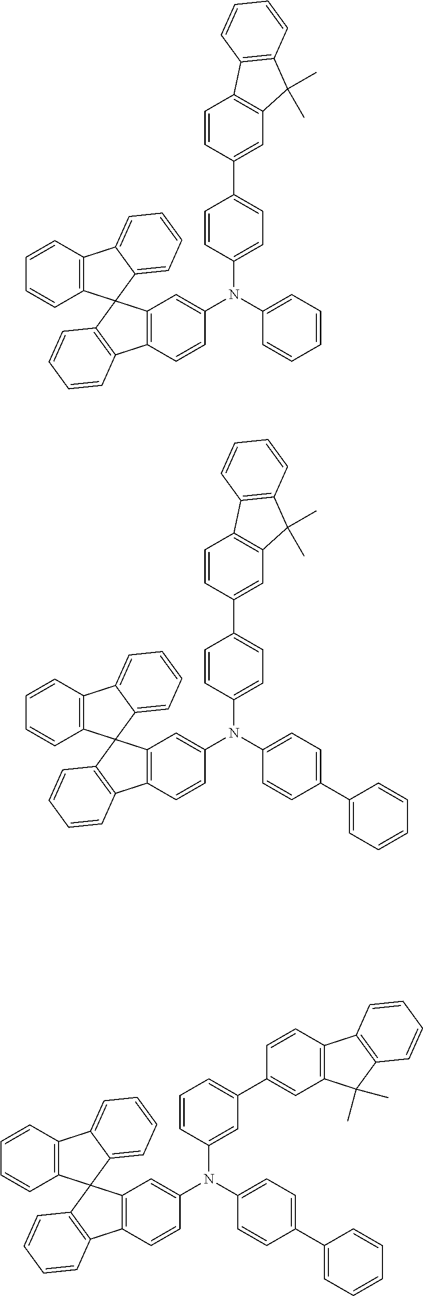 [SMILES: CC1(C)c2ccccc2-c2ccc(-c3ccc(N(c4ccccc4)c4ccc5c(c4)C4(c6ccccc6-c6ccccc64)c4ccccc4-5)cc3)cc21 ; CC1(C)c2ccccc2-c2ccc(-c3ccc(N(c4ccc(-c5ccccc5)cc4)c4ccc5c(c4)C4(c6ccccc6-c6ccccc64)c4ccccc4-5)cc3)cc21 ; CC1(C)c2ccccc2-c2ccc(-c3cccc(N(c4ccc(-c5ccccc5)cc4)c4ccc5c(c4)C4(c6ccccc6-c6ccccc64)c4ccccc4-5)c3)cc21]

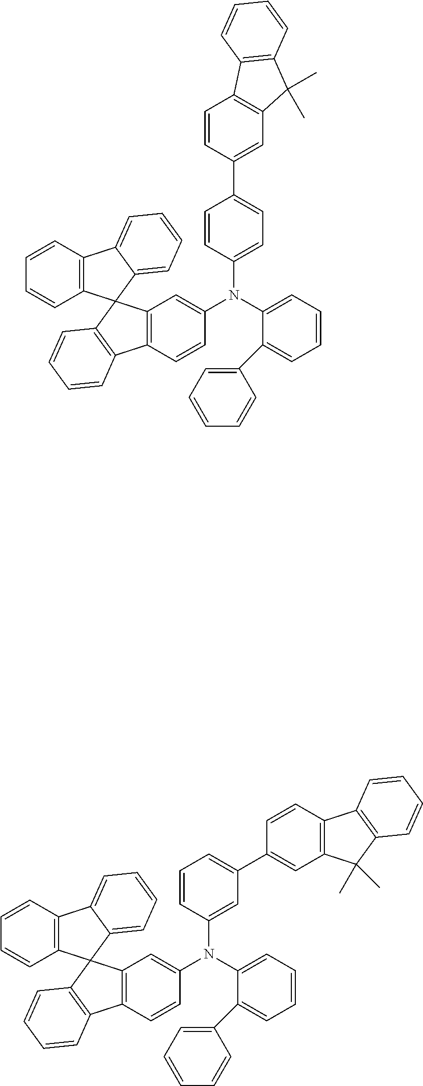 [SMILES: CC1(C)c2ccccc2-c2ccc(-c3ccc(N(c4ccc5c(c4)C4(c6ccccc6-c6ccccc64)c4ccccc4-5)c4ccccc4-c4ccccc4)cc3)cc21 ; CC1(C)c2ccccc2-c2ccc(-c3cccc(N(c4ccc5c(c4)C4(c6ccccc6-c6ccccc64)c4ccccc4-5)c4ccccc4-c4ccccc4)c3)cc21]

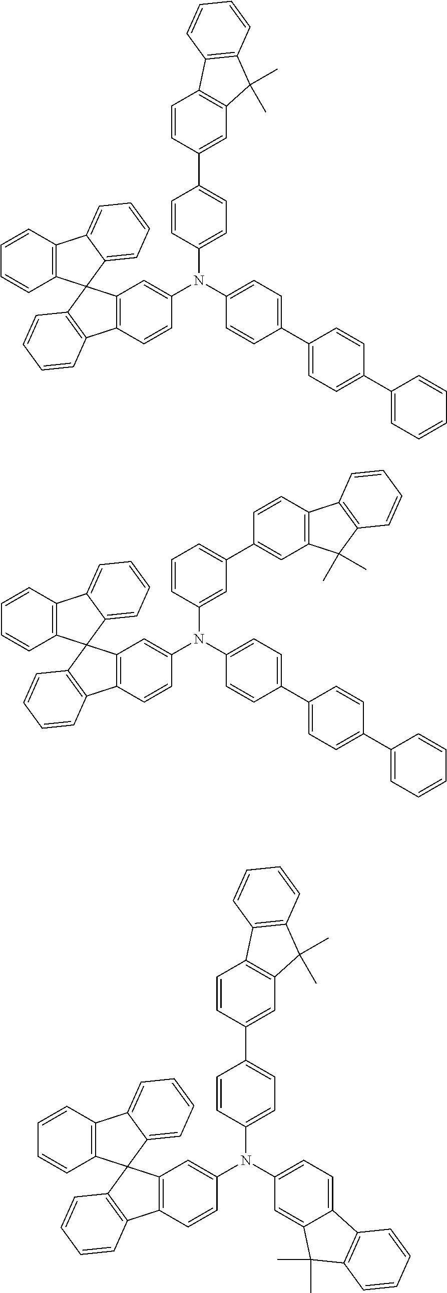 [SMILES: CC1(C)c2ccccc2-c2ccc(-c3ccc(N(c4ccc(-c5ccc(-c6ccccc6)cc5)cc4)c4ccc5c(c4)C4(c6ccccc6-c6ccccc64)c4ccccc4-5)cc3)cc21 ; CC1(C)c2ccccc2-c2ccc(-c3cccc(N(c4ccc(-c5ccc(-c6ccccc6)cc5)cc4)c4ccc5c(c4)C4(c6ccccc6-c6ccccc64)c4ccccc4-5)c3)cc21 ; CC1(C)c2ccccc2-c2ccc(-c3ccc(N(c4ccc5c(c4)C(C)(C)c4ccccc4-5)c4ccc5c(c4)C4(c6ccccc6-c6ccccc64)c4ccccc4-5)cc3)cc21]

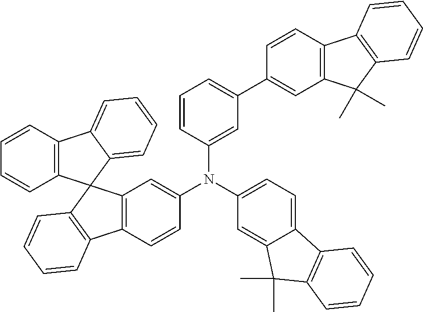 [SMILES: CC1(C)c2ccccc2-c2ccc(-c3cccc(N(c4ccc5c(c4)C(C)(C)c4ccccc4-5)c4ccc5c(c4)C4(c6ccccc6-c6ccccc64)c4ccccc4-5)c3)cc21]

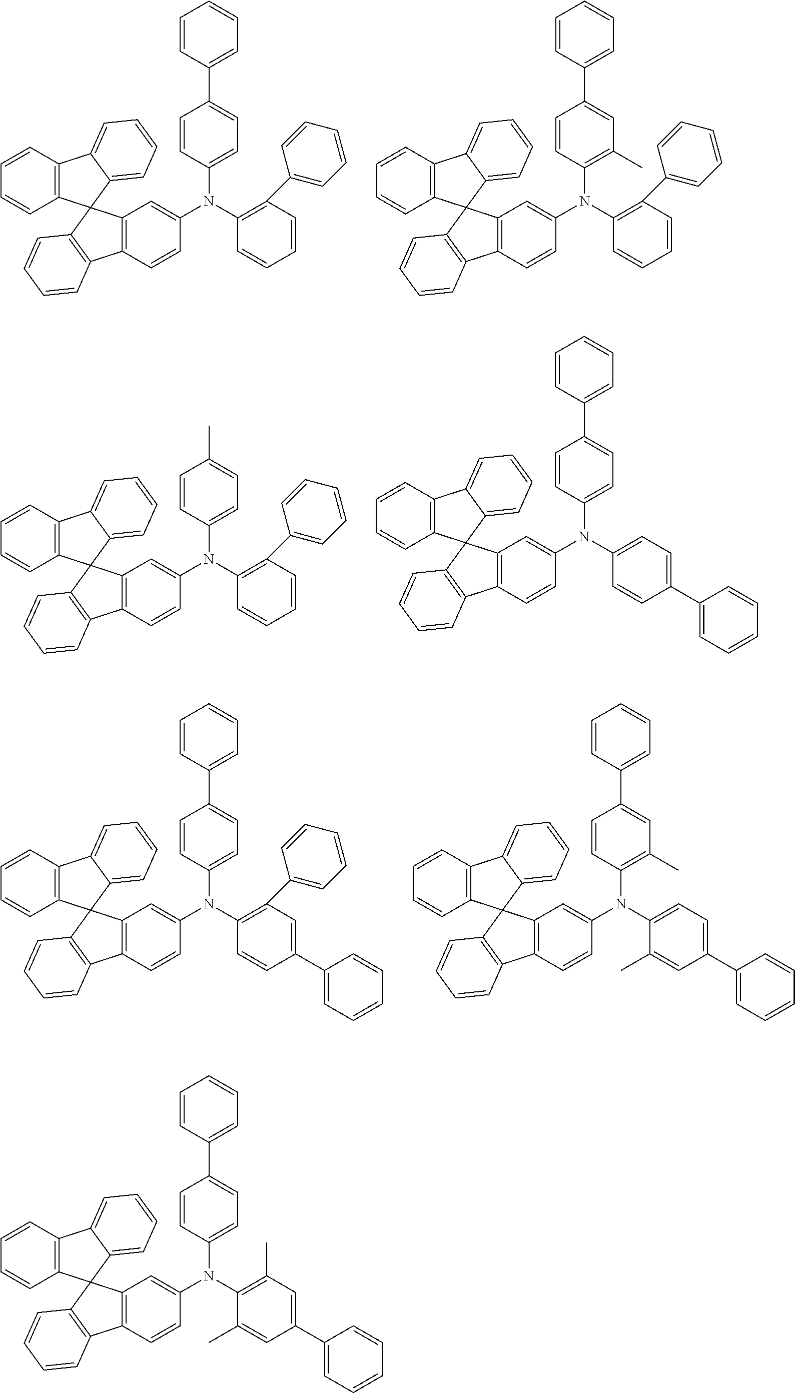

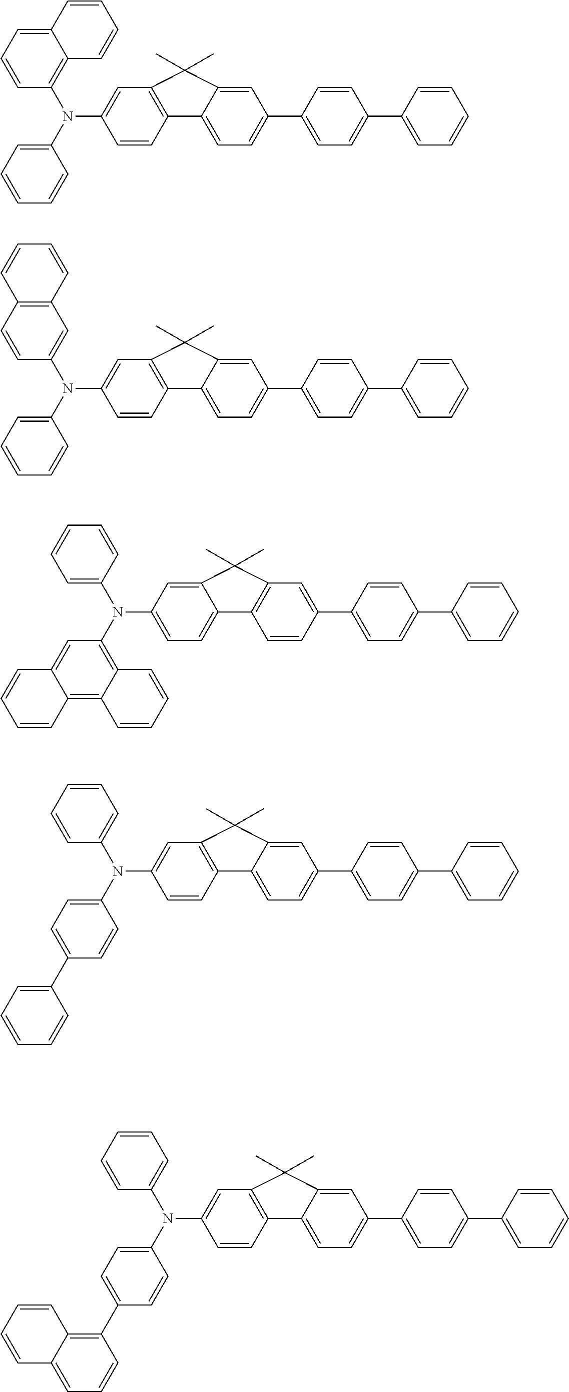

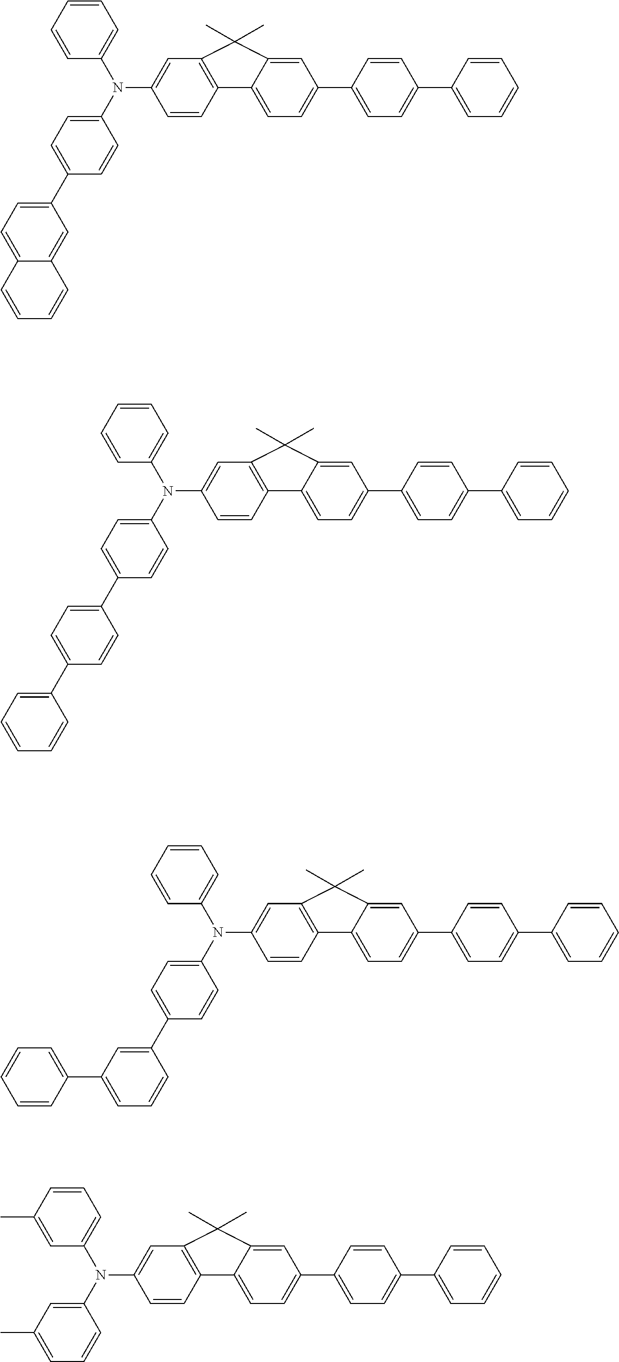 [SMILES: CC1(C)c2cc(-c3ccc(-c4ccccc4)cc3)ccc2-c2ccc(N(c3ccccc3)c3ccc(-c4ccc5ccccc5c4)cc3)cc21 ; CC1(C)c2cc(-c3ccc(-c4ccccc4)cc3)ccc2-c2ccc(N(c3ccccc3)c3ccc(-c4ccc(-c5ccccc5)cc4)cc3)cc21 ; CC1(C)c2cc(-c3ccc(-c4ccccc4)cc3)ccc2-c2ccc(N(c3ccccc3)c3ccc(-c4cccc(-c5ccccc5)c4)cc3)cc21 ; Cc1cccc(N(c2cccc(C)c2)c2ccc3c(c2)C(C)(C)c2cc(-c4ccc(-c5ccccc5)cc4)ccc2-3)c1]

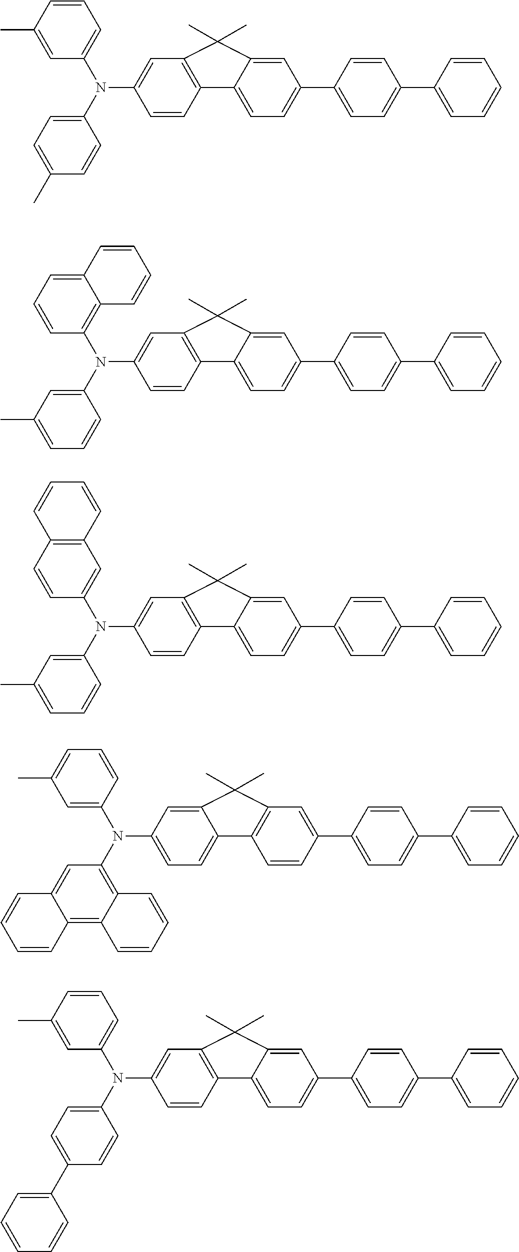

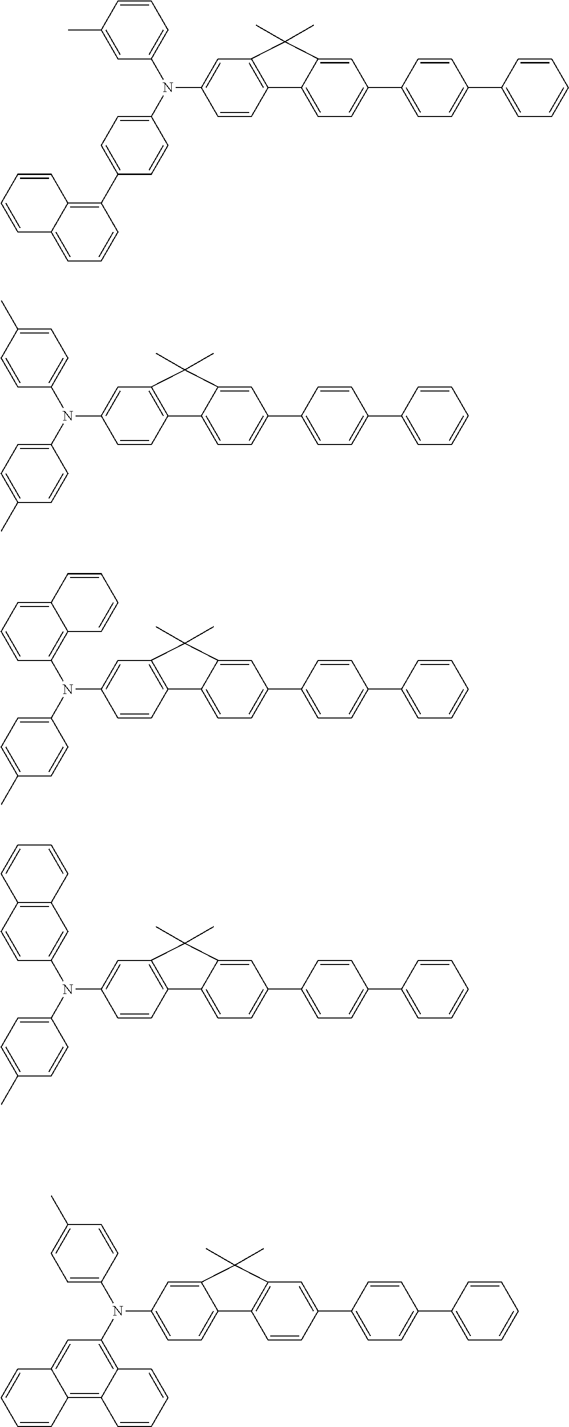

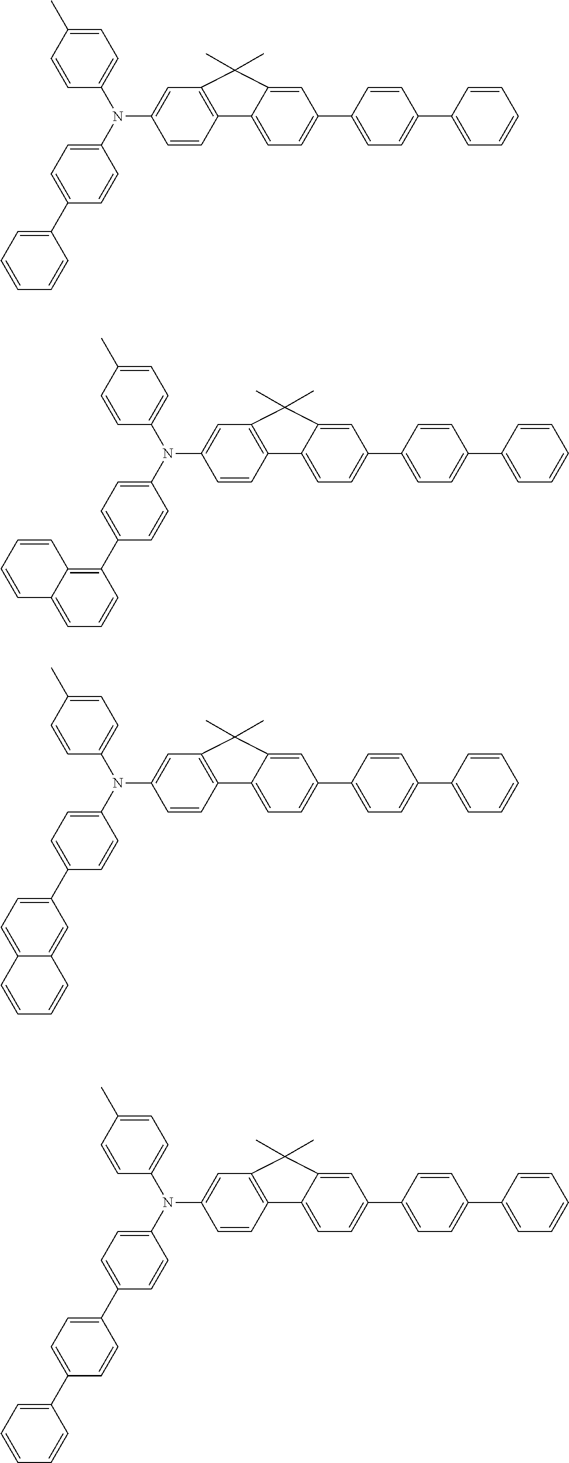

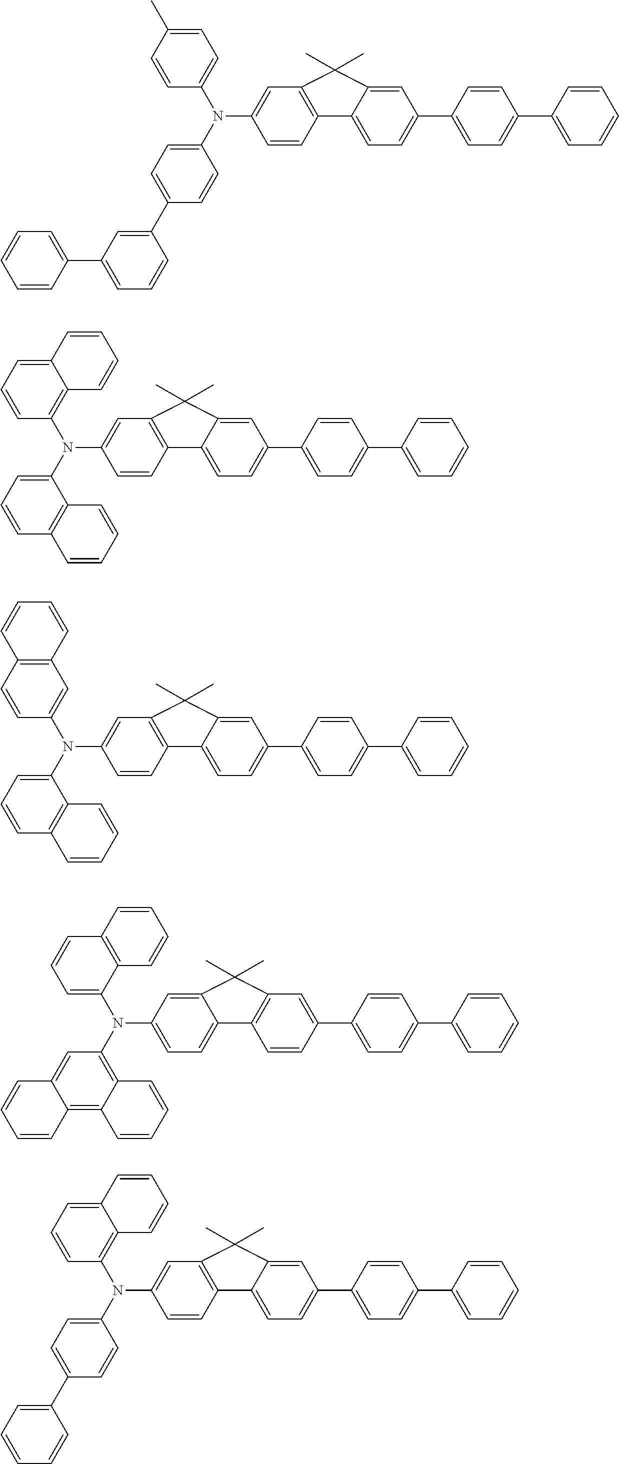

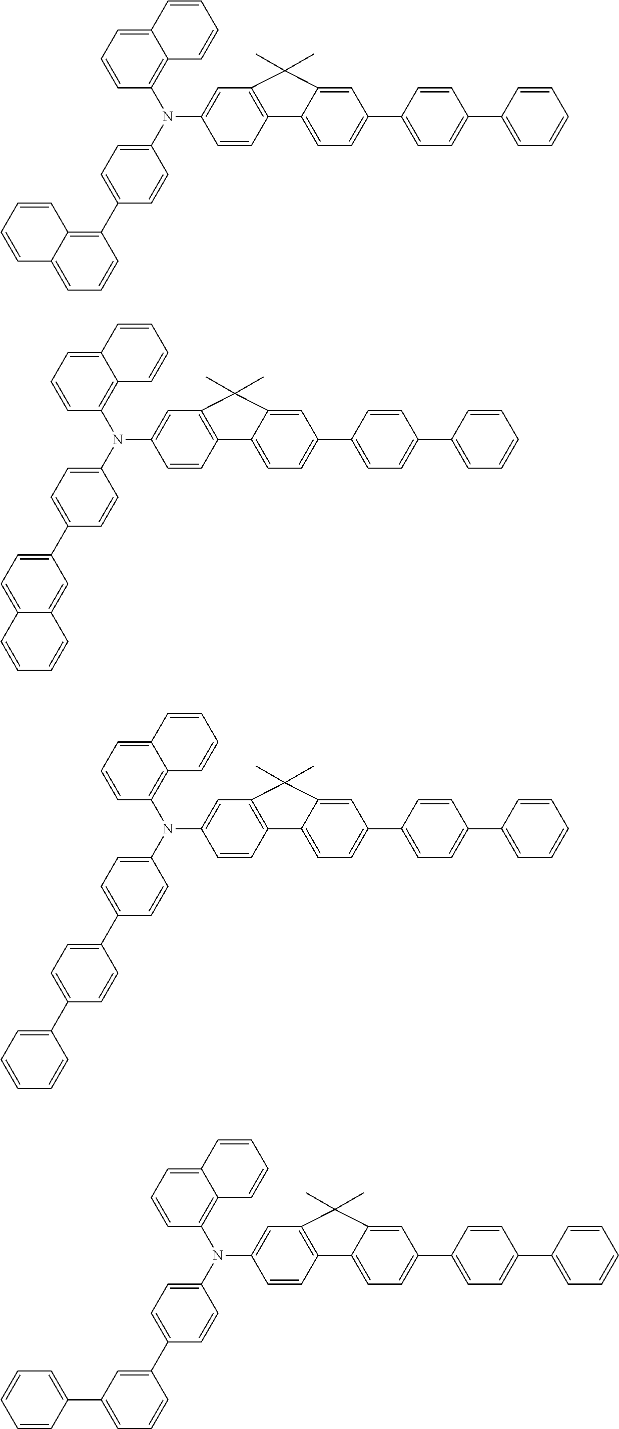

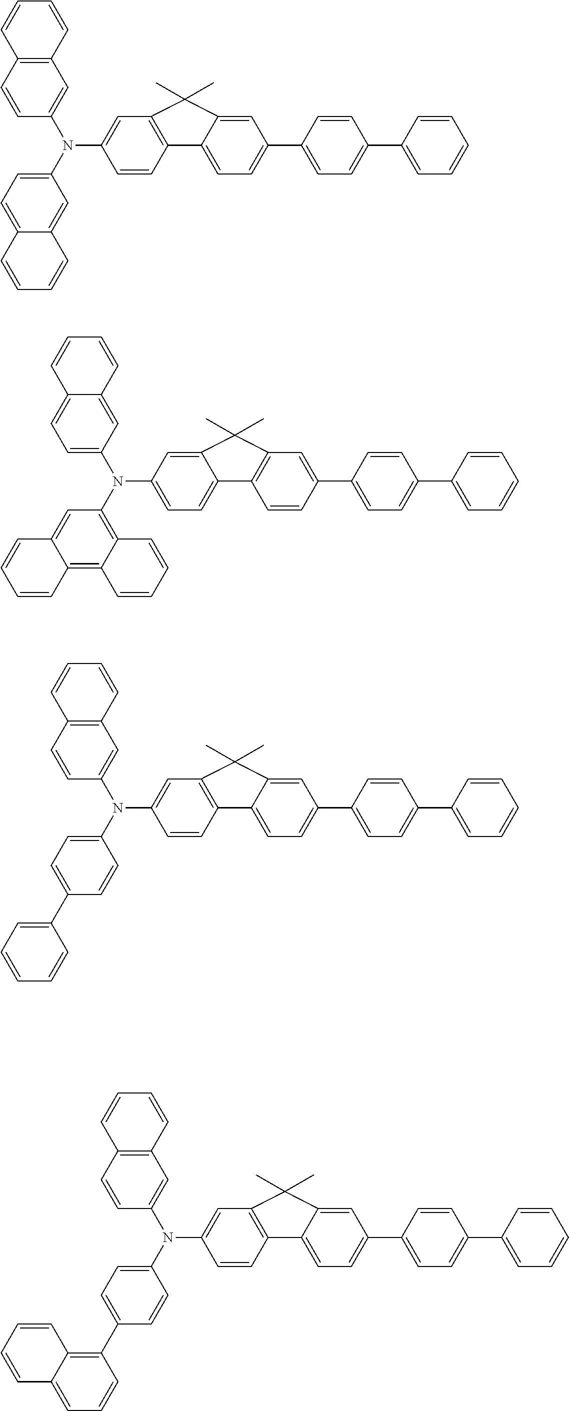 [SMILES: CC1(C)c2cc(-c3ccc(-c4ccccc4)cc3)ccc2-c2ccc(N(c3ccc4ccccc4c3)c3ccc4ccccc4c3)cc21 ; CC1(C)c2cc(-c3ccc(-c4ccccc4)cc3)ccc2-c2ccc(N(c3ccc4ccccc4c3)c3cc4ccccc4c4ccccc34)cc21 ; CC1(C)c2cc(-c3ccc(-c4ccccc4)cc3)ccc2-c2ccc(N(c3ccc(-c4ccccc4)cc3)c3ccc4ccccc4c3)cc21 ; CC1(C)c2cc(-c3ccc(-c4ccccc4)cc3)ccc2-c2ccc(N(c3ccc(-c4cccc5ccccc45)cc3)c3ccc4ccccc4c3)cc21]

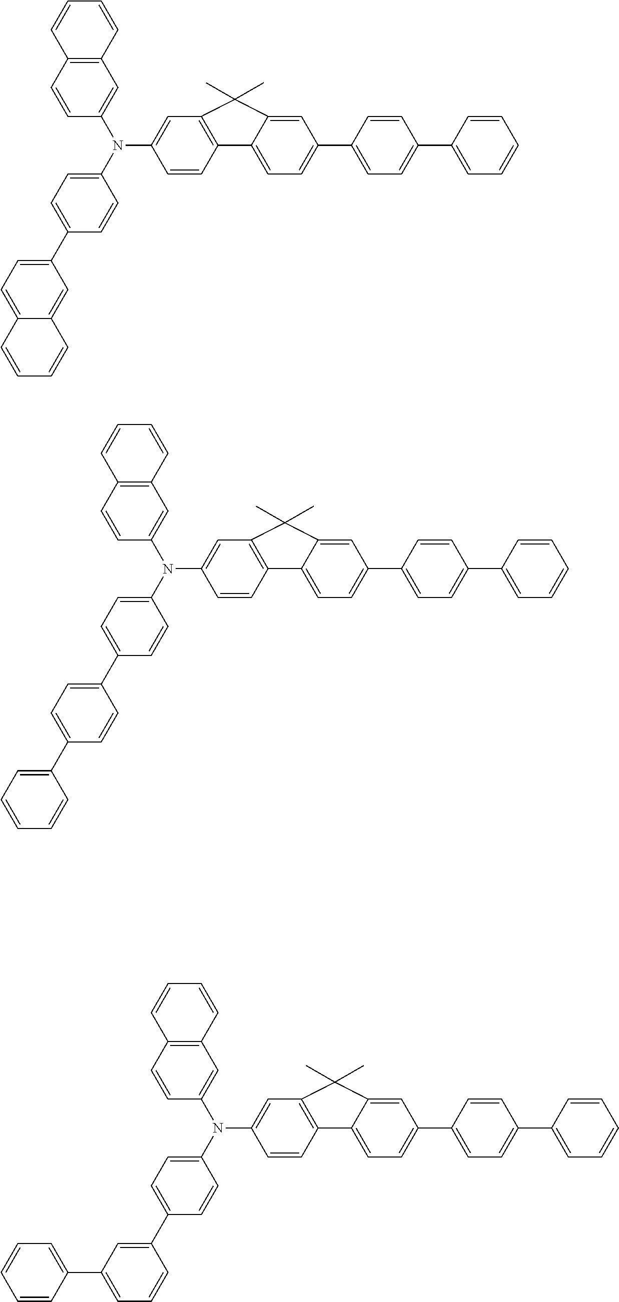 [SMILES: CC1(C)c2cc(-c3ccc(-c4ccccc4)cc3)ccc2-c2ccc(N(c3ccc(-c4ccc5ccccc5c4)cc3)c3ccc4ccccc4c3)cc21 ; CC1(C)c2cc(-c3ccc(-c4ccccc4)cc3)ccc2-c2ccc(N(c3ccc(-c4ccc(-c5ccccc5)cc4)cc3)c3ccc4ccccc4c3)cc21 ; CC1(C)c2cc(-c3ccc(-c4ccccc4)cc3)ccc2-c2ccc(N(c3ccc(-c4cccc(-c5ccccc5)c4)cc3)c3ccc4ccccc4c3)cc21]

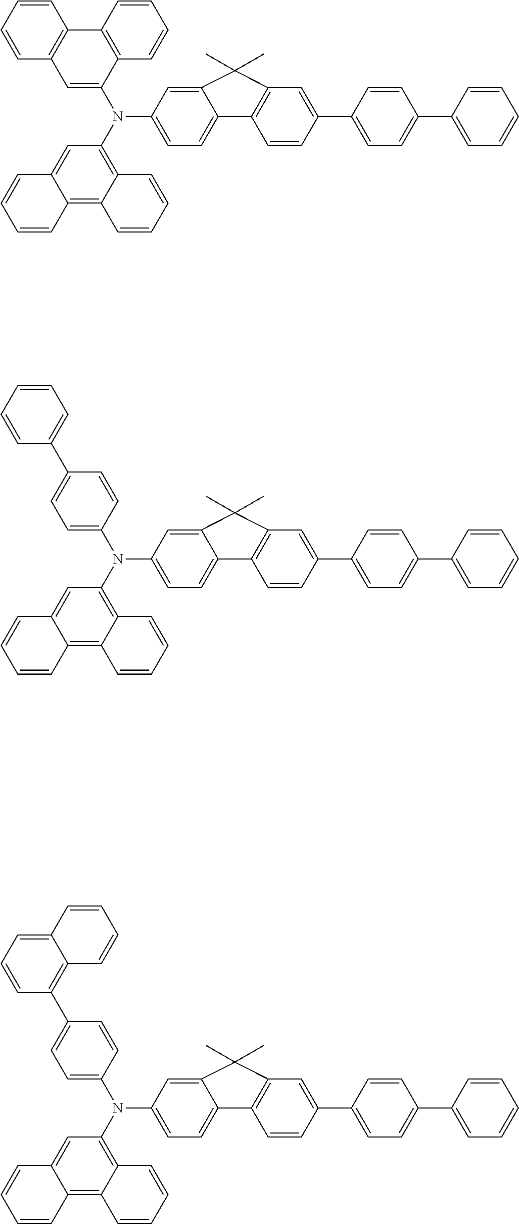 [SMILES: CC1(C)c2cc(-c3ccc(-c4ccccc4)cc3)ccc2-c2ccc(N(c3cc4ccccc4c4ccccc34)c3cc4ccccc4c4ccccc34)cc21 ; CC1(C)c2cc(-c3ccc(-c4ccccc4)cc3)ccc2-c2ccc(N(c3ccc(-c4ccccc4)cc3)c3cc4ccccc4c4ccccc34)cc21 ; CC1(C)c2cc(-c3ccc(-c4ccccc4)cc3)ccc2-c2ccc(N(c3ccc(-c4cccc5ccccc45)cc3)c3cc4ccccc4c4ccccc34)cc21]

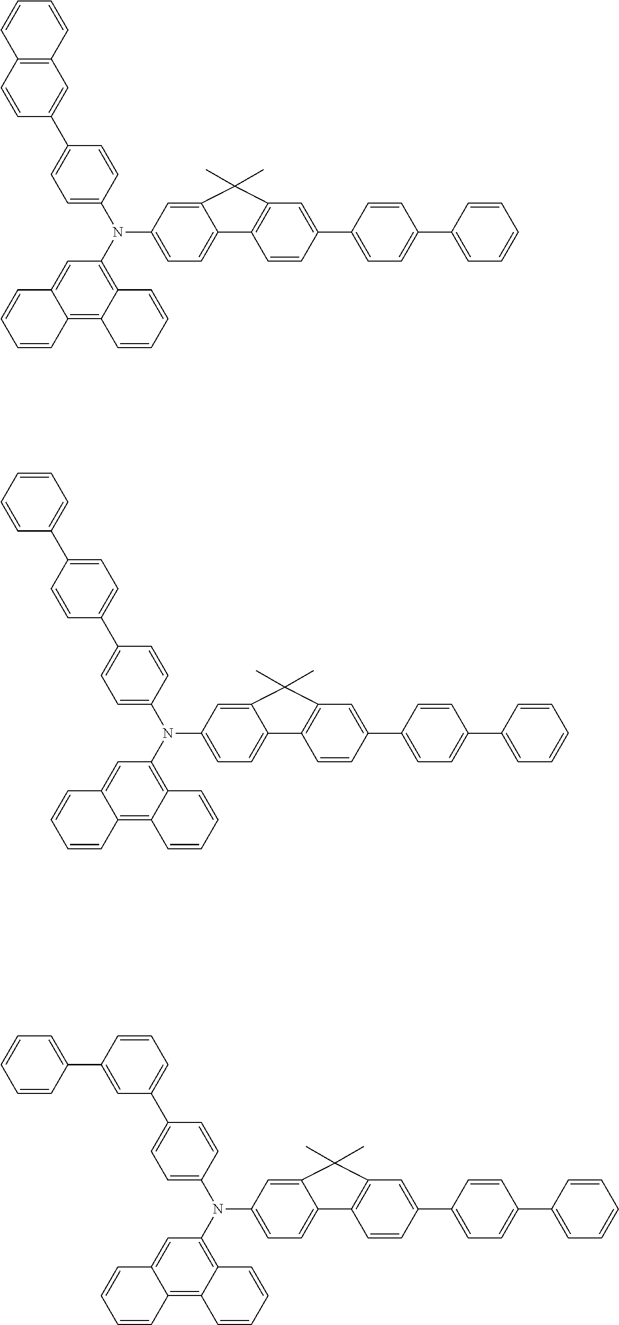 [SMILES: CC1(C)c2cc(-c3ccc(-c4ccccc4)cc3)ccc2-c2ccc(N(c3ccc(-c4ccc5ccccc5c4)cc3)c3cc4ccccc4c4ccccc34)cc21 ; CC1(C)c2cc(-c3ccc(-c4ccccc4)cc3)ccc2-c2ccc(N(c3ccc(-c4ccc(-c5ccccc5)cc4)cc3)c3cc4ccccc4c4ccccc34)cc21 ; CC1(C)c2cc(-c3ccc(-c4ccccc4)cc3)ccc2-c2ccc(N(c3ccc(-c4cccc(-c5ccccc5)c4)cc3)c3cc4ccccc4c4ccccc34)cc21]

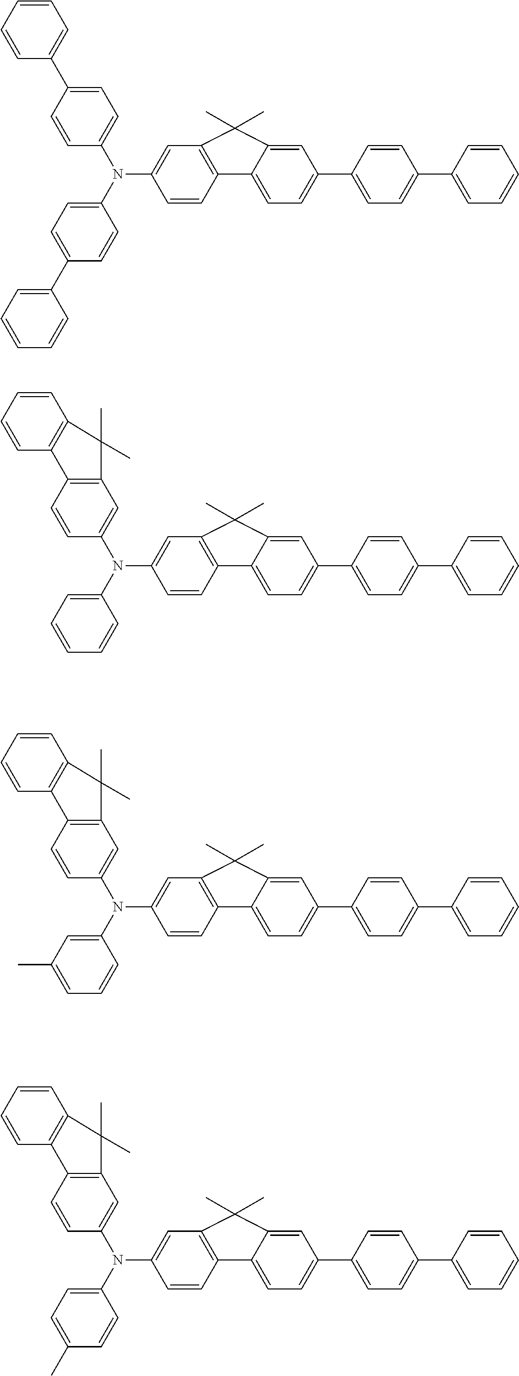

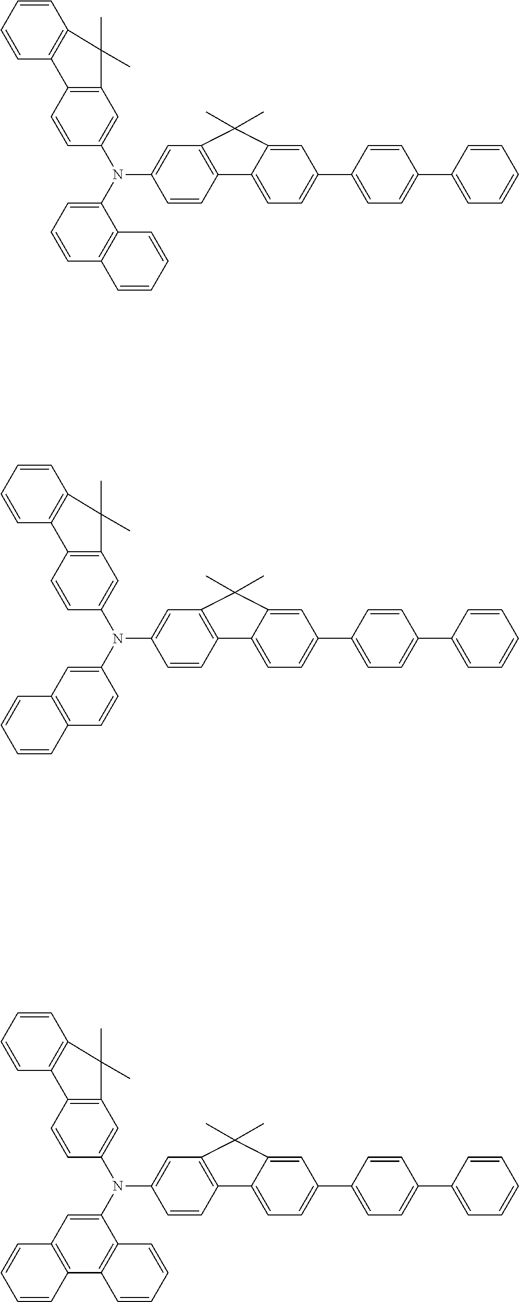 [SMILES: CC1(C)c2ccccc2-c2ccc(N(c3ccc4c(c3)C(C)(C)c3cc(-c5ccc(-c6ccccc6)cc5)ccc3-4)c3cccc4ccccc34)cc21 ; CC1(C)c2ccccc2-c2ccc(N(c3ccc4c(c3)C(C)(C)c3cc(-c5ccc(-c6ccccc6)cc5)ccc3-4)c3ccc4ccccc4c3)cc21 ; CC1(C)c2ccccc2-c2ccc(N(c3ccc4c(c3)C(C)(C)c3cc(-c5ccc(-c6ccccc6)cc5)ccc3-4)c3cc4ccccc4c4ccccc34)cc21]

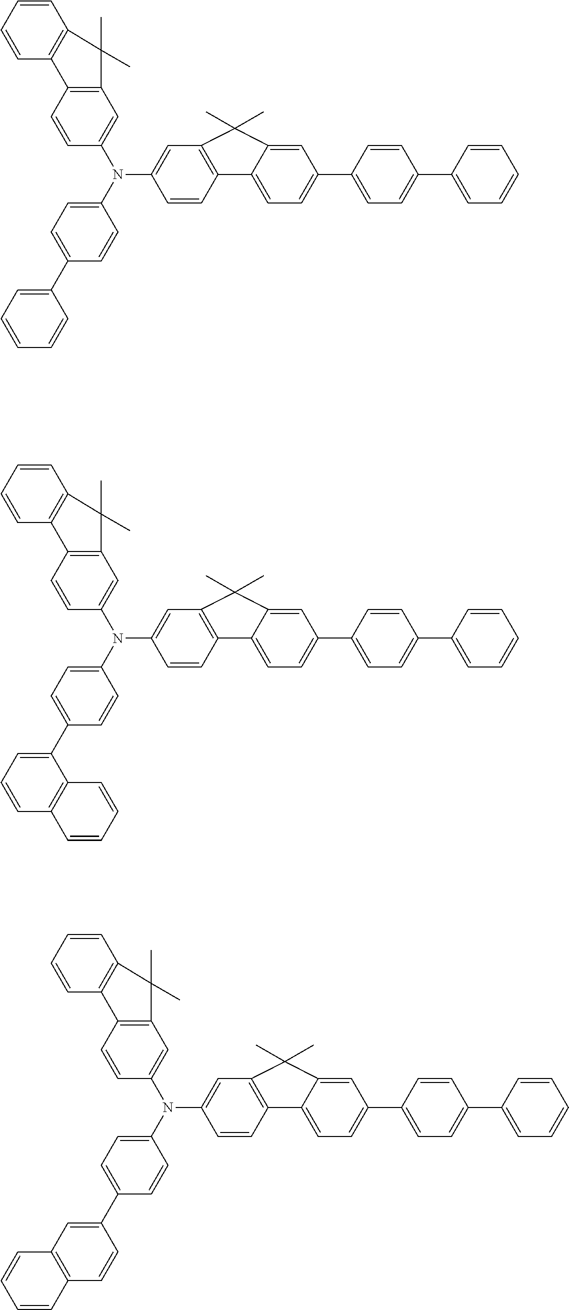 [SMILES: CC1(C)c2ccccc2-c2ccc(N(c3ccc(-c4ccccc4)cc3)c3ccc4c(c3)C(C)(C)c3cc(-c5ccc(-c6ccccc6)cc5)ccc3-4)cc21 ; CC1(C)c2ccccc2-c2ccc(N(c3ccc(-c4cccc5ccccc45)cc3)c3ccc4c(c3)C(C)(C)c3cc(-c5ccc(-c6ccccc6)cc5)ccc3-4)cc21 ; CC1(C)c2ccccc2-c2ccc(N(c3ccc(-c4ccc5ccccc5c4)cc3)c3ccc4c(c3)C(C)(C)c3cc(-c5ccc(-c6ccccc6)cc5)ccc3-4)cc21]

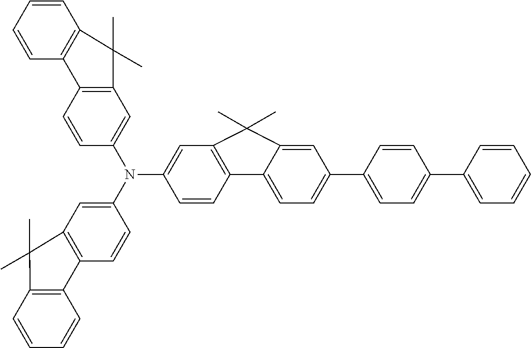 [SMILES: CC1(C)c2ccccc2-c2ccc(N(c3ccc4c(c3)C(C)(C)c3ccccc3-4)c3ccc4c(c3)C(C)(C)c3cc(-c5ccc(-c6ccccc6)cc5)ccc3-4)cc21]

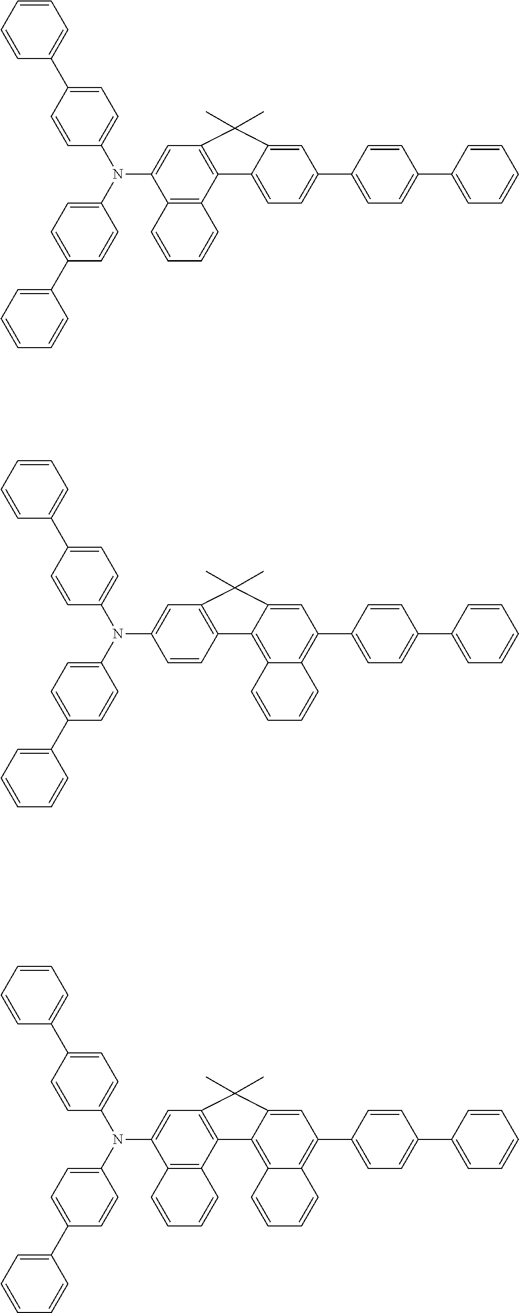 [SMILES: CC1(C)c2cc(-c3ccc(-c4ccccc4)cc3)ccc2-c2c1cc(N(c1ccc(-c3ccccc3)cc1)c1ccc(-c3ccccc3)cc1)c1ccccc21 ; CC1(C)c2cc(N(c3ccc(-c4ccccc4)cc3)c3ccc(-c4ccccc4)cc3)ccc2-c2c1cc(-c1ccc(-c3ccccc3)cc1)c1ccccc21 ; CC1(C)c2cc(-c3ccc(-c4ccccc4)cc3)c3ccccc3c2-c2c1cc(N(c1ccc(-c3ccccc3)cc1)c1ccc(-c3ccccc3)cc1)c1ccccc21]

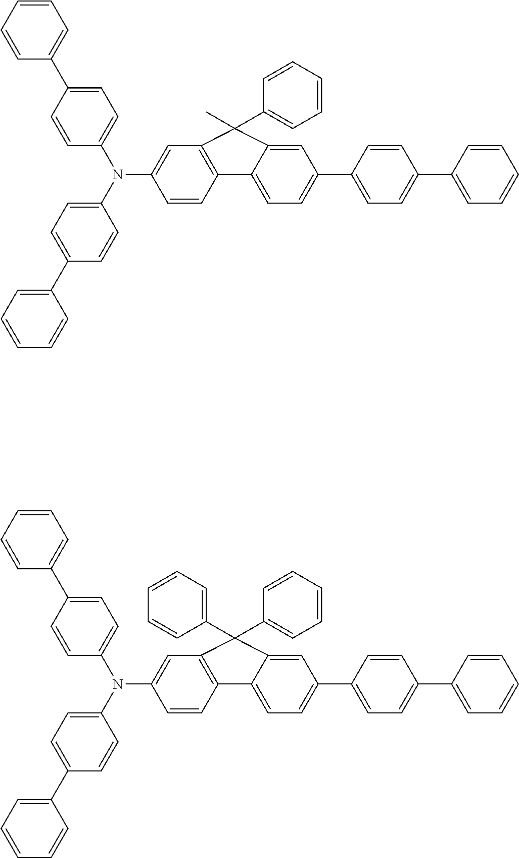 [SMILES: CC1(c2ccccc2)c2cc(-c3ccc(-c4ccccc4)cc3)ccc2-c2ccc(N(c3ccc(-c4ccccc4)cc3)c3ccc(-c4ccccc4)cc3)cc21 ; c1ccc(-c2ccc(-c3ccc4c(c3)C(c3ccccc3)(c3ccccc3)c3cc(N(c5ccc(-c6ccccc6)cc5)c5ccc(-c6ccccc6)cc5)ccc3-4)cc2)cc1]

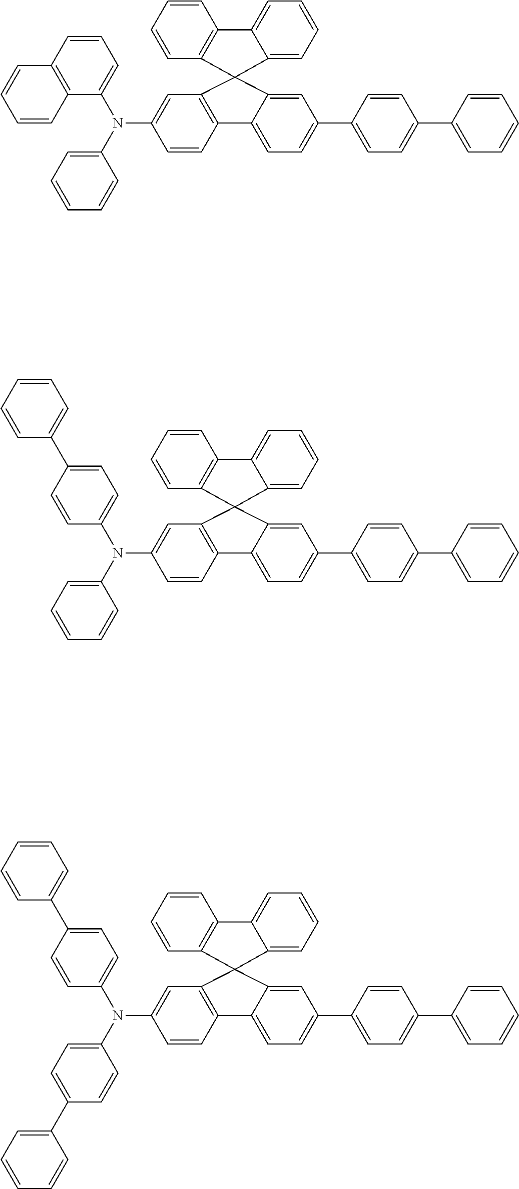 [SMILES: c1ccc(-c2ccc(-c3ccc4c(c3)C3(c5ccccc5-c5ccccc53)c3cc(N(c5ccccc5)c5cccc6ccccc56)ccc3-4)cc2)cc1 ; c1ccc(-c2ccc(-c3ccc4c(c3)C3(c5ccccc5-c5ccccc53)c3cc(N(c5ccccc5)c5ccc(-c6ccccc6)cc5)ccc3-4)cc2)cc1 ; c1ccc(-c2ccc(-c3ccc4c(c3)C3(c5ccccc5-c5ccccc53)c3cc(N(c5ccc(-c6ccccc6)cc5)c5ccc(-c6ccccc6)cc5)ccc3-4)cc2)cc1]

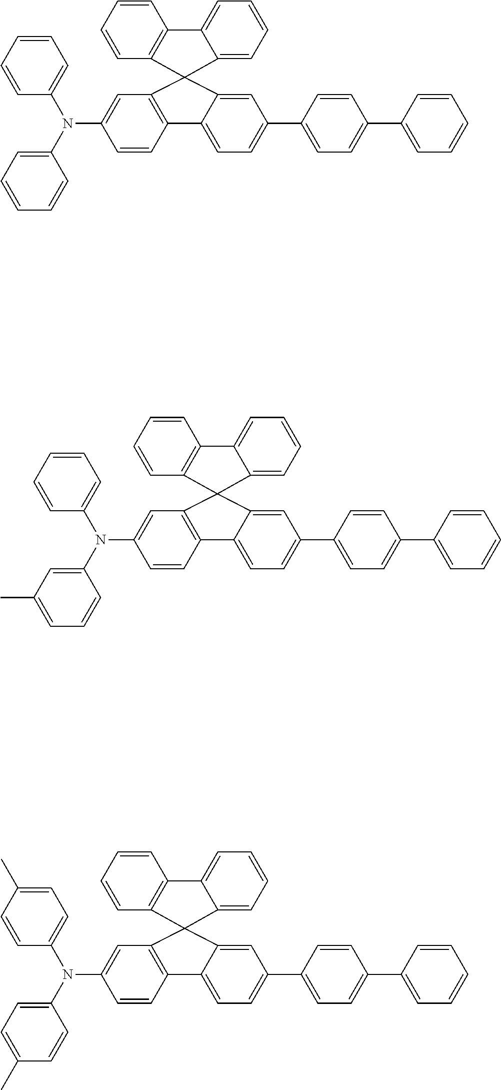 [SMILES: c1ccc(-c2ccc(-c3ccc4c(c3)C3(c5ccccc5-c5ccccc53)c3cc(N(c5ccccc5)c5ccccc5)ccc3-4)cc2)cc1 ; Cc1cccc(N(c2ccccc2)c2ccc3c(c2)C2(c4ccccc4-c4ccccc42)c2cc(-c4ccc(-c5ccccc5)cc4)ccc2-3)c1 ; Cc1ccc(N(c2ccc(C)cc2)c2ccc3c(c2)C2(c4ccccc4-c4ccccc42)c2cc(-c4ccc(-c5ccccc5)cc4)ccc2-3)cc1]

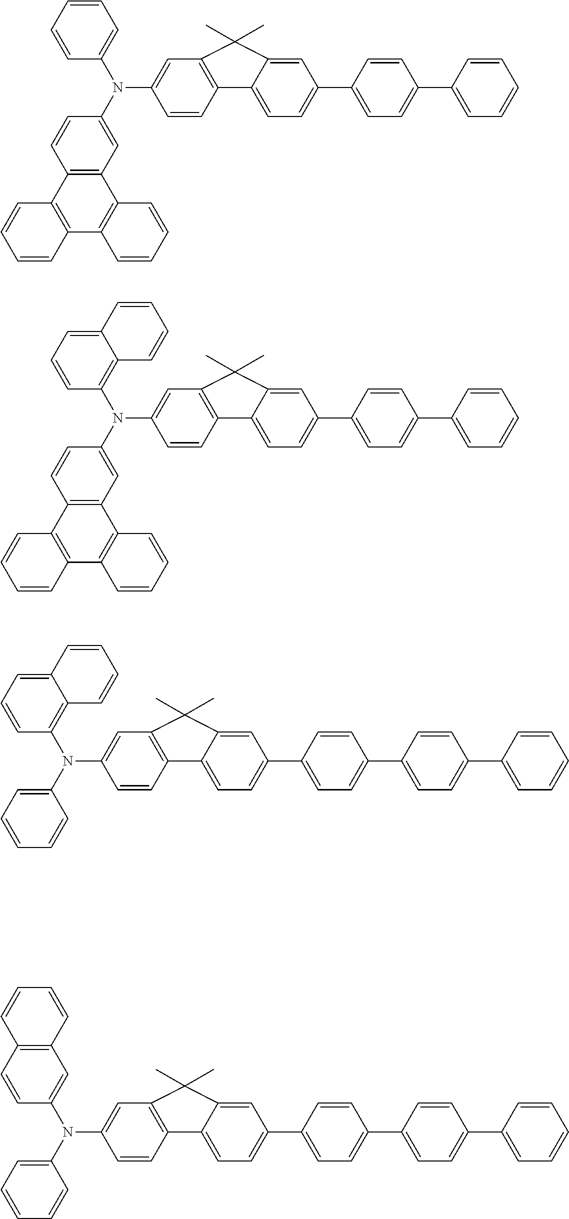

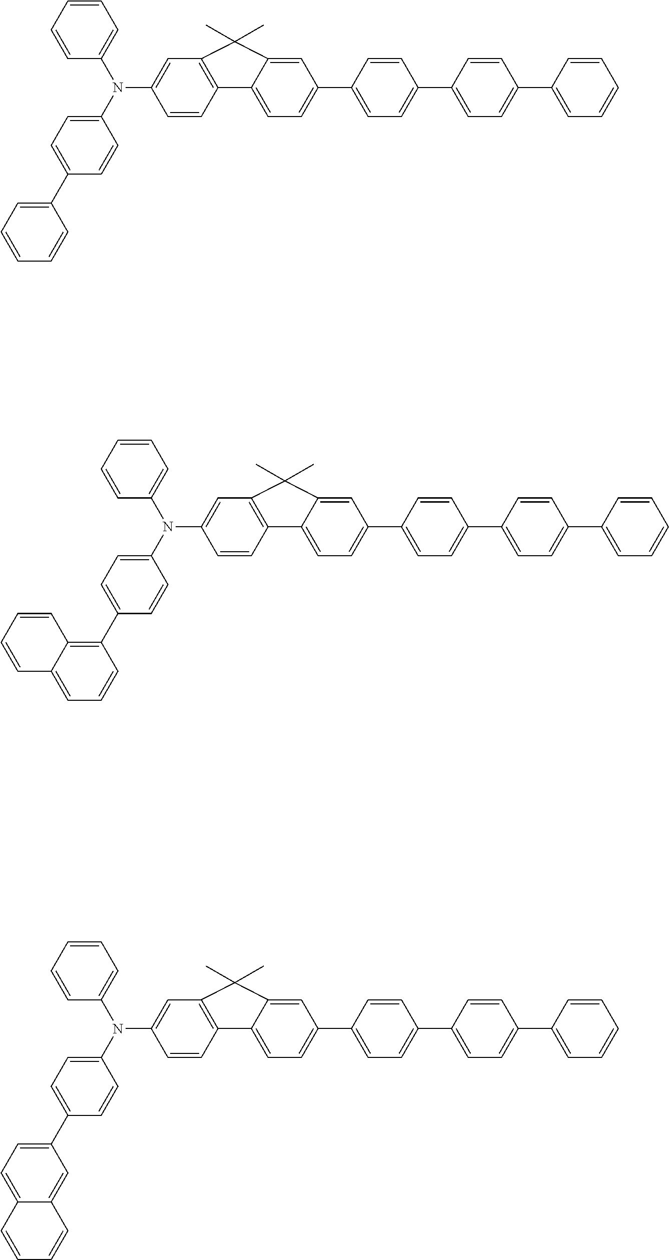 [SMILES: CC1(C)c2cc(-c3ccc(-c4ccc(-c5ccccc5)cc4)cc3)ccc2-c2ccc(N(c3ccccc3)c3ccc(-c4ccccc4)cc3)cc21 ; CC1(C)c2cc(-c3ccc(-c4ccc(-c5ccccc5)cc4)cc3)ccc2-c2ccc(N(c3ccccc3)c3ccc(-c4cccc5ccccc45)cc3)cc21 ; CC1(C)c2cc(-c3ccc(-c4ccc(-c5ccccc5)cc4)cc3)ccc2-c2ccc(N(c3ccccc3)c3ccc(-c4ccc5ccccc5c4)cc3)cc21]

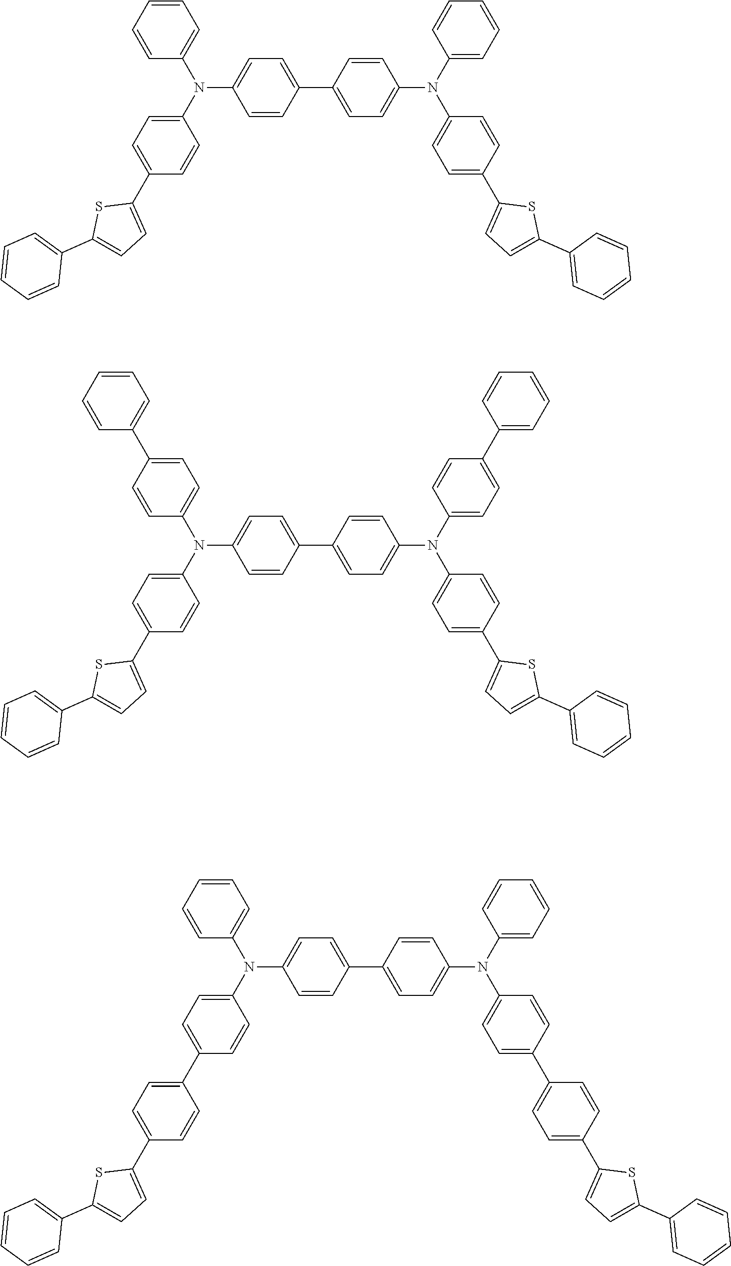 [SMILES: c1ccc(-c2ccc(-c3ccc(N(c4ccccc4)c4ccc(-c5ccc(N(c6ccccc6)c6ccc(-c7ccc(-c8ccccc8)s7)cc6)cc5)cc4)cc3)s2)cc1 ; c1ccc(-c2ccc(N(c3ccc(-c4ccc(N(c5ccc(-c6ccccc6)cc5)c5ccc(-c6ccc(-c7ccccc7)s6)cc5)cc4)cc3)c3ccc(-c4ccc(-c5ccccc5)s4)cc3)cc2)cc1 ; c1ccc(-c2ccc(-c3ccc(-c4ccc(N(c5ccccc5)c5ccc(-c6ccc(N(c7ccccc7)c7ccc(-c8ccc(-c9ccc(-c%10ccccc%10)s9)cc8)cc7)cc6)cc5)cc4)cc3)s2)cc1]

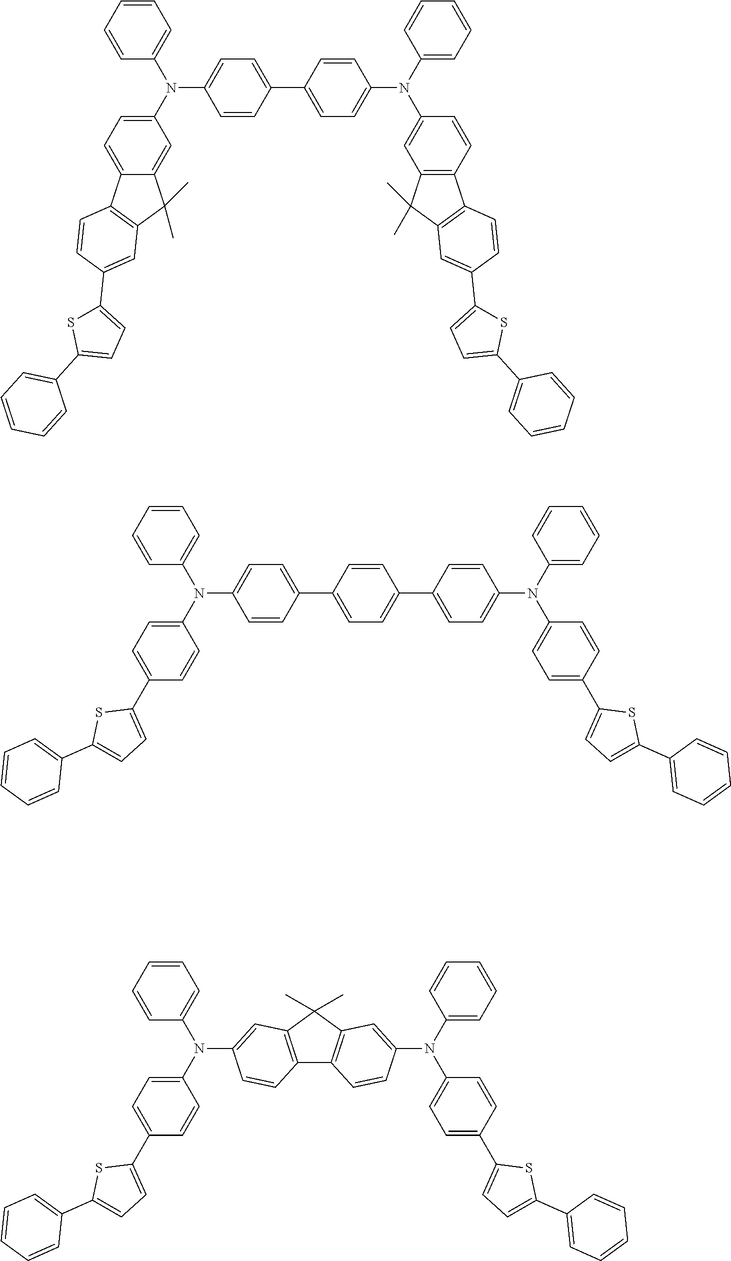 [SMILES: CC1(C)c2cc(-c3ccc(-c4ccccc4)s3)ccc2-c2ccc(N(c3ccccc3)c3ccc(-c4ccc(N(c5ccccc5)c5ccc6c(c5)C(C)(C)c5cc(-c7ccc(-c8ccccc8)s7)ccc5-6)cc4)cc3)cc21 ; c1ccc(-c2ccc(-c3ccc(N(c4ccccc4)c4ccc(-c5ccc(-c6ccc(N(c7ccccc7)c7ccc(-c8ccc(-c9ccccc9)s8)cc7)cc6)cc5)cc4)cc3)s2)cc1 ; CC1(C)c2cc(N(c3ccccc3)c3ccc(-c4ccc(-c5ccccc5)s4)cc3)ccc2-c2ccc(N(c3ccccc3)c3ccc(-c4ccc(-c5ccccc5)s4)cc3)cc21]

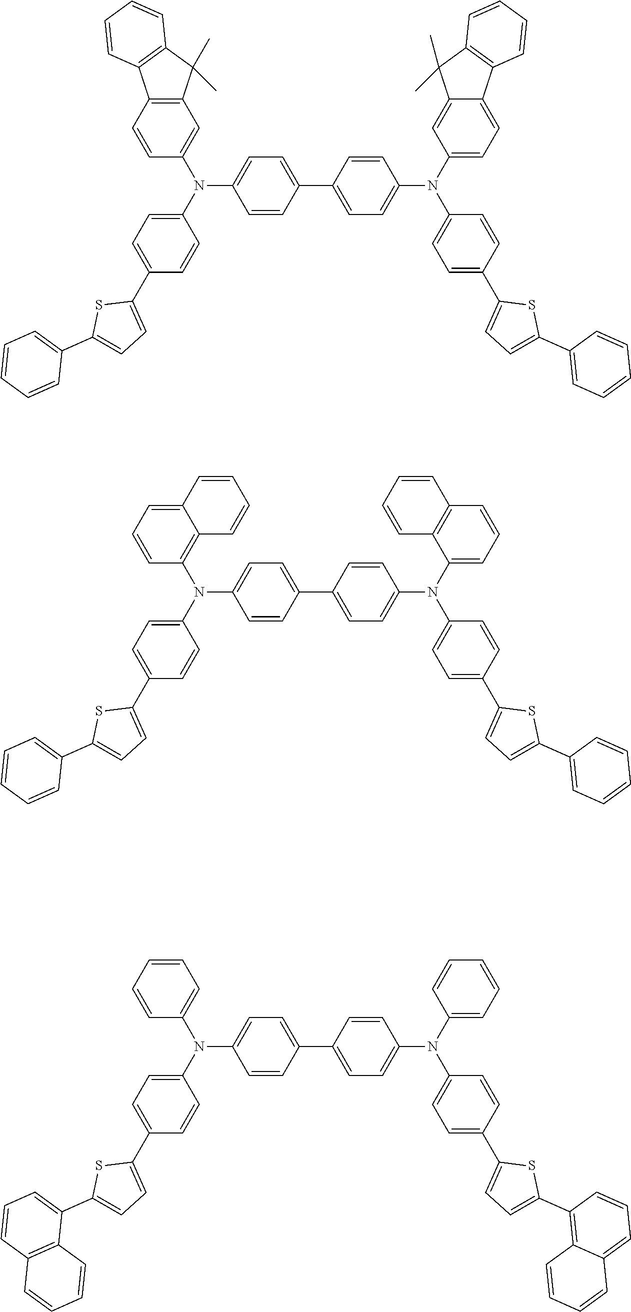 [SMILES: CC1(C)c2ccccc2-c2ccc(N(c3ccc(-c4ccc(N(c5ccc(-c6ccc(-c7ccccc7)s6)cc5)c5ccc6c(c5)C(C)(C)c5ccccc5-6)cc4)cc3)c3ccc(-c4ccc(-c5ccccc5)s4)cc3)cc21 ; c1ccc(-c2ccc(-c3ccc(N(c4ccc(-c5ccc(N(c6ccc(-c7ccc(-c8ccccc8)s7)cc6)c6cccc7ccccc67)cc5)cc4)c4cccc5ccccc45)cc3)s2)cc1 ; c1ccc(N(c2ccc(-c3ccc(N(c4ccccc4)c4ccc(-c5ccc(-c6cccc7ccccc67)s5)cc4)cc3)cc2)c2ccc(-c3ccc(-c4cccc5ccccc45)s3)cc2)cc1]

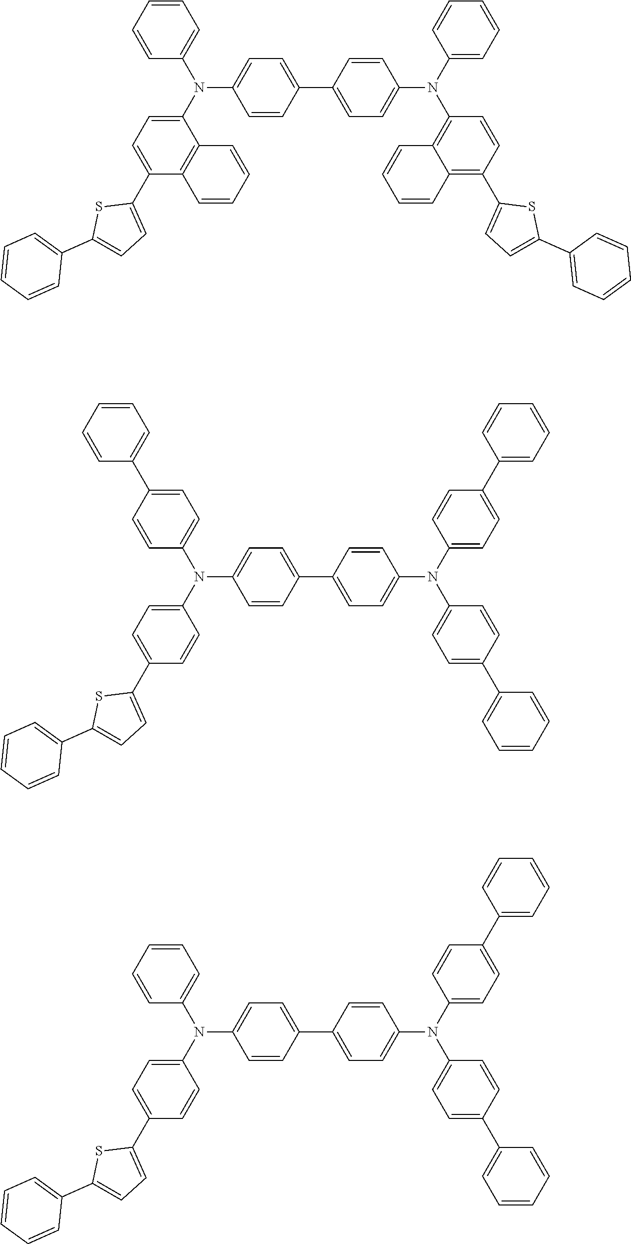 [SMILES: c1ccc(-c2ccc(-c3ccc(N(c4ccccc4)c4ccc(-c5ccc(N(c6ccccc6)c6ccc(-c7ccc(-c8ccccc8)s7)c7ccccc67)cc5)cc4)c4ccccc34)s2)cc1 ; c1ccc(-c2ccc(N(c3ccc(-c4ccccc4)cc3)c3ccc(-c4ccc(N(c5ccc(-c6ccccc6)cc5)c5ccc(-c6ccc(-c7ccccc7)s6)cc5)cc4)cc3)cc2)cc1 ; c1ccc(-c2ccc(N(c3ccc(-c4ccccc4)cc3)c3ccc(-c4ccc(N(c5ccccc5)c5ccc(-c6ccc(-c7ccccc7)s6)cc5)cc4)cc3)cc2)cc1]

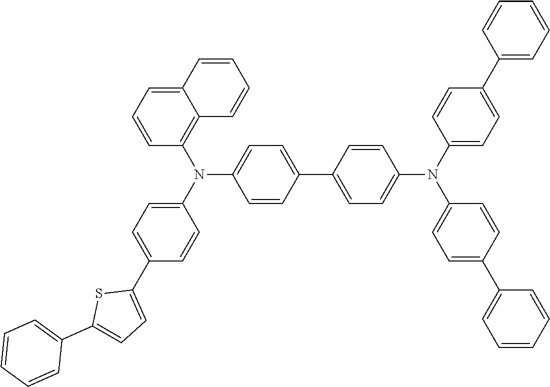 [SMILES: c1ccc(-c2ccc(N(c3ccc(-c4ccccc4)cc3)c3ccc(-c4ccc(N(c5ccc(-c6ccc(-c7ccccc7)s6)cc5)c5cccc6ccccc56)cc4)cc3)cc2)cc1]

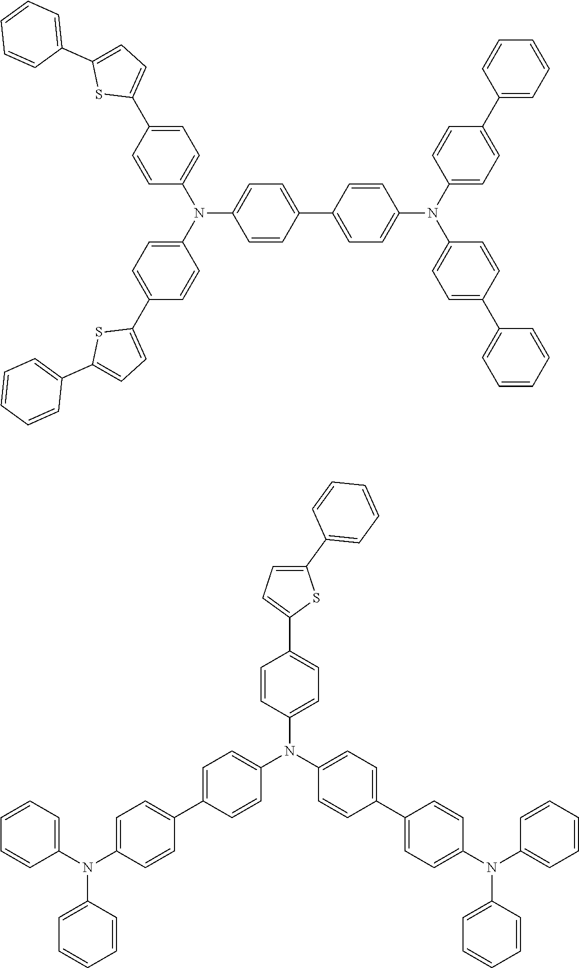 [SMILES: c1ccc(-c2ccc(N(c3ccc(-c4ccccc4)cc3)c3ccc(-c4ccc(N(c5ccc(-c6ccc(-c7ccccc7)s6)cc5)c5ccc(-c6ccc(-c7ccccc7)s6)cc5)cc4)cc3)cc2)cc1 ; c1ccc(-c2ccc(-c3ccc(N(c4ccc(-c5ccc(N(c6ccccc6)c6ccccc6)cc5)cc4)c4ccc(-c5ccc(N(c6ccccc6)c6ccccc6)cc5)cc4)cc3)s2)cc1]

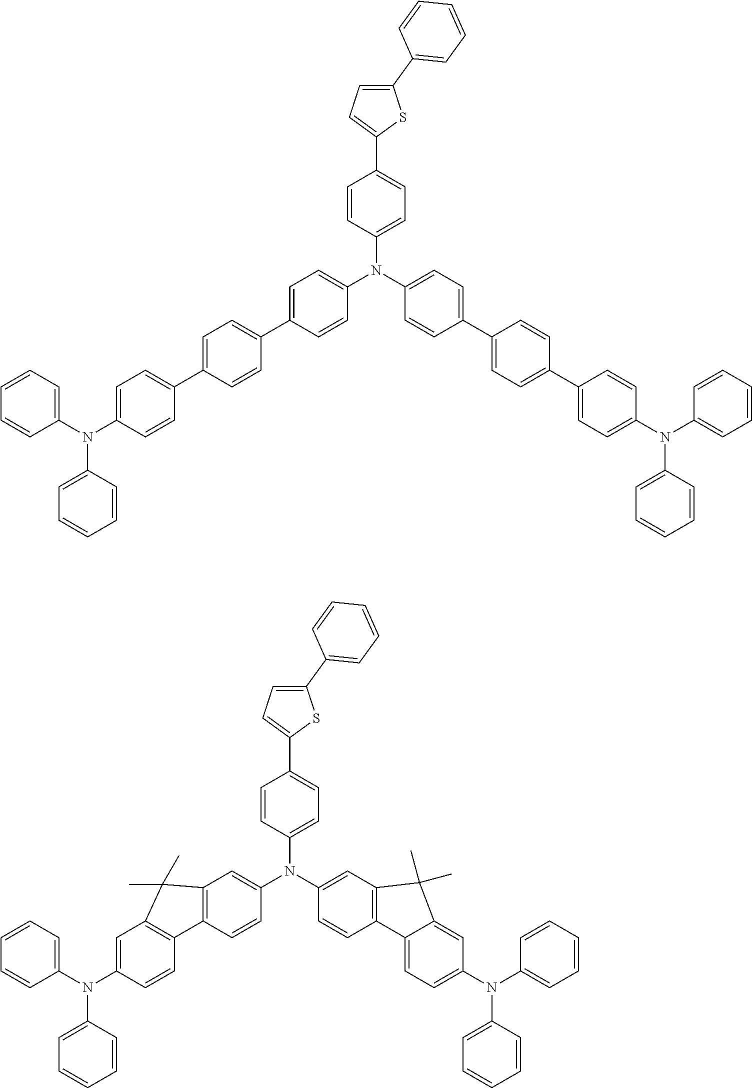 [SMILES: c1ccc(-c2ccc(-c3ccc(N(c4ccc(-c5ccc(-c6ccc(N(c7ccccc7)c7ccccc7)cc6)cc5)cc4)c4ccc(-c5ccc(-c6ccc(N(c7ccccc7)c7ccccc7)cc6)cc5)cc4)cc3)s2)cc1 ; CC1(C)c2cc(N(c3ccccc3)c3ccccc3)ccc2-c2ccc(N(c3ccc(-c4ccc(-c5ccccc5)s4)cc3)c3ccc4c(c3)C(C)(C)c3cc(N(c5ccccc5)c5ccccc5)ccc3-4)cc21]

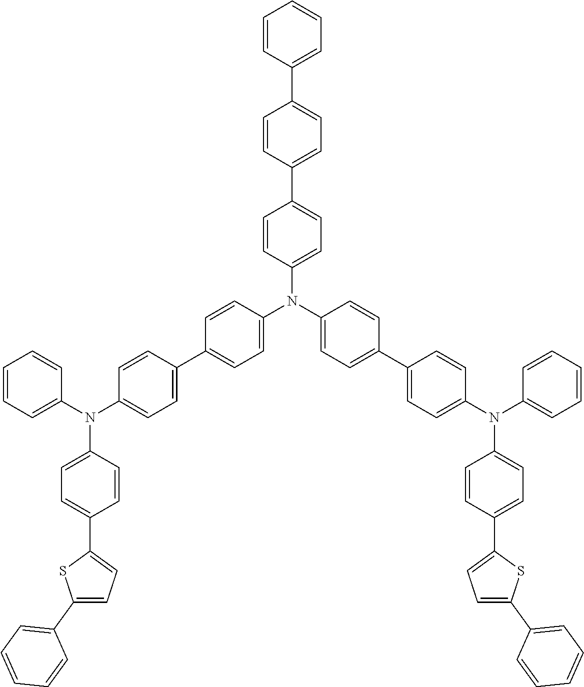 [SMILES: c1ccc(-c2ccc(-c3ccc(N(c4ccc(-c5ccc(N(c6ccccc6)c6ccc(-c7ccc(-c8ccccc8)s7)cc6)cc5)cc4)c4ccc(-c5ccc(N(c6ccccc6)c6ccc(-c7ccc(-c8ccccc8)s7)cc6)cc5)cc4)cc3)cc2)cc1]

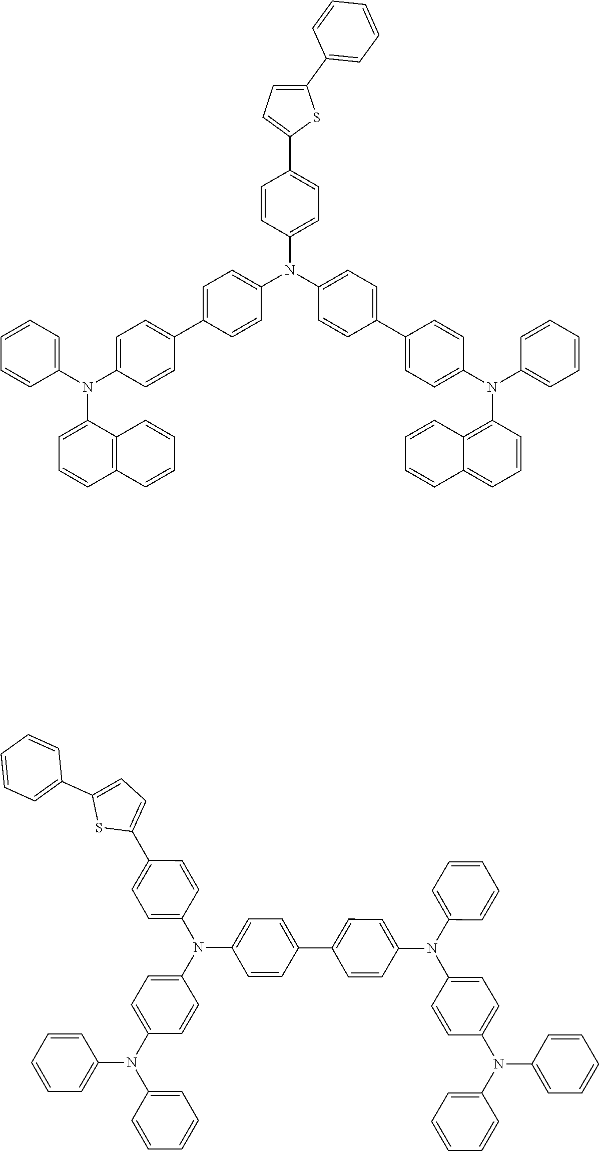 [SMILES: c1ccc(-c2ccc(-c3ccc(N(c4ccc(-c5ccc(N(c6ccccc6)c6cccc7ccccc67)cc5)cc4)c4ccc(-c5ccc(N(c6ccccc6)c6cccc7ccccc67)cc5)cc4)cc3)s2)cc1 ; c1ccc(-c2ccc(-c3ccc(N(c4ccc(-c5ccc(N(c6ccccc6)c6ccc(N(c7ccccc7)c7ccccc7)cc6)cc5)cc4)c4ccc(N(c5ccccc5)c5ccccc5)cc4)cc3)s2)cc1]

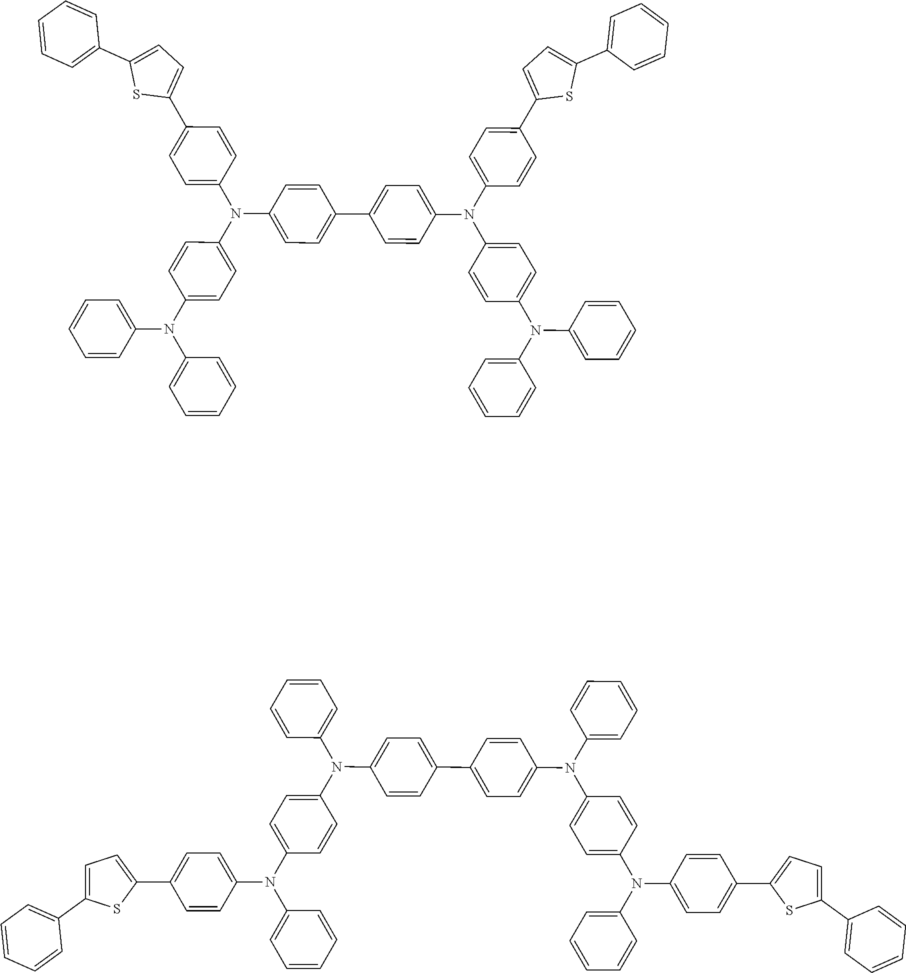 [SMILES: c1ccc(-c2ccc(-c3ccc(N(c4ccc(-c5ccc(N(c6ccc(-c7ccc(-c8ccccc8)s7)cc6)c6ccc(N(c7ccccc7)c7ccccc7)cc6)cc5)cc4)c4ccc(N(c5ccccc5)c5ccccc5)cc4)cc3)s2)cc1 ; c1ccc(-c2ccc(-c3ccc(N(c4ccccc4)c4ccc(N(c5ccccc5)c5ccc(-c6ccc(N(c7ccccc7)c7ccc(N(c8ccccc8)c8ccc(-c9ccc(-c%10ccccc%10)s9)cc8)cc7)cc6)cc5)cc4)cc3)s2)cc1]

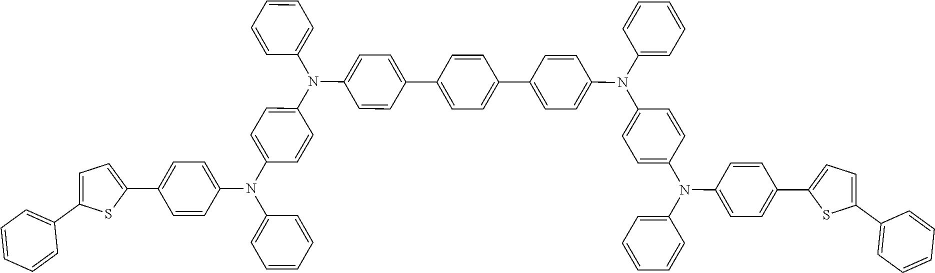 [SMILES: c1ccc(-c2ccc(-c3ccc(N(c4ccccc4)c4ccc(N(c5ccccc5)c5ccc(-c6ccc(-c7ccc(N(c8ccccc8)c8ccc(N(c9ccccc9)c9ccc(-c%10ccc(-c%11ccccc%11)s%10)cc9)cc8)cc7)cc6)cc5)cc4)cc3)s2)cc1]

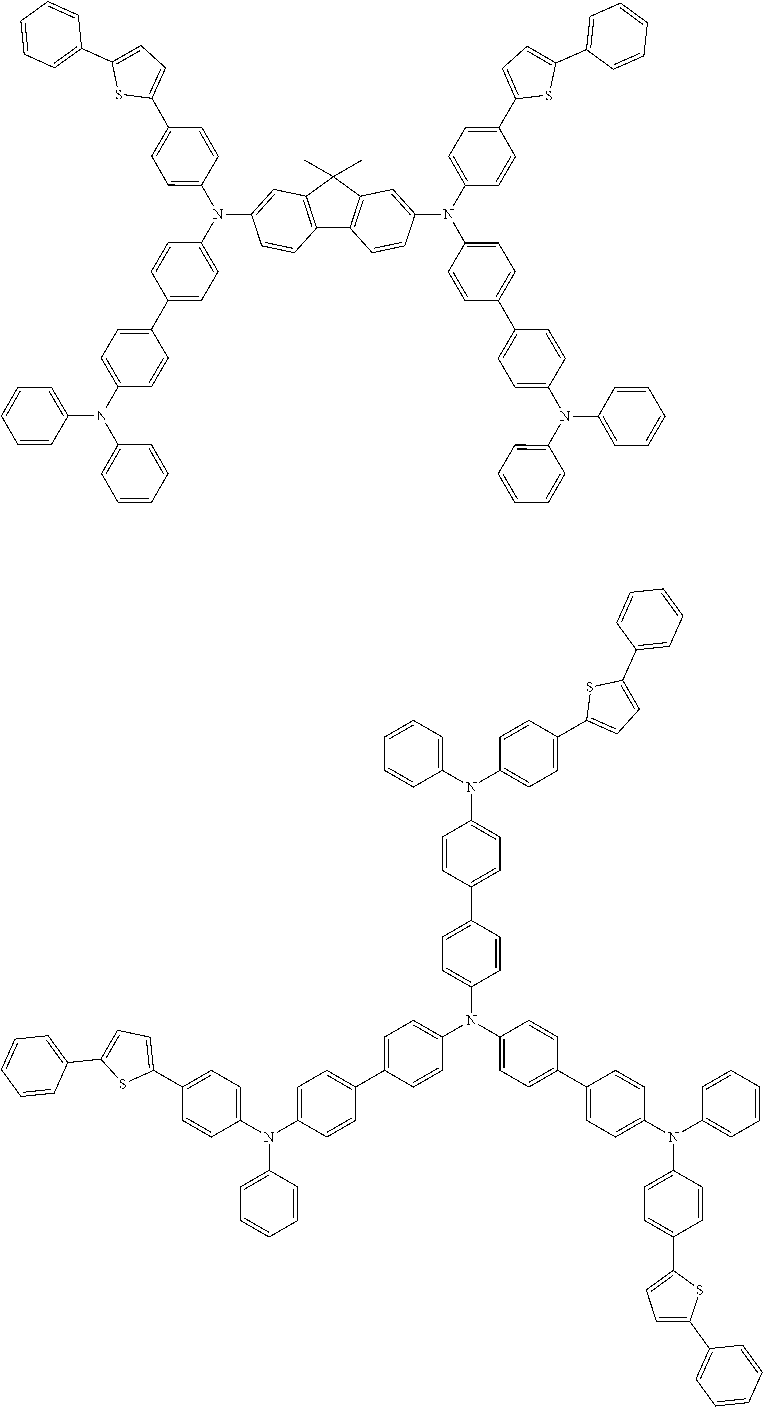 [SMILES: CC1(C)c2cc(N(c3ccc(-c4ccc(N(c5ccccc5)c5ccccc5)cc4)cc3)c3ccc(-c4ccc(-c5ccccc5)s4)cc3)ccc2-c2ccc(N(c3ccc(-c4ccc(N(c5ccccc5)c5ccccc5)cc4)cc3)c3ccc(-c4ccc(-c5ccccc5)s4)cc3)cc21 ; c1ccc(-c2ccc(-c3ccc(N(c4ccccc4)c4ccc(-c5ccc(N(c6ccc(-c7ccc(N(c8ccccc8)c8ccc(-c9ccc(-c%10ccccc%10)s9)cc8)cc7)cc6)c6ccc(-c7ccc(N(c8ccccc8)c8ccc(-c9ccc(-c%10ccccc%10)s9)cc8)cc7)cc6)cc5)cc4)cc3)s2)cc1]

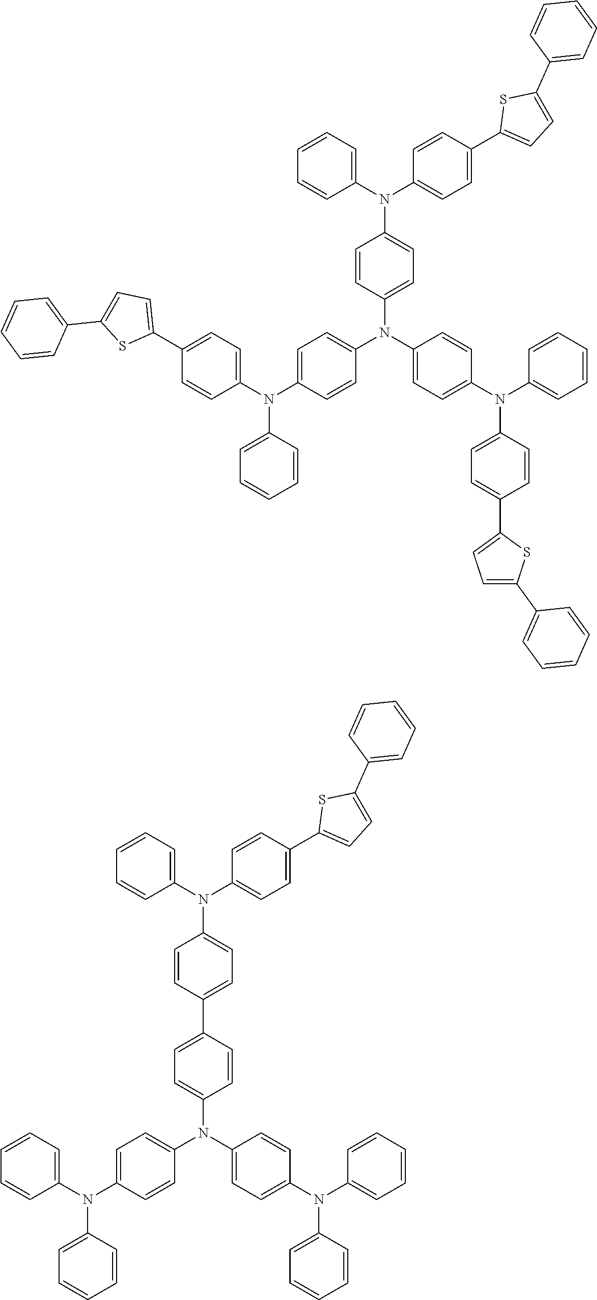 [SMILES: c1ccc(-c2ccc(-c3ccc(N(c4ccccc4)c4ccc(N(c5ccc(N(c6ccccc6)c6ccc(-c7ccc(-c8ccccc8)s7)cc6)cc5)c5ccc(N(c6ccccc6)c6ccc(-c7ccc(-c8ccccc8)s7)cc6)cc5)cc4)cc3)s2)cc1 ; c1ccc(-c2ccc(-c3ccc(N(c4ccccc4)c4ccc(-c5ccc(N(c6ccc(N(c7ccccc7)c7ccccc7)cc6)c6ccc(N(c7ccccc7)c7ccccc7)cc6)cc5)cc4)cc3)s2)cc1]

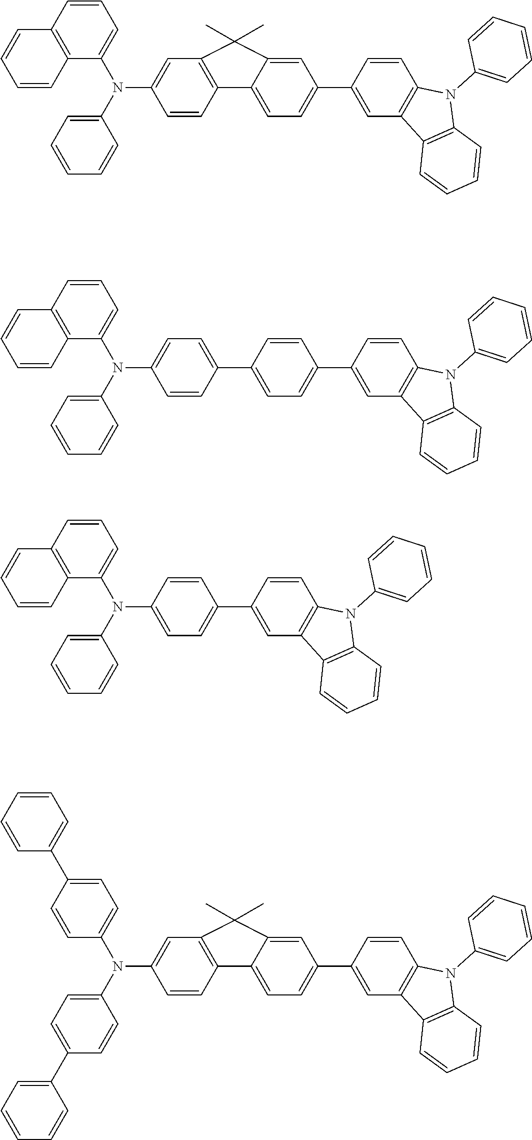 [SMILES: CC1(C)c2cc(-c3ccc4c(c3)c3ccccc3n4-c3ccccc3)ccc2-c2ccc(N(c3ccccc3)c3cccc4ccccc34)cc21 ; c1ccc(N(c2ccc(-c3ccc(-c4ccc5c(c4)c4ccccc4n5-c4ccccc4)cc3)cc2)c2cccc3ccccc23)cc1 ; c1ccc(N(c2ccc(-c3ccc4c(c3)c3ccccc3n4-c3ccccc3)cc2)c2cccc3ccccc23)cc1 ; CC1(C)c2cc(-c3ccc4c(c3)c3ccccc3n4-c3ccccc3)ccc2-c2ccc(N(c3ccc(-c4ccccc4)cc3)c3ccc(-c4ccccc4)cc3)cc21]

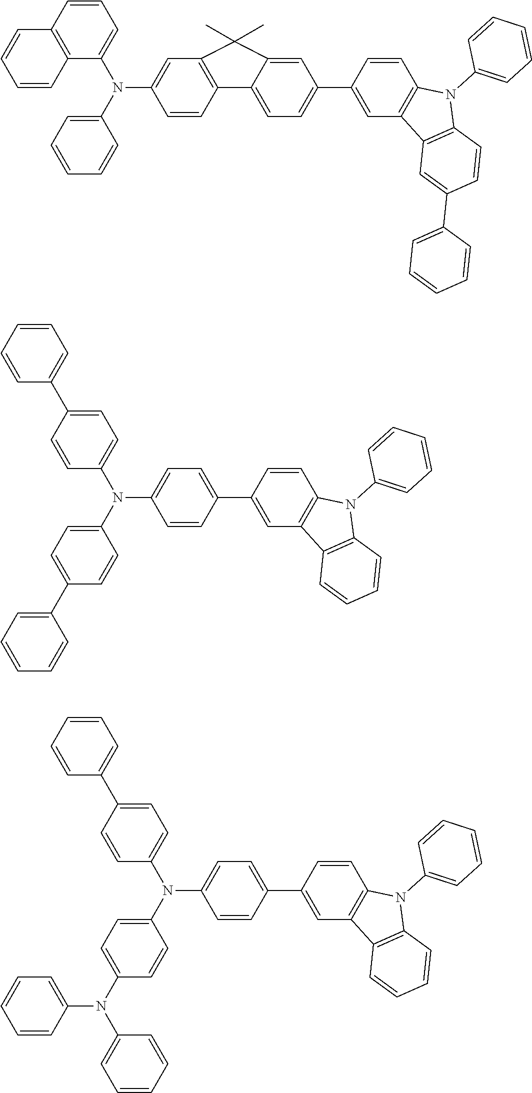 [SMILES: CC1(C)c2cc(-c3ccc4c(c3)c3cc(-c5ccccc5)ccc3n4-c3ccccc3)ccc2-c2ccc(N(c3ccccc3)c3cccc4ccccc34)cc21 ; c1ccc(-c2ccc(N(c3ccc(-c4ccccc4)cc3)c3ccc(-c4ccc5c(c4)c4ccccc4n5-c4ccccc4)cc3)cc2)cc1 ; c1ccc(-c2ccc(N(c3ccc(-c4ccc5c(c4)c4ccccc4n5-c4ccccc4)cc3)c3ccc(N(c4ccccc4)c4ccccc4)cc3)cc2)cc1]

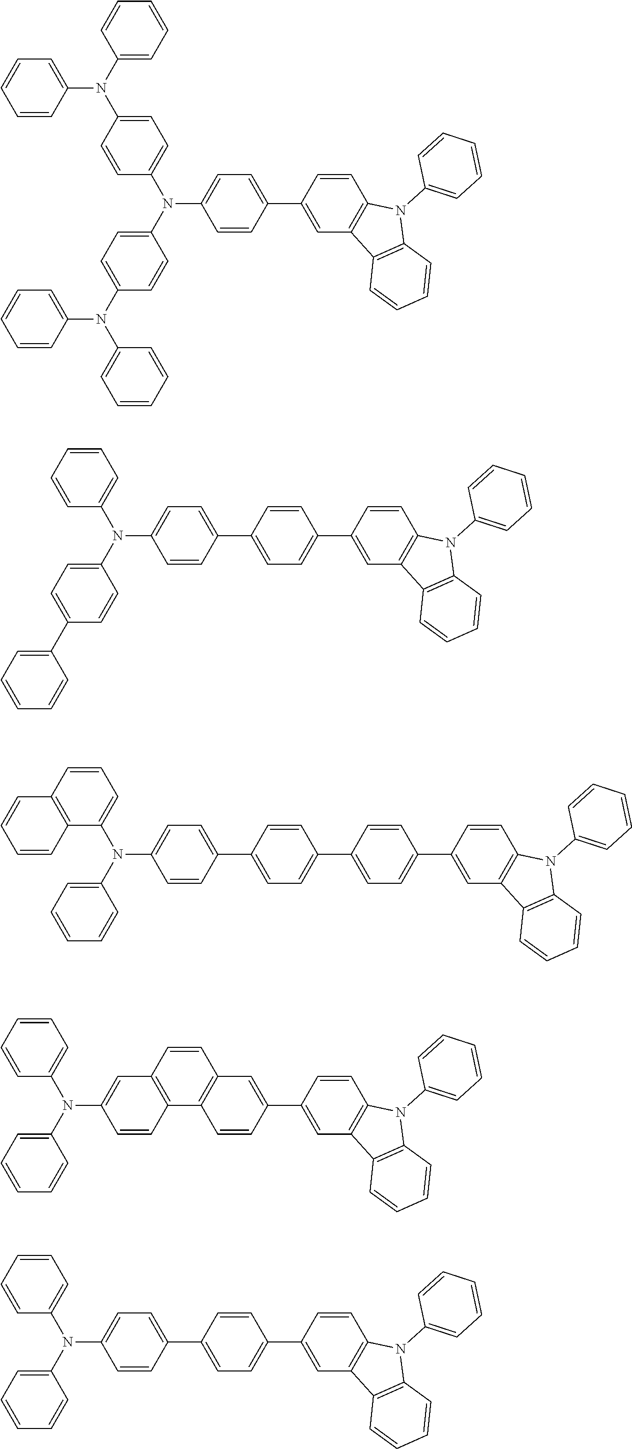

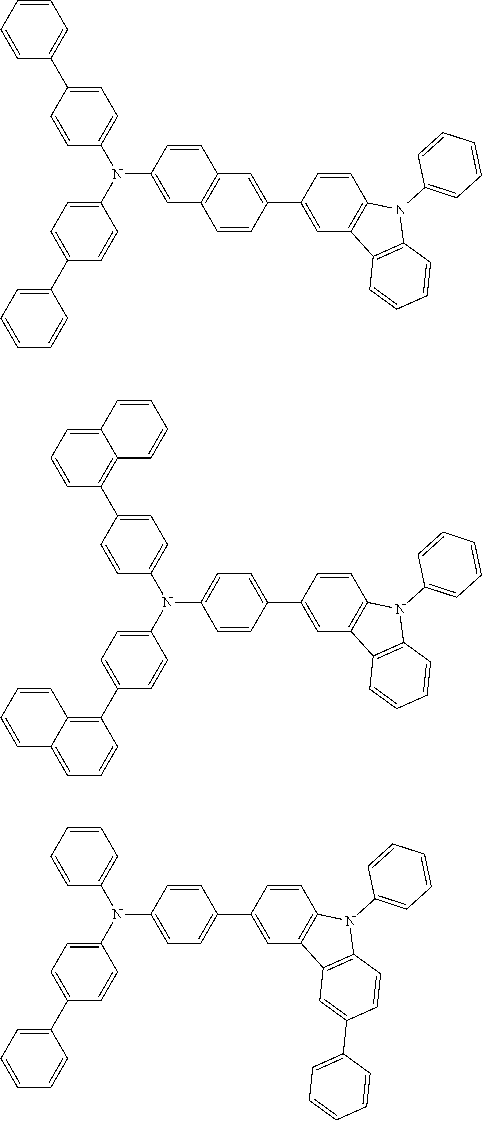 [SMILES: c1ccc(-c2ccc(N(c3ccc(-c4ccccc4)cc3)c3ccc4cc(-c5ccc6c(c5)c5ccccc5n6-c5ccccc5)ccc4c3)cc2)cc1 ; c1ccc(-n2c3ccccc3c3cc(-c4ccc(N(c5ccc(-c6cccc7ccccc67)cc5)c5ccc(-c6cccc7ccccc67)cc5)cc4)ccc32)cc1 ; c1ccc(-c2ccc(N(c3ccccc3)c3ccc(-c4ccc5c(c4)c4cc(-c6ccccc6)ccc4n5-c4ccccc4)cc3)cc2)cc1]

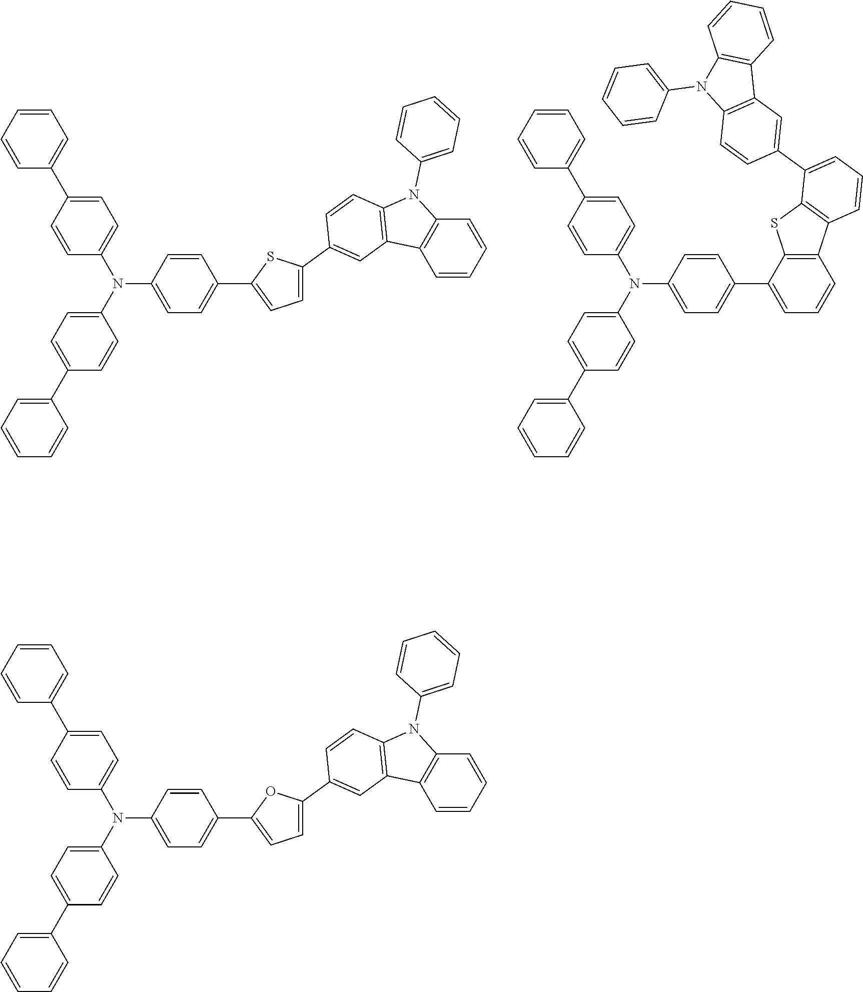 [SMILES: c1ccc(-c2ccc(N(c3ccc(-c4ccccc4)cc3)c3ccc(-c4ccc(-c5ccc6c(c5)c5ccccc5n6-c5ccccc5)s4)cc3)cc2)cc1 ; c1ccc(-c2ccc(N(c3ccc(-c4ccccc4)cc3)c3ccc(-c4cccc5c4sc4c(-c6ccc7c(c6)c6ccccc6n7-c6ccccc6)cccc45)cc3)cc2)cc1 ; c1ccc(-c2ccc(N(c3ccc(-c4ccccc4)cc3)c3ccc(-c4ccc(-c5ccc6c(c5)c5ccccc5n6-c5ccccc5)o4)cc3)cc2)cc1]

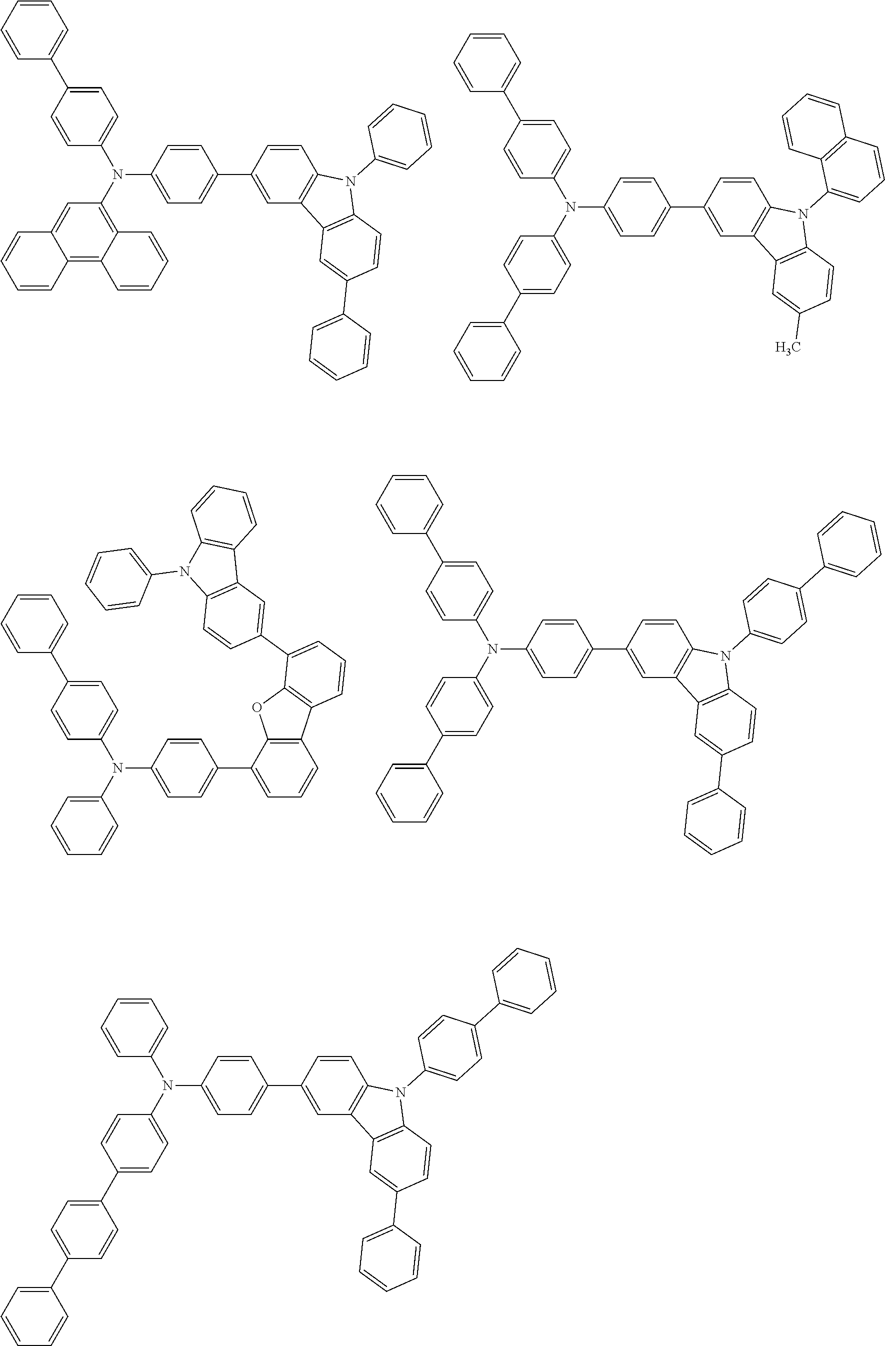

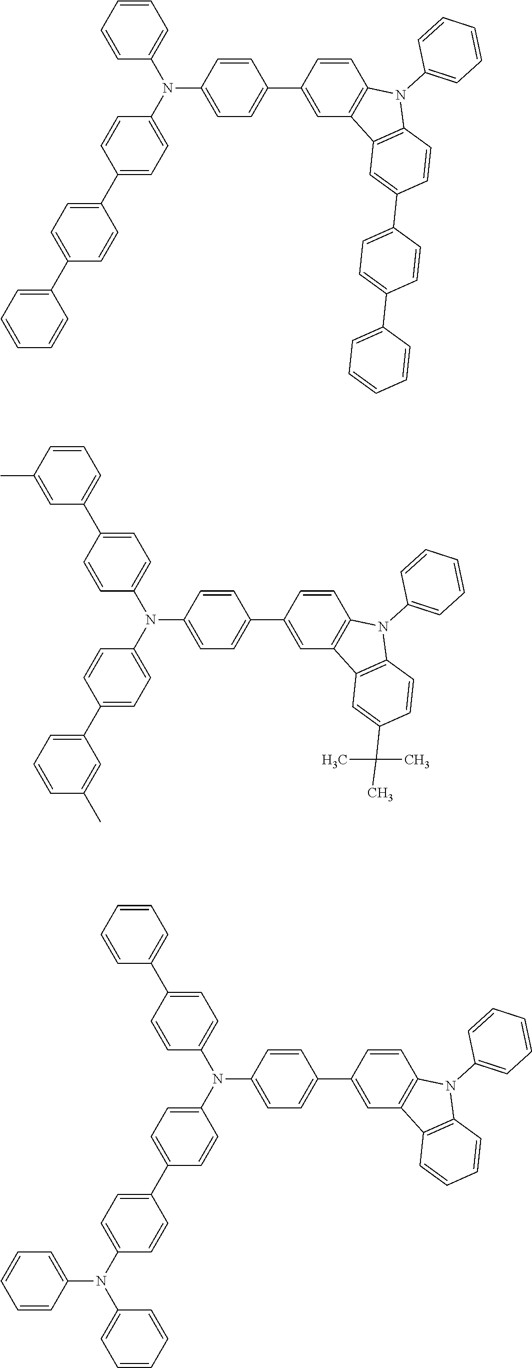 [SMILES: c1ccc(-c2ccc(-c3ccc(N(c4ccccc4)c4ccc(-c5ccc6c(c5)c5cc(-c7ccc(-c8ccccc8)cc7)ccc5n6-c5ccccc5)cc4)cc3)cc2)cc1 ; Cc1cccc(-c2ccc(N(c3ccc(-c4cccc(C)c4)cc3)c3ccc(-c4ccc5c(c4)c4cc(C(C)(C)C)ccc4n5-c4ccccc4)cc3)cc2)c1 ; c1ccc(-c2ccc(N(c3ccc(-c4ccc(N(c5ccccc5)c5ccccc5)cc4)cc3)c3ccc(-c4ccc5c(c4)c4ccccc4n5-c4ccccc4)cc3)cc2)cc1]

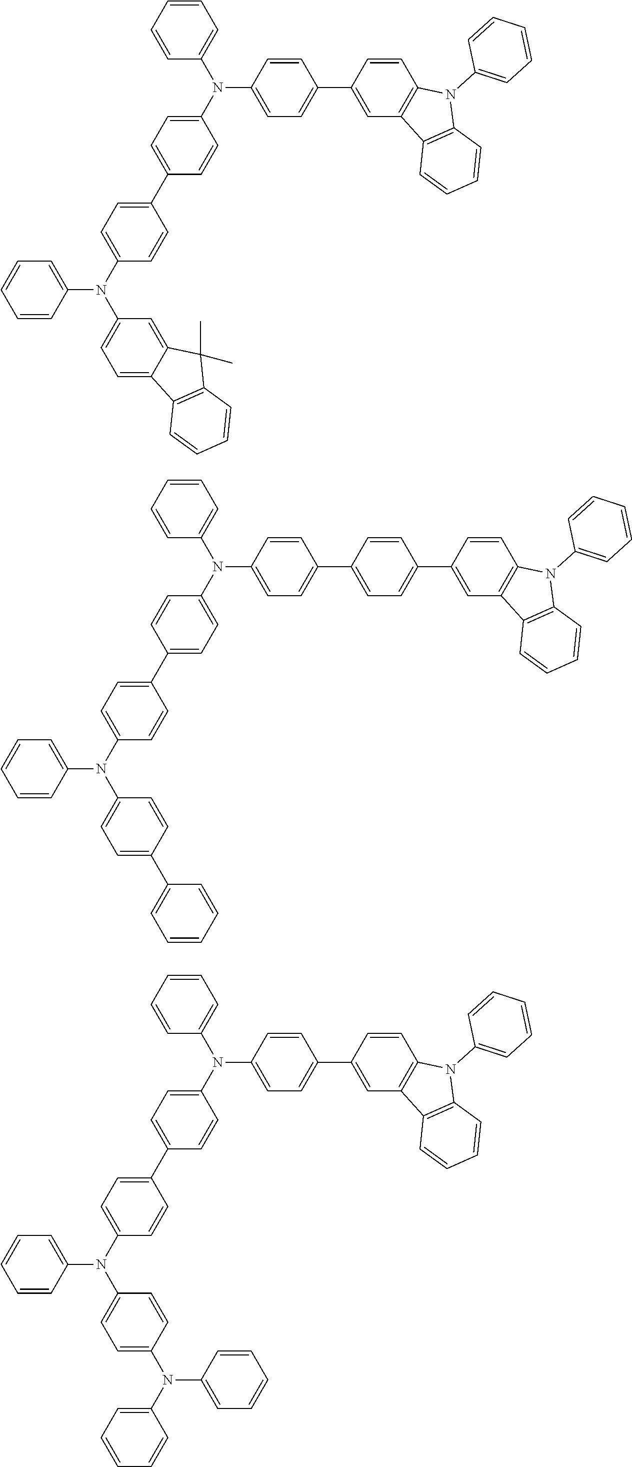

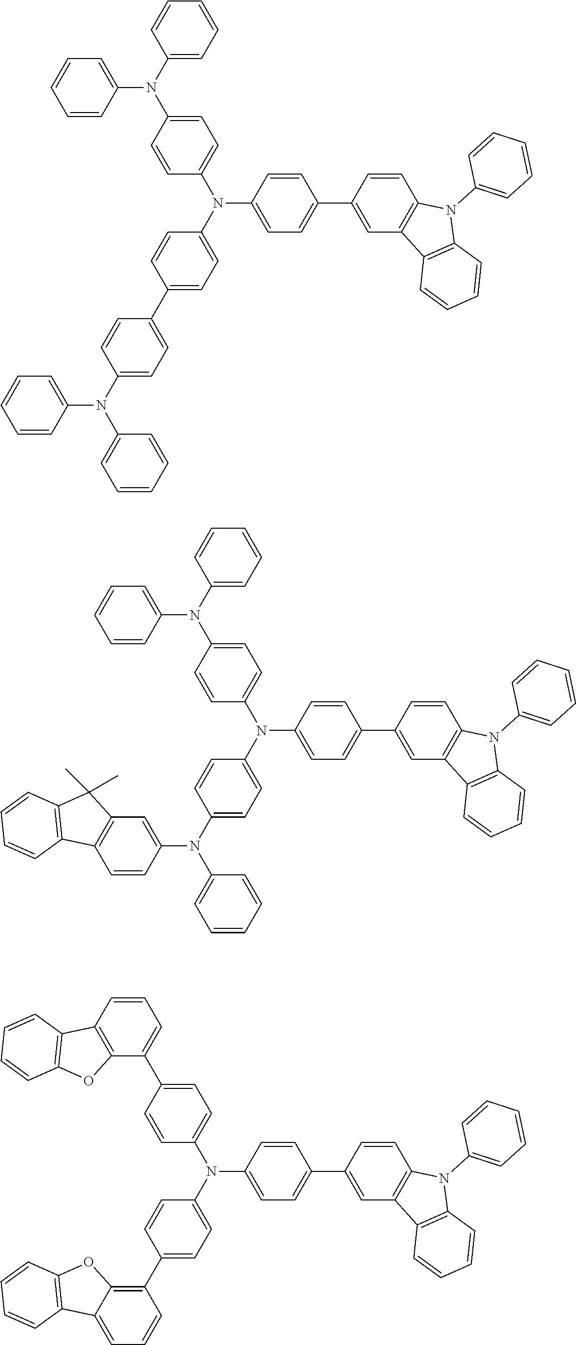 [SMILES: c1ccc(N(c2ccccc2)c2ccc(-c3ccc(N(c4ccc(-c5ccc6c(c5)c5ccccc5n6-c5ccccc5)cc4)c4ccc(N(c5ccccc5)c5ccccc5)cc4)cc3)cc2)cc1 ; CC1(C)c2ccccc2-c2ccc(N(c3ccccc3)c3ccc(N(c4ccc(-c5ccc6c(c5)c5ccccc5n6-c5ccccc5)cc4)c4ccc(N(c5ccccc5)c5ccccc5)cc4)cc3)cc21 ; c1ccc(-n2c3ccccc3c3cc(-c4ccc(N(c5ccc(-c6cccc7c6oc6ccccc67)cc5)c5ccc(-c6cccc7c6oc6ccccc67)cc5)cc4)ccc32)cc1]

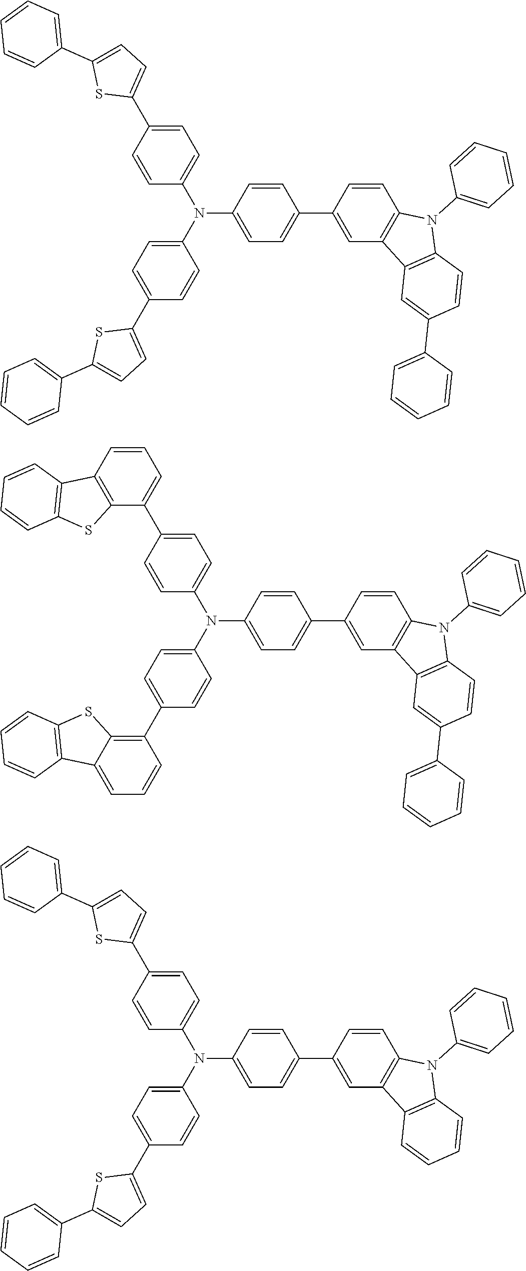

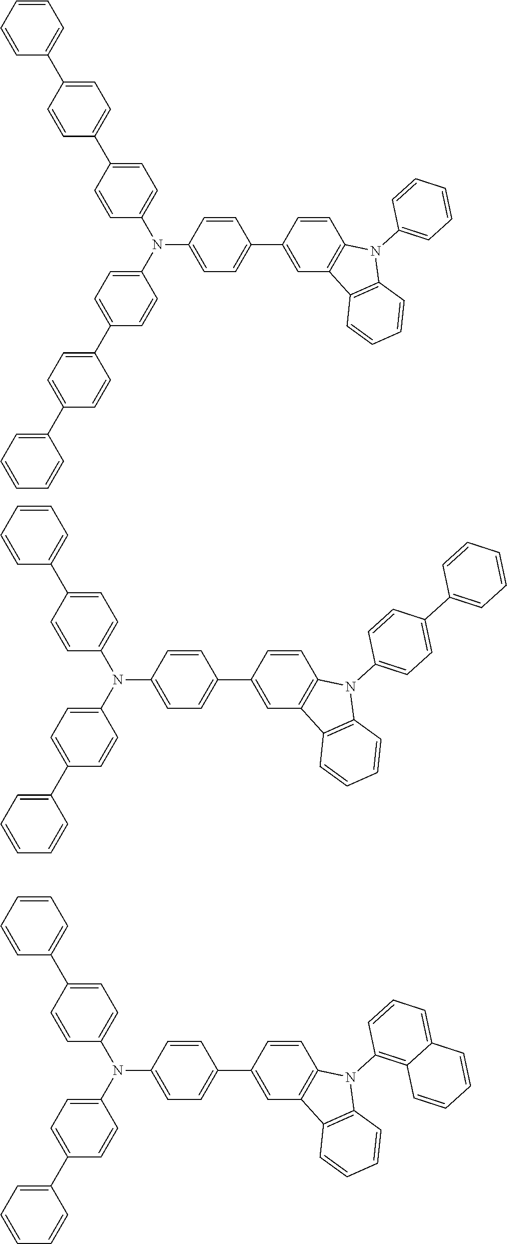

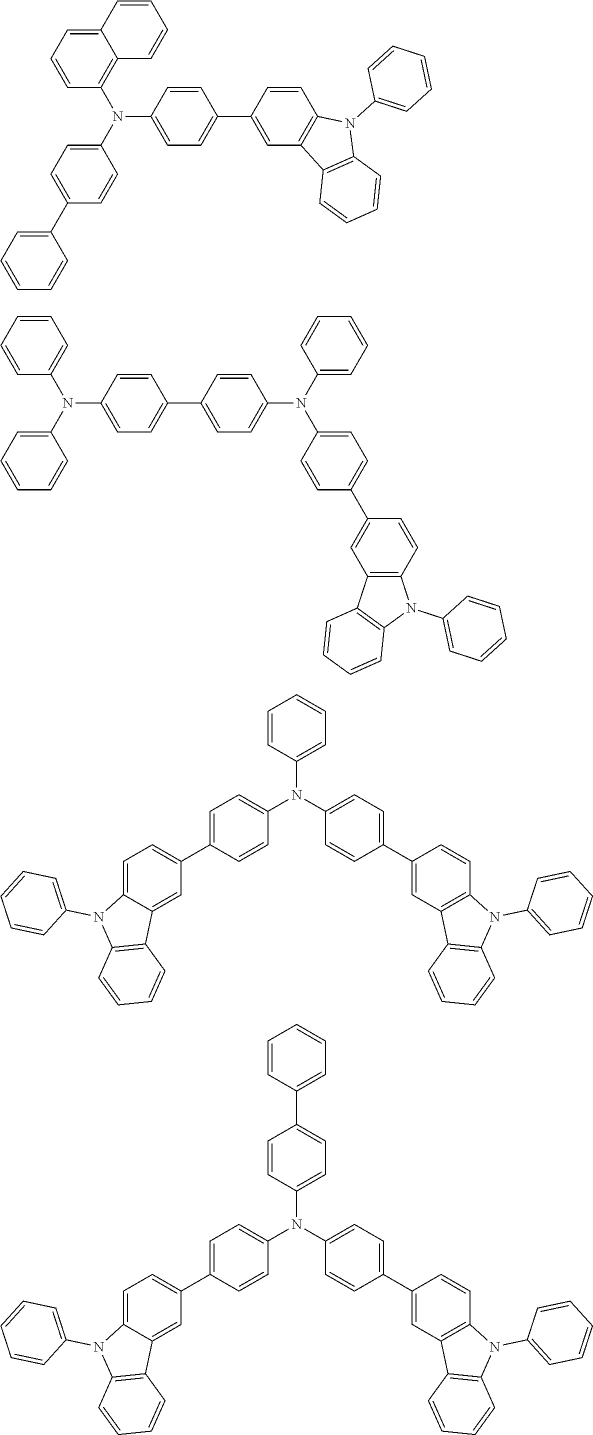

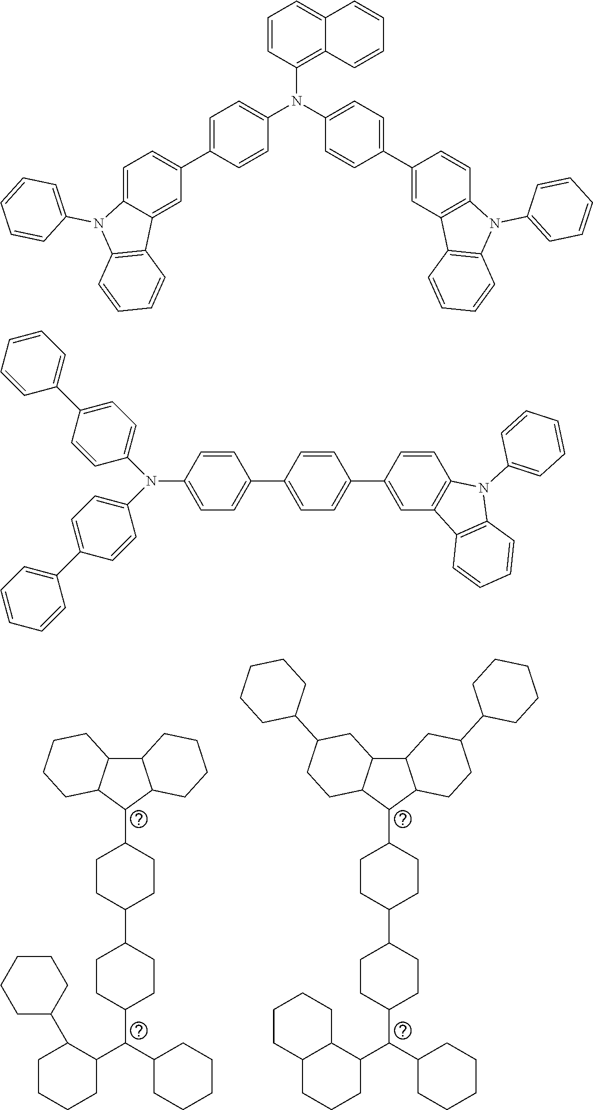

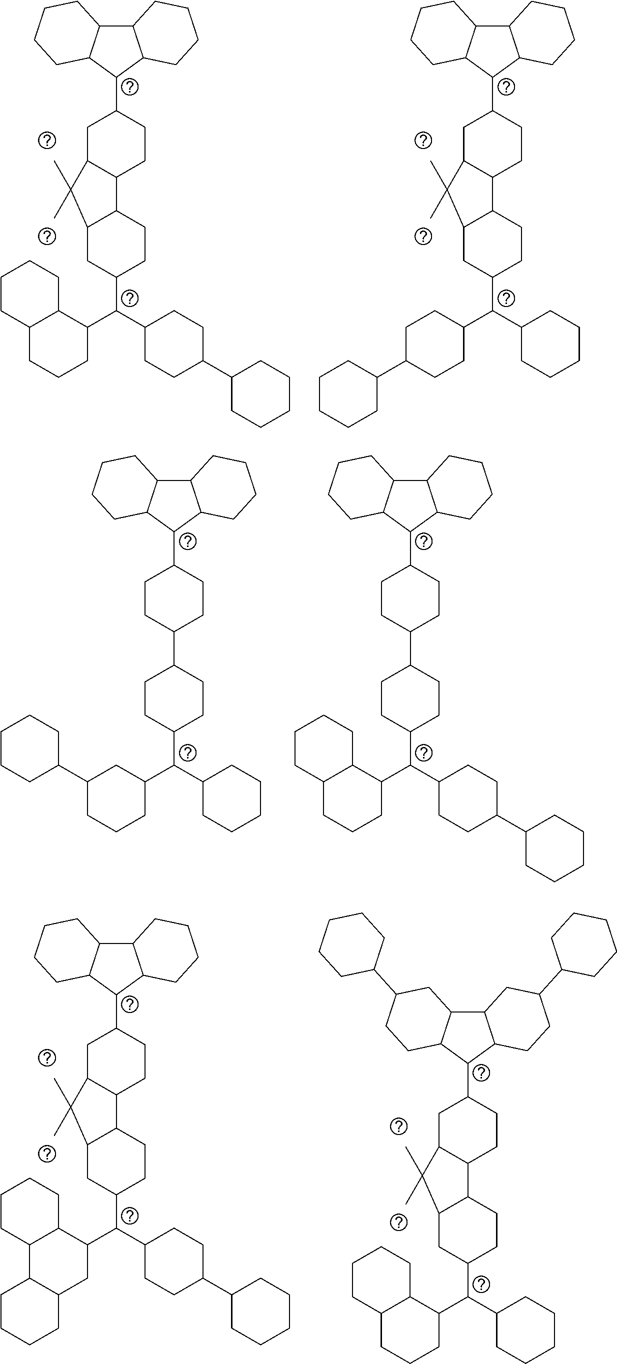

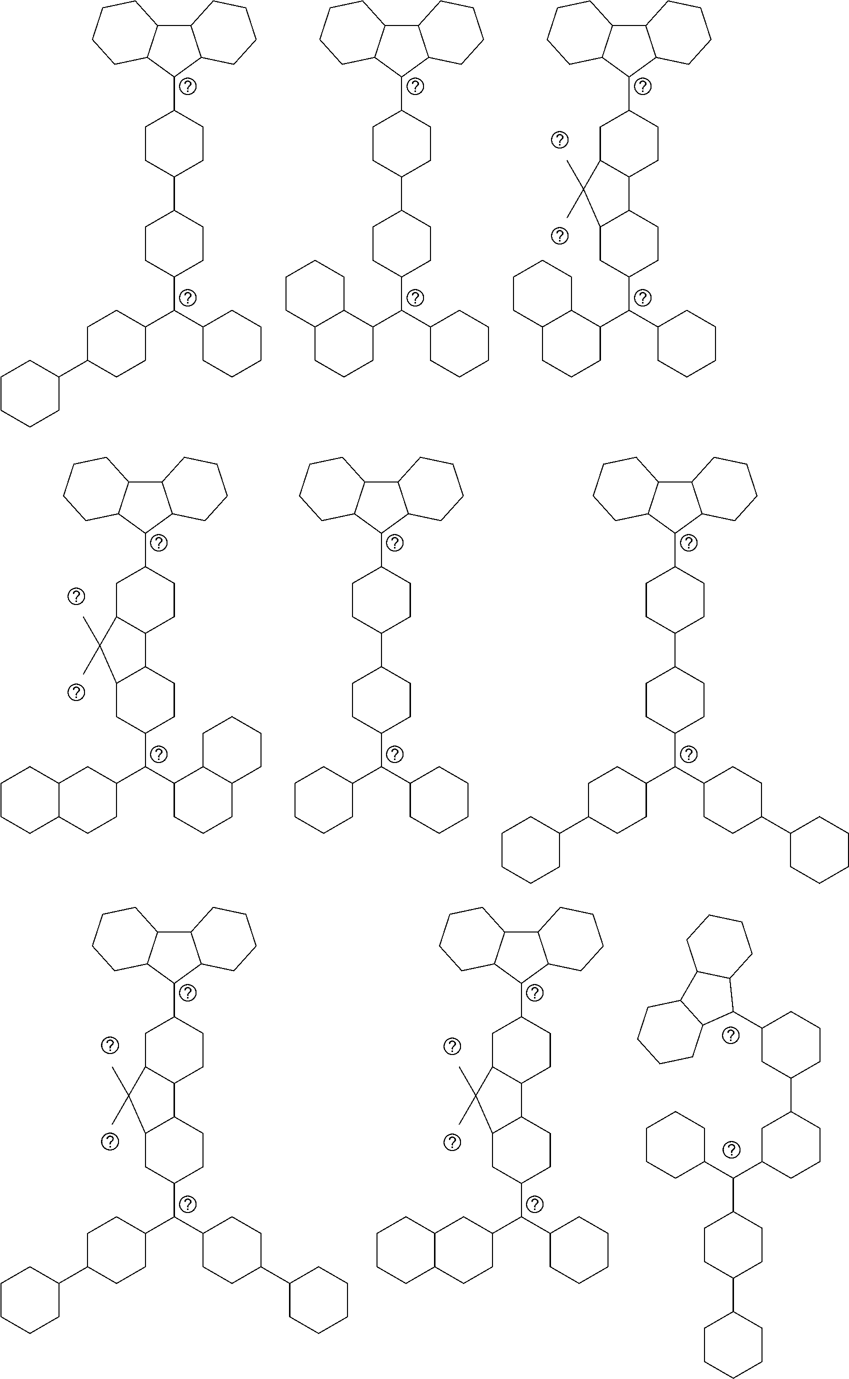

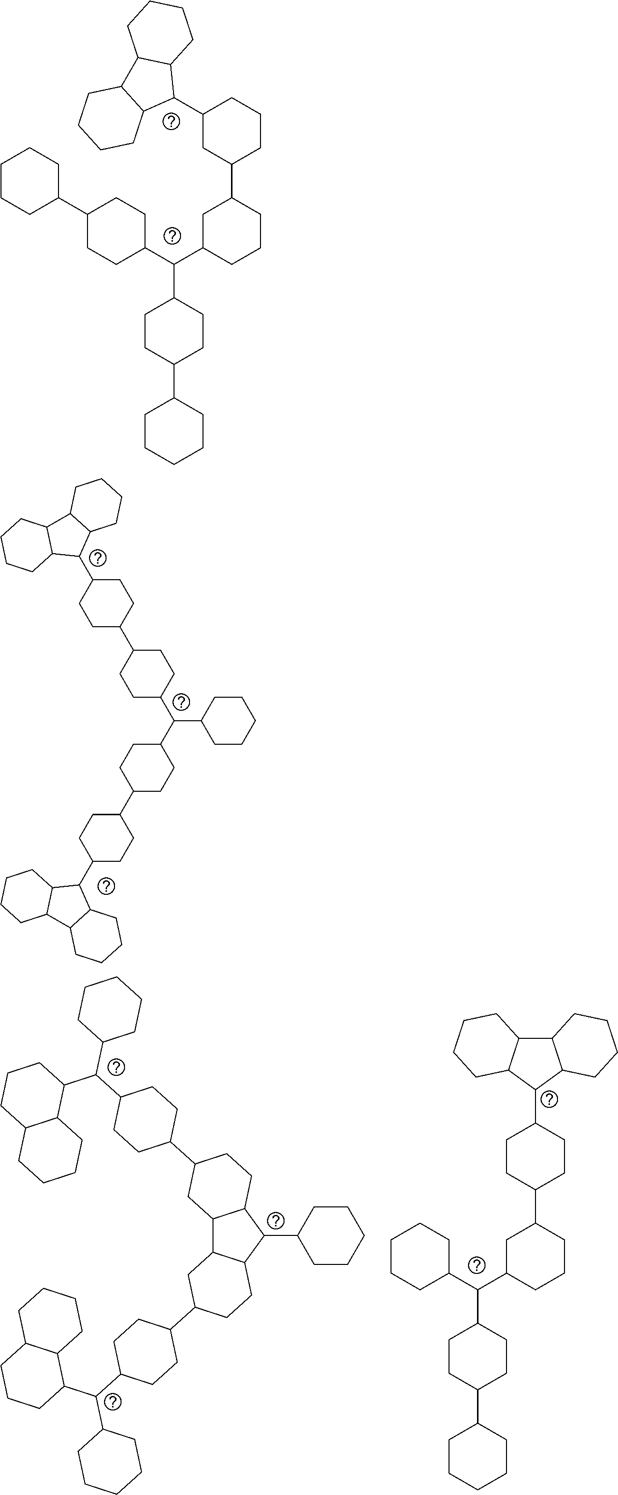

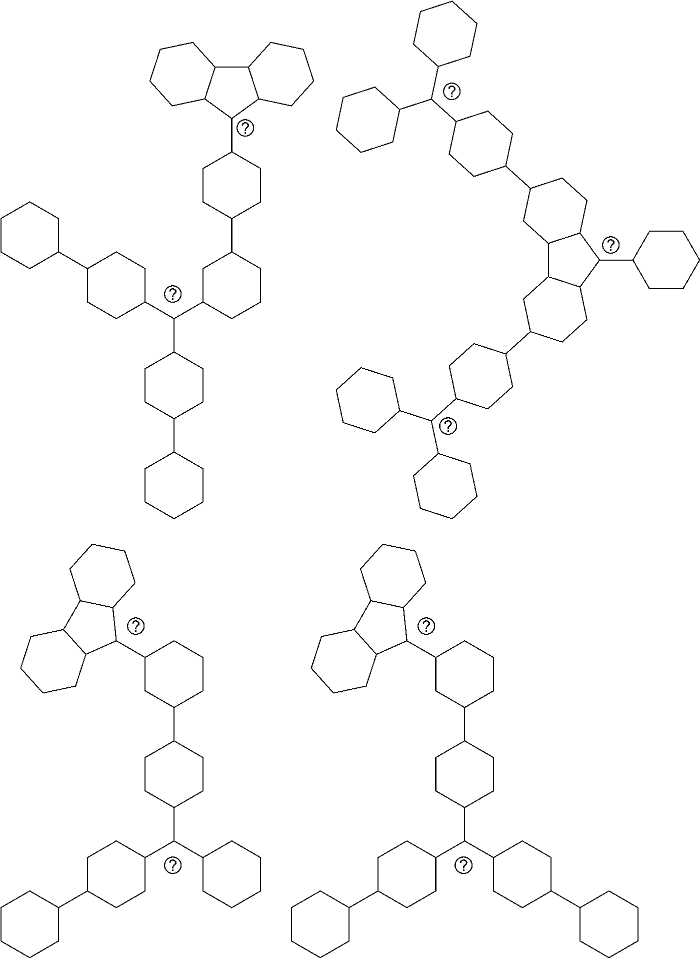

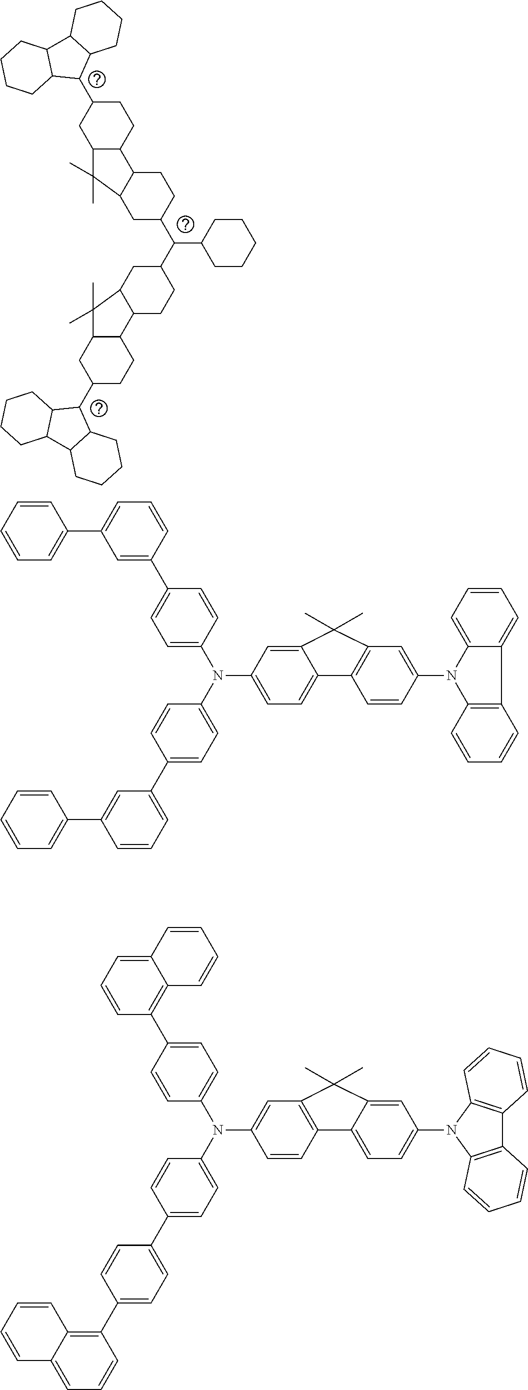

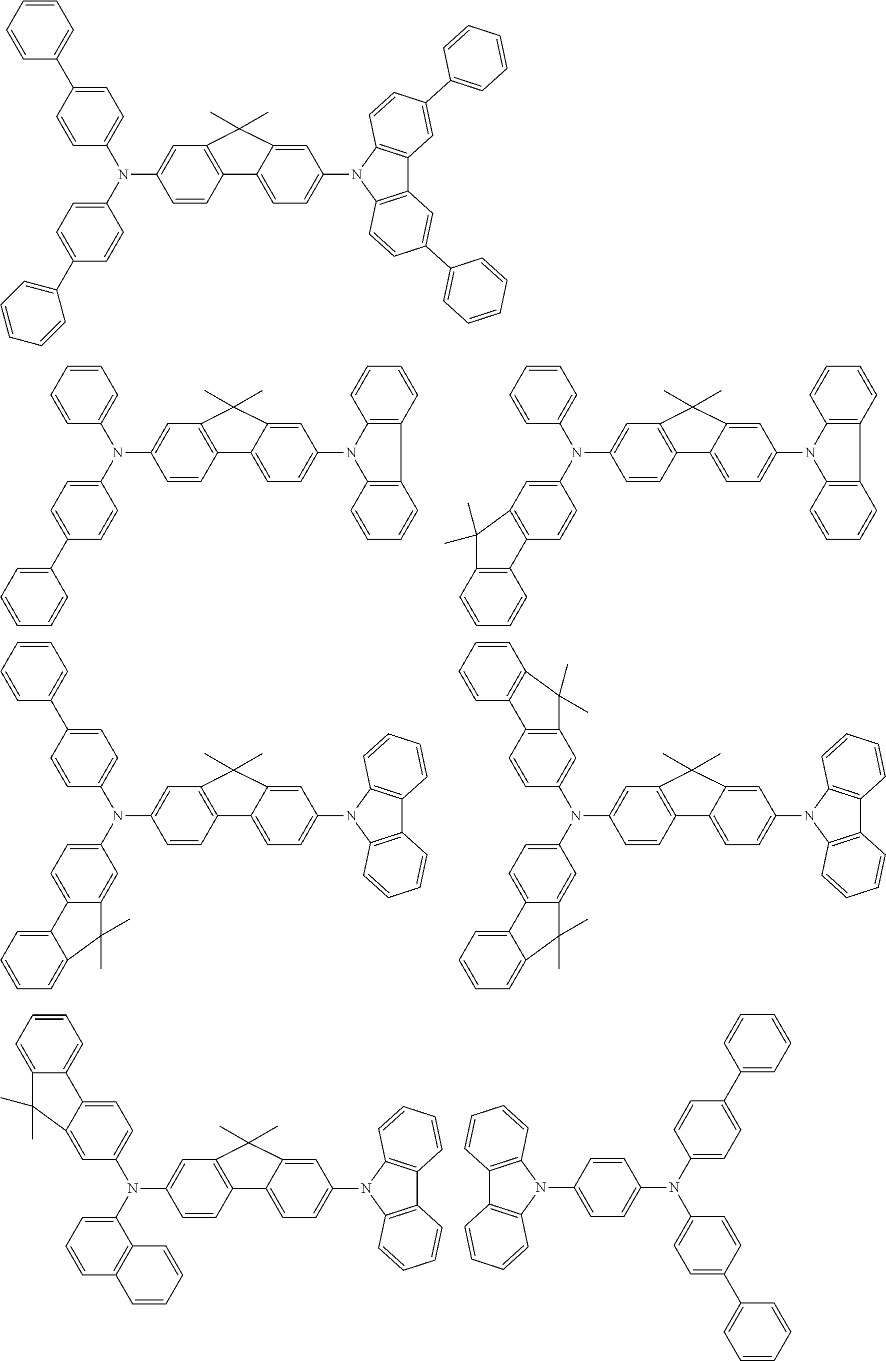

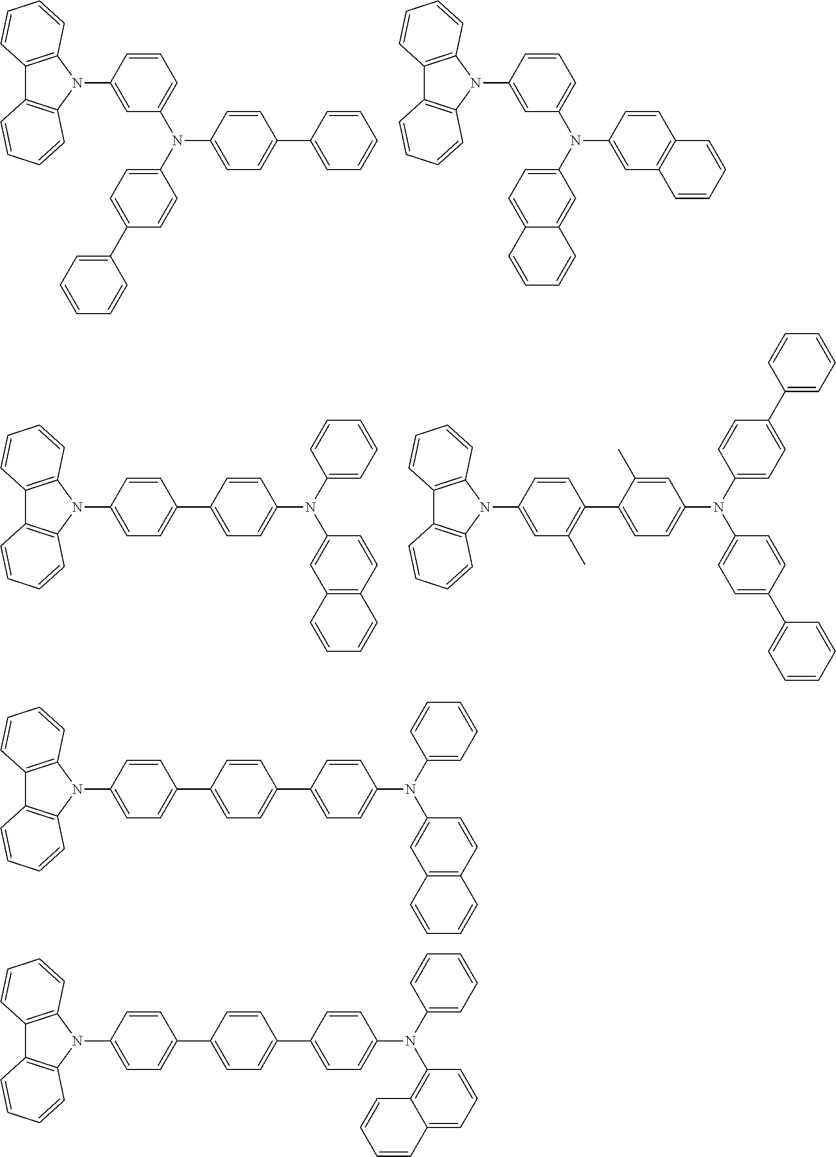

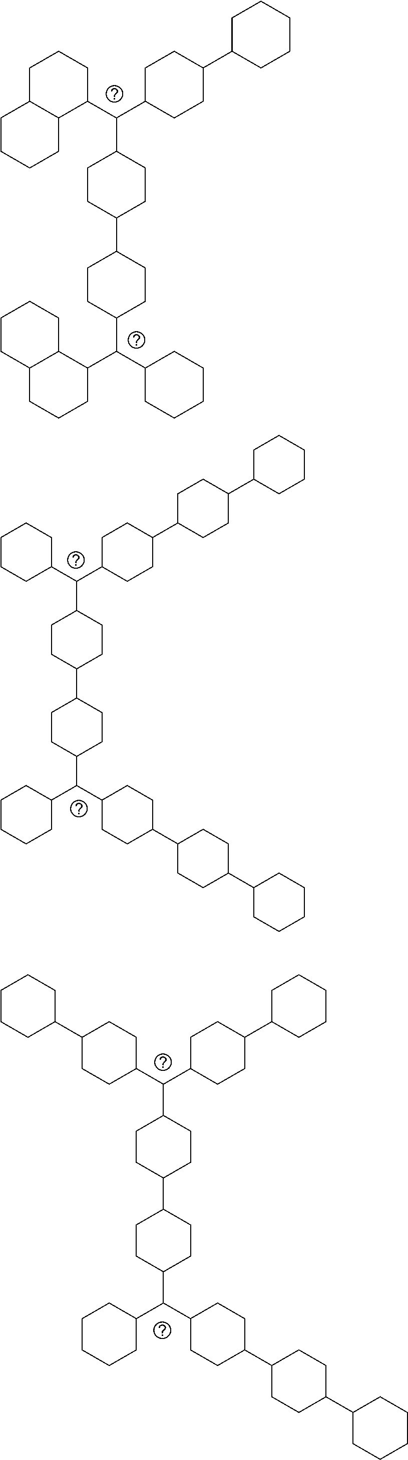

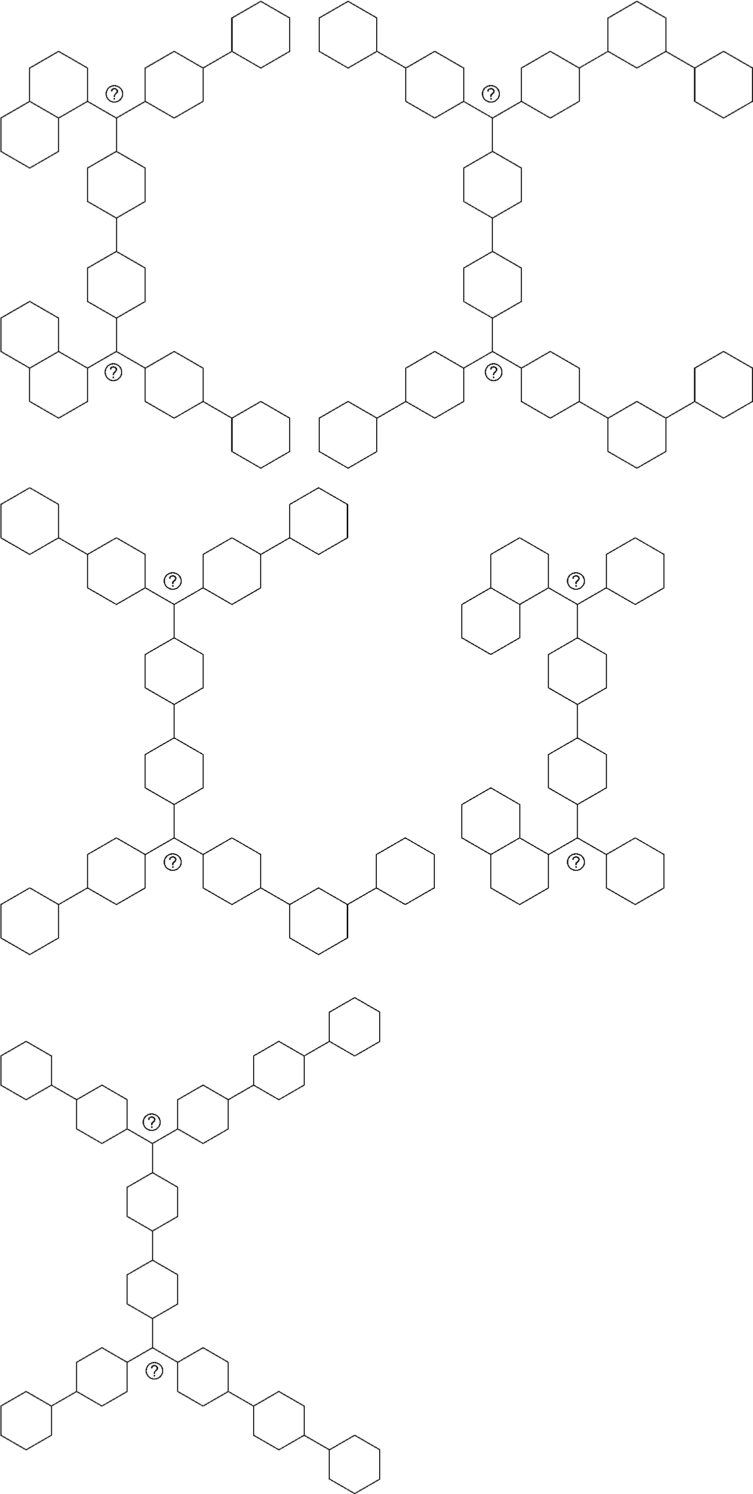

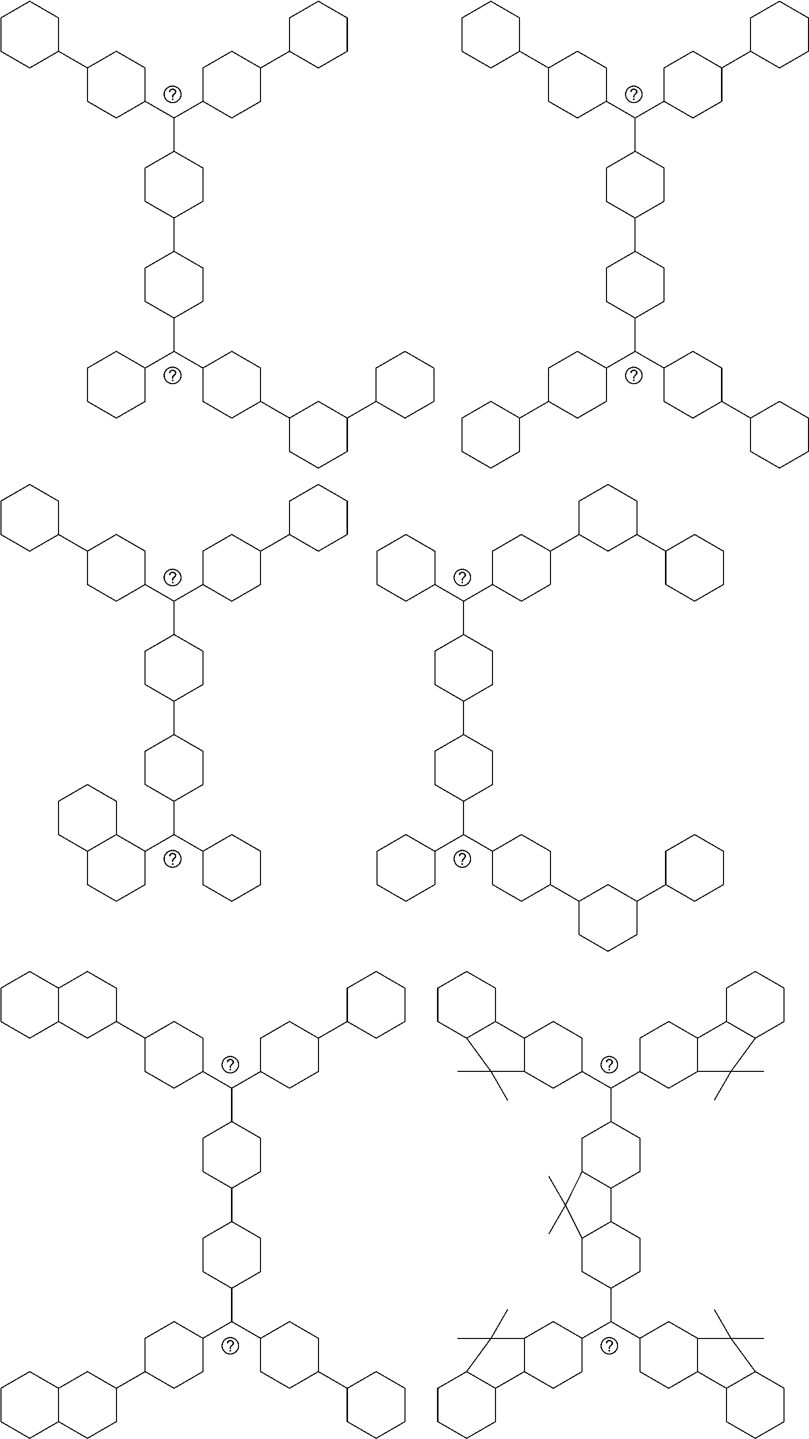

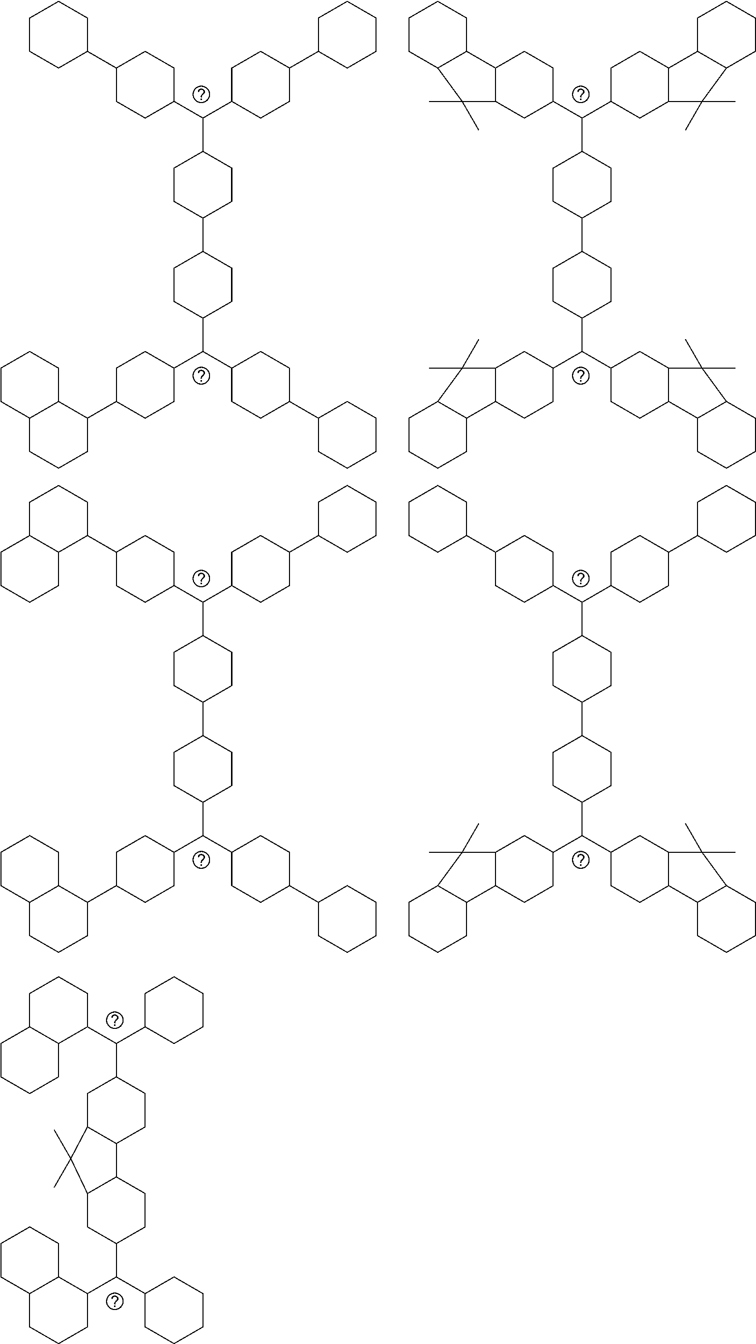

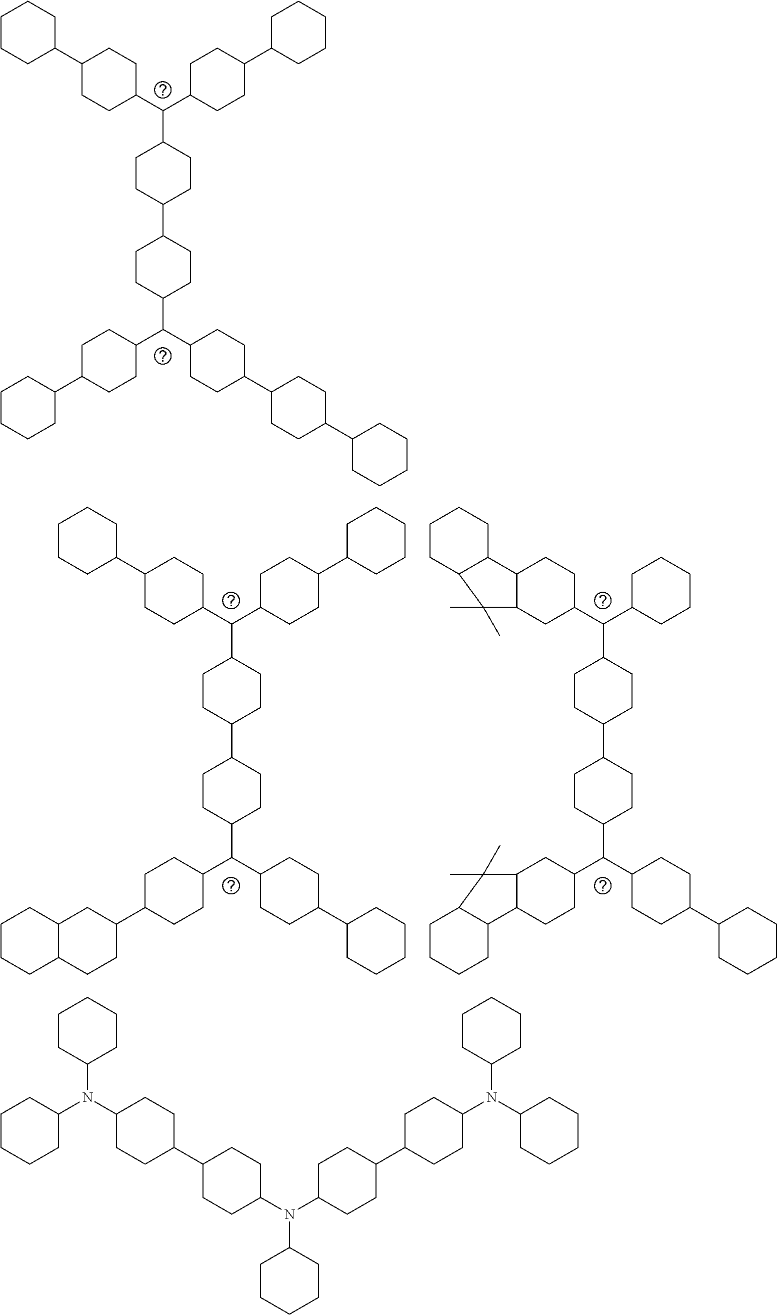

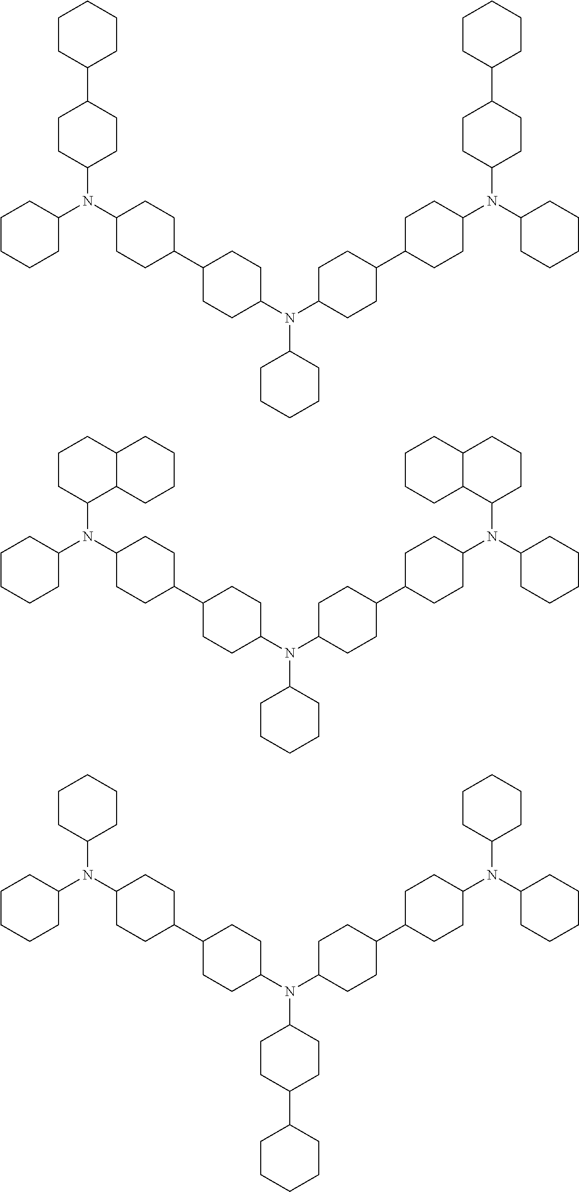 [SMILES: C1CCC(C2CCC(N(C3CCCCC3)C3CCC(C4CCC(N(C5CCCCC5)C5CCC(C6CCC(N(C7CCCCC7)C7CCC(C8CCCCC8)CC7)CC6)CC5)CC4)CC3)CC2)CC1 ; C1CCC(N(C2CCC(C3CCC(N(C4CCCCC4)C4CCCC5CCCCC54)CC3)CC2)C2CCC(C3CCC(N(C4CCCCC4)C4CCCC5CCCCC54)CC3)CC2)CC1 ; C1CCC(C2CCC(N(C3CCC(C4CCC(N(C5CCCCC5)C5CCCCC5)CC4)CC3)C3CCC(C4CCC(N(C5CCCCC5)C5CCCCC5)CC4)CC3)CC2)CC1]

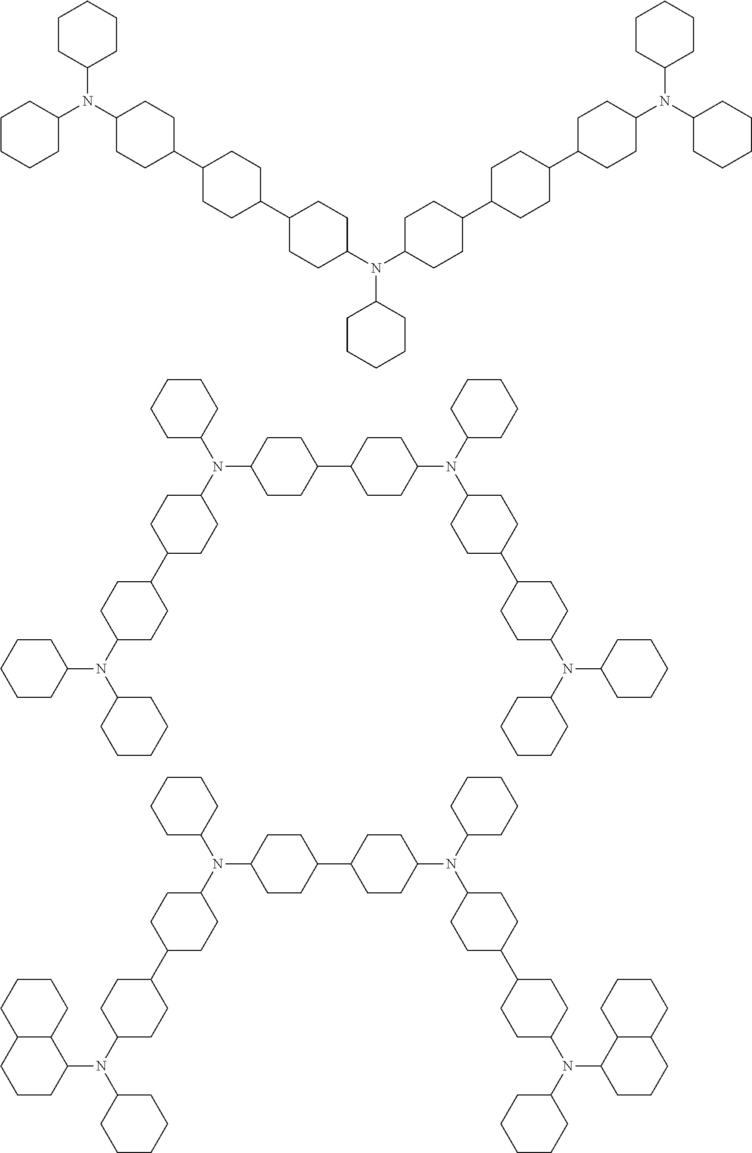

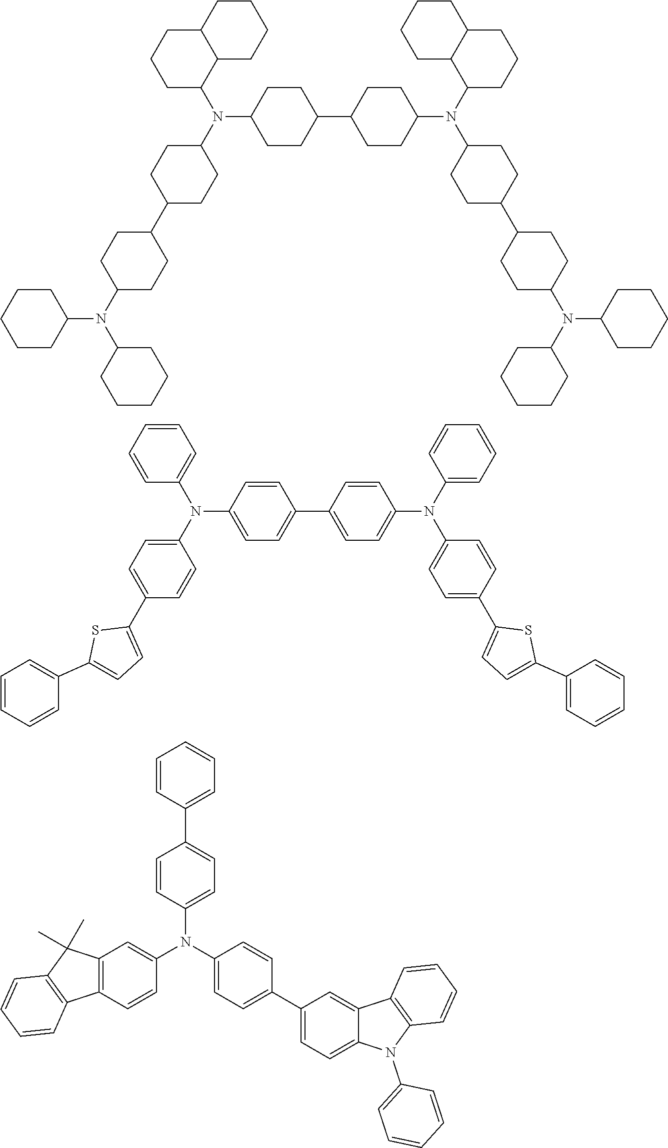

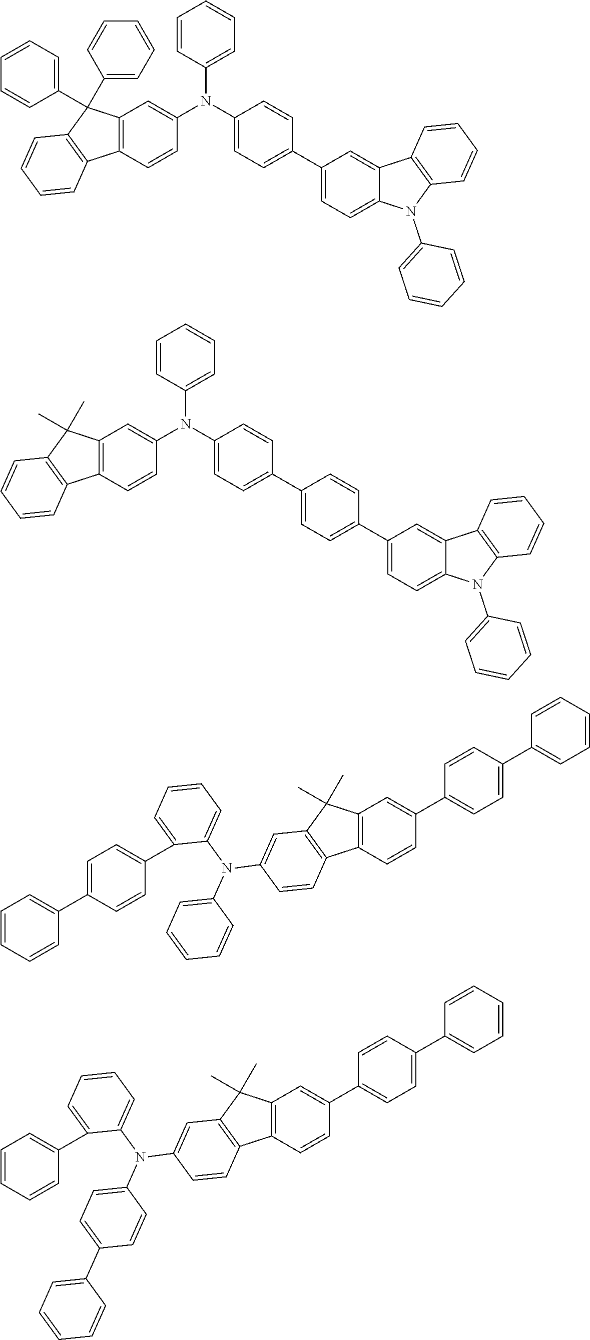

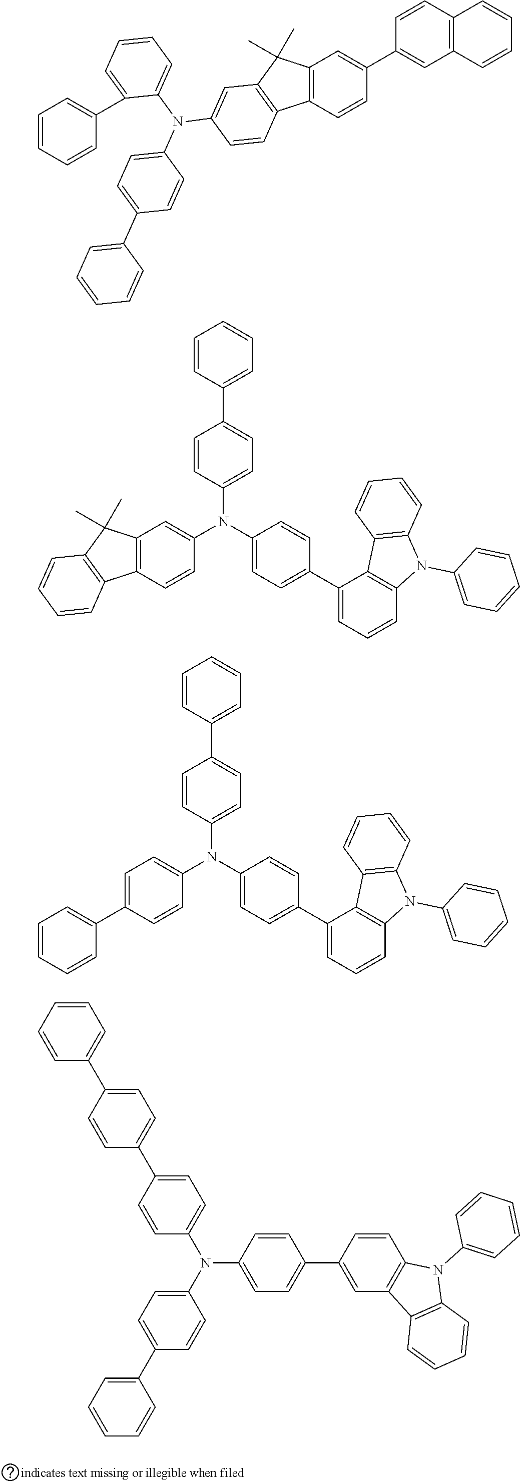

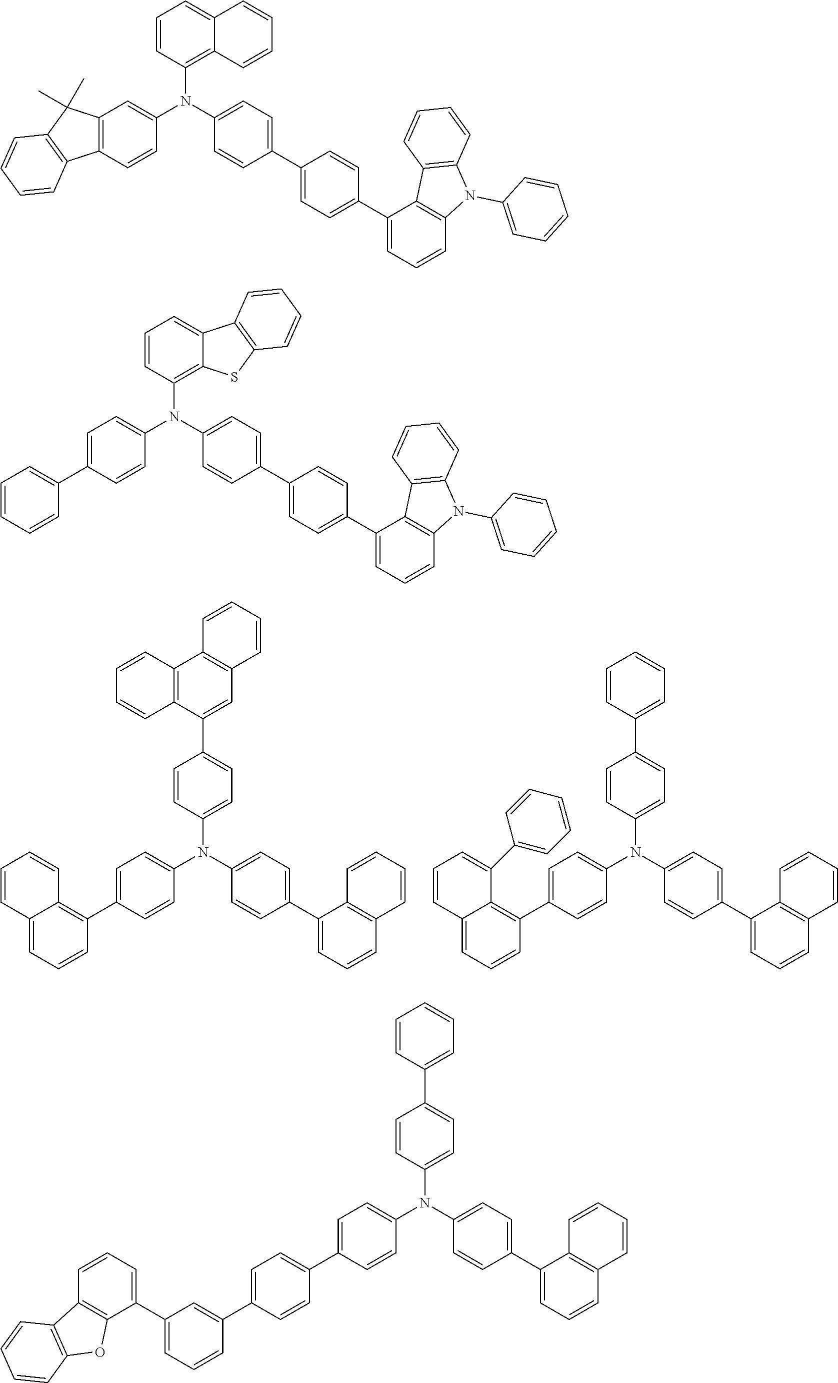

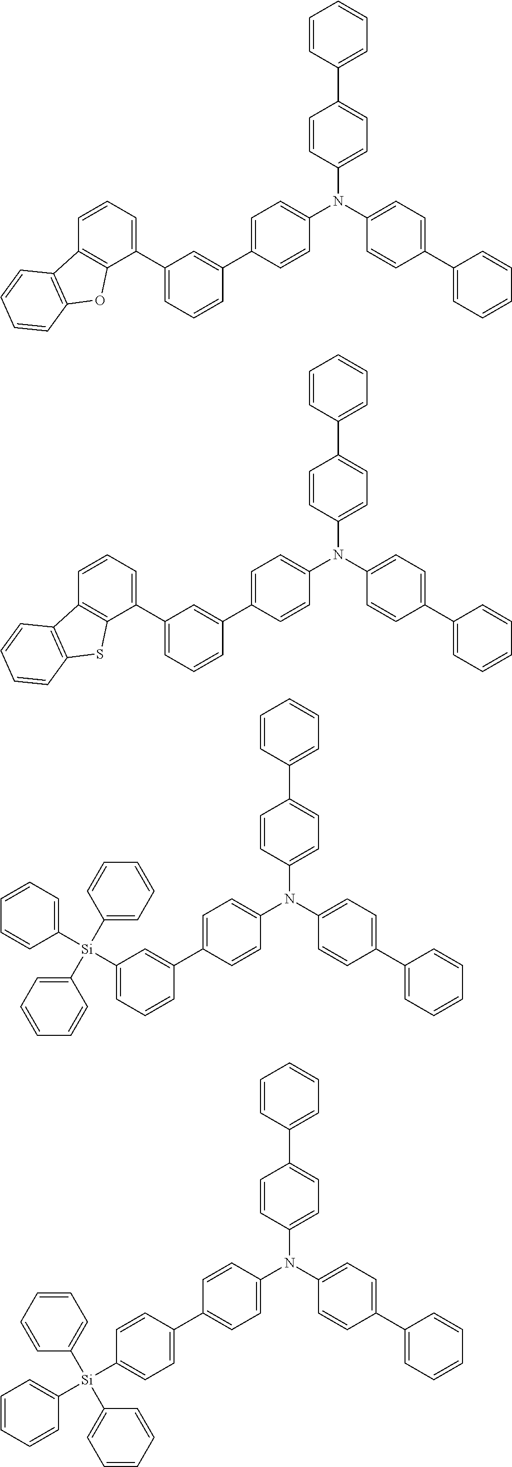 [SMILES: c1ccc(-c2ccc(N(c3ccc(-c4ccccc4)cc3)c3ccc(-c4cccc(-c5cccc6c5oc5ccccc56)c4)cc3)cc2)cc1 ; c1ccc(-c2ccc(N(c3ccc(-c4ccccc4)cc3)c3ccc(-c4cccc(-c5cccc6c5sc5ccccc56)c4)cc3)cc2)cc1 ; c1ccc(-c2ccc(N(c3ccc(-c4ccccc4)cc3)c3ccc(-c4cccc([Si](c5ccccc5)(c5ccccc5)c5ccccc5)c4)cc3)cc2)cc1 ; c1ccc(-c2ccc(N(c3ccc(-c4ccccc4)cc3)c3ccc(-c4ccc([Si](c5ccccc5)(c5ccccc5)c5ccccc5)cc4)cc3)cc2)cc1]

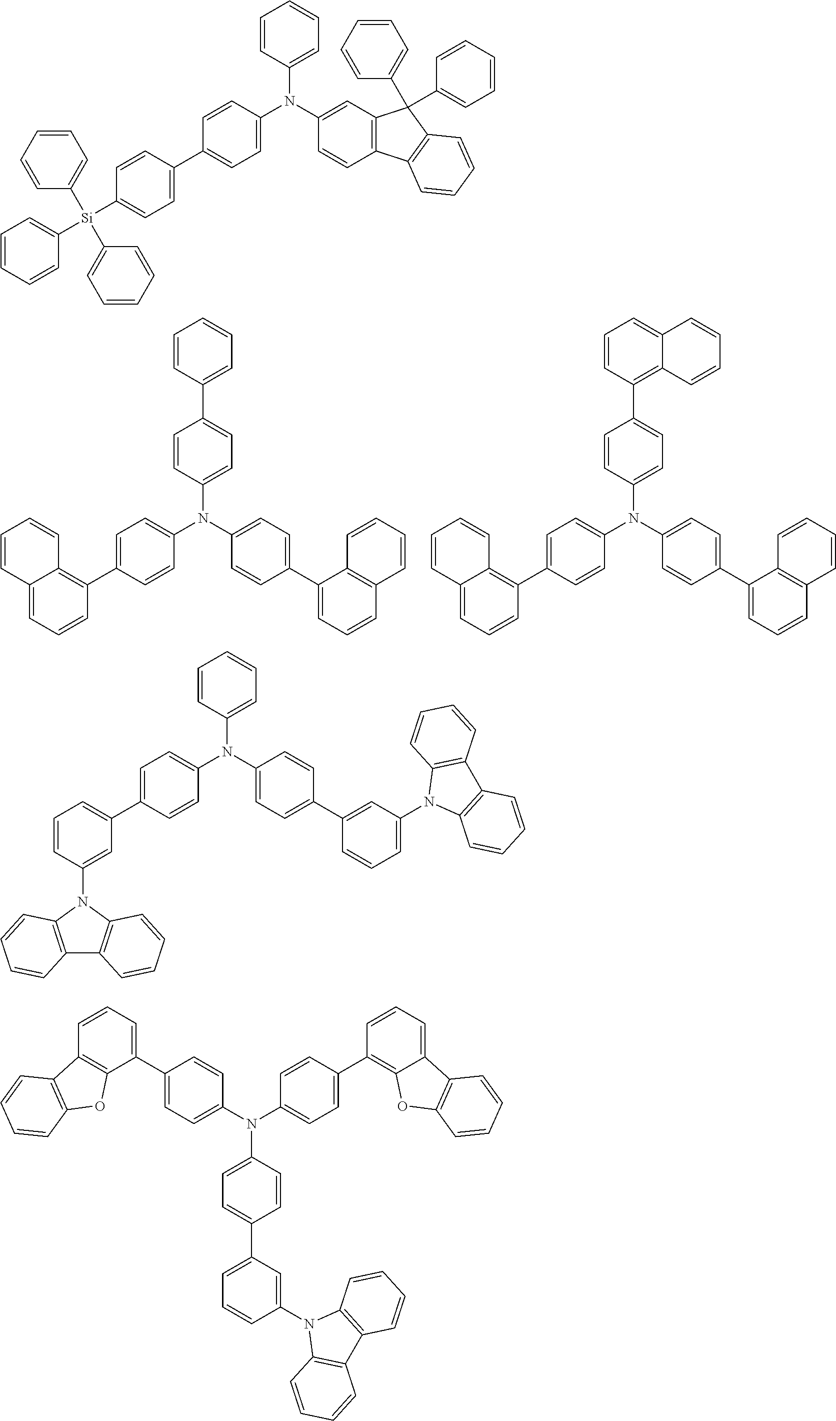

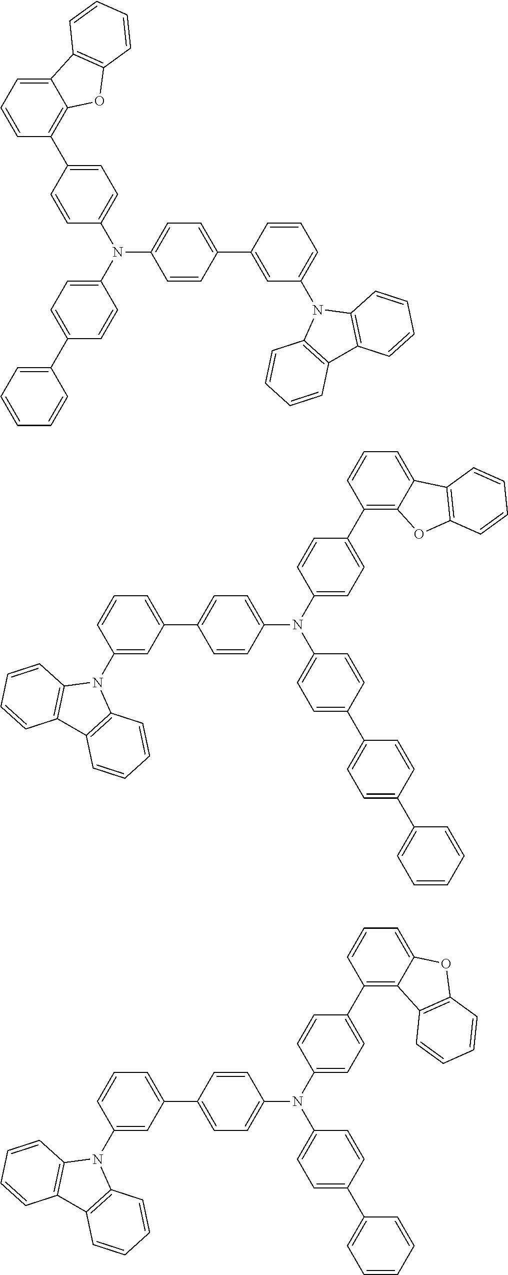

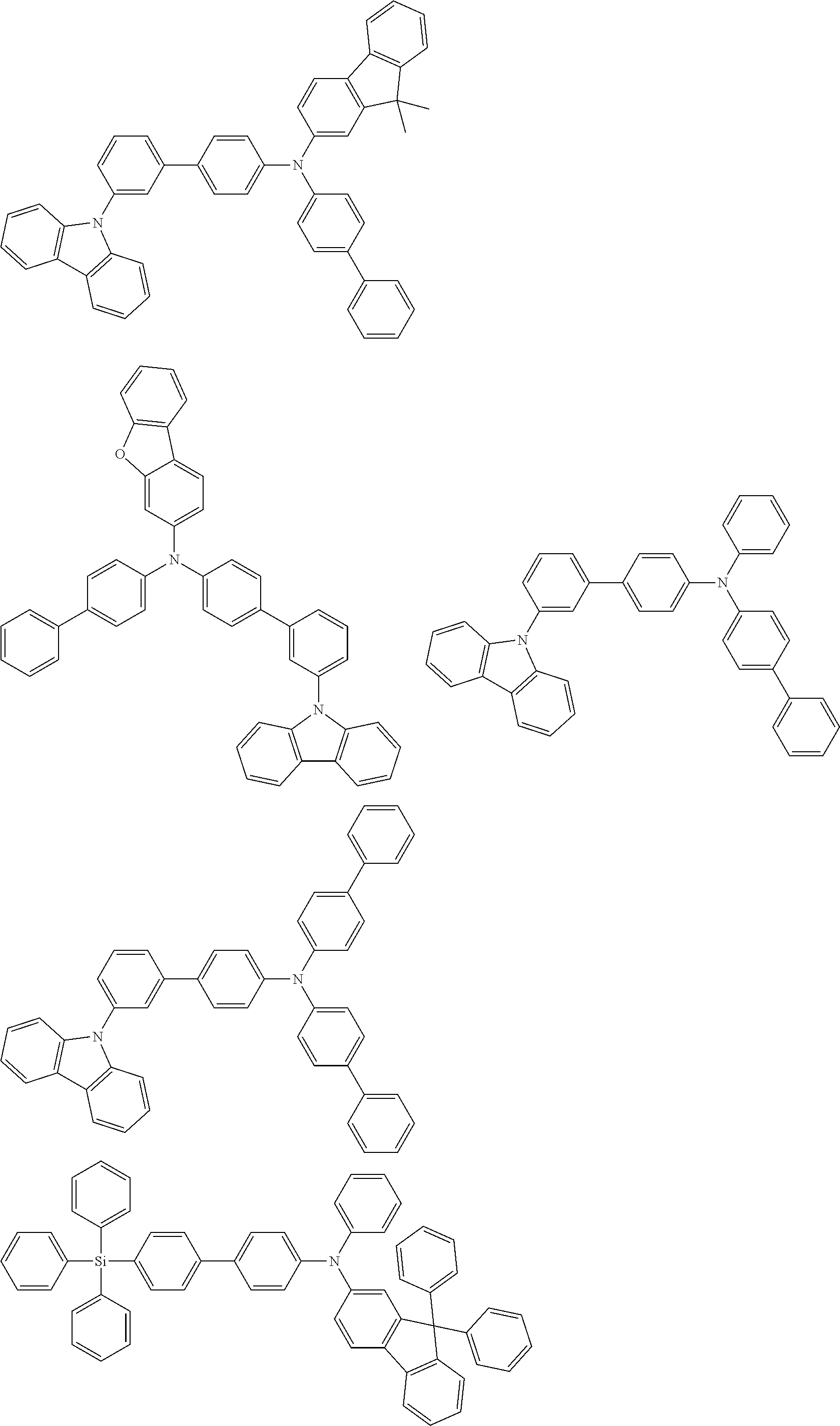

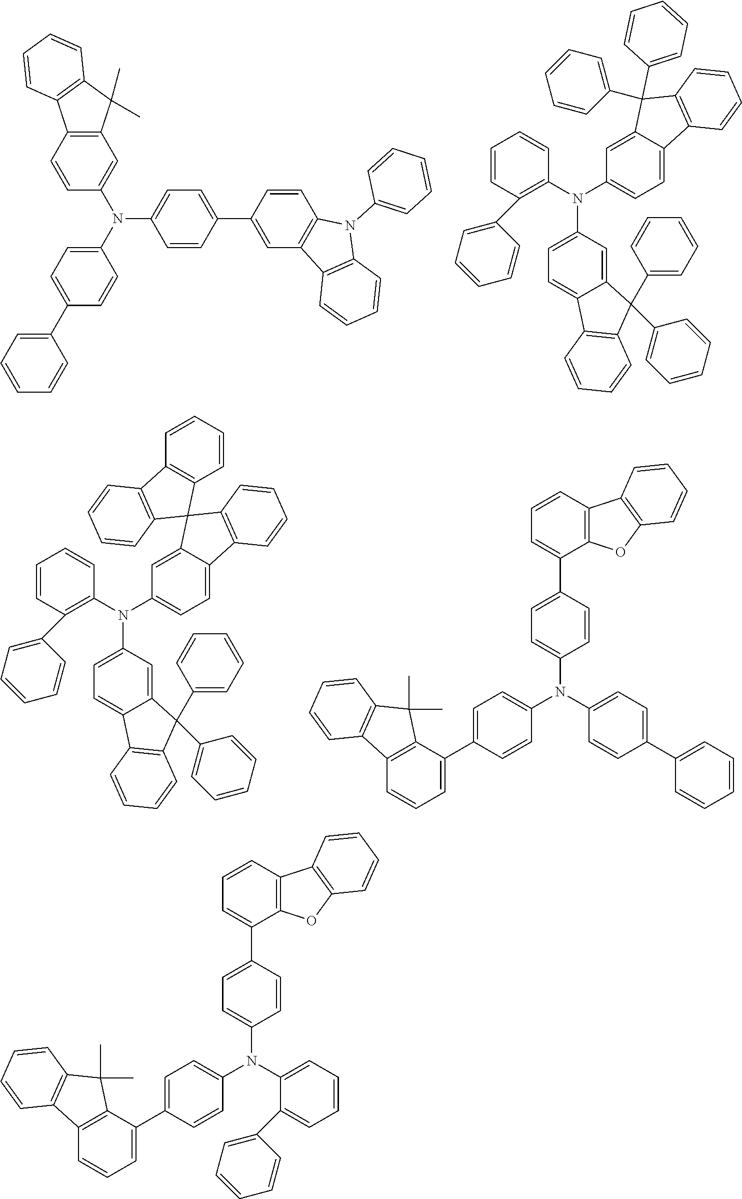 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1 ; c1ccc(-c2ccccc2N(c2ccc3c(c2)C(c2ccccc2)(c2ccccc2)c2ccccc2-3)c2ccc3c(c2)C2(c4ccccc4-c4ccccc42)c2ccccc2-3)cc1 ; CC1(C)c2ccccc2-c2cccc(-c3ccc(N(c4ccc(-c5ccccc5)cc4)c4ccc(-c5cccc6c5oc5ccccc56)cc4)cc3)c21 ; CC1(C)c2ccccc2-c2cccc(-c3ccc(N(c4ccc(-c5cccc6c5oc5ccccc56)cc4)c4ccccc4-c4ccccc4)cc3)c21]

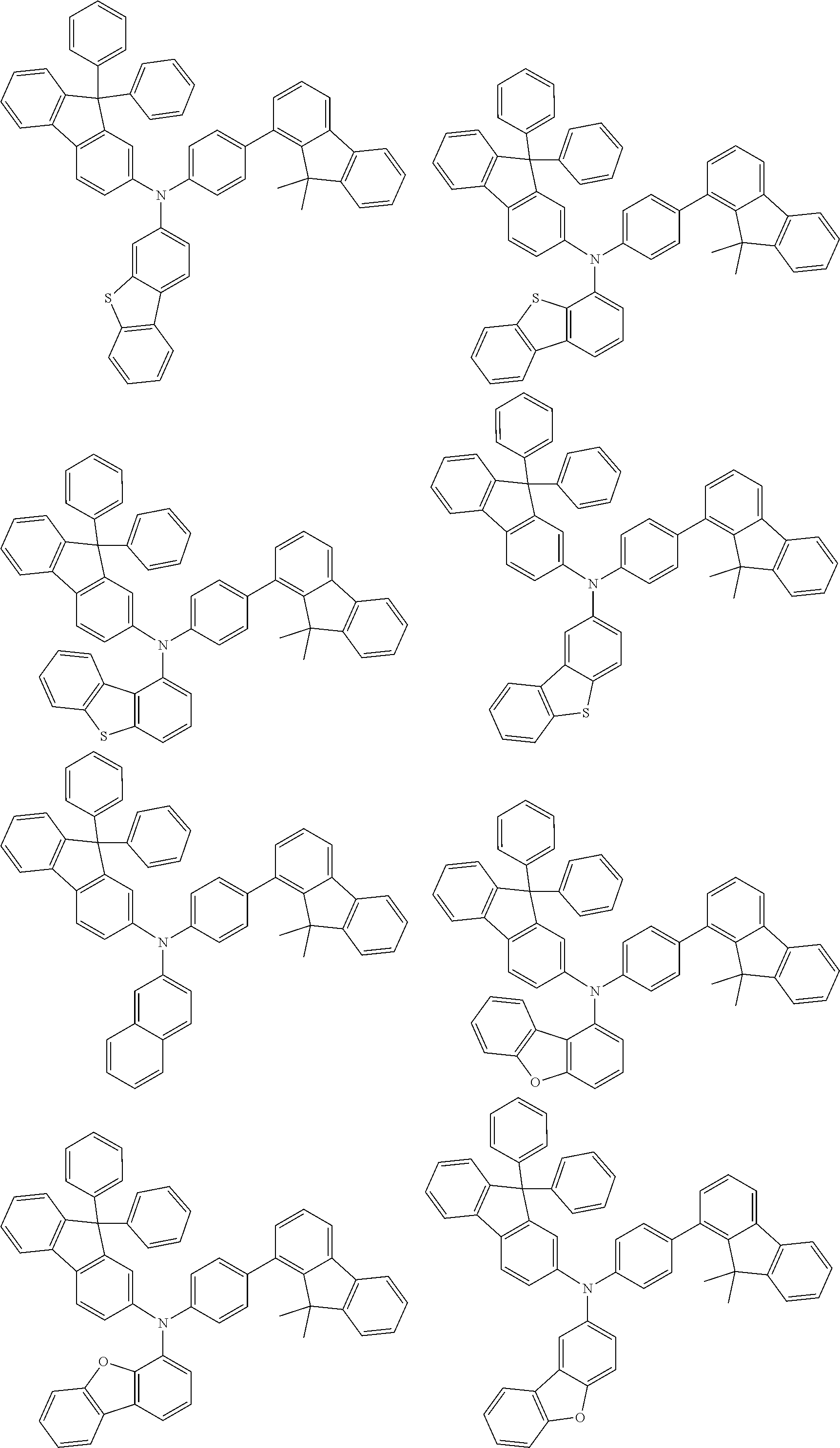

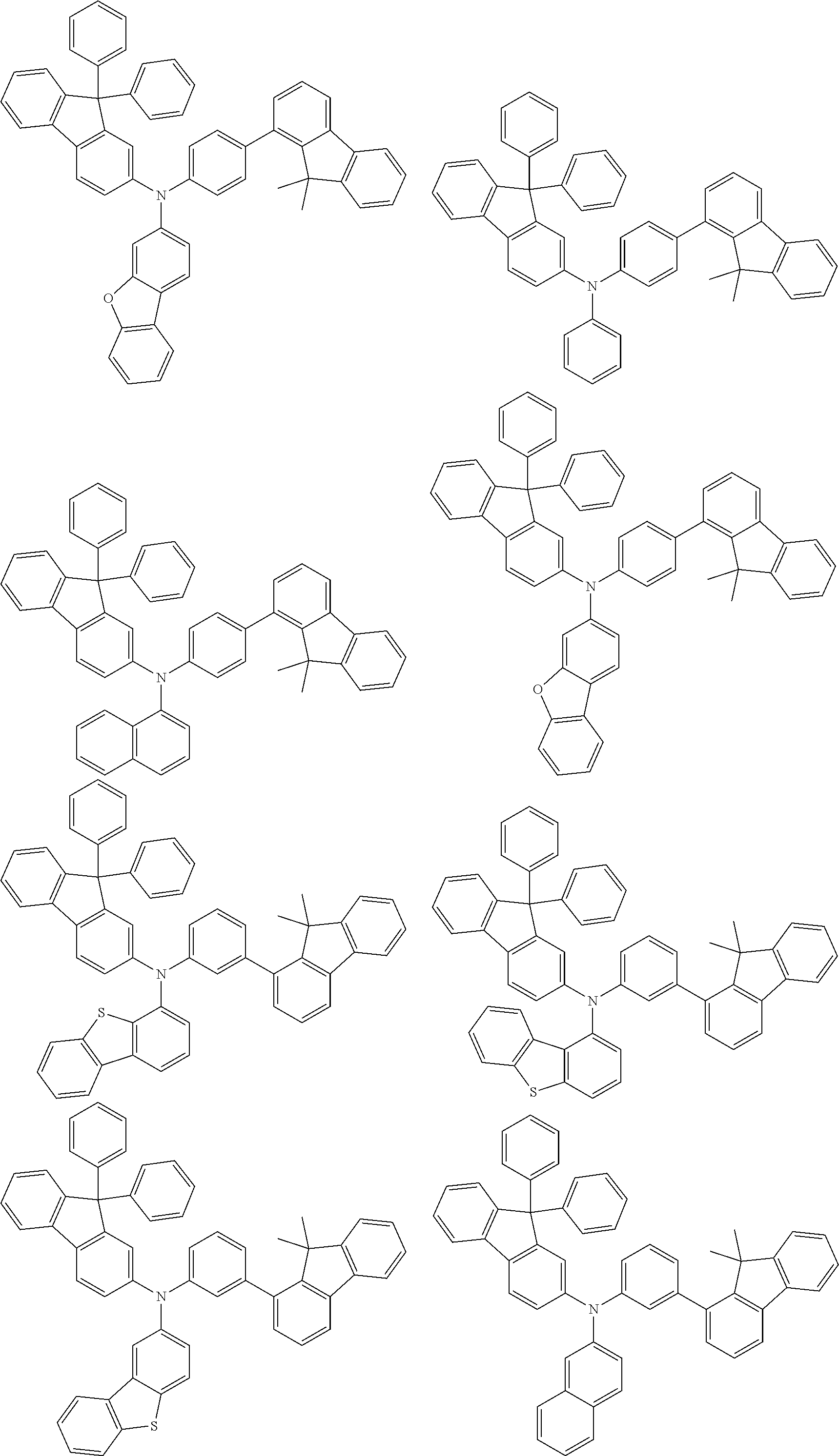

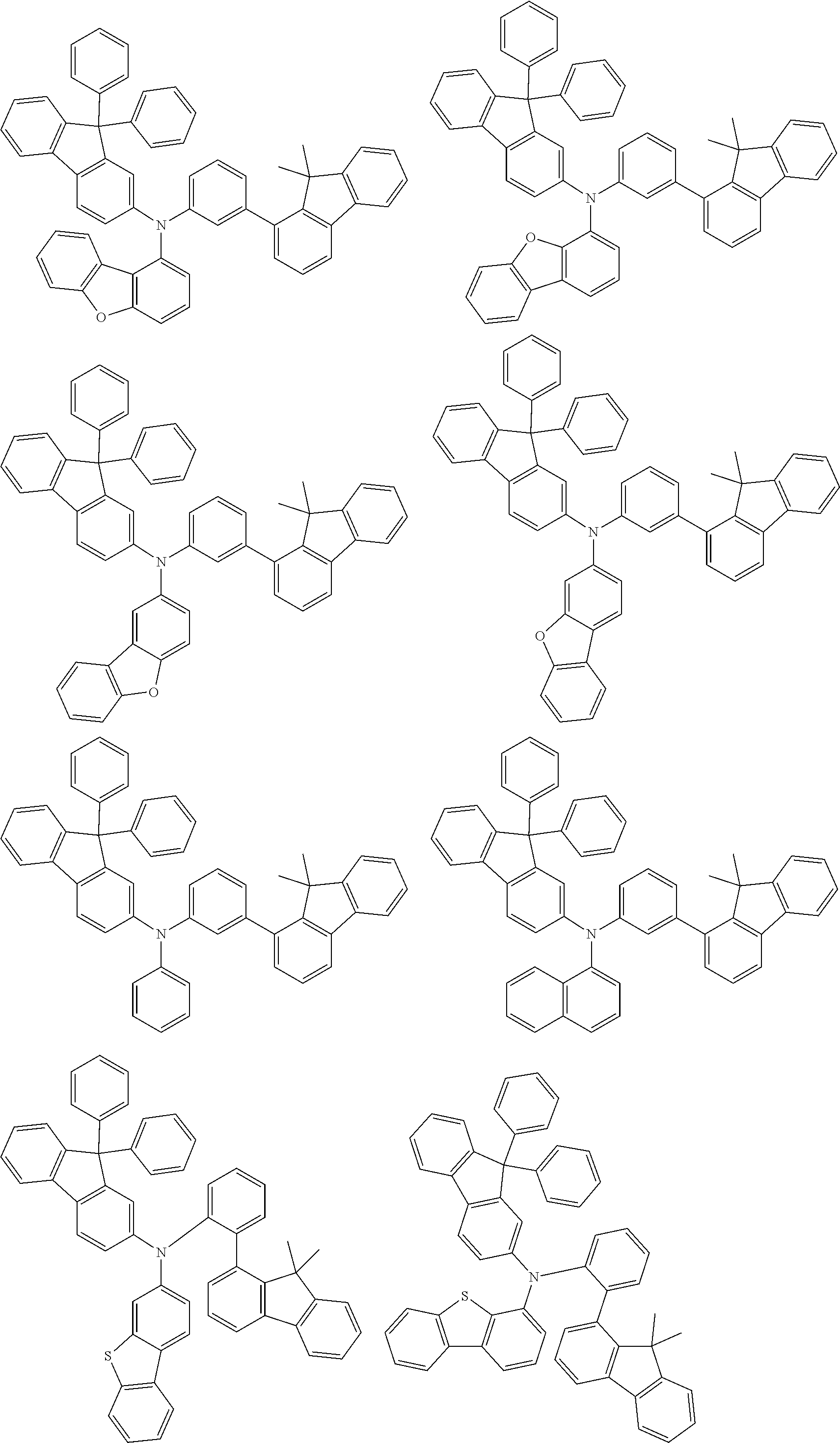

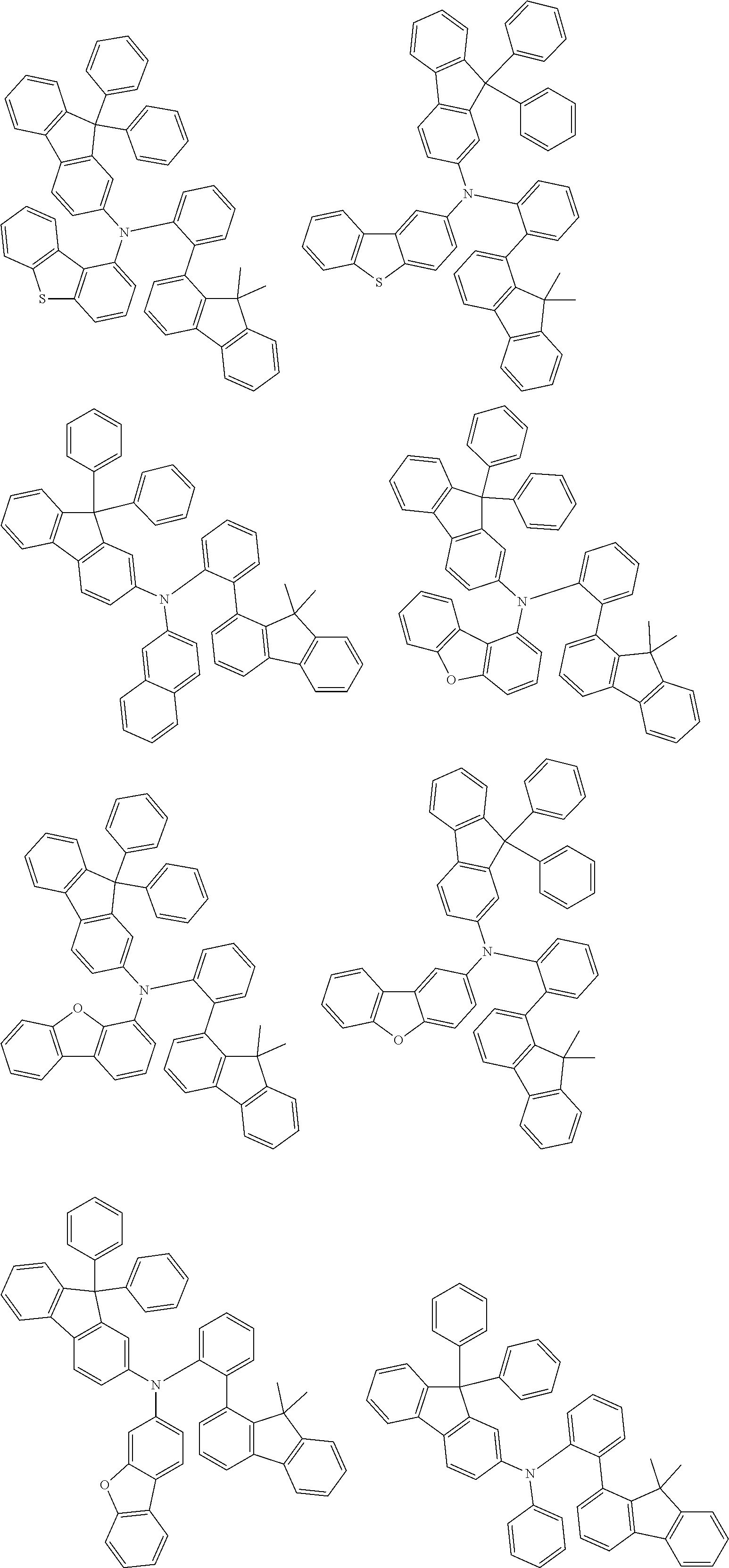

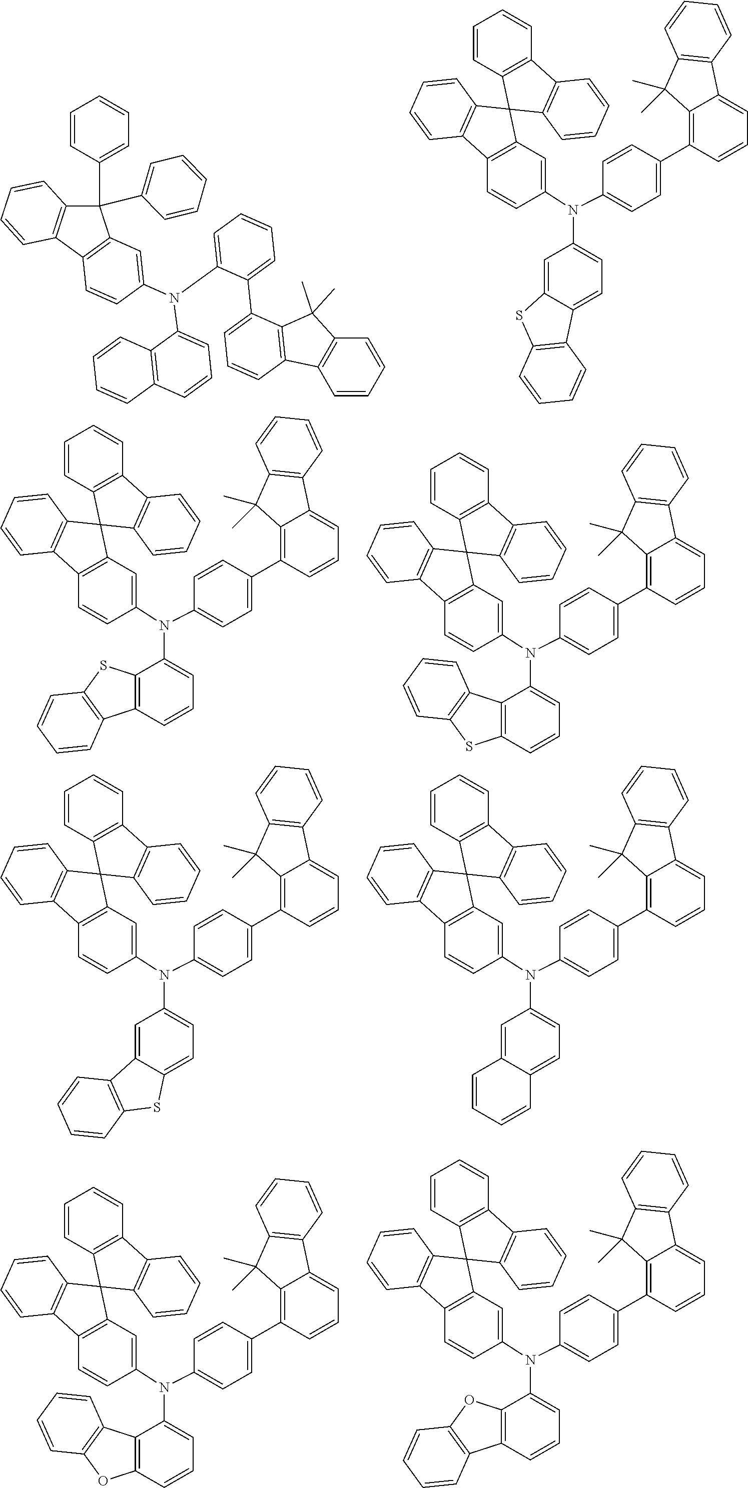

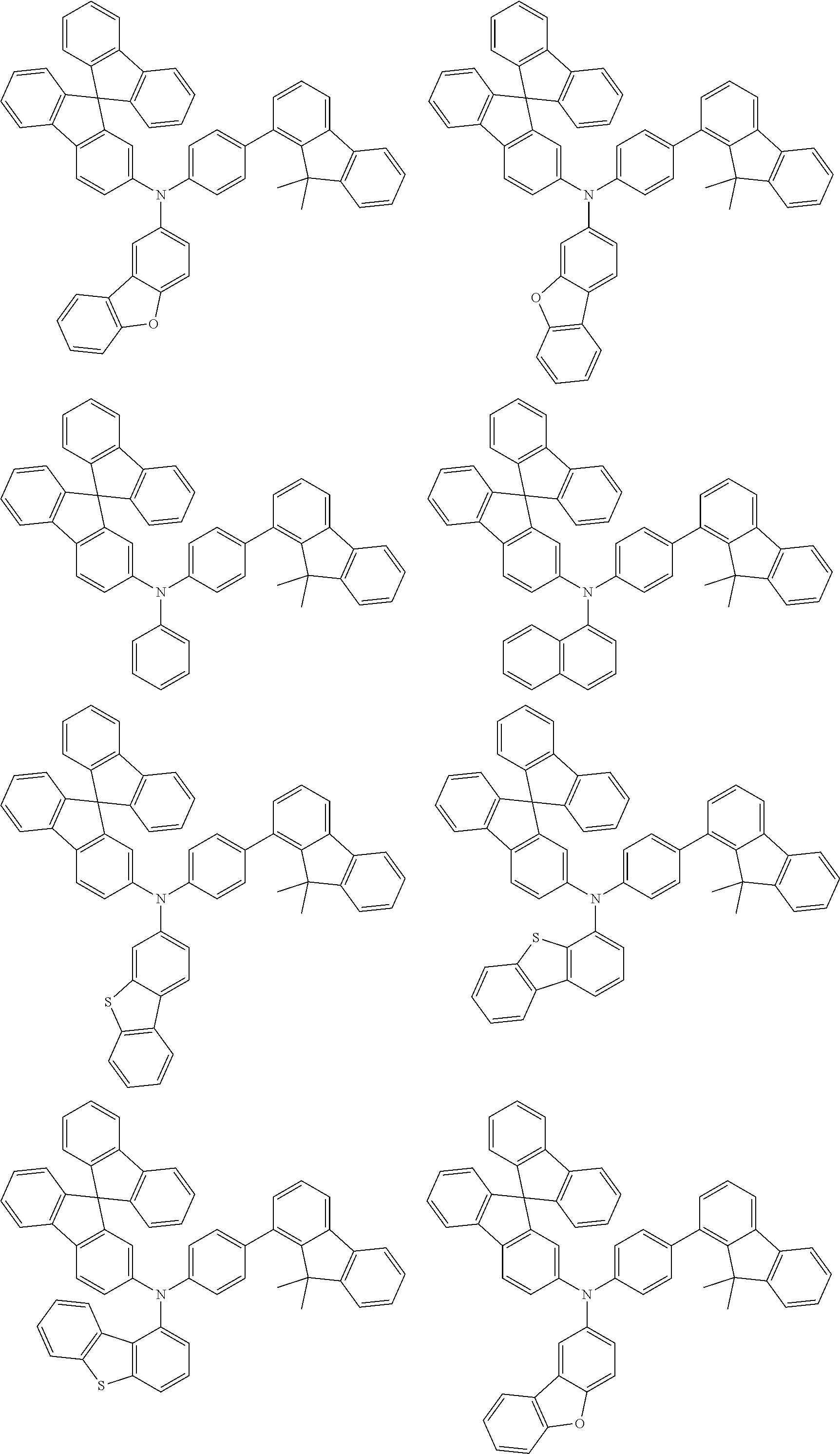

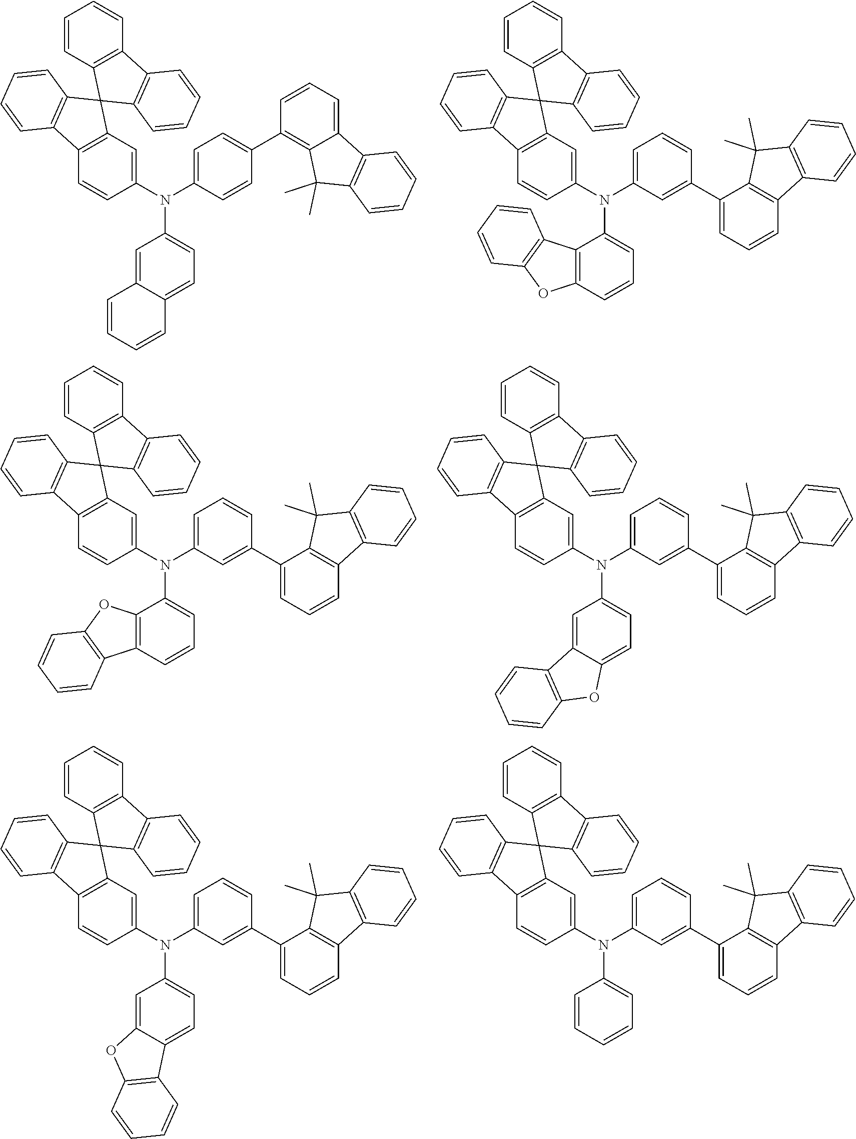

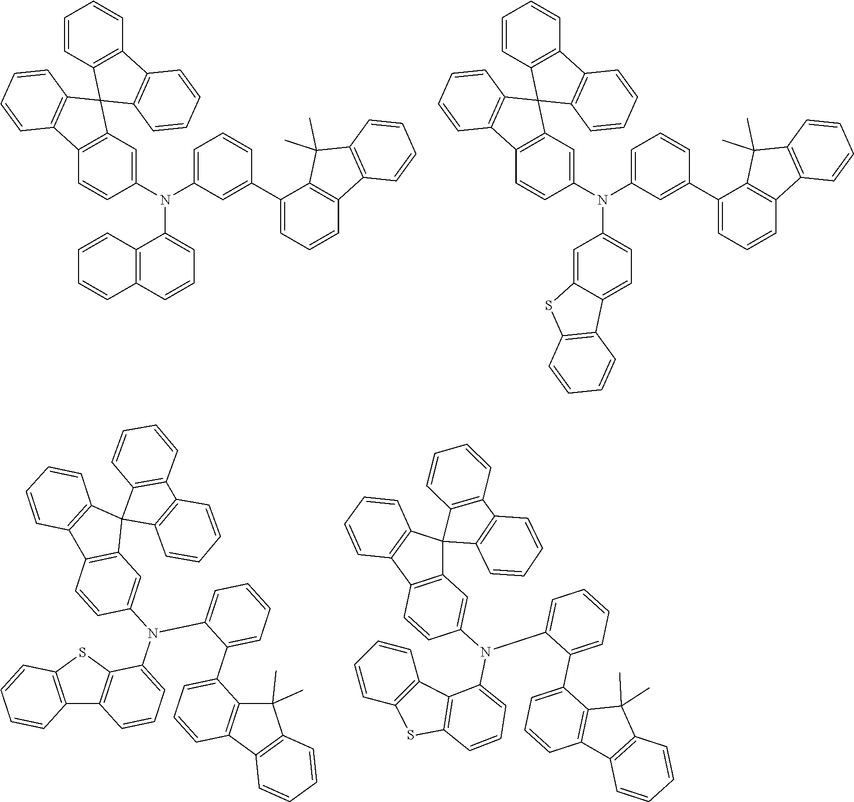

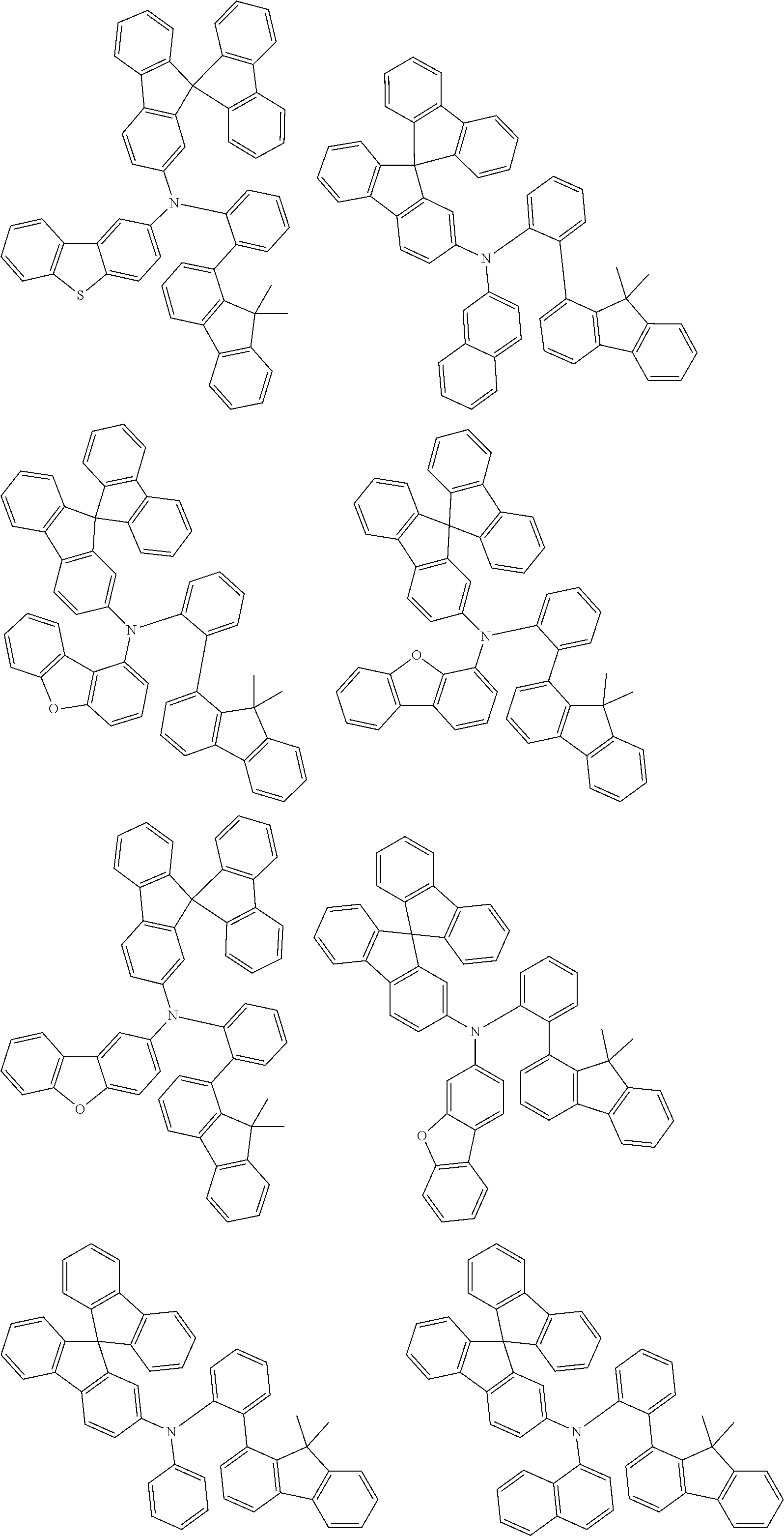

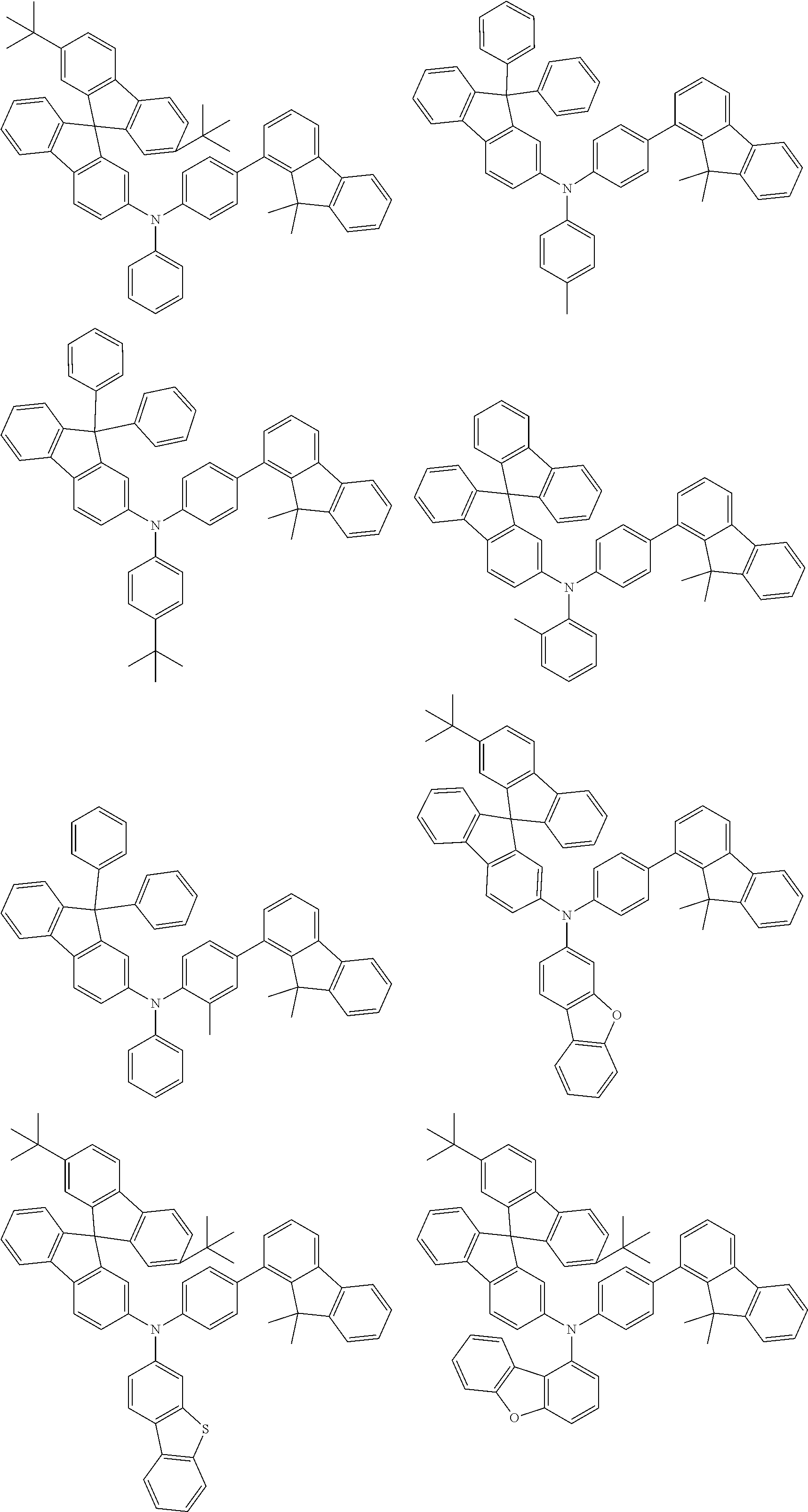

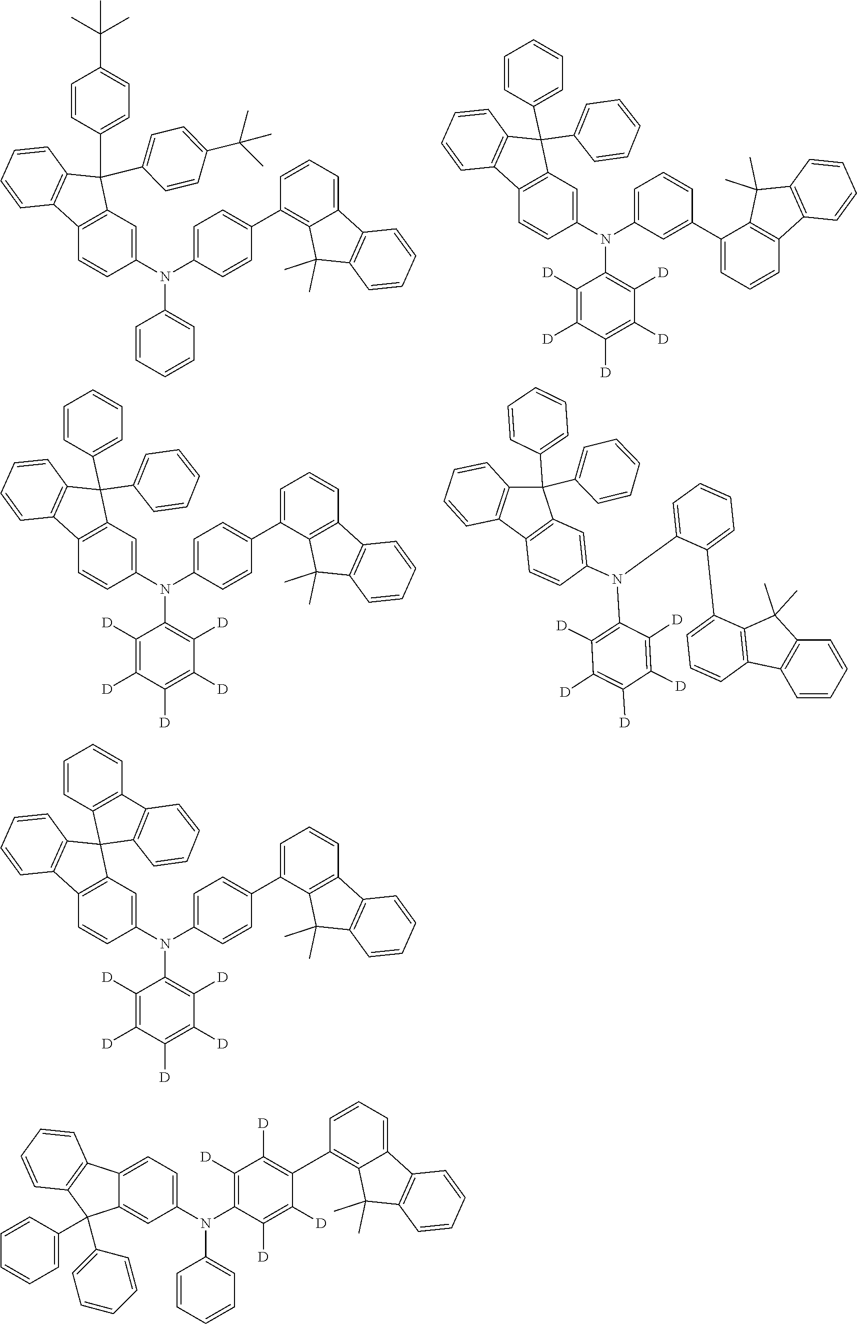

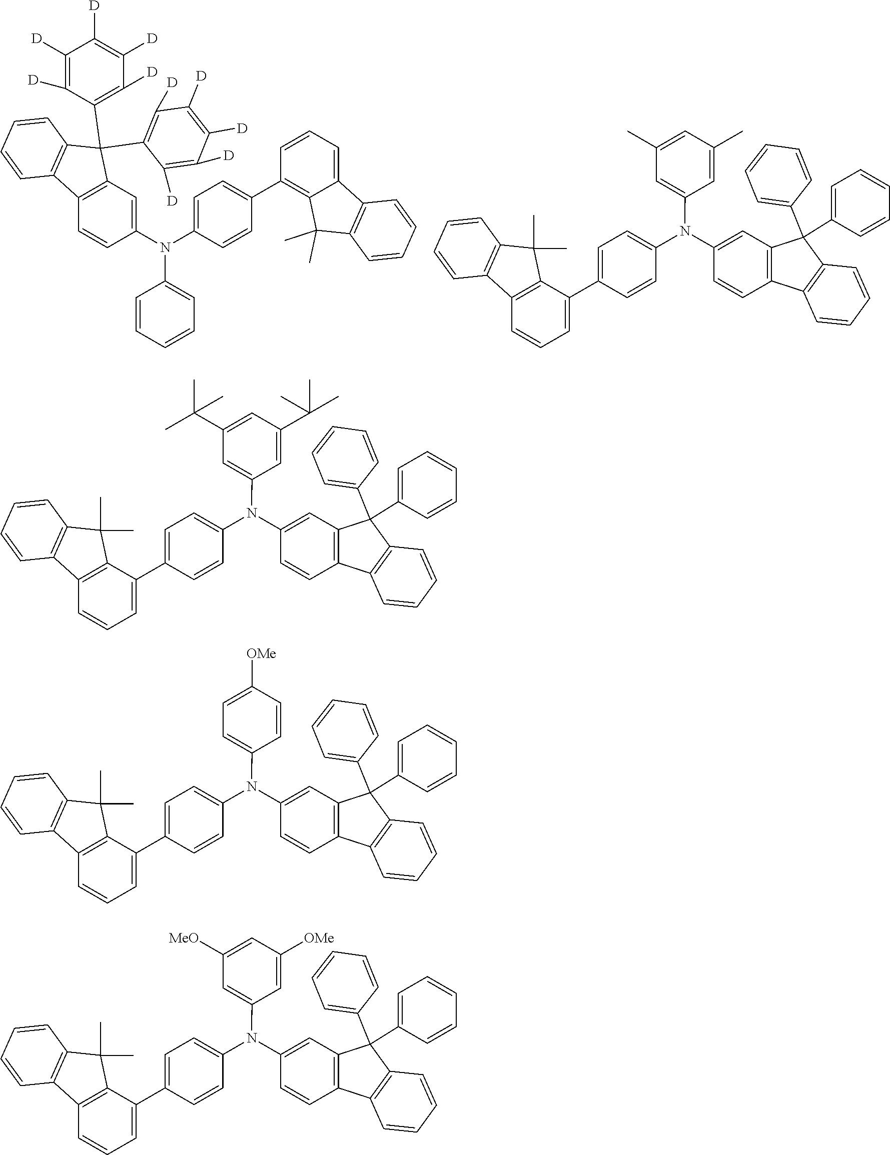

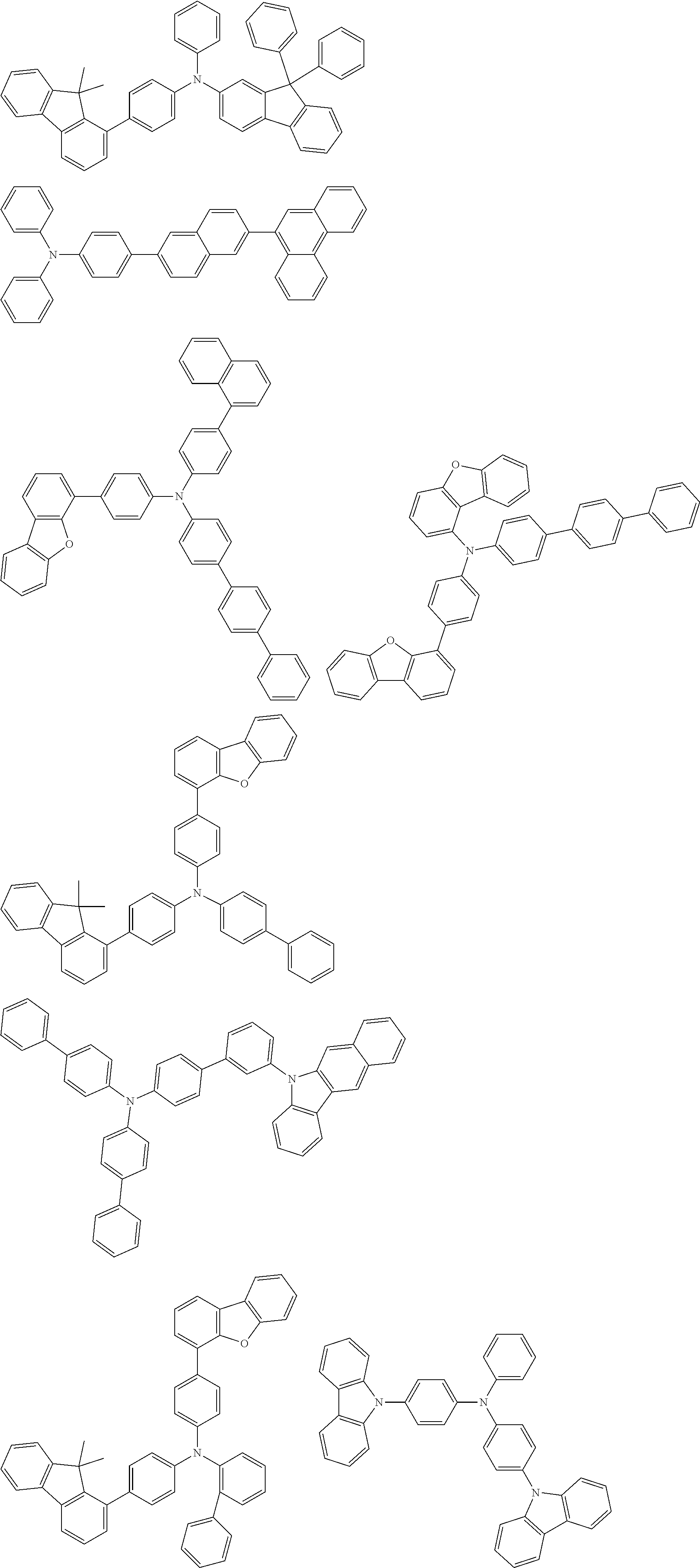

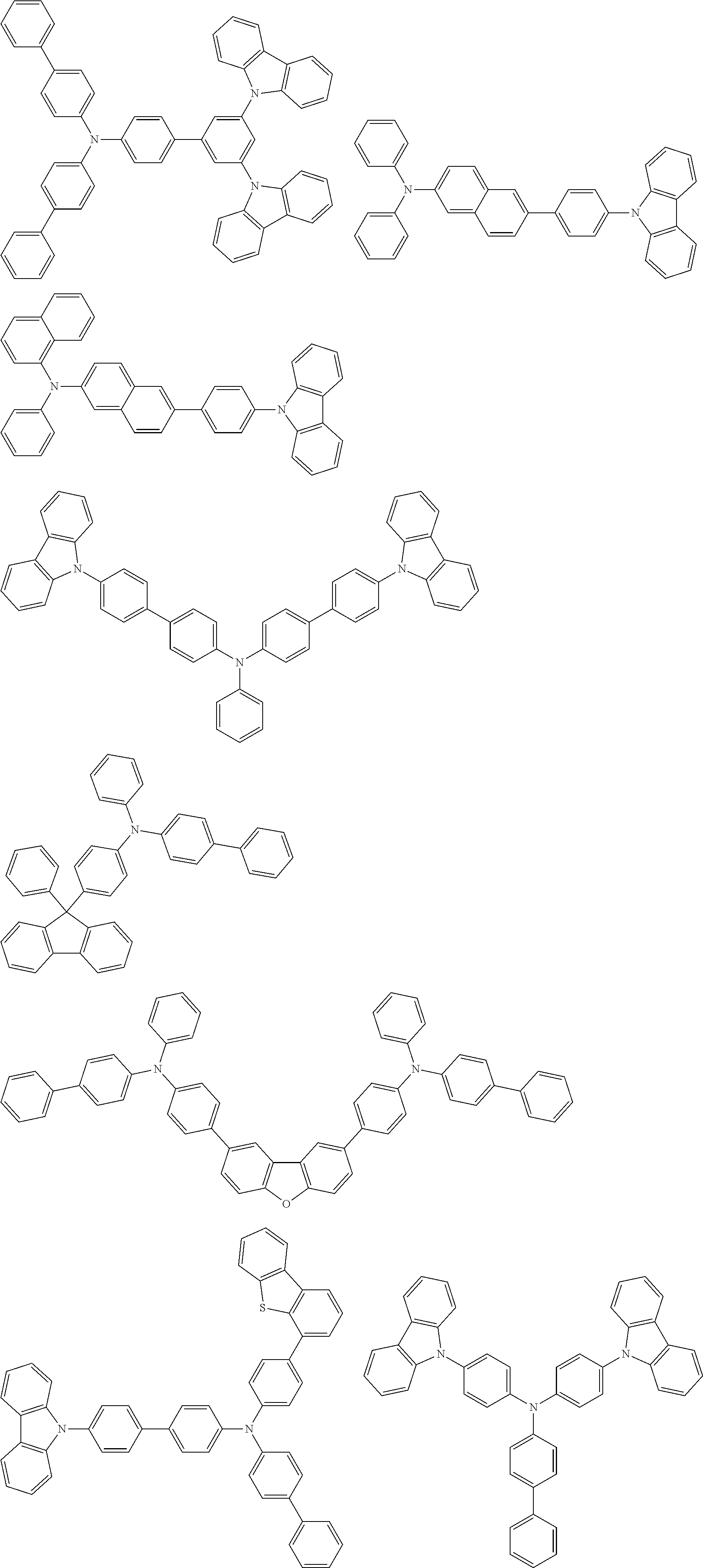

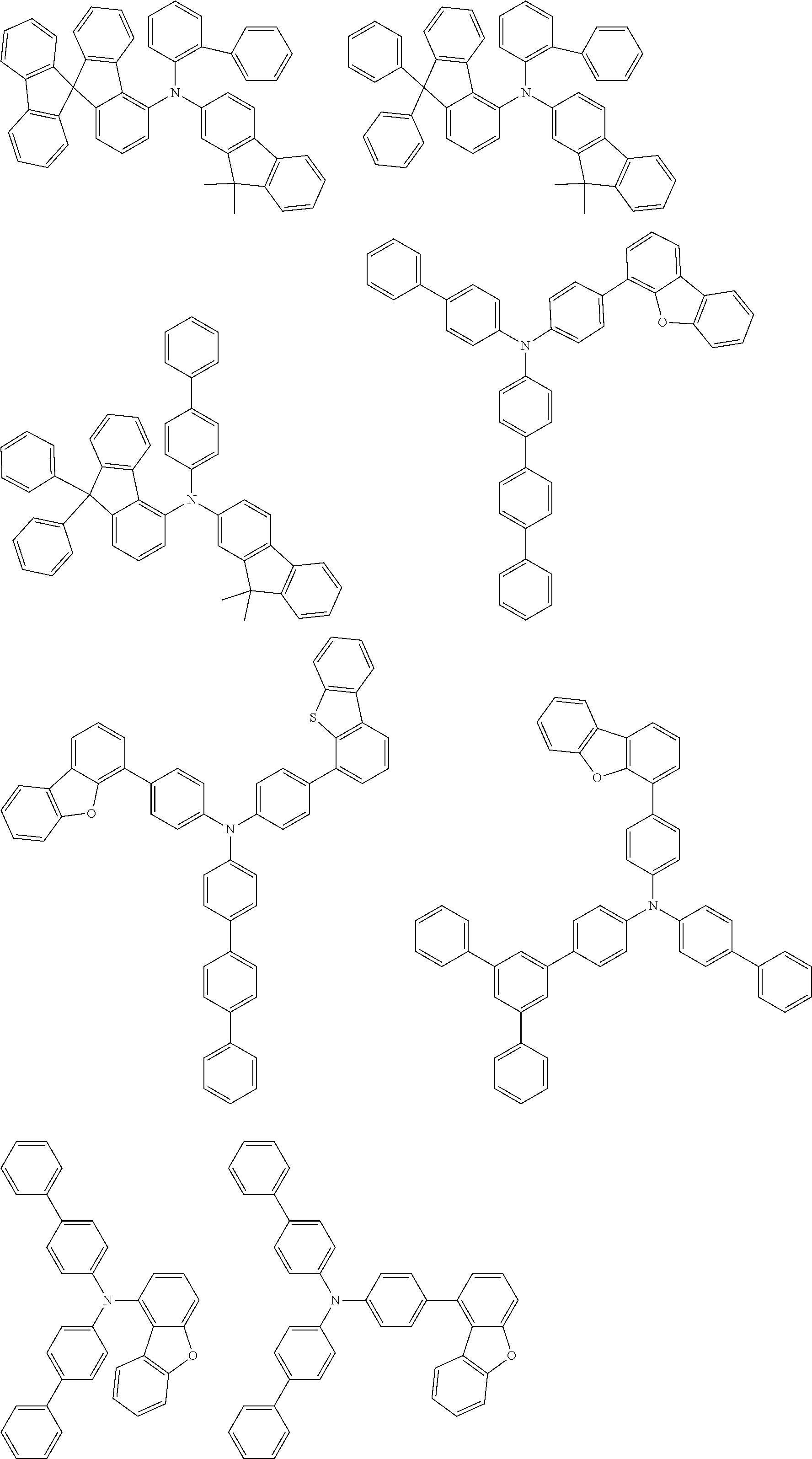

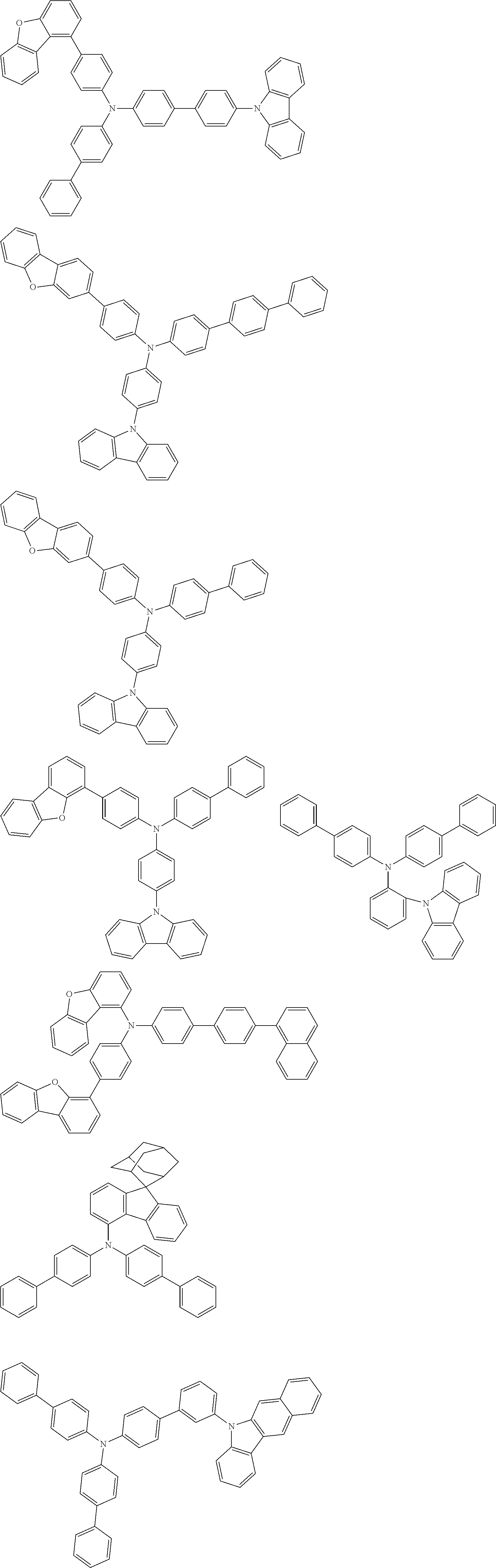

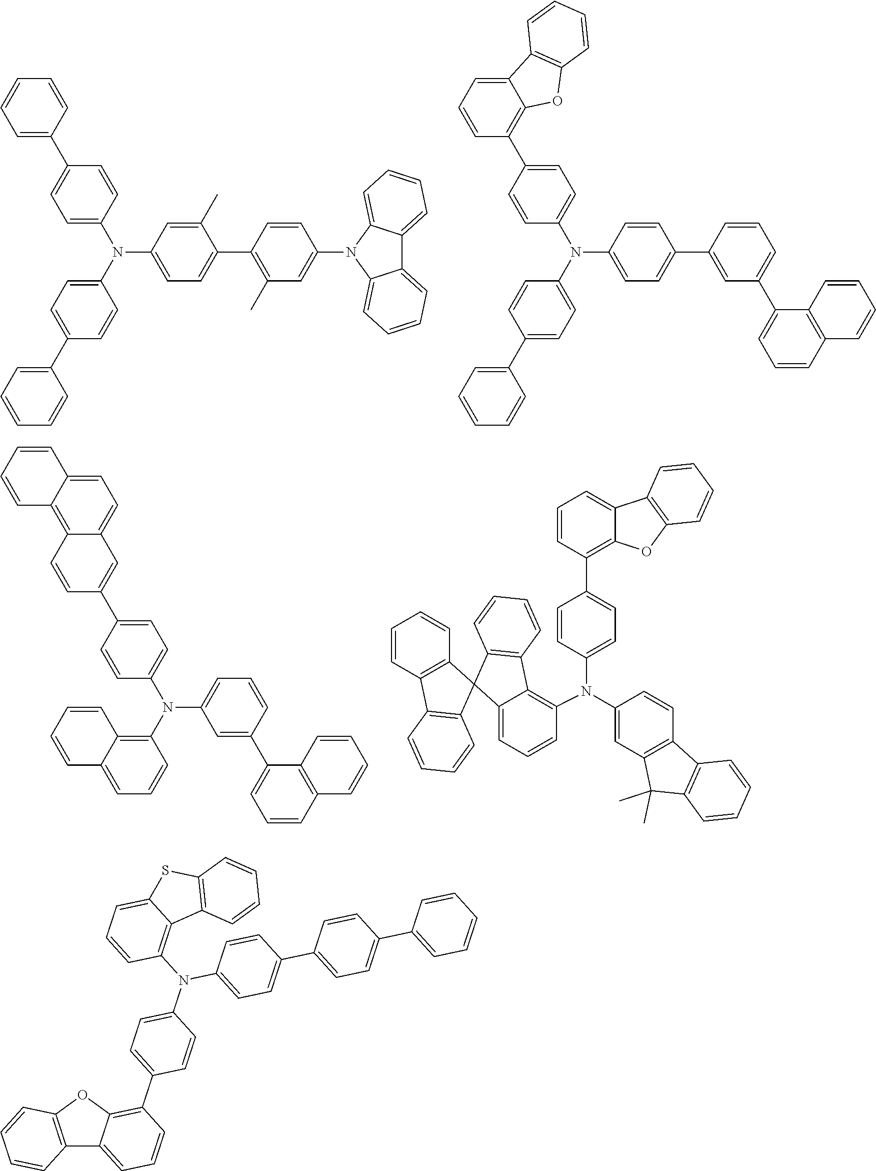

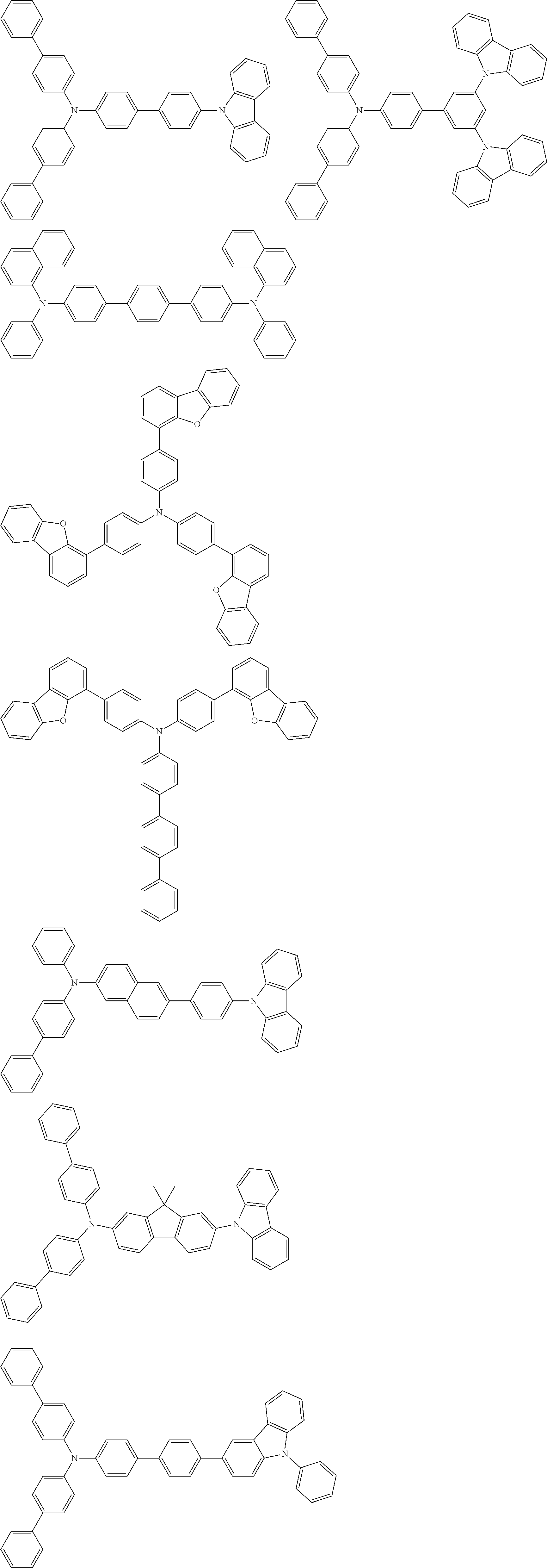

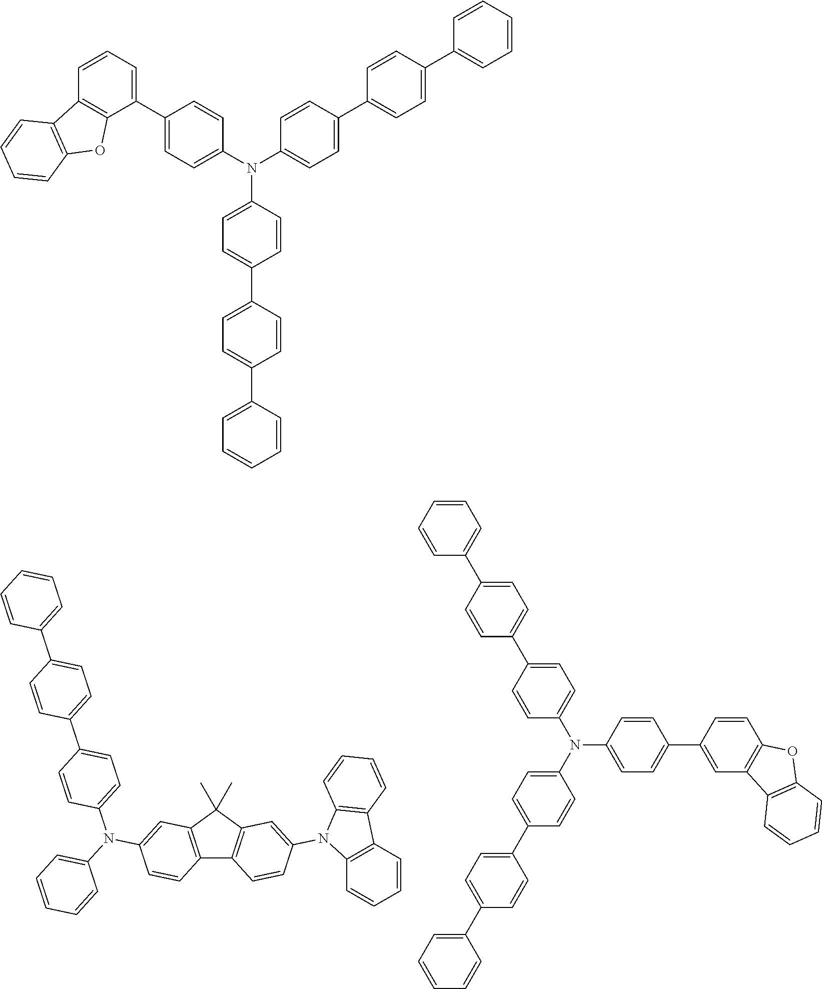 [SMILES: c1ccc(-c2ccc(-c3ccc(N(c4ccc(-c5ccc(-c6ccccc6)cc5)cc4)c4ccc(-c5cccc6c5oc5ccccc56)cc4)cc3)cc2)cc1 ; CC1(C)c2cc(N(c3ccccc3)c3ccc(-c4ccc(-c5ccccc5)cc4)cc3)ccc2-c2ccc(-n3c4ccccc4c4ccccc43)cc21 ; c1ccc(-c2ccc(-c3ccc(N(c4ccc(-c5ccc(-c6ccccc6)cc5)cc4)c4ccc(-c5ccc6oc7ccccc7c6c5)cc4)cc3)cc2)cc1]

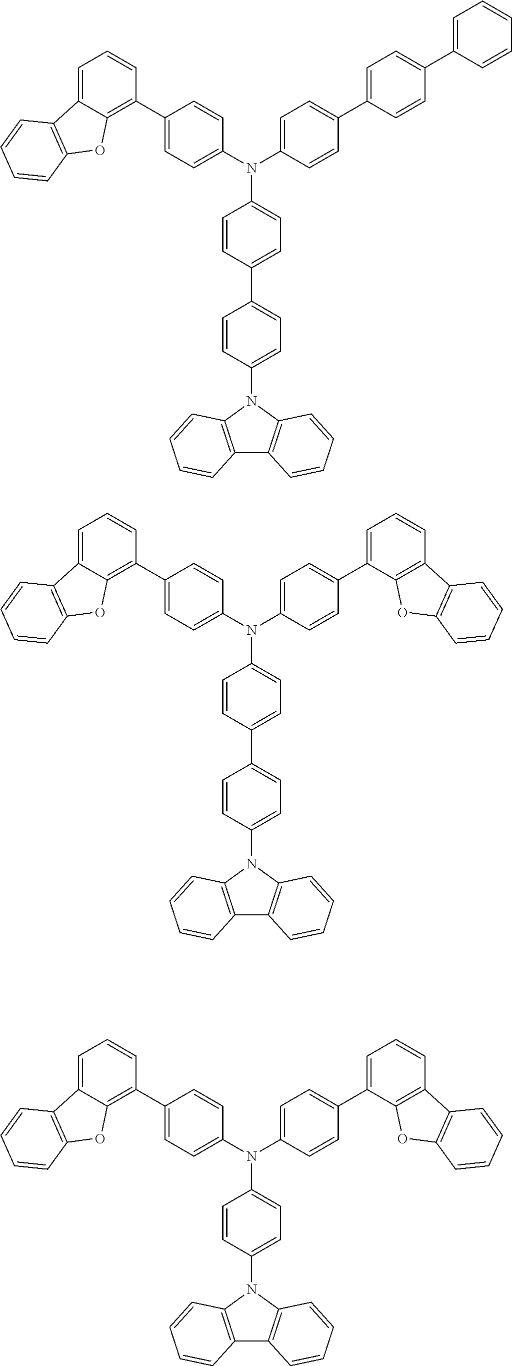 [SMILES: c1ccc(-c2ccc(-c3ccc(N(c4ccc(-c5ccc(-n6c7ccccc7c7ccccc76)cc5)cc4)c4ccc(-c5cccc6c5oc5ccccc56)cc4)cc3)cc2)cc1 ; c1ccc2c(c1)oc1c(-c3ccc(N(c4ccc(-c5ccc(-n6c7ccccc7c7ccccc76)cc5)cc4)c4ccc(-c5cccc6c5oc5ccccc56)cc4)cc3)cccc12 ; c1ccc2c(c1)oc1c(-c3ccc(N(c4ccc(-c5cccc6c5oc5ccccc56)cc4)c4ccc(-n5c6ccccc6c6ccccc65)cc4)cc3)cccc12]

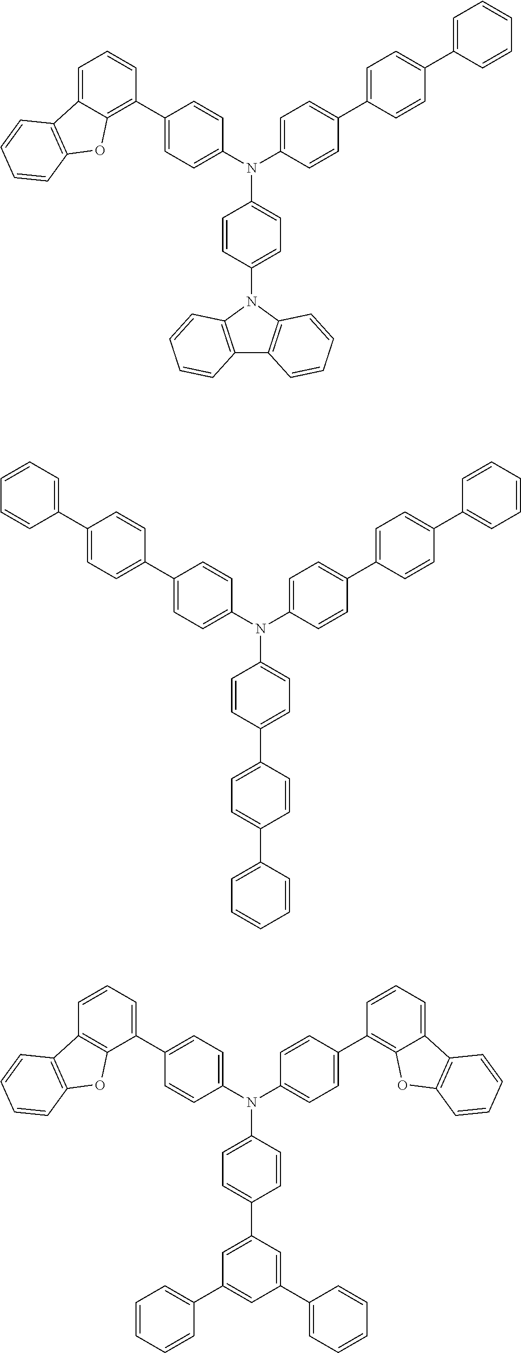 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccc(-c6ccccc6)cc5)cc4)c4ccc(-c5ccc(-c6ccccc6)cc5)cc4)cc3)cc2)cc1 ; c1ccc(-c2cc(-c3ccccc3)cc(-c3ccc(N(c4ccc(-c5cccc6c5oc5ccccc56)cc4)c4ccc(-c5cccc6c5oc5ccccc56)cc4)cc3)c2)cc1]

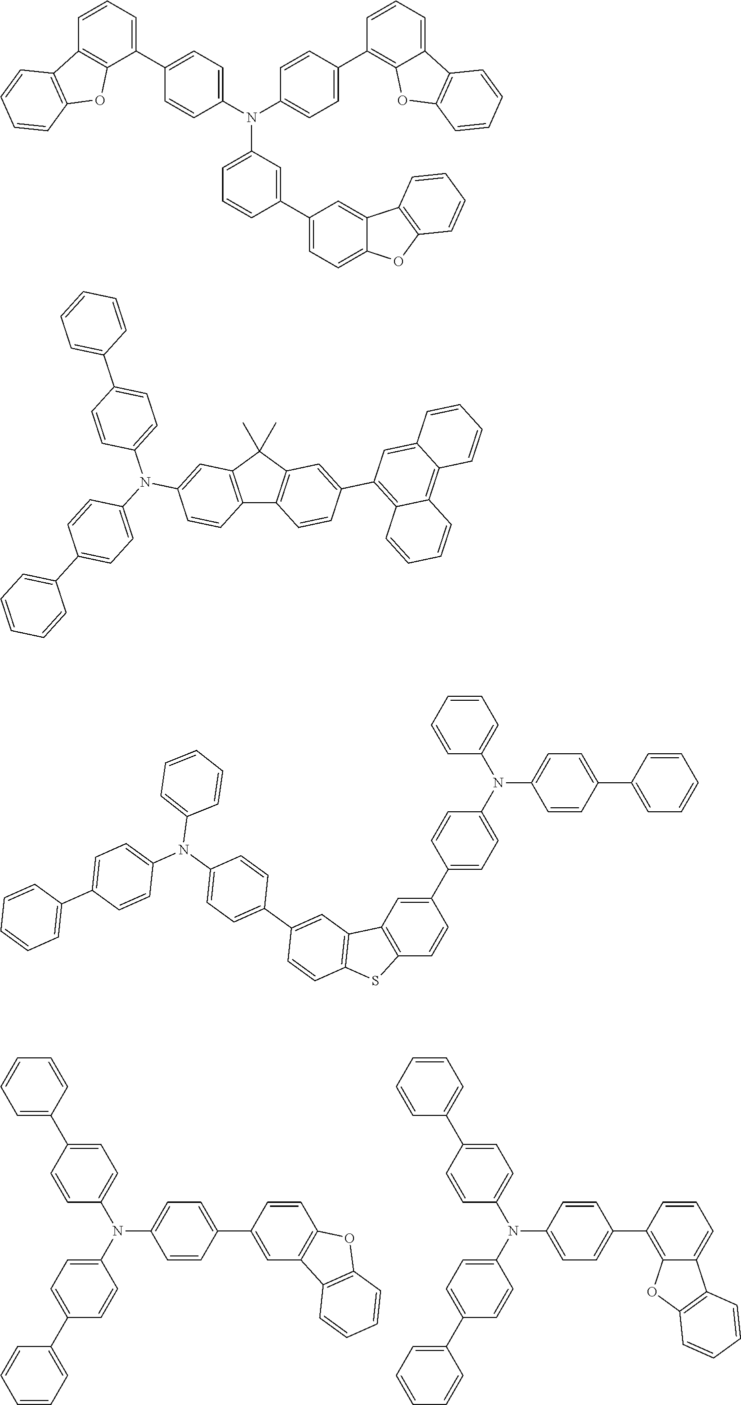

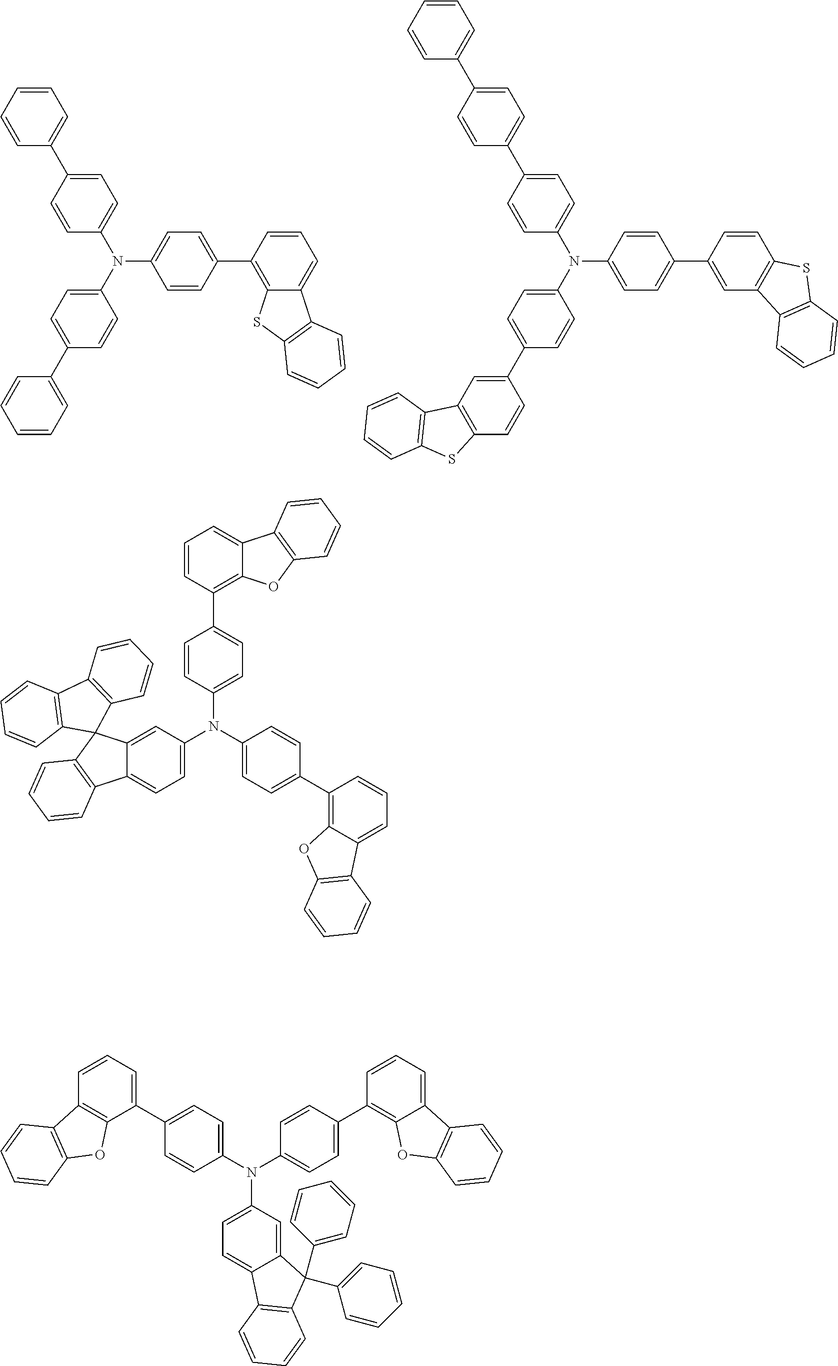

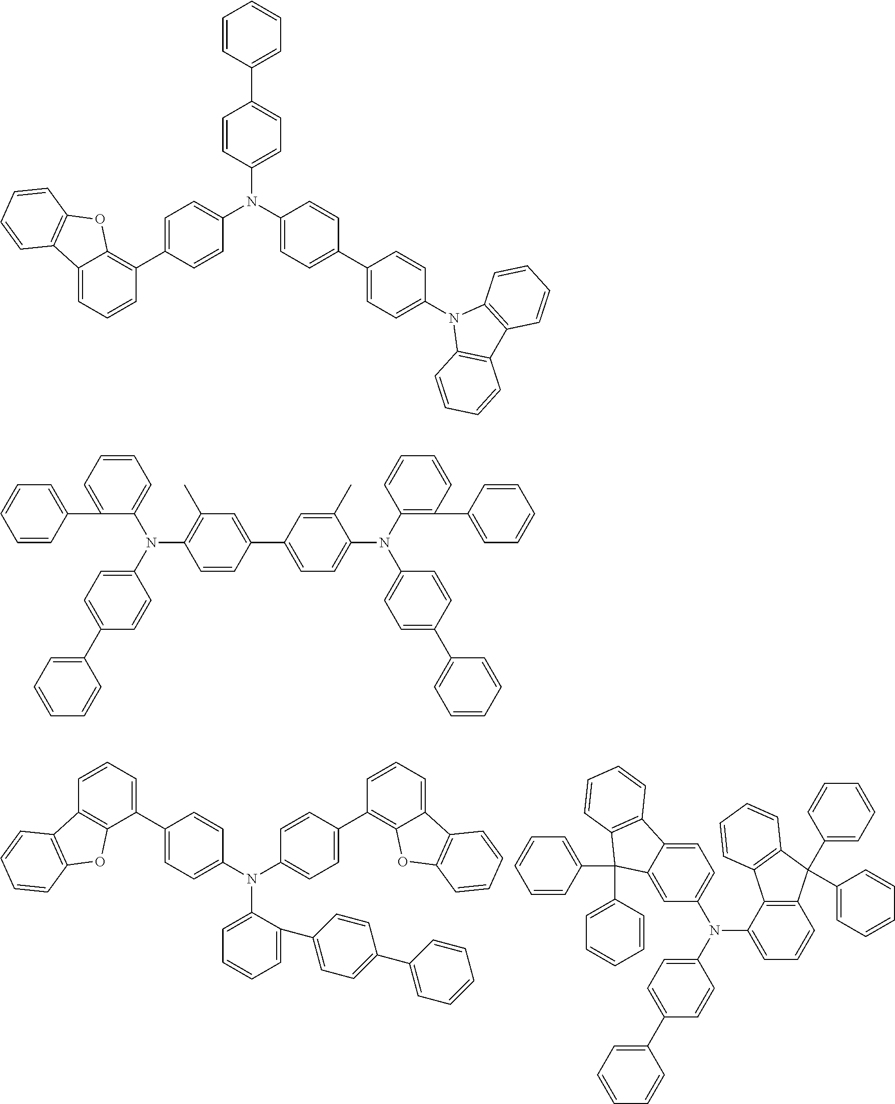

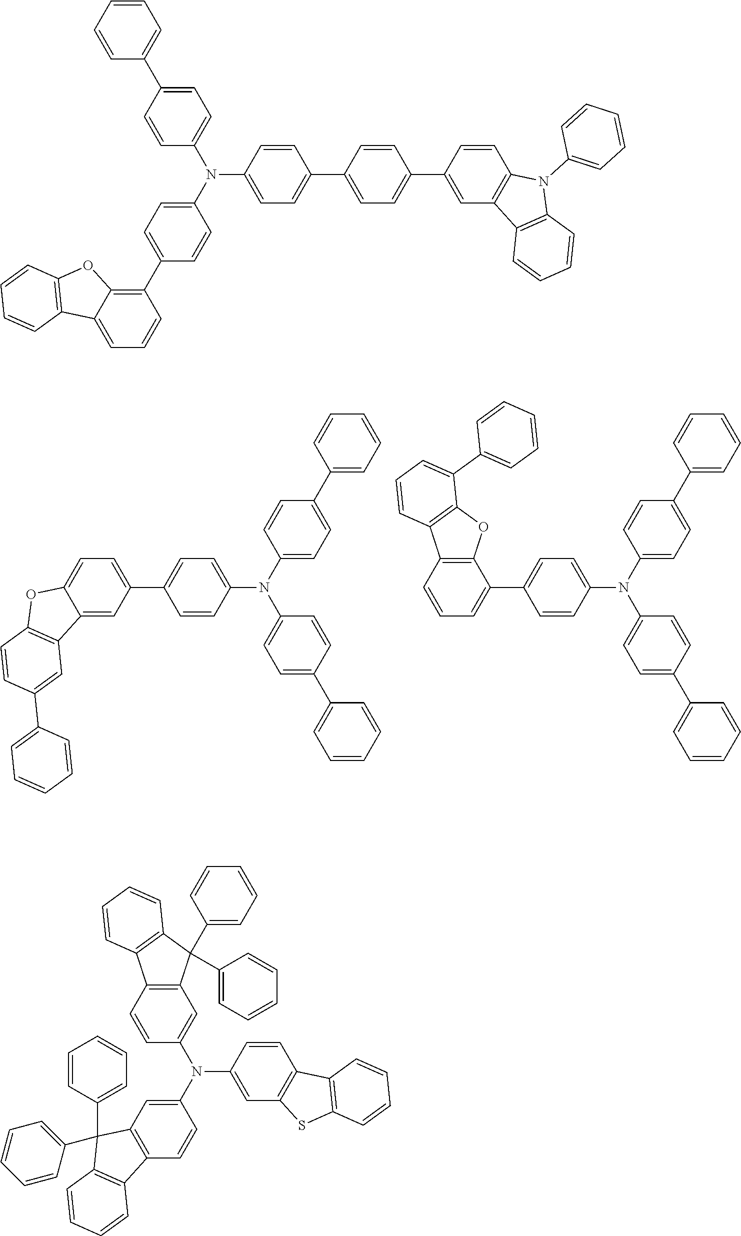

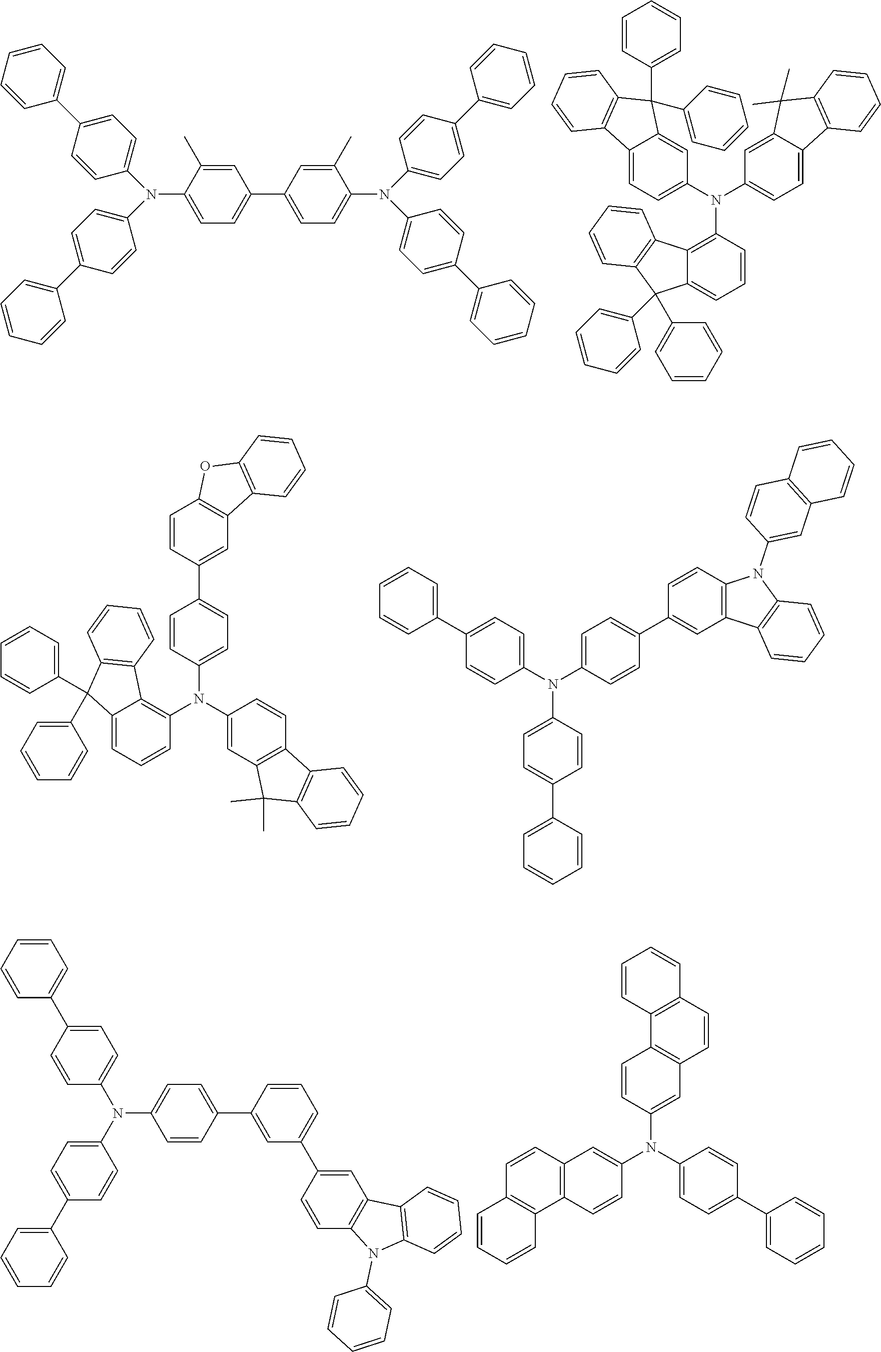

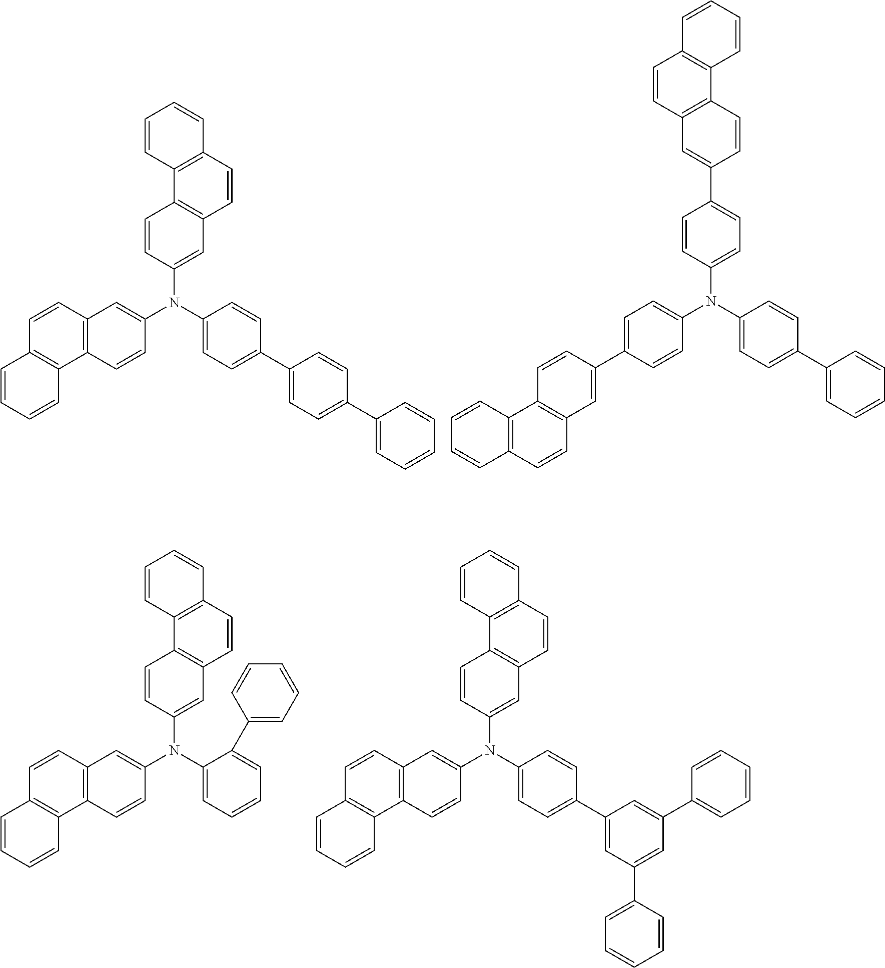

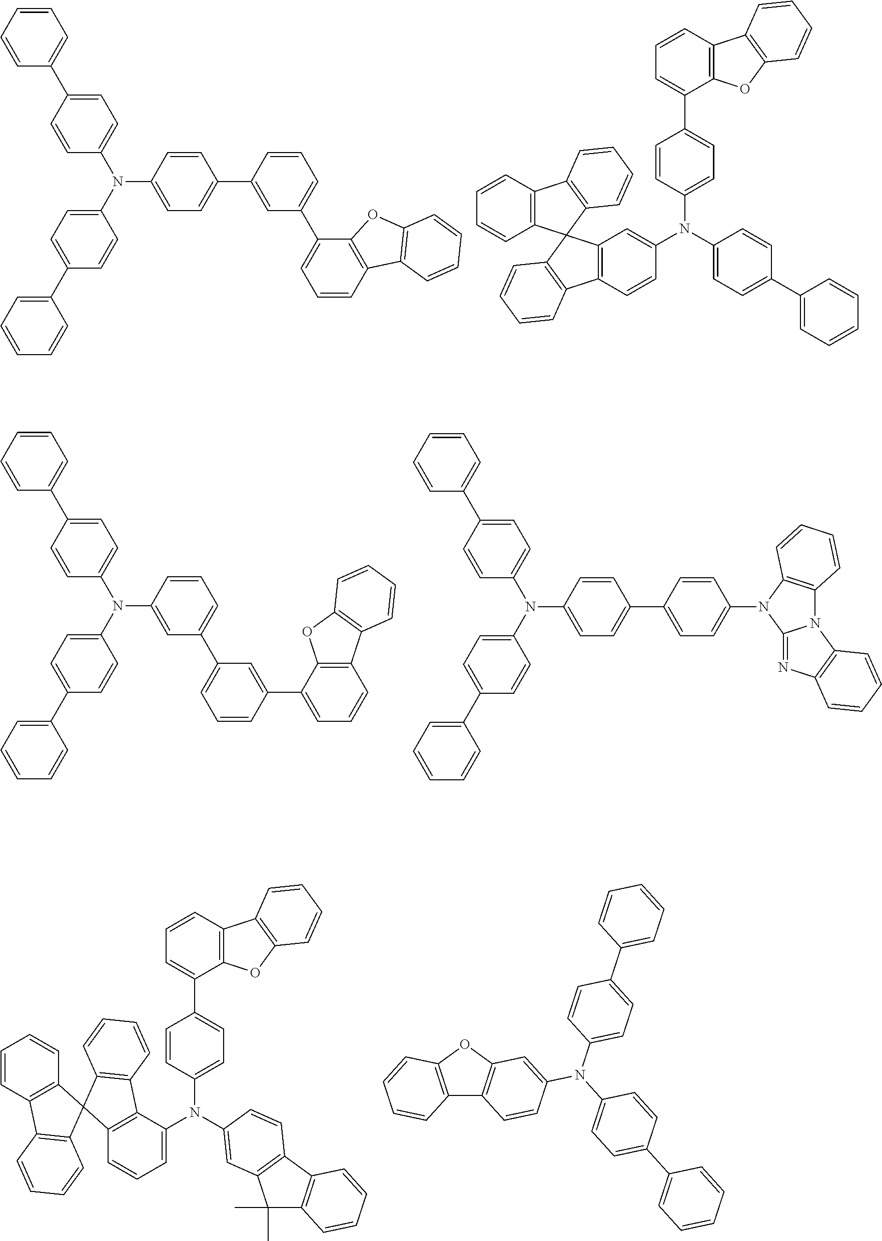

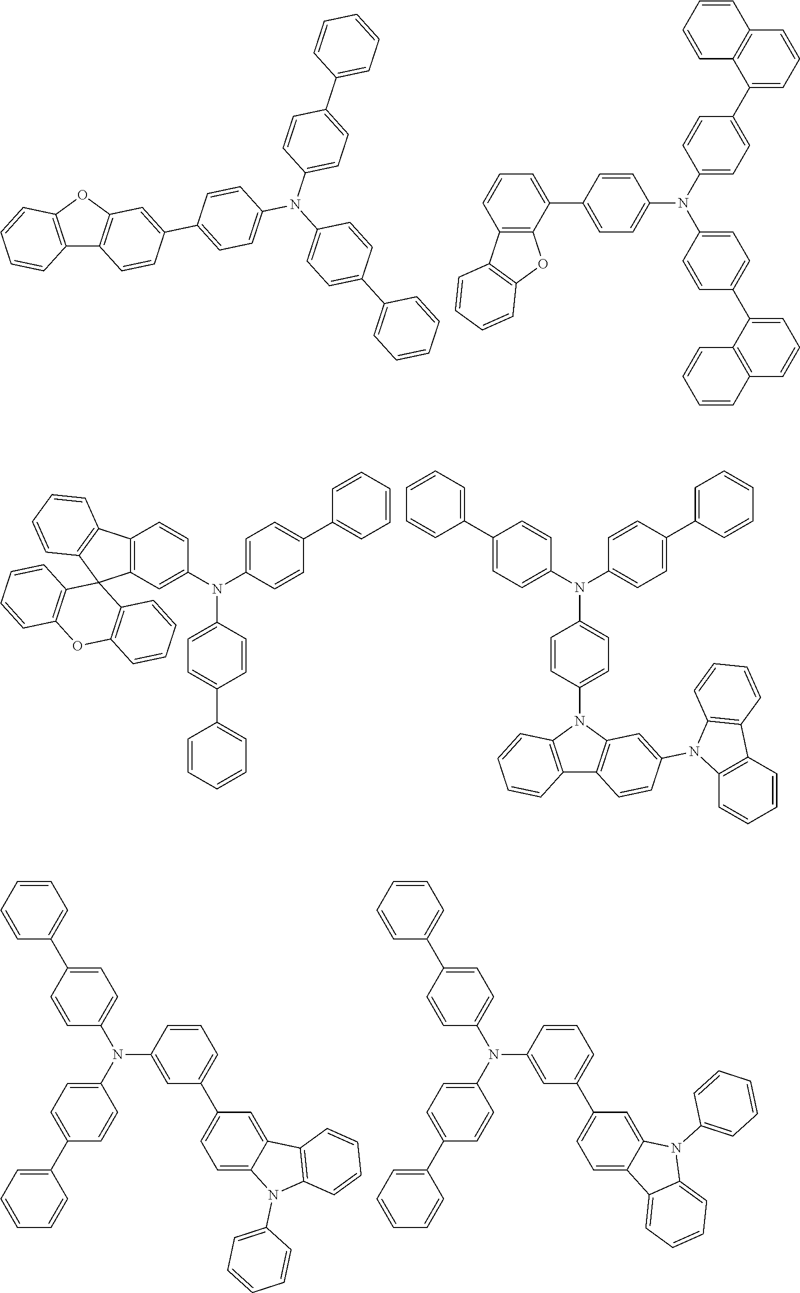

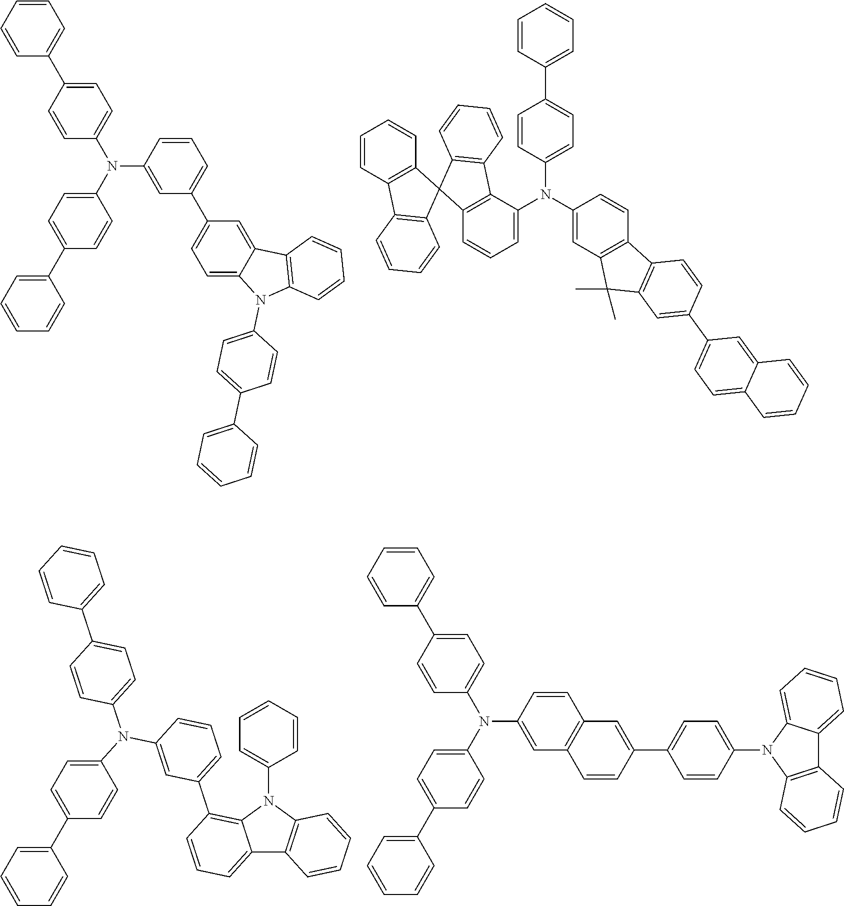

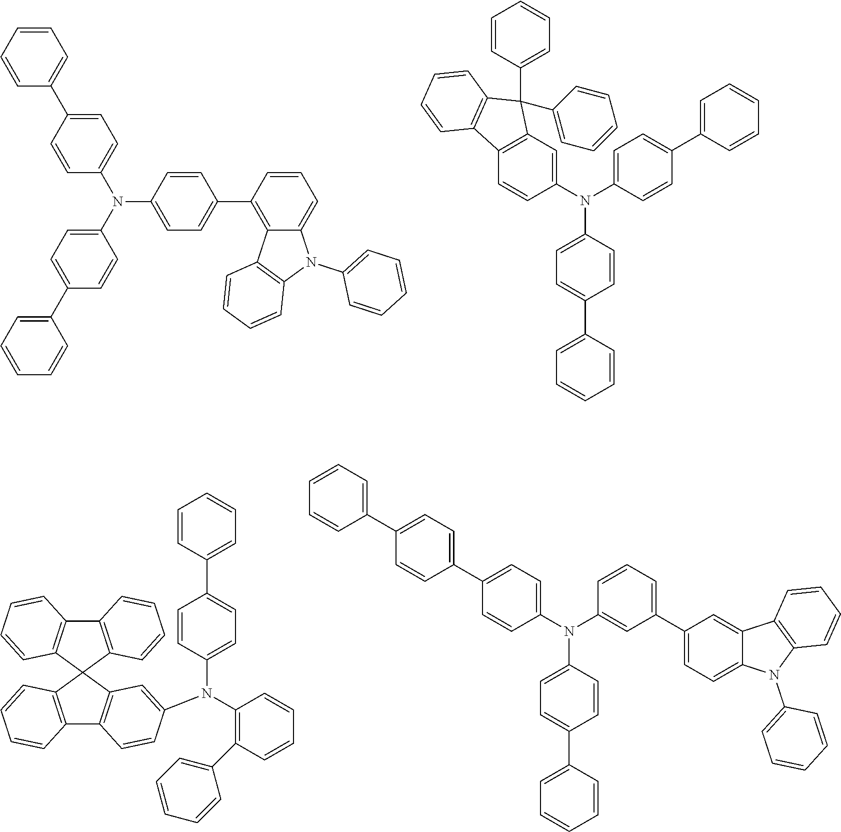 [SMILES: c1ccc(-c2ccc(N(c3ccc(-c4ccccc4)cc3)c3ccc(-c4cccc5c4c4ccccc4n5-c4ccccc4)cc3)cc2)cc1 ; c1ccc(-c2ccc(N(c3ccc(-c4ccccc4)cc3)c3ccc4c(c3)C(c3ccccc3)(c3ccccc3)c3ccccc3-4)cc2)cc1 ; c1ccc(-c2ccc(N(c3ccc4c(c3)C3(c5ccccc5-c5ccccc53)c3ccccc3-4)c3ccccc3-c3ccccc3)cc2)cc1 ; c1ccc(-c2ccc(-c3ccc(N(c4ccc(-c5ccccc5)cc4)c4cccc(-c5ccc6c(c5)c5ccccc5n6-c5ccccc5)c4)cc3)cc2)cc1]

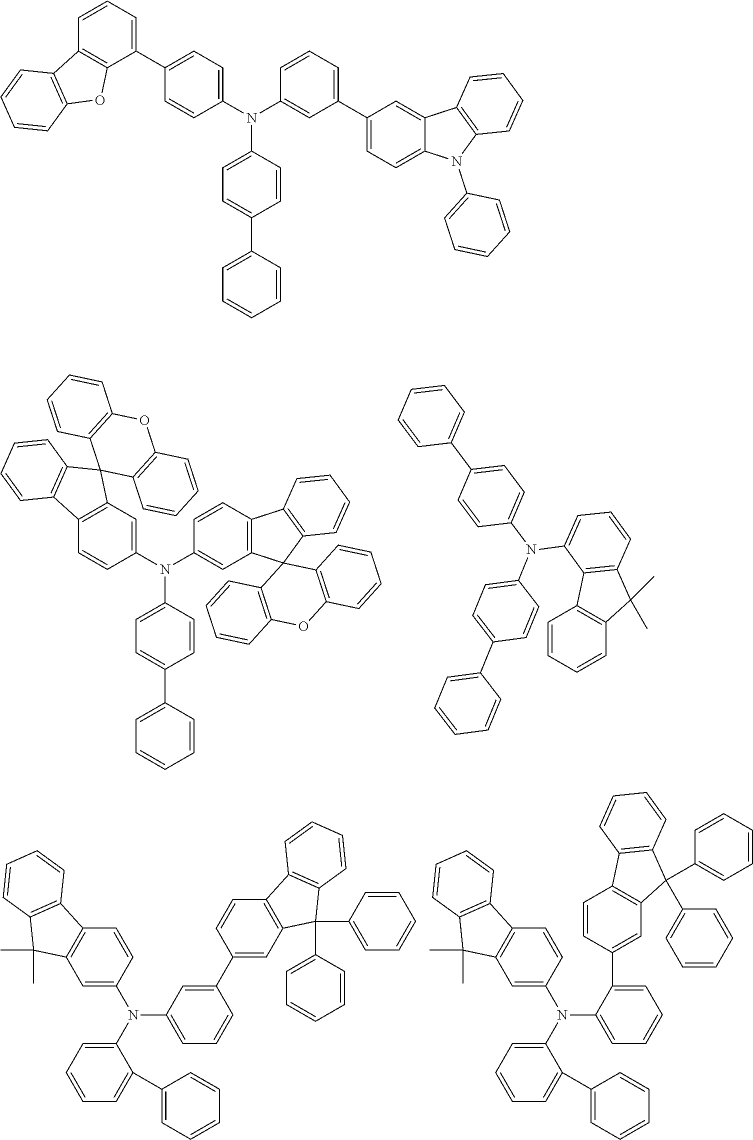

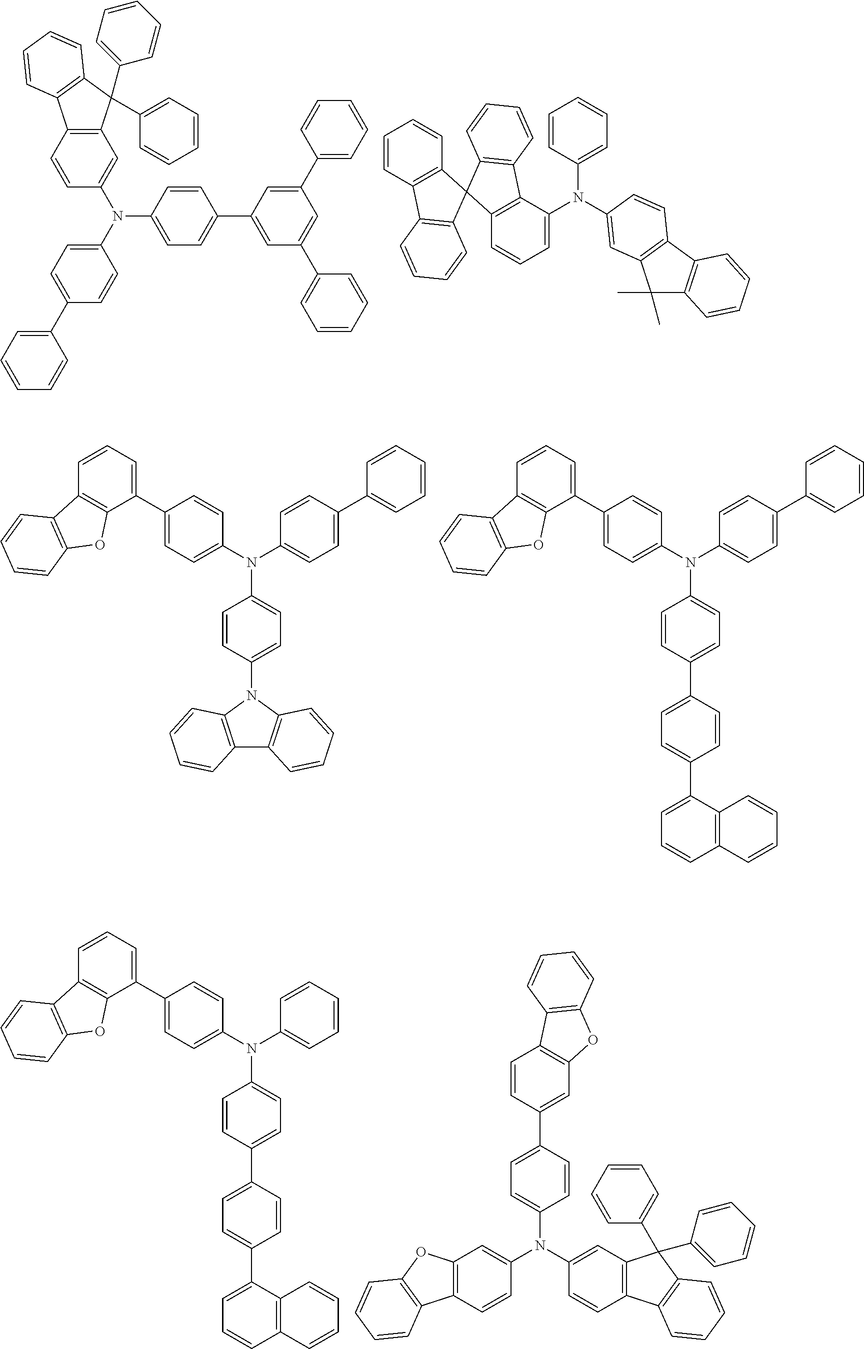

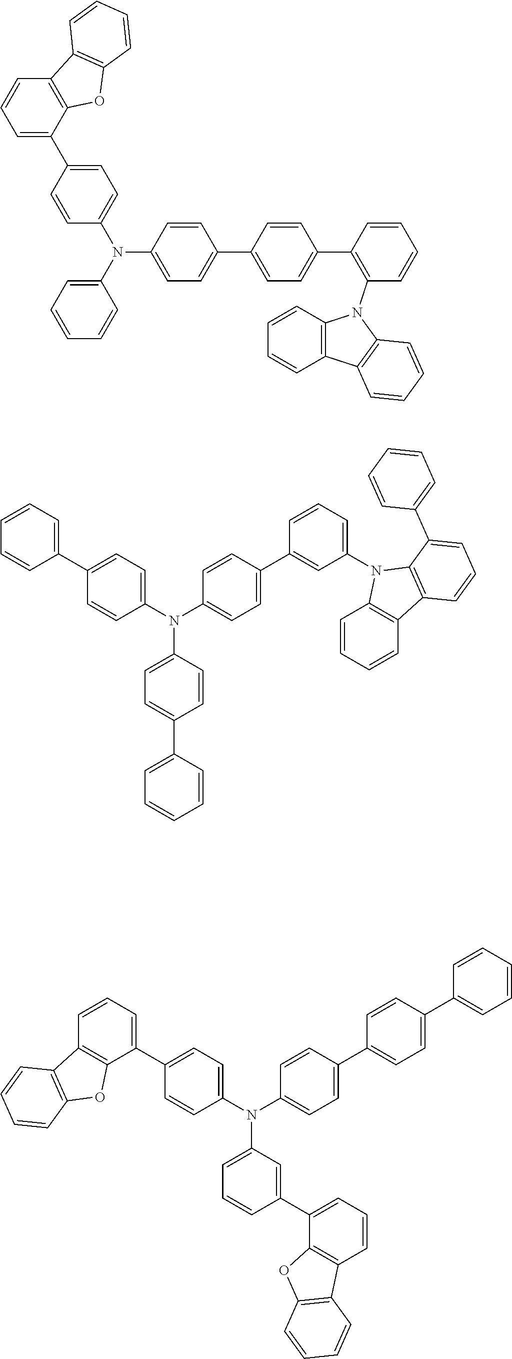 [SMILES: c1ccc(N(c2ccc(-c3ccc(-c4ccccc4-n4c5ccccc5c5ccccc54)cc3)cc2)c2ccc(-c3cccc4c3oc3ccccc34)cc2)cc1 ; c1ccc(-c2ccc(N(c3ccc(-c4ccccc4)cc3)c3ccc(-c4cccc(-n5c6ccccc6c6cccc(-c7ccccc7)c65)c4)cc3)cc2)cc1 ; c1ccc(-c2ccc(-c3ccc(N(c4ccc(-c5cccc6c5oc5ccccc56)cc4)c4cccc(-c5cccc6c5oc5ccccc56)c4)cc3)cc2)cc1]

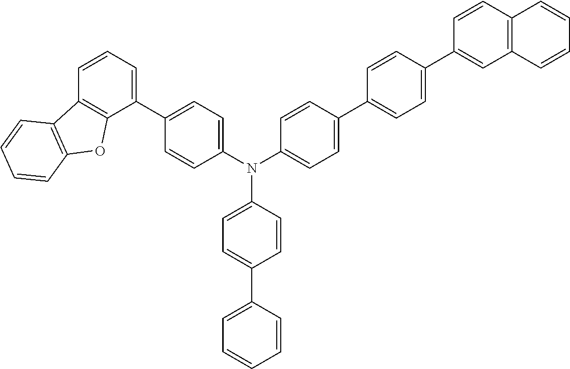 [SMILES: c1ccc(-c2ccc(N(c3ccc(-c4ccc(-c5ccc6ccccc6c5)cc4)cc3)c3ccc(-c4cccc5c4oc4ccccc45)cc3)cc2)cc1]

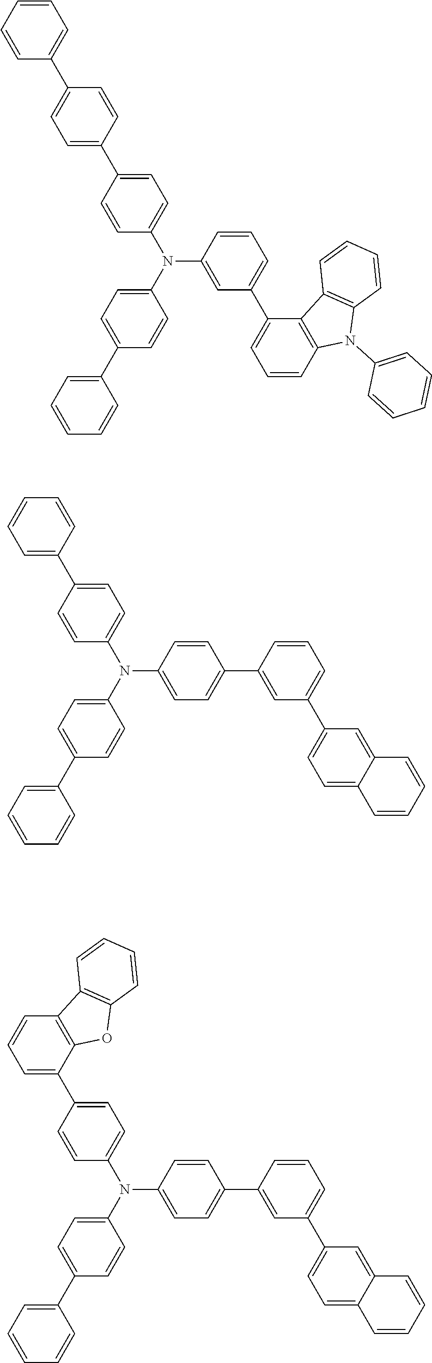 [SMILES: c1ccc(-c2ccc(-c3ccc(N(c4ccc(-c5ccccc5)cc4)c4cccc(-c5cccc6c5c5ccccc5n6-c5ccccc5)c4)cc3)cc2)cc1 ; c1ccc(-c2ccc(N(c3ccc(-c4ccccc4)cc3)c3ccc(-c4cccc(-c5ccc6ccccc6c5)c4)cc3)cc2)cc1 ; c1ccc(-c2ccc(N(c3ccc(-c4cccc(-c5ccc6ccccc6c5)c4)cc3)c3ccc(-c4cccc5c4oc4ccccc45)cc3)cc2)cc1]

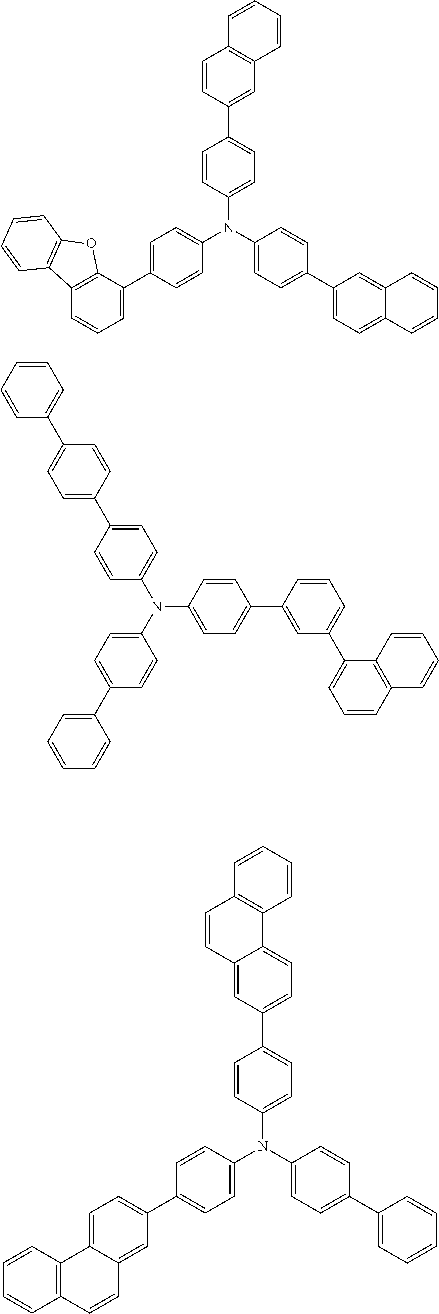 [SMILES: c1ccc2cc(-c3ccc(N(c4ccc(-c5ccc6ccccc6c5)cc4)c4ccc(-c5cccc6c5oc5ccccc56)cc4)cc3)ccc2c1 ; c1ccc(-c2ccc(-c3ccc(N(c4ccc(-c5ccccc5)cc4)c4ccc(-c5cccc(-c6cccc7ccccc67)c5)cc4)cc3)cc2)cc1 ; c1ccc(-c2ccc(N(c3ccc(-c4ccc5c(ccc6ccccc65)c4)cc3)c3ccc(-c4ccc5c(ccc6ccccc65)c4)cc3)cc2)cc1]

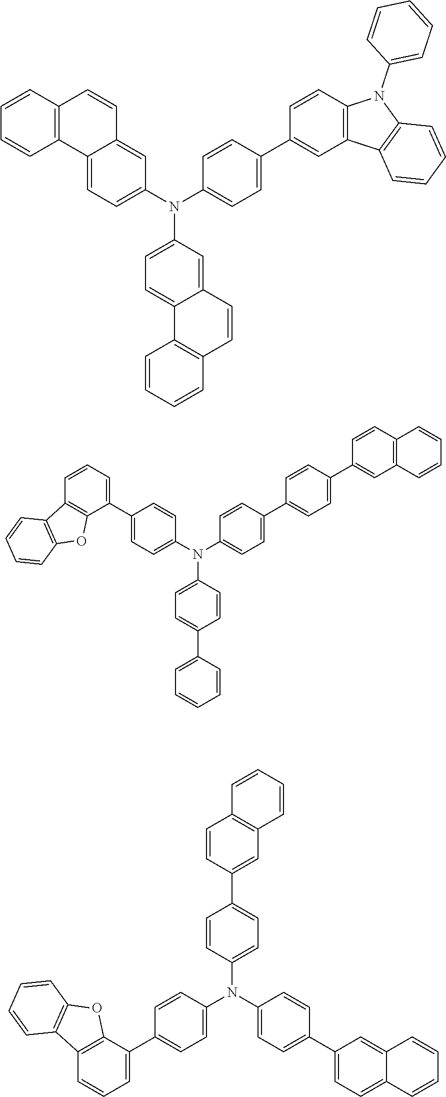 [SMILES: c1ccc(-n2c3ccccc3c3cc(-c4ccc(N(c5ccc6c(ccc7ccccc76)c5)c5ccc6c(ccc7ccccc76)c5)cc4)ccc32)cc1 ; c1ccc(-c2ccc(N(c3ccc(-c4ccc(-c5ccc6ccccc6c5)cc4)cc3)c3ccc(-c4cccc5c4oc4ccccc45)cc3)cc2)cc1 ; c1ccc2cc(-c3ccc(N(c4ccc(-c5ccc6ccccc6c5)cc4)c4ccc(-c5cccc6c5oc5ccccc56)cc4)cc3)ccc2c1]

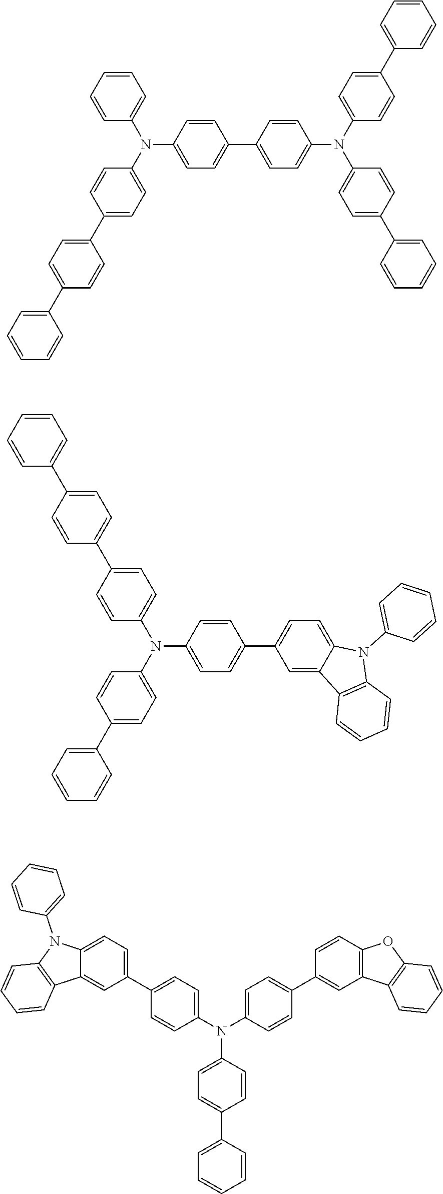 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(-c2ccc(-c3ccc(N(c4ccc(-c5ccccc5)cc4)c4ccc(-c5ccc6c(c5)c5ccccc5n6-c5ccccc5)cc4)cc3)cc2)cc1 ; c1ccc(-c2ccc(N(c3ccc(-c4ccc5oc6ccccc6c5c4)cc3)c3ccc(-c4ccc5c(c4)c4ccccc4n5-c4ccccc4)cc3)cc2)cc1]

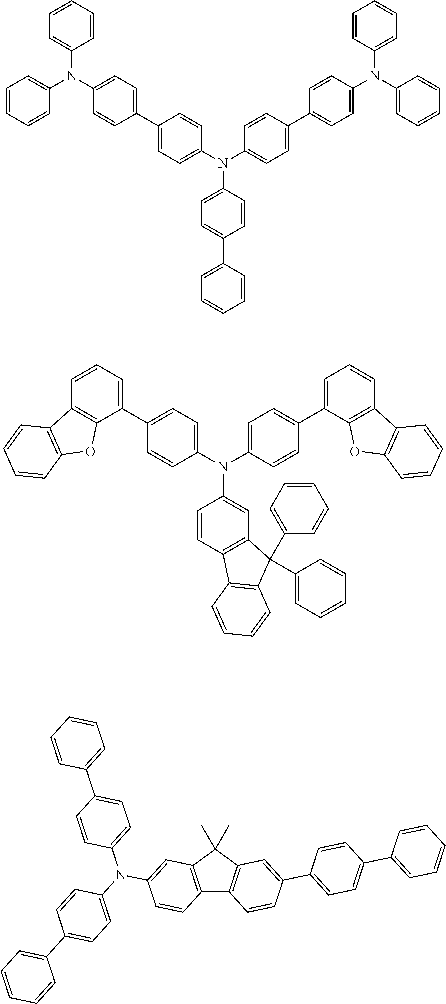 [SMILES: c1ccc(-c2ccc(N(c3ccc(-c4ccc(N(c5ccccc5)c5ccccc5)cc4)cc3)c3ccc(-c4ccc(N(c5ccccc5)c5ccccc5)cc4)cc3)cc2)cc1 ; c1ccc(C2(c3ccccc3)c3ccccc3-c3ccc(N(c4ccc(-c5cccc6c5oc5ccccc56)cc4)c4ccc(-c5cccc6c5oc5ccccc56)cc4)cc32)cc1 ; CC1(C)c2cc(-c3ccc(-c4ccccc4)cc3)ccc2-c2ccc(N(c3ccc(-c4ccccc4)cc3)c3ccc(-c4ccccc4)cc3)cc21]

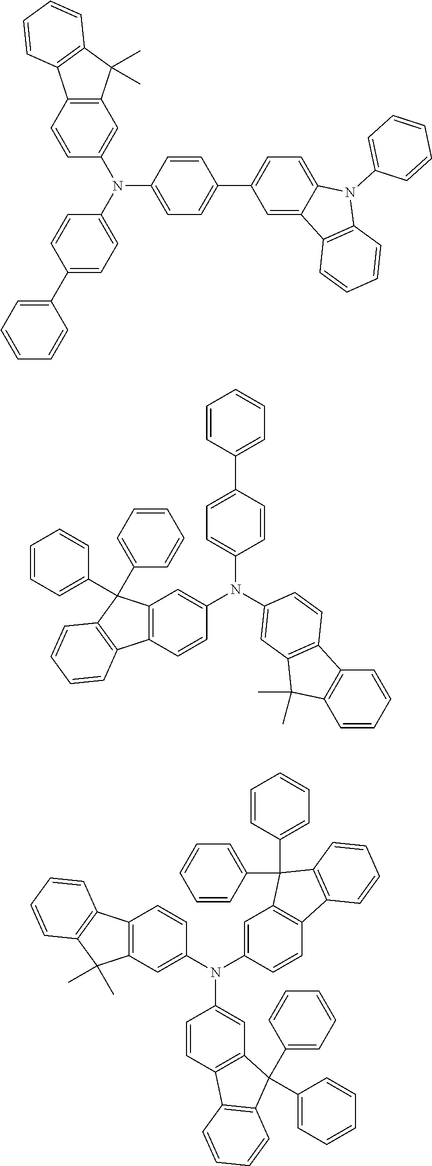 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccc(-c4ccccc4)cc3)c3ccc4c(c3)C(c3ccccc3)(c3ccccc3)c3ccccc3-4)cc21 ; CC1(C)c2ccccc2-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc21]

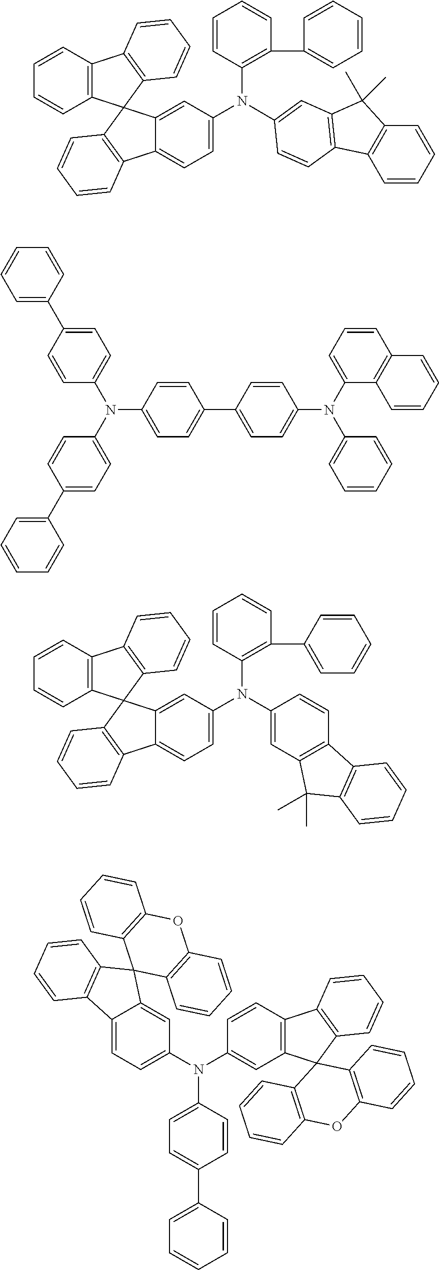 [SMILES: CC1(C)c2ccccc2-c2ccc(N(c3ccc4c(c3)C3(c5ccccc5-c5ccccc53)c3ccccc3-4)c3ccccc3-c3ccccc3)cc21 ; c1ccc(-c2ccc(N(c3ccc(-c4ccccc4)cc3)c3ccc(-c4ccc(N(c5ccccc5)c5cccc6ccccc56)cc4)cc3)cc2)cc1 ; CC1(C)c2ccccc2-c2ccc(N(c3ccc4c(c3)C3(c5ccccc5-c5ccccc53)c3ccccc3-4)c3ccccc3-c3ccccc3)cc21 ; c1ccc(-c2ccc(N(c3ccc4c(c3)C3(c5ccccc5Oc5ccccc53)c3ccccc3-4)c3ccc4c(c3)C3(c5ccccc5Oc5ccccc53)c3ccccc3-4)cc2)cc1]

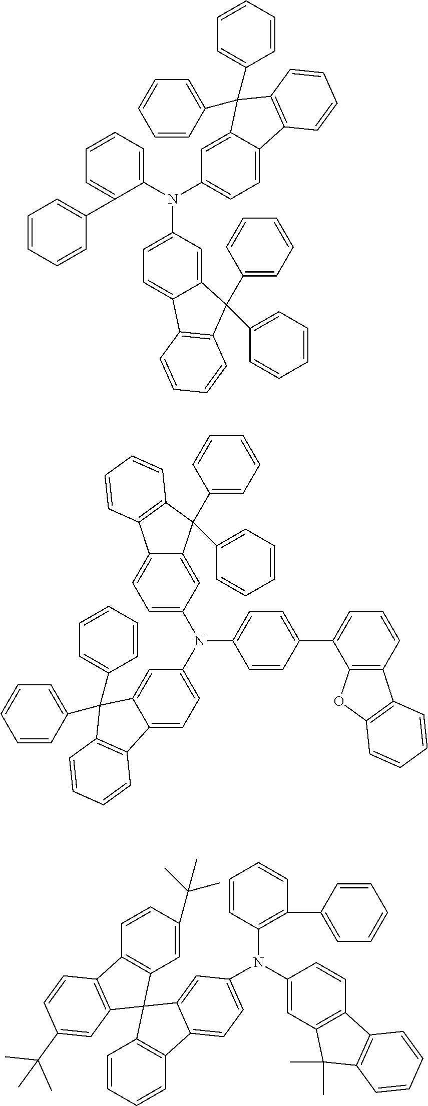

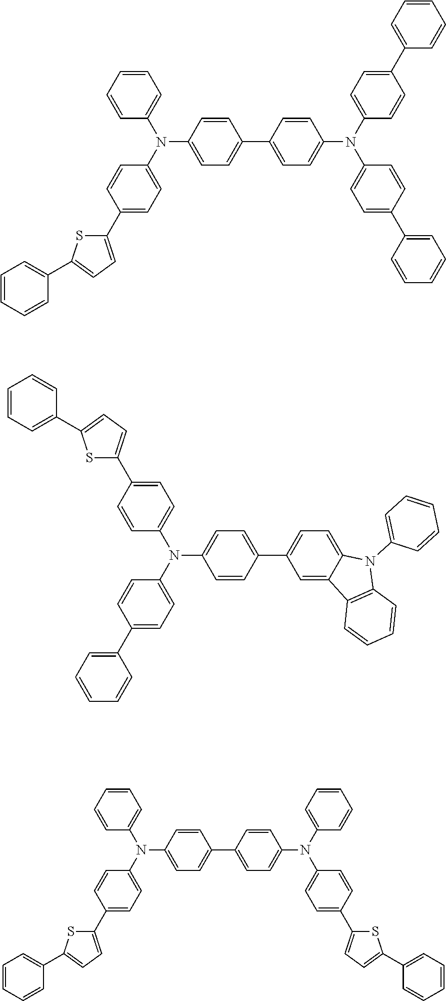 [SMILES: c1ccc(-c2ccc(N(c3ccc(-c4ccccc4)cc3)c3ccc(-c4ccc(N(c5ccccc5)c5ccc(-c6ccc(-c7ccccc7)s6)cc5)cc4)cc3)cc2)cc1 ; c1ccc(-c2ccc(N(c3ccc(-c4ccc5c(c4)c4ccccc4n5-c4ccccc4)cc3)c3ccc(-c4ccc(-c5ccccc5)s4)cc3)cc2)cc1 ; c1ccc(-c2ccc(-c3ccc(N(c4ccccc4)c4ccc(-c5ccc(N(c6ccccc6)c6ccc(-c7ccc(-c8ccccc8)s7)cc6)cc5)cc4)cc3)s2)cc1]

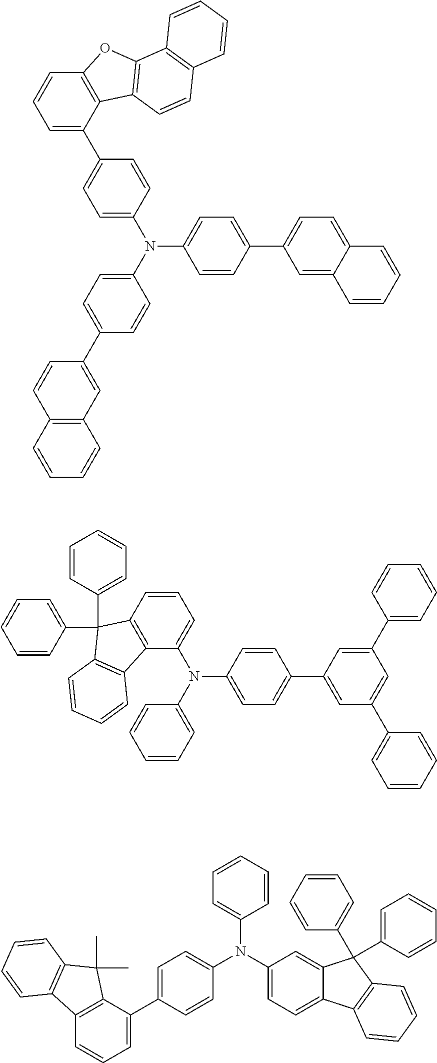 [SMILES: c1ccc2cc(-c3ccc(N(c4ccc(-c5ccc6ccccc6c5)cc4)c4ccc(-c5cccc6oc7c8ccccc8ccc7c56)cc4)cc3)ccc2c1 ; c1ccc(-c2cc(-c3ccccc3)cc(-c3ccc(N(c4ccccc4)c4cccc5c4-c4ccccc4C5(c4ccccc4)c4ccccc4)cc3)c2)cc1 ; CC1(C)c2ccccc2-c2cccc(-c3ccc(N(c4ccccc4)c4ccc5c(c4)C(c4ccccc4)(c4ccccc4)c4ccccc4-5)cc3)c21]

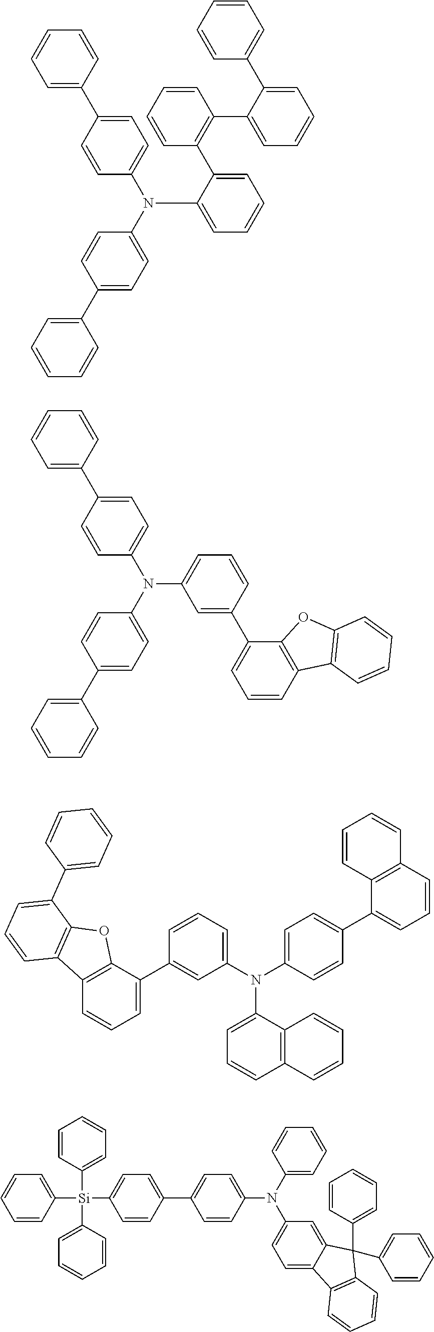

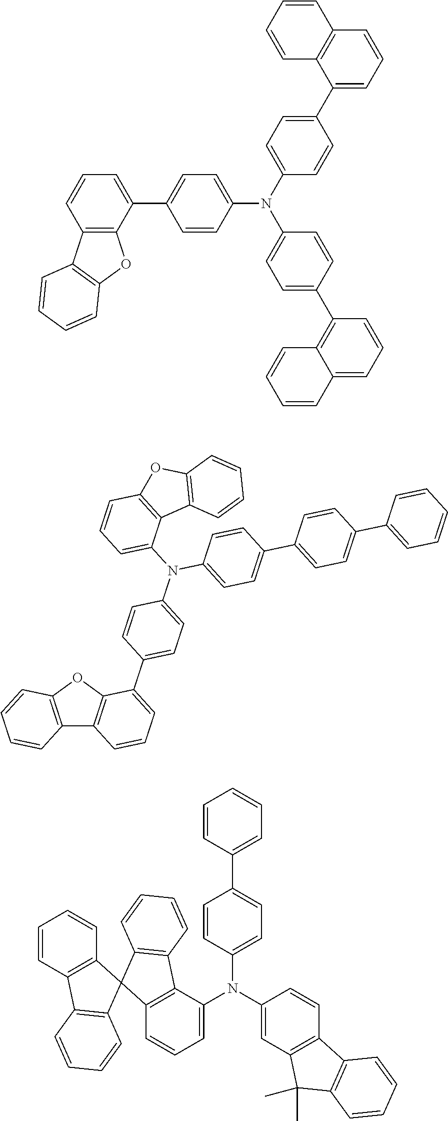 [SMILES: c1ccc2c(-c3ccc(N(c4ccc(-c5cccc6ccccc56)cc4)c4ccc(-c5cccc6c5oc5ccccc56)cc4)cc3)cccc2c1 ; c1ccc(-c2ccc(-c3ccc(N(c4ccc(-c5cccc6c5oc5ccccc56)cc4)c4cccc5oc6ccccc6c45)cc3)cc2)cc1 ; CC1(C)c2ccccc2-c2ccc(N(c3ccc(-c4ccccc4)cc3)c3cccc4c3-c3ccccc3C43c4ccccc4-c4ccccc43)cc21]

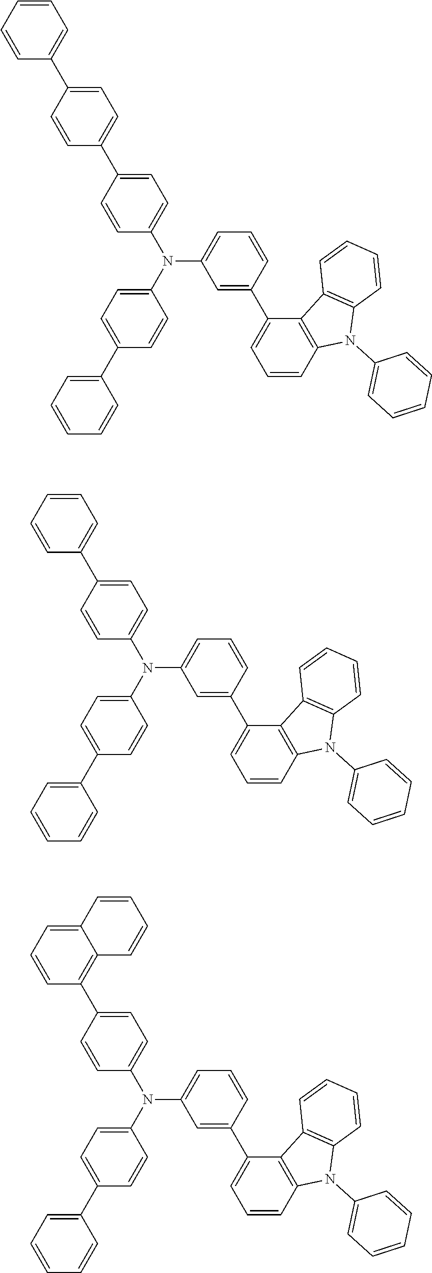 [SMILES: c1ccc(-c2ccc(-c3ccc(N(c4ccc(-c5ccccc5)cc4)c4cccc(-c5cccc6c5c5ccccc5n6-c5ccccc5)c4)cc3)cc2)cc1 ; c1ccc(-c2ccc(N(c3ccc(-c4ccccc4)cc3)c3cccc(-c4cccc5c4c4ccccc4n5-c4ccccc4)c3)cc2)cc1 ; c1ccc(-c2ccc(N(c3ccc(-c4cccc5ccccc45)cc3)c3cccc(-c4cccc5c4c4ccccc4n5-c4ccccc4)c3)cc2)cc1]

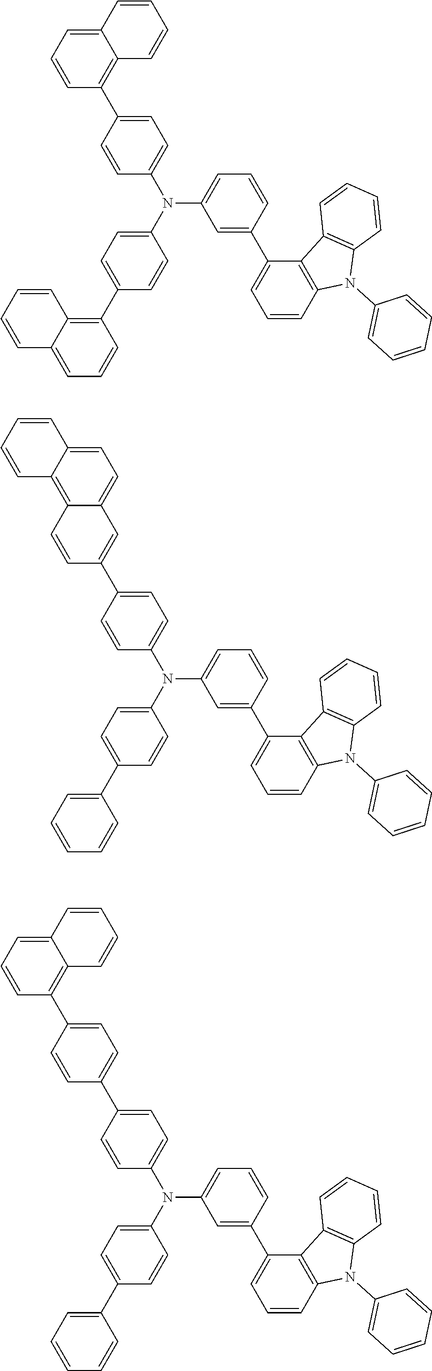

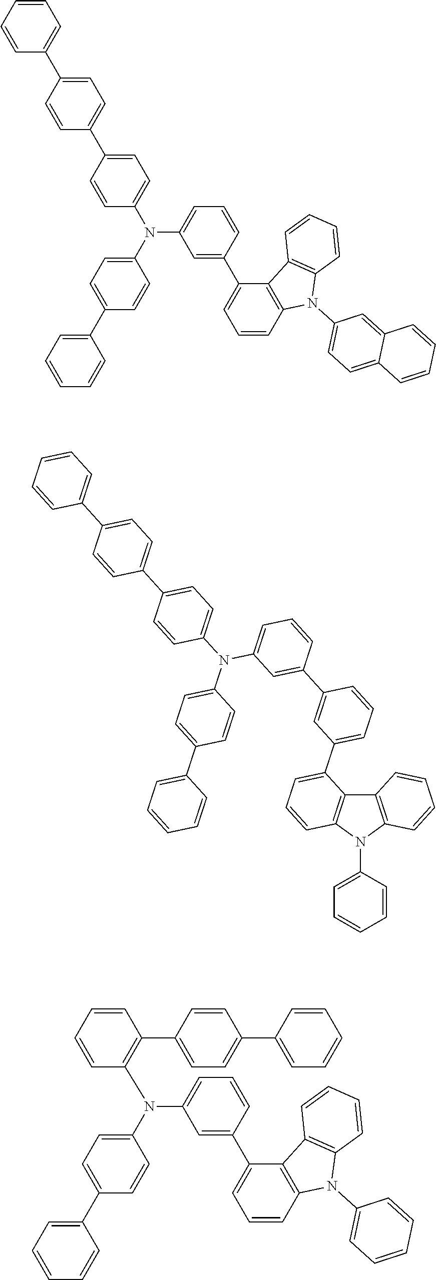 [SMILES: c1ccc(-c2ccc(-c3ccc(N(c4ccc(-c5ccccc5)cc4)c4cccc(-c5cccc6c5c5ccccc5n6-c5ccc6ccccc6c5)c4)cc3)cc2)cc1 ; c1ccc(-c2ccc(-c3ccc(N(c4ccc(-c5ccccc5)cc4)c4cccc(-c5cccc(-c6cccc7c6c6ccccc6n7-c6ccccc6)c5)c4)cc3)cc2)cc1 ; c1ccc(-c2ccc(-c3ccccc3N(c3ccc(-c4ccccc4)cc3)c3cccc(-c4cccc5c4c4ccccc4n5-c4ccccc4)c3)cc2)cc1]

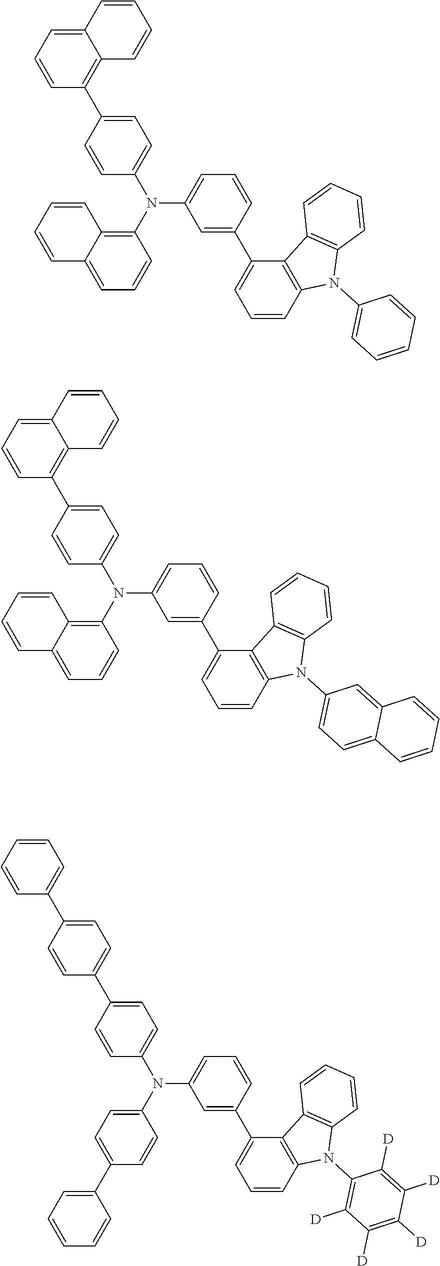 [SMILES: c1ccc(-n2c3ccccc3c3c(-c4cccc(N(c5ccc(-c6cccc7ccccc67)cc5)c5cccc6ccccc56)c4)cccc32)cc1 ; c1cc(-c2cccc3c2c2ccccc2n3-c2ccc3ccccc3c2)cc(N(c2ccc(-c3cccc4ccccc34)cc2)c2cccc3ccccc23)c1 ; [2H]c1c([2H])c([2H])c(-n2c3ccccc3c3c(-c4cccc(N(c5ccc(-c6ccccc6)cc5)c5ccc(-c6ccc(-c7ccccc7)cc6)cc5)c4)cccc32)c([2H])c1[2H]]

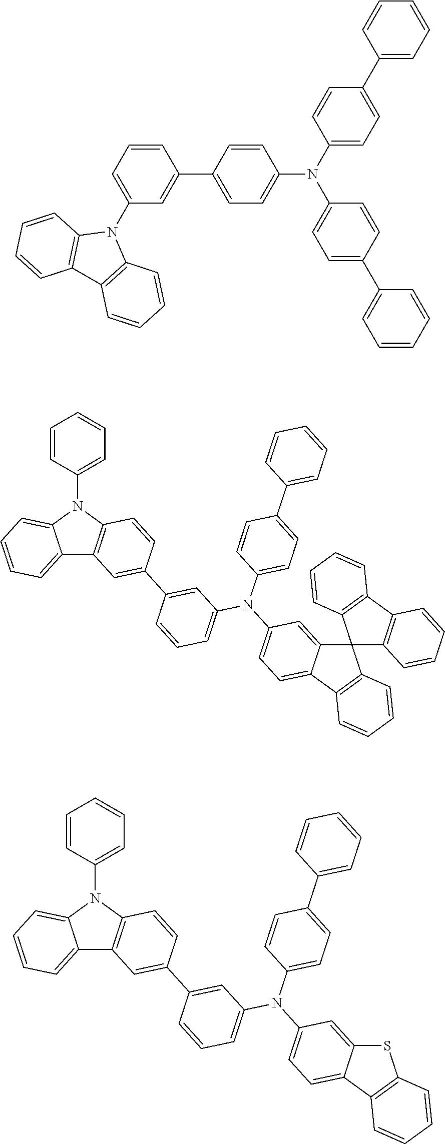 [SMILES: c1ccc(-c2ccc(N(c3ccc(-c4ccccc4)cc3)c3ccc(-c4cccc(-n5c6ccccc6c6ccccc65)c4)cc3)cc2)cc1 ; c1ccc(-c2ccc(N(c3cccc(-c4ccc5c(c4)c4ccccc4n5-c4ccccc4)c3)c3ccc4c(c3)C3(c5ccccc5-c5ccccc53)c3ccccc3-4)cc2)cc1 ; c1ccc(-c2ccc(N(c3cccc(-c4ccc5c(c4)c4ccccc4n5-c4ccccc4)c3)c3ccc4c(c3)sc3ccccc34)cc2)cc1]

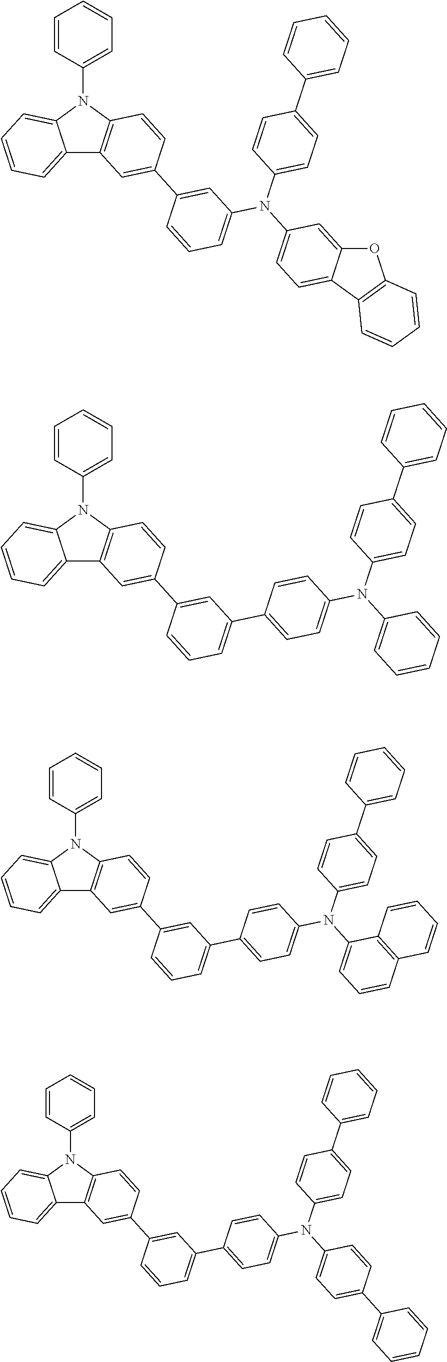 [SMILES: c1ccc(-c2ccc(N(c3cccc(-c4ccc5c(c4)c4ccccc4n5-c4ccccc4)c3)c3ccc4c(c3)oc3ccccc34)cc2)cc1 ; c1ccc(-c2ccc(N(c3ccccc3)c3ccc(-c4cccc(-c5ccc6c(c5)c5ccccc5n6-c5ccccc5)c4)cc3)cc2)cc1 ; c1ccc(-c2ccc(N(c3ccc(-c4cccc(-c5ccc6c(c5)c5ccccc5n6-c5ccccc5)c4)cc3)c3cccc4ccccc34)cc2)cc1 ; c1ccc(-c2ccc(N(c3ccc(-c4ccccc4)cc3)c3ccc(-c4cccc(-c5ccc6c(c5)c5ccccc5n6-c5ccccc5)c4)cc3)cc2)cc1]

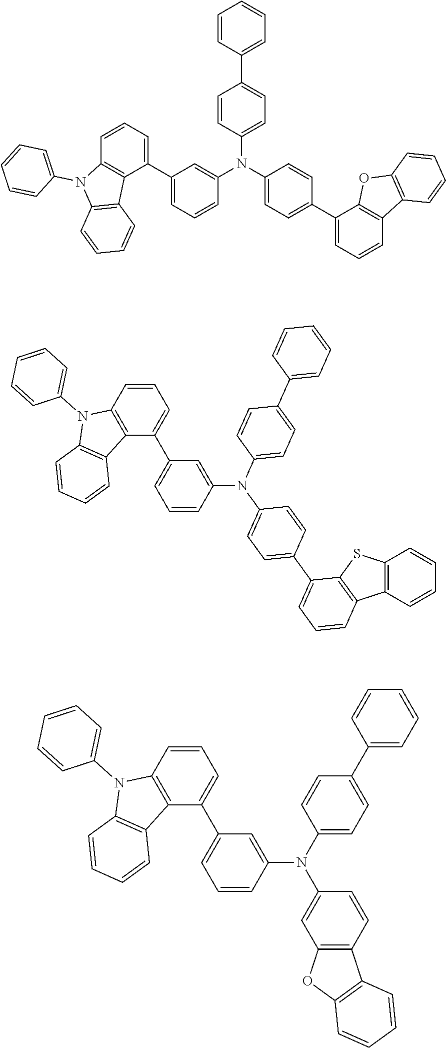 [SMILES: c1ccc(-c2ccc(N(c3ccc(-c4cccc5c4oc4ccccc45)cc3)c3cccc(-c4cccc5c4c4ccccc4n5-c4ccccc4)c3)cc2)cc1 ; c1ccc(-c2ccc(N(c3ccc(-c4cccc5c4sc4ccccc45)cc3)c3cccc(-c4cccc5c4c4ccccc4n5-c4ccccc4)c3)cc2)cc1 ; c1ccc(-c2ccc(N(c3cccc(-c4cccc5c4c4ccccc4n5-c4ccccc4)c3)c3ccc4c(c3)oc3ccccc34)cc2)cc1]

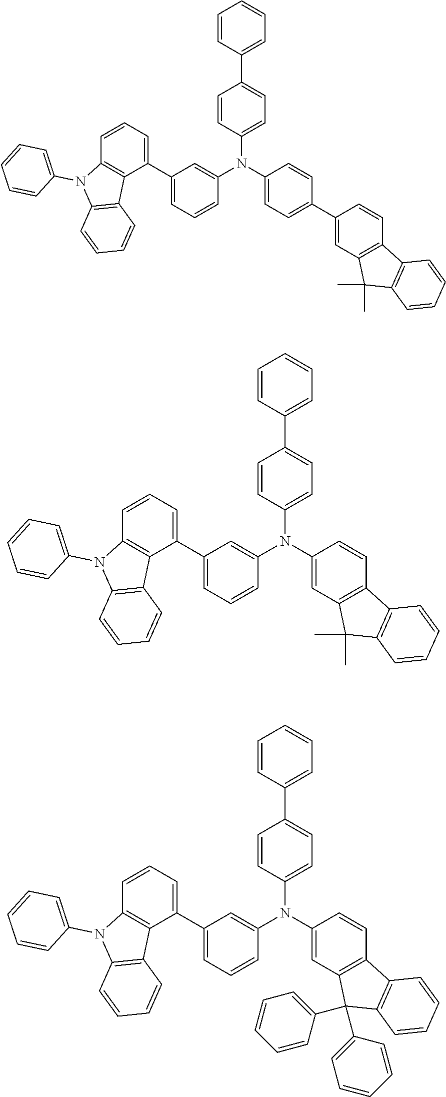 [SMILES: CC1(C)c2ccccc2-c2ccc(-c3ccc(N(c4ccc(-c5ccccc5)cc4)c4cccc(-c5cccc6c5c5ccccc5n6-c5ccccc5)c4)cc3)cc21 ; CC1(C)c2ccccc2-c2ccc(N(c3ccc(-c4ccccc4)cc3)c3cccc(-c4cccc5c4c4ccccc4n5-c4ccccc4)c3)cc21 ; c1ccc(-c2ccc(N(c3cccc(-c4cccc5c4c4ccccc4n5-c4ccccc4)c3)c3ccc4c(c3)C(c3ccccc3)(c3ccccc3)c3ccccc3-4)cc2)cc1]

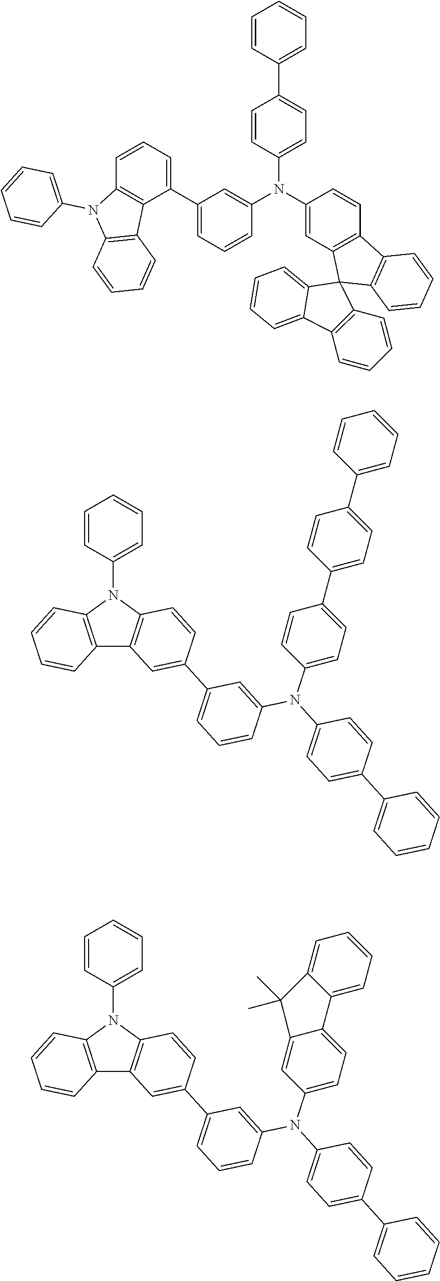

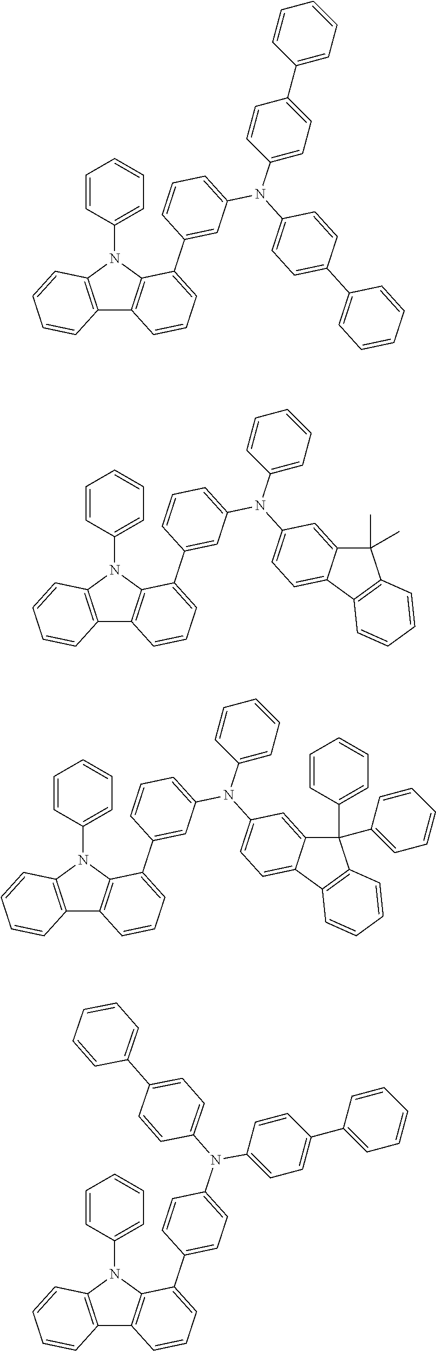 [SMILES: c1ccc(-c2ccc(N(c3ccc(-c4ccccc4)cc3)c3cccc(-c4cccc5c6ccccc6n(-c6ccccc6)c45)c3)cc2)cc1 ; CC1(C)c2ccccc2-c2ccc(N(c3ccccc3)c3cccc(-c4cccc5c6ccccc6n(-c6ccccc6)c45)c3)cc21 ; c1ccc(N(c2cccc(-c3cccc4c5ccccc5n(-c5ccccc5)c34)c2)c2ccc3c(c2)C(c2ccccc2)(c2ccccc2)c2ccccc2-3)cc1 ; c1ccc(-c2ccc(N(c3ccc(-c4ccccc4)cc3)c3ccc(-c4cccc5c6ccccc6n(-c6ccccc6)c45)cc3)cc2)cc1]

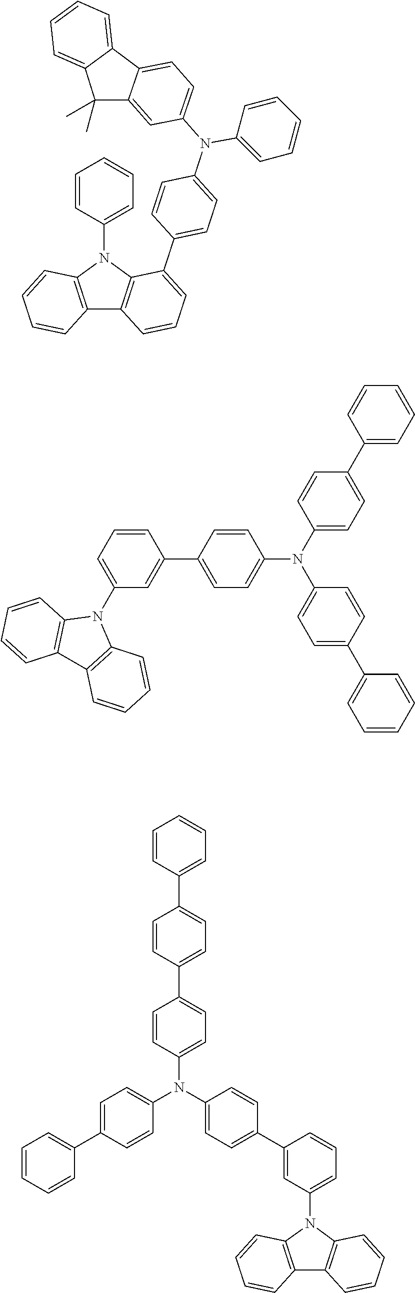 [SMILES: CC1(C)c2ccccc2-c2ccc(N(c3ccccc3)c3ccc(-c4cccc5c6ccccc6n(-c6ccccc6)c45)cc3)cc21 ; c1ccc(-c2ccc(N(c3ccc(-c4ccccc4)cc3)c3ccc(-c4cccc(-n5c6ccccc6c6ccccc65)c4)cc3)cc2)cc1 ; c1ccc(-c2ccc(-c3ccc(N(c4ccc(-c5ccccc5)cc4)c4ccc(-c5cccc(-n6c7ccccc7c7ccccc76)c5)cc4)cc3)cc2)cc1]

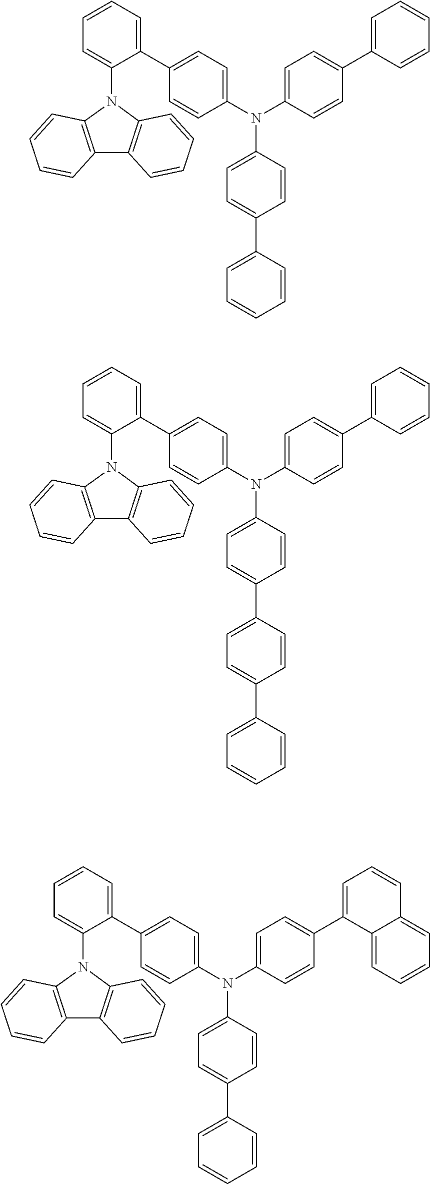 [SMILES: c1ccc(-c2ccc(N(c3ccc(-c4ccccc4)cc3)c3ccc(-c4ccccc4-n4c5ccccc5c5ccccc54)cc3)cc2)cc1 ; c1ccc(-c2ccc(-c3ccc(N(c4ccc(-c5ccccc5)cc4)c4ccc(-c5ccccc5-n5c6ccccc6c6ccccc65)cc4)cc3)cc2)cc1 ; c1ccc(-c2ccc(N(c3ccc(-c4ccccc4-n4c5ccccc5c5ccccc54)cc3)c3ccc(-c4cccc5ccccc45)cc3)cc2)cc1]

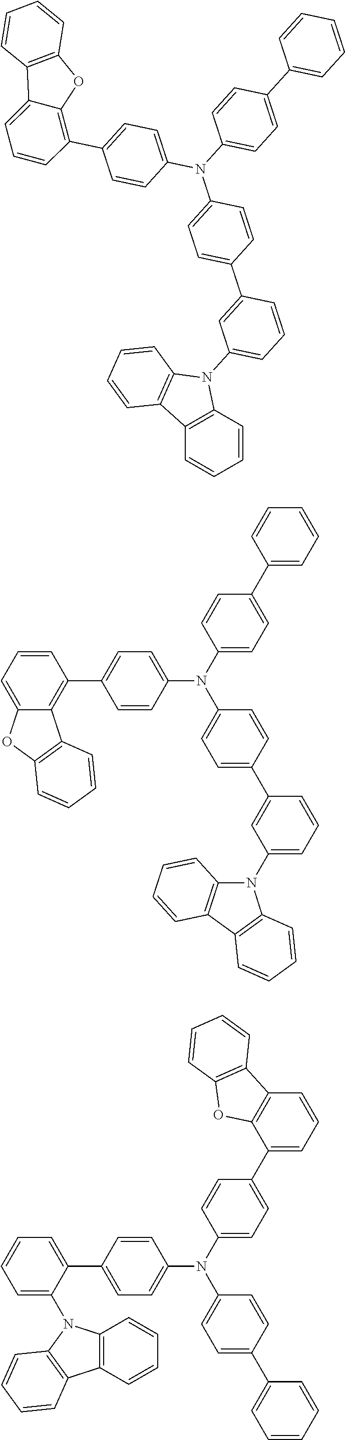 [SMILES: c1ccc(-c2ccc(N(c3ccc(-c4cccc(-n5c6ccccc6c6ccccc65)c4)cc3)c3ccc(-c4cccc5c4oc4ccccc45)cc3)cc2)cc1 ; c1ccc(-c2ccc(N(c3ccc(-c4cccc(-n5c6ccccc6c6ccccc65)c4)cc3)c3ccc(-c4cccc5oc6ccccc6c45)cc3)cc2)cc1 ; c1ccc(-c2ccc(N(c3ccc(-c4ccccc4-n4c5ccccc5c5ccccc54)cc3)c3ccc(-c4cccc5c4oc4ccccc45)cc3)cc2)cc1]

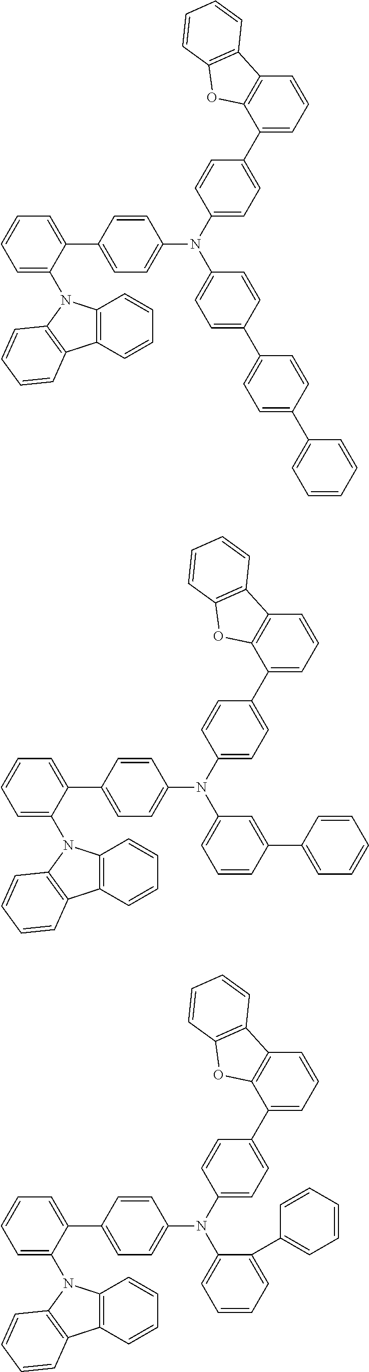 [SMILES: c1ccc(-c2ccc(-c3ccc(N(c4ccc(-c5ccccc5-n5c6ccccc6c6ccccc65)cc4)c4ccc(-c5cccc6c5oc5ccccc56)cc4)cc3)cc2)cc1 ; c1ccc(-c2cccc(N(c3ccc(-c4ccccc4-n4c5ccccc5c5ccccc54)cc3)c3ccc(-c4cccc5c4oc4ccccc45)cc3)c2)cc1 ; c1ccc(-c2ccccc2N(c2ccc(-c3ccccc3-n3c4ccccc4c4ccccc43)cc2)c2ccc(-c3cccc4c3oc3ccccc34)cc2)cc1]

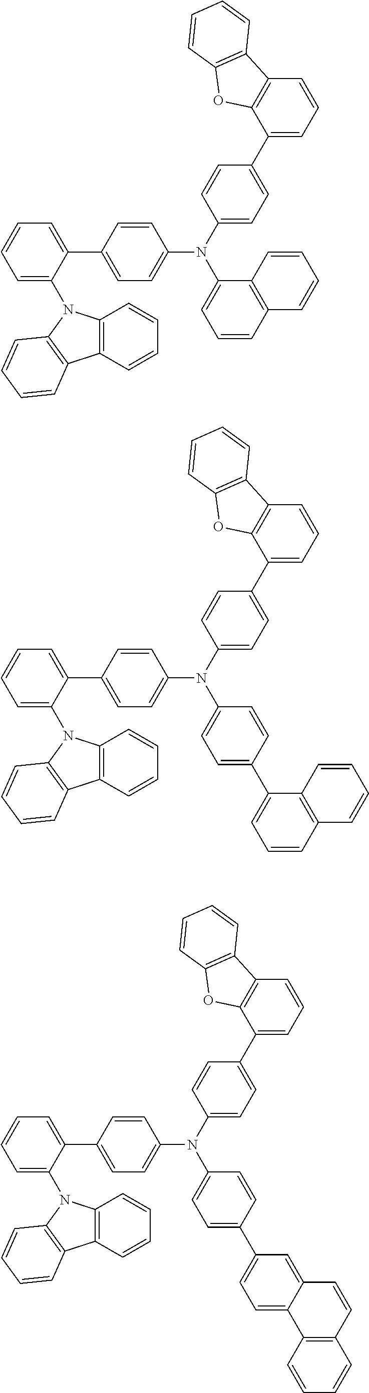 [SMILES: c1ccc(-n2c3ccccc3c3ccccc32)c(-c2ccc(N(c3ccc(-c4cccc5c4oc4ccccc45)cc3)c3cccc4ccccc34)cc2)c1 ; c1ccc(-n2c3ccccc3c3ccccc32)c(-c2ccc(N(c3ccc(-c4cccc5ccccc45)cc3)c3ccc(-c4cccc5c4oc4ccccc45)cc3)cc2)c1 ; c1ccc(-n2c3ccccc3c3ccccc32)c(-c2ccc(N(c3ccc(-c4ccc5c(ccc6ccccc65)c4)cc3)c3ccc(-c4cccc5c4oc4ccccc45)cc3)cc2)c1]

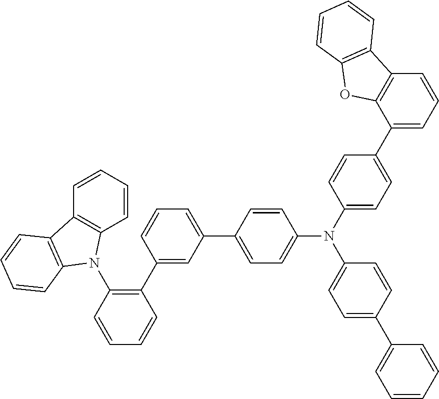 [SMILES: c1ccc(-c2ccc(N(c3ccc(-c4cccc(-c5ccccc5-n5c6ccccc6c6ccccc65)c4)cc3)c3ccc(-c4cccc5c4oc4ccccc45)cc3)cc2)cc1]

In one embodiment, specific examples of the second compound in the first composition and the second composition include the following compounds.

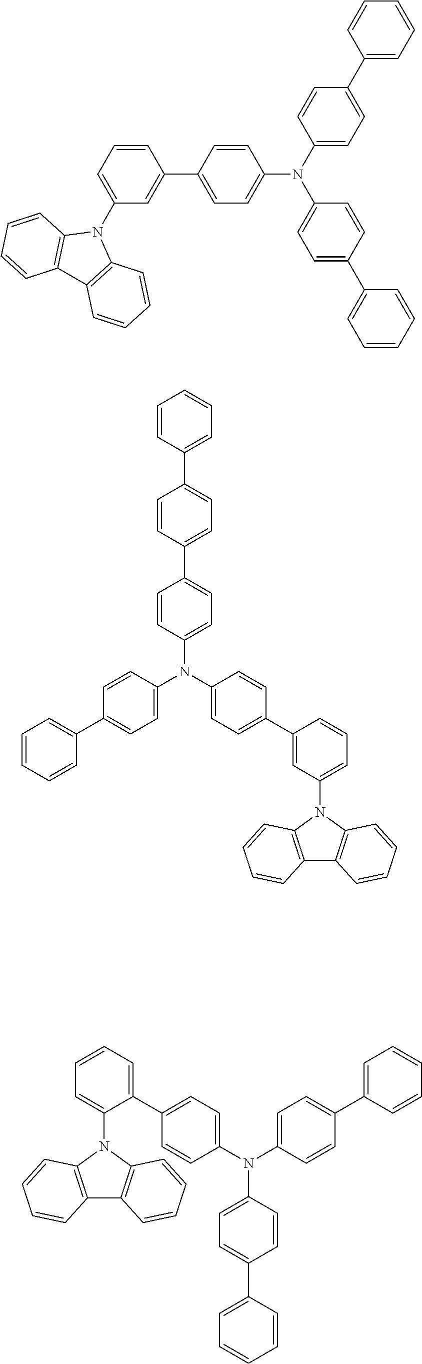 [SMILES: c1ccc(-c2ccc(N(c3ccc(-c4ccccc4)cc3)c3ccc(-c4cccc(-n5c6ccccc6c6ccccc65)c4)cc3)cc2)cc1 ; c1ccc(-c2ccc(-c3ccc(N(c4ccc(-c5ccccc5)cc4)c4ccc(-c5cccc(-n6c7ccccc7c7ccccc76)c5)cc4)cc3)cc2)cc1 ; c1ccc(-c2ccc(N(c3ccc(-c4ccccc4)cc3)c3ccc(-c4ccccc4-n4c5ccccc5c5ccccc54)cc3)cc2)cc1]

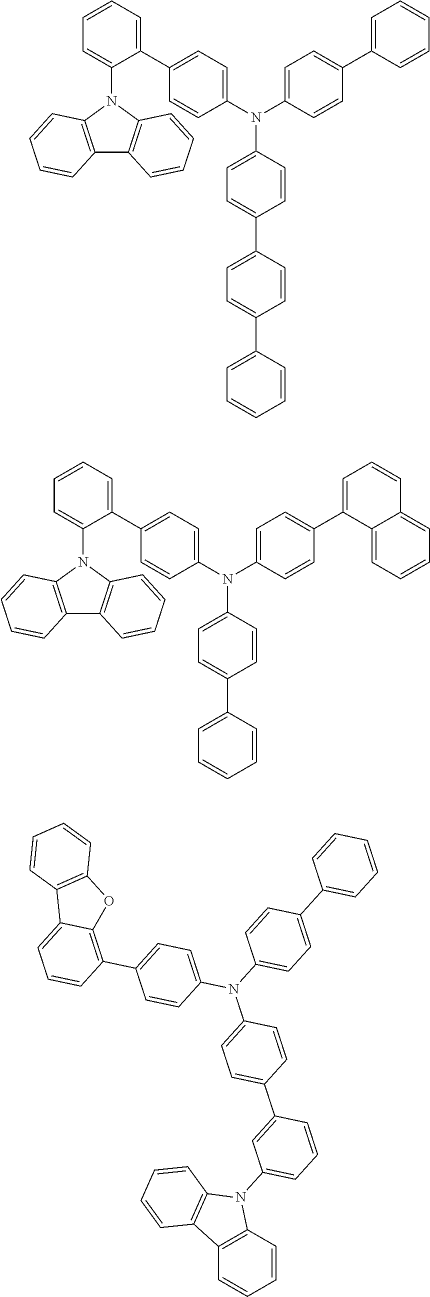 [SMILES: c1ccc(-c2ccc(-c3ccc(N(c4ccc(-c5ccccc5)cc4)c4ccc(-c5ccccc5-n5c6ccccc6c6ccccc65)cc4)cc3)cc2)cc1 ; c1ccc(-c2ccc(N(c3ccc(-c4ccccc4-n4c5ccccc5c5ccccc54)cc3)c3ccc(-c4cccc5ccccc45)cc3)cc2)cc1 ; c1ccc(-c2ccc(N(c3ccc(-c4cccc(-n5c6ccccc6c6ccccc65)c4)cc3)c3ccc(-c4cccc5c4oc4ccccc45)cc3)cc2)cc1]

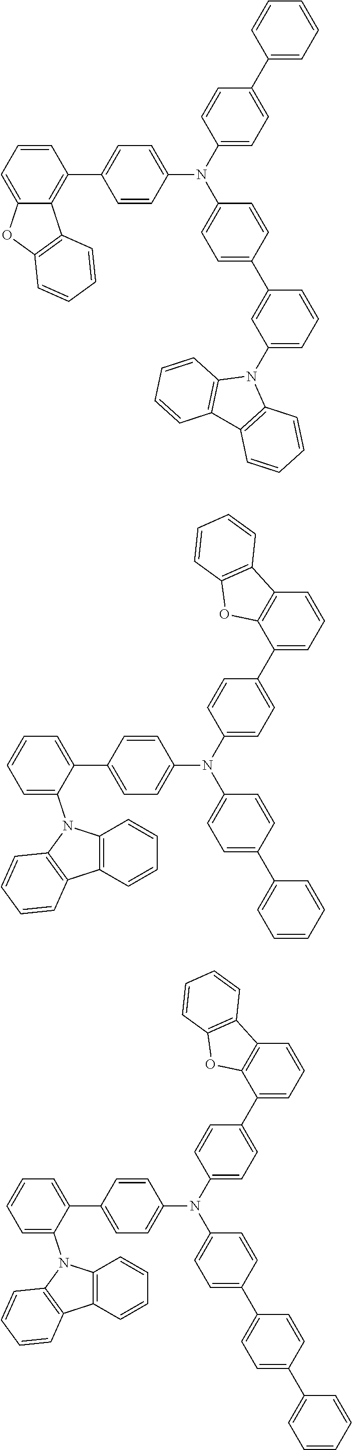 [SMILES: c1ccc(-c2ccc(N(c3ccc(-c4cccc(-n5c6ccccc6c6ccccc65)c4)cc3)c3ccc(-c4cccc5oc6ccccc6c45)cc3)cc2)cc1 ; c1ccc(-c2ccc(N(c3ccc(-c4ccccc4-n4c5ccccc5c5ccccc54)cc3)c3ccc(-c4cccc5c4oc4ccccc45)cc3)cc2)cc1 ; c1ccc(-c2ccc(-c3ccc(N(c4ccc(-c5ccccc5-n5c6ccccc6c6ccccc65)cc4)c4ccc(-c5cccc6c5oc5ccccc56)cc4)cc3)cc2)cc1]

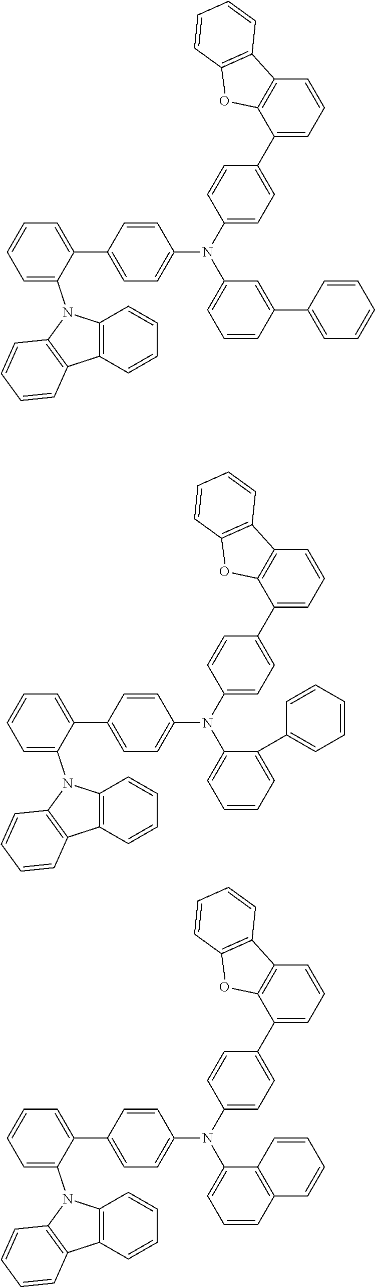 [SMILES: c1ccc(-c2cccc(N(c3ccc(-c4ccccc4-n4c5ccccc5c5ccccc54)cc3)c3ccc(-c4cccc5c4oc4ccccc45)cc3)c2)cc1 ; c1ccc(-c2ccccc2N(c2ccc(-c3ccccc3-n3c4ccccc4c4ccccc43)cc2)c2ccc(-c3cccc4c3oc3ccccc34)cc2)cc1 ; c1ccc(-n2c3ccccc3c3ccccc32)c(-c2ccc(N(c3ccc(-c4cccc5c4oc4ccccc45)cc3)c3cccc4ccccc34)cc2)c1]

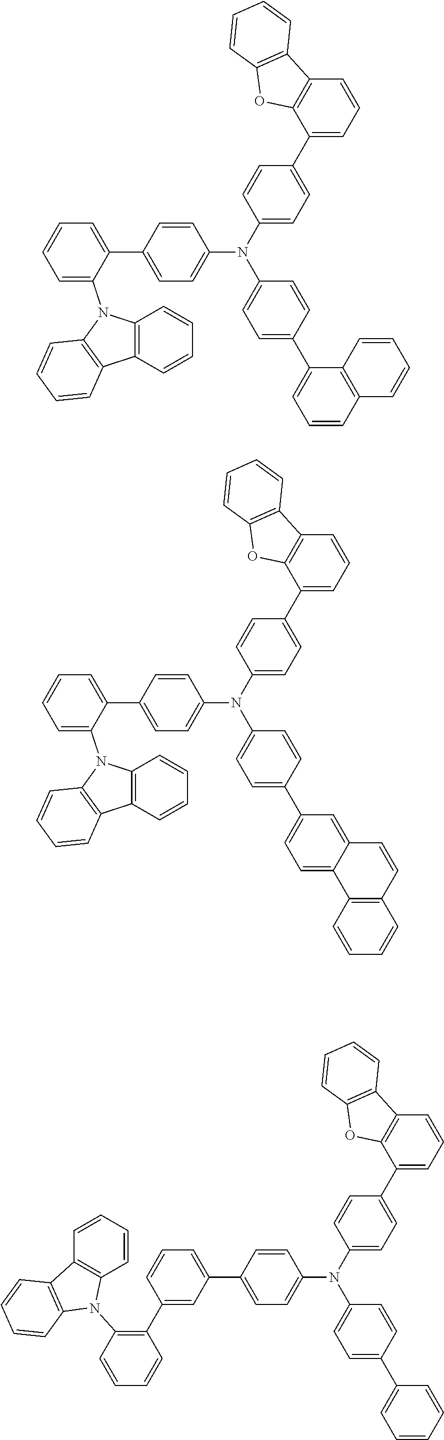 [SMILES: c1ccc(-n2c3ccccc3c3ccccc32)c(-c2ccc(N(c3ccc(-c4cccc5ccccc45)cc3)c3ccc(-c4cccc5c4oc4ccccc45)cc3)cc2)c1 ; c1ccc(-n2c3ccccc3c3ccccc32)c(-c2ccc(N(c3ccc(-c4ccc5c(ccc6ccccc65)c4)cc3)c3ccc(-c4cccc5c4oc4ccccc45)cc3)cc2)c1 ; c1ccc(-c2ccc(N(c3ccc(-c4cccc(-c5ccccc5-n5c6ccccc6c6ccccc65)c4)cc3)c3ccc(-c4cccc5c4oc4ccccc45)cc3)cc2)cc1]

### [First Organic Electroluminescence Device]

A first organic EL device according to an aspect of the present invention includes a cathode, an anode and one or two or more organic layers arranged between the cathode and the anode, wherein at least one layer of the one or two or more organic layers includes a first compound and a second compound, the first compound is a compound represented by the formula (12), and the second compound is a compound represented by the formula (21).

The first compound and the second compound in the first organic EL device is the same as described above in those of the first composition.

When the first organic EL device according to an aspect of the present invention includes the above configurations, the device performance thereof can be improved. Specifically, an organic EL device having high efficiency and long lifetime can be achieved.

The amount ratio of the first compound and the second compound in a layer including the first compound and the second compound (hereinafter, also referred to as a “layer A”) is not particularly limited, but in one embodiment, the amount of the first compound is 30 to 70% by mass based on the total amount of the first compound and the second compound, and it may be 40 to 60% by mass.

The layer A may or may not include other compound other than the first compound and the second compound.

In one embodiment, the layer A substantially consists of the first compound and the second compound.

The expression “substantially consists of the first compound and the second compound” refers that the layer A includes no other component or includes extreamly small amount of other component as long as the effects of the present invention are not impaired. For example, the expression includes the case where unavoidable impurities are immixed therein as other component.

In one embodiment, 80% by mass or more, 90% by mass or more, 95% by mass or more, 99% by mass or more, 99.5% by mass or more, 99.9% by mass or more, 99.99% by mass or more, or 100% by mass of the layer A is the first compound and the second compound.

In one embodiment, 80 mol % or more, 90 mol % or more, 95 mol % or more, 99 mol % or more, 99.5 mol % or more, 99.9 mol % or more, 99.99 mol % or more, or 100 mol % of the layer A is the first compound and the second compound.

In one embodiment, the layer A consists of the first compound and the second compound.

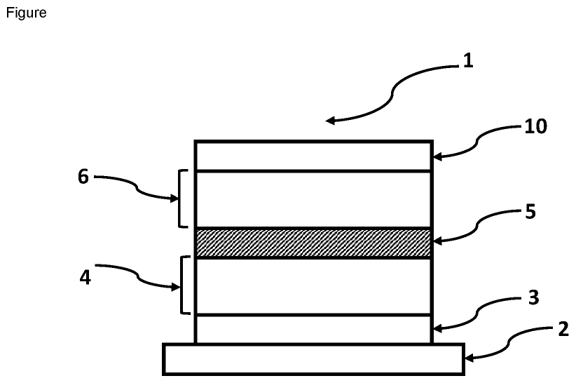

A schematic configuration of the organic EL device according to an aspect of the present invention will be described with reference to FIG. 1.

The organic EL device 1 according to an aspect of the present invention includes a substrate 2, an anode 3, an emitting layer 5 being an organic layer, a cathode 10, an organic layer 4 between the anode 3 and the emitting layer 5, and an organic layer 6 between the emitting layer 5 and the cathode 10.

Each of the organic layer 4 and the organic layer 6 may be a single layer or may composed of a plurality of layers.

In one embodiment, the first organic EL device according to an aspect of the present invention includes the anode, a hole-transporting region, an emitting layer, and the cathode in this order, wherein the hole-transporting region includes the first compound and the second compound.

### (Hole-Transporting Region)

The hole-transporting region indicates a general term for one or two or more layers arranged between the anode and the emitting layer. The hole-transporting region is configured, for example, from each layer which is referred to as the electron-blocking layer, the hole-transporting layer and the hole-injecting layer described later from the emitting layer side, and it may be a stacked structure including all of them, or may be a layer configuration merely including a part of them. Further, each of the above layers may be formed by using two or more kinds of layers, and for example, two kinds of hole-transporting layers having different compositions may be stacked.

Each layer may be formed by using one kind of material alone, or may be formed by using two or more kinds of materials in combination.

Stacked structures of the hole-transporting region in the first organic EL device according to an aspect of the present invention are shown below.

(a) (an anode/) a second layer (a hole-injecting layer)/a first layer (a hole-transporting layer) (/an emitting layer)
(b) (an anode/) a third layer (a hole-injecting layer)/a second layer (a hole-transporting layer)/a first layer (an electron-blocking layer layer) (/an emitting layer)
(c) (an anode/) a fourth layer (a hole-injecting layer)/a third layer (a first hole-transporting layer)/a second layer (a second hole-transporting layer)/a first layer (an electron-blocking layer layer) (/an emitting layer)
(d) (an anode/) a fifth layer (a first hole-injecting layer)/a fourth layer (a first hole-transporting layer)/a third layer (a second hole-transporting layer)/a second layer (a second hole-injecting layer)/a first layer (an electron-blocking layer layer) (/an emitting layer)

In one embodiment, the hole-transporting region includes at least a first layer and a second layer in this order from the emitting layer side, and one or more layers selected from the group consisting of the first layer and the second layer include the first compound and the second compound.

In one embodiment, the hole-transporting region includes a hole-transporting layer and a hole-injecting layer from the emitting layer side.

In one embodiment, the hole-transporting region includes at least a first layer, a second layer and a third layer in this order from the emitting layer side, and one or more layers selected from the group consisting of the first layer, the second layer, and the third layer include the first compound and the second compound.

In one embodiment, the first layer includes the first compound and the second compound.

### (Other Configuration of Organic EL Device)

Conventionally-known materials and device configurations can be applied to the first organic EL device according to an aspect of the present invention as long as the one or two or more organic layers arranged between the cathode and the anode satisfy the above conditions, and further as long as the effects of the present invention are not impaired.

Device configurations, materials for forming each layer, and the like in the first organic EL device according to an aspect of the present invention will be described below.

As a representative device configuration of the organic EL device, structures in which the following structures are stacked on a substrate can be given:

(1) an anode/a hole-transporting region/an emitting layer/a cathode,
(2) an anode/a hole-transporting region/an emitting layer/an electron-transporting region/a cathode,

wherein “/” indicates that the layers are stacked adjacent to each other.

### (Electron-Transporting Region)

The electron-transporting region indicates a general term for one or two or more layers arranged between the cathode and the emitting layer. The electron-transporting region is configured, for example, from each layer which is referred to as a hole-blocking layer, an exciton-blocking layer, an electron-transporting layer and an electron-injecting layer described later from the emitting layer side, and it may be a stacked structure including all of them, or may be a layer configuration merely including a part of them. Further, each of the above layers may be formed by using two or more kinds of layers, and for example, two kinds of electron-transporting layers having different compositions may be stacked.

Each layer may be formed by using one kind of material alone, or may be formed by using two or more kinds of materials in combination.

In one embodiment, the electron-transporting region includes at least one organic layer,

the at least one organic layer includes a nitrogen-containing compound, and

the nitrogen-containing compound includes one or more rings selected from the group consisting of a nitrogen-containing five-membered ring and a nitrogen-containing six-membered ring.

In one embodiment, the nitrogen-containing compound is one or more compounds selected from the group consisting of an imidazole derivative, a benzimidazole derivative, an azine derivative, a carbazole derivative, and a phenanthroline derivative.

### (Emitting Layer)

In one embodiment, the emitting layer includes a host material, and an emitting compound in which the maximum peak wavelength represents 500 nm or less of emission.

As the emitting compound in which the maximum peak wavelength represents 500 nm or less of emission, a blue fluorescent emitting material described later can be mentioned.

The maximum peak wavelength can be measured using a fluorescence spectrum measuring apparatus.

For example, 5 μmol/L of a toluene solution of compound being a measurement target is prepared as a sample, it is put in a quartz cell, and then an emission spectrum of the sample is measured at room temperature (300 K) (as a vertical axis: emission strength and a horizonal axis: wavelength). The emission spectrum can be measured using a fluorescence spectrophotometer (apparatus name: F-7000) manufactured by Hitachi High-Tech Science Corporation. The maximum peak wavelength in the emission spectrum means a peak wavelength of the emission spectrum with maximum emission strength.

In one embodiment, the first organic EL device according to an aspect of the present invention includes two or more emitting layers.

Compounds which can be used for the emitting layer are described later.

Each layer of the first organic EL device according to an aspect of the present invention will be described below.

### (Substrate)

The substrate is used as a support of an emitting device. As the substrate, glass, quartz, plastic or the like can be used, for example. Further, a flexible substrate may be used. The term “flexible substrate” means a bendable (flexible) substrate, and specific examples thereof include a plastic substrate formed of polycarbonate, polyvinyl chloride or the like.

### (Anode)

For the anode formed on the substrate, metals, alloys, electrically conductive compounds, mixtures thereof, and the like, which have large work function (specifically 4.0 eV or more) are preferably used. Specific examples thereof include indium oxide-tin oxide (ITO: Indium Tin Oxide), indium oxide-tin oxide containing silicon or silicon oxide, indium oxide-zinc oxide, tungsten oxide, indium oxide containing zinc oxide, graphene, and the like. In addition thereto, specific examples thereof include gold (Au), platinum (Pt), a nitride of a metallic material (for example, titanium nitride), or the like.

### (Hole-Injecting Layer)

The hole-injecting layer is a layer containing a substance having high hole-injecting property. As the substance having high hole-injecting property, molybdenum oxide, titanium oxide, vanadium oxide, rhenium oxide, ruthenium oxide, chromium oxide, zirconium oxide, hafnium oxide, tantalum oxide, silver oxide, tungsten oxide, manganese oxide, an aromatic amine compound, a polymer compound (oligomers, dendrimers, polymers, and the like), or the like can be given.

### (Hole-Transporting Layer)

The hole-transporting layer is a layer containing a substance having high hole-transporting property. For the hole-transporting layer, an aromatic amine compound, a carbazole derivative, an anthracene derivative, or the like can be used. A polymer compound such as poly(N-vinylcarbazole) (abbreviation: PVK) and poly(4-vinyltriphenylamine) (abbreviation: PVTPA) can also be used. Provided that a substance other than the above-described substances may be used as long as the substance has higher hole-transporting property than electron-transporting property. The layer containing the substance having high hole-transporting property may be not only a single layer, but also layers in which two or more layers formed of the above-described substances are stacked.

### (Guest (Dopant) Material of Emitting Layer)

The emitting layer is a layer containing a substance having high luminous property, and various materials can be used. For example, as the substance having high emitting property, a fluorescent compound which emits fluorescence or a phosphorescent compound which emits phosphorescence can be used. The fluorescent compound is a compound which can emit from a singlet excited state, and the phosphorescent compound is a compound which can emit from a triplet excited state.

As a blue fluorescent emitting material which can be used for the emitting layer, pyrene derivatives, styrylamine derivatives, chrysene derivatives, fluoranthene derivatives, fluorene derivatives, diamine derivatives, triarylamine derivatives, and the like can be used. As a green fluorescent emitting material which can be used for the emitting layer, aromatic amine derivatives and the like can be used. As a red fluorescent emitting material which can be used for the emitting layer, tetracene derivatives, diamine derivatives and the like can be used.

As a blue phosphorescent emitting material which can be used for the emitting layer, metal complexes such as iridium complexes, osmium complexes and platinum complexes are used. As a green phosphorescent emitting material which can be used for the emitting layer, iridium complexes and the like are used. As a red phosphorescent emitting material which can be used for the emitting layer, metal complexes such as iridium complexes, platinum complexes, terbium complexes and europium complexes are used.

### (Host Material for Emitting Layer)

The emitting layer may have a constitution in which the substance having high emitting property (guest material) is dispersed in another substance (host material). As a substance for dispersing the substance having high emitting property, a variety of substances can be used, and it is preferable to use a substance having a higher lowest unoccupied molecular orbital level (LUMO level) and a lower highest occupied molecular orbital level (HOMO level) than a substance having high emitting property.

As a substance (host material) for dispersing the substance having high emitting property, 1) a metal complex such as an aluminum complex, a beryllium complex, and a zinc complex, 2) a heterocyclic compound such as an oxadiazole derivative, a benzimidazole derivative, and a phenanthroline derivative, 3) a fused aromatic compound such as a carbazole derivative, an anthracene derivative, a phenanthrene derivative, a pyrene derivative, and a chrysene derivative, and 4) an aromatic amine compound such as a triarylamine derivative and a fused polycyclic aromatic amine derivative are used.

A compound having delayed fluorescence (thermally activated delayed fluorescence) can also be used as the host material. It is also preferable that the emitting layer includes the material used in the present invention described above and the host compound having delayed fluorescence.

### (Electron-Blocking Layer, Hole-Blocking Layer, Exciton-Blocking Layer)

An electron-blocking layer, a hole-blocking layer, an exciton (triplet)-blocking layer, and the like may be provided adjacent to the emitting layer.

The electron-blocking layer is a layer which has a function of preventing leakage of electrons from the emitting layer to the hole-transporting layer. The hole-blocking layer is a layer which has a function of preventing leakage of holes from the emitting layer to the electron-transporting layer. The exciton-blocking layer is a layer which has a function of preventing diffusion of excitons generated in the emitting layer into the adjacent layers to confine the excitons within the emitting layer.

### (Electron-Transporting Layer)

The electron-transporting layer is a layer containing a substance having high electron-transporting property. For the electron-transporting layer, 1) a metal complex such as an aluminum complex, a beryllium complex, and a zinc complex; 2) a heteroaromatic complex such as an imidazole derivative, a benzimidazole derivative, an azine derivative, carbazole derivative, and a phenanthroline derivative; and 3) a polymer compound can be used.

### (Electron-Injecting Layer)

The electron-injecting layer is a layer containing a substance having high electron-injecting property. For the electron-injecting layer, lithium (Li), ytterbium (Yb), lithium fluoride (LiF), cesium fluoride (CsF), calcium fluoride (CaF₂), a metal complex compound such as 8-hydroxyquinolinolato-lithium (Liq), an alkali metal such as lithium oxide (LiOₓ), an alkaline earth metal, or a compound thereof can be used.

### (Cathode)

For the cathode, metals, alloys, electrically conductive compounds, mixtures thereof, and the like, which have small work function (specifically 3.8 eV or less) are preferably used. Specific examples of such a cathode material include an element belonging to Group 1 or Group 2 of the Periodic Table of the Elements, i.e., an alkali metal such as lithium (Li) and cesium (Cs), an alkaline earth metal such as magnesium (Mg), calcium (Ca) and strontium (Sr), and an alloy containing these (e.g., MgAg and AlLi); a rare earth metal such as europium (Eu) and ytterbium (Yb), and an alloy containing these.

In the first organic EL device according to an aspect of the present invention, the thickness of each layer is not particularly limited, but is normally preferable several nm to 1 μm generally in order to suppress defects such as pinholes, to suppress applied voltages to be low, and to improve luminous efficiency.

In one embodiment, the hole-transporting region has the thickness of 110 to 150 nm, and may have the thickness of 120 to 140 nm.

### [Second Organic Electroluminescence Device]

A second organic EL device according to an aspect of the present invention includes a cathode, an anode and one or two or more organic layers arranged between the cathode and the anode, wherein at least one layer of the one or two or more organic layers includes a first compound and a second compound, the first compound is a compound represented by the formula (12), and the second compound is a compound represented by the formula (21).

The first compound and the second compound in the second organic EL device is the same as described above in those of the second composition.

When the second organic EL device according to an aspect of the present invention includes the above configurations, the device performance thereof can be improved. Specifically, an organic EL device having high efficiency and long lifetime can be achieved.

The second organic EL device is the same as the above first organic EL device, except that the first compound in the second composition is used as the first compound and the second compound in the second composition is used as the second compound. Others described above in the first organic EL device can be used for those of the above second organic EL device. That is, the composition in the layer A, device configurations, materials for forming each layer, and the like, described in the first organic EL device can be used for those of the second organic EL device.

### [Third Organic Electroluminescence Device]

A third organic EL device according to an aspect of the present invention includes the composition according to an aspect of the present invention.

When the third organic EL device according to an aspect of the present invention includes the above configurations, the device performance thereof can be improved. Specifically, an organic EL device having high efficiency and long lifetime can be achieved.

The third organic EL device is the same as the above first organic EL device, except that at least one layer of the one or two or more organic layers is not limited to including a first compound and a second compound. Others described above in the first organic EL device can be used for those of the above third organic EL device. That is, device configurations, materials for forming each layer, and the like, described in the first organic EL device can be used for those of the third organic EL device.

### [Method for Fabricating Organic EL Device]

In the first organic EL device, the second organic EL device, and the third organic EL device, according to an aspect of the present invention, the method for forming each layer is not particularly limited. A conventionally-known method for forming each layer such as a vacuum deposition process and a spin coating process can be used. Each layer such as the emitting layer can be formed by a known method such as a vacuum deposition process, a molecular beam deposition process (MBE process), or an application process such as a dipping process, a spin coating process, a casting process, a bar coating process and a roll coating process, using a solution prepared by dissolving the material in a solvent.

A method for fabricating the first organic EL device, the second organic EL device, and the third organic EL device, according to an aspect of the present invention including: forming a film on a substrate by depositing the first compound and the second compound in the same deposition source or different deposition sources.

A method of simultaneously depositing (co-depositing) the first compound and the second compound each in different deposition sources to form the hole-transporting region may be used, or a method of mixing them in advance, and then depositing them in the same deposition source to form the hole-transporting region may be used.

### [Electronic Apparatus]

An electronic apparatus according to an aspect of the present invention is characterized by including the first organic EL device, the second organic EL device, or the third organic EL device, according to an aspect of the present invention.

Specific examples of the electronic apparatus include display components such as an organic EL panel module; display devices for a television, a cellular phone and a personal computer; and emitting devices such as a light and a vehicular lamp; and the like.

### EXAMPLES

### <Compound>

First compounds used in Examples and Comparative Examples are shown below.

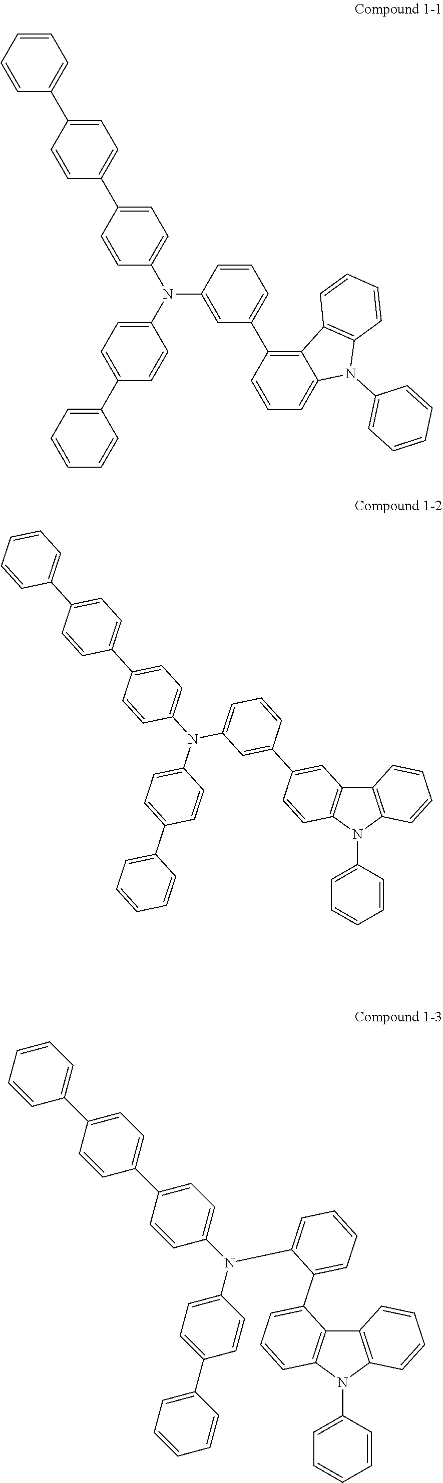 [SMILES: c1ccc(-c2ccc(-c3ccc(N(c4ccc(-c5ccccc5)cc4)c4cccc(-c5cccc6c5c5ccccc5n6-c5ccccc5)c4)cc3)cc2)cc1 ; c1ccc(-c2ccc(-c3ccc(N(c4ccc(-c5ccccc5)cc4)c4cccc(-c5ccc6c(c5)c5ccccc5n6-c5ccccc5)c4)cc3)cc2)cc1 ; c1ccc(-c2ccc(-c3ccc(N(c4ccc(-c5ccccc5)cc4)c4ccccc4-c4cccc5c4c4ccccc4n5-c4ccccc4)cc3)cc2)cc1]

Second compounds used in Examples and Comparative Examples are shown below.

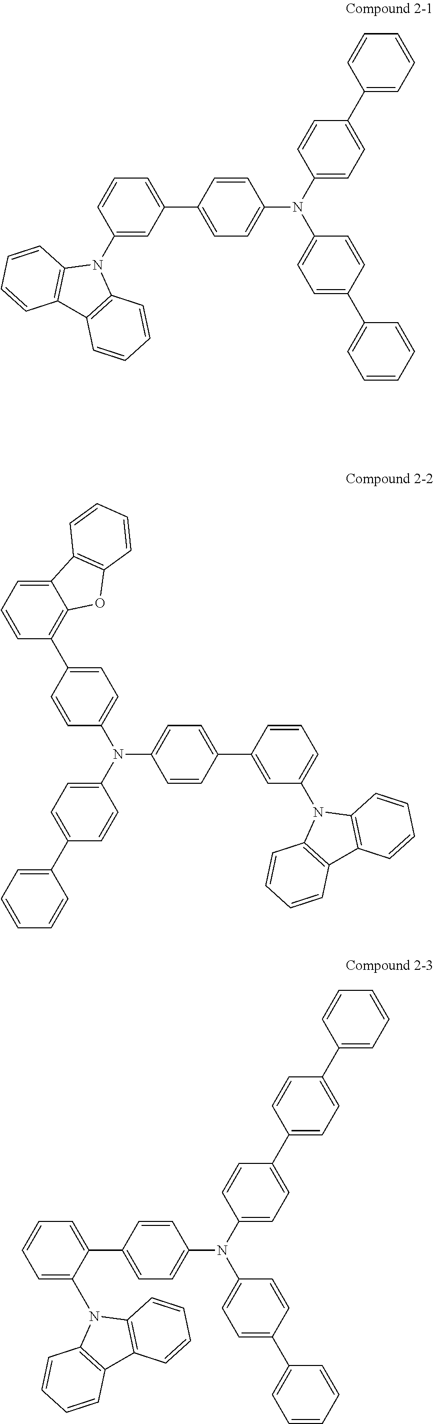 [SMILES: c1ccc(-c2ccc(N(c3ccc(-c4ccccc4)cc3)c3ccc(-c4cccc(-n5c6ccccc6c6ccccc65)c4)cc3)cc2)cc1 ; c1ccc(-c2ccc(N(c3ccc(-c4cccc(-n5c6ccccc6c6ccccc65)c4)cc3)c3ccc(-c4cccc5c4oc4ccccc45)cc3)cc2)cc1 ; c1ccc(-c2ccc(-c3ccc(N(c4ccc(-c5ccccc5)cc4)c4ccc(-c5ccccc5-n5c6ccccc6c6ccccc65)cc4)cc3)cc2)cc1]

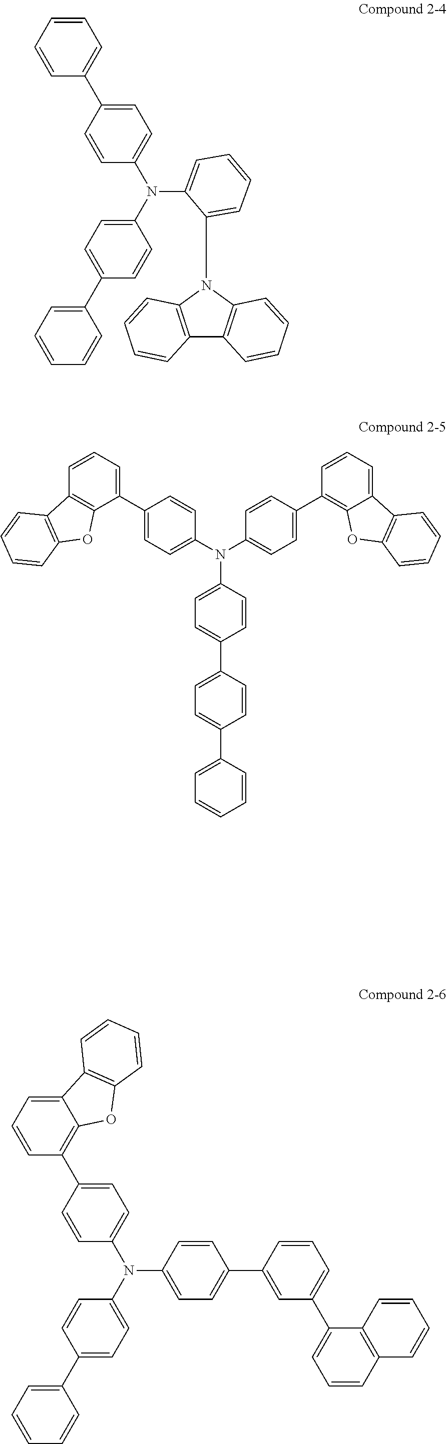 [SMILES: c1ccc(-c2ccc(N(c3ccc(-c4ccccc4)cc3)c3ccccc3-n3c4ccccc4c4ccccc43)cc2)cc1 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; c1ccc(-c2ccc(N(c3ccc(-c4cccc(-c5cccc6ccccc56)c4)cc3)c3ccc(-c4cccc5c4oc4ccccc45)cc3)cc2)cc1]

Compound structures used in a third hole-transporting layer of Comparative Examples 3 and 4 are shown below.

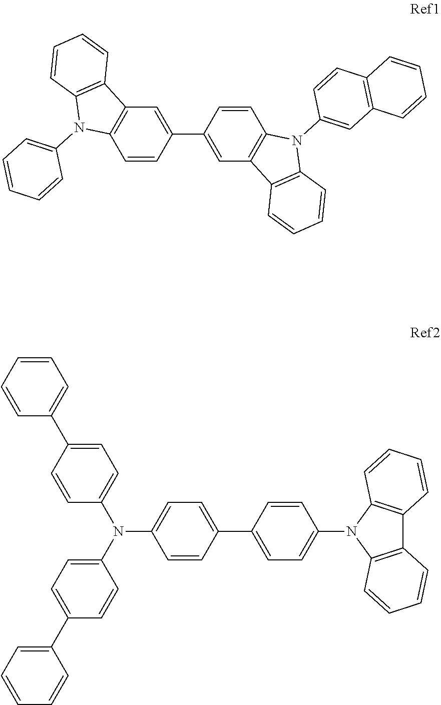 [SMILES: c1ccc(-n2c3ccccc3c3cc(-c4ccc5c(c4)c4ccccc4n5-c4ccc5ccccc5c4)ccc32)cc1 ; c1ccc(-c2ccc(N(c3ccc(-c4ccccc4)cc3)c3ccc(-c4ccc(-n5c6ccccc6c6ccccc65)cc4)cc3)cc2)cc1]

Other compound structures used in the fabrication of the organic EL devices of Examples and Comparative Examples are shown below.

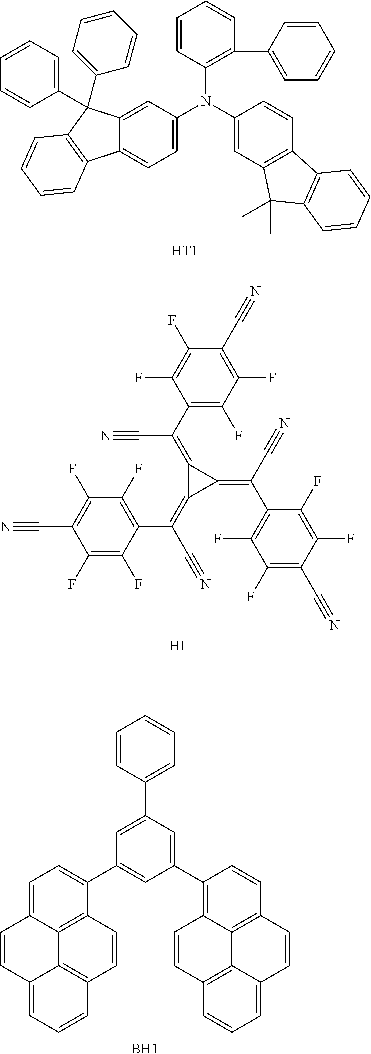

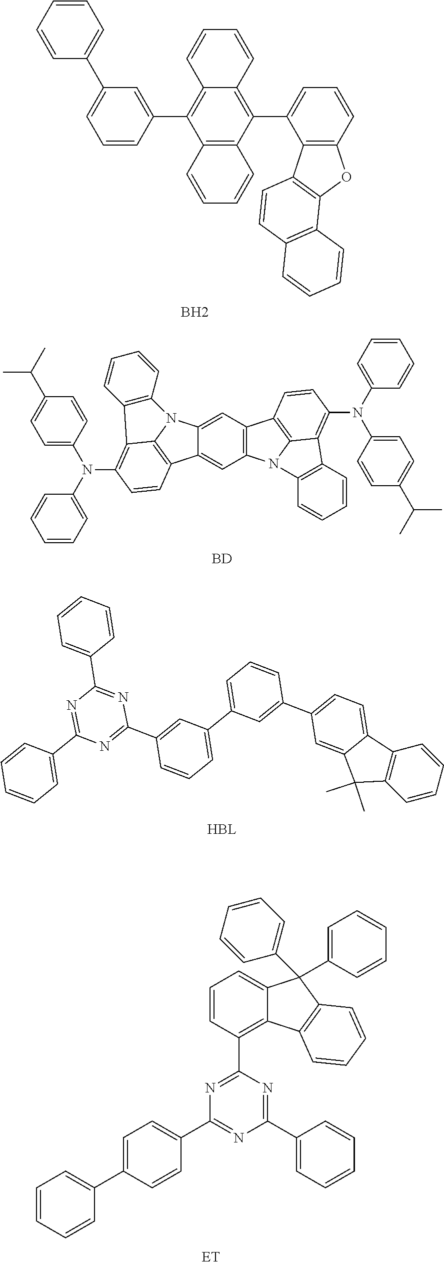

### <Evaluation of Properties Possessed by Compound>

Regarding Compound 1-1, Compound 2-1, Ref1, and Ref2, evaluations were conducted as follows. The results are shown in Table 1.

### Ionization Potential (Ip)

The ionization potential was measured using a photoemission spectroscopy (“AC-3” manufactured by RIKEN KEIKI CO., LTD.) in the air. Specifically, a compound being a measurement target was irradiated with light, and the quantity of electrons generated by charge separation in the irradiation was measured to obtain it.

### Hole Mobility (μh)

The hole mobility was measured using a device for evaluation of hole mobility, which was fabricated as follows.

A 25 mm×75 mm×1.1 mm-thick glass substrate with an ITO transparent electrode (anode) (manufactured by GEOMATEC Co., Ltd.) was subjected to ultrasonic cleaning in isopropyl alcohol for 5 minutes, and then subjected to UV-ozone cleaning for 30 minutes. The ITO has the film thickness of 130 nm.

The glass substrate after being cleaned was mounted onto a substrate holder in a vacuum vapor deposition apparatus. First, a compound HA-2 was deposited on the surface on the side where the transparent electrode line was formed so as to cover the transparent electrode to form a hole-injecting layer having the thickness of 5 nm.

A compound HT-A was deposited on the formed film of the hole-injecting layer to form a hole-transporting layer having the thickness of 10 nm.

Subsequently, a compound “Target” being a measurement target for the hole mobility was deposited to form a measurement target layer having the thickness of 200 nm.

And then, a metal aluminum (Al) was deposited on the measurement target layer to form a metal cathode having the thickness of 80 nm.

The device configuration for evaluation of hole mobility described above is schematically shown as follows.

ITO(130)/HA-2(5)/HT-A(10)/Target(200)/Al(80)

The numerical values in parentheses indicate the film thickness (nm).

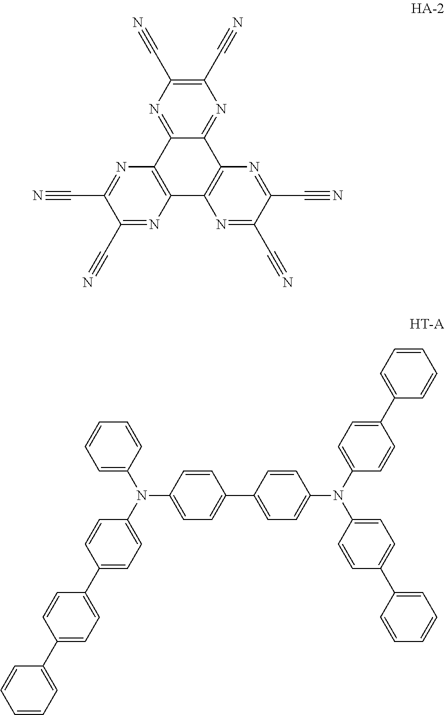 [SMILES: N#Cc1nc2c3nc(C#N)c(C#N)nc3c3nc(C#N)c(C#N)nc3c2nc1C#N ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

Subsequently, the hole mobility was measured as follows using the device for evaluation of mobility, which was fabricated as described above.

The device for evaluation of mobility was arranged in a measuring apparatus of impedance to be subjected to impedance measurement. The impedance measurement was conducted such that measuring frequency was swept from 1 Hz to 1 MHz. While sweeping, a direct voltage V was applied to the device with 0.1 V of alternate current amplitude. Modulus M was calculated using the relationship of the following calculus equation (C1) from the measured impedance Z.

M=jωZ Calculus equation (C1):

In the calculus equation (C1), j is an imaginary unit that the square thereof becomes −1, and w is an angular frequency [rad/s]. In a Bode plot in which an imaginary part of the Modulus M was used as a vertical axis and a frequency [Hz] was used as a horizonal axis, an electrical time constant T of the device for evaluation of mobility was obtained using the following calculus equation (C2) from a frequency indicating the peak fmax.

τ=1/(2πfmax) Calculus equation (C2):

π in the calculus equation (C2) is a symbol representing Pi.

A hole mobility (μh) was calculated using the relationship of the following calculus equation (C3) from the above T.

μh=d²/(Vτ) Calculus equation (C3):

d in the calculus equation (C3) is the total film thickness of organic thin films forming the device, and as described above in the device configuration for evaluation of mobility, d=215 [nm] was indicated.

The hole mobility in the present specification is a value in the case of a square root of electric field intensity E^{1/2}=500 [V^{1/2}/cm^{1/2}]. The square root of electric field intensity E^{1/2} can be calculated using the relationship of the following calculus equation (C4).

E^{1/2}=V^{1/2}d^{1/2} Calculus equation (C4):

In the impedance measurement of the present Examples, a model number 1260 manufactured by Solartron was used as the measuring apparatus of impedance, and a dielectric measurement interface of the model number 1296 manufactured by Solartron was used in combination for becoming high precision.

TABLE 1

| | IP (eV) | μh (cm²/Vs) |
|---|---|---|
| Compound 1-1 | 5.6 | 1.5 × 10⁻⁴ |
| Compound 1-2 | 5.6 | 2.3 × 10⁻⁴ |
| Compound 1-3 | 5.6 | 5.4 × 10⁻⁴ |
| Compound 2-1 | 5.7 | 4.9 × 10⁻⁷ |
| Compound 2-2 | 5.7 | 1.6 × 10⁻⁶ |
| Compound 2-3 | 5.7 | 7.8 × 10⁻⁷ |
| Compound 2-4 | 5.8 | 5.8 × 10⁻³ |
| Compound 2-5 | 5.7 | 2.0 × 10⁻⁴ |
| Compound 2-6 | 5.7 | 1.5 × 10⁻⁴ |
| Ref1 | 5.6 | 3.1 × 10⁻⁵ |
| Ref2 | 5.7 | 2.1 × 10⁻⁴ |

### Example 1

### <Fabrication of Organic EL Device>

Organic EL devices were fabricated as follows.

A 25 mm×75 mm×1.1 mm-thick glass substrate with an ITO transparent electrode (anode) (manufactured by GEOMATEC Co., Ltd.) was subjected to ultrasonic cleaning in isopropyl alcohol for 5 minutes, and then subjected to UV-ozone cleaning for 30 minutes. The ITO has the film thickness of 130 nm.

The glass substrate with the transparent electrode after being cleaned was mounted onto a substrate holder in a vacuum vapor deposition apparatus. First, compounds HT1 and HI were co-deposited on the surface on the side where the transparent electrode was formed so as to cover the transparent electrode to be 3% by mass in a proportion of the compound HI to form a first hole-transporting layer having the thickness of 10 nm.

The compound HT1 was deposited on the first hole-transporting layer to form a second hole-transporting layer having the thickness of 80 nm.

Compounds 1-1 and 2-1 were co-deposited on the second hole-transporting layer to be 50% by mass in a proportion of the compound 2-1 to form a third hole-transporting layer having the thickness of 5 nm.

A compound BH1 (host material) and a compound BD (dopant material) were co-deposited on the third hole-transporting layer to be 1% by mass in a proportion of the compound BD to form a first emitting layer having the thickness of 10 nm.

A compound BH2 (host material) and the compound BD (dopant material) were co-deposited on the first emitting layer to be 1% by mass in a proportion of the compound BD to form a second emitting layer having the thickness of 10 nm.

A compound HBL was deposited on the second emitting layer to form a hole-barrier layer having the thickness of 5 nm.

Compounds ET and Liq were co-deposited on the hole-barrier layer to be 50% by mass in a proportion of Liq to form an electron-transporting layer having the thickness of 20 nm.

A metal Yb was deposited on the electron-transporting layer to form an electron-injecting layer having the thickness of 1 nm.

A metal Al was deposited on the electron-injecting layer to form a cathode having the thickness of 60 nm.

The device configuration of the organic EL device of Example 1 is schematically shown as follows. ITO(130)/HT1:HA(10:3%)/HT1(80)/1-1:2-1(5:50%)/BH1:BD(10:1%)/BH2:BD(10:1%)/HBL(5)/ET:Liq(20:50%)/Yb(1)/Al(60)

The numerical values in parentheses indicate the film thickness (unit: nm). The numerical values represented by percent in parentheses indicate a proportion (% by mass) of the latter compound in the layer.

### <Evaluation of Organic EL Device>

The obtained organic EL device was evaluated as follows. The results are shown in Table 2.

### External Quantum Efficiency

A voltage was applied to the organic EL device so that the current density became 10 mA/cm², and the EL emission spectrum was measured by using Spectroradiometer CS-2000 (manufactured by KONICA MINOLTA, INC.). External quantum efficiency (EQE) (%) was calculated from the obtained spectral emission luminance spectrum. The results are shown in Table 2.

### Device Lifetime

A voltage was applied to the obtained organic EL device at room temperature so that the current density became 50 mA/cm², and the time until the luminance became 95% of the initial luminance (LT95 (unit: h)) was measured. The results are shown in Table 2.

### Example 2

An organic EL device was fabricated and evaluated in the same manner as in Example 1, except that a compound 2-2 was used instead of the compound 2-1. The results are shown in Table 2.

### Example 3

An organic EL device was fabricated and evaluated in the same manner as in Example 1, except that a compound 2-3 was used instead of the compound 2-1. The results are shown in Table 2.

### Example 4

An organic EL device was fabricated and evaluated in the same manner as in Example 1, except that a compound 2-4 was used instead of the compound 2-1. The results are shown in Table 2.

### Example 5

An organic EL device was fabricated and evaluated in the same manner as in Example 1, except that a compound 2-5 was used instead of the compound 2-1. The results are shown in Table 2.

### Example 6

An organic EL device was fabricated and evaluated in the same manner as in Example 1, except that a compound 2-6 was used instead of the compound 2-1. The results are shown in Table 2.

### Example 7

An organic EL device was fabricated and evaluated in the same manner as in Example 1, except that a compound 1-2 was used instead of the compound 1-1. The results are shown in Table 2.

### Example 8

An organic EL device was fabricated and evaluated in the same manner as in Example 1, except that a compound 1-3 was used instead of the compound 1-1. The results are shown in Table 2.

### Comparative Example 1

An organic EL device was fabricated and evaluated in the same manner as in Example 1, except that the compound 1-1 was deposited alone to form the third hole-transporting layer instead of co-depositing compounds 1-1 and 2-1. The results are shown in Table 2.

### Comparative Example 2

An organic EL device was fabricated and evaluated in the same manner as in Example 1, except that the compound 2-1 was deposited alone to form the third hole-transporting layer instead of co-depositing compounds 1-1 and 2-1. The results are shown in Table 2.

### Comparative Example 3

An organic EL device was fabricated and evaluated in the same manner as in Example 1, except that the compounds Ref1 and 2-1 were co-deposited to be 50% by mass in a proportion of the compound 2-1 to form the third hole-transporting layer instead of co-depositing compounds 1-1 and 2-1. The results are shown in Table 2.

### Comparative Example 4

An organic EL device was fabricated and evaluated in the same manner as in Example 1, except that the compounds Ref2 and 2-1 were co-deposited to be 50% by mass in a proportion of the compound 2-1 to form the third hole-transporting layer instead of co-depositing compounds 1-1 and 2-1. The results are shown in Table 2.

TABLE 2

| | | | Device |
|---|---|---|---|
| | Third hole- | Externalquantum | lifetime |
| | transporting layer | efficiency (%) | (hr) |
| Example 1 | Compound 1-1 + | 10.0 | 78 |
| | Compound 2-1 | | |
| | (50 wt %:50 wt %) | | |
| Example 2 | Compound 1-1 + | 10.0 | 82 |
| | Compound 2-2 | | |
| | (50 wt %:50 wt %) | | |
| Example 3 | Compound 1-1 + | 10.0 | 80 |
| | Compound 2-3 | | |
| | (50 wt %:50 wt %) | | |
| Example 4 | Compound 1-1 + | 9.9 | 50 |
| | Compound 2-4 | | |
| | (50 wt %:50 wt %) | | |
| Example 5 | Compound 1-1 + | 10.2 | 51 |
| | Compound 2-5 | | |
| | (50 wt %:50 wt %) | | |
| Example 6 | Compound 1-1 + | 10.2 | 50 |
| | Compound 2-6 | | |
| | (50 wt %:50 wt %) | | |
| Example 7 | Compound 1-2 + | 10.0 | 80 |
| | Compound 2-1 | | |
| | (50 wt %:50 wt %) | | |
| Example 8 | Compound 1-3 + | 10.0 | 80 |
| | Compound 2-1 | | |
| | (50 wt %:50 wt %) | | |
| Comparative | Compound 1-1 | 10.1 | 31 |
| Example 1 | | | |
| Comparative | Compound 2-1 | 9.6 | 63 |
| Example 2 | | | |
| Comparative | Compound Ref1 + | 9.3 | 39 |
| Example 3 | Compound 2-1 | | |
| | (50 wt %:50 wt %) | | |
| Comparative | Compound Ref2 + | 9.3 | 39 |
| Example 4 | Compound 2-1 | | |
| | (50 wt %:50 wt %) | | |

As seen from the results shown in Table 2, it was found that an organic EL device having high efficiency and long lifetime can be obtained by using the composition of the present invention in which compounds having the specific structures are used in combination.

Although only some exemplary embodiments and/or examples of this invention have been described in detail above, those skilled in the art will readily appreciate that many modifications are possible in the exemplary embodiments and/or examples without materially departing from the novel teachings and advantages of this invention. Accordingly, all such modifications are intended to be included within the scope of this invention.

The documents described in the specification and the specification of Japanese application(s) on the basis of which the present application claims Paris convention priority are incorporated herein by reference in its entirety.

1. A composition comprising a first compound and a second compound, wherein the first compound is a compound represented by the following formula (12), and the second compound is a compound represented by the following formula (21) (provided that the compound represented by the formula (12) is different from the compound represented by the formula (21)): 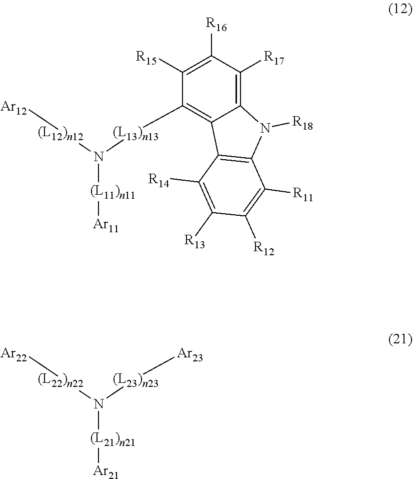
wherein in the formula (12),
Ar₁₁ and Ar₁₂ are independently
a substituted or unsubstituted aryl group having 6 to 50 ring carbon atoms,
a substituted or unsubstituted monovalent heterocyclic group having 5 to 50 ring atoms, or
—Si(R_{C1})(R_{C2})(R_{C3});
R_{C1} to R_{C3} are independently a substituted or unsubstituted aryl group having 6 to 50 ring carbon atoms,
when a plurality of each of R_{C1} to R_{C3} are present, the plurality of each of R_{C1} to R_{C3} may be the same as or different from each other;
n11 is an integer of 0 to 3; when n11 is 0, Ar₁₁ is directly bonded with the nitrogen atom of the amine via a single bond; when n11 is 2 or 3, a plurality of L₁₁'s is linked in series with each other and Ar₁₁ is bonded with L₁₁ which is farthest from the nitrogen atom of the amine; when two or more L₁₁'s are present, one or more sets of the adjacent two or more of the two or more L₁₁'s form a substituted or unsubstituted single ring by bonding with each other, form a substituted or unsubstituted fused ring by bonding with each other, or do not form the ring; when two or more L₁₁'s are present, the two or more L₁₁'s may be the same as or different from each other;
n12 is an integer of 0 to 3; when n12 is 0, Ar₁₂ is directly bonded with the nitrogen atom of the amine via a single bond; when n12 is 2 or 3, a plurality of L₁₂'s is linked in series with each other and Ar₁₂ is bonded with L₁₂ which is farthest from the nitrogen atom of the amine; when two or more L₁₂'s are present, one or more sets of the adjacent two or more of the two or more L₁₂'s form a substituted or unsubstituted single ring by bonding with each other, form a substituted or unsubstituted fused ring by bonding with each other, or do not form the ring; when two or more L₁₂'s are present, the two or more L₁₂'s may be the same as or different from each other;
n13 is an integer of 0 to 3; when n13 is 0, the carbon atom of the carbazole skeleton is directly bonded with the nitrogen atom of the amine via a single bond; when n13 is 2 or 3, a plurality of L₁₃'s is linked in series with each other and the carbazole skeleton is bonded with L₁₃ which is farthest from the nitrogen atom of the amine; when two or more L₁₃'s are present, one or more sets of the adjacent two or more of the two or more L₁₃'s form a substituted or unsubstituted single ring by bonding with each other, form a substituted or unsubstituted fused ring by bonding with each other, or do not form the ring; when two or more L₁₃'s are present, the two or more L₁₃'s may be the same as or different from each other;
L₁₁, L₁₂, and L₁₃ which do not form the ring are independently
a single bond,
a substituted or unsubstituted arylene group having 6 to 50 ring carbon atoms, or
a substituted or unsubstituted divalent heterocyclic group having 5 to 50 ring atoms;
one or more sets of the adjacent two or more of R₁₁ to R₁₇
form a substituted or unsubstituted single ring by bonding with each other,
form a substituted or unsubstituted fused ring by bonding with each other, or
do not bond with each other;
R₁₈, and R₁₁ to R₁₇ which do not form the substituted or unsubstituted single ring and which do not form the substituted or unsubstituted fused ring are independently
a hydrogen atom,
a cyano group,
a substituted or unsubstituted alkyl group having 1 to 50 carbon atoms,
a substituted or unsubstituted halogenated alkyl group having 1 to 50 carbon atoms,
a substituted or unsubstituted cycloalkyl group having 3 to 50 ring carbon atoms,
a group represented by —Si(R_{901A})(R_{902A})(R_{903A}),
a group represented by —O—(R_{904A}),
a substituted or unsubstituted aryl group having 6 to 50 ring carbon atoms, or
a substituted or unsubstituted monovalent heterocyclic group having 5 to 50 ring atoms;
R_{901A} to R_{904A} are independently
a hydrogen atom,
a substituted or unsubstituted alkyl group having 1 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted monovalent heterocyclic group having 5 to 50 ring atoms;
when a plurality of each of R_{901A} to R_{904A} are present, the plurality of each of R_{901A} to R_{904A} may be the same as or different from each other;
in the formula (21),
Ar₂₁, Ar₂₂, and Ar₂₃ are independently
a substituted or unsubstituted aryl group having 6 to 50 ring carbon atoms,
a substituted or unsubstituted monovalent heterocyclic group having 5 to 50 ring atoms, or
—Si(R_{C1})(R_{C2})(R_{C3});
R_{C1} to R_{C3} are the same as defined in the formula (12);
n21 is an integer of 0 to 3; when n21 is 0, Ar₂₁ is directly bonded with the nitrogen atom of the amine via a single bond; when n21 is 2 or 3, a plurality of L₂₁'s is linked in series with each other and Ar₂₁ is bonded with L₂₁ which is farthest from the nitrogen atom of the amine; when two or more L₂₁'s are present, one or more sets of the adjacent two or more of the two or more L₂₁'s form a substituted or unsubstituted single ring by bonding with each other, form a substituted or unsubstituted fused ring by bonding with each other, or do not form the ring; when two or more L₂₁'s are present, the two or more L₂₁'s may be the same as or different from each other;
n22 is an integer of 0 to 3; when n22 is 0, Ar₂₂ is directly bonded with the nitrogen atom of the amine via a single bond; when n22 is 2 or 3, a plurality of L₂₂'s is linked in series with each other and Ar₂₂ is bonded with L₂₂ which is farthest from the nitrogen atom of the amine; when two or more L₂₂'s are present, one or more sets of the adjacent two or more of the two or more L₂₂'s form a substituted or unsubstituted single ring by bonding with each other, form a substituted or unsubstituted fused ring by bonding with each other, or do not form the ring; when two or more L₂₂'s are present, the two or more L₂₂'s may be the same as or different from each other;
n23 is an integer of 0 to 3; when n23 is 0, Ar₂₃ is directly bonded with the nitrogen atom of the amine via a single bond; when n23 is 2 or 3, a plurality of L₂₃'s is linked in series with each other and Ar₂₃ is bonded with L₂₃ which is farthest from the nitrogen atom of the amine; when two or more L₂₃'s are present, one or more sets of the adjacent two or more of the two or more L₂₃'s form a substituted or unsubstituted single ring by bonding with each other, form a substituted or unsubstituted fused ring by bonding with each other, or do not form the ring; when two or more L₂₃'s are present, the two or more L₂₃'s may be the same as or different from each other; and
L₂₁, L₂₂, and L₂₃ which do not form the ring are independently
a single bond,
a substituted or unsubstituted arylene group having 6 to 50 ring carbon atoms, or
a substituted or unsubstituted divalent heterocyclic group having 5 to 50 ring atoms.

2. The composition according to claim 1, wherein L₁₃ is a substituted or unsubstituted arylene group having 6 to 50 ring carbon atoms, or a substituted or unsubstituted divalent heterocyclic group having 5 to 50 ring atoms.

3. The composition according to claim 1, wherein the compound represented by the formula (12) is a compound represented by the following formula (12-1) or (12-2): 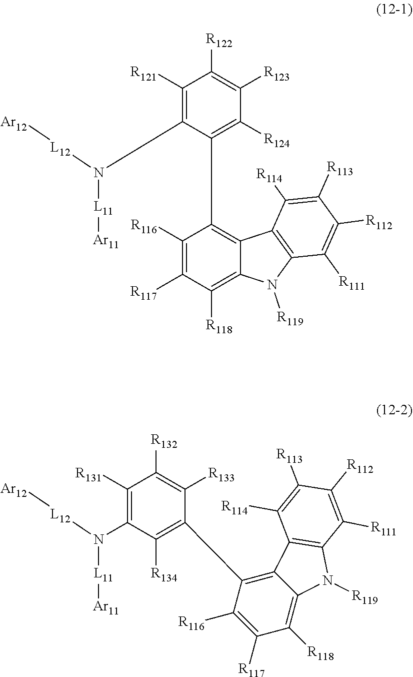
wherein in the formula (12-1),
Ar₁₁, Ar₁₂, L₁₁, and L₁₂ are the same as defined in the formula (12);
one or more sets of the adjacent two or more of R₁₁₁ to R₁₁₄ and R₁₁₆ to R₁₁₈
form a substituted or unsubstituted single ring by bonding with each other,
form a substituted or unsubstituted fused ring by bonding with each other, or
do not bond with each other;
R₁₁₉, and R₁₁₁ to R₁₁₄ and R₁₁₆ to R₁₁₈ which do not form the substituted or unsubstituted single ring and which do not form the substituted or unsubstituted fused ring are independently
a hydrogen atom,
a cyano group,
a substituted or unsubstituted alkyl group having 1 to 50 carbon atoms,
a substituted or unsubstituted halogenated alkyl group having 1 to 50 carbon atoms,
a substituted or unsubstituted cycloalkyl group having 3 to 50 ring carbon atoms,
a group represented by —Si(R_{901A})(R_{902A})(R_{903A}),
a group represented by —O—(R_{904A}),
a substituted or unsubstituted aryl group having 6 to 50 ring carbon atoms, or
a substituted or unsubstituted monovalent heterocyclic group having 5 to 50 ring atoms;
R_{901A} to R_{904A} are the same as defined in the formula (12);
R₁₂₁ to R₁₂₄ are independently a hydrogen atom, or a substituent R;
in the formula (12-2),
Ar₁₁, Ar₁₂, L₁₁, and L₁₂ are the same as defined in the formula (12);
one or more sets of the adjacent two or more of R₁₁₁ to R₁₁₄ and R₁₁ to R₁₁₈
form a substituted or unsubstituted single ring by bonding with each other,
form a substituted or unsubstituted fused ring by bonding with each other, or
do not bond with each other;
R₁₁₉, and R₁₁₁ to R₁₁₄ and R₁₁₆ to R₁₁₈ which do not form the substituted or unsubstituted single ring and which do not form the substituted or unsubstituted fused ring are independently
a hydrogen atom,
a cyano group,
a substituted or unsubstituted alkyl group having 1 to 50 carbon atoms,
a substituted or unsubstituted halogenated alkyl group having 1 to 50 carbon atoms,
a substituted or unsubstituted cycloalkyl group having 3 to 50 ring carbon atoms,
a group represented by —Si(R_{901A})(R_{902A})(R_{903A}),
a group represented by —O—(R_{904A}),
a substituted or unsubstituted aryl group having 6 to 50 ring carbon atoms, or
a substituted or unsubstituted monovalent heterocyclic group having 5 to 50 ring atoms;
R_{901A} to R_{904A} are the same as defined in the formula (12);
R₁₃₁ to R₁₃₄ are independently a hydrogen atom, or a substituent R;
the substituent R is selected from the group consisting of
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,
—Si(R₉₀₁)(R₉₀₂)(R₉₀₃),
—O—(R₉₀₄),
—S—(R₉₀₅),
—N(R₉₀₆)(R₉₀₇)
(wherein R₉₀₁ to R₉₀₇ are independently
a hydrogen atom,
a substituted or unsubstituted alkyl group having 1 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted monovalent heterocyclic group having 5 to 50 ring atoms; when two or more of each of R₉₀₁ to R₉₀₇ are present, the two or more of each of R₉₀₁ to R₉₀₇ may be the same as or different from each other),
a halogen atom, a cyano group, a nitro group,
a substituted or unsubstituted aryl group having 6 to 50 ring carbon atoms, and
a substituted or unsubstituted monovalent heterocyclic group having 5 to 50 ring atoms; and
when two or more substituents R are present, the two or more substituents R may be the same as or different from each other.

4. The composition according to claim 1, wherein the compound represented by the formula (21) is a compound represented by the following formula (22): 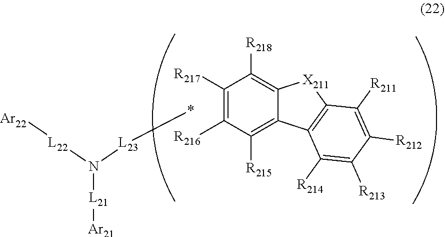
wherein in the formula (22),
Ar₂₁, Ar₂₂ and L₂₁ to L₂₃ are the same as defined in the formula (21);
X₂₁₁ is C(Rₐ)(R_{b}), N(R₂₁₉), O, or S;
any one of R₂₁₉ in the case where X₂₁₁ is N(R₂₁₉) and R₂₁₁ to R₂₁₈ represents a bond with L₂₃; when L₂₃ is a single bond, any of carbon atoms in the skeleton among the structure in the above parentheses and N in the case where X₂₁₁ is N(R₂₁₉) is directly bonded with the nitrogen atom of the amine via a single bond;
one or more sets of the adjacent two or more of R₂₁₁ to R₂₁₈ which do not represent a bond with L₂₃ do not bond with each other;
R₂₁₁ to R₂₁₉ which do not represent a bond with L₂₃ are independently a hydrogen atom, or a substituent R;
Rₐ and R_{b}
form a substituted or unsubstituted single ring by bonding with each other,
form a substituted or unsubstituted fused ring by bonding with each other, or
do not bond with each other;
Rₐ and R_{b} which do not form the substituted or unsubstituted single ring and which do not form the substituted or unsubstituted fused ring are independently
a substituted or unsubstituted alkyl group having 1 to 10 carbon atoms, or
a substituted or unsubstituted aryl group having 6 to 18 ring carbon atoms;
the substituent R is selected from the group consisting of
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,
—Si(R₉₀₁)(R₉₀₂)(R₉₀₃),
—O—(R₉₀₄),
—S—(R₉₀₅),
—N(R₉₀₅)(R₉₀₇)
(wherein R₉₀₁ to R₉₀₇ are independently
a hydrogen atom,
a substituted or unsubstituted alkyl group having 1 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted monovalent heterocyclic group having 5 to 50 ring atoms; when two or more of each of R₉₀₁ to R₉₀₇ are present, the two or more of each of R₉₀₁ to R₉₀₇ may be the same as or different from each other),
a halogen atom, a cyano group, a nitro group,
a substituted or unsubstituted aryl group having 6 to 50 ring carbon atoms, and
a substituted or unsubstituted monovalent heterocyclic group having 5 to 50 ring atoms; and
when two or more substituents R are present, the two or more substituents R may be the same as or different from each other.

5. The composition according to claim 4, wherein the compound represented by the formula (22) is a compound represented by the following formula (22-1) or (22-2): 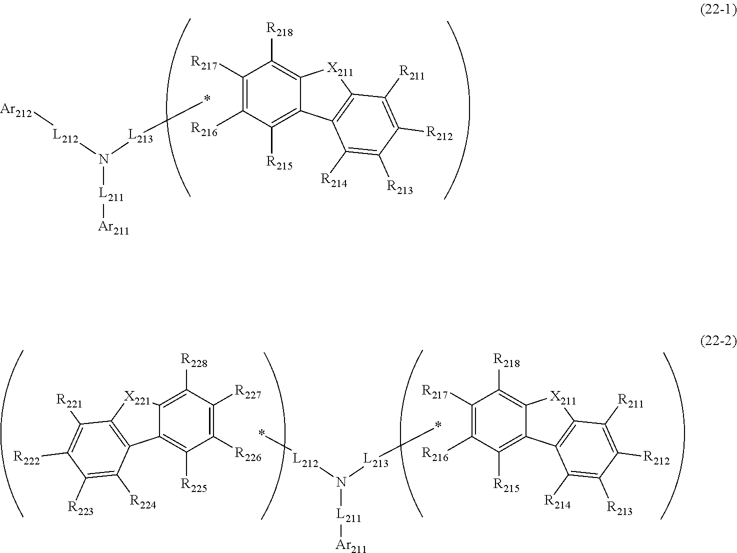
wherein in the formula (22-1),
X₂₁₁ and R₂₁₁ to R₂₁₈ are the same as defined in the formula (22);
Ar₂₁₁ and Ar₂₁₂ are independently
a substituted or unsubstituted aryl group having 6 to 50 ring carbon atoms, or
—Si(R_{C1})(R_{C2})(R_{C3});
R_{C1} to R_{C3} are the same as defined in the formula (12);
L₂₁₁, L₂₁₂, and L₂₁₃ are independently
a single bond,
a substituted or unsubstituted arylene group having 6 to 50 ring carbon atoms, or
a substituted or unsubstituted divalent heterocyclic group having 5 to 50 ring atoms;
in the formula (22-2),
X₂₁₁ and R₂₁₁ to R₂₁₈ are the same as defined in the formula (22);
Ar₂₁₁ is
a substituted or unsubstituted aryl group having 6 to 50 ring carbon atoms, or
—Si(R_{C1})(R_{C2})(R_{C3});
R_{C1} to R_{C3} are the same as defined in the formula (12);
L₂₁₁, L₂₁₂, and L₂₁₃ are independently
a single bond,
a substituted or unsubstituted arylene group having 6 to 50 ring carbon atoms, or
a substituted or unsubstituted divalent heterocyclic group having 5 to 50 ring atoms;
X₂₂₁ is C(Rₐ)(R_{b}), N(R₂₂₉), O, or S;
any one of R₂₂₉ in the case where X₂₂₁ is N(R₂₂₉) and R₂₂₁ to R₂₂₈ represents a bond with L₂₁₂;
when L₂₁₂ is a single bond, any of carbon atoms in the skeleton among the structure in the above parentheses and N in the case where X₂₂₁ is N(R₂₂₉) is directly bonded with the nitrogen atom of the amine via a single bond;
one or more sets of the adjacent two or more of R₂₂₁ to R₂₂₈ which do not represent a bond with L₂₁₂ do not bond with each other;
R₂₂₁ to R₂₂₉ which do not represent a bond with L₂₁₃ are independently a hydrogen atom, or a substituent R;
Rₐ and R_{b}
form a substituted or unsubstituted single ring by bonding with each other,
form a substituted or unsubstituted fused ring by bonding with each other, or
do not bond with each other;
Rₐ and R_{b} which do not form the substituted or unsubstituted single ring and which do not form the substituted or unsubstituted fused ring are independently
a substituted or unsubstituted alkyl group having 1 to 10 carbon atoms, or
a substituted or unsubstituted aryl group having 6 to 18 ring carbon atoms; and
the substituent R are the same as defined in the formula (22).

6. The composition according to claim 4, wherein the compound represented by the formula (22) is a compound represented by the following formula (23): 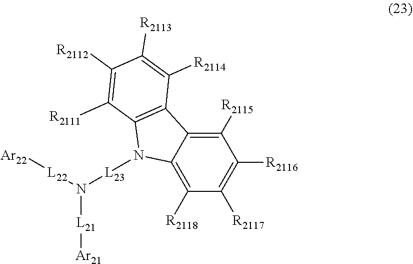
wherein in the formula (23), Ar₂₁, Ar₂₂ and L₂₁ to L₂₃ are the same as defined in the formula (21);
one or more sets of the adjacent two or more of R₂₁₁₁ to R₂₁₁₈ do not bond with each other;
R₂₁₁₁ to R₂₁₁₈ are independently a hydrogen atom, or a substituent R; and
the substituent R are the same as defined in the formula (22).

7. A composition comprising a first compound and a second compound, wherein the first compound is a compound represented by the following formula (11), and the second compound is a compound represented by the following formula (23) (provided that the compound represented by the formula (11) is different from the compound represented by the formula (23)): 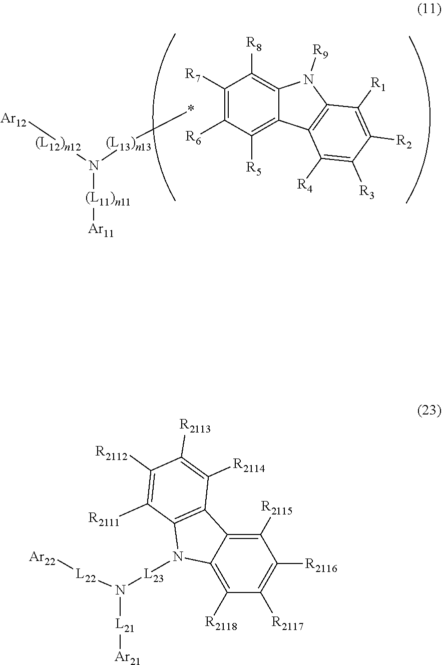
wherein in the formula (11),
Ar₁₁ and Ar₁₂ are independently
a substituted or unsubstituted aryl group having 6 to 50 ring carbon atoms,
a substituted or unsubstituted monovalent heterocyclic group having 5 to 50 ring atoms, or
—Si(R_{C1})(R_{C2})(R_{C3});
R_{C1} to R_{C3} are independently a substituted or unsubstituted aryl group having 6 to 50 ring carbon atoms,
when a plurality of each of R_{C1} to R_{C3} are present, the plurality of each of R_{C1} to R_{C3} may be the same as or different from each other;
any one of R₁ to Rₐ represents a bond with L₁₃;
one or more sets of the adjacent two or more of R₁ to Rₐ which do not represent a bond with L₁₃
form a substituted or unsubstituted single ring by bonding with each other,
form a substituted or unsubstituted fused ring by bonding with each other, or do not bond with each other;
R₉, and R₁ to Rₐ which do not represent a bond with L₁₃, which do not form the substituted or unsubstituted single ring and which do not form the substituted or unsubstituted fused ring are independently
a hydrogen atom,
a cyano group,
a substituted or unsubstituted alkyl group having 1 to 50 carbon atoms,
a substituted or unsubstituted halogenated alkyl group having 1 to 50 carbon atoms,
a substituted or unsubstituted cycloalkyl group having 3 to 50 ring carbon atoms,
a group represented by —Si(R_{901A})(R_{902A})(R_{903A}),
a group represented by —O—(R_{904A}),
a substituted or unsubstituted aryl group having 6 to 50 ring carbon atoms, or
a substituted or unsubstituted monovalent heterocyclic group having 5 to 50 ring atoms;
R_{901A} to R_{904A} are independently
a hydrogen atom,
a substituted or unsubstituted alkyl group having 1 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted monovalent heterocyclic group having 5 to 50 ring atoms;
when a plurality of each of R_{901A} to R_{904A} are present, the plurality of each of R_{901A} to R_{904A} may be the same as or different from each other;
n11 is an integer of 0 to 3; when n11 is 0, Ar₁₁ is directly bonded with the nitrogen atom of the amine via a single bond; when n11 is 2 or 3, a plurality of L₁₁'s is linked in series with each other and Ar₁₁ is bonded with L₁₁ which is farthest from the nitrogen atom of the amine; when two or more L₁₁'s are present, one or more sets of the adjacent two or more of the two or more L₁₁'s form a substituted or unsubstituted single ring by bonding with each other, form a substituted or unsubstituted fused ring by bonding with each other, or do not form the ring; when two or more L₁₁'s are present, the two or more L₁₁'s may be the same as or different from each other;
n12 is an integer of 0 to 3; when n12 is 0, Ar₁₂ is directly bonded with the nitrogen atom of the amine via a single bond; when n12 is 2 or 3, a plurality of L₁₂'s is linked in series with each other and Ar₁₂ is bonded with L₁₂ which is farthest from the nitrogen atom of the amine; when two or more L₁₂'s are present, one or more sets of the adjacent two or more of the two or more L₁₂'s form a substituted or unsubstituted single ring by bonding with each other, form a substituted or unsubstituted fused ring by bonding with each other, or do not form the ring; when two or more L₁₂'s are present, the two or more L₁₂'s may be the same as or different from each other;
n13 is an integer of 0 to 3; when n13 is 0, the carbon atom of the carbazole skeleton is directly bonded with the nitrogen atom of the amine via a single bond; when n13 is 2 or 3, a plurality of L₁₃'s is linked in series with each other and the carbazole skeleton is bonded with L₁₃ which is farthest from the nitrogen atom of the amine; when two or more L₁₃'s are present, one or more sets of the adjacent two or more of the two or more L₁₃'s form a substituted or unsubstituted single ring by bonding with each other, form a substituted or unsubstituted fused ring by bonding with each other, or do not form the ring; when two or more L₁₃'s are present, the two or more L₁₃'s may be the same as or different from each other;
L₁₁, L₁₂, and L₁₃ which do not form the ring are independently
a single bond,
a substituted or unsubstituted arylene group having 6 to 50 ring carbon atoms, or
a substituted or unsubstituted divalent heterocyclic group having 5 to 50 ring atoms;
in the formula (23),
Ar₂₁ and Ar₂₂ are independently
a substituted or unsubstituted aryl group having 6 to 50 ring carbon atoms,
a substituted or unsubstituted monovalent heterocyclic group having 5 to 50 ring atoms, or
—Si(R_{C1})(R_{C2})(R_{C3});
R_{C1} to R_{C3} are the same as defined in the formula (11);
L₂₁, L₂₂, and L₂₃ are independently
a single bond,
a substituted or unsubstituted arylene group having 6 to 50 ring carbon atoms, or
a substituted or unsubstituted divalent heterocyclic group having 5 to 50 ring atoms;
one or more sets of the adjacent two or more of R₂₁₁₁ to R₂₁₁₈ do not bond with each other;
R₂₁₁₁ to R₂₁₁₈ are independently a hydrogen atom, or a substituent R;
the substituent R is selected from the group consisting of
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,
—Si(R₉₀₁)(R₉₀₂)(R₉₀₃),
—O—(R₉₀₄),
—S—(R₉₀₅),
—N(R₉₀₅)(R₉₀₇)
(wherein R₉₀₁ to R₉₀₇ are independently
a hydrogen atom,
a substituted or unsubstituted alkyl group having 1 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted monovalent heterocyclic group having 5 to 50 ring atoms; when two or more of each of R₉₀₁ to R₉₀₇ are present, the two or more of each of R₉₀₁ to R₉₀₇ may be the same as or different from each other),
a halogen atom, a cyano group, a nitro group,
a substituted or unsubstituted aryl group having 6 to 50 ring carbon atoms, and
a substituted or unsubstituted monovalent heterocyclic group having 5 to 50 ring atoms; and
when two or more substituents R are present, the two or more substituents R may be the same as or different from each other.

8. The composition according to claim 7, wherein Ar₂₁ and Ar₂₂ are independently a substituted or unsubstituted aryl group having 6 to 50 ring carbon atoms, or —Si(R_{C1})(R_{C2})(R_{C3}).

9. The composition according to claim 7, wherein the compound represented by the formula (11) is a compound represented by the following formula (12): 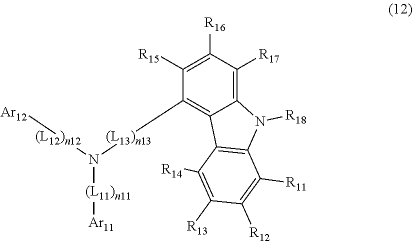
wherein in the formula (12),
Ar₁₁, Ar₁₂, L₁₁, L₁₂, L₁₃, n11, n12, and n13 are the same as defined in the formula (11);
one or more sets of the adjacent two or more of R₁₁ to R₁₇
form a substituted or unsubstituted single ring by bonding with each other,
form a substituted or unsubstituted fused ring by bonding with each other, or
do not bond with each other;
R₁₈, and R₁₁ to R₁₇ which do not form the substituted or unsubstituted single ring and which do not form the substituted or unsubstituted fused ring are independently
a hydrogen atom,
a cyano group,
a substituted or unsubstituted alkyl group having 1 to 50 carbon atoms,
a substituted or unsubstituted halogenated alkyl group having 1 to 50 carbon atoms,
a substituted or unsubstituted cycloalkyl group having 3 to 50 ring carbon atoms,
a group represented by —Si(R_{901A})(R_{902A})(R_{903A}),
a group represented by —O—(R_{904A}),
a substituted or unsubstituted aryl group having 6 to 50 ring carbon atoms, or
a substituted or unsubstituted monovalent heterocyclic group having 5 to 50 ring atoms; and
R_{901A} to R_{904A} are the same as defined in the formula (11).

10. The composition according to claim 7, wherein L₁₃ is a substituted or unsubstituted arylene group having 6 to 50 ring carbon atoms, or a substituted or unsubstituted divalent heterocyclic group having 5 to 50 ring atoms.

11. The composition according to claim 9, wherein the compound represented by the formula (12) is a compound represented by the following formula (12-1) or (12-2): 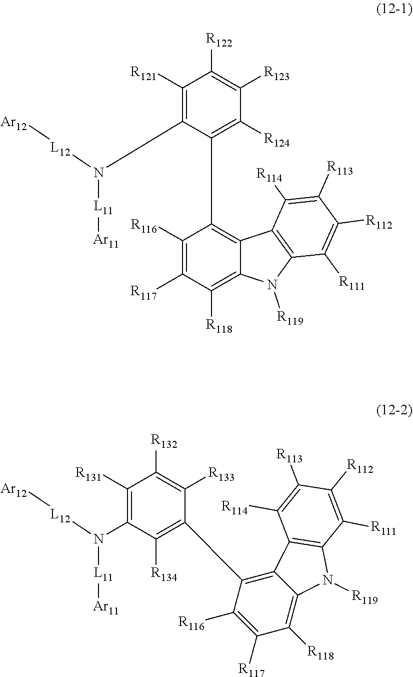
wherein in the formula (12-1),
Ar₁₁, Ar₁₂, L₁₁, and L₁₂ are the same as defined in the formula (12);
one or more sets of the adjacent two or more of R₁₁₁ to R₁₁₄ and R₁₁₆ to R₁₁₈
form a substituted or unsubstituted single ring by bonding with each other,
form a substituted or unsubstituted fused ring by bonding with each other, or
do not bond with each other;
R₁₁₉, and R₁₁₁ to R₁₁₄ and R₁₁₆ to R₁₁₈ which do not form the substituted or unsubstituted single ring and which do not form the substituted or unsubstituted fused ring are independently
a hydrogen atom,
a cyano group,
a substituted or unsubstituted alkyl group having 1 to 50 carbon atoms,
a substituted or unsubstituted halogenated alkyl group having 1 to 50 carbon atoms,
a substituted or unsubstituted cycloalkyl group having 3 to 50 ring carbon atoms,
a group represented by —Si(R_{901A})(R_{902A})(R_{903A}),
a group represented by —O—(R_{904A}),
a substituted or unsubstituted aryl group having 6 to 50 ring carbon atoms, or a substituted or unsubstituted monovalent heterocyclic group having 5 to 50 ring atoms;
R_{901A} to R_{904A} are the same as defined in the formula (12);
R₁₂₁ to R₁₂₄ are independently a hydrogen atom, or a substituent R;
in the formula (12-2),
Ar₁₁, Ar₁₂, L₁₁, and L₁₂ are the same as defined in the formula (12);
one or more sets of the adjacent two or more of R₁₁₁ to R₁₁₄ and R₁₁₆ to R₁₁₈
form a substituted or unsubstituted single ring by bonding with each other,
form a substituted or unsubstituted fused ring by bonding with each other, or
do not bond with each other;
R₁₁₉, and R₁₁₁ to R₁₁₄ and R₁₁ to R₁₁₈ which do not form the substituted or unsubstituted single ring and which do not form the substituted or unsubstituted fused ring are independently
a hydrogen atom,
a cyano group,
a substituted or unsubstituted alkyl group having 1 to 50 carbon atoms,
a substituted or unsubstituted halogenated alkyl group having 1 to 50 carbon atoms,
a substituted or unsubstituted cycloalkyl group having 3 to 50 ring carbon atoms,
a group represented by —Si(R_{901A})(R_{902A})(R_{903A}),
a group represented by —O—(R_{904A}),
a substituted or unsubstituted aryl group having 6 to 50 ring carbon atoms, or
a substituted or unsubstituted monovalent heterocyclic group having 5 to 50 ring atoms;
R_{901A} to R_{904A} are the same as defined in the formula (12);
R₁₃₁ to R₁₃₄ are independently a hydrogen atom, or a substituent R;
the substituent R is selected from the group consisting of
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,
—Si(R₉₀₁)(R₉₀₂)(R₉₀₃),
—O—(R₉₀₄),
—S—(R₉₀₅),
—N(R₉₀₆)(R₉₀₇)
(wherein R₉₀₁ to R₉₀₇ are independently
a hydrogen atom,
a substituted or unsubstituted alkyl group having 1 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted monovalent heterocyclic group having 5 to 50 ring atoms; when two or more of each of R₉₀₁ to R₉₀₇ are present, the two or more of each of R₉₀₁ to R₉₀₇ may be the same as or different from each other),
a halogen atom, a cyano group, a nitro group,
a substituted or unsubstituted aryl group having 6 to 50 ring carbon atoms, and
a substituted or unsubstituted monovalent heterocyclic group having 5 to 50 ring atoms; and
when two or more substituents R are present, the two or more substituents R may be the same as or different from each other.

12. The composition according to claim 1, wherein the amount of the first compound is 30 to 70% by mass based on the total amount of the first compound and the second compound.

13. The composition according to claim 1, wherein the ionization potential of the second compound is 5.6 eV or more.

14. The composition according to claim 1, wherein the ionization potential of the second compound is larger than the ionization potential of the first compound by 0.1 eV or more.

15. The composition according to claim 1, wherein the hole mobility of the first compound is larger than 1.0×10⁻⁵ cm²/(V·s).

16. The composition according to claim 1, wherein the hole mobility of the second compound is smaller than 1.0×10⁻⁵ cm²/(V·s).

17. The composition according to claim 1, which is powder-like.

18. An organic electroluminescence device comprising the composition according to claim 1.

19. The composition according to claim 7, wherein the amount of the first compound is 30 to 70% by mass based on the total amount of the first compound and the second compound.

20. The composition according to claim 7, wherein the ionization potential of the second compound is 5.6 eV or more.

21. The composition according to claim 7, wherein the ionization potential of the second compound is larger than the ionization potential of the first compound by 0.1 eV or more.

22. The composition according to claim 7, wherein the hole mobility of the first compound is larger than 1.0×10⁻⁵ cm²/(V·s).

23. The composition according to claim 7, wherein the hole mobility of the second compound is smaller than 1.0×10⁻⁵ cm²/(V·s).

24. The composition according to claim 7, which is powder-like.

25. An organic electroluminescence device comprising the composition according to claim 7.

26. An organic electroluminescence device comprising
a cathode,
an anode, and
one or two or more organic layers arranged between the cathode and the anode,
wherein at least one layer of the one or two or more organic layers
comprises a first compound and a second compound,
the first compound is a compound represented by the following formula (12),
the second compound is a compound represented by the following formula (21),
provided that the first compound is different from the second compound: 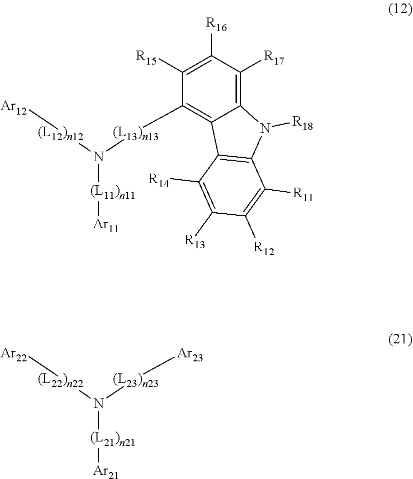
wherein in the formula (12),
Ar₁₁ and Ar₁₂ are independently
a substituted or unsubstituted aryl group having 6 to 50 ring carbon atoms,
a substituted or unsubstituted monovalent heterocyclic group having 5 to 50 ring atoms, or
—Si(R_{C1})(R_{C2})(R_{C3});
R_{C1} to R_{C3} are independently a substituted or unsubstituted aryl group having 6 to 50 ring carbon atoms,
when a plurality of each of R_{C1} to R_{C3} are present, the plurality of each of R_{C1} to R_{C3} may be the same as or different from each other;
n11 is an integer of 0 to 3; when n11 is 0, Ar₁₁ is directly bonded with the nitrogen atom of the amine via a single bond; when n11 is 2 or 3, a plurality of L₁₁'s is linked in series with each other and Ar₁₁ is bonded with L₁₁ which is farthest from the nitrogen atom of the amine; when two or more L₁₁'s are present, one or more sets of the adjacent two or more of the two or more L₁₁'s form a substituted or unsubstituted single ring by bonding with each other, form a substituted or unsubstituted fused ring by bonding with each other, or do not form the ring; when two or more L₁₁'s are present, the two or more L₁₁'s may be the same as or different from each other;
n12 is an integer of 0 to 3; when n12 is 0, Ar₁₂ is directly bonded with the nitrogen atom of the amine via a single bond; when n12 is 2 or 3, a plurality of L₁₂'s is linked in series with each other and Ar₁₂ is bonded with L₁₂ which is farthest from the nitrogen atom of the amine; when two or more L₁₂'s are present, one or more sets of the adjacent two or more of the two or more L₁₂'s form a substituted or unsubstituted single ring by bonding with each other, form a substituted or unsubstituted fused ring by bonding with each other, or do not form the ring; when two or more L₁₂'s are present, the two or more L₁₂'s may be the same as or different from each other;
n13 is an integer of 0 to 3; when n13 is 0, the carbon atom of the carbazole skeleton is directly bonded with the nitrogen atom of the amine via a single bond; when n13 is 2 or 3, a plurality of L₁₃'s is linked in series with each other and the carbazole skeleton is bonded with L₁₃ which is farthest from the nitrogen atom of the amine; when two or more L₁₃'s are present, one or more sets of the adjacent two or more of the two or more L₁₃'s form a substituted or unsubstituted single ring by bonding with each other, form a substituted or unsubstituted fused ring by bonding with each other, or do not form the ring; when two or more L₁₃'s are present, the two or more L₁₃'s may be the same as or different from each other;
L₁₁, L₁₂, and L₁₃ which do not form the ring are independently
a single bond,
a substituted or unsubstituted arylene group having 6 to 50 ring carbon atoms, or
a substituted or unsubstituted divalent heterocyclic group having 5 to 50 ring atoms;
one or more sets of the adjacent two or more of R₁₁ to R₁₇
form a substituted or unsubstituted single ring by bonding with each other,
form a substituted or unsubstituted fused ring by bonding with each other, or
do not bond with each other;
R₁₃, and R₁₁ to R₁₇ which do not form the substituted or unsubstituted single ring and which do not form the substituted or unsubstituted fused ring are independently
a hydrogen atom,
a cyano group,
a substituted or unsubstituted alkyl group having 1 to 50 carbon atoms,
a substituted or unsubstituted halogenated alkyl group having 1 to 50 carbon atoms,
a substituted or unsubstituted cycloalkyl group having 3 to 50 ring carbon atoms,
a group represented by —Si(R_{901A})(R_{902A})(R_{903A}),
a group represented by —O—(R_{904A}),
a substituted or unsubstituted aryl group having 6 to 50 ring carbon atoms, or
a substituted or unsubstituted monovalent heterocyclic group having 5 to 50 ring atoms;
R_{901A} to R_{904A} are independently
a hydrogen atom,
a substituted or unsubstituted alkyl group having 1 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted monovalent heterocyclic group having 5 to 50 ring atoms;
when a plurality of each of R_{901A} to R_{904A} are present, the plurality of each of R_{901A} to R_{904A} may be the same as or different from each other;
in the formula (21),
Ar₂₁, Ar₂₂, and Ar₂₃ are independently
a substituted or unsubstituted aryl group having 6 to 50 ring carbon atoms,
a substituted or unsubstituted monovalent heterocyclic group having 5 to 50 ring atoms, or
—Si(R_{C1})(R_{C2})(R_{C3});
R_{C1} to R_{C3} are the same as defined in the formula (12);
n21 is an integer of 0 to 3; when n21 is 0, Ar₂₁ is directly bonded with the nitrogen atom of the amine via a single bond; when n21 is 2 or 3, a plurality of L₂₁'s is linked in series with each other and Ar₂₁ is bonded with L₂₁ which is farthest from the nitrogen atom of the amine; when two or more L₂₁'s are present, one or more sets of the adjacent two or more of the two or more L₂₁'s form a substituted or unsubstituted single ring by bonding with each other, form a substituted or unsubstituted fused ring by bonding with each other, or do not form the ring; when two or more L₂₁'s are present, the two or more L₂₁'s may be the same as or different from each other;
n22 is an integer of 0 to 3; when n22 is 0, Ar₂₂ is directly bonded with the nitrogen atom of the amine via a single bond; when n22 is 2 or 3, a plurality of L₂₂'s is linked in series with each other and Ar₂₂ is bonded with L₂₂ which is farthest from the nitrogen atom of the amine; when two or more L₂₂'s are present, one or more sets of the adjacent two or more of the two or more L₂₂'s form a substituted or unsubstituted single ring by bonding with each other, form a substituted or unsubstituted fused ring by bonding with each other, or do not form the ring; when two or more L₂₂'s are present, the two or more L₂₂'s may be the same as or different from each other;
n23 is an integer of 0 to 3; when n23 is 0, Ar₂₃ is directly bonded with the nitrogen atom of the amine via a single bond; when n23 is 2 or 3, a plurality of L₂₃'s is linked in series with each other and Ar₂₃ is bonded with L₂₃ which is farthest from the nitrogen atom of the amine; when two or more L₂₃'s are present, one or more sets of the adjacent two or more of the two or more L₂₃'s form a substituted or unsubstituted single ring by bonding with each other, form a substituted or unsubstituted fused ring by bonding with each other, or do not form the ring; when two or more L₂₃'s are present, the two or more L₂₃'s may be the same as or different from each other; and
L₂₁, L₂₂, and L₂₃ which do not form the ring are independently
a single bond,
a substituted or unsubstituted arylene group having 6 to 50 ring carbon atoms, or
a substituted or unsubstituted divalent heterocyclic group having 5 to 50 ring atoms.

27. An organic electroluminescence device comprising
a cathode,
an anode, and
one or two or more organic layers arranged between the cathode and the anode,
wherein at least one layer of the one or two or more organic layers
comprises a first compound and a second compound,
the first compound is a compound represented by the following formula (11),
the second compound is a compound represented by the following formula (23),
provided that the first compound is different from the second compound: 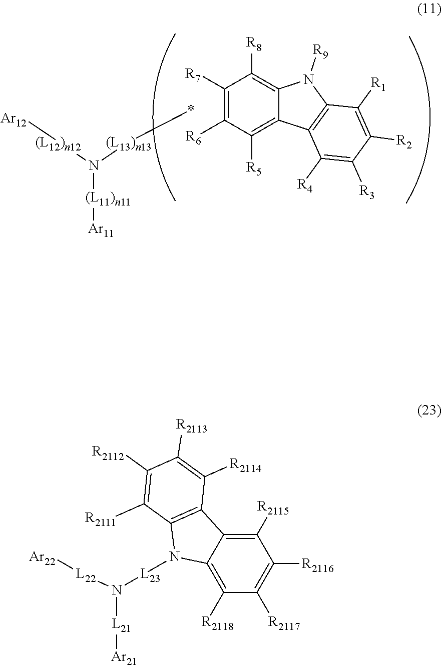
wherein in the formula (11),
Ar₁₁ and Ar₁₂ are independently
a substituted or unsubstituted aryl group having 6 to 50 ring carbon atoms,
a substituted or unsubstituted monovalent heterocyclic group having 5 to 50 ring atoms, or
—Si(R_{C1})(R_{C2})(R_{C3});
R_{C1} to R_{C3} are independently a substituted or unsubstituted aryl group having 6 to 50 ring carbon atoms,
when a plurality of each of R_{C1} to R_{C3} are present, the plurality of each of R_{C1} to R_{C3} may be the same as or different from each other;
any one of R₁ to Rₐ represents a bond with L₁₃;
one or more sets of the adjacent two or more of R₁ to Rₐ which do not represent a bond with L₁₃
form a substituted or unsubstituted single ring by bonding with each other,
form a substituted or unsubstituted fused ring by bonding with each other, or
do not bond with each other;
R₉, and R₁ to Rₐ which do not represent a bond with L₁₃, which do not form the substituted or unsubstituted single ring and which do not form the substituted or unsubstituted fused ring are independently
a hydrogen atom,
a cyano group,
a substituted or unsubstituted alkyl group having 1 to 50 carbon atoms,
a substituted or unsubstituted halogenated alkyl group having 1 to 50 carbon atoms,
a substituted or unsubstituted cycloalkyl group having 3 to 50 ring carbon atoms,
a group represented by —Si(R_{901A})(R_{902A})(R_{903A}),
a group represented by —O—(R_{904A}),
a substituted or unsubstituted aryl group having 6 to 50 ring carbon atoms, or
a substituted or unsubstituted monovalent heterocyclic group having 5 to 50 ring atoms;
R_{901A} to R_{904A} are independently
a hydrogen atom,
a substituted or unsubstituted alkyl group having 1 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted monovalent heterocyclic group having 5 to 50 ring atoms;
when a plurality of each of R_{901A} to R_{904A} are present, the plurality of each of R_{901A} to R_{904A} may be the same as or different from each other;
n11 is an integer of 0 to 3; when n11 is 0, Ar₁₁ is directly bonded with the nitrogen atom of the amine via a single bond; when n11 is 2 or 3, a plurality of L₁₁'s is linked in series with each other and Ar₁₁ is bonded with L₁₁ which is farthest from the nitrogen atom of the amine; when two or more L₁₁'s are present, one or more sets of the adjacent two or more of the two or more L₁₁'s form a substituted or unsubstituted single ring by bonding with each other, form a substituted or unsubstituted fused ring by bonding with each other, or do not form the ring; when two or more L₁₁'s are present, the two or more L₁₁'s may be the same as or different from each other;
n12 is an integer of 0 to 3; when n12 is 0, Ar₁₂ is directly bonded with the nitrogen atom of the amine via a single bond; when n12 is 2 or 3, a plurality of L₁₂'s is linked in series with each other and Ar₁₂ is bonded with L₁₂ which is farthest from the nitrogen atom of the amine; when two or more L₁₂'s are present, one or more sets of the adjacent two or more of the two or more L₁₂'s form a substituted or unsubstituted single ring by bonding with each other, form a substituted or unsubstituted fused ring by bonding with each other, or do not form the ring; when two or more L₁₂'s are present, the two or more L₁₂'s may be the same as or different from each other;
n13 is an integer of 0 to 3; when n13 is 0, the carbon atom of the carbazole skeleton is directly bonded with the nitrogen atom of the amine via a single bond; when n13 is 2 or 3, a plurality of L₁₃'s is linked in series with each other and the carbazole skeleton is bonded with L₁₃ which is farthest from the nitrogen atom of the amine; when two or more L₁₃'s are present, one or more sets of the adjacent two or more of the two or more L₁₃'s form a substituted or unsubstituted single ring by bonding with each other, form a substituted or unsubstituted fused ring by bonding with each other, or do not form the ring; when two or more L₁₃'s are present, the two or more L₁₃'s may be the same as or different from each other;
L₁₁, L₁₂, and L₁₃ which do not form the ring are independently
a single bond,
a substituted or unsubstituted arylene group having 6 to 50 ring carbon atoms, or
a substituted or unsubstituted divalent heterocyclic group having 5 to 50 ring atoms;
in the formula (23),
Ar₂₁ and Ar₂₂ are independently
a substituted or unsubstituted aryl group having 6 to 50 ring carbon atoms,
a substituted or unsubstituted monovalent heterocyclic group having 5 to 50 ring atoms, or
—Si(R_{C1})(R_{C2})(R_{C3});
R_{C1} to R_{C3} are the same as defined in the formula (11);
L₂₁, L₂₂, and L₂₃ are independently
a single bond,
a substituted or unsubstituted arylene group having 6 to 50 ring carbon atoms, or
a substituted or unsubstituted divalent heterocyclic group having 5 to 50 ring atoms;
one or more sets of the adjacent two or more of R₂₁₁₁ to R₂₁₁₈ do not bond with each other;
R₂₁₁₁ to R₂₁₁₈ are independently a hydrogen atom, or a substituent R;
the substituent R is selected from the group consisting of
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,
—Si(R₉₀₁)(R₉₀₂)(R₉₀₃),
—O—(R₉₀₄),
—S—(R₉₀₅),
—N(R₉₀₅)(R₉₀₇)
(wherein R₉₀₁ to R₉₀₇ are independently
a hydrogen atom,
a substituted or unsubstituted alkyl group having 1 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted monovalent heterocyclic group having 5 to 50 ring atoms; when two or more of each of R₉₀₁ to R₉₀₇ are present, the two or more of each of R₉₀₁ to R₉₀₇ may be the same as or different from each other),
a halogen atom, a cyano group, a nitro group,
a substituted or unsubstituted aryl group having 6 to 50 ring carbon atoms, and
a substituted or unsubstituted monovalent heterocyclic group having 5 to 50 ring atoms; and
when two or more substituents R are present, the two or more substituents R may be the same as or different from each other.

28. The organic electroluminescence device according to claim 26, which comprises the anode, a hole-transporting region, an emitting layer, and the cathode in this order, wherein the hole-transporting region comprises the first compound and the second compound.

29. The organic electroluminescence device according to claim 28, wherein the hole-transporting region comprises at least a first layer and a second layer in this order from the emitting layer side, and one or more layers selected from the group consisting of the first layer and the second layer comprise the first compound and the second compound.

30. The organic electroluminescence device according to claim 28, wherein the hole-transporting region comprises a hole-transporting layer and a hole-injecting layer from the emitting layer side.

31. The organic electroluminescence device according to claim 28, wherein the hole-transporting region comprises at least a first layer, a second layer and a third layer in this order from the emitting layer side, and
one or more layers selected from the group consisting of the first layer, the second layer, and the third layer comprise the first compound and the second compound.

32. The organic electroluminescence device according to claim 29, wherein the first layer comprises the first compound and the second compound.

33. The organic electroluminescence device according to claim 28, wherein the hole-transporting region has the thickness of 110 to 150 nm.

34. The organic electroluminescence device according to claim 28, which comprises an electron-transporting region arranged between the emitting layer and the cathode,
wherein the electron-transporting region comprises at least one organic layer,
the at least one organic layer comprises a nitrogen-containing compound, and
the nitrogen-containing compound comprises one or more rings selected from the group consisting of a nitrogen-containing five-membered ring and a nitrogen-containing six-membered ring.

35. The organic electroluminescence device according to claim 34, wherein the nitrogen-containing compound is one or more compounds selected from the group consisting of an imidazole derivative, a benzimidazole derivative, an azine derivative, a carbazole derivative, and a phenanthroline derivative.

36. The organic electroluminescence device according to claim 28, wherein the emitting layer comprises a host material, and an emitting compound in which the maximum peak wavelength represents 500 nm or less of emission.

37. The organic electroluminescence device according to claim 28, which comprises two or more emitting layers.

38. The organic electroluminescence device according to claim 27, which comprises the anode, a hole-transporting region, an emitting layer, and the cathode in this order, wherein the hole-transporting region comprises the first compound and the second compound.

39. The organic electroluminescence device according to claim 38, wherein the hole-transporting region comprises at least a first layer and a second layer in this order from the emitting layer side, and one or more layers selected from the group consisting of the first layer and the second layer comprise the first compound and the second compound.

40. The organic electroluminescence device according to claim 38, wherein the hole-transporting region comprises a hole-transporting layer and a hole-injecting layer from the emitting layer side.

41. The organic electroluminescence device according to claim 38, wherein the hole-transporting region comprises at least a first layer, a second layer and a third layer in this order from the emitting layer side, and
one or more layers selected from the group consisting of the first layer, the second layer, and the third layer comprise the first compound and the second compound.

42. The organic electroluminescence device according to claim 39, wherein the first layer comprises the first compound and the second compound.

43. The organic electroluminescence device according to claim 38, wherein the hole-transporting region has the thickness of 110 to 150 nm.

44. The organic electroluminescence device according to claim 38, which comprises an electron-transporting region arranged between the emitting layer and the cathode,
wherein the electron-transporting region comprises at least one organic layer,
the at least one organic layer comprises a nitrogen-containing compound, and
the nitrogen-containing compound comprises one or more rings selected from the group consisting of a nitrogen-containing five-membered ring and a nitrogen-containing six-membered ring.

45. The organic electroluminescence device according to claim 44, wherein the nitrogen-containing compound is one or more compounds selected from the group consisting of an imidazole derivative, a benzimidazole derivative, an azine derivative, a carbazole derivative, and a phenanthroline derivative.

46. The organic electroluminescence device according to claim 38, wherein the emitting layer comprises a host material, and an emitting compound in which the maximum peak wavelength represents 500 nm or less of emission.

47. The organic electroluminescence device according to claim 38, which comprises two or more emitting layers.

48. An electronic apparatus, comprising the organic electroluminescence device according to claim 18.

49. An electronic apparatus, comprising the organic electroluminescence device according to claim 25.

50. A method for fabricating an organic electroluminescence device, comprising: forming a film on a substrate by depositing the first compound and the second compound in the same deposition source or different deposition sources to fabricate the organic electroluminescence device according to claim 18.

51. A method for fabricating an organic electroluminescence device, comprising: forming a film on a substrate by depositing the first compound and the second compound in the same deposition source or different deposition sources to fabricate the organic electroluminescence device according to claim 25.
